(19) United States
(12) Patent Application Publication
(10) Pub. No.: US 2024/0268214 A1
(43) Pub. Date: Aug. 8, 2024

(54) ORGANOMETALLIC COMPOUND AND ORGANIC LIGHT-EMITTING DIODE INCLUDING THE SAME

(71) Applicant: LG Display Co., Ltd., Seoul (KR)

(72) Inventors: Kusun Choung, Seoul (KR); Misang Yoo, Seoul (KR); Hansol Park, Goyang-si (KR); Yoojeong Jeong, Seoul (KR); Soonjae Hwang, Seoul (KR); Kyoungjin PARK, Hwaseong-si (KR); Hyun KIM, Hwaseong-si (KR); Soo-Yong LEE, Cheonan-si (KR); Samuel KIM, Cheonan-si (KR)

(73) Assignee: LG Display Co., Ltd., Seoul (KR)

(21) Appl. No.: 18/416,752

(22) Filed: Jan. 18, 2024

(30) Foreign Application Priority Data
Jan. 20, 2023 (KR) 10-2023-0008787

(51) Int. Cl. H10K 85/30; C07F 15/00; C09K 11/06; H10K 50/12

(52) U.S. Cl. CPC H10K 85/342; C07F 15/0033; C09K 11/06; C07B 2200/05; C09K 2211/1051; C09K 2211/185; H10K 50/12

(57) ABSTRACT

Disclosed are an organometallic compound used as a phosphorescent dopant material of a light-emitting layer of an organic light-emitting diode, and an organic light-emitting diode containing the same. The organometallic compound is represented by Ir(L_{A})ₘ(L_{B})ₙ. An organic light-emitting diode includes a first electrode; a second electrode facing the first electrode; and an organic layer disposed between the first electrode and the second electrode. The organic layer includes a light-emitting layer that contains the organometallic compound disclosed herein.

### CROSS-REFERENCE TO RELATED APPLICATION

This application claims the benefit of and the priority to Korean Patent Application No. 10-2023-0008787 filed on Jan. 20, 2023 in the Korean Intellectual Property Office, the disclosure of which is hereby incorporated by reference in its entirety.

### BACKGROUND

### 1. Technical Field

The present disclosure relates to an organometallic compound, and more particularly, to an organometallic compound having phosphorescent properties and an organic light-emitting diode including the same.

### 2. Description of the Related Art

As a display device is applied to various fields, interest with the display device is increasing. One of the display devices is an organic light-emitting display device including an organic light-emitting diode (OLED) which is rapidly developing.

In the organic light-emitting diode, when electric charges are injected into a light-emitting layer formed between a positive electrode and a negative electrode, an electron and a hole are recombined with each other in the light-emitting layer to form an exciton and thus energy of the exciton is converted to light. Thus, the organic light-emitting diode emits the light. Compared to conventional display devices, the organic light-emitting diode may operate at a low voltage, consume relatively little power, render excellent colors, and may be used in a variety of ways because a flexible substrate may be applied thereto. Further, a size of the organic light-emitting diode may be freely adjustable.

The organic light-emitting diode (OLED) has superior viewing angle and contrast ratio compared to a liquid crystal display (LCD), and is lightweight and is ultra-thin because the OLED does not require a backlight. The organic light-emitting diode includes a plurality of organic layers between a negative electrode (electron injection electrode; cathode) and a positive electrode (hole injection electrode; anode). The plurality of organic layers may include a hole injection layer, a hole transport layer, a hole transport auxiliary layer, an electron blocking layer, and a light-emitting layer, an electron transport layer, etc.

In this organic light-emitting diode structure, when a voltage is applied across the two electrodes, electrons and holes are injected from the negative and positive electrodes, respectively, into the light-emitting layer and thus excitons are generated in the light-emitting layer and then fall to a ground state to emit light.

Organic materials used in the organic light-emitting diode may be largely classified into light-emitting materials and charge-transporting materials. The light-emitting material is an important factor determining luminous efficiency of the organic light-emitting diode. The luminescent material must have high quantum efficiency, excellent electron and hole mobility, and must exist uniformly and stably in the light-emitting layer. The light-emitting materials may be classified into light-emitting materials emitting light of blue, red, and green colors based on colors of the light. A color-generating material may include a host and dopants to increase the color purity and luminous efficiency through energy transfer.

When the fluorescent material is used, singlets as about 25% of excitons generated in the light-emitting layer are used to emit light, while most of triplets as 75% of the excitons generated in the light-emitting layer are dissipated as heat. However, when the phosphorescent material is used, singlets and triplets are used to emit light.

Conventionally, an organometallic compound is used as the phosphorescent material used in the organic light-emitting diode. There is still a technical need to improve performance of an organic light-emitting diode by deriving a high-efficiency phosphorescent dopant material and applying a host material of optimal photophysical properties to improve diode efficiency and lifetime, compared to a conventional organic light-emitting diode.

### SUMMARY

Accordingly, an object of the present disclosure is to provide an organometallic compound capable of lowering operation voltage of an organic light-emitting diode, and improving efficiency and lifespan thereof, and an organic light-emitting diode including an organic light-emitting layer containing the same.

Objects of the present disclosure are not limited to the above-mentioned object. Other objects and advantages of the present disclosure that are not mentioned may be understood based on following description, and may be more clearly understood based on aspects of the present disclosure. Further, it may be easily understood that the objects and advantages of the present disclosure may be realized using means shown in the claims and combinations thereof.

To achieve these and other advantages and in accordance with objects of the disclosure, as embodied and broadly described herein, an organometallic compound has a novel structure represented by a following Chemical Formula 1:

Ir(L_{A})ₘ(L_{B})ₙ [Chemical Formula 1]
wherein in the Chemical Formula 1,
L_{A} and L_{B} may be represented by a following Chemical Formula 2 and a following Chemical Formula 3, respectively,
m may be an integer from 1 to 3, n may be an integer from 0 to 2, a sum of m and n may be 3,

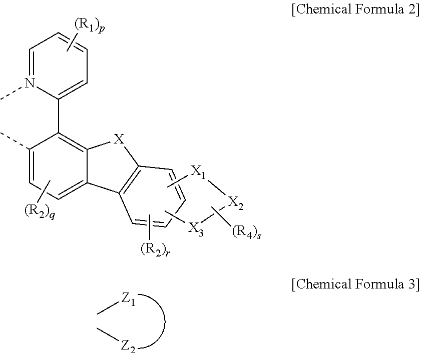

wherein in the Chemical Formula 2,
each of X, X₁, X₂ and X₃ may independently represent one selected from a group consisting of carbon (C), oxygen (O), nitrogen (N) and sulfur (S),
each of R₁, R₂, R₃ and R₄ may independently represent one selected from a group consisting of deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acid, ester, nitrile, isonitrile, sulfanyl, sulfinyl, sulfonyl, phosphino, and combinations thereof,
p may be an integer from 0 to 4, each of q and r may independently be an integer from 0 to 2, s may be an integer from 0 to 3,
when p is 2 or larger, two adjacent to each other of a plurality of R₁s may bind to each other to form a fused ring structure,
when q is 2, two adjacent to each other of a plurality of R₂s may bind to each other to form a fused ring structure,
when r is 2, two adjacent to each other of a plurality of R₃s may bind to each other to form a fused ring structure,
when s is 2, two adjacent to each other of a plurality of R₄s may bind to each other to form a fused ring structure,
the Chemical Formula 3 may be a bidendate ligand.

A second aspect of the present disclosure provides an organic light-emitting diode including a first electrode; a second electrode facing the first electrode; and an organic layer disposed between the first electrode and the second electrode, wherein the organic layer includes a light-emitting layer, wherein the light-emitting layer contains the organometallic compound according to the first aspect of the present disclosure.

A third aspect of the present disclosure provides an organic light-emitting display device including a substrate; a driving element located on the substrate; and an organic light-emitting diode disposed on the substrate and connected to the driving element, wherein the organic light-emitting diode includes the organic light-emitting diode according to the second aspect of the present disclosure.

The organometallic compound according to the present disclosure may be used as the dopant of the light-emitting layer of the organic light-emitting diode, such that the operation voltage of the organic light-emitting diode may be lowered, and the efficiency and lifespan characteristics of the organic light-emitting diode may be improved. Thus, a low power display deice may be realized.

Effects of the present disclosure are not limited to the above-mentioned effects, and other effects not mentioned may be clearly understood by those skilled in the art from following descriptions.

It is to be understood that both the foregoing general description and the following detailed description of the present disclosure are merely by way of example and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain principles of the disclosure.

FIG. 1 is a schematic cross-sectional view of an organic light-emitting diode according to an embodiment of the present disclosure.

FIG. 2 is a cross-sectional view schematically showing an organic light-emitting diode having a tandem structure having two light-emitting stacks according to an embodiment of the present disclosure.

FIG. 3 is a cross-sectional view schematically showing an organic light-emitting diode of a tandem structure having three light-emitting stacks according to an embodiment of the present disclosure.

FIG. 4 is a cross-sectional view schematically illustrating an organic light-emitting display device including an organic light-emitting diode according to an illustrative embodiment of the present disclosure.

### DETAILED DESCRIPTION

Reference will now be made in detail to some of the examples and embodiments of the disclosure illustrated in the accompanying drawings. Wherever possible, the same reference numbers will be used throughout the drawings to refer to the same or like parts.

Advantages and features of the present disclosure, and a method of achieving the advantages and features will become apparent with reference to embodiments described later in detail together with the accompanying drawings. However, the present disclosure is not limited to the embodiments as disclosed below, but may be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for describing embodiments of the present disclosure are illustrative, and the present disclosure is not limited thereto. The same reference numerals refer to the same elements herein.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “connected to” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects,” and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for describing embodiments.

Further, in a specific case, a term may be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions.

As used herein, the term “halo” or “halogen” includes fluorine, chlorine, bromine and iodine.

As used herein, the term “alkyl group” refers to both linear alkyl radicals and branched alkyl radicals. Unless otherwise specified, the alkyl group contains 1 to 20 carbon atoms, and includes methyl, ethyl, propyl, isopropyl, butyl, isobutyl, tert-butyl, etc. Further, the alkyl group may be optionally substituted.

As used herein, the term “cycloalkyl group” refers to a cyclic alkyl radical. Unless otherwise specified, the cycloalkyl group contains 3 to 20 carbon atoms, and includes cyclopropyl, cyclopentyl, cyclohexyl, and the like. Further, the cycloalkyl group may be optionally substituted.

As used herein, the term “alkenyl group” refers to both linear alkene radicals and branched alkene radicals. Unless otherwise specified, the alkenyl group contains 2 to 20 carbon atoms. Additionally, the alkenyl group may be optionally substituted.

As used herein, the term “alkynyl group” refers to both linear alkyne radicals and branched alkyne radicals. Unless otherwise specified, the alkynyl group contains 2 to 20 carbon atoms. Additionally, the alkynyl group may be optionally substituted.

The terms “aralkyl group” and “arylalkyl group” as used herein are used interchangeably with each other and refer to an alkyl group having an aromatic group as a substituent. Further, the alkylaryl group may be optionally substituted.

The terms “aryl group” and “aromatic group” as used herein are used in the same meaning. The aryl group includes both a monocyclic group and a polycyclic group. The polycyclic group may include a “fused ring” in which two or more rings are fused with each other such that two carbons are common to two adjacent rings. Unless otherwise specified, the aryl group contains 6 to 60 carbon atoms. Further, the aryl group may be optionally substituted.

The term “heterocyclic group” as used herein means that at least one of carbon atoms constituting an aryl group, a cycloalkyl group, or an aralkyl group (arylalkyl group) is substituted with a heteroatom such as oxygen (O), nitrogen (N), sulfur (S), etc. Further, the heterocyclic group may be optionally substituted.

The term “carbon ring” as used herein may be used as a term including both “cycloalkyl group” as an alicyclic group and “aryl group” an aromatic group unless otherwise specified.

The terms “heteroalkyl group” and “heteroalkenyl group” as used herein mean that at least one of carbon atoms constituting the group is substituted with a heteroatom such as oxygen (O), nitrogen (N), or sulfur (S). In addition, the heteroalkyl group and the heteroalkenyl group may be optionally substituted.

As used herein, the term “substituted” means that a substituent other than hydrogen (H) binds to corresponding carbon.

As used herein, a substituent may be interpreted as containing 1 to 30 carbon atoms unless there is a particular limitation on the number of carbon atoms, and the minimum number of carbon atoms that may be included in each substituent may be determined by what is known.

Unless specifically limited herein, the substituent may be deuterium, halogen, an alkyl group, a heteroalkyl group, an alkoxy group, an aryloxy group, an alkynyl group, an aryl group, a heteroaryl group, an acyl group, a carbonyl group, a carboxylic acid group, a nitrile group, a cyano group, an amino group, an alkylsilyl group, an arylsilyl group, a sulfonyl group, a phosphino group, and combinations thereof.

Subjects and substituents as defined in the present disclosure may be the same as or different from each other unless otherwise specified.

Hereinafter, a structure of an organometallic compound according to the present disclosure and an organic light-emitting diode including the same will be described in detail.

An organometallic compound represented by a following Chemical Formula 1 of the present disclosure is structurally characterized in that a 5-membered fused ring, in particular, a thiazole group is introduced to a dibenzofuran group (a carbon ring moiety), compared to a benzofuropyridine metal complex that has been widely used conventionally.

Thus, findings have been experimentally identified that when the organometallic compound represented by the Chemical Formula 1 is used as a dopant material of a phosphorescent light-emitting layer of the organic light-emitting diode, the light-emitting efficiency and lifetime of the organic light-emitting diode are improved, and an operation voltage thereof is lowered. In this way, the present disclosure has been completed.

Ir(L_{A})ₘ(L_{B})ₙ [Chemical Formula 1]
wherein in the Chemical Formula 1,
L_{A} and L_{B} may be represented by a following Chemical Formula 2 and a following Chemical Formula 3, respectively,
m may be an integer from 1 to 3, n may be an integer from 0 to 2, a sum of m and n may be 3,

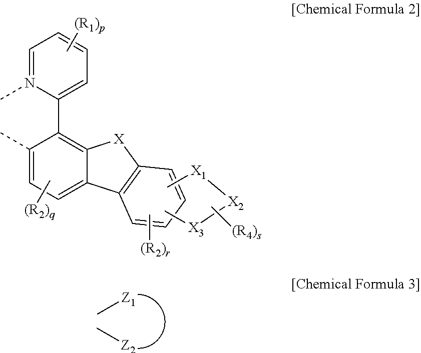

wherein in the Chemical Formula 2,
each of X, X₁, X₂ and X₃ may independently represent one selected from a group consisting of carbon (C), oxygen (O), nitrogen (N) and sulfur (S).
In the above Chemical Formula 2, each of R₁, R₂, R₃ and R₄ means a substituent that may bind to a moiety. As used herein, the definitions of R₁, R₂, R₃ and R₄ are applied to a case where R₁, R₂, R₃ and R₄ are present, that is, a case where p, q, r and s are 1 or larger. When R₁, R₂, R₃ and R₄ are not present, that is, when p, q, r, and s are 0, the moiety is unsubstituted with the substituent, and hydrogen basically binds thereto. Thus, even though the term “unsubstituted” is not recited herein, it is interpreted that hydrogen basically binding to carbon (C), oxygen (O), nitrogen (N) or sulfur (S) is present as along as the substituent does not bind thereto.

In the above Chemical Formula 2, each of R₁, R₂, R₃ and R₄ may independently represent one selected from a group consisting of deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acid, ester, nitrile, isonitrile, sulfanyl, sulfinyl, sulfonyl, phosphino, and combinations thereof.
p may be an integer from 0 to 4, each of q and r may independently be an integer from 0 to 2, s may be an integer from 0 to 3,
when p is 2 or larger, optionally, two adjacent to each other of a plurality of R₁s may bind to each other to form a fused ring structure,
when q is 2, optionally, two adjacent to each other of a plurality of R₂s may bind to each other to form a fused ring structure,
when r is 2, optionally, two adjacent to each other of a plurality of R₃s may bind to each other to form a fused ring structure,
when s is 2, optionally, two adjacent to each other of a plurality of R₄s may bind to each other to form a fused ring structure,
the Chemical Formula 3 may be a bidendate ligand.

According to one implementation of the present disclosure, the X may be oxygen (O).

According to one implementation of the present disclosure, m may be 1, n may be 2, m may be 2, n may be 1, m may be 3, n may be 0, preferably m may be 1 or 2.

According to one implementation of the present disclosure, preferably, one of X₁ and X₃ may be nitrogen (N), and the other of X₁ and X₃ other than nitrogen (N) may be sulfur (S). More preferably, X₁ to X₃ may constitute a thiazole group or a thiazole derivative.

According to one implementation of the present disclosure, the Chemical Formula 2 may have a structure represented by one of following Chemical Formula 2-1, Chemical Formula 2-2, or Chemical Formula 2-3 depending on a binding position of a pentagonal aromatic ring composed of X₁ to X₃.

In the following Chemical Formula 2-1, Chemical Formula 2-2 or Chemical Formula 2-3, s may be 1, and is the same as defined above in the Chemical Formula 2.

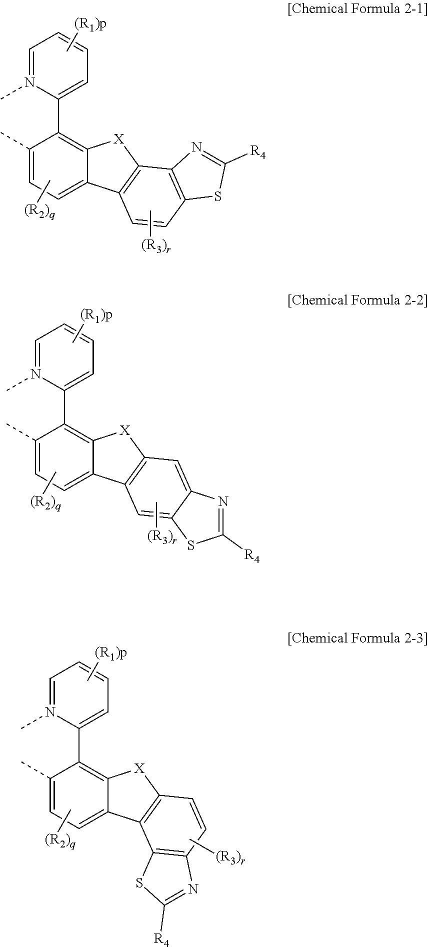

In particular, in the Chemical Formulas 2-1 to 2-3, each of R₁ and R₄ may be one selected from a group consisting of deuterium, halogen, a C1 to C10 linear alkyl group, a C1 to C10 branched alkyl group, a C7 to C30 aralkyl group, and a C6 to C30 aryl group. Optionally, at least one hydrogen of each of the C1 to C10 linear alkyl group, the C1 to C10 branched alkyl group, the C7 to C30 aralkyl group, and the C6 to C30 aryl group selected as R₁ or R₄ may be substituted with deuterium.

According to one implementation of the present disclosure, R₄ may be one selected from a group consisting of deuterium, a C to C10 linear alkyl group, and a C1 to C10 branched alkyl group. Optionally, at least one hydrogen of each of the C1 to C10 linear alkyl group, and the C1 to C10 branched alkyl group selected as R₄ may be substituted with deuterium.

According to one implementation of the present disclosure, each of q and r may independently be an integer of 0, which means that the substituents R₂ and R₃ in the Chemical Formula 2 are absent, so that an aryl group moiety to which R₂ and R₃ otherwise bind is not substituted with the substituent.

According to one implementation of the present disclosure, the Chemical Formula 3 may have a structure represented by one selected from a group consisting of following Chemical Formula 3-1 and Chemical Formula 3-2.

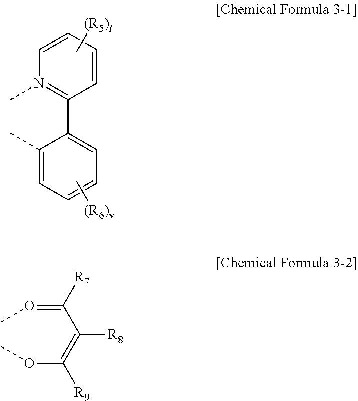

In the Chemical Formula 3-1, each of R₅ and R₆ may independently represent one selected from a group consisting of deuterium, a C1 to C5 linear alkyl group, and a C1 to C5 branched alkyl group, and each of t and v independently may be an integer from 0 to 4.

Optionally, at least one hydrogen of each of the C1 to C5 linear alkyl group or the C1 to C5 branched alkyl group selected as R₅ or R₆ may be substituted with at least one selected from deuterium and a halogen element.

Optionally, when t is 2 or greater, two functional groups adjacent to each other among a plurality of R₅s may bind to each other to form a fused ring structure. When v is 2 or greater, two functional groups adjacent to each other among a plurality of R₆s may bind to each other to form a fused ring structure.

In the Chemical Formula 3-2, each of R₇, R₈, and R₉ may independently represent one selected from a group consisting of hydrogen, deuterium, a C1 to C5 linear alkyl group, and a C1 to C5 branched alkyl group.

Optionally, at least one hydrogen of each of the C1 to C5 linear alkyl group or the C1 to C5 branched alkyl group selected as R₇, R₈ or R₉ may be substituted with at least one selected from deuterium and a halogen element.

Optionally, two functional groups adjacent to each other among R₇, R₈ and R₉ may bind to each other to form a fused ring structure.

According to one implementation of the present disclosure, preferably, the compound represented by the Chemical Formula 1 may be used as a green phosphorescent material. However, the present disclosure is not necessarily limited thereto.

A specific example of the compound represented by the Chemical Formula 1 of the present disclosure may be one selected from a group consisting of following Compound 1 to Compound 680. However, the specific example of the compound represented by the Chemical Formula 1 of the present disclosure is not limited thereto as long as it meets the above definition of the Chemical Formula 1:

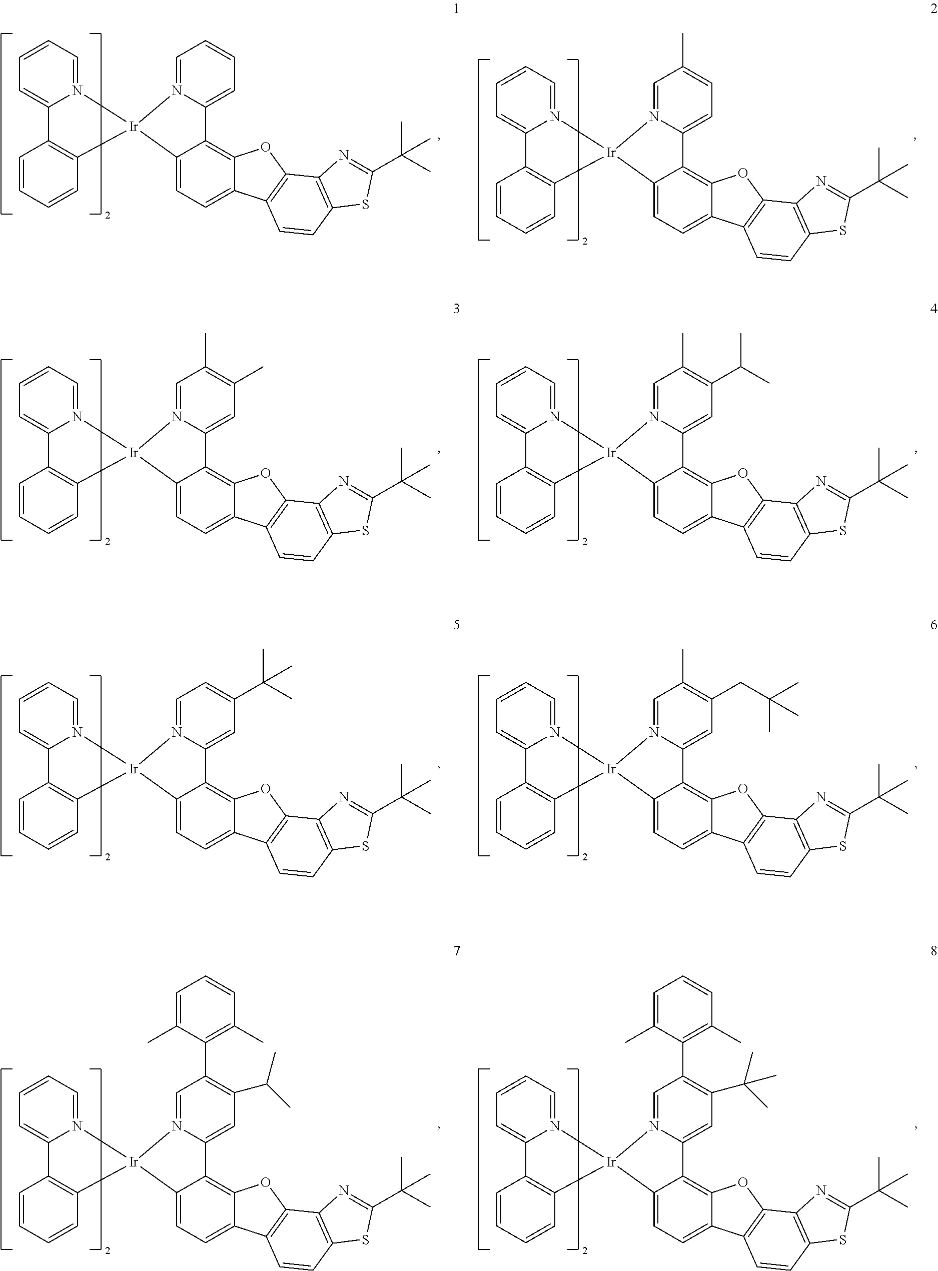

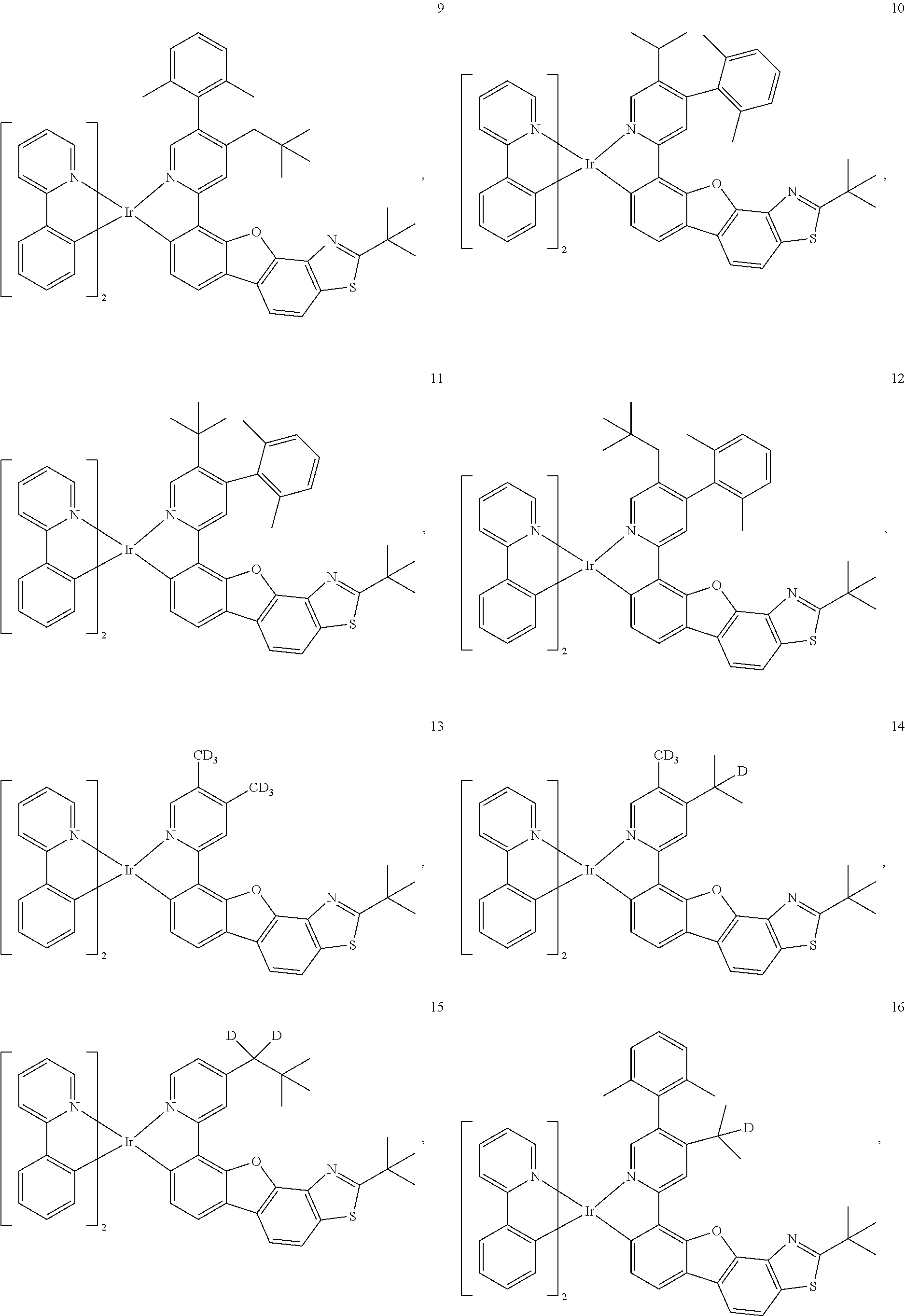

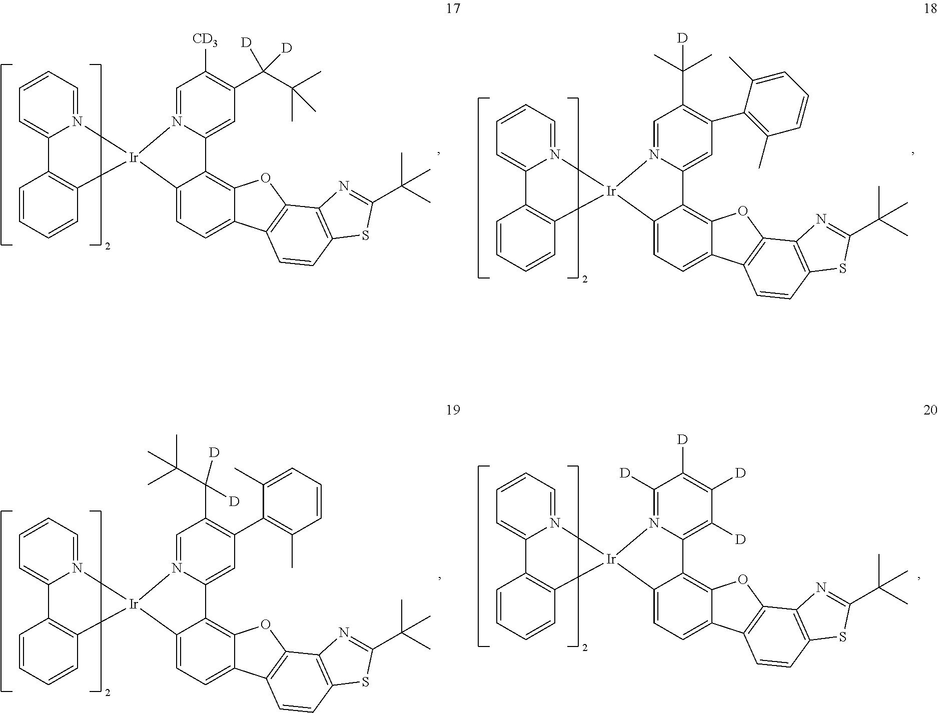

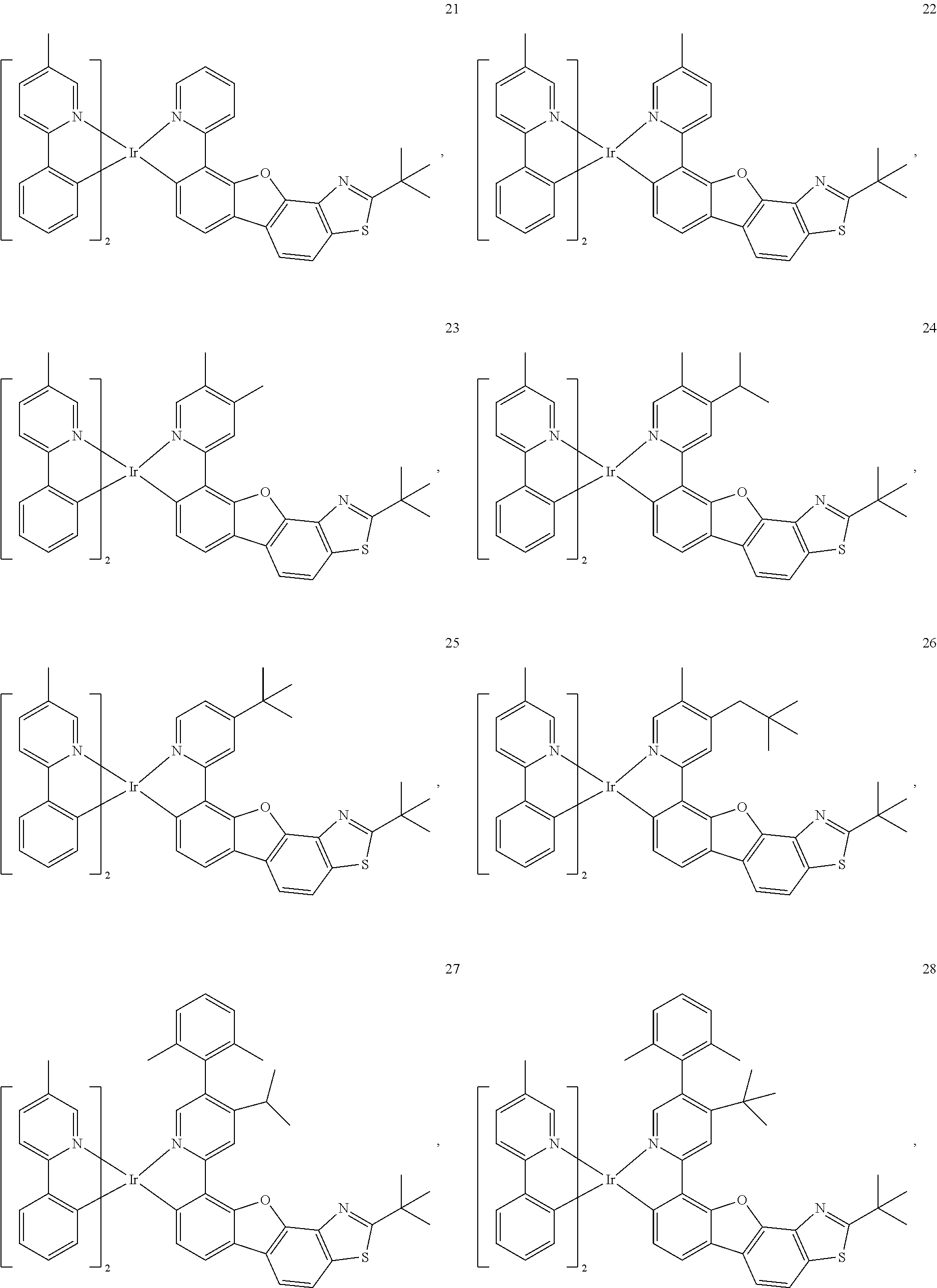

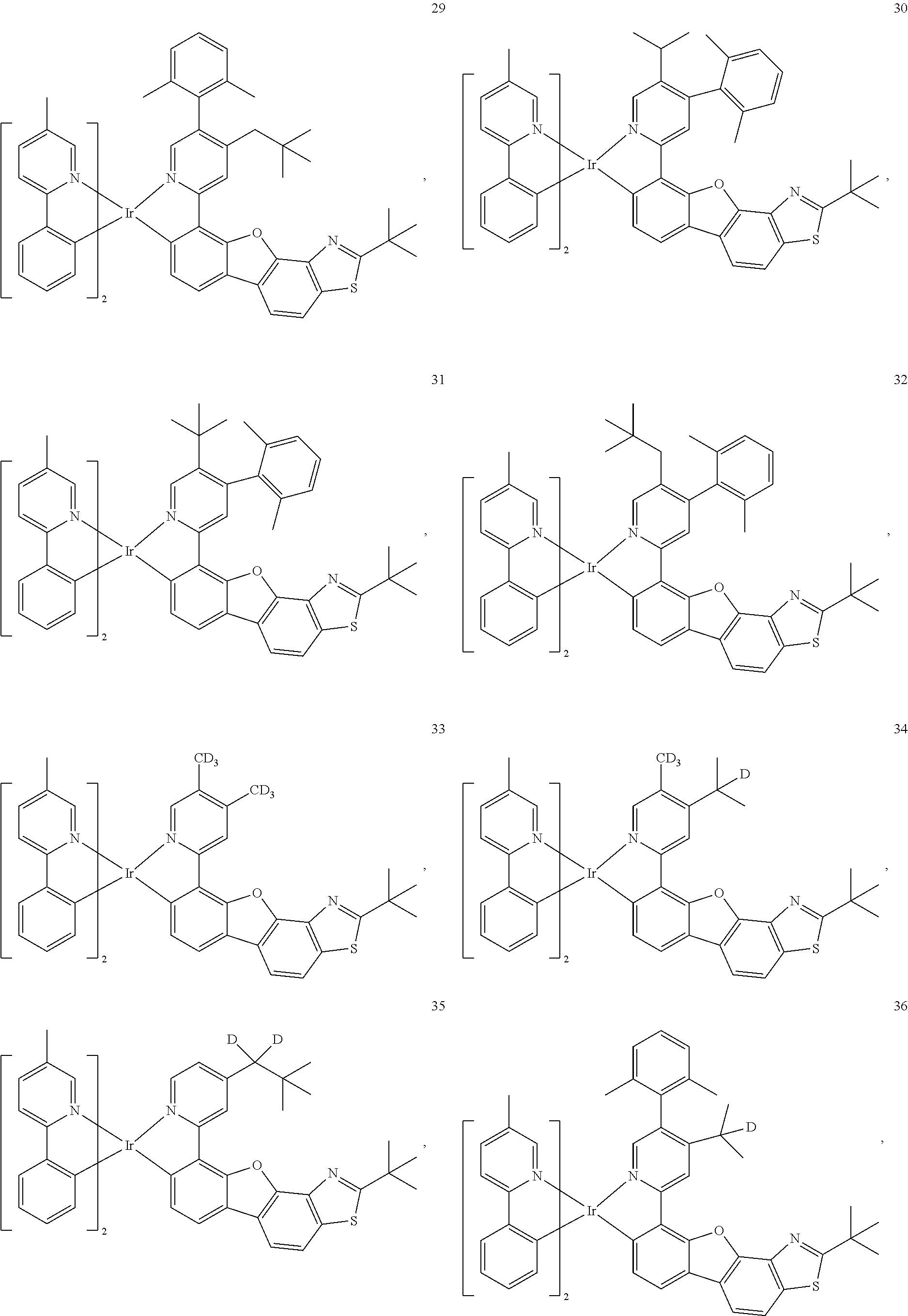

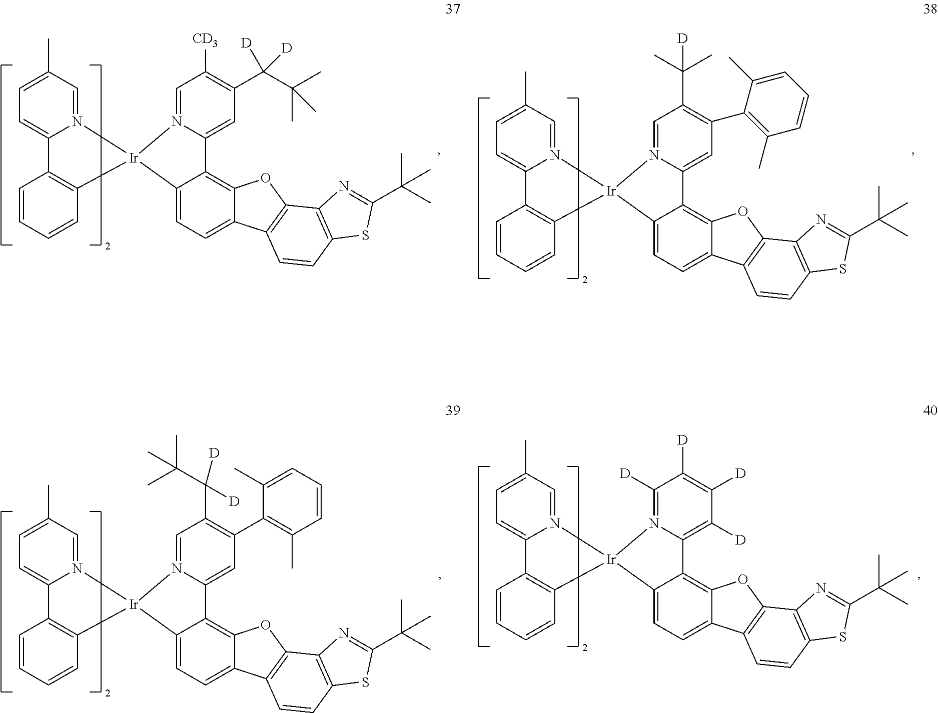

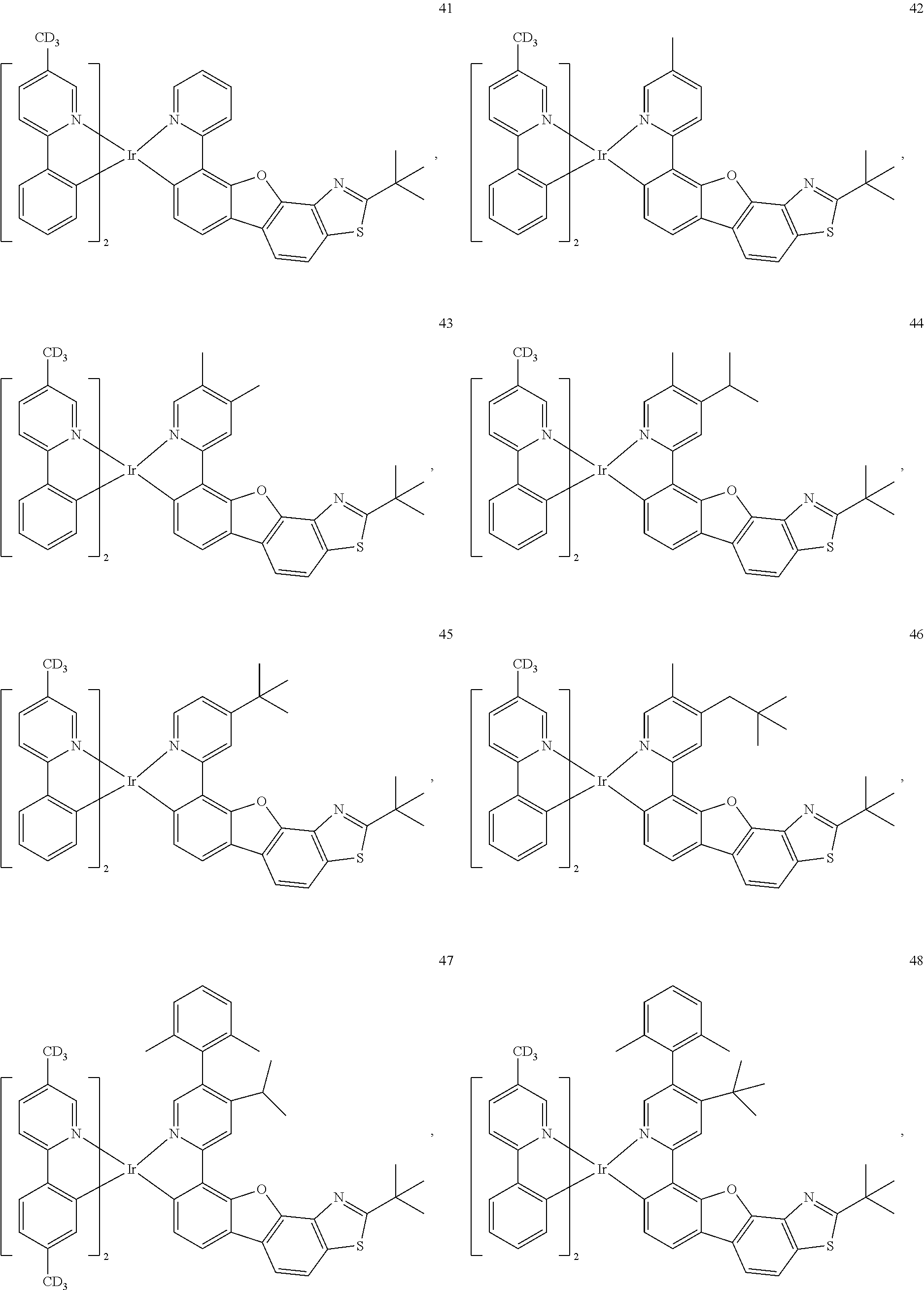

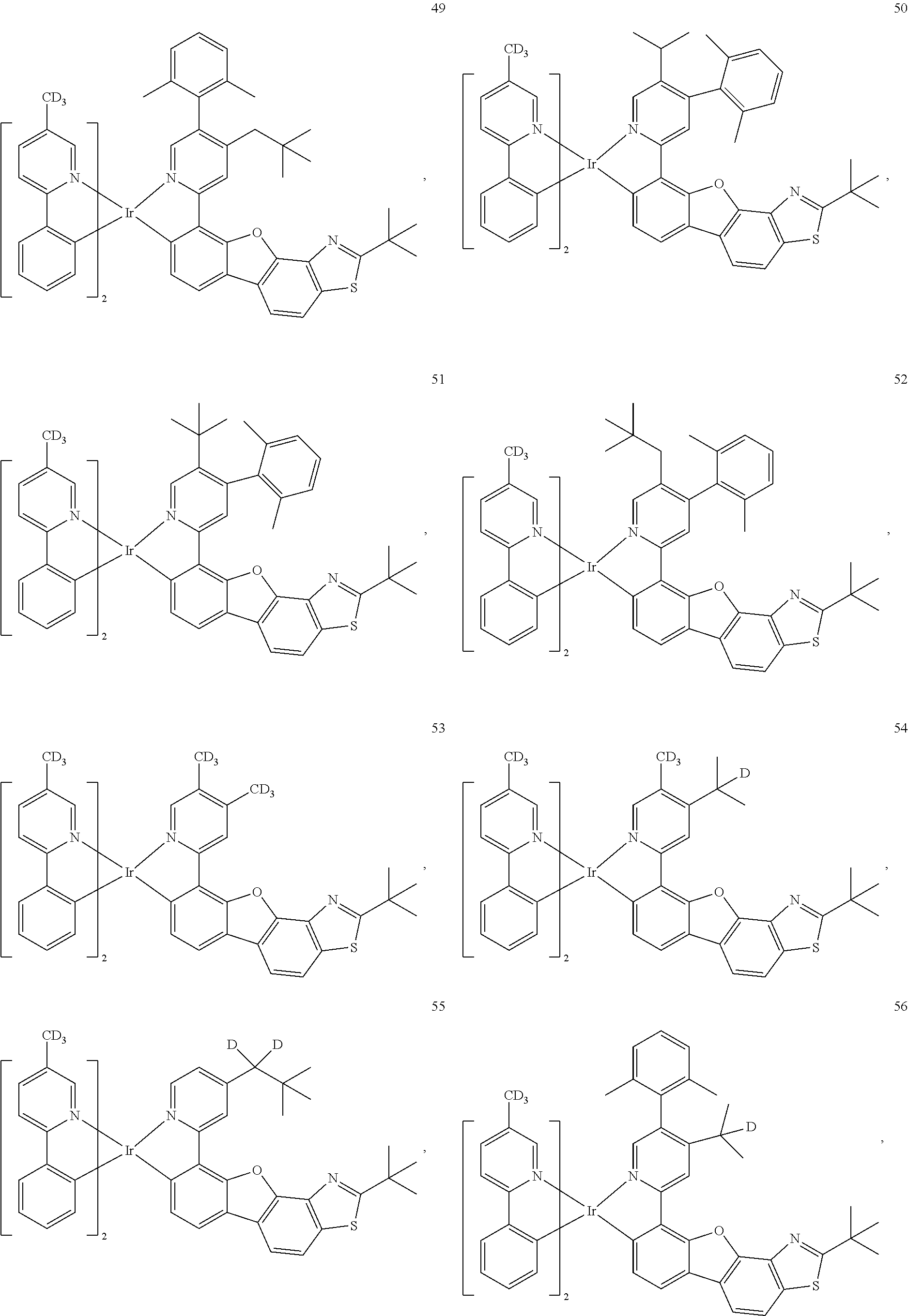

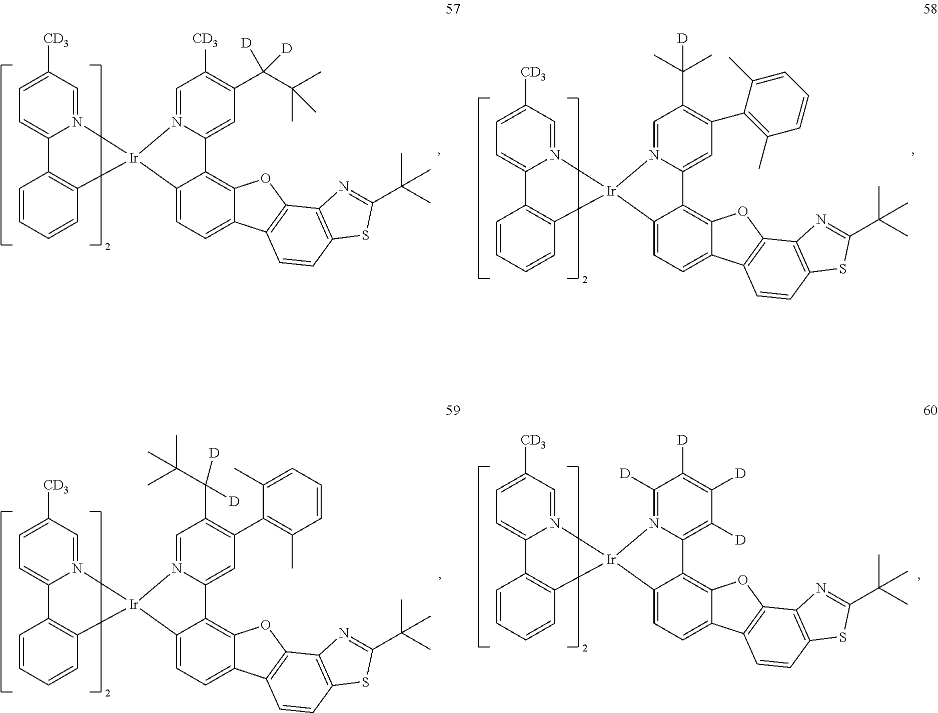

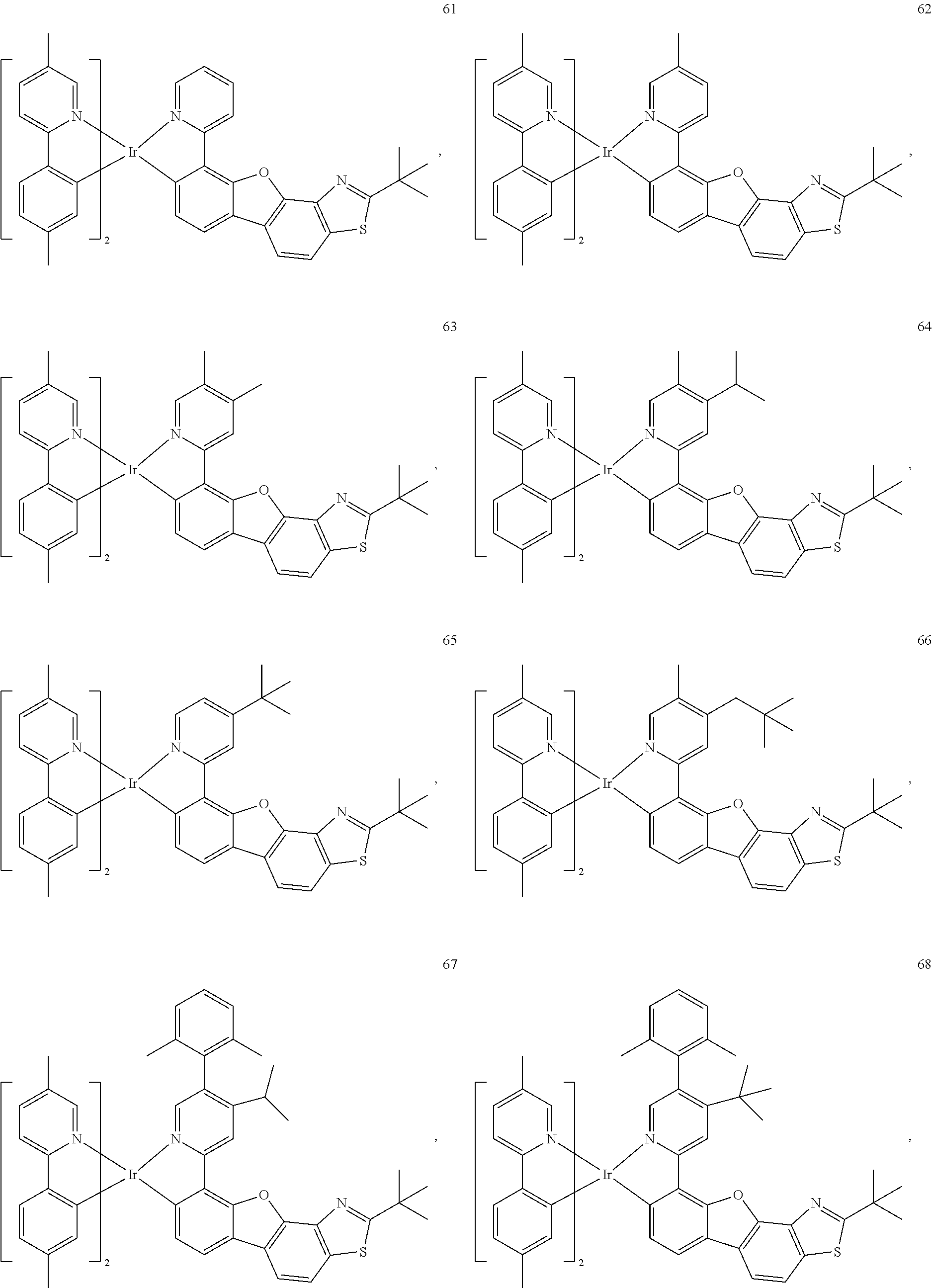

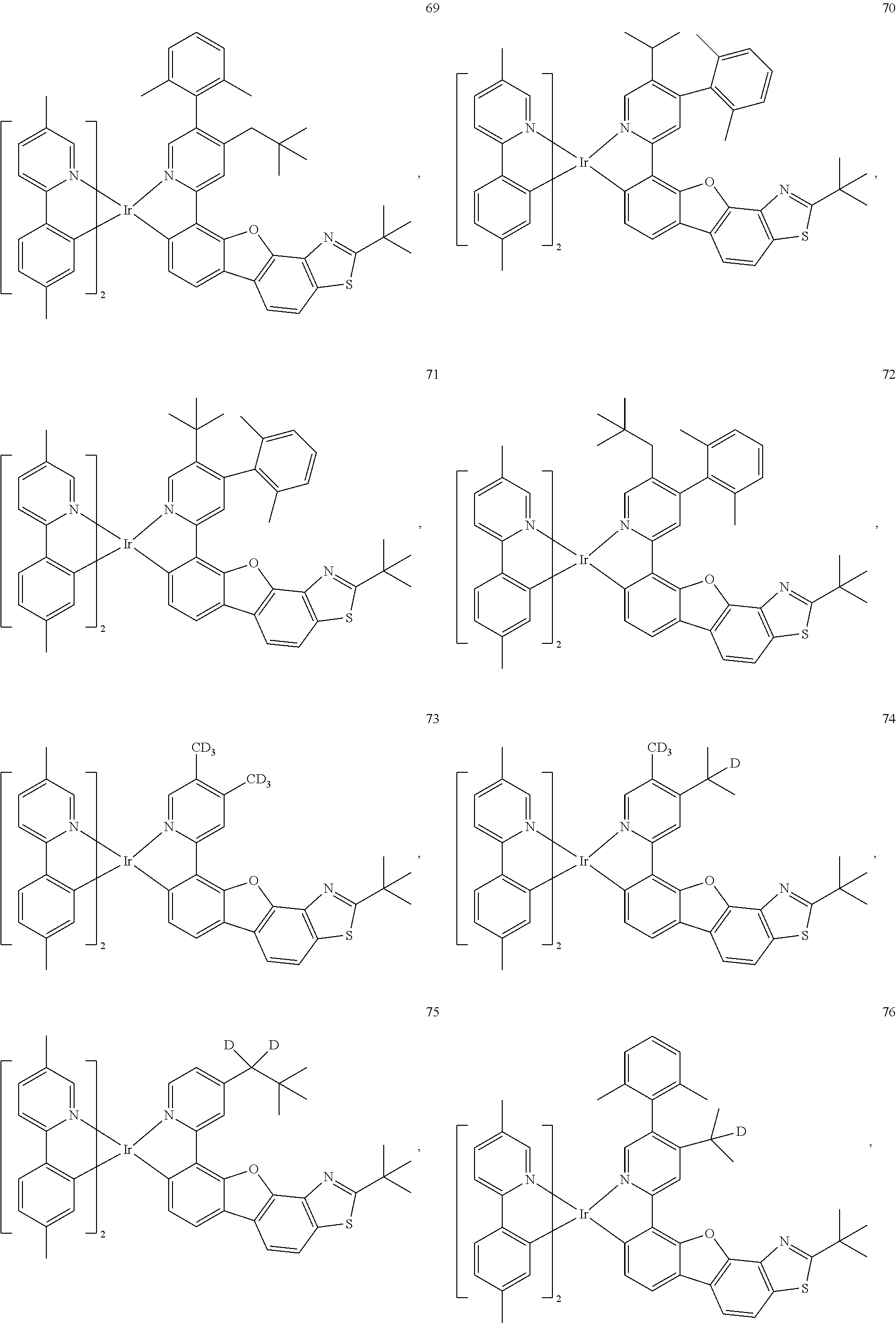

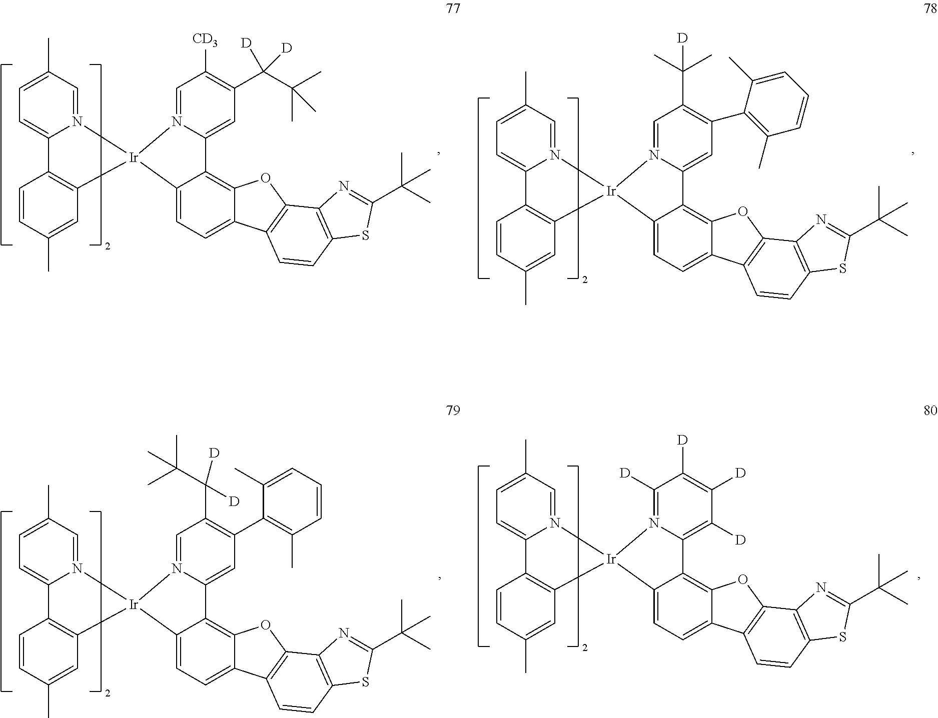

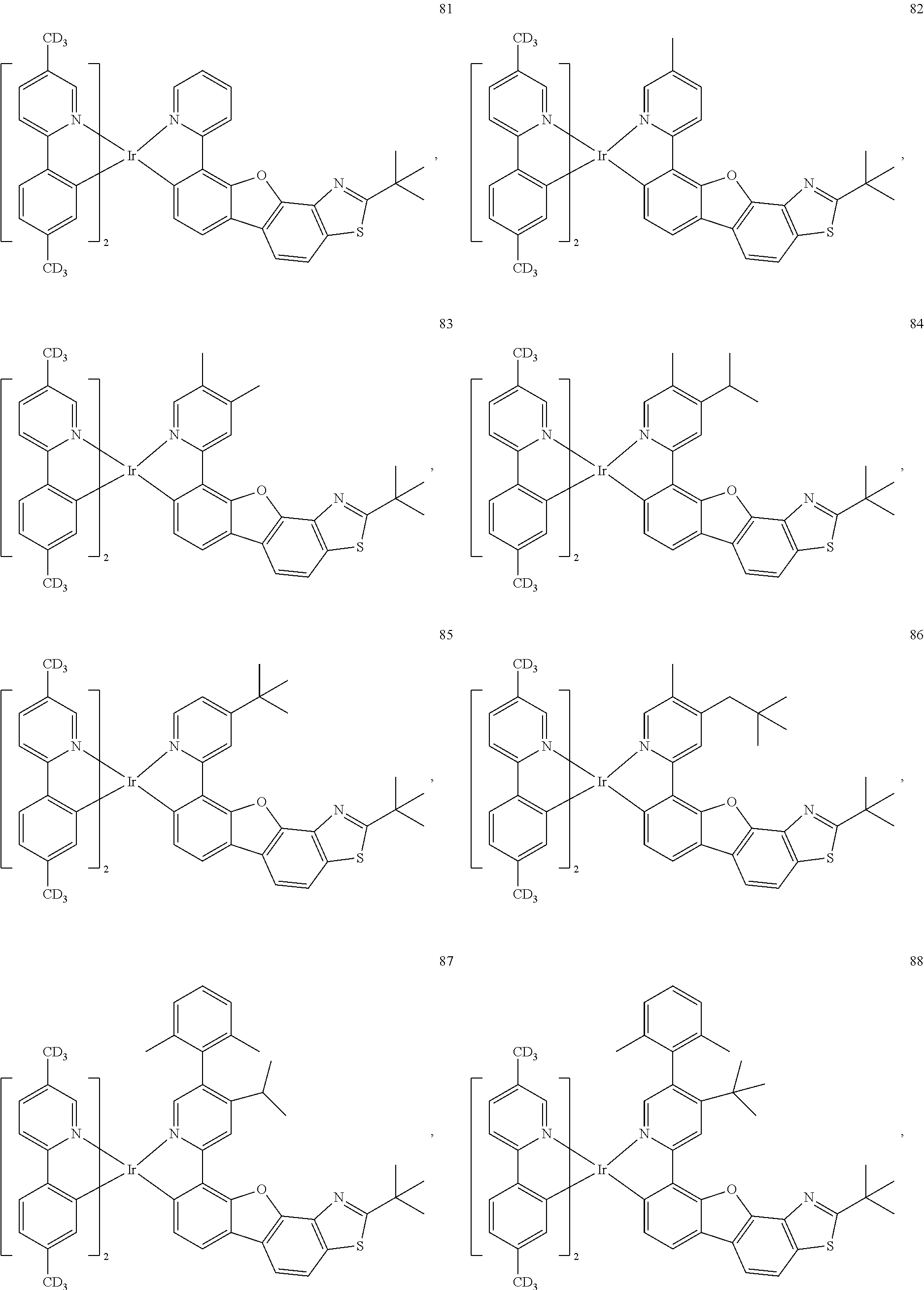

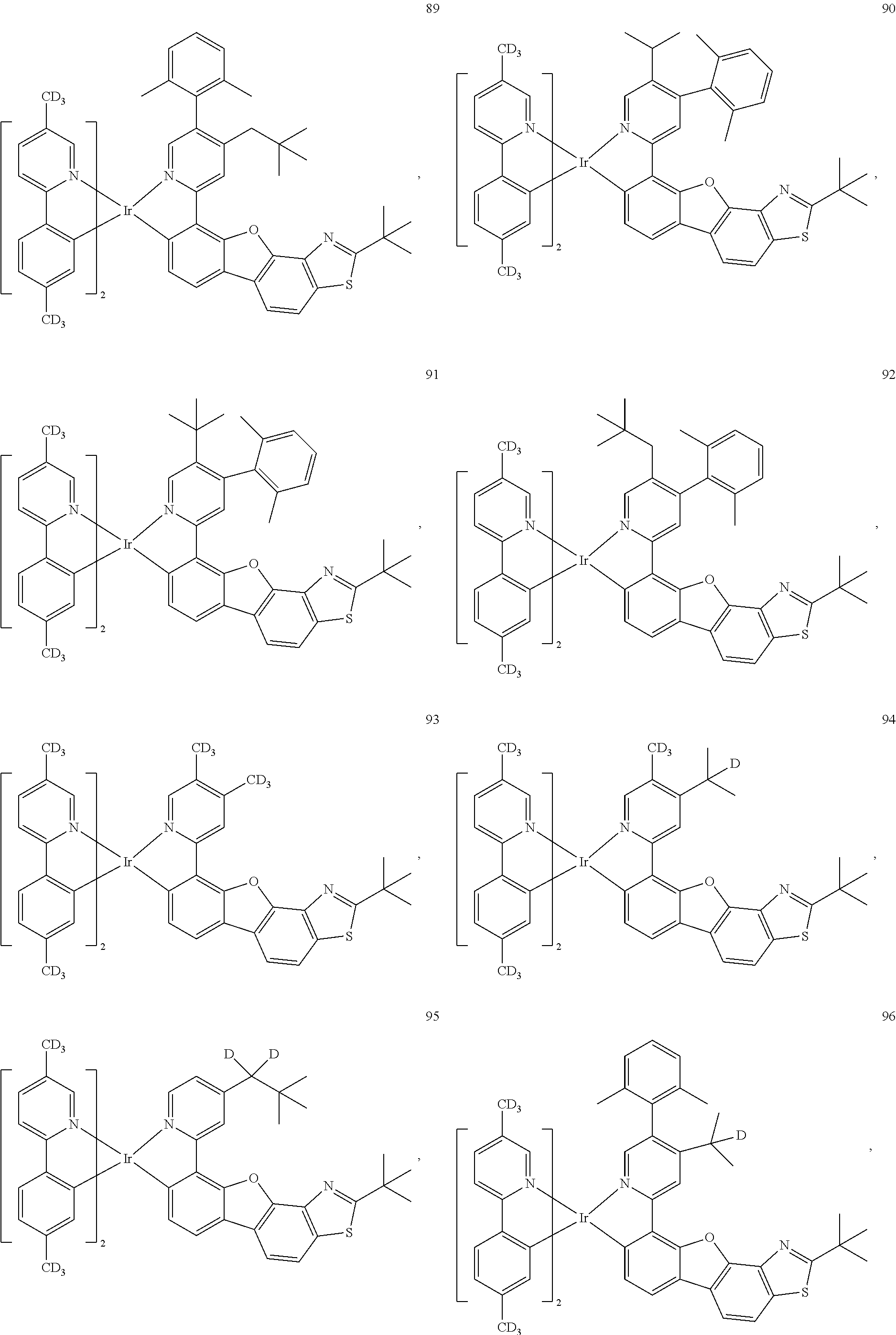

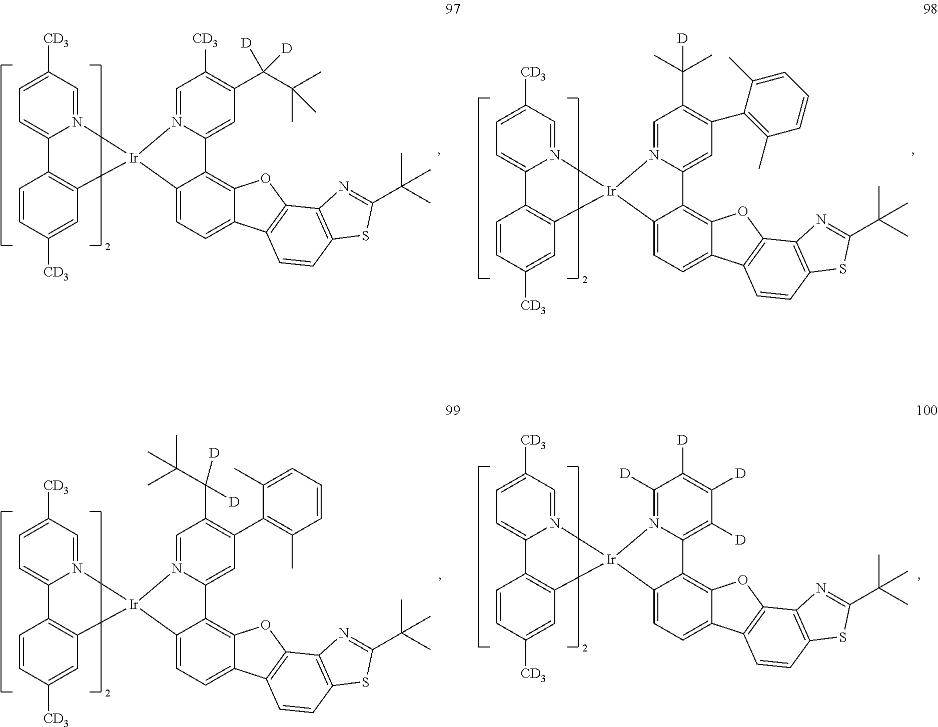

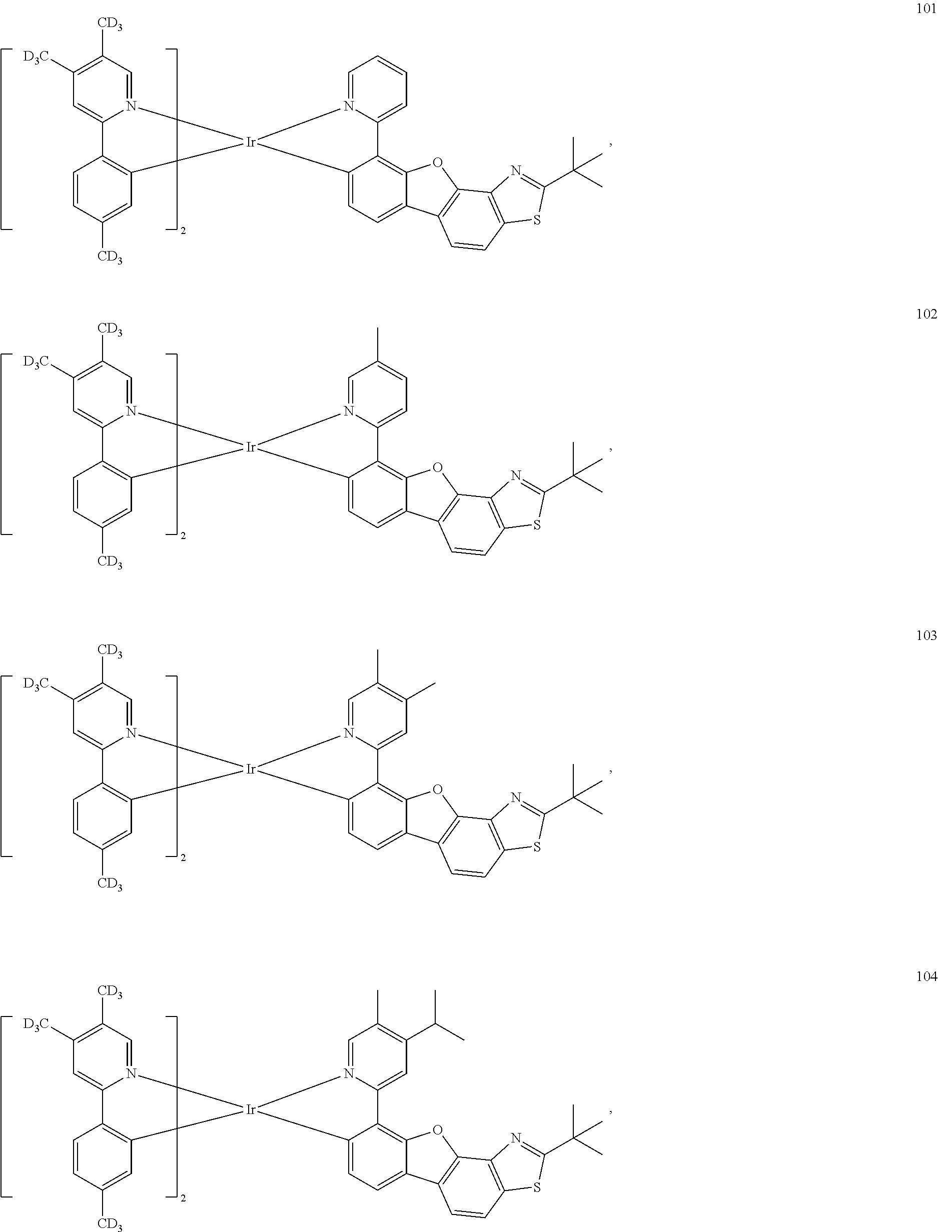

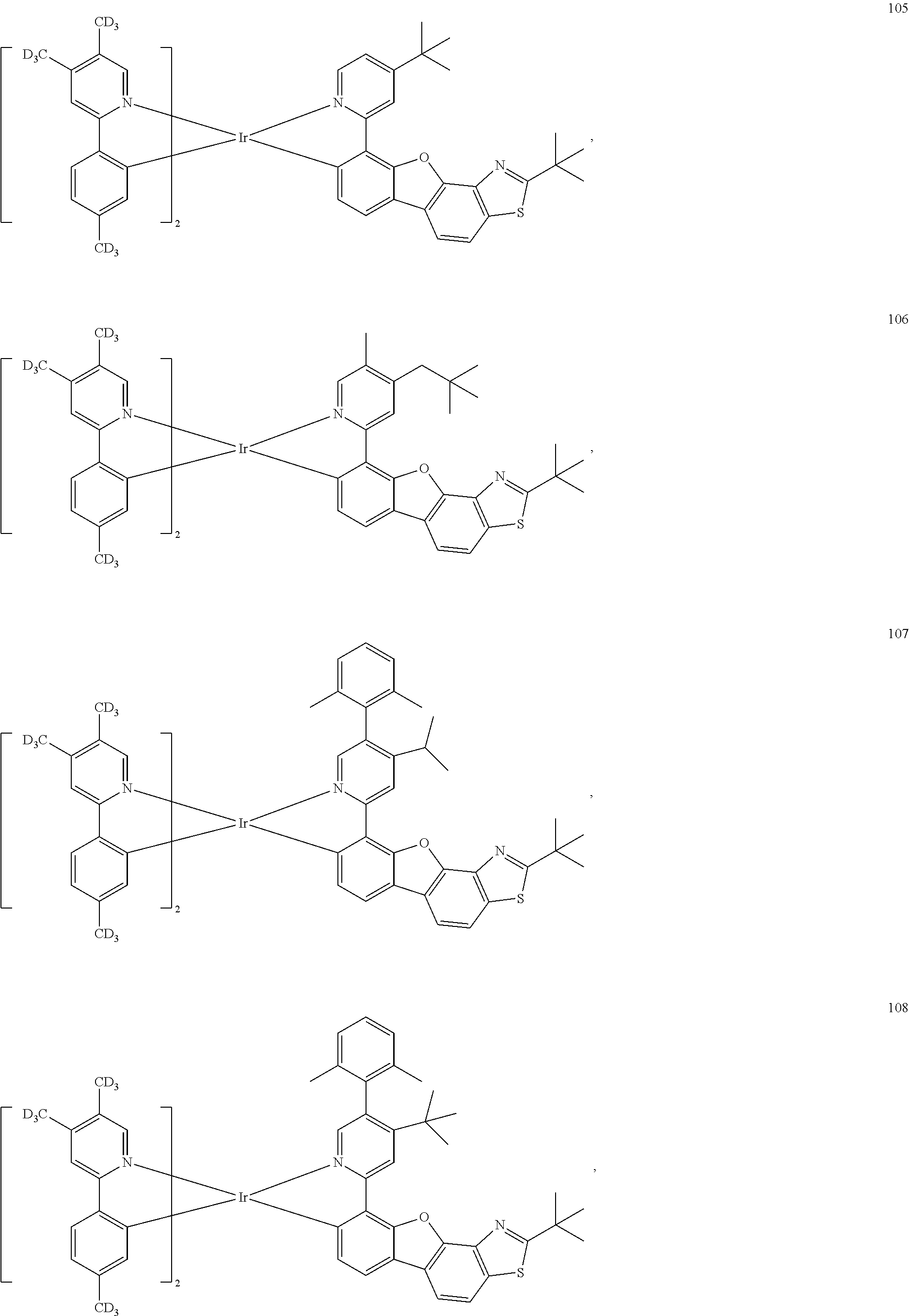

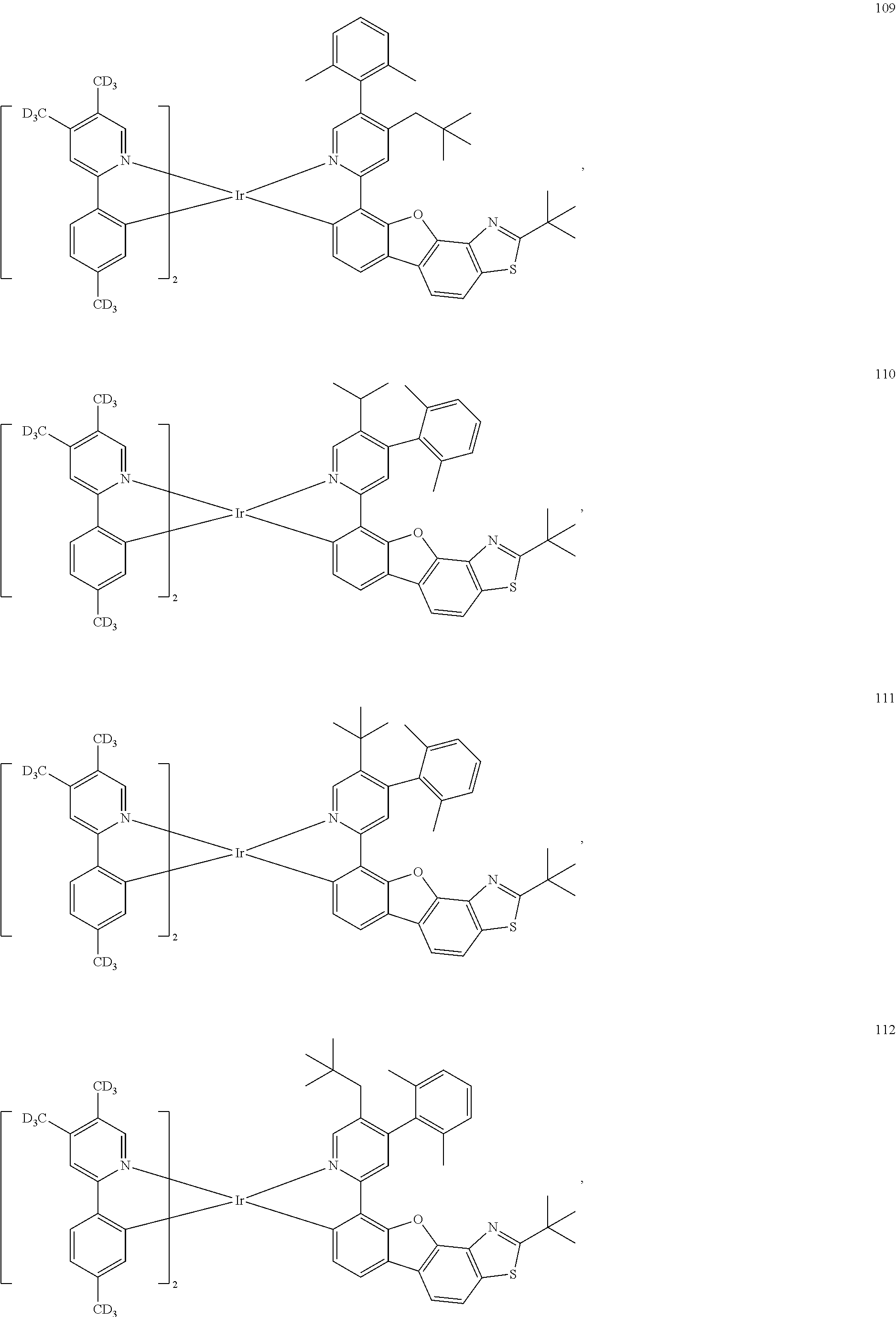

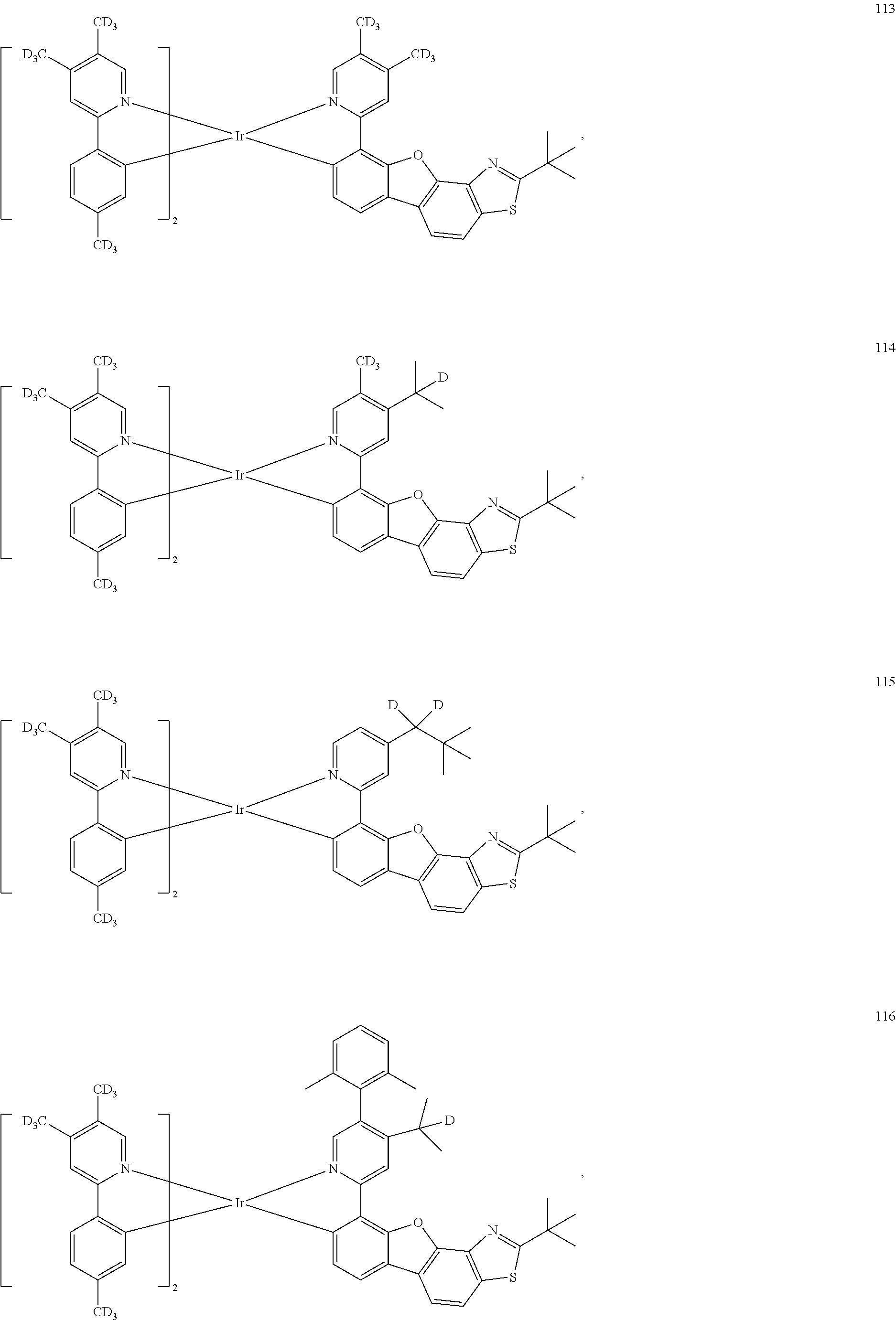

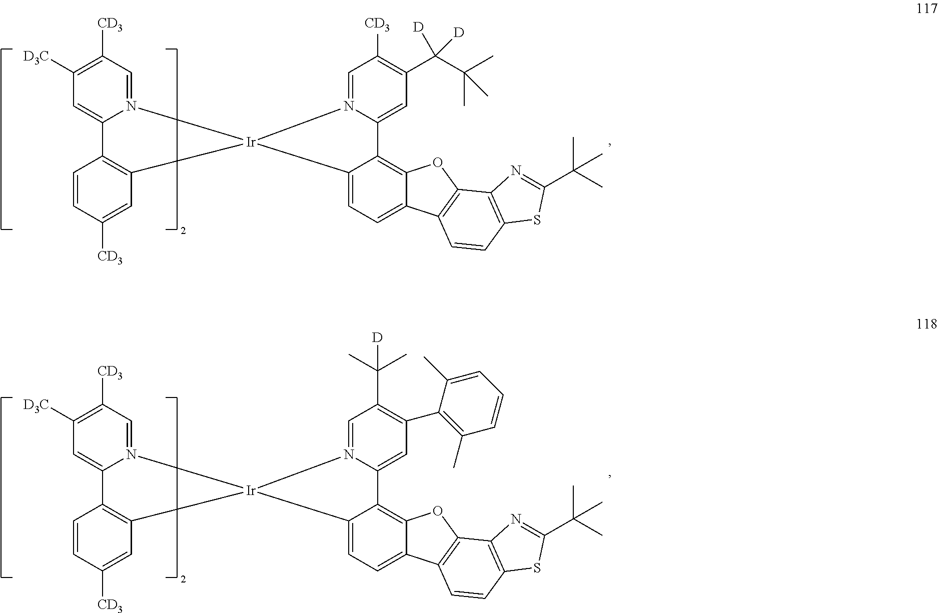

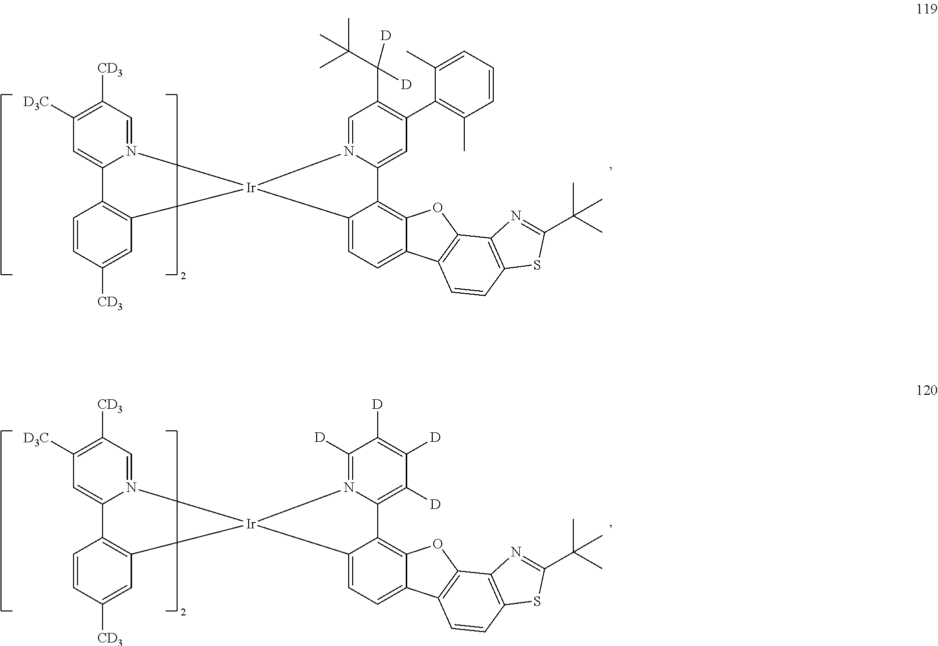

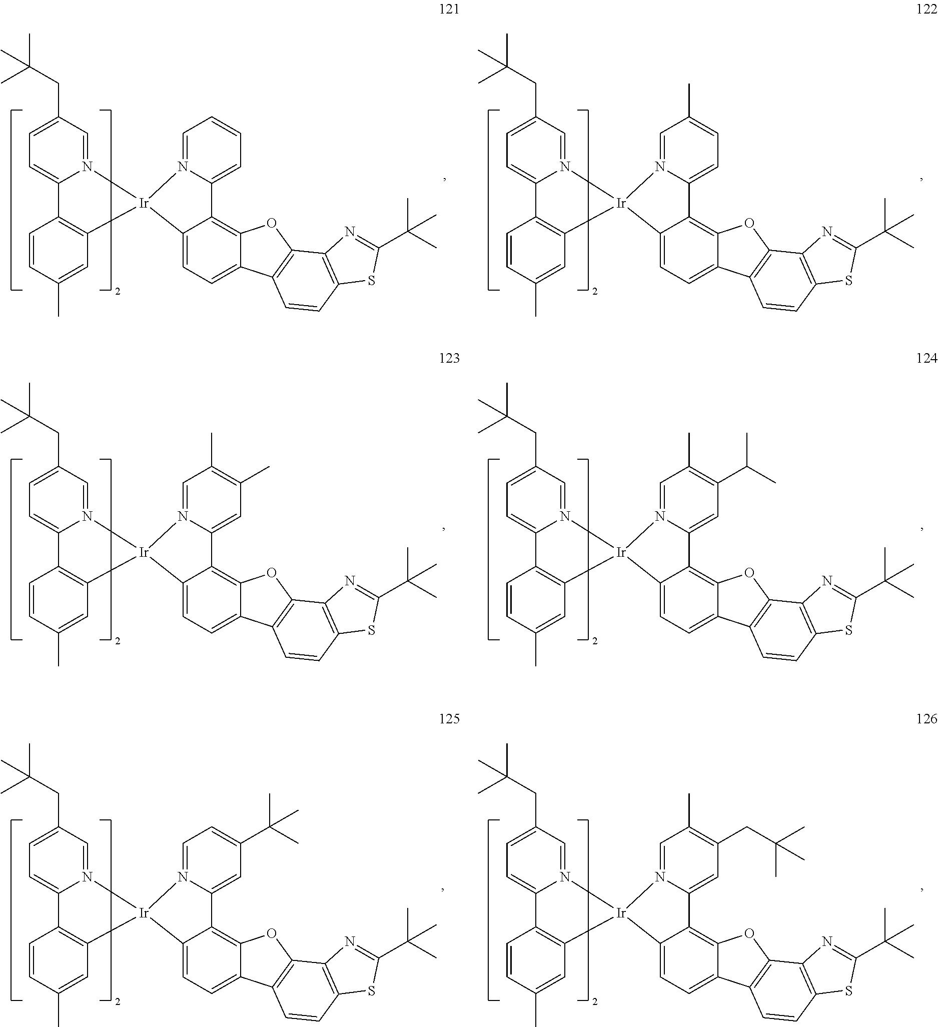

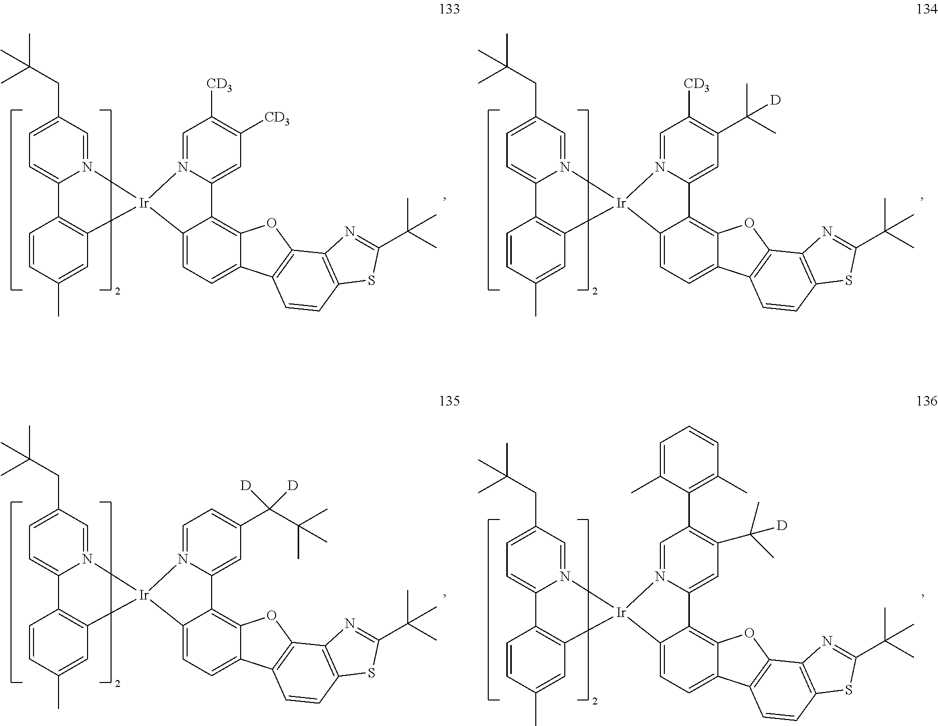

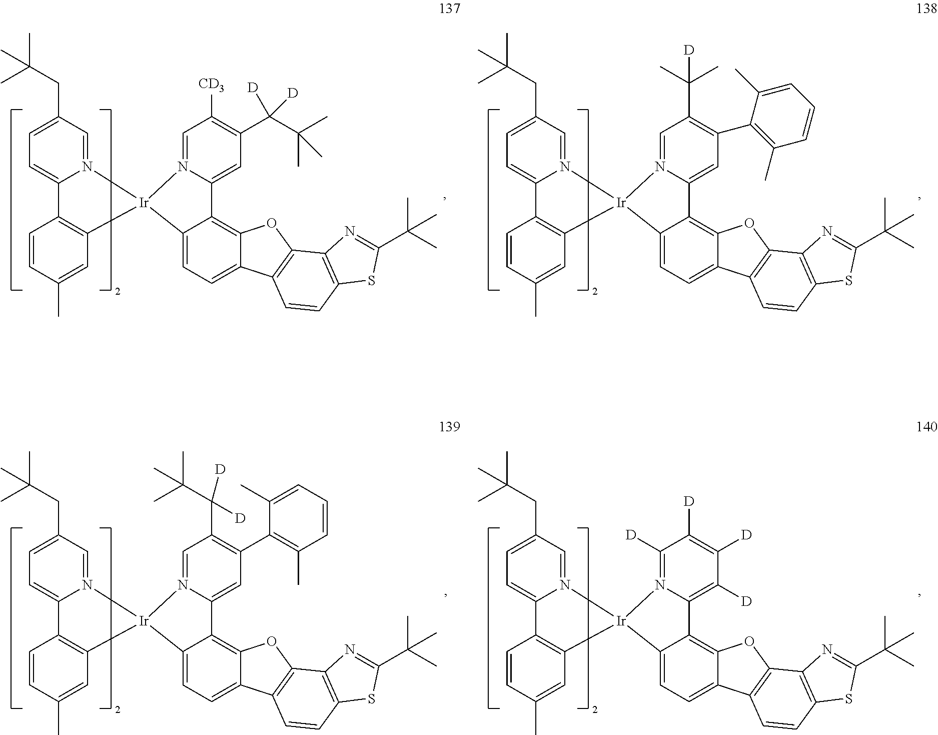

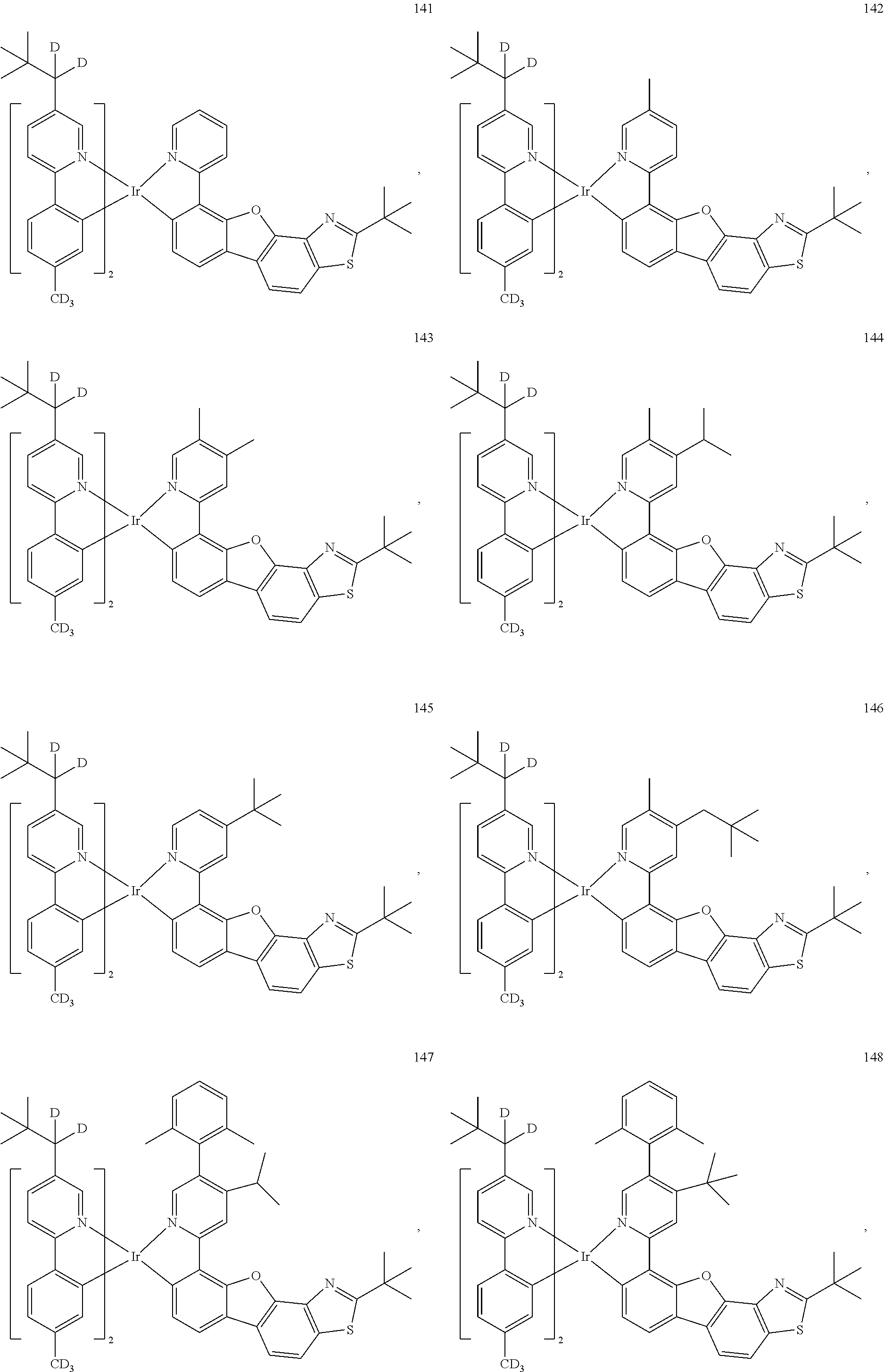

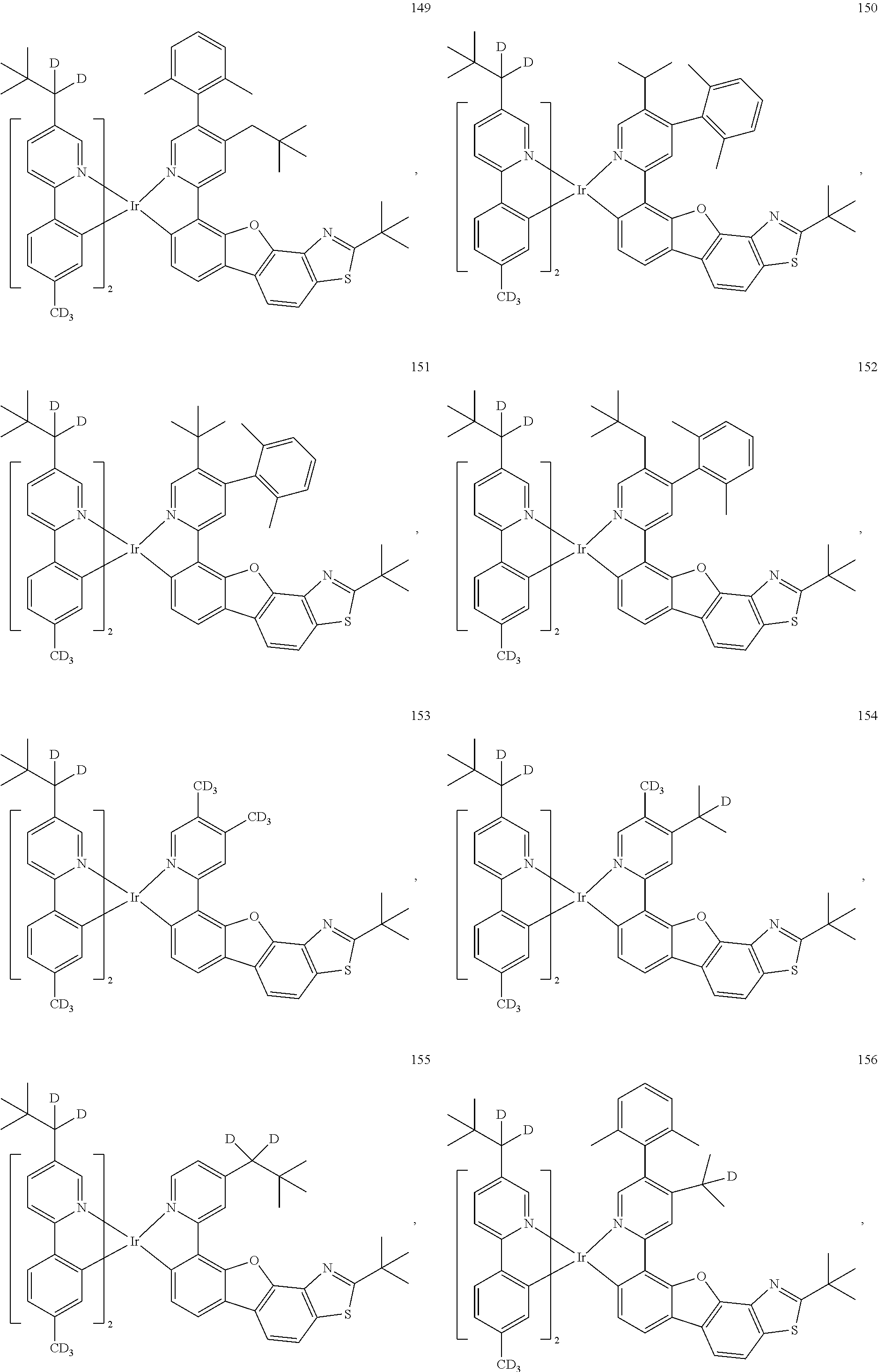

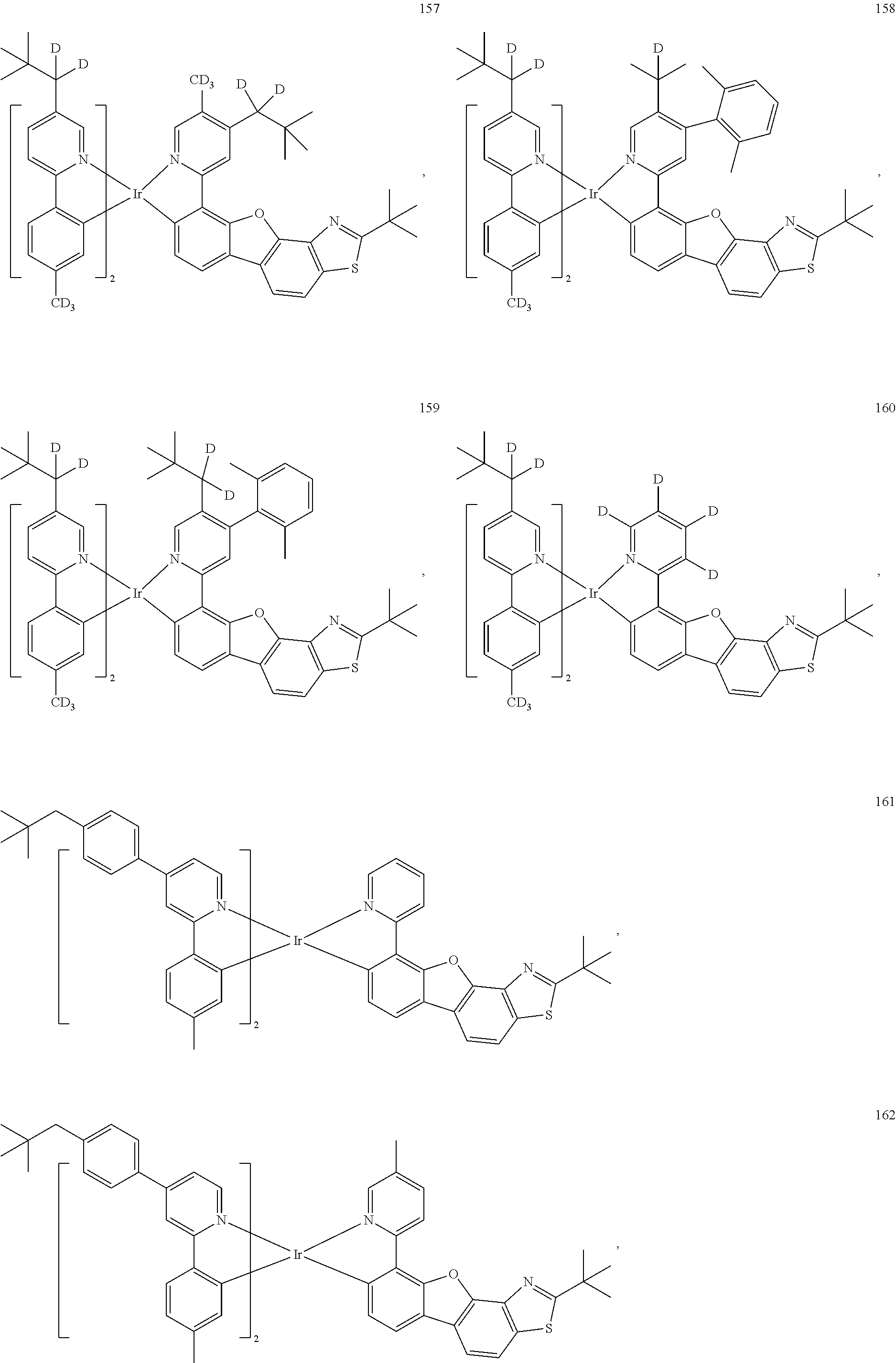

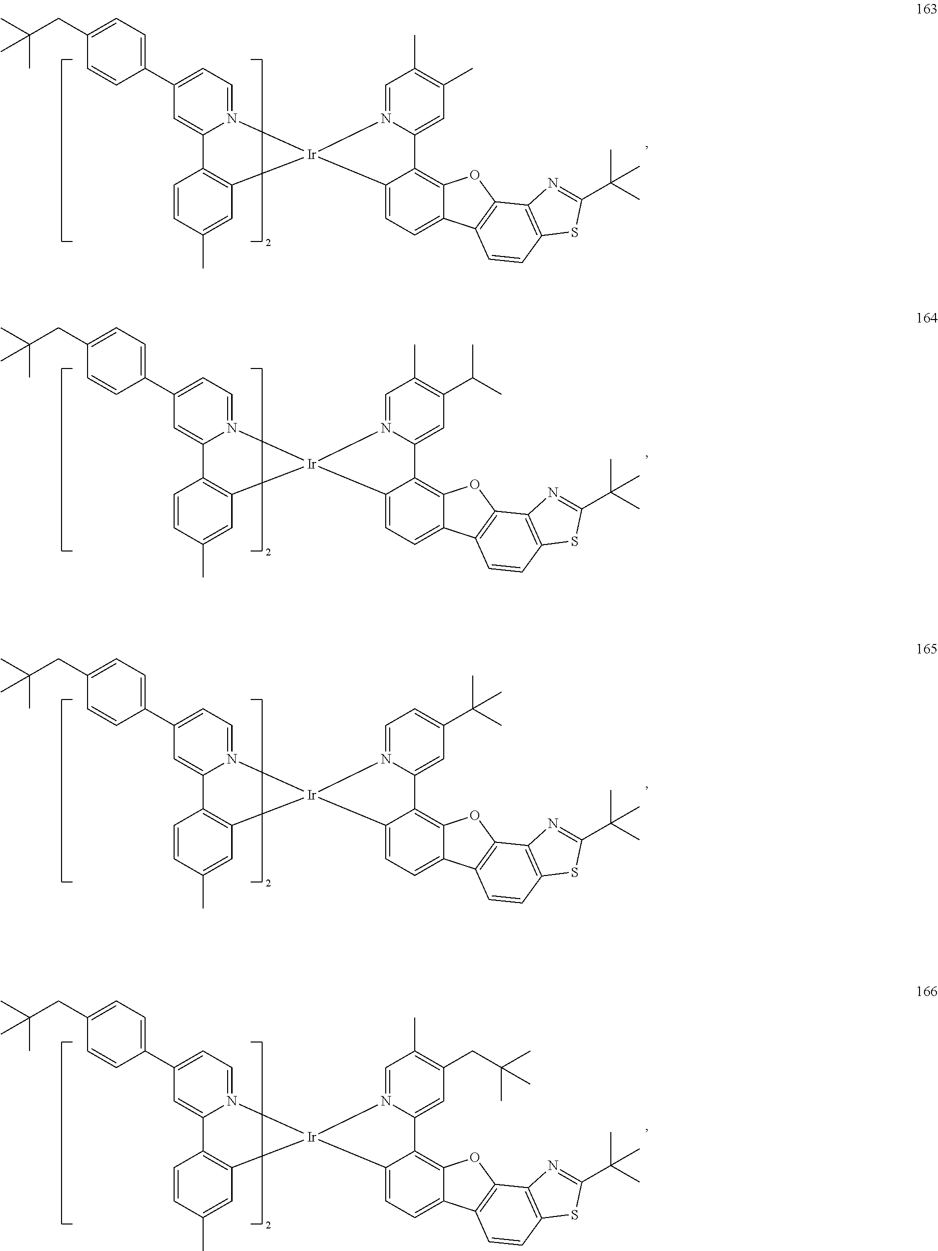

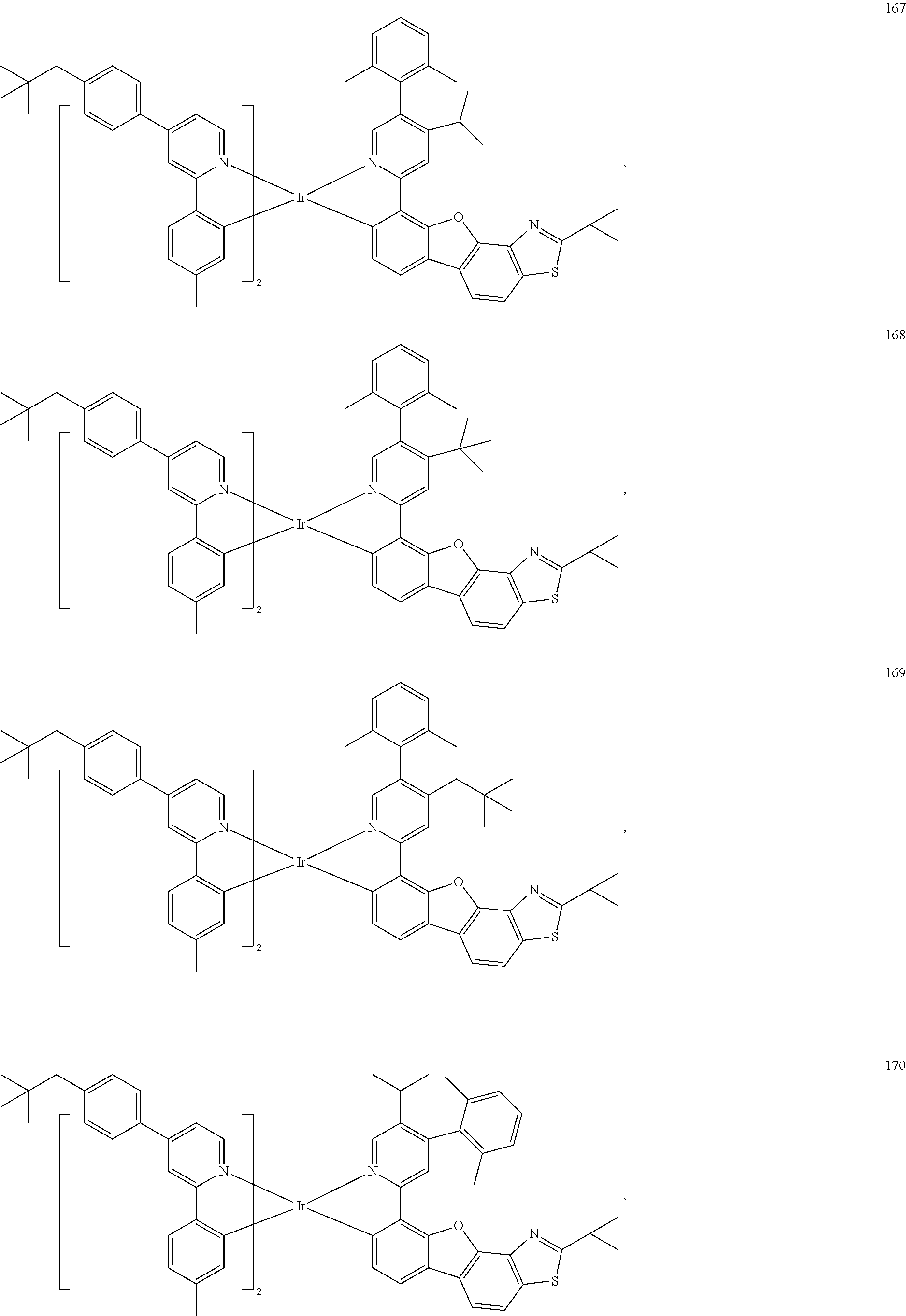

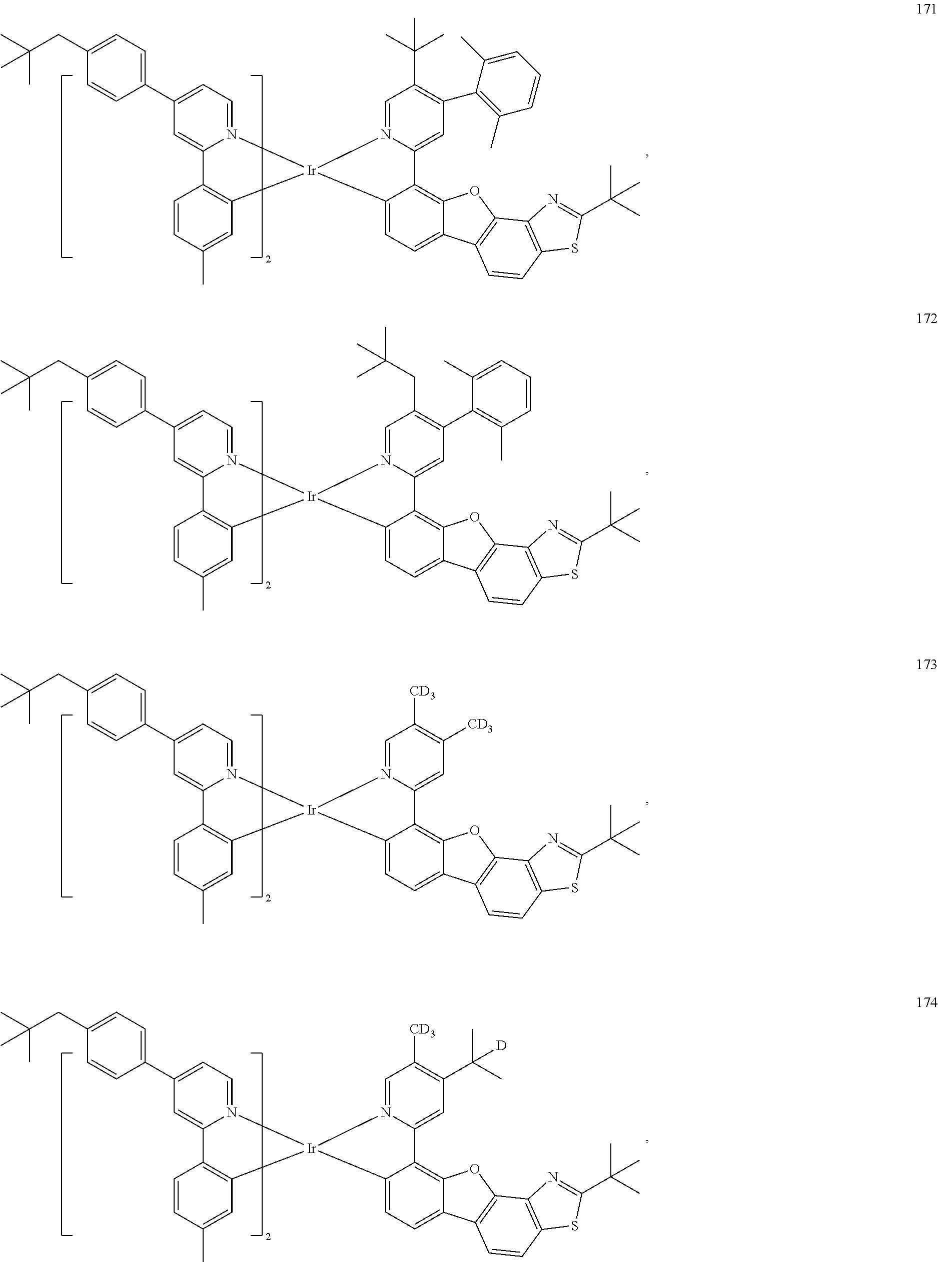

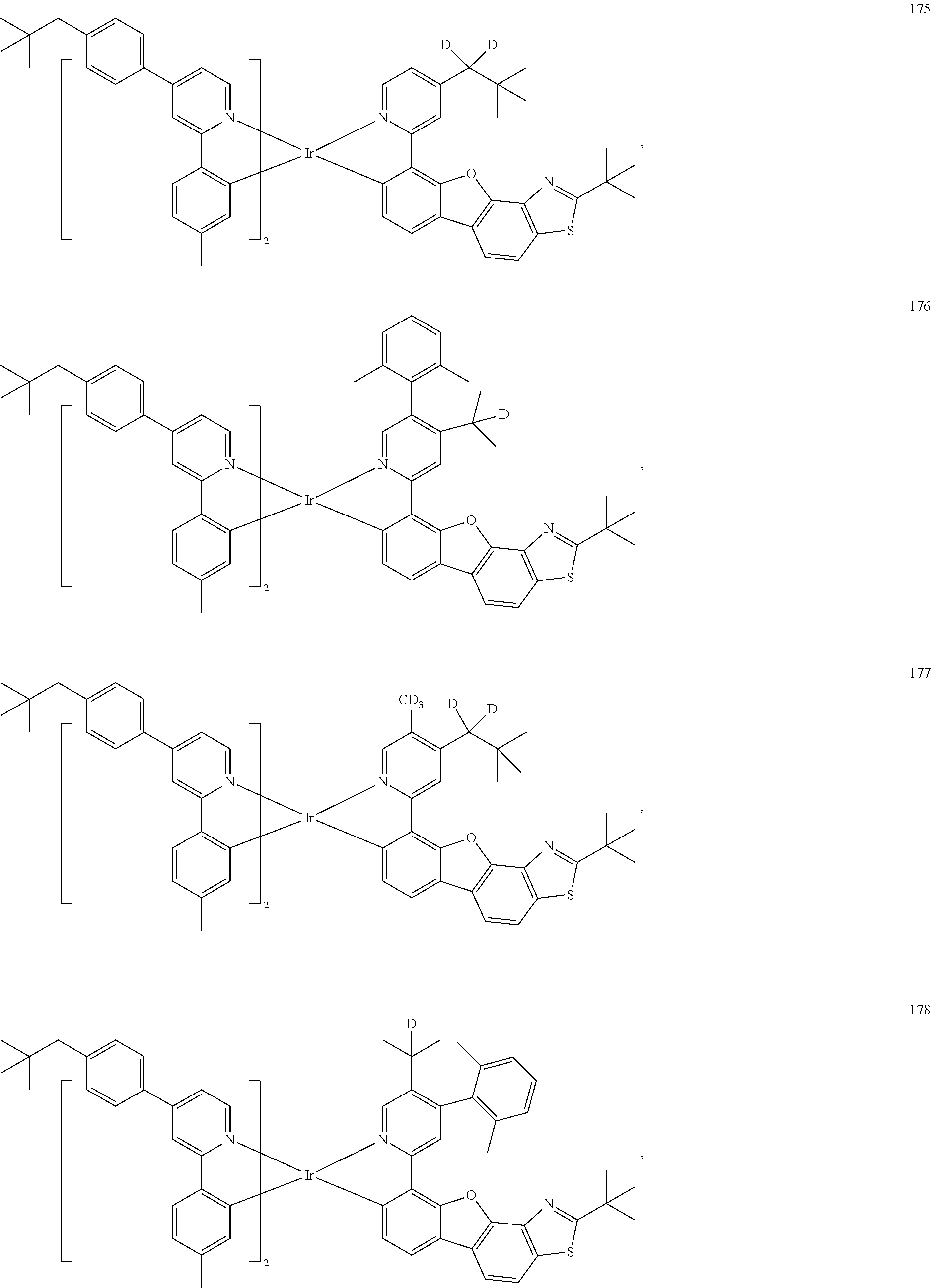

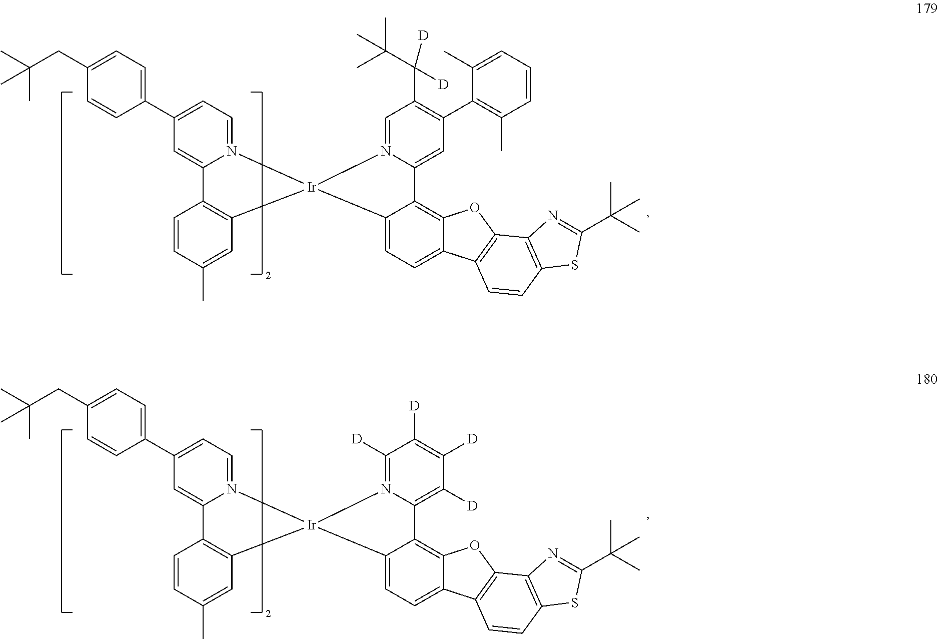

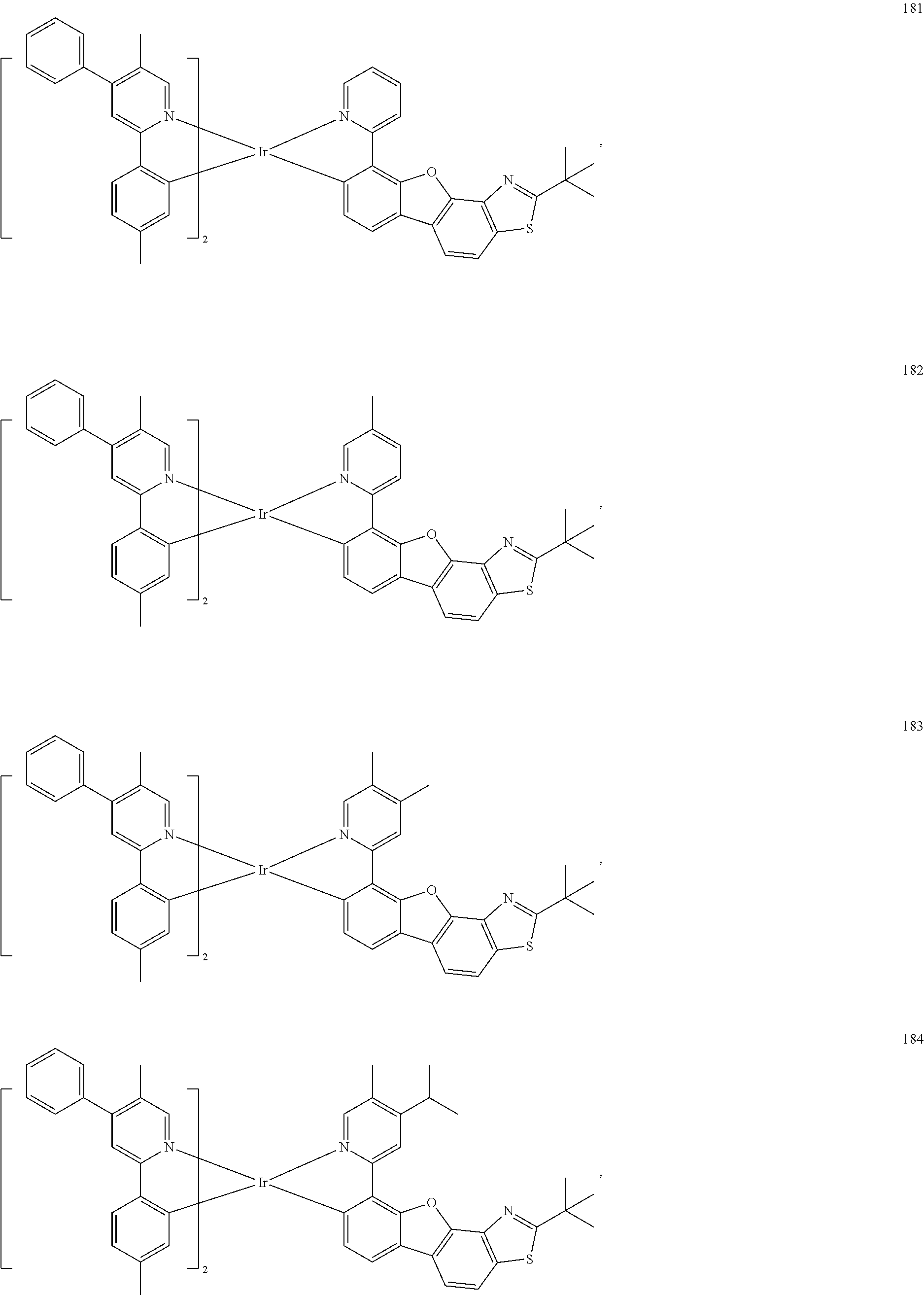

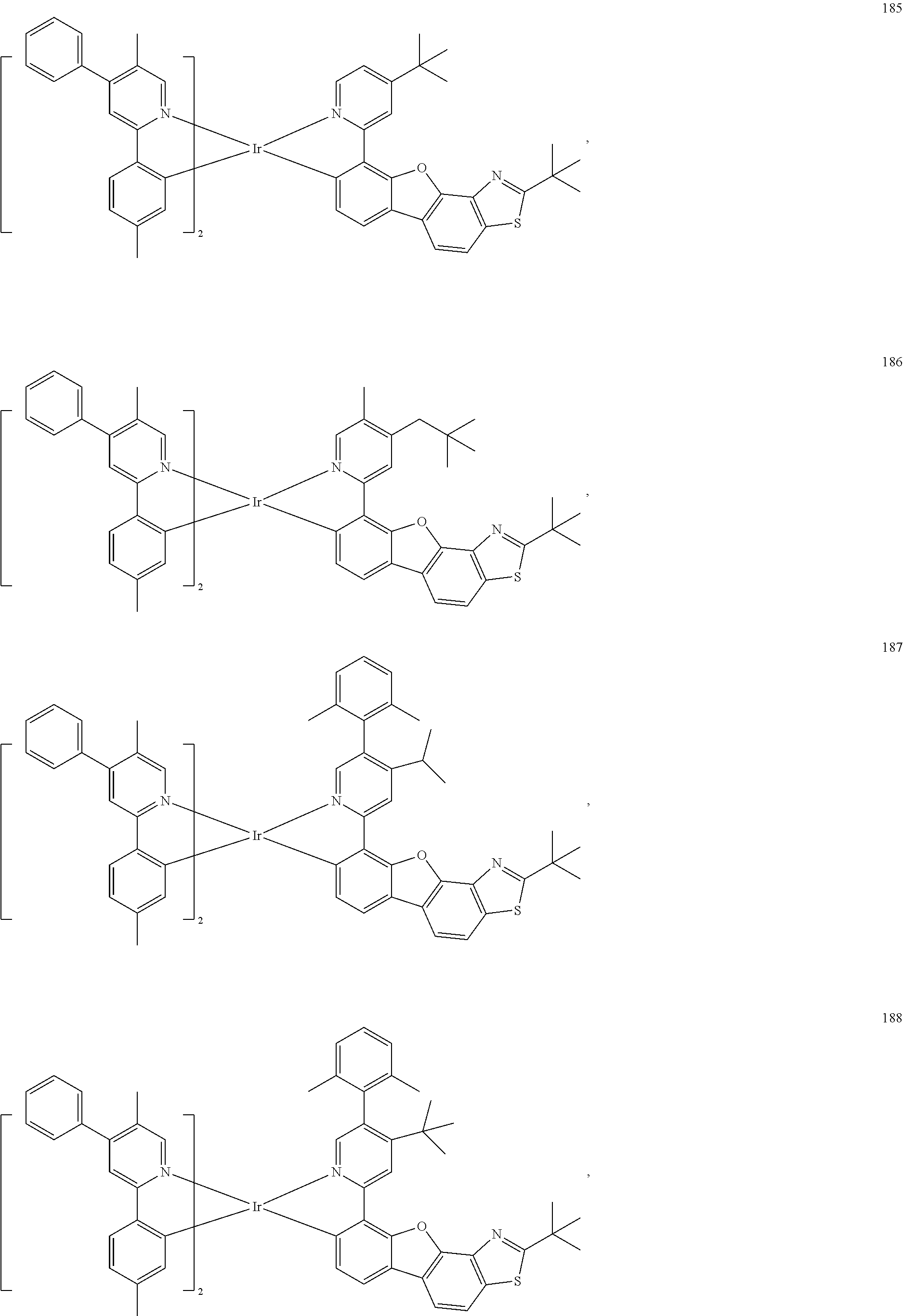

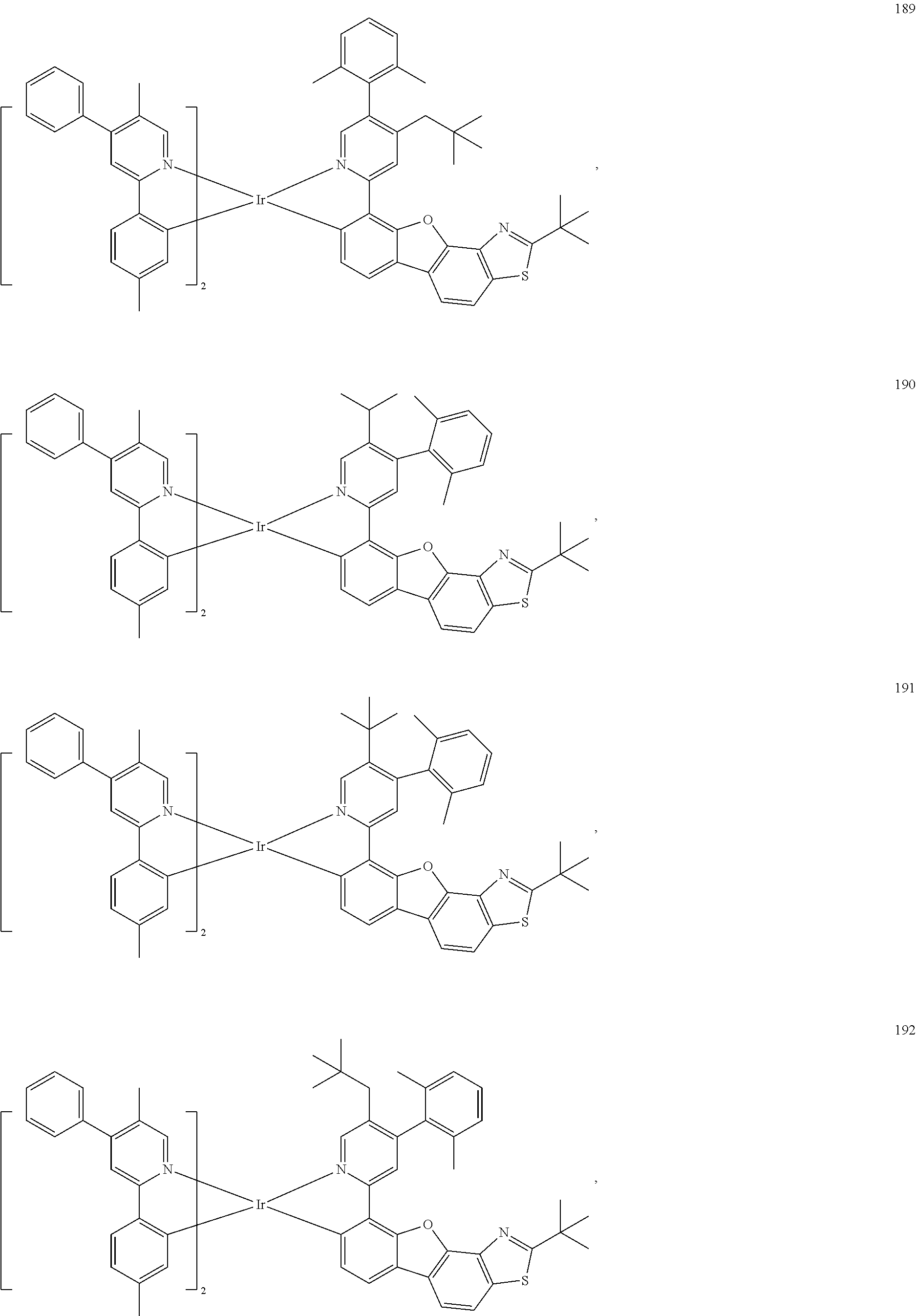

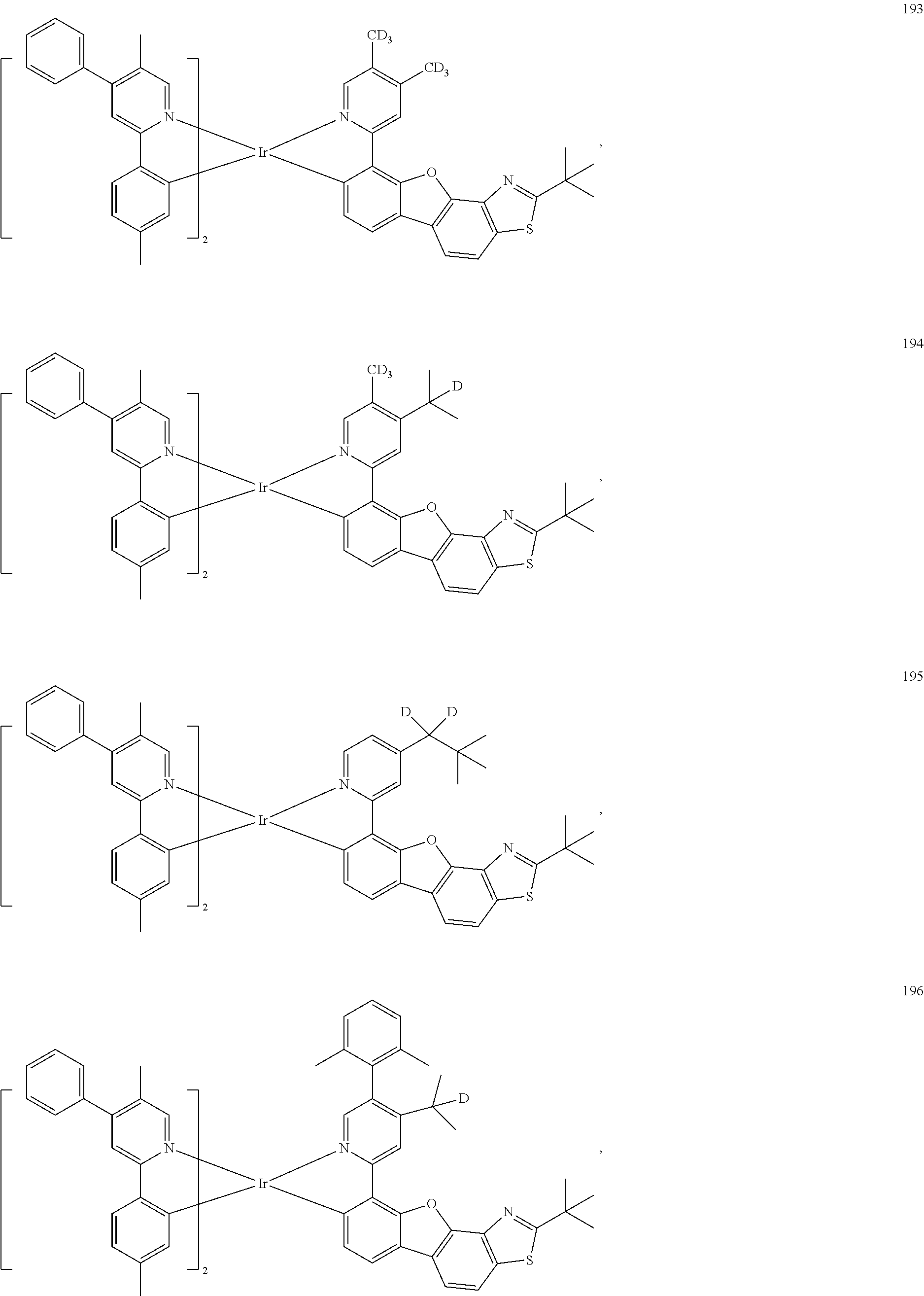

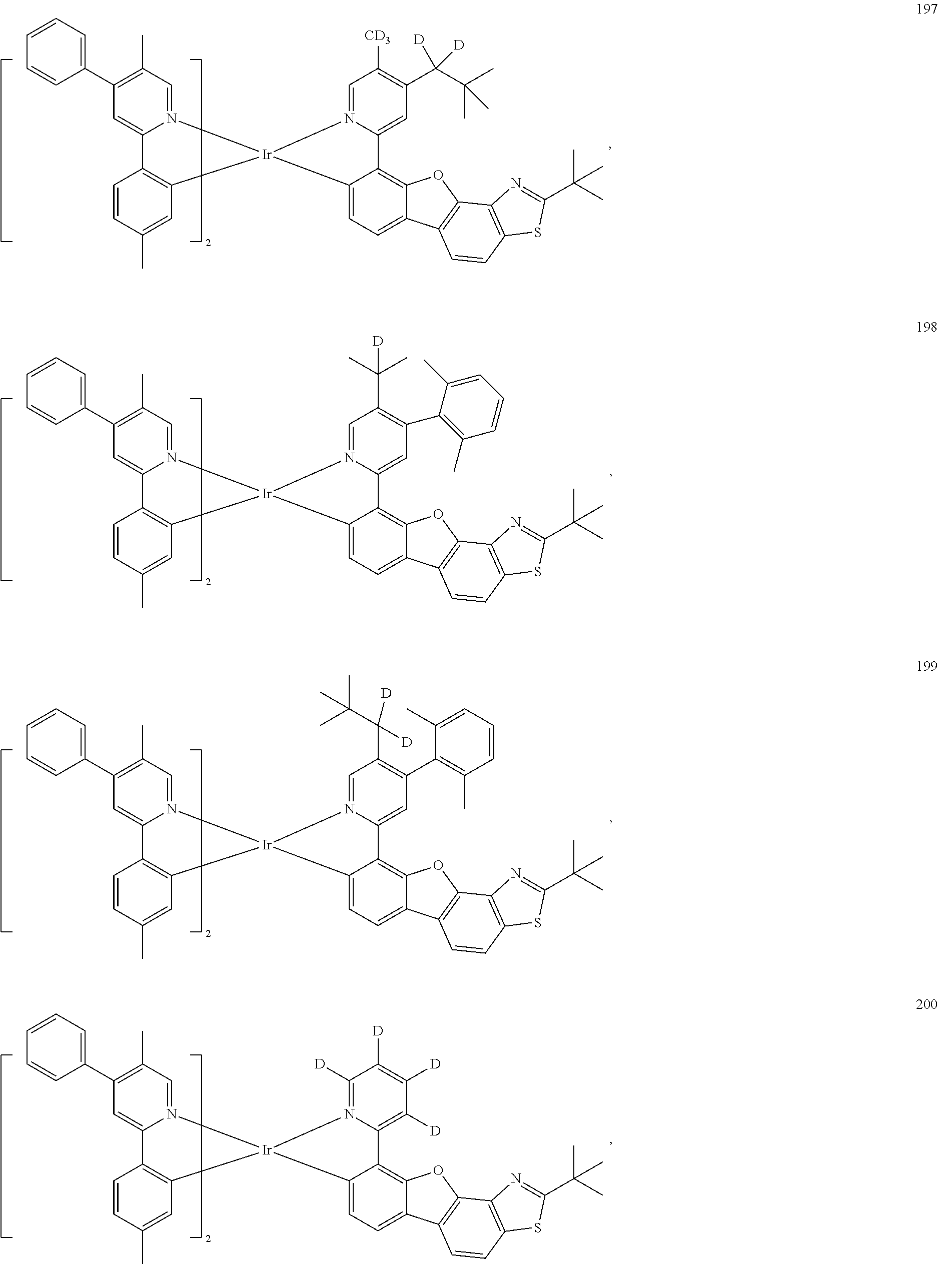

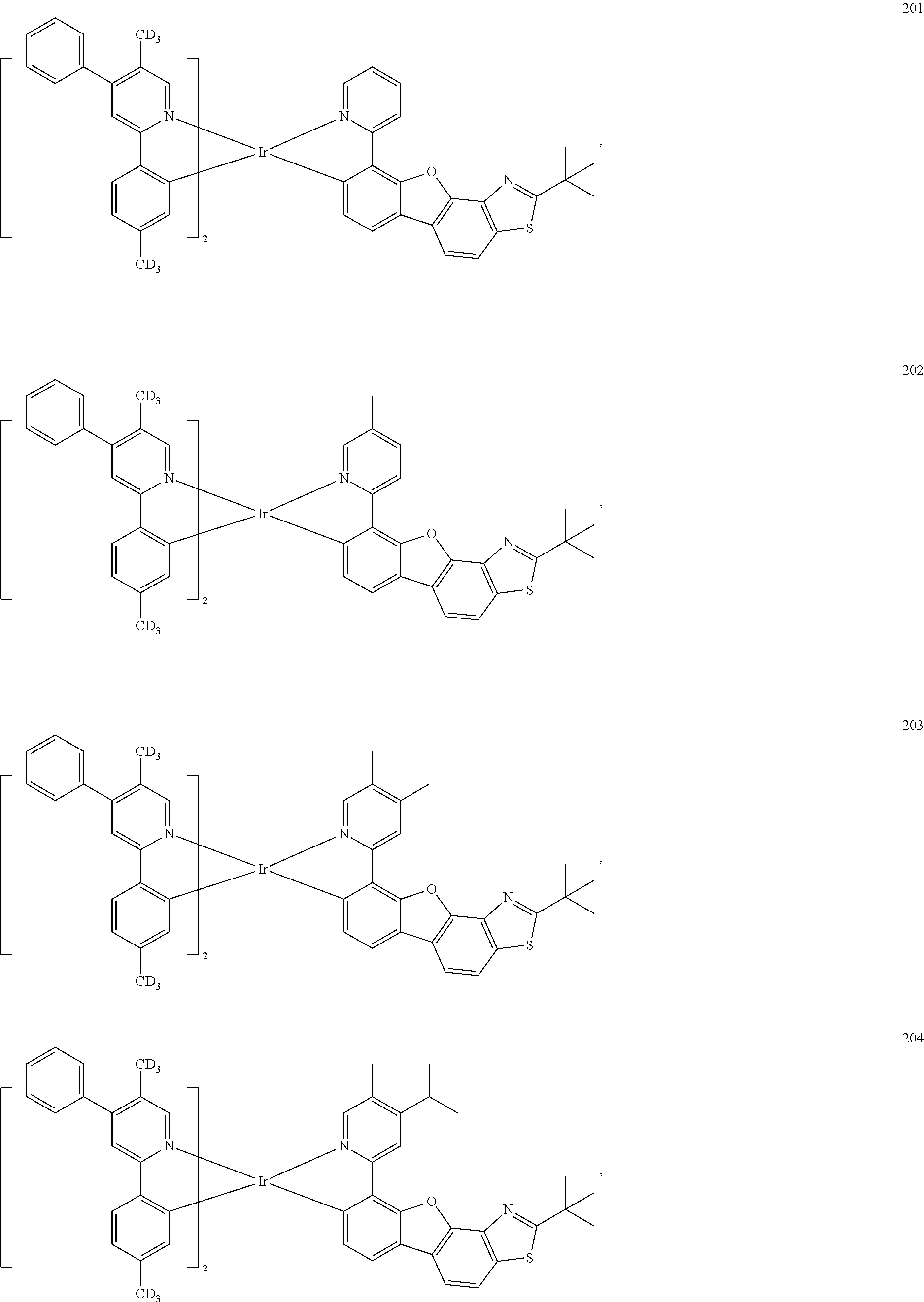

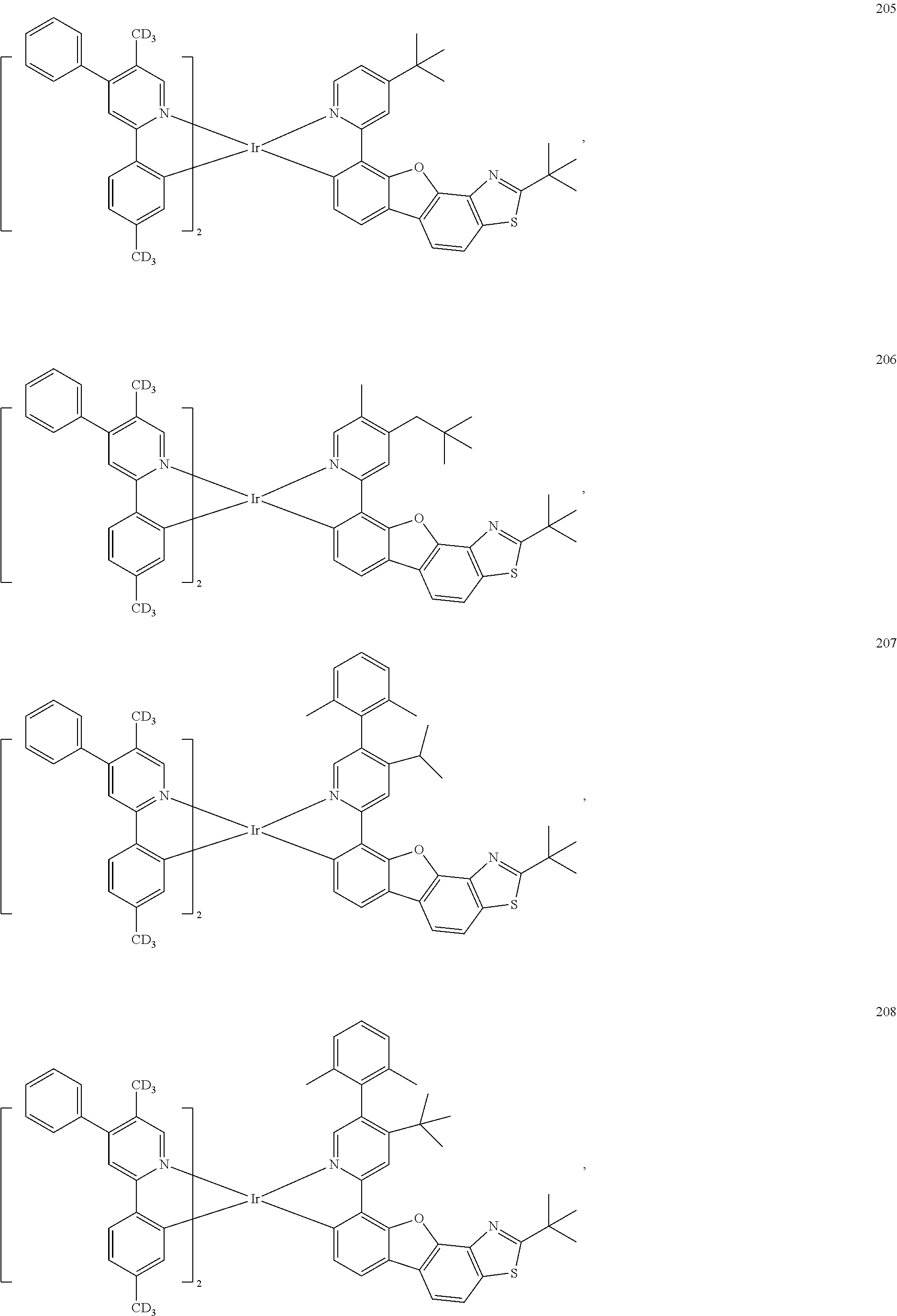

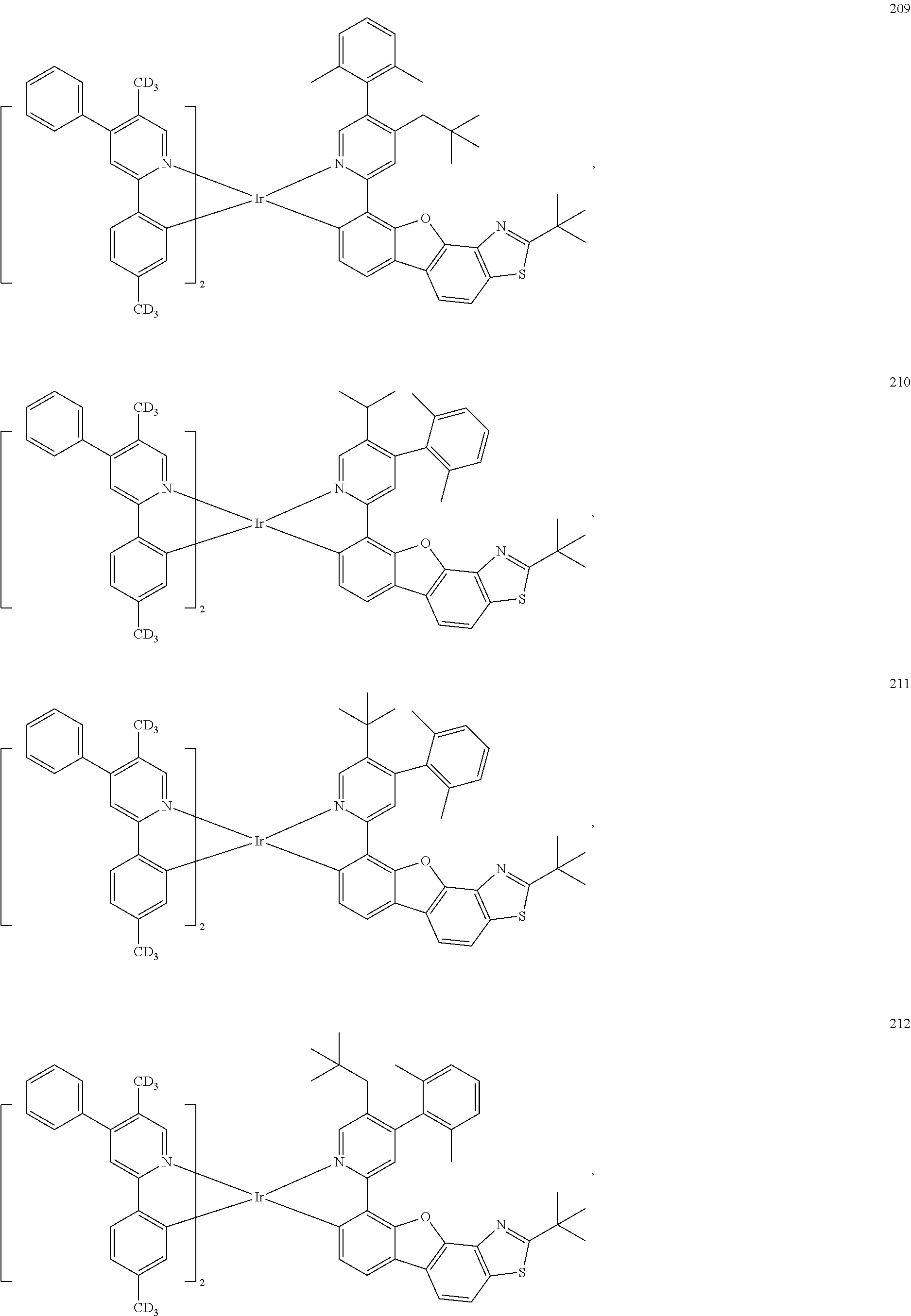

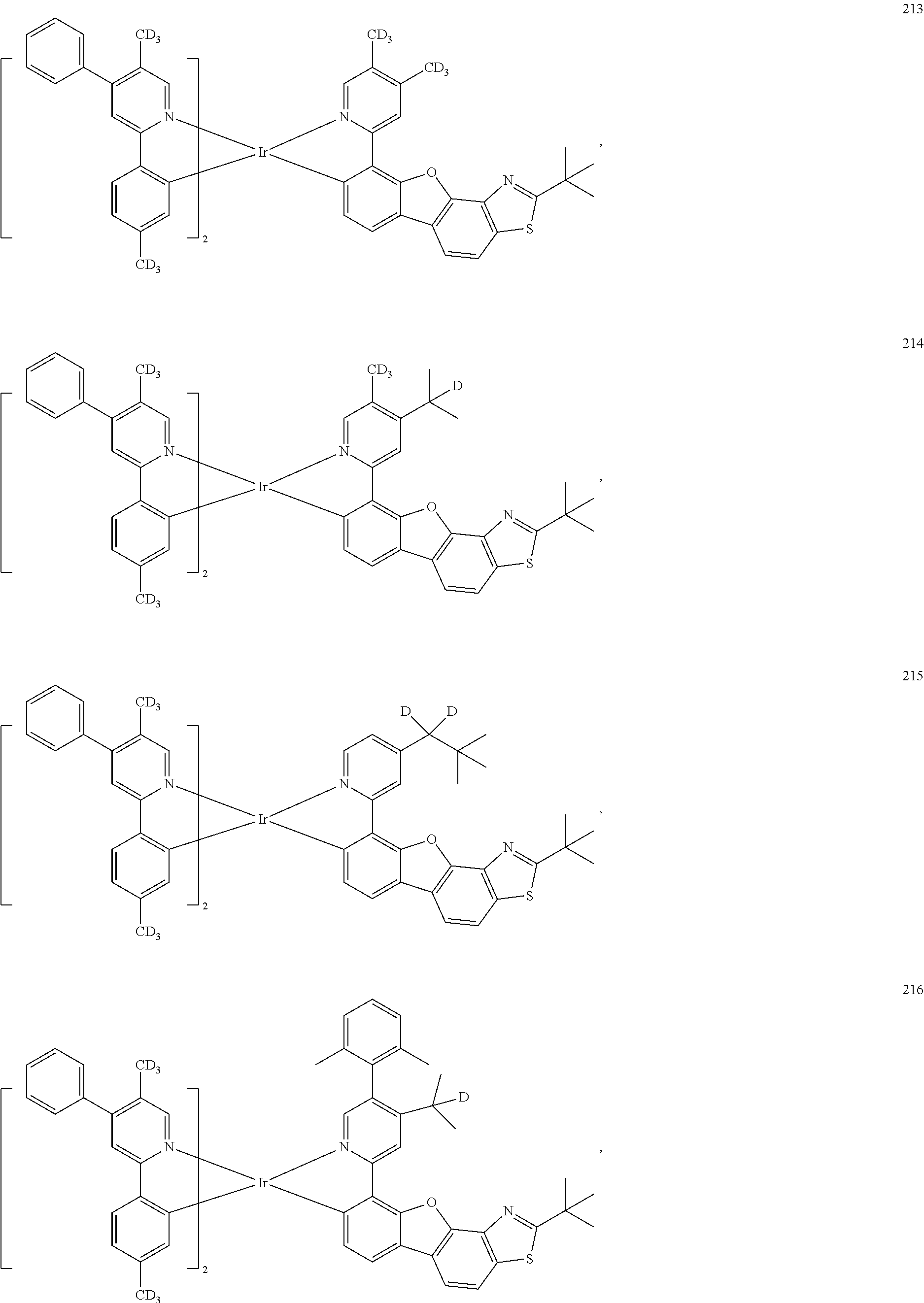

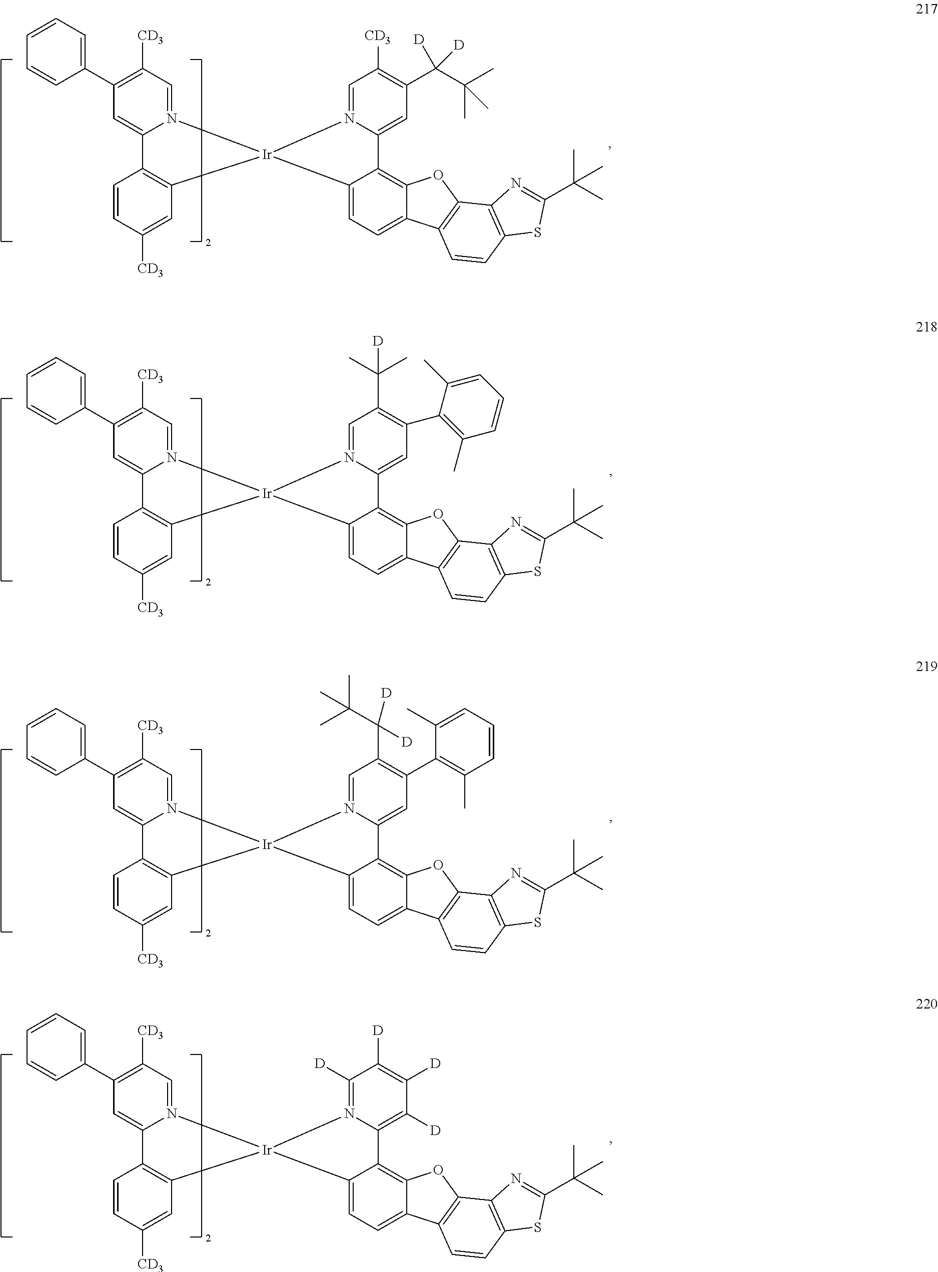

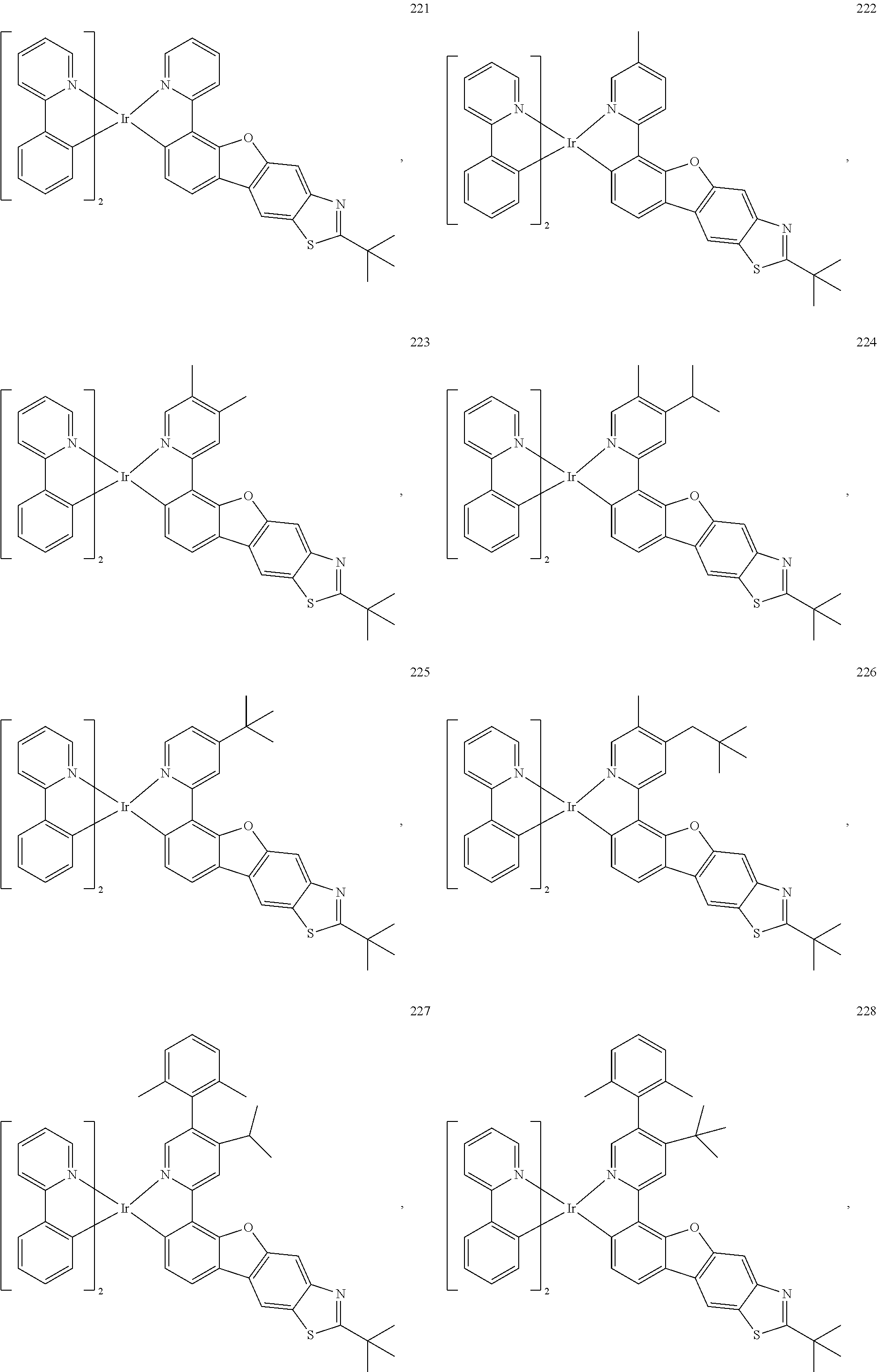

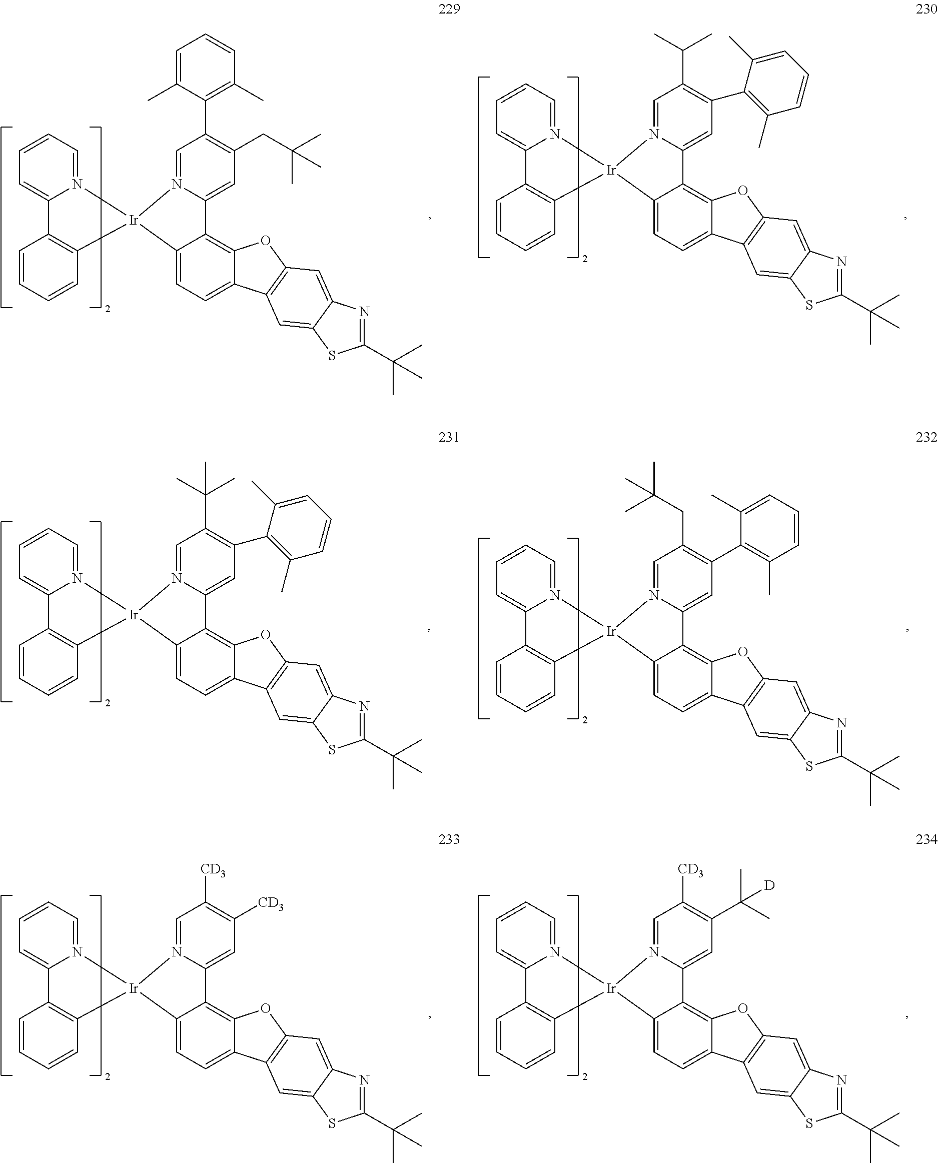

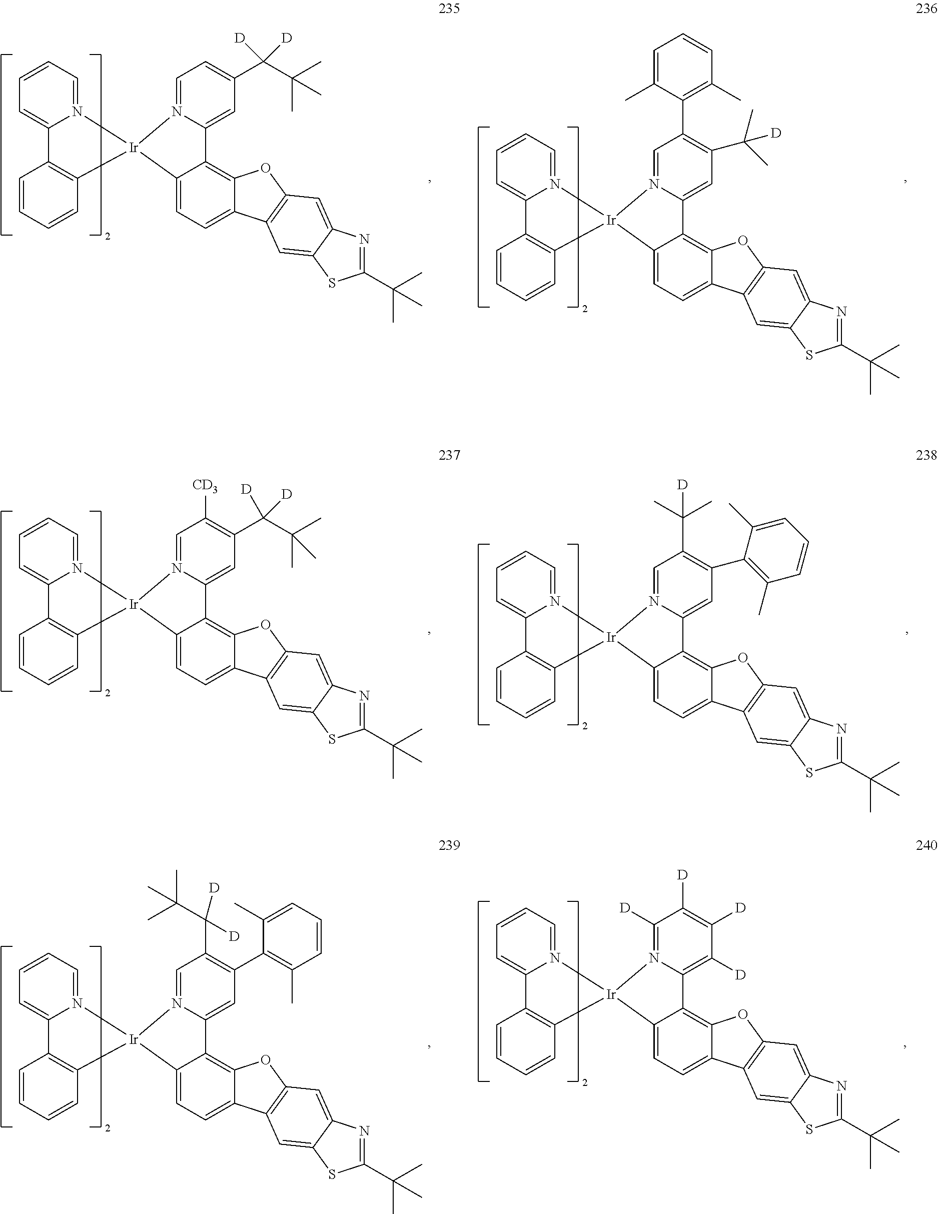

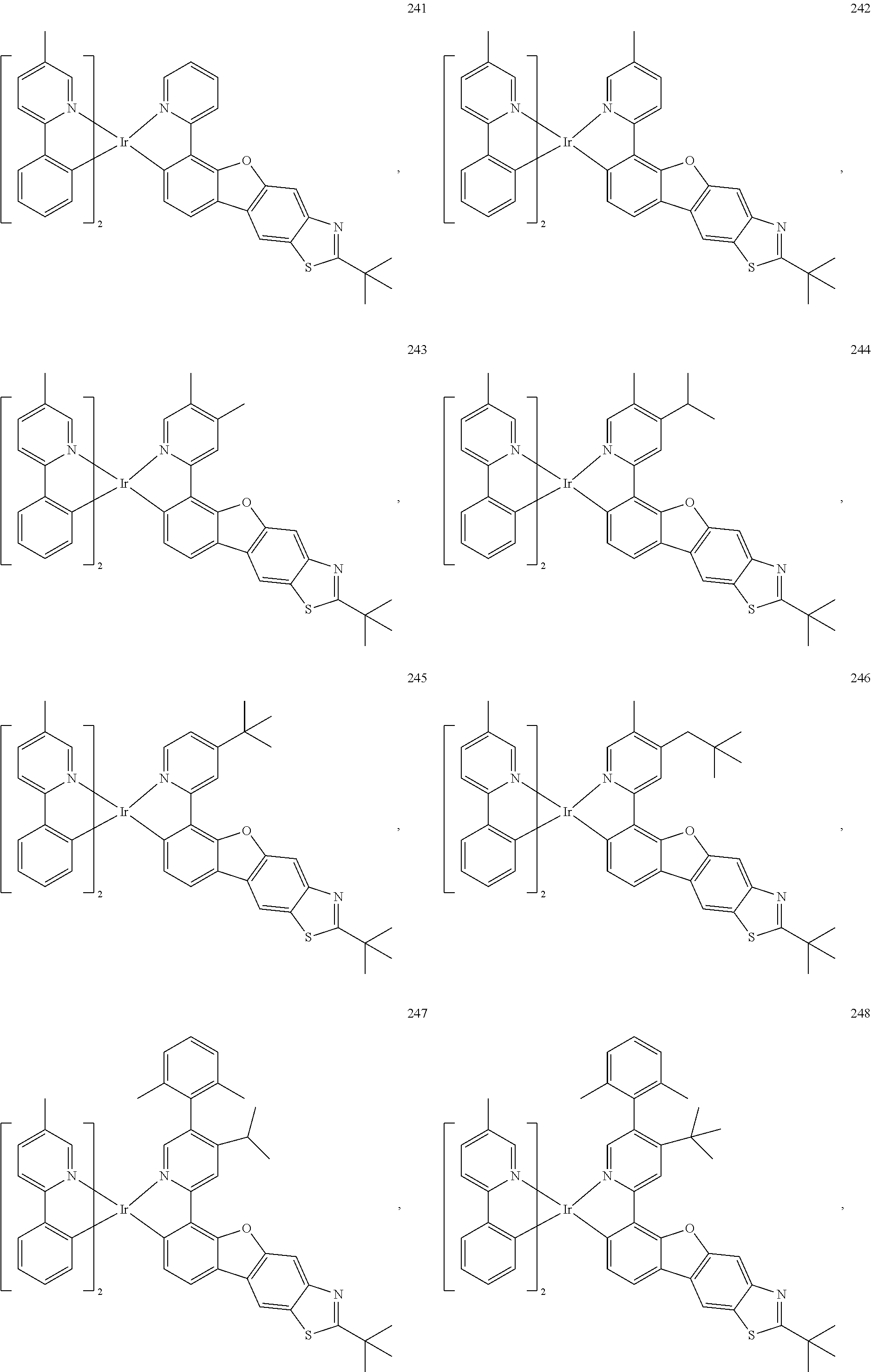

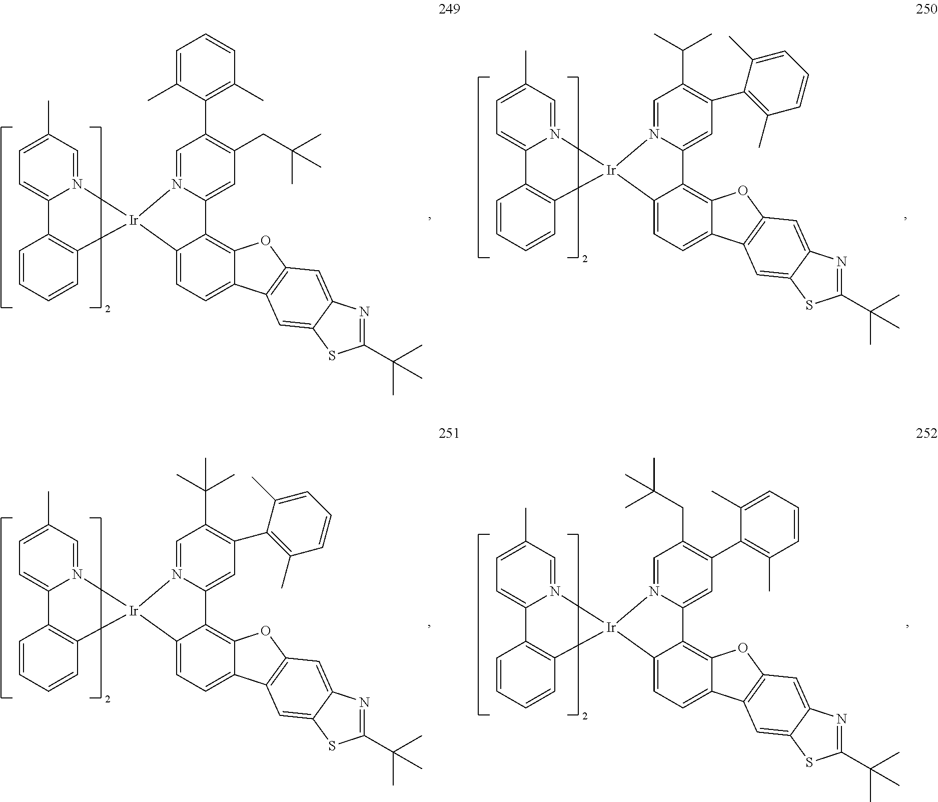

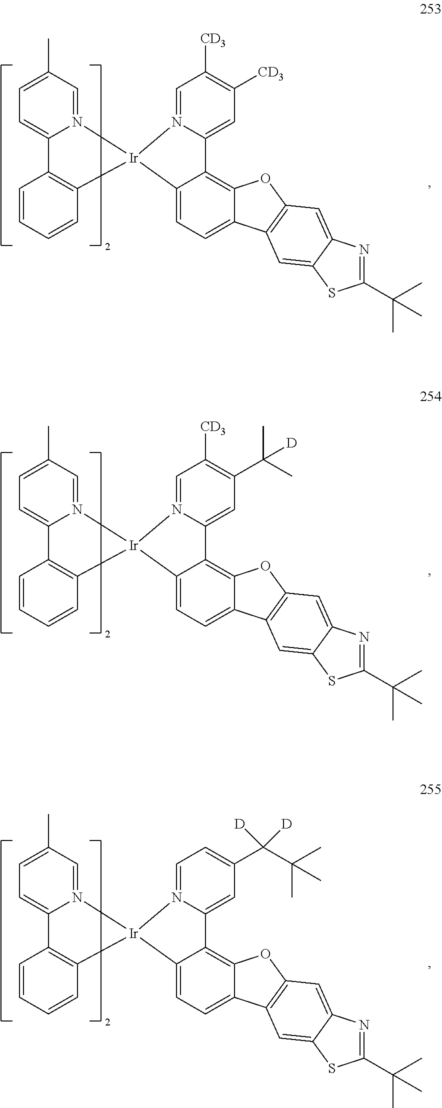

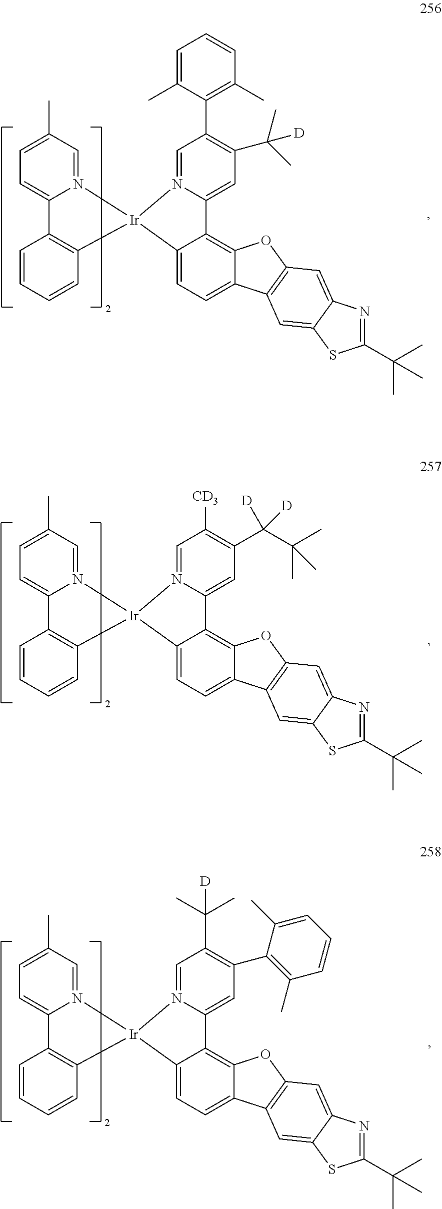

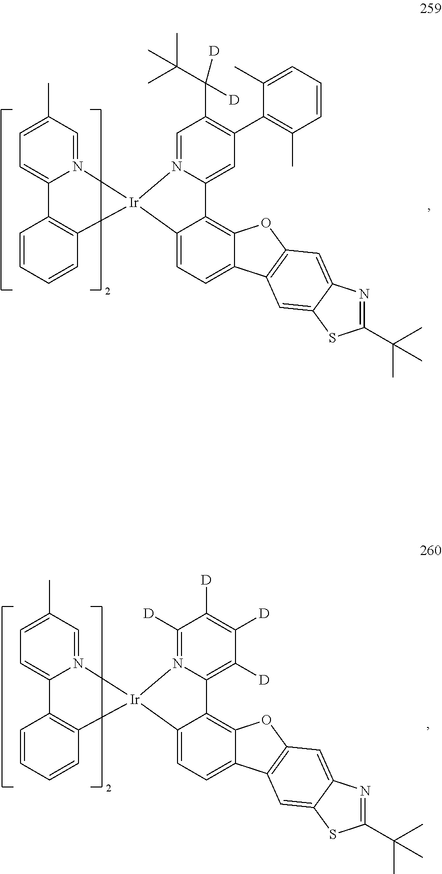

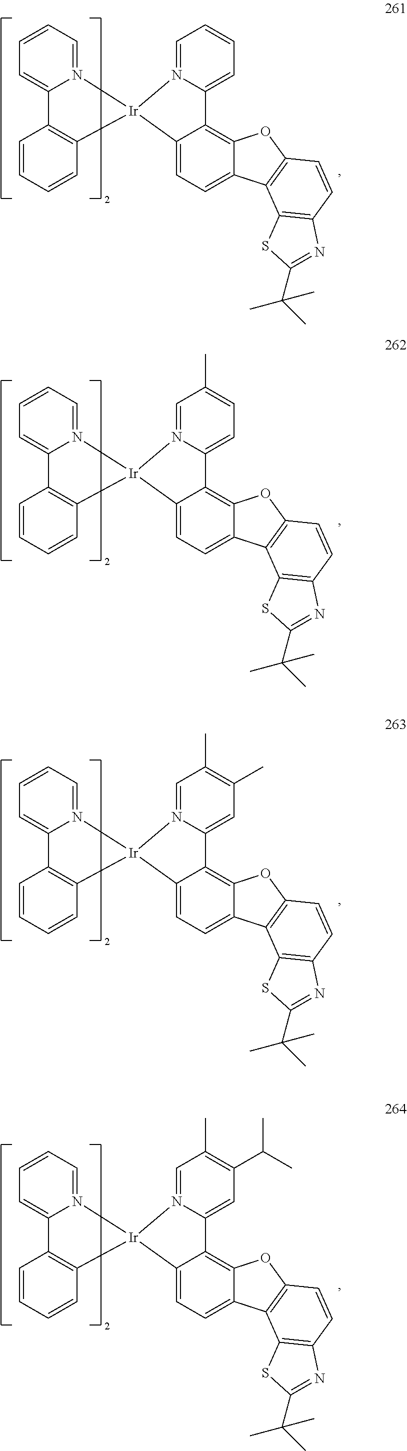

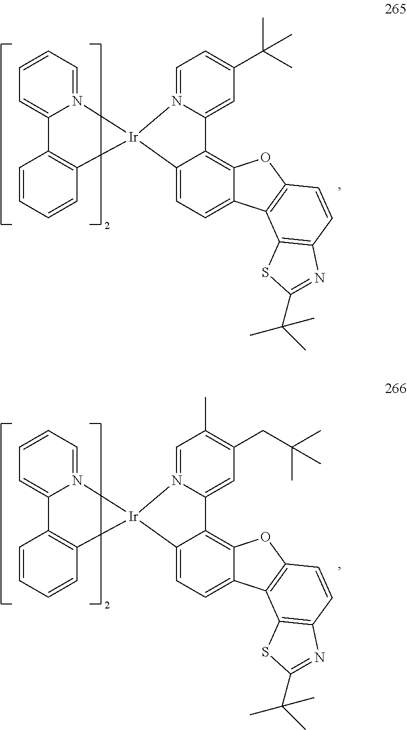

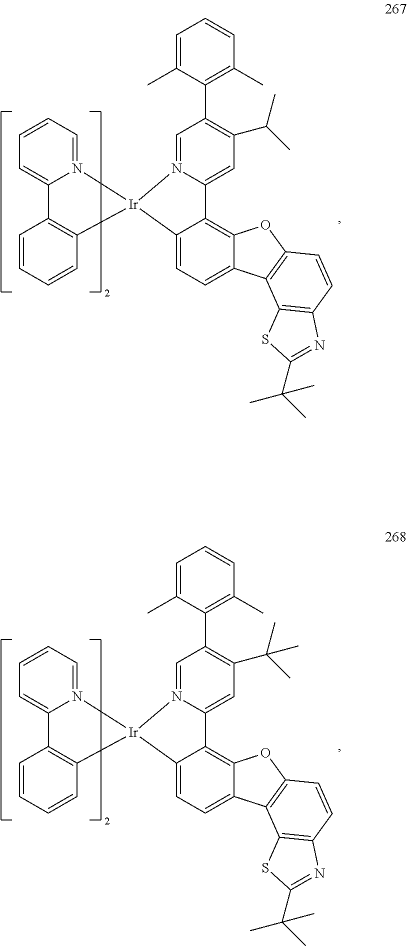

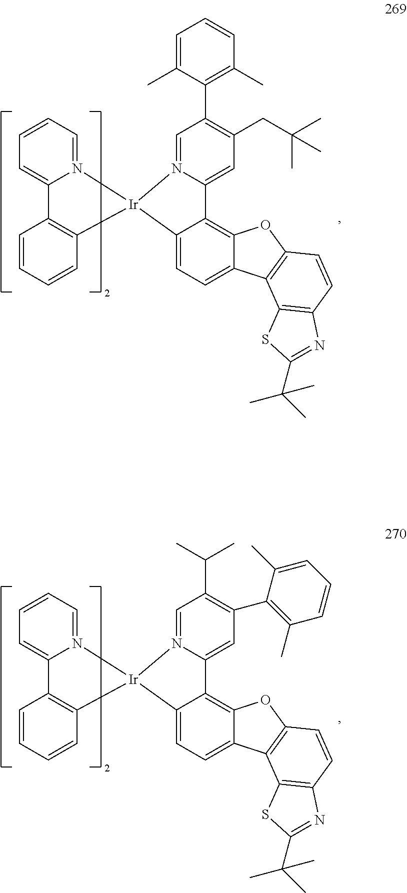

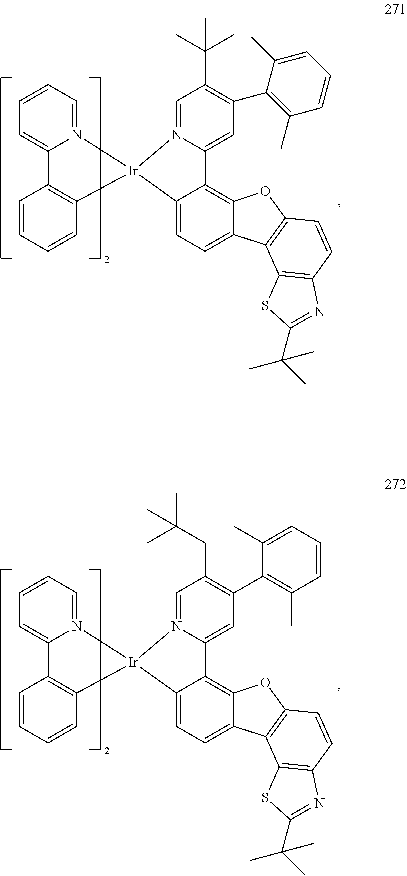

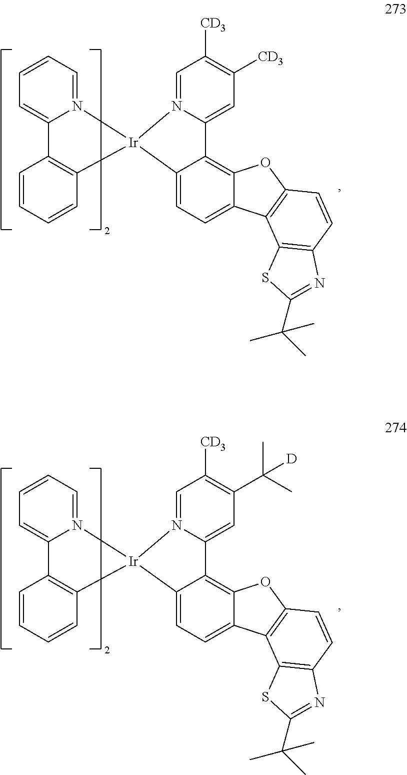

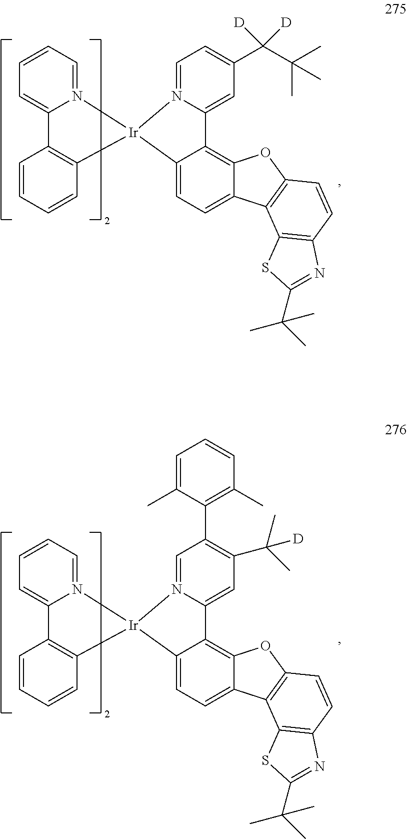

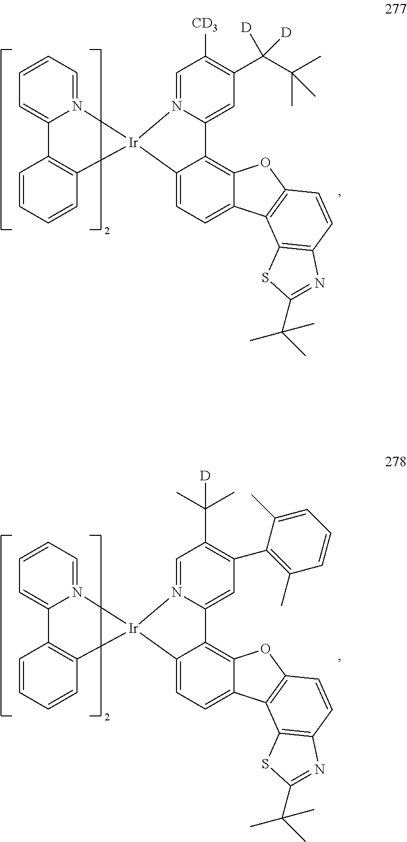

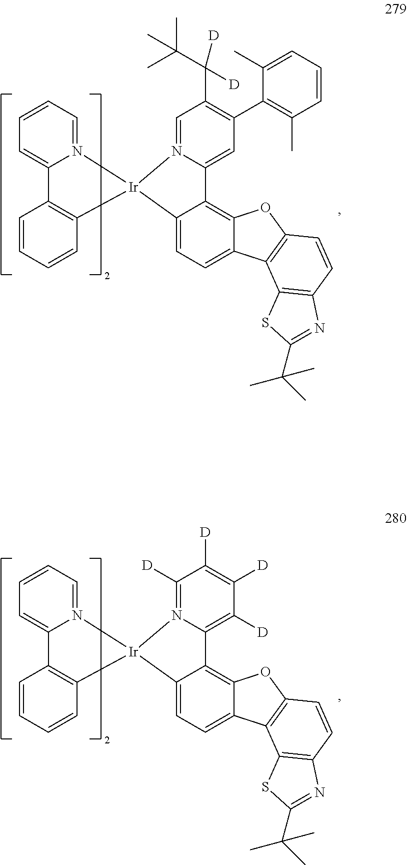

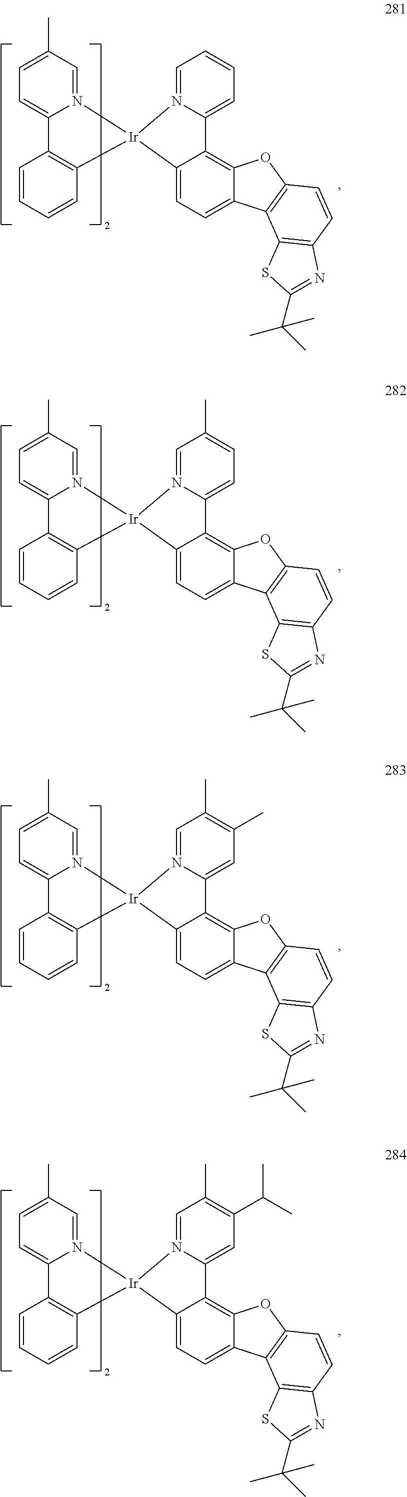

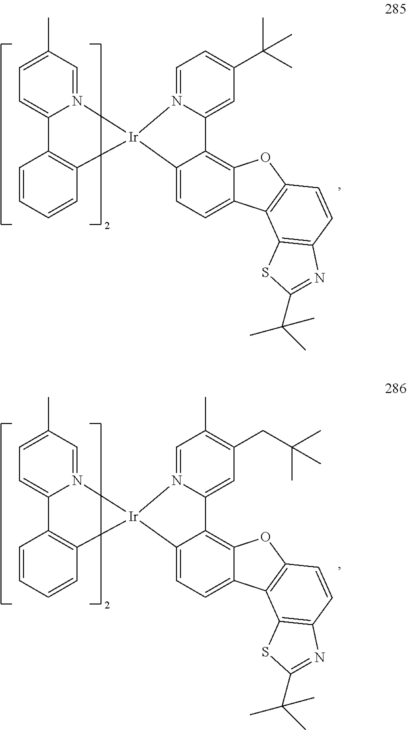

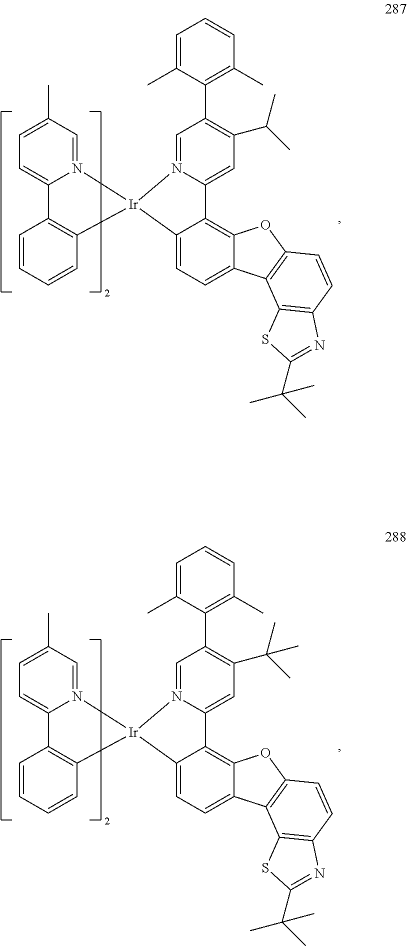

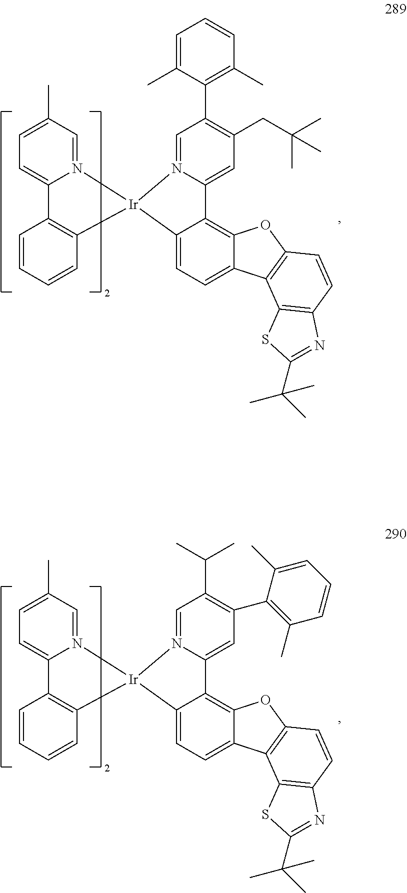

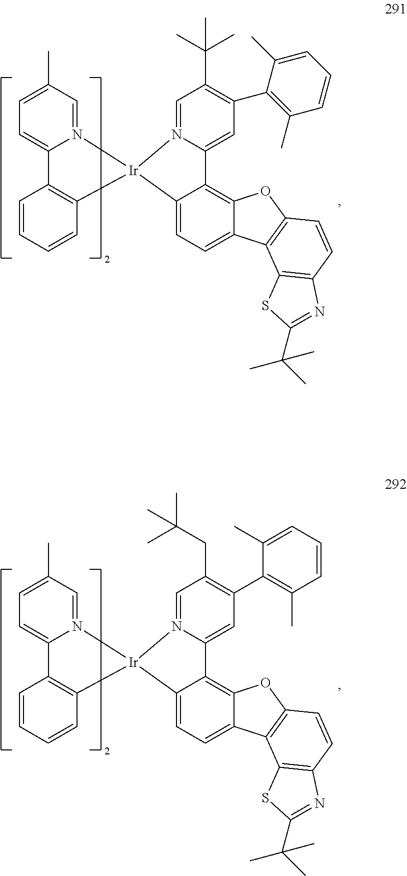

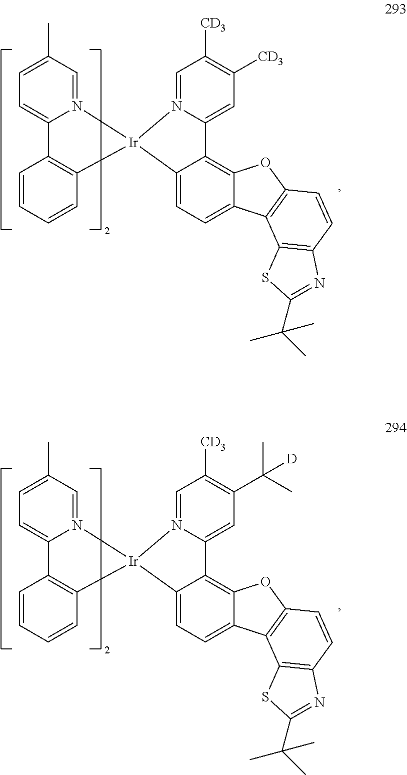

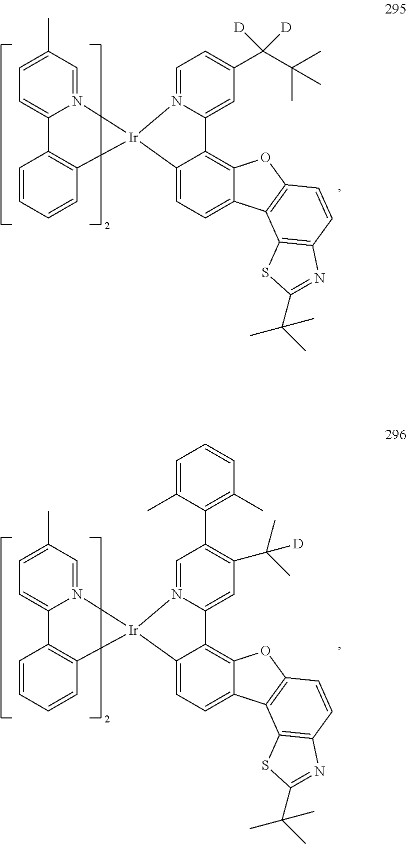

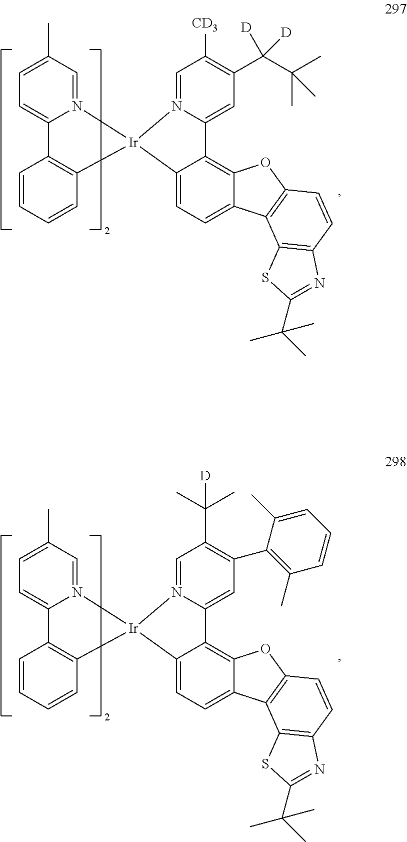

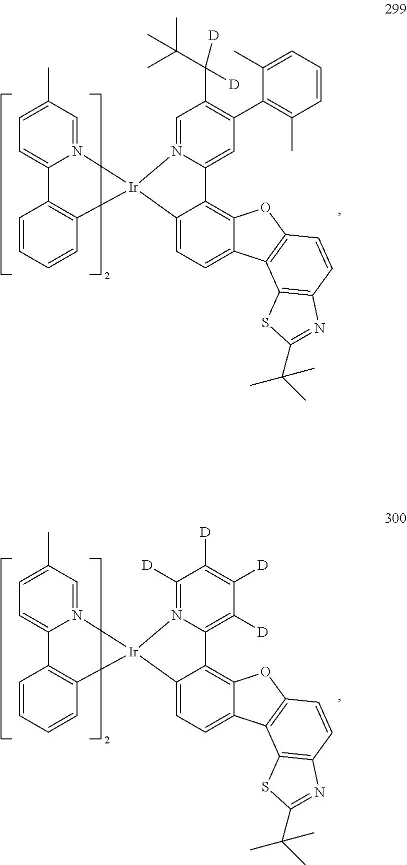

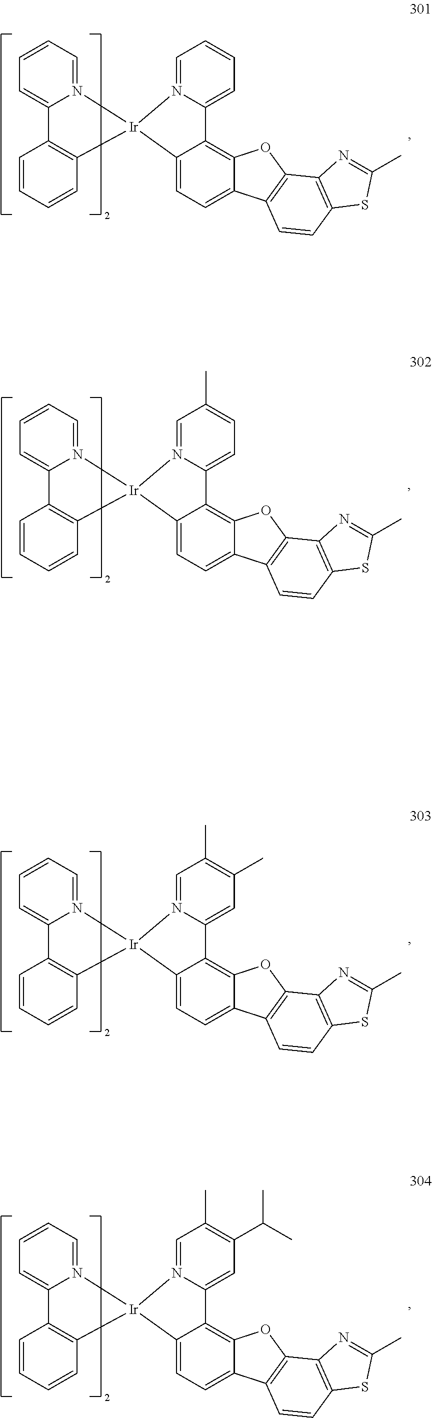

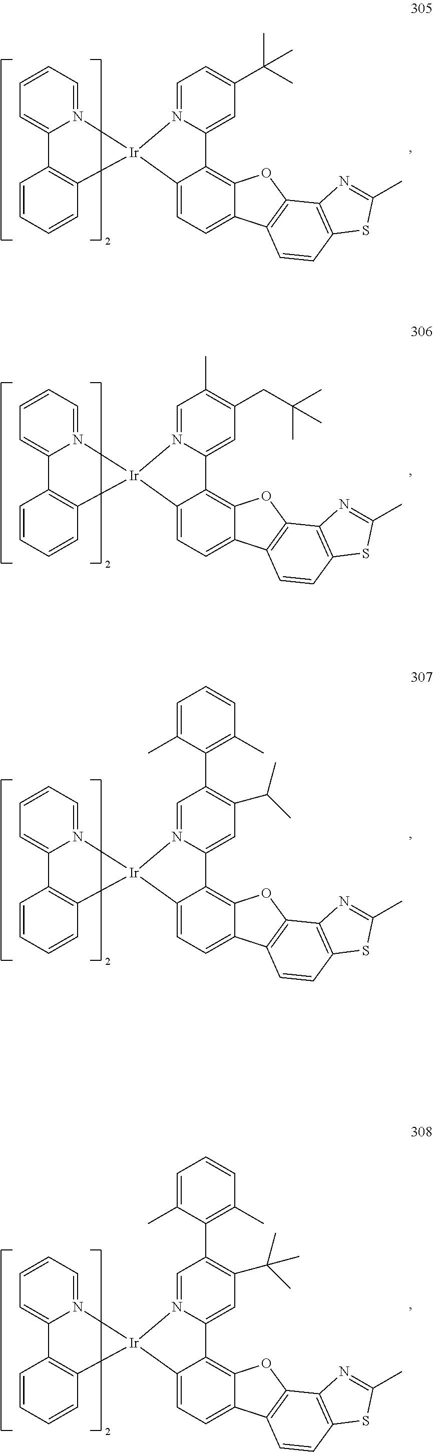

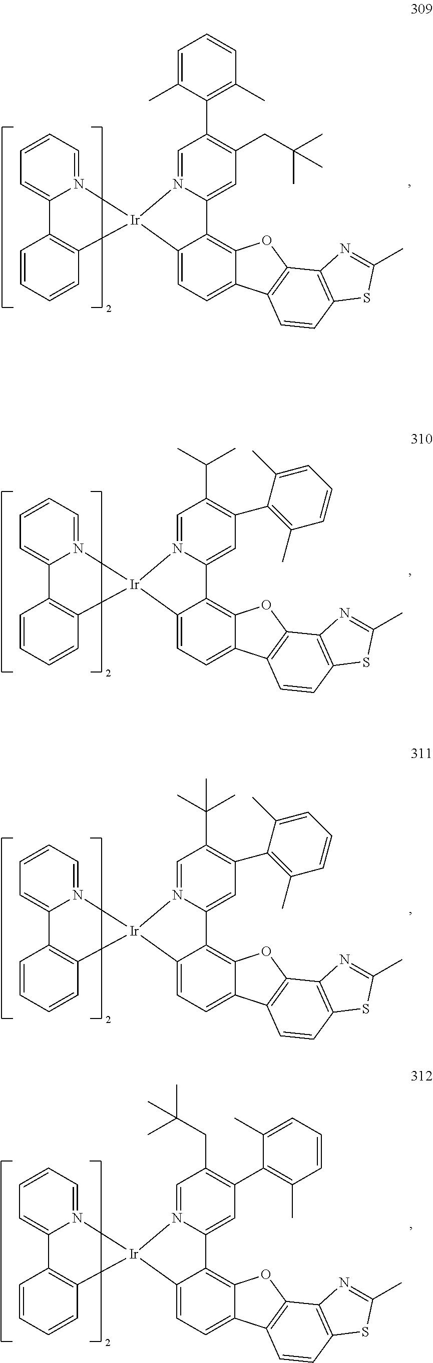

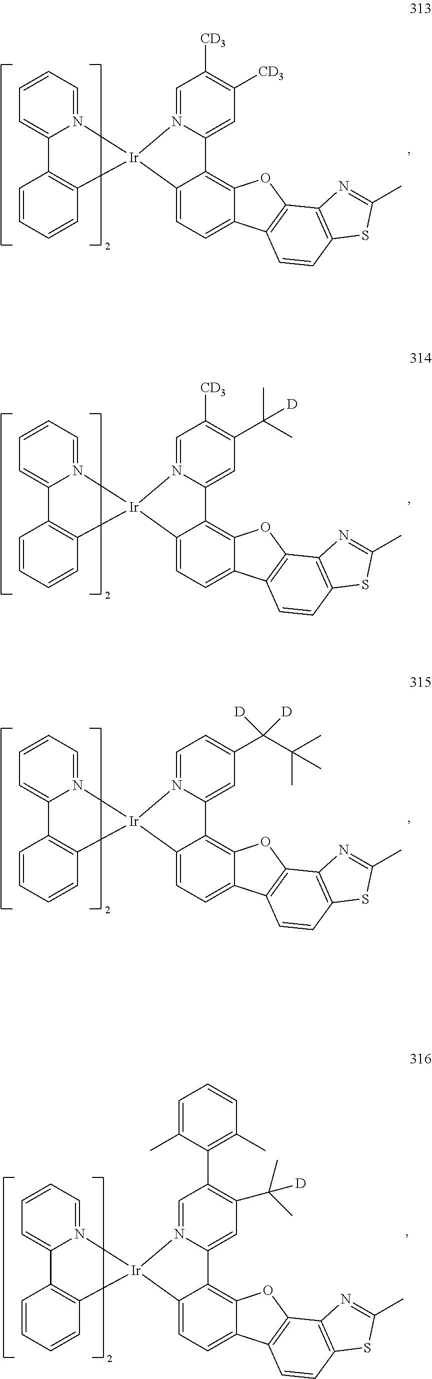

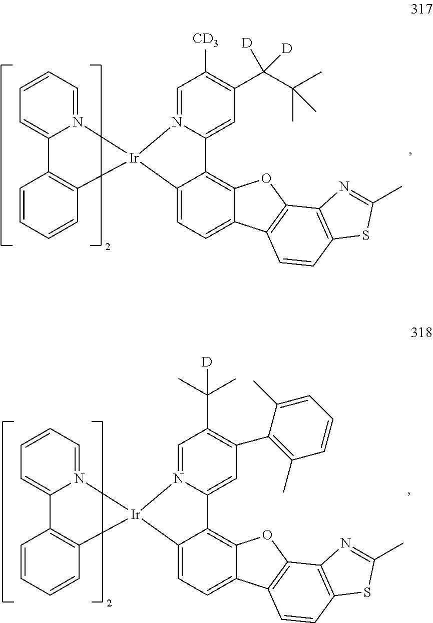

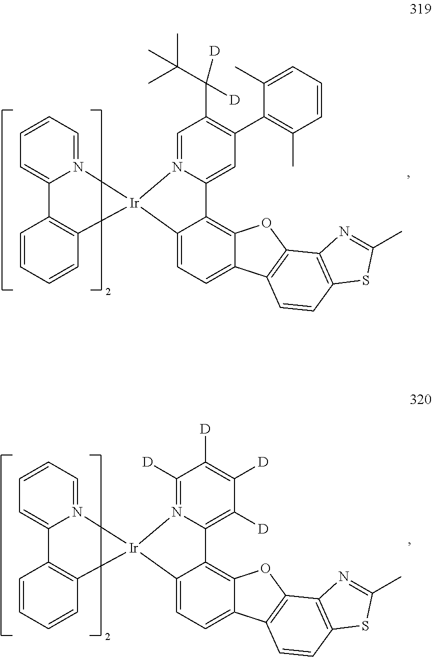

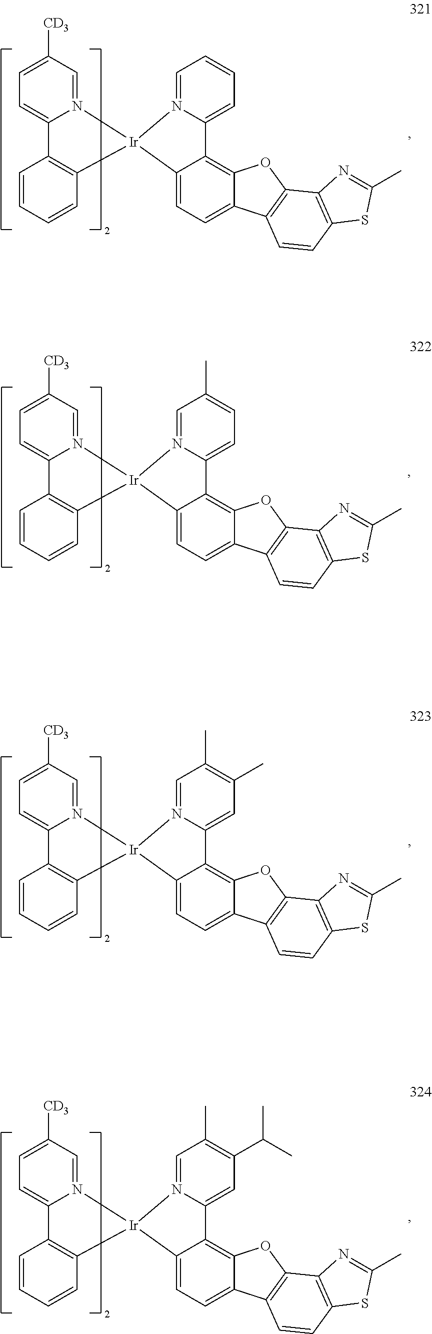

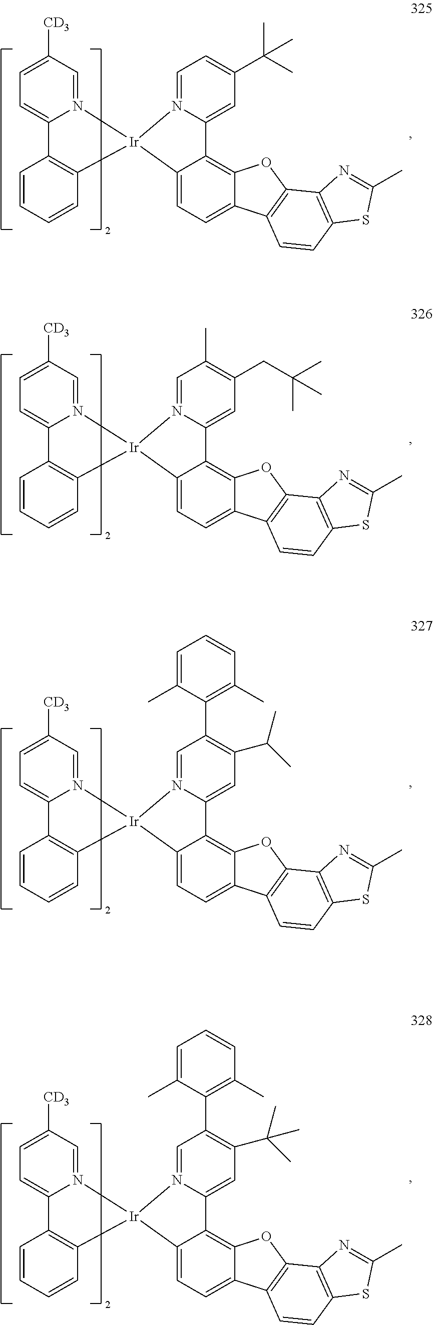

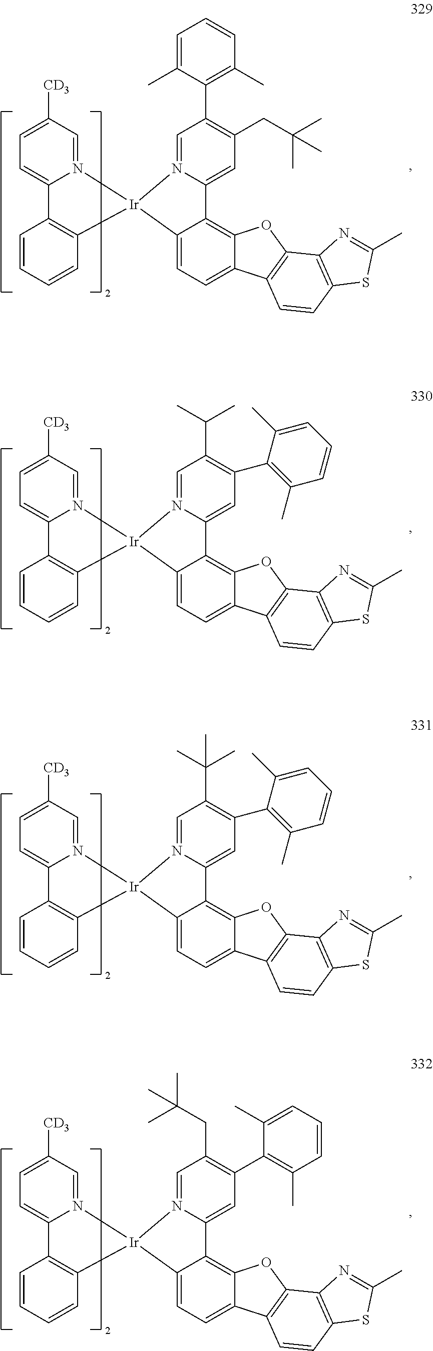

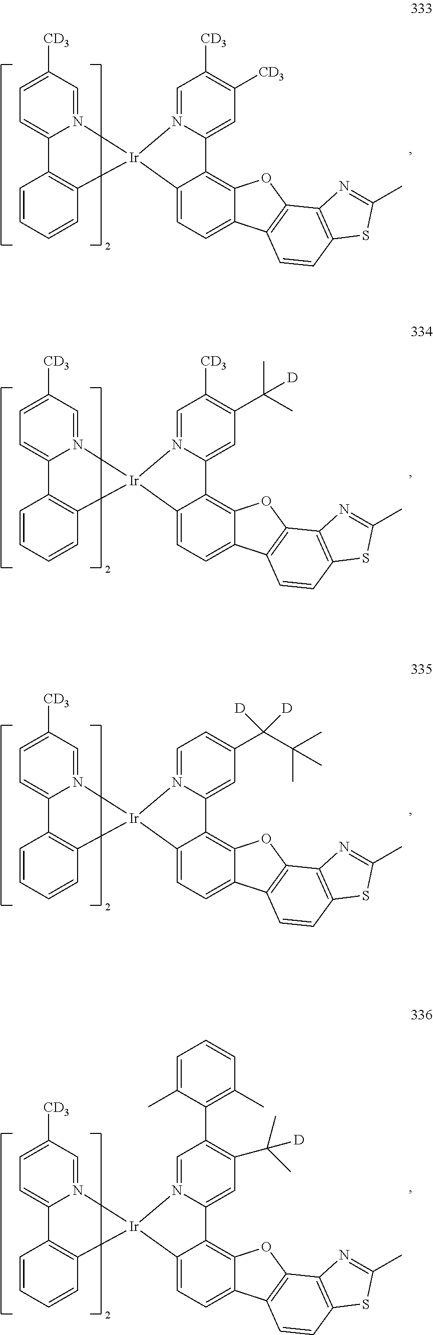

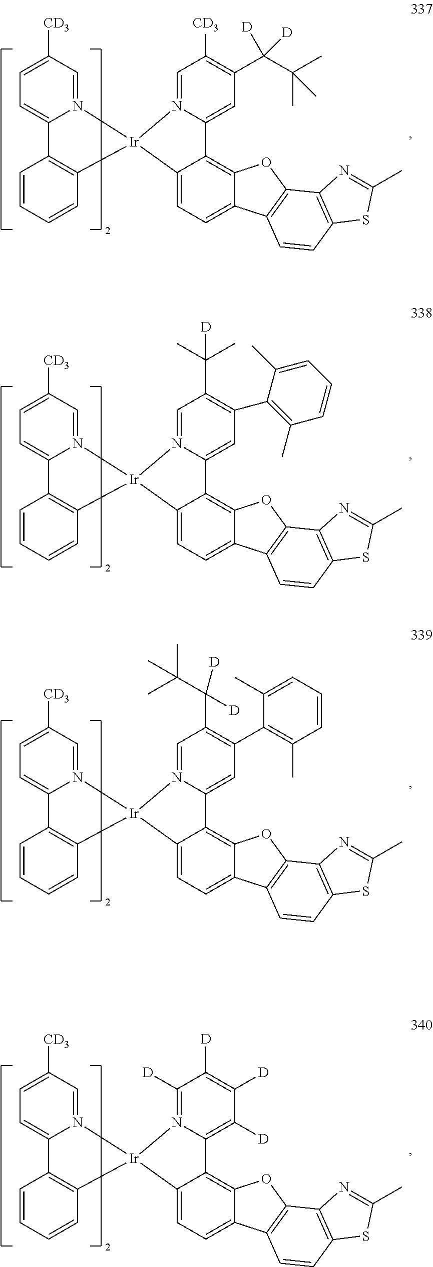

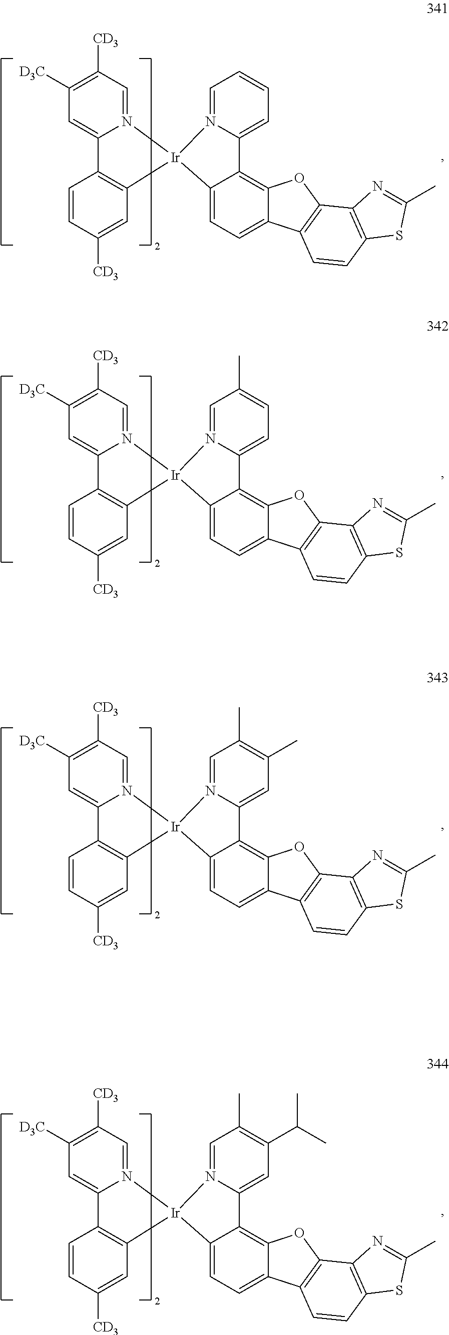

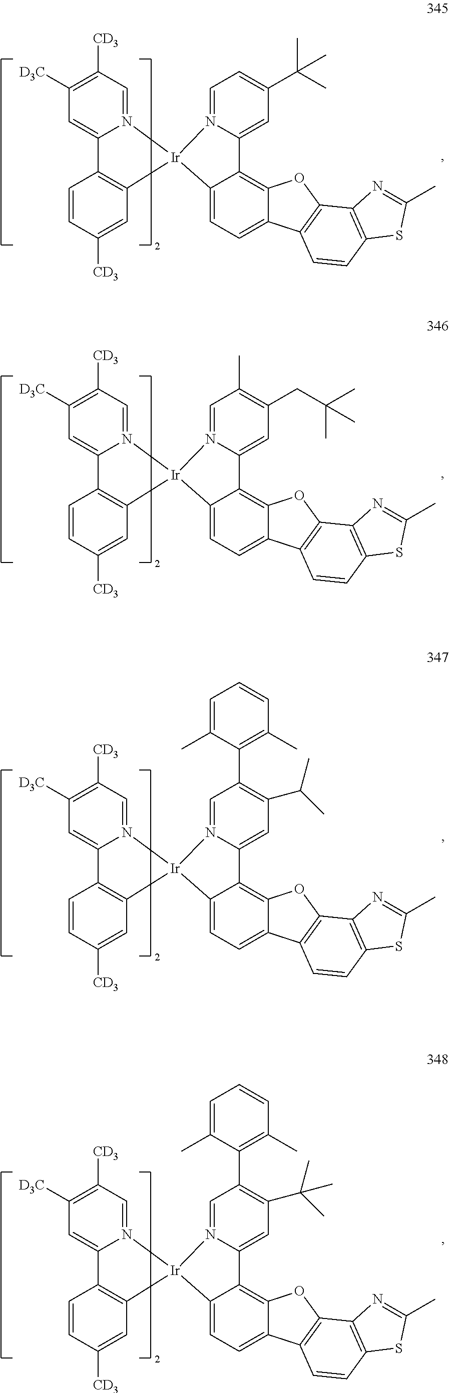

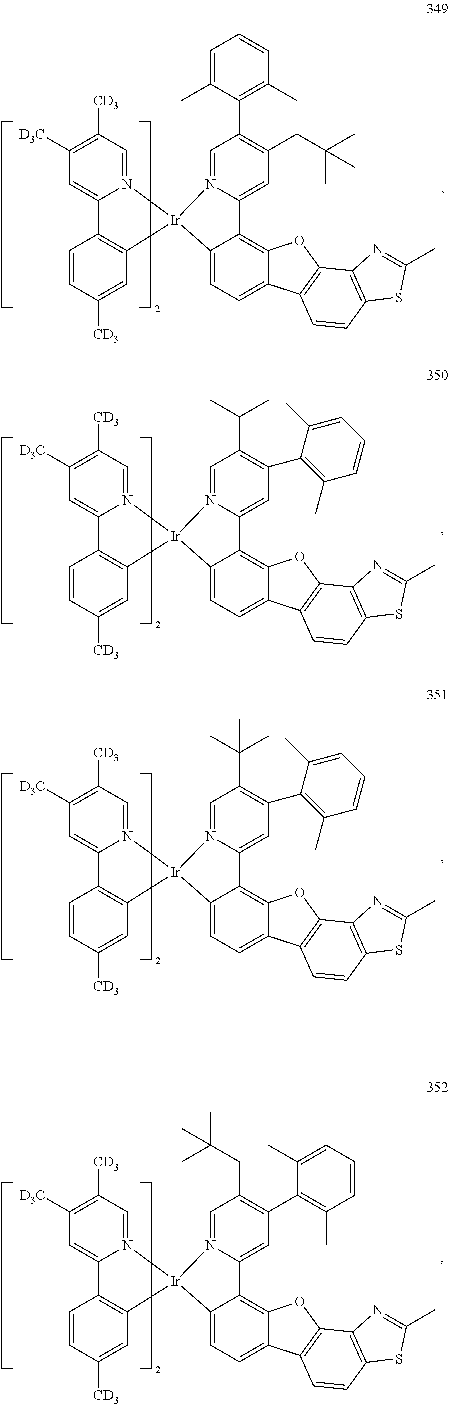

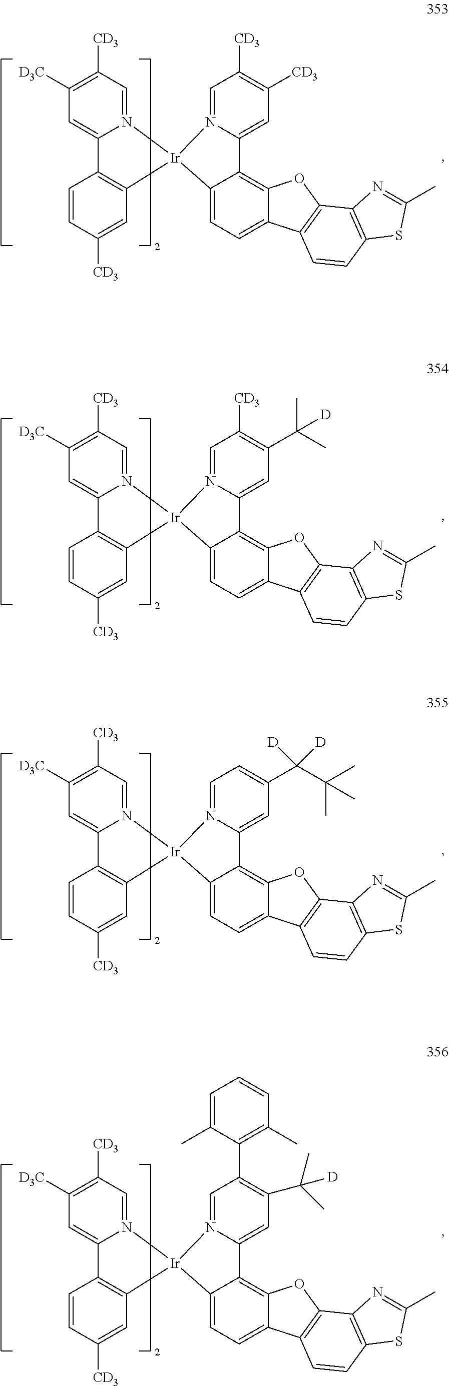

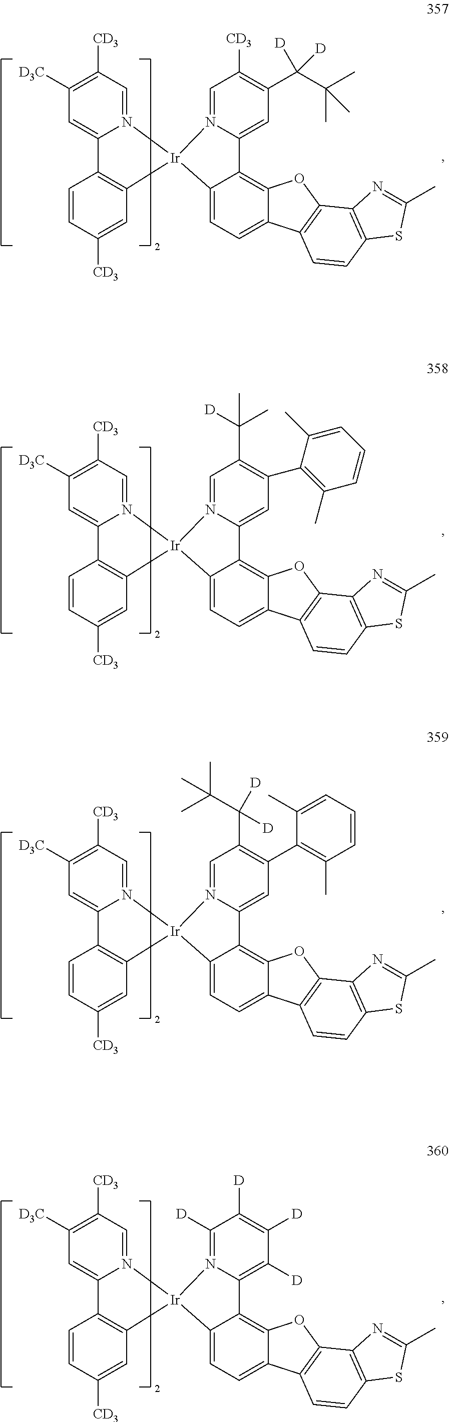

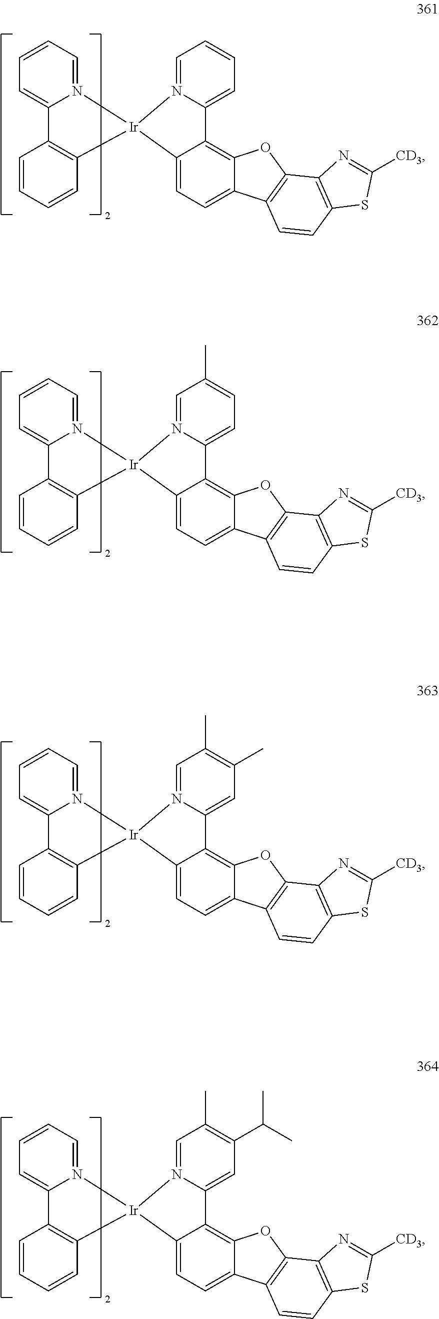

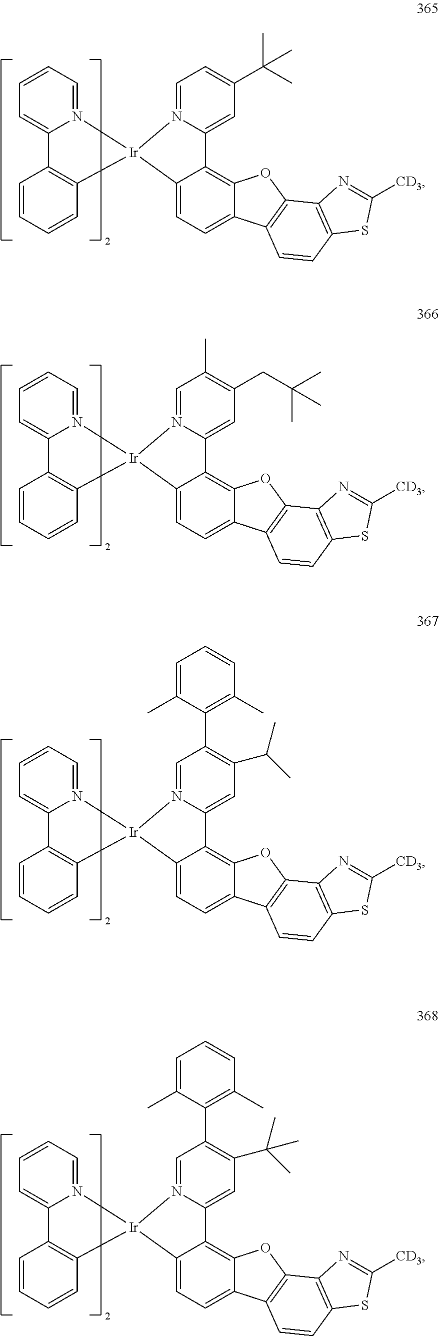

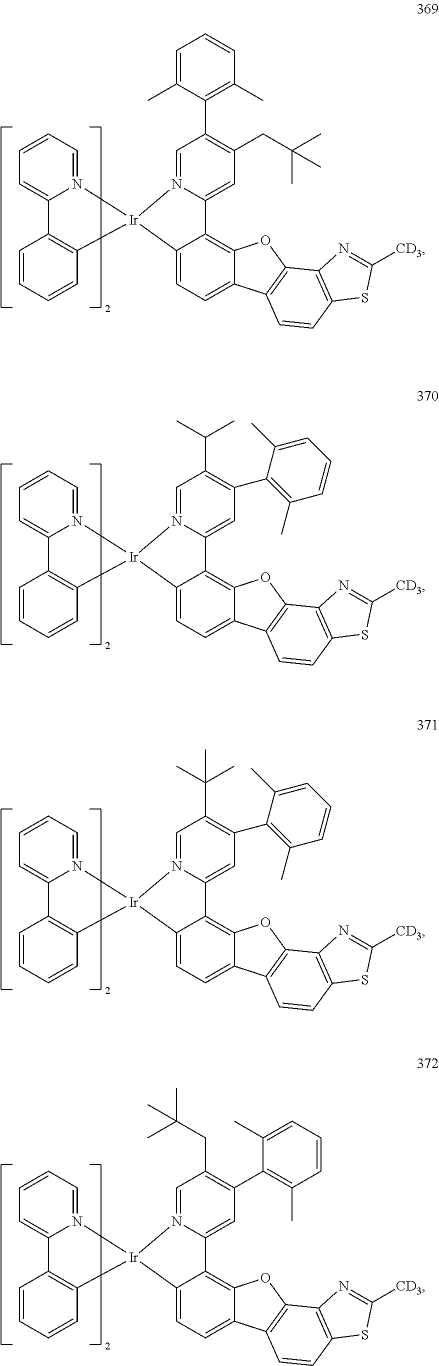

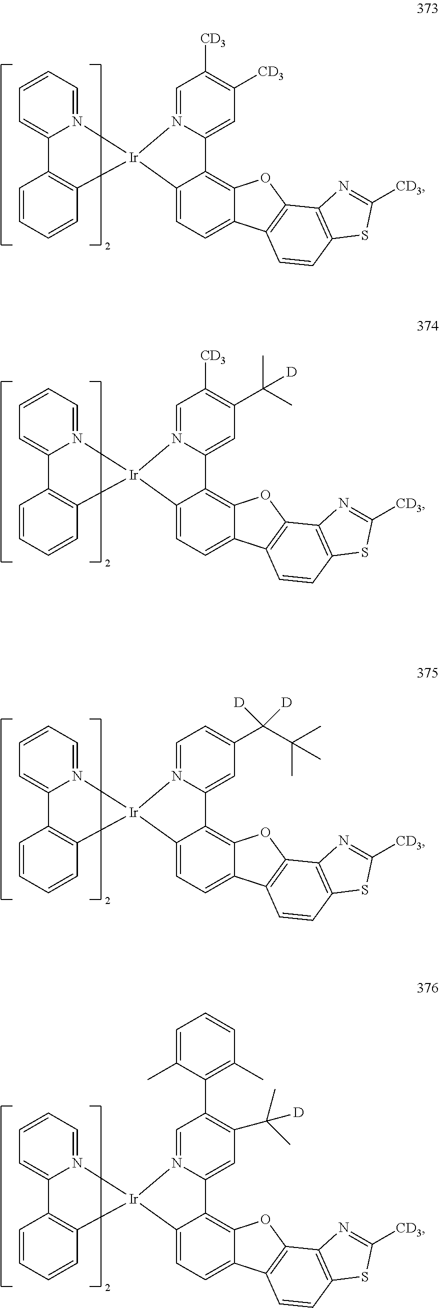

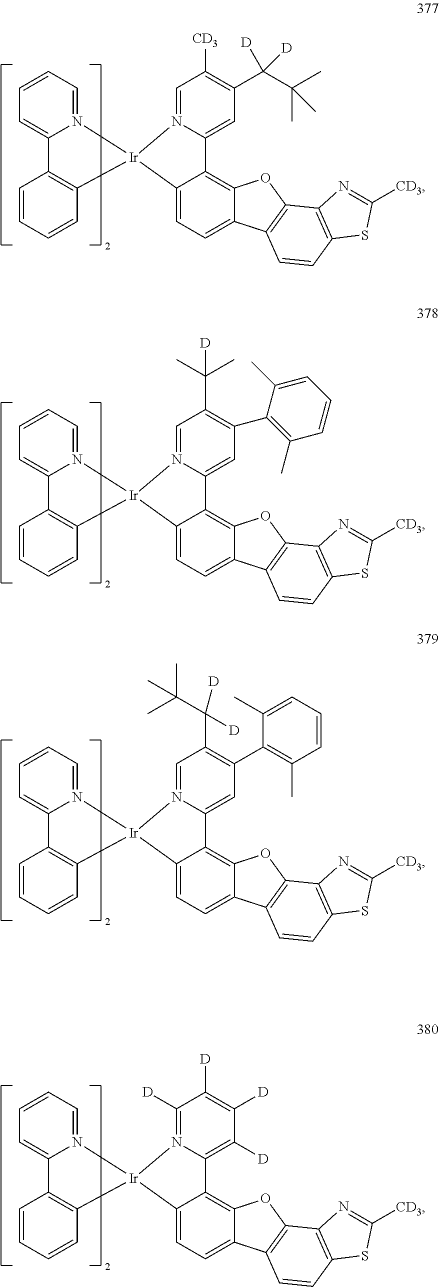

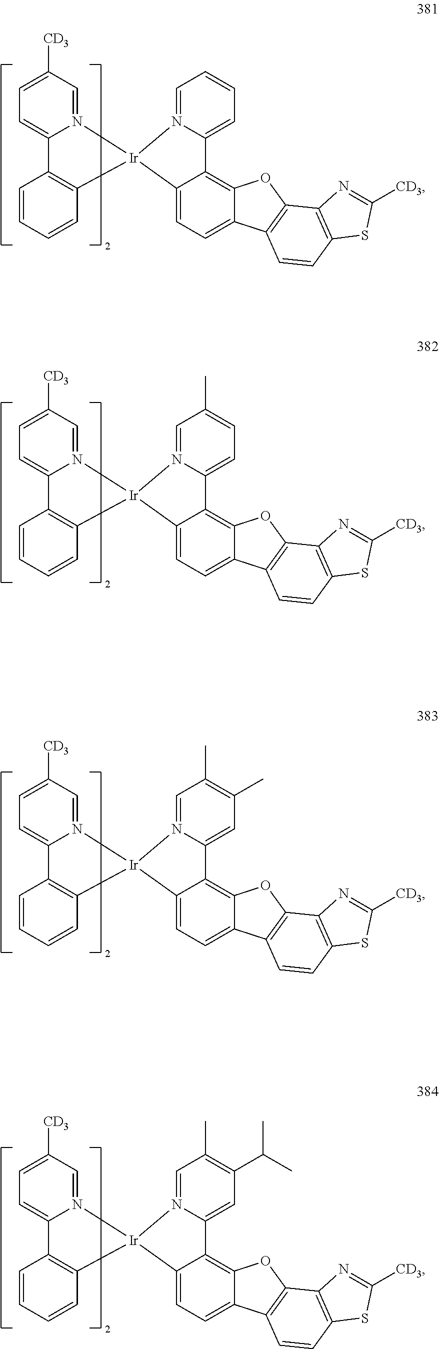

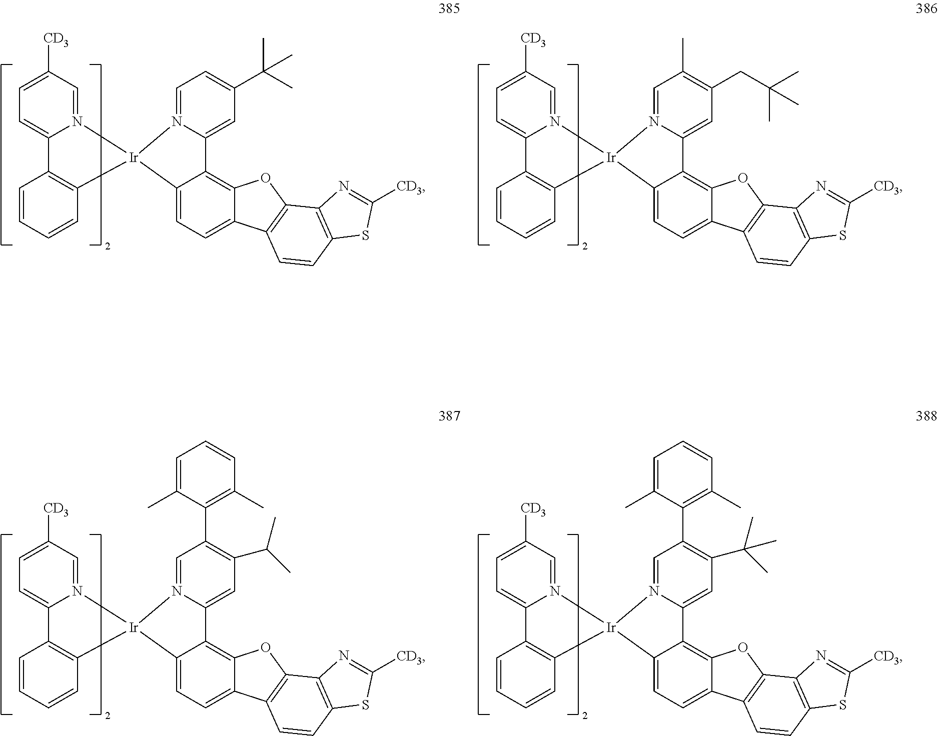

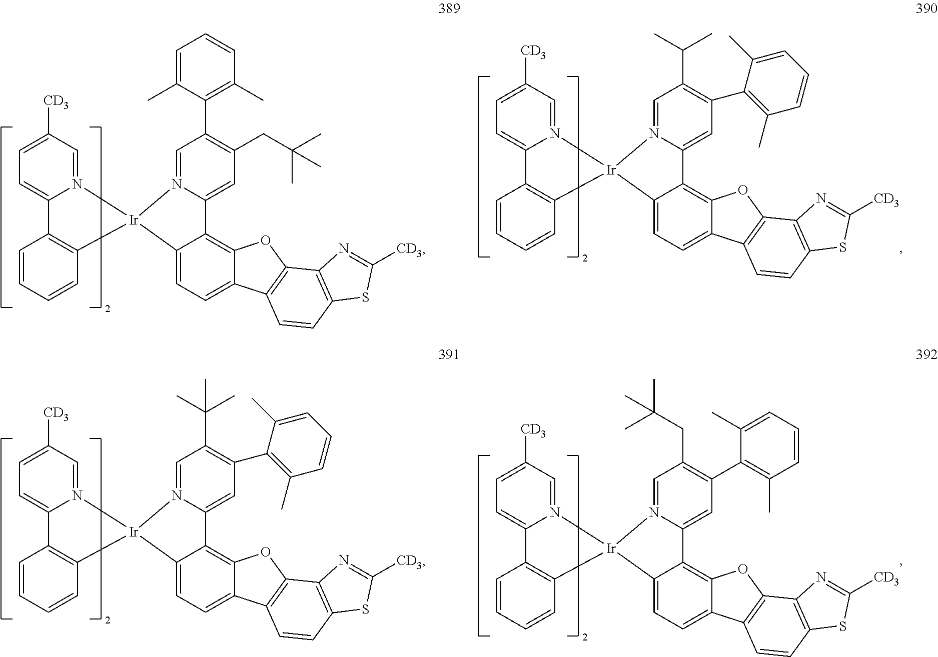

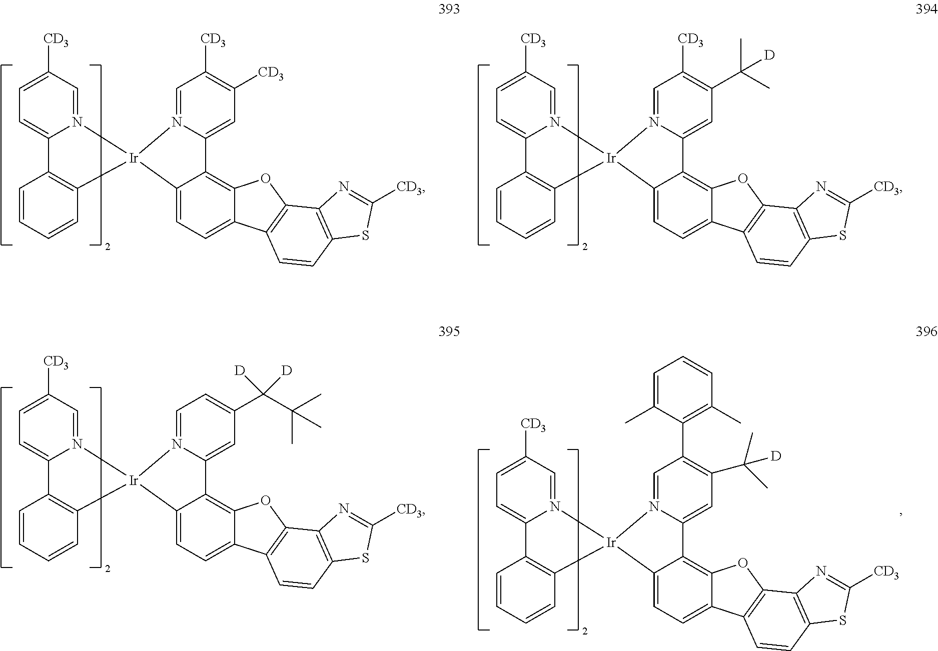

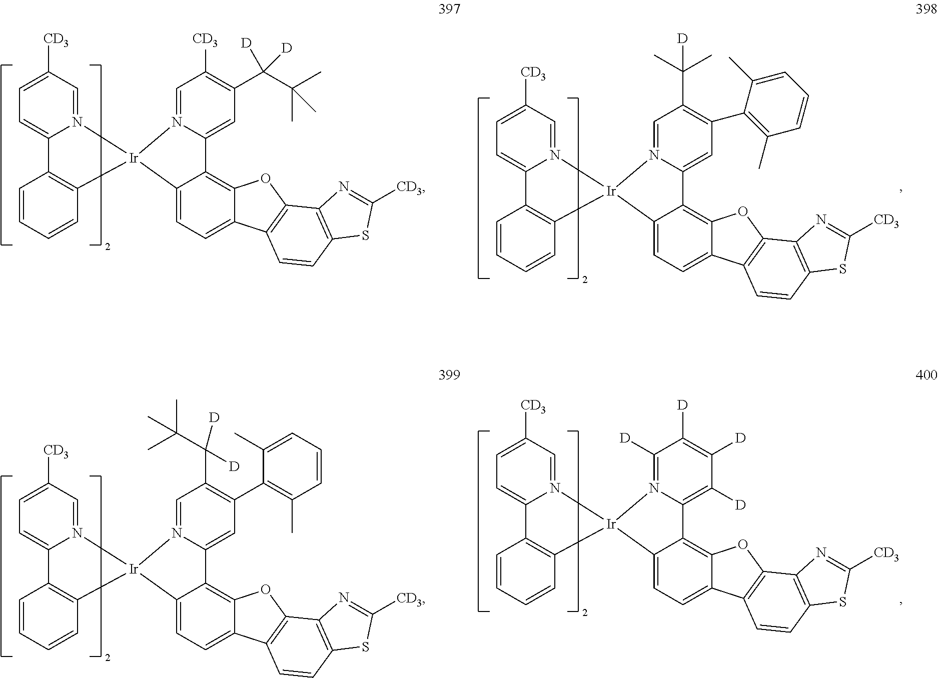

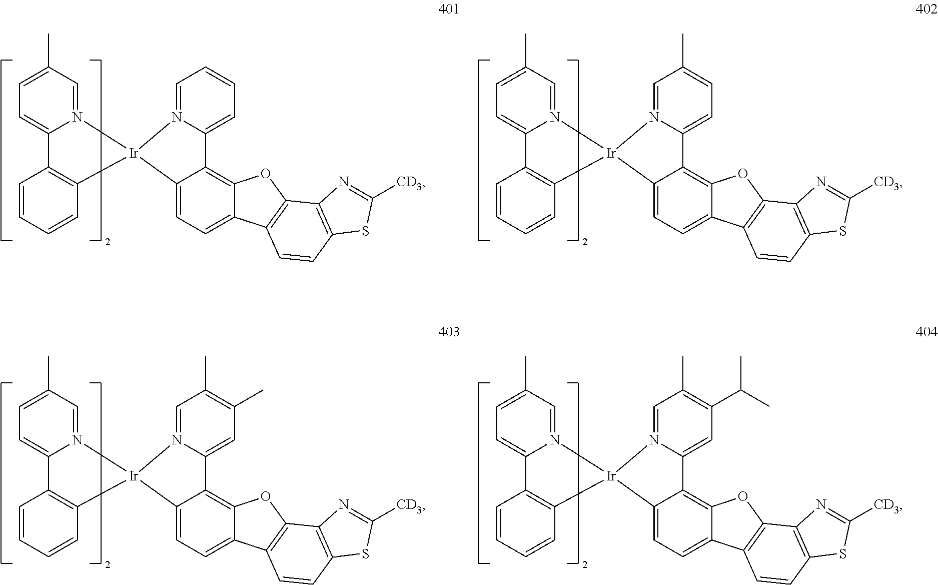

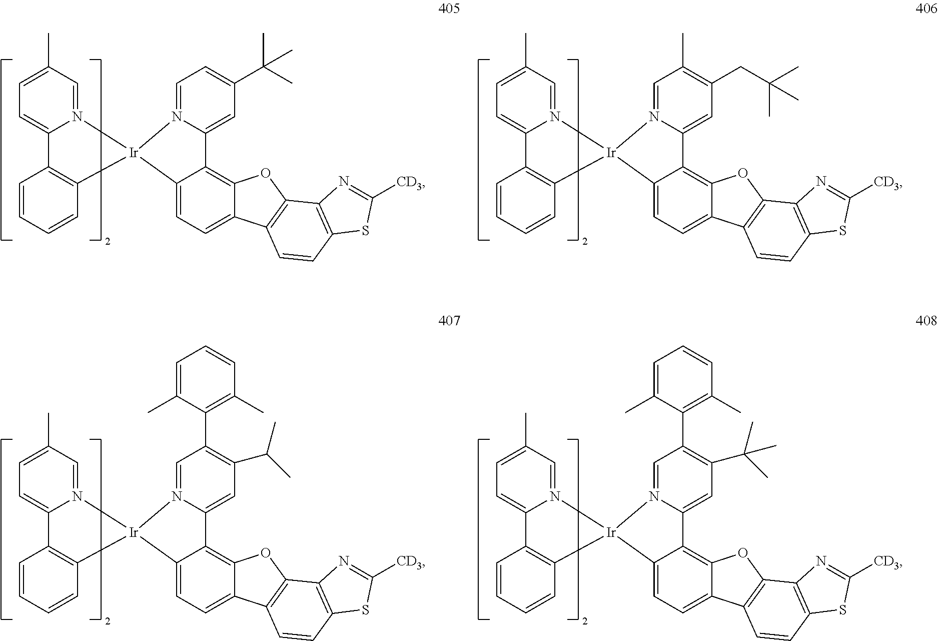

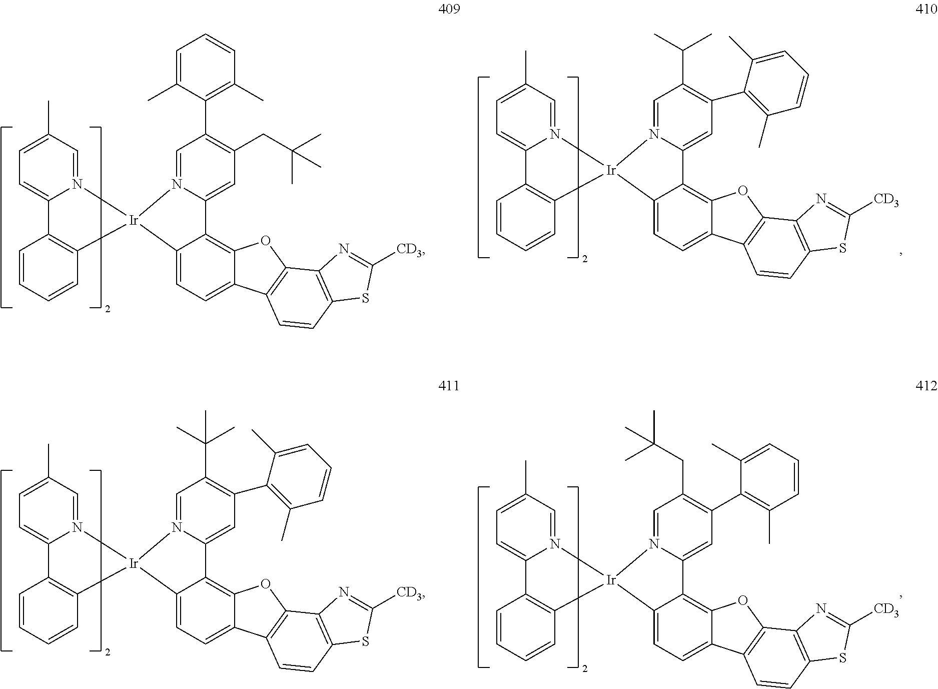

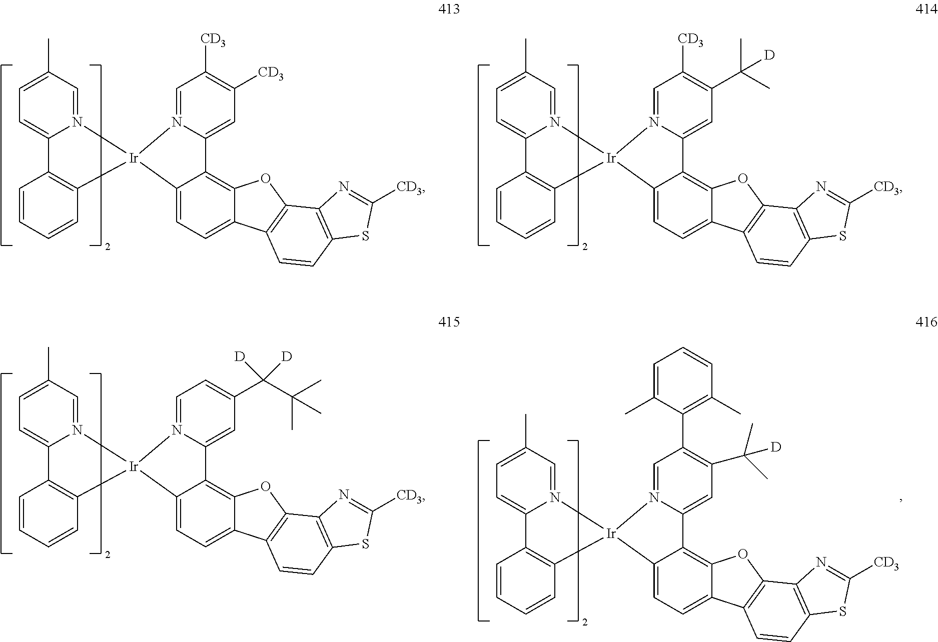

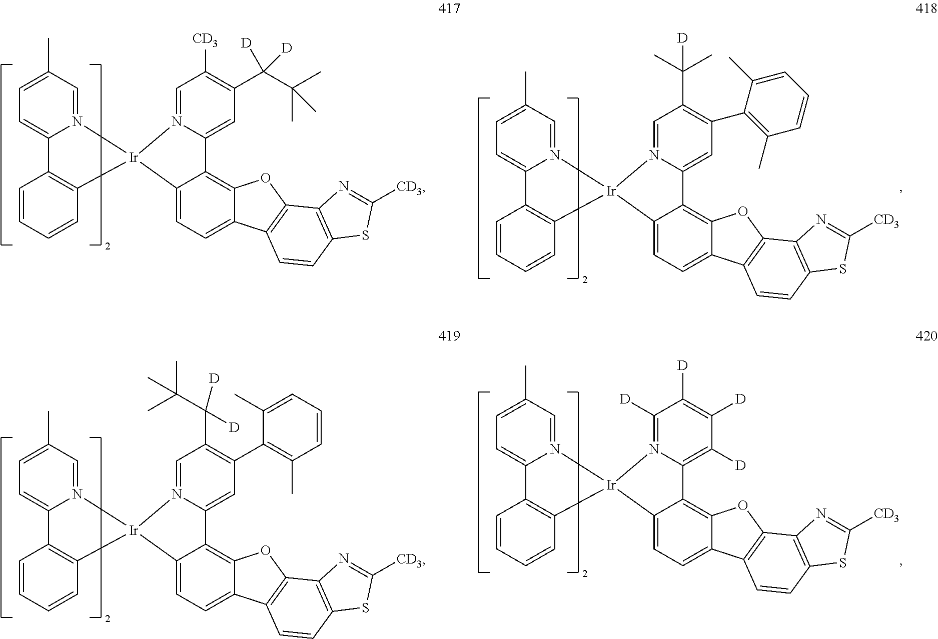

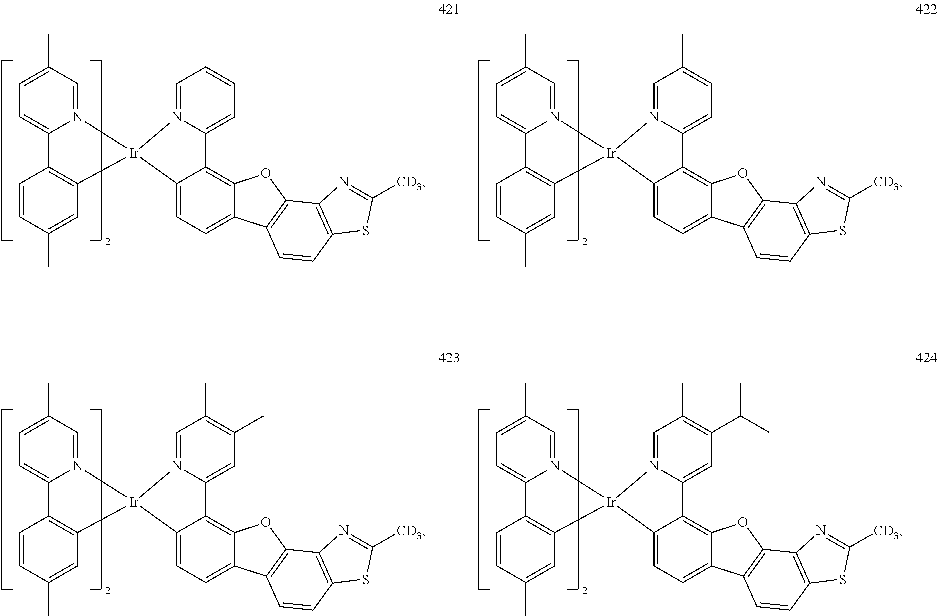

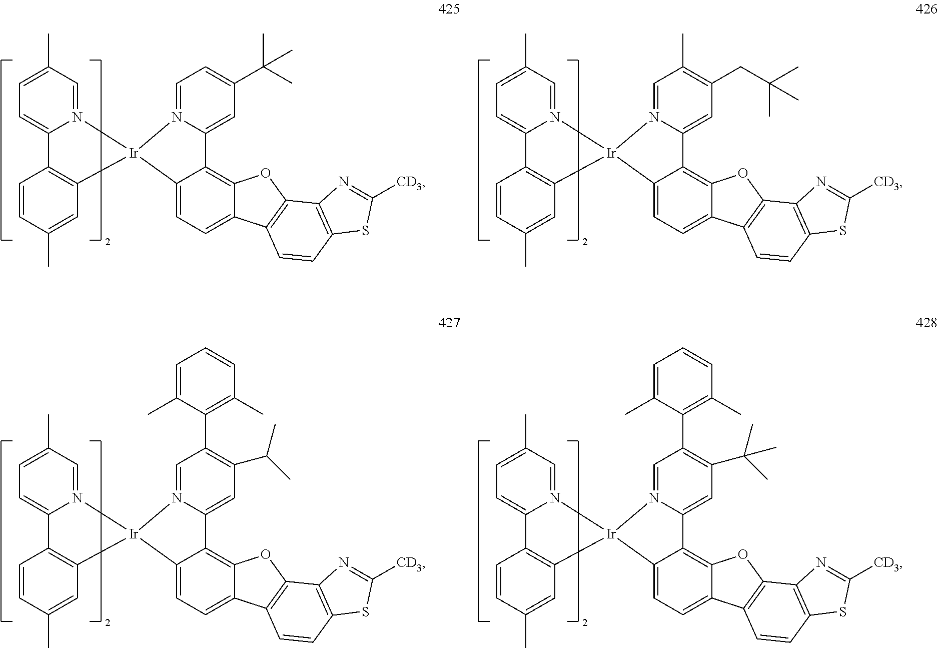

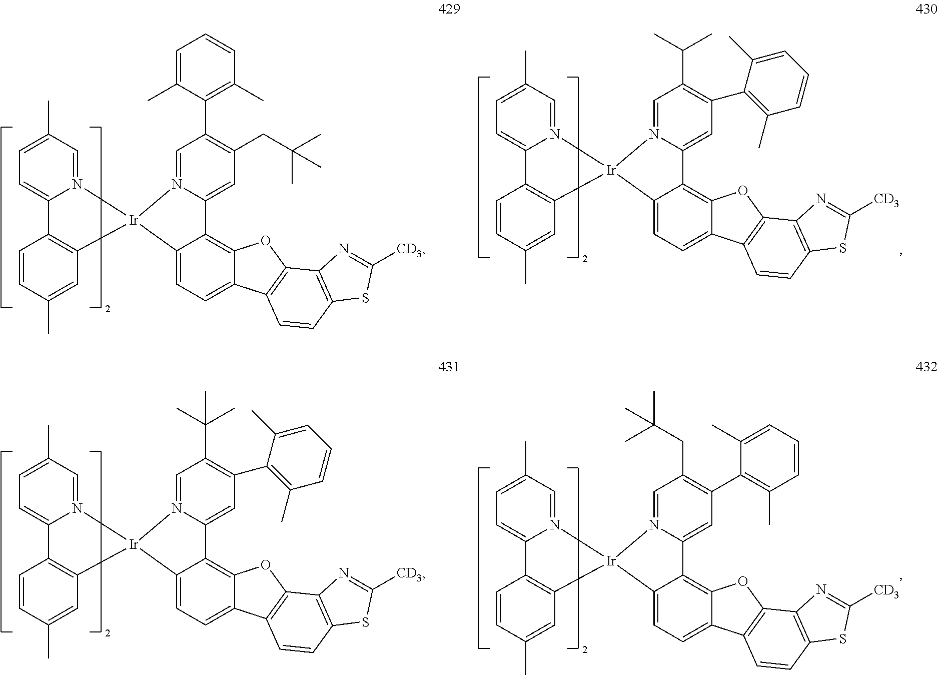

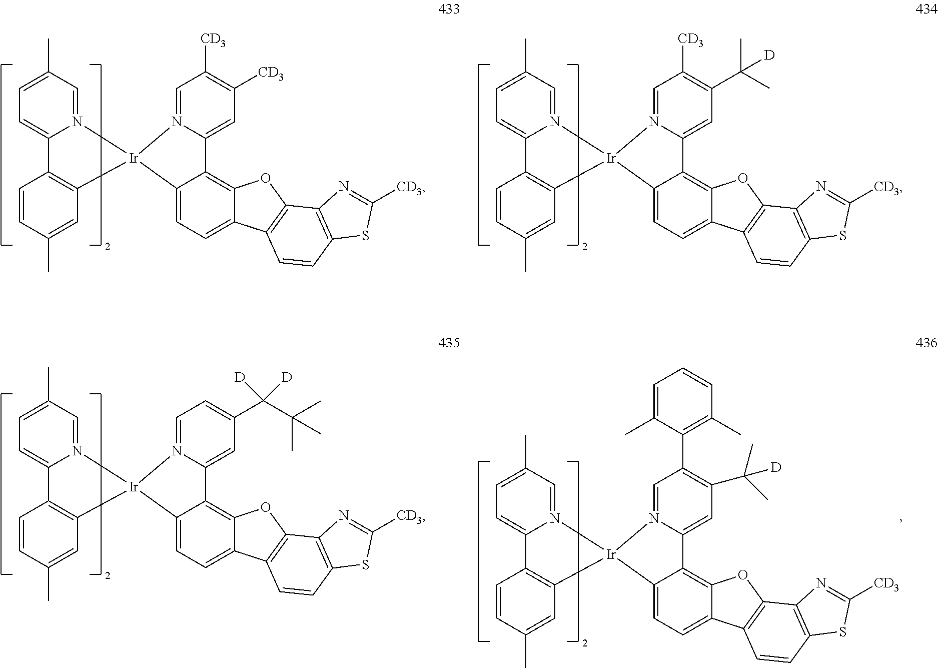

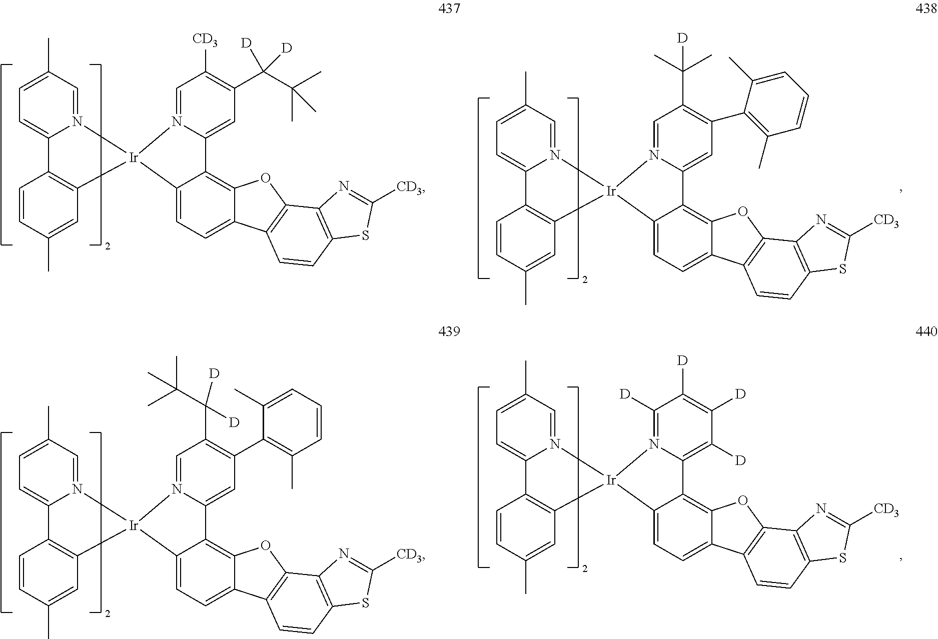

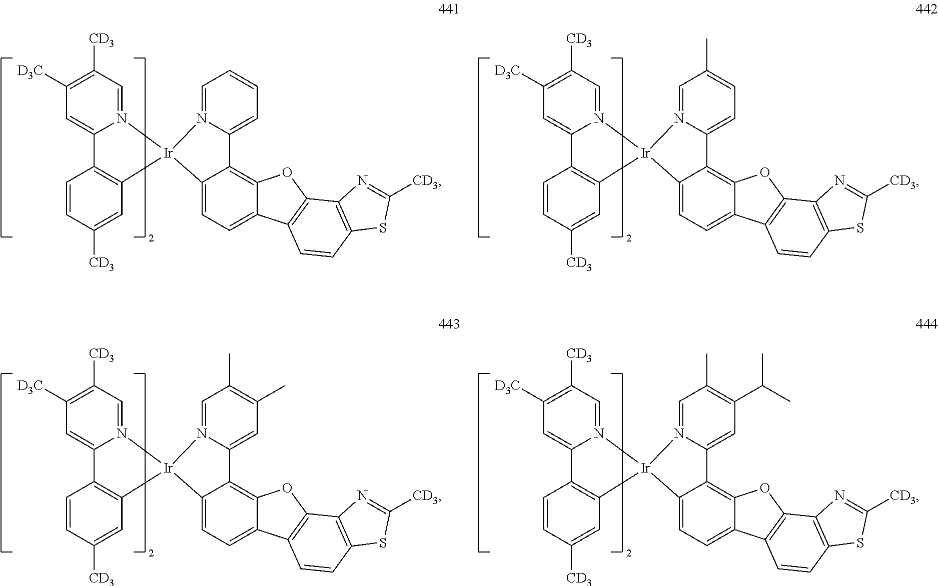

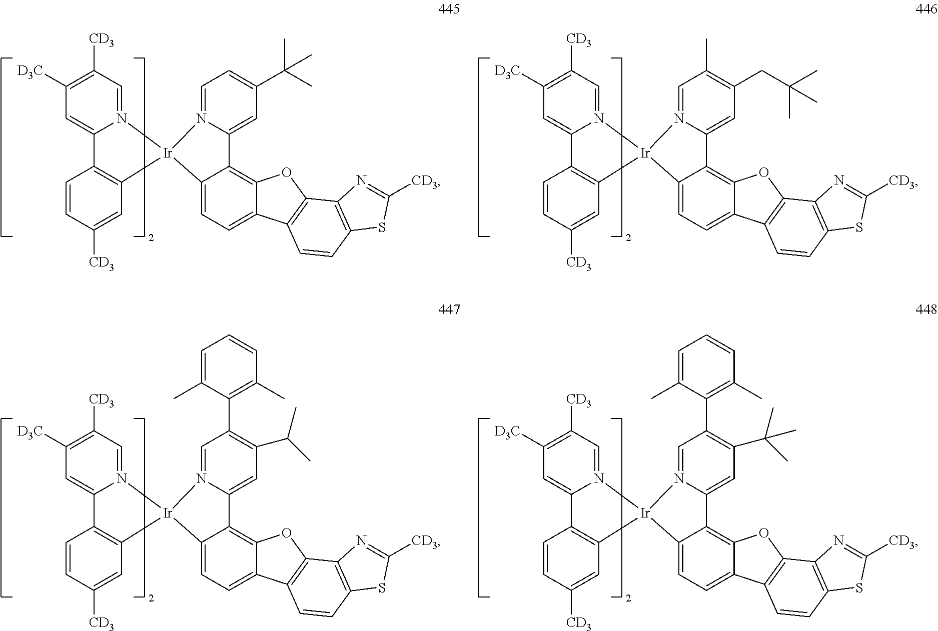

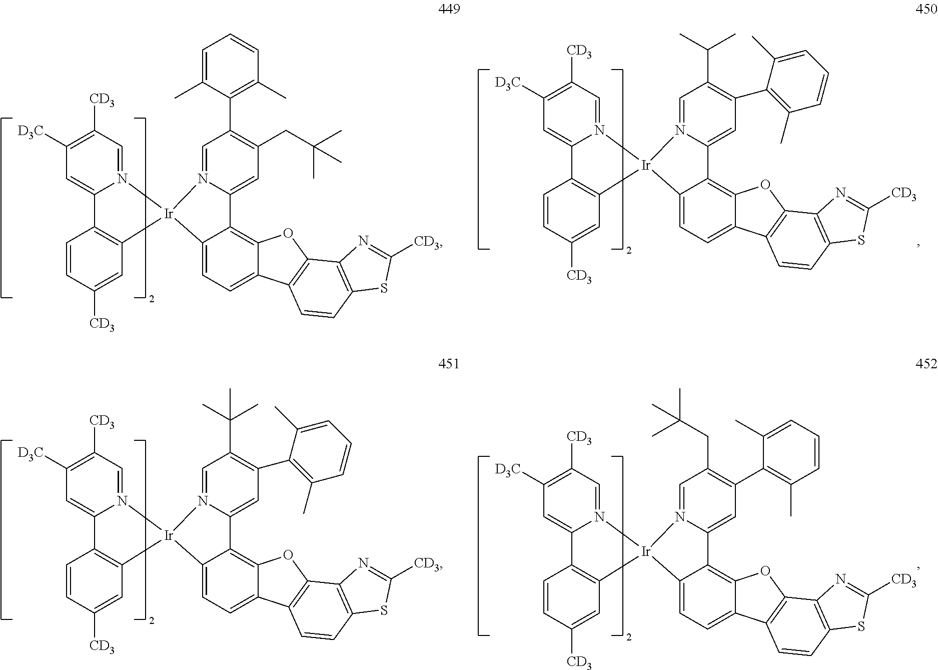

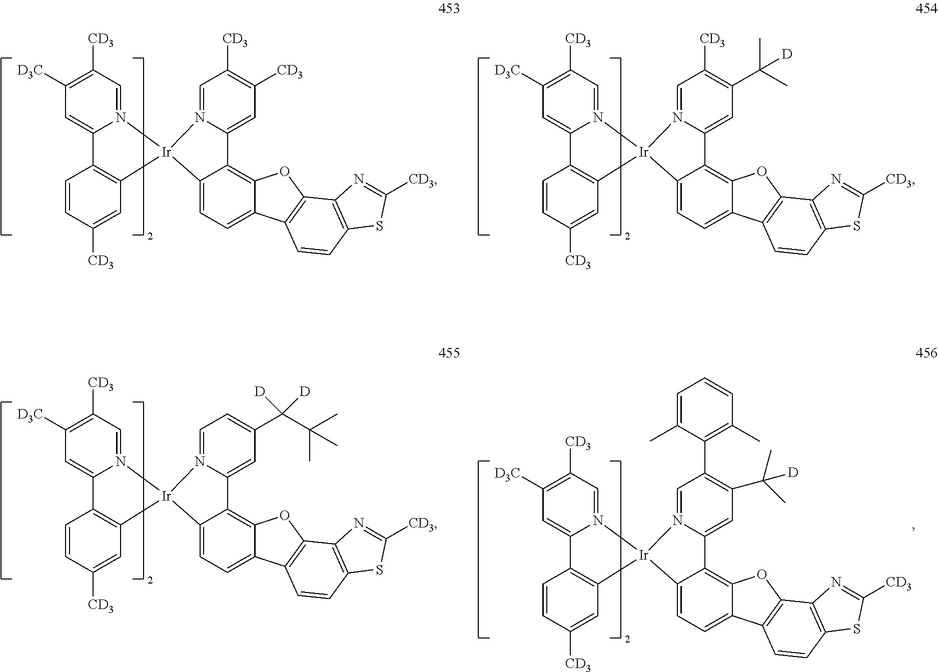

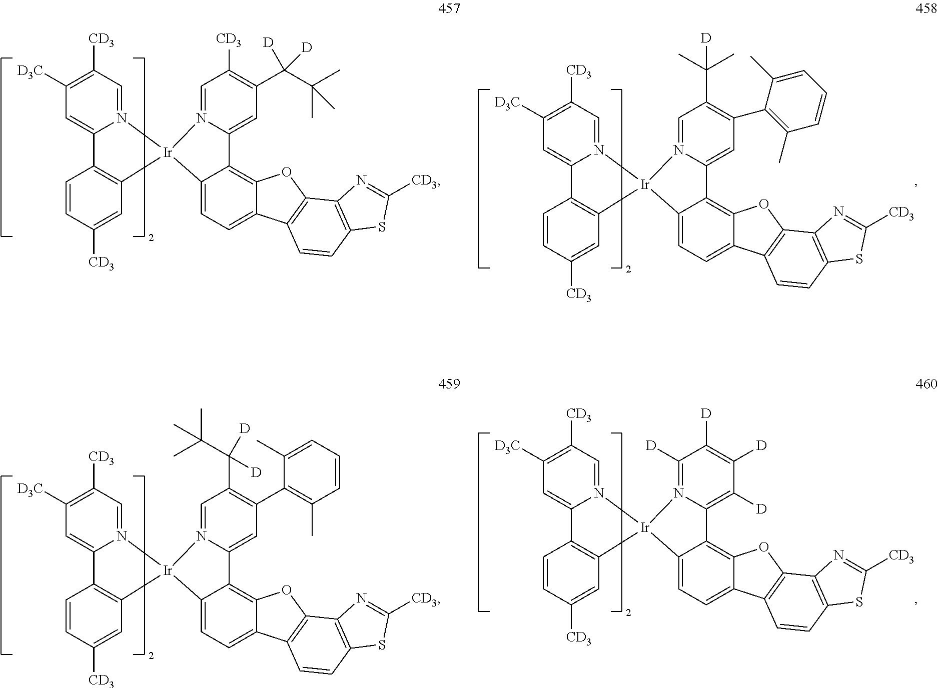

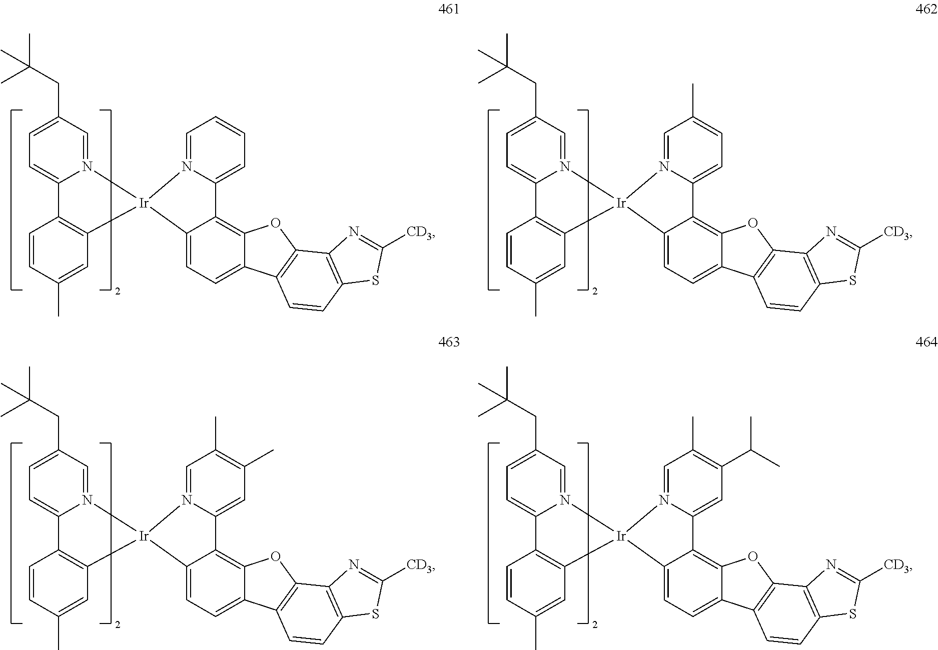

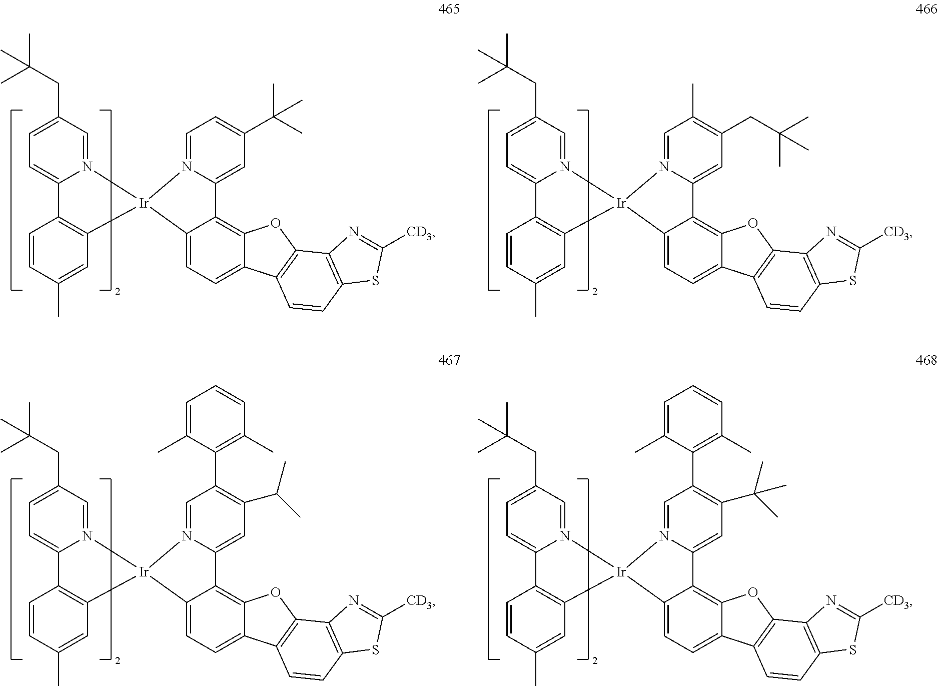

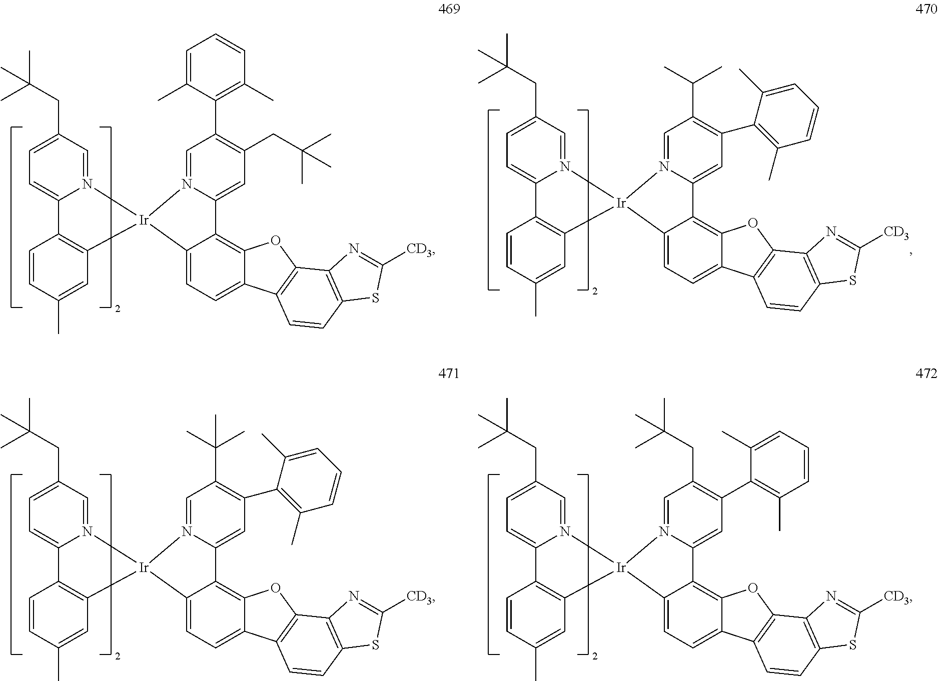

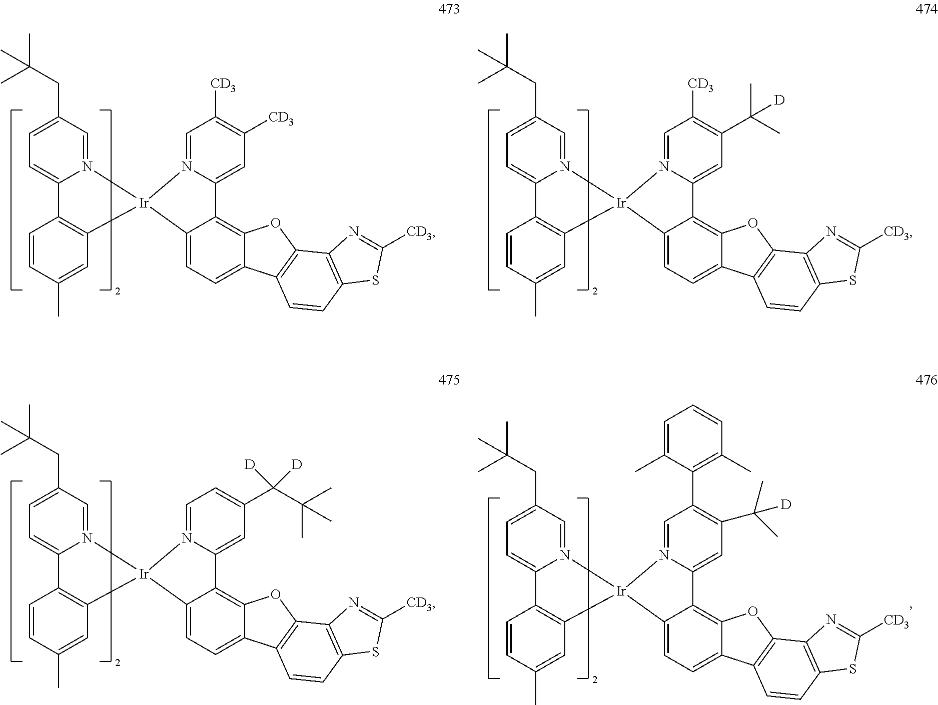

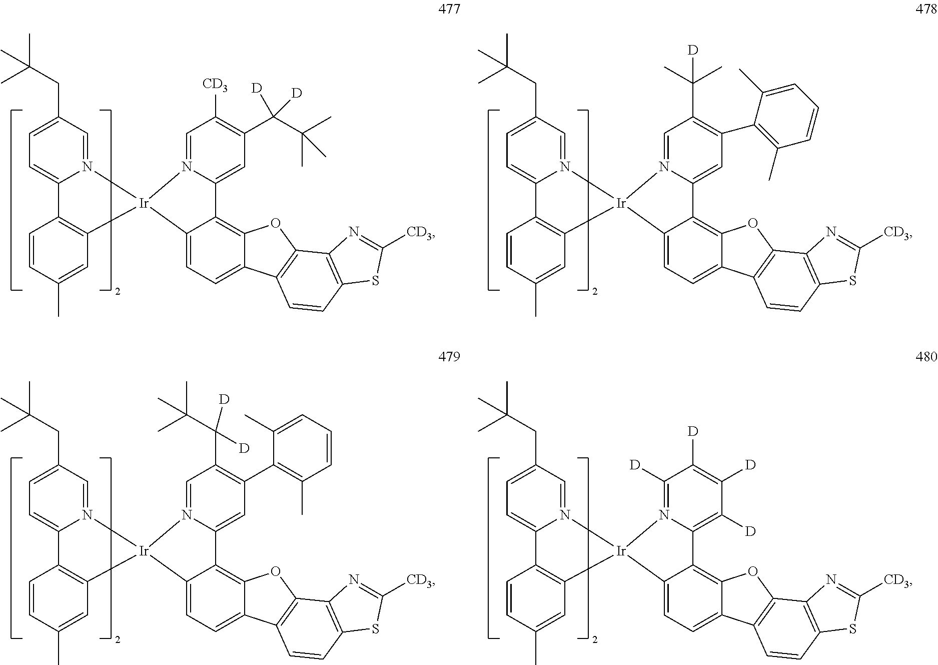

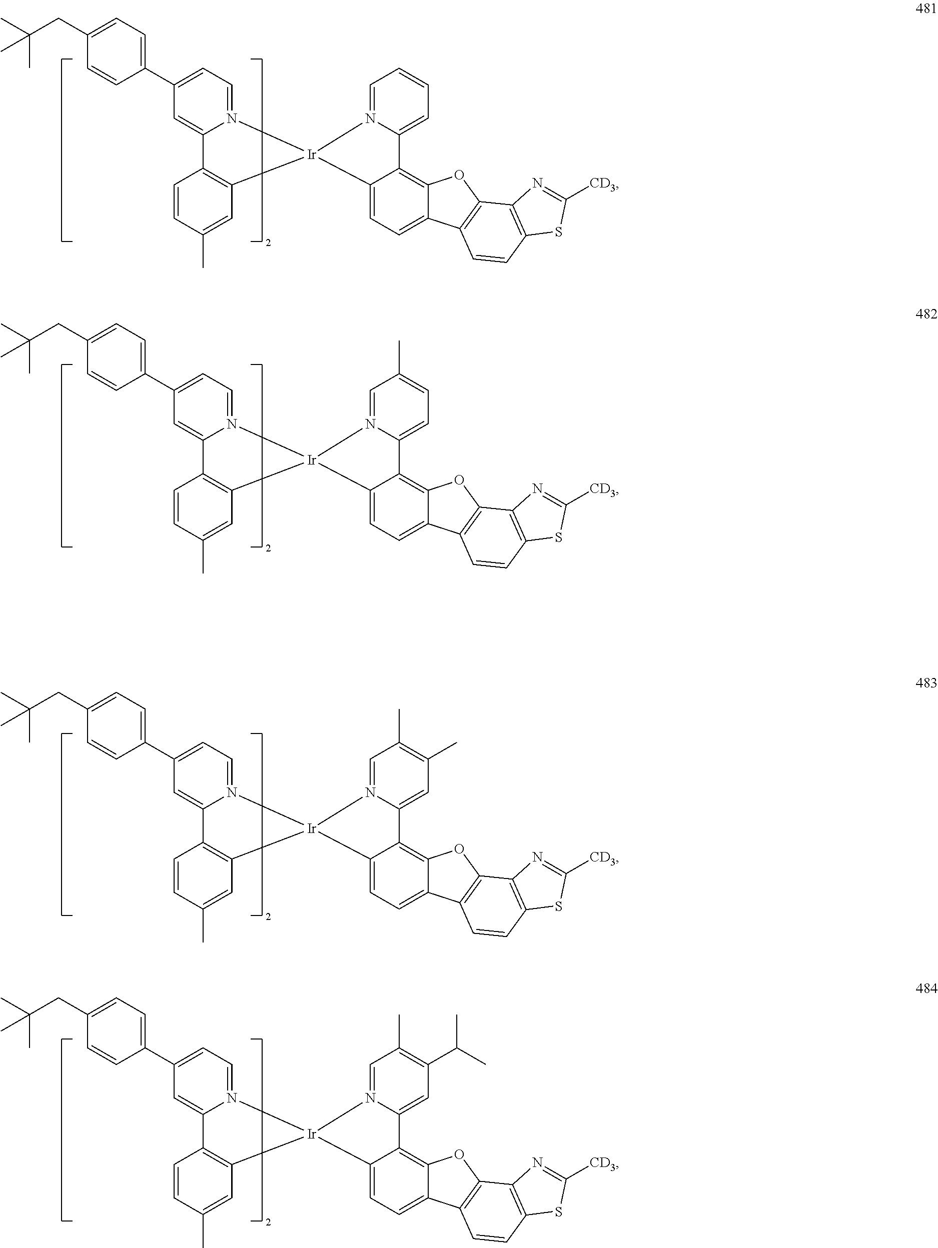

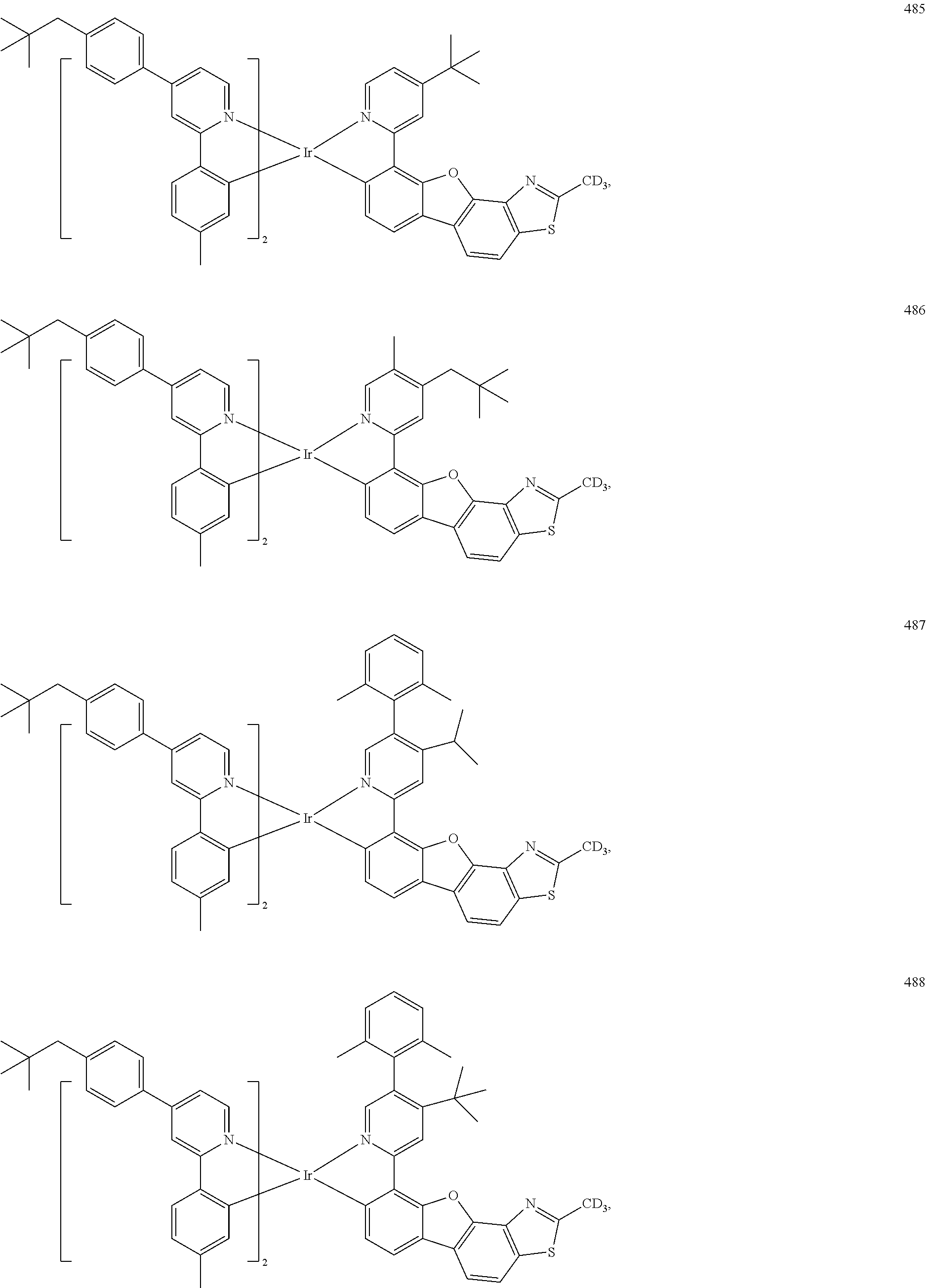

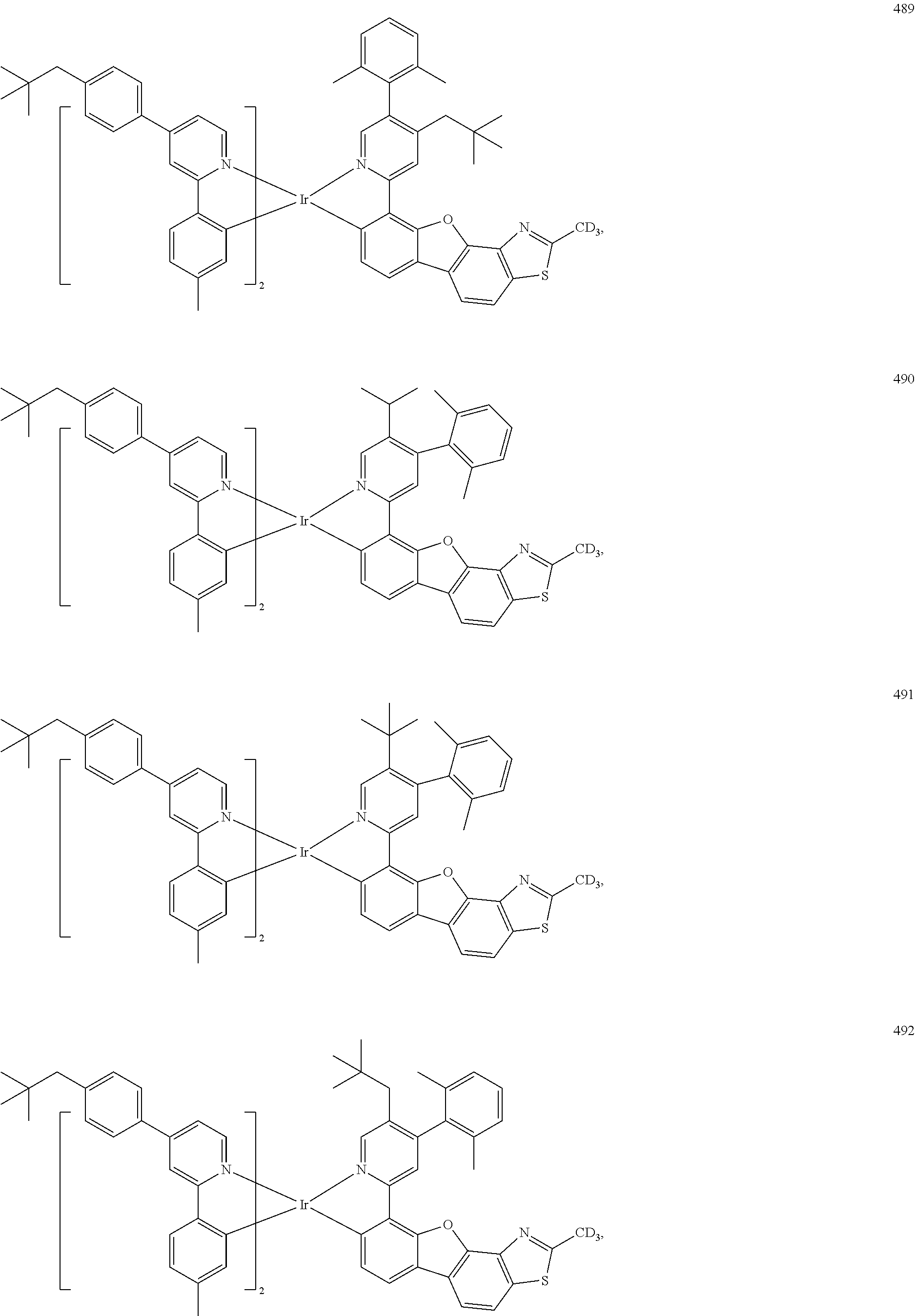

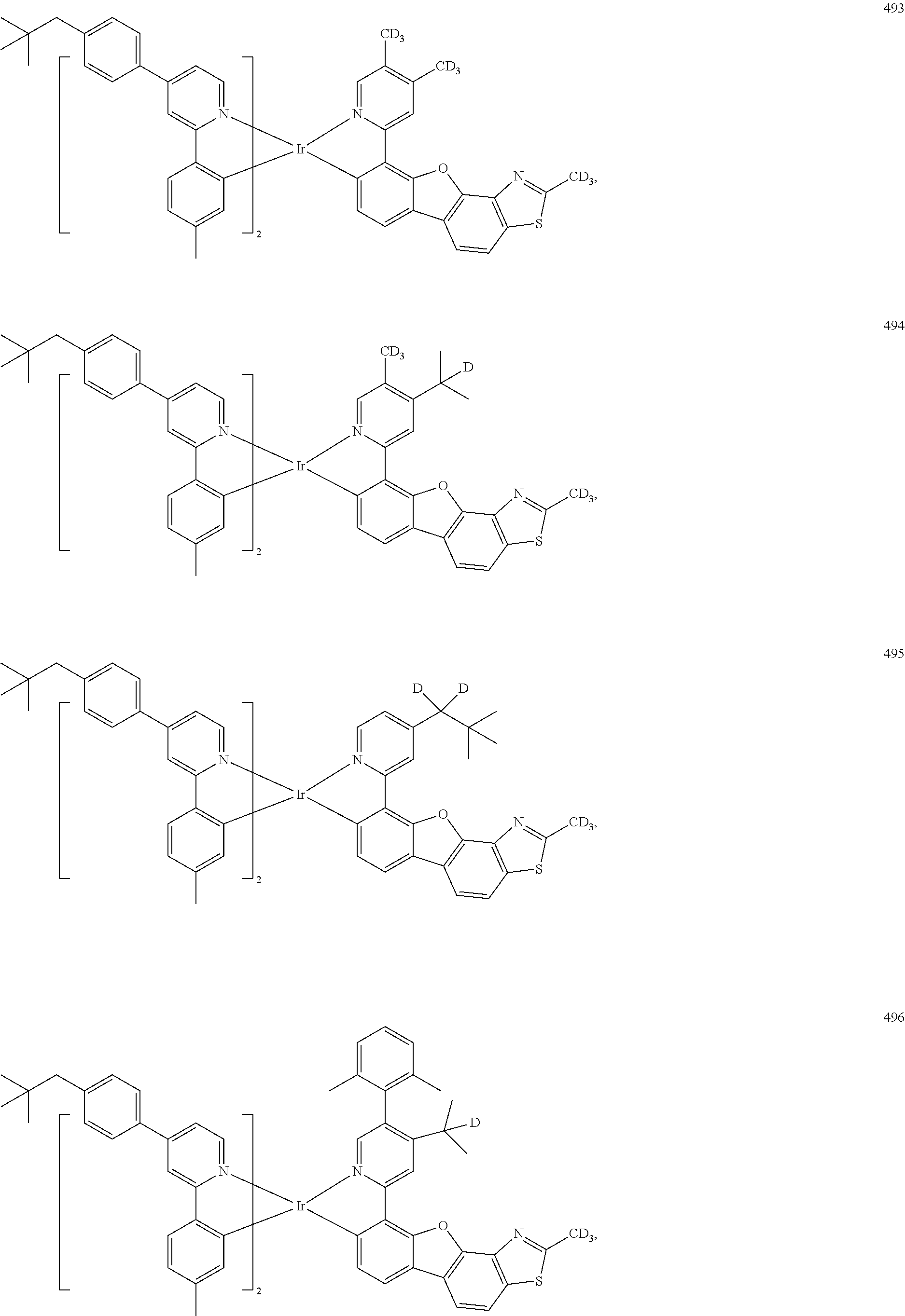

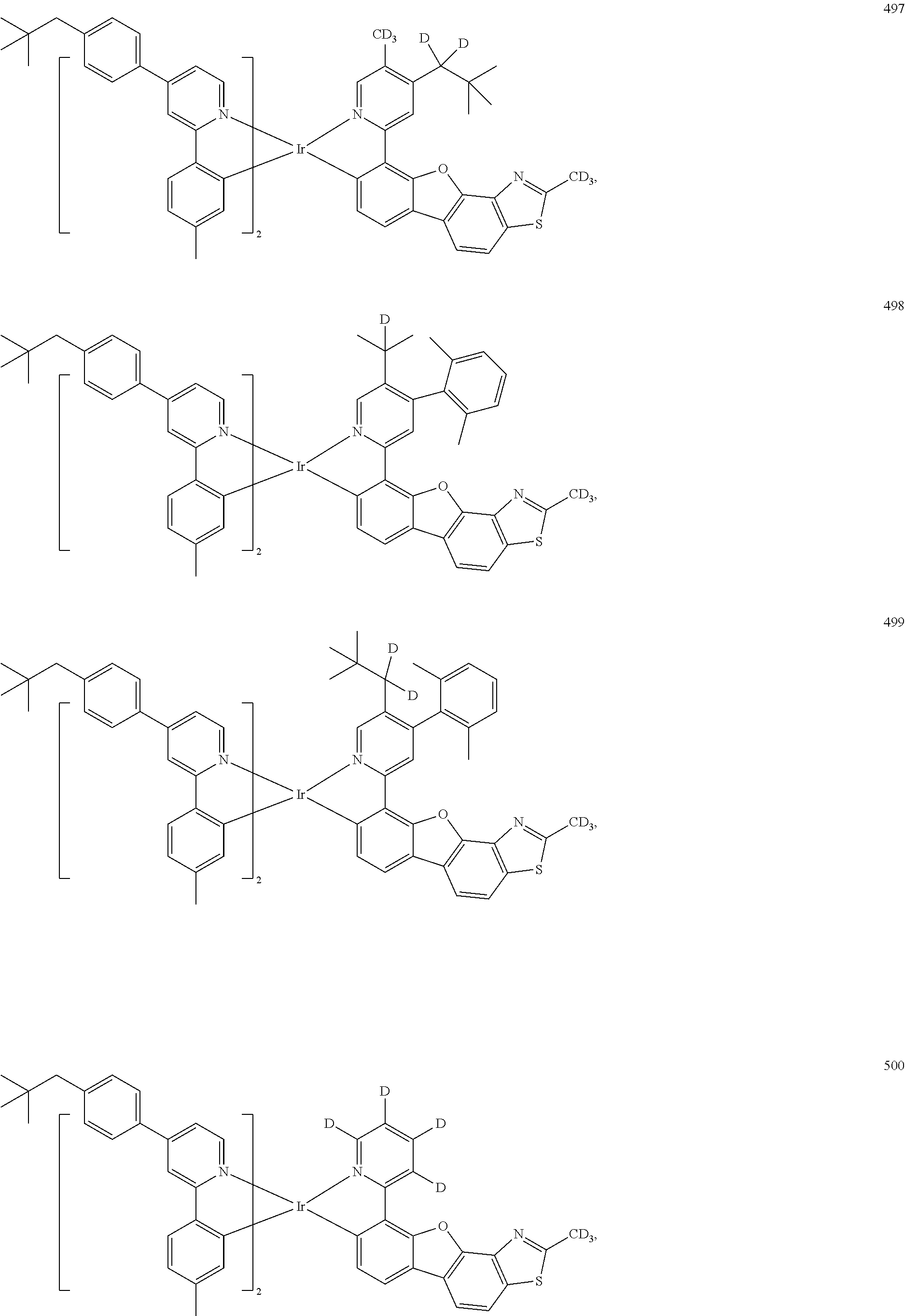

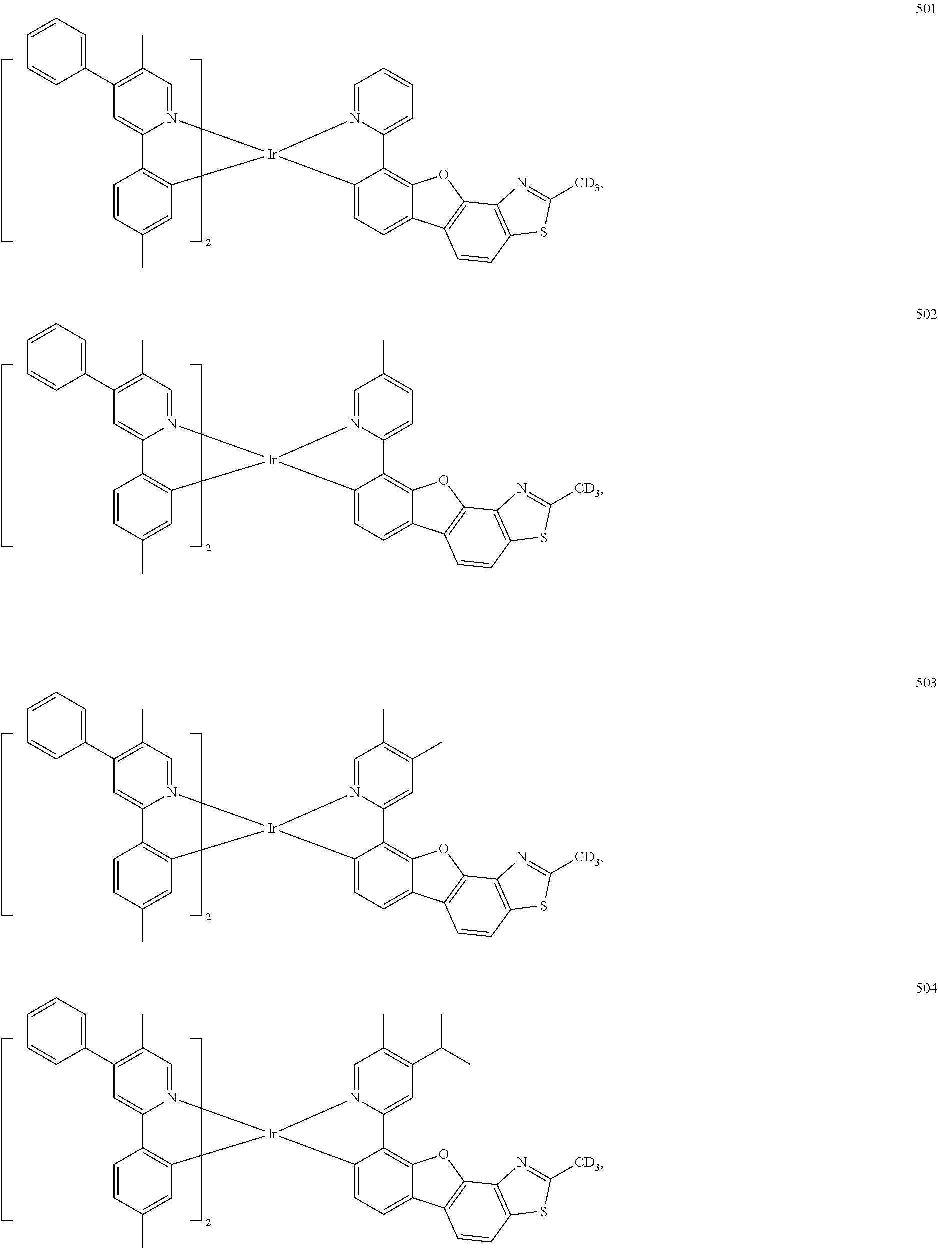

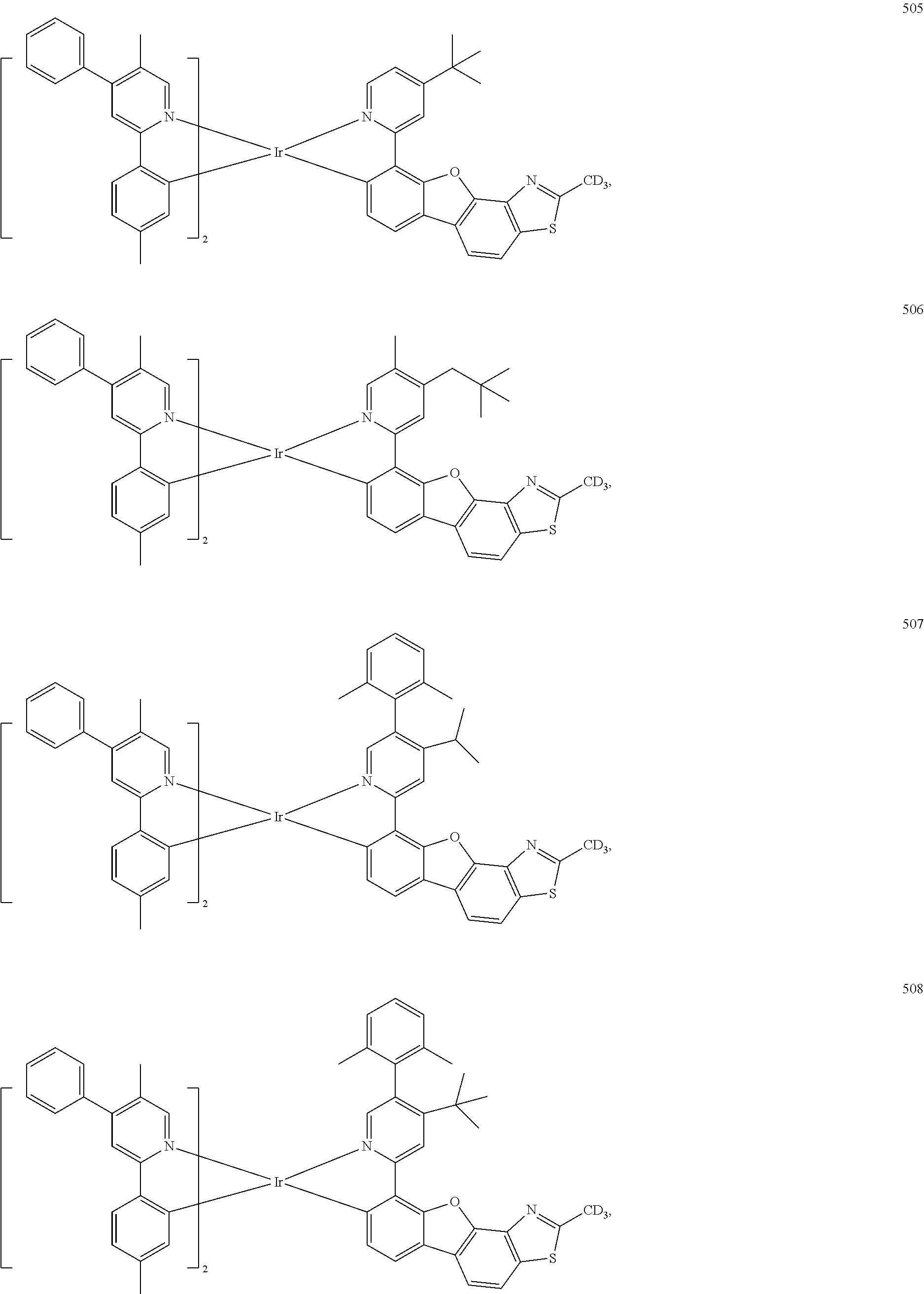

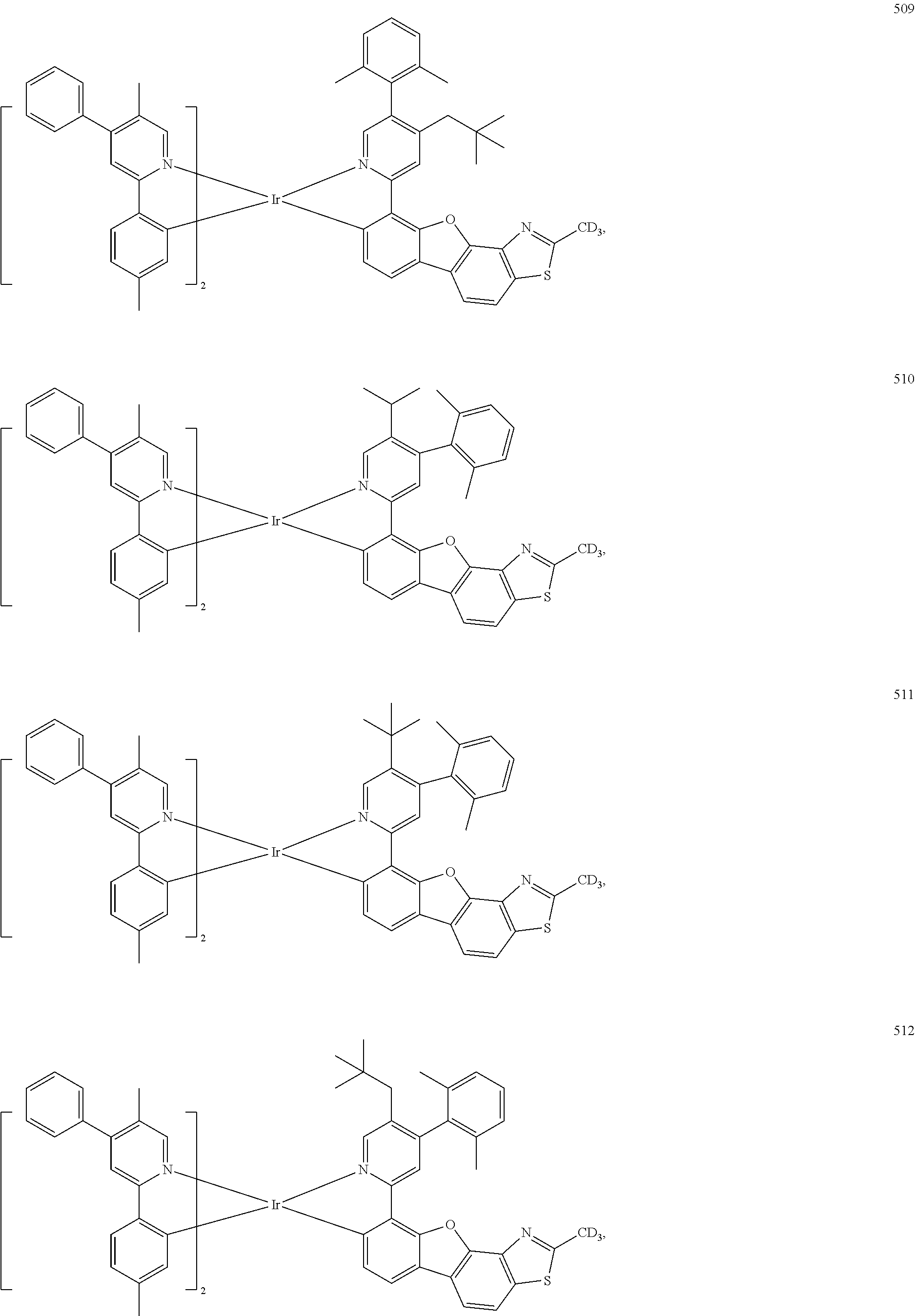

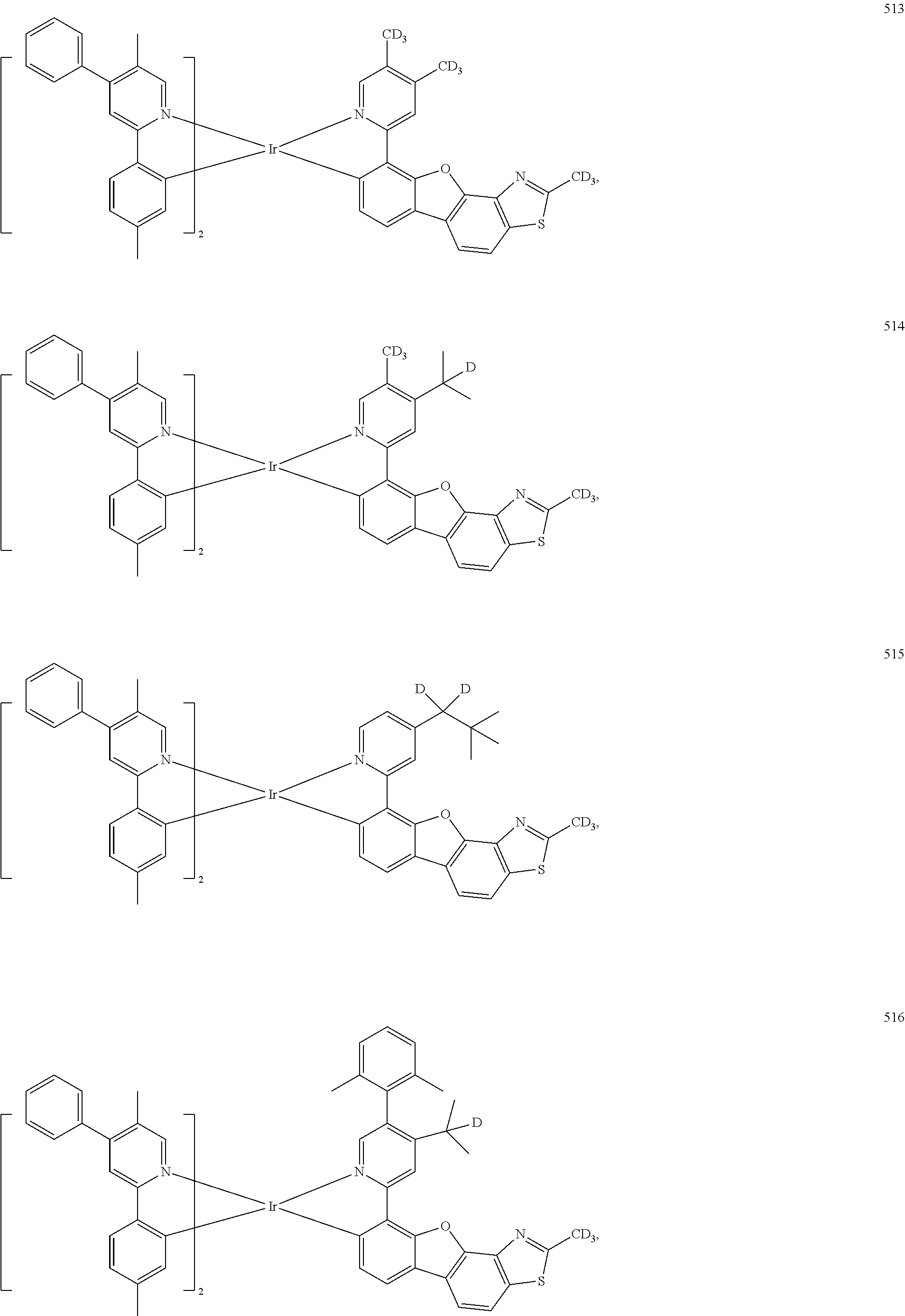

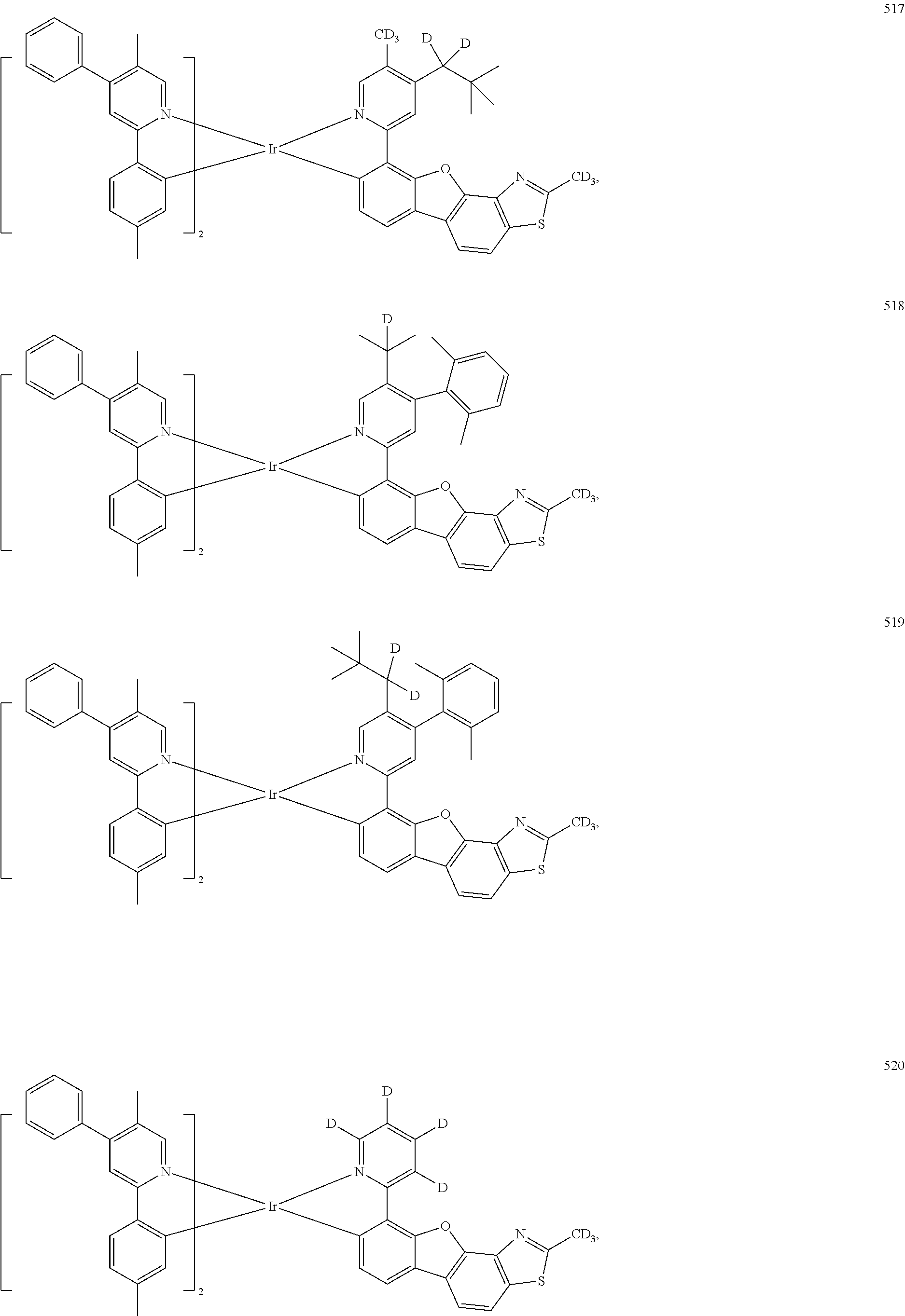

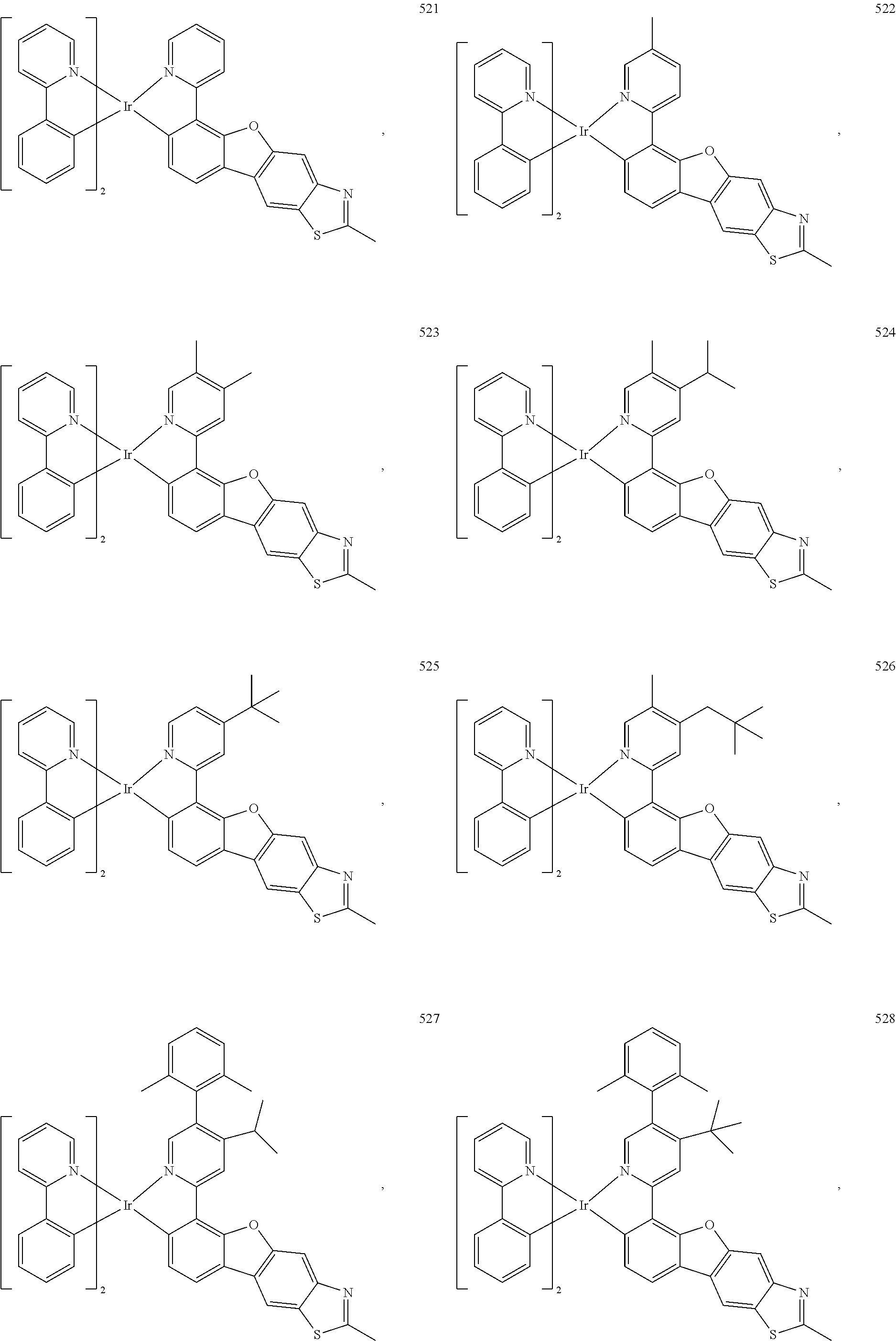

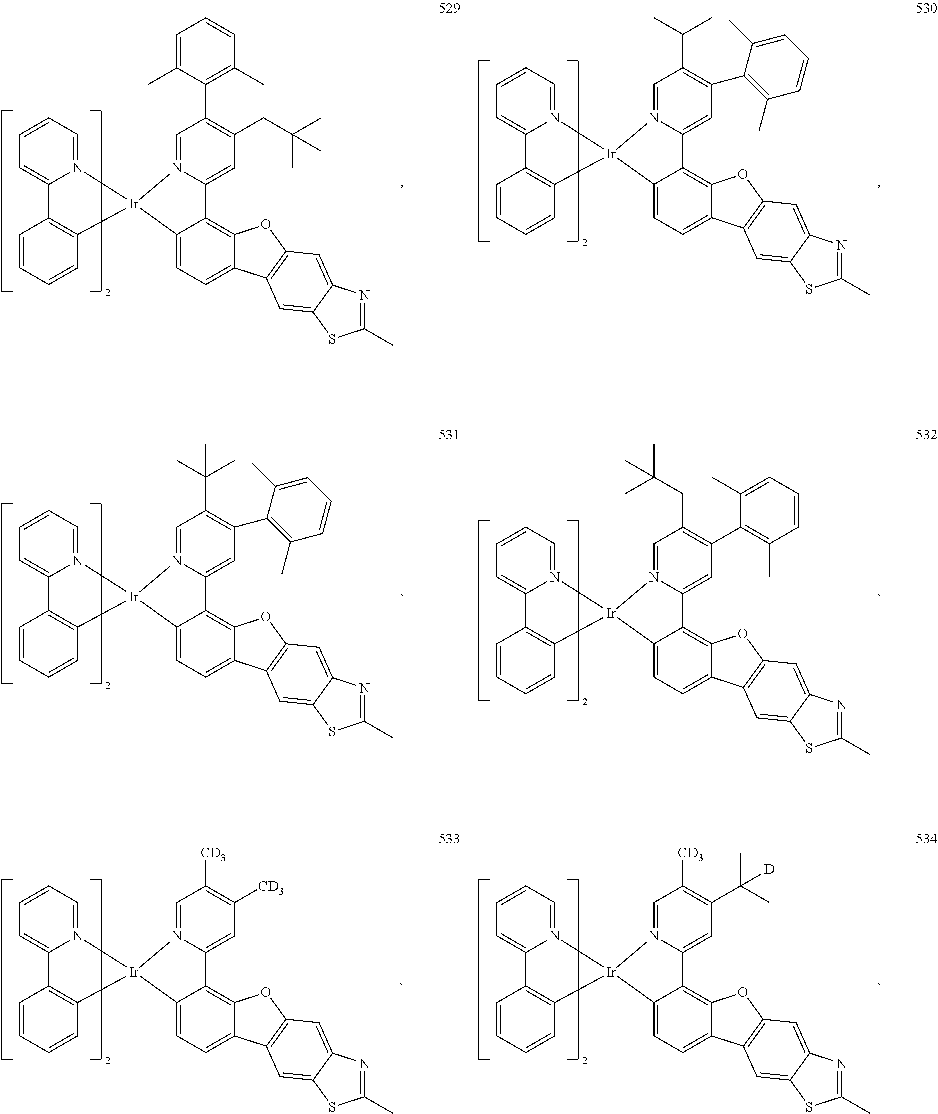

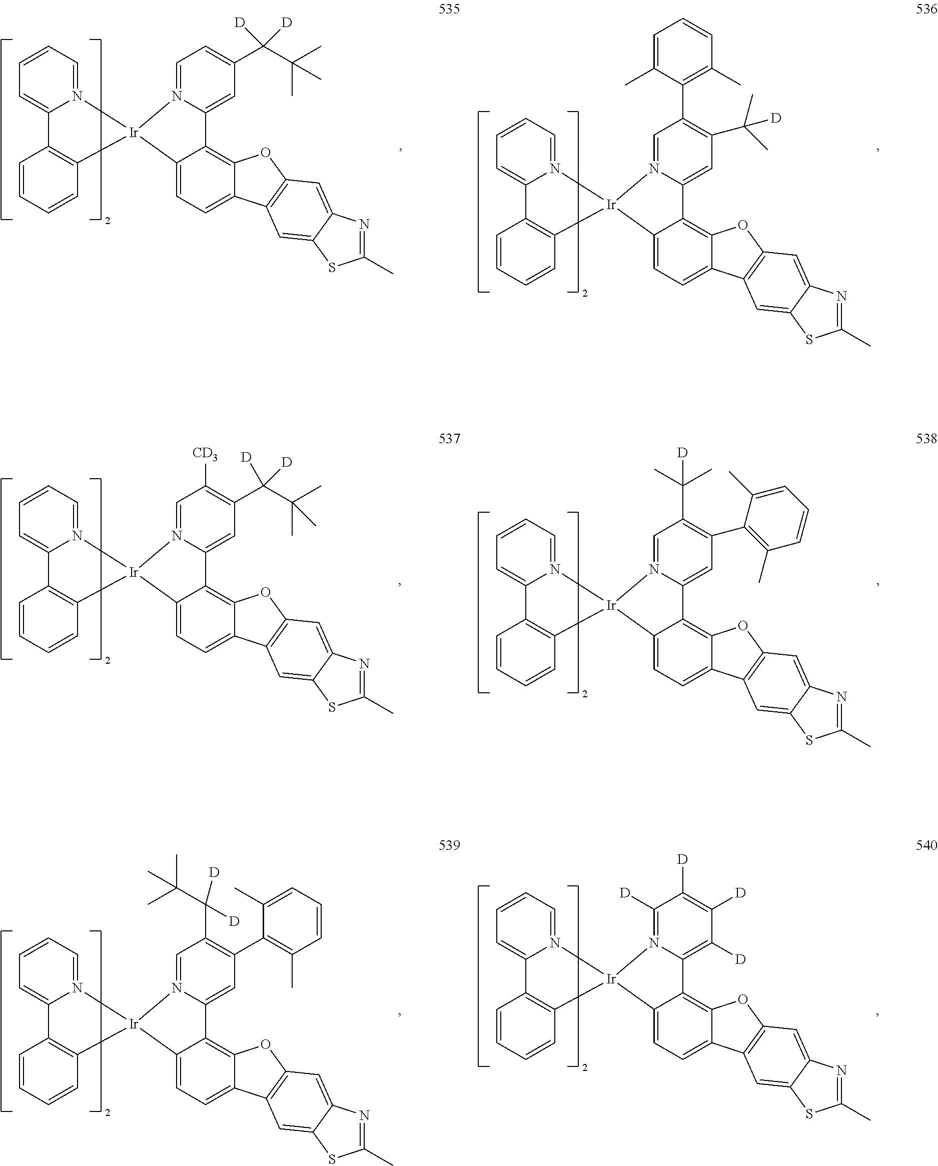

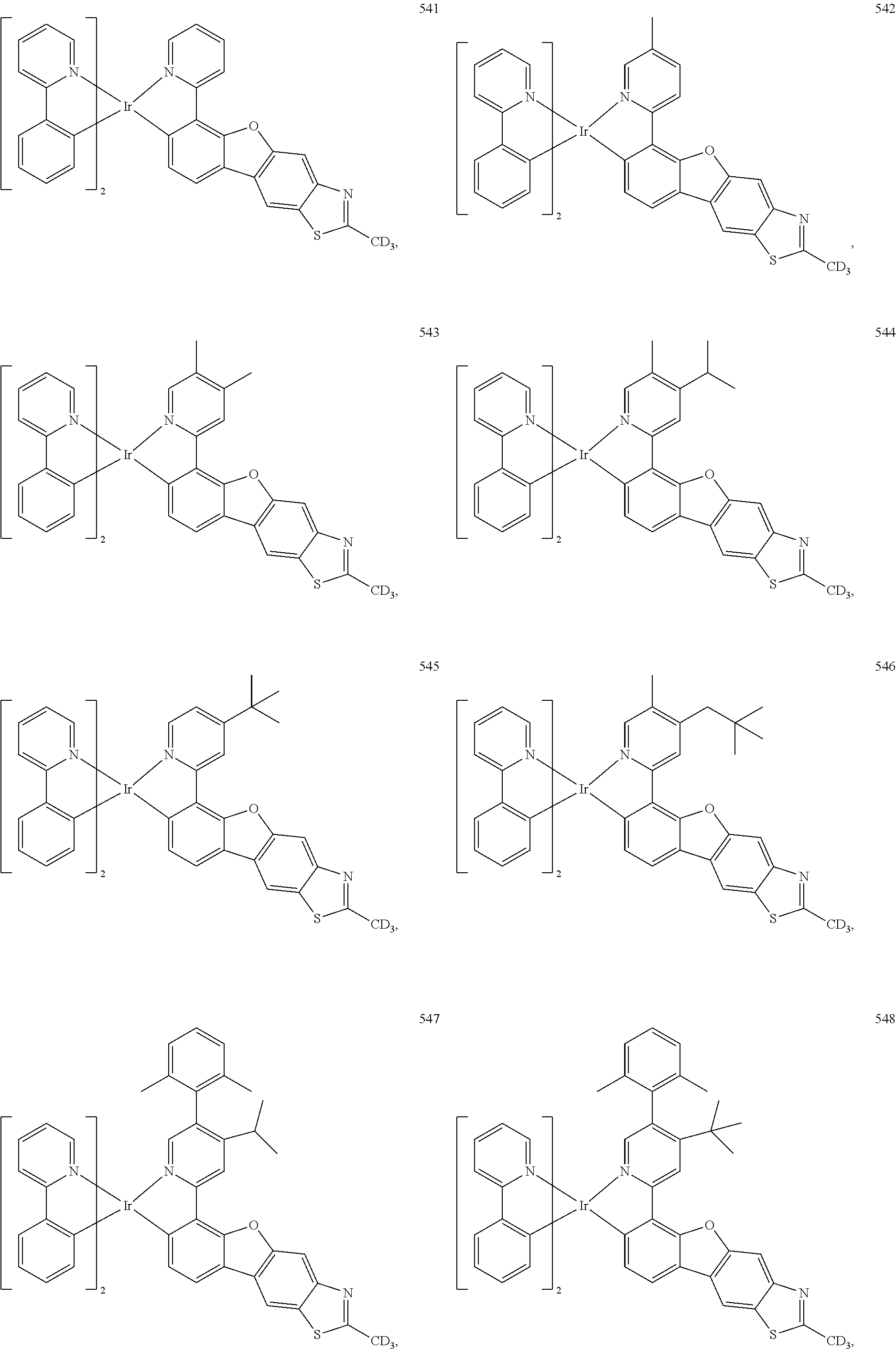

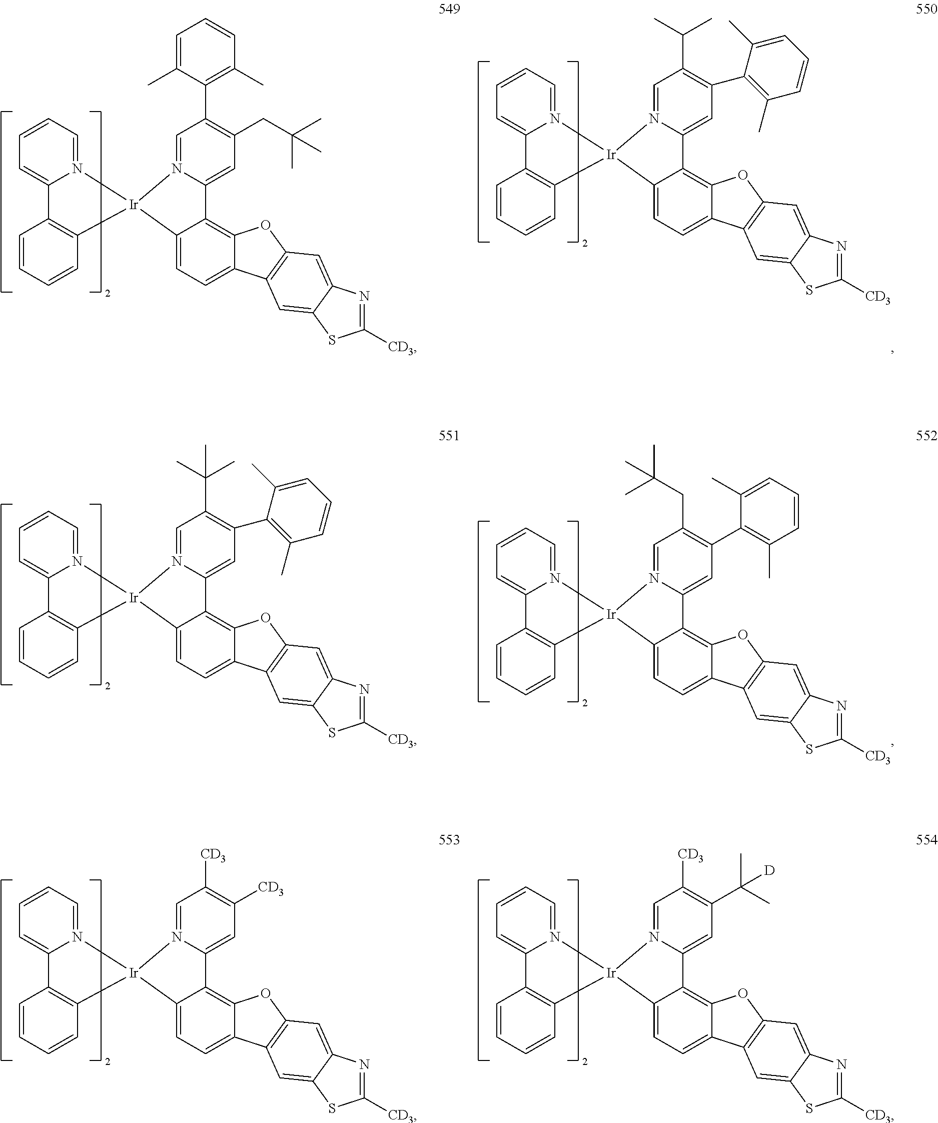

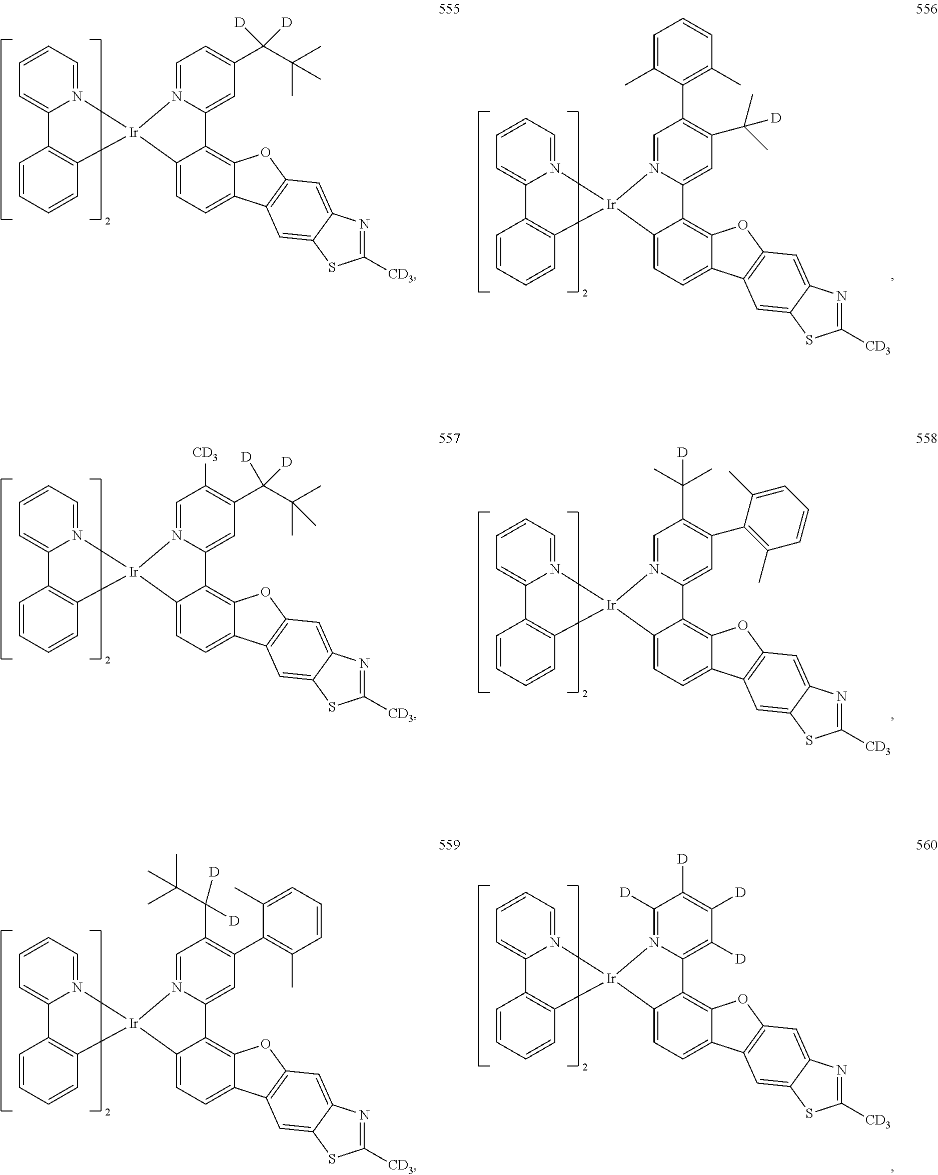

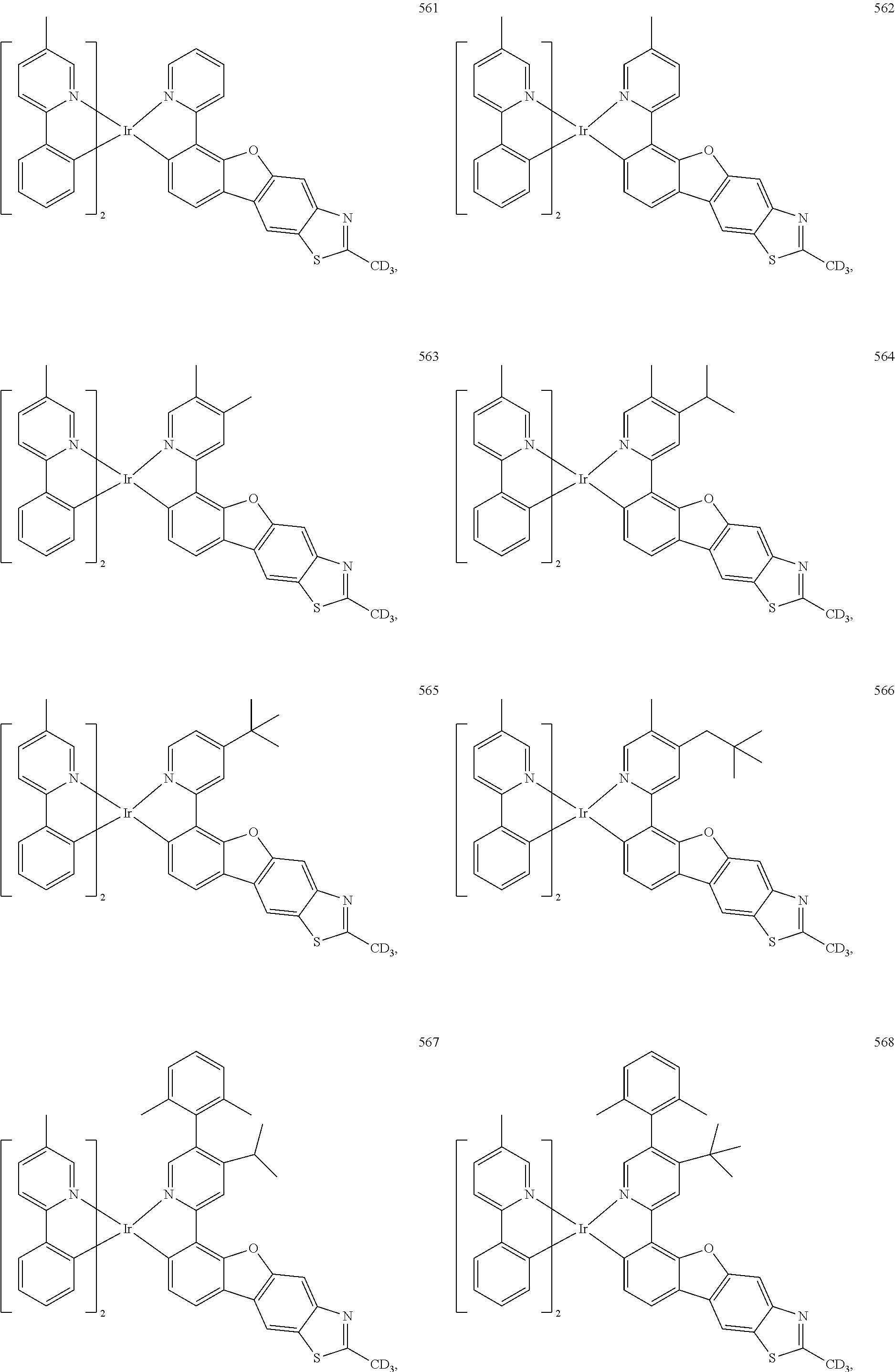

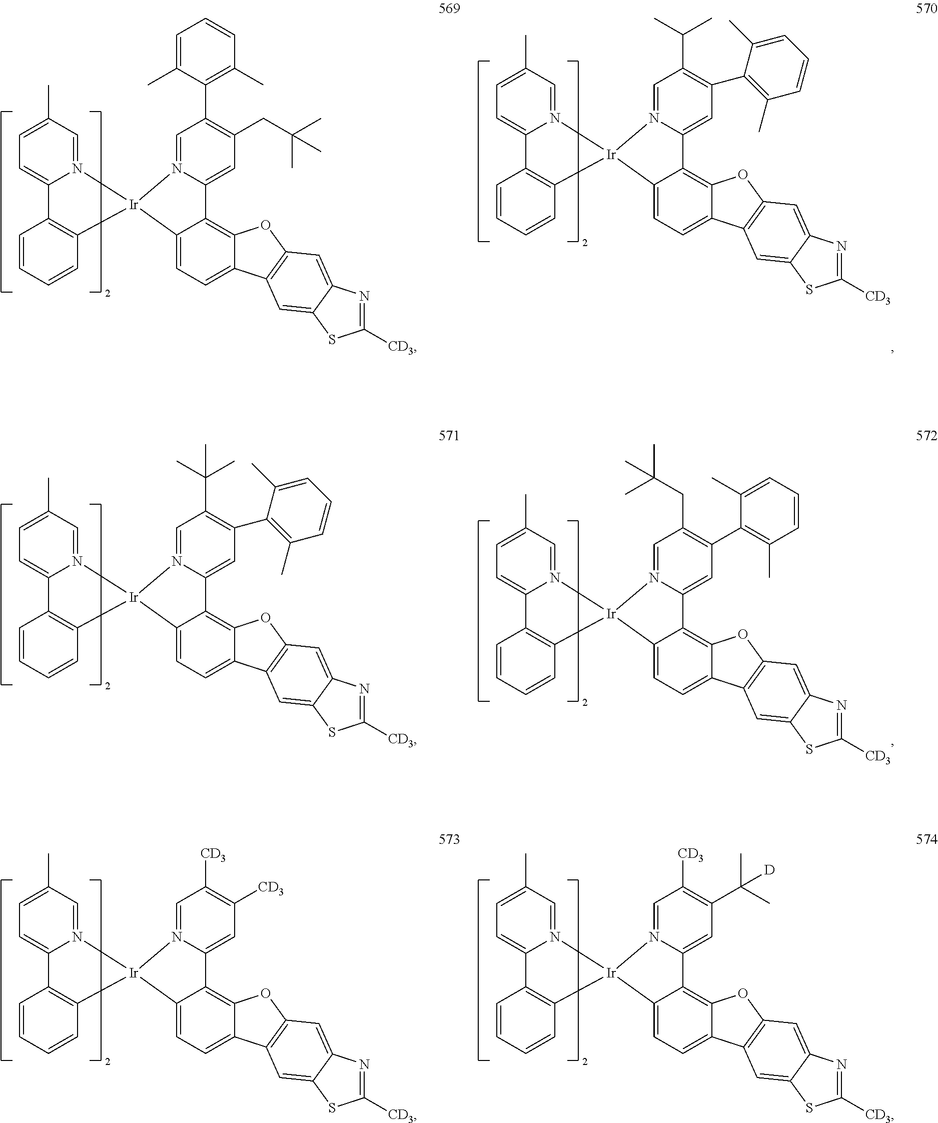

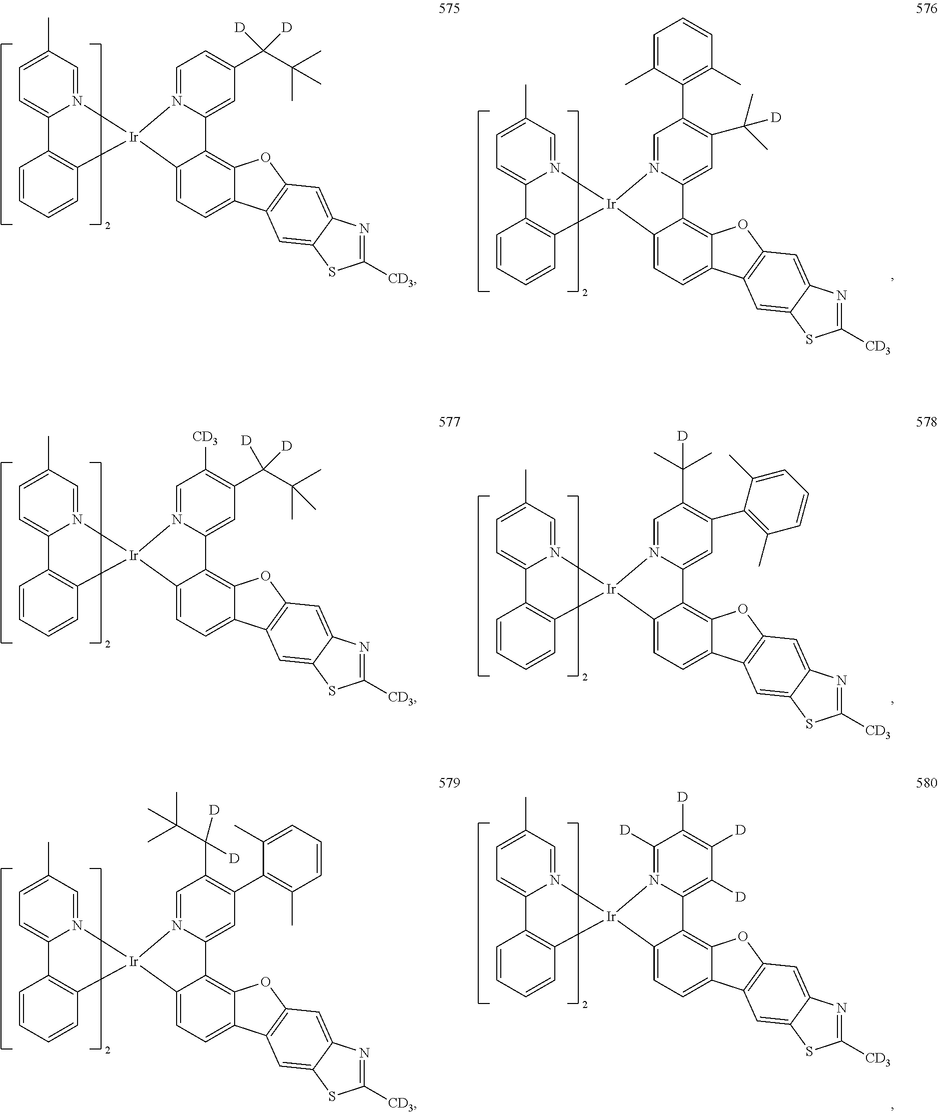

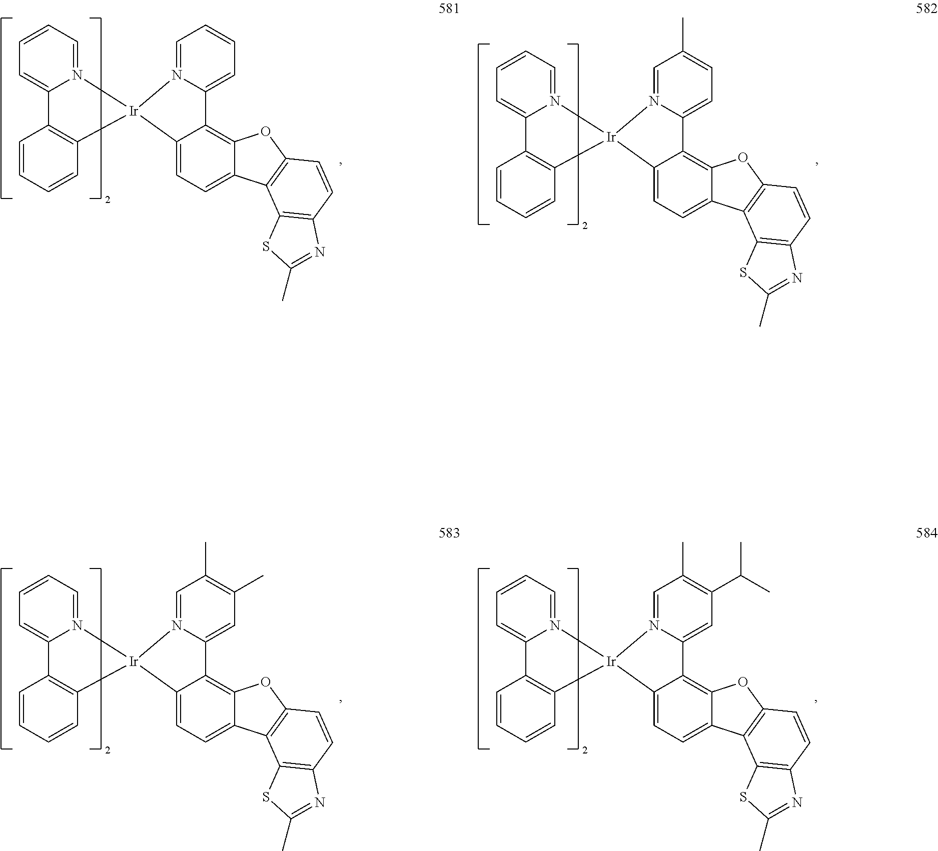

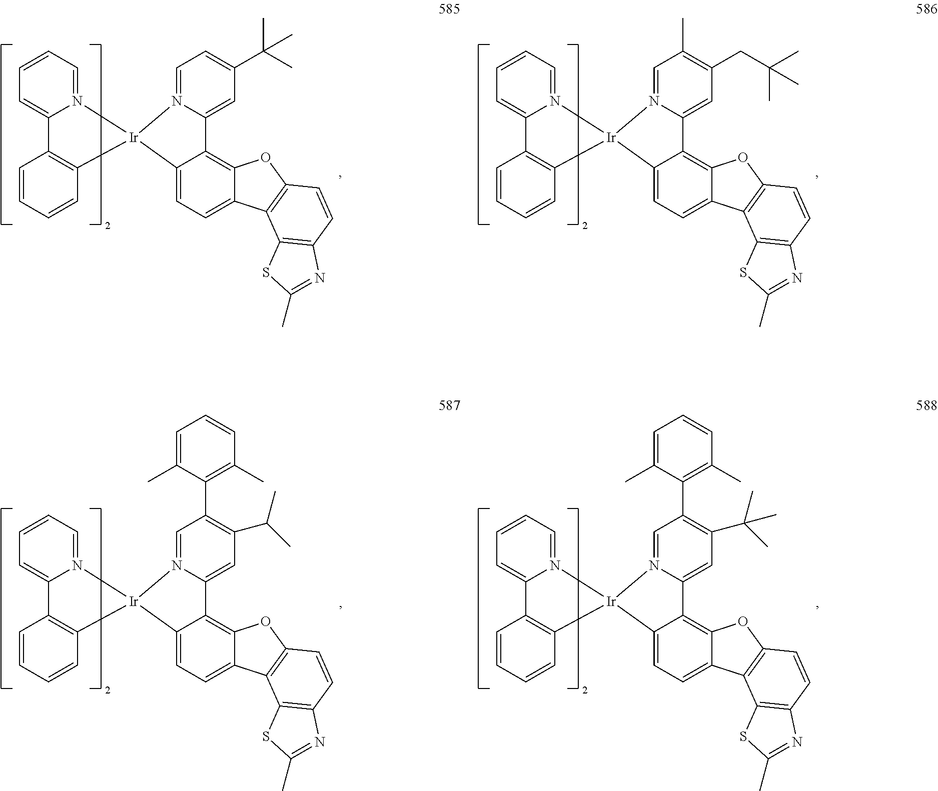

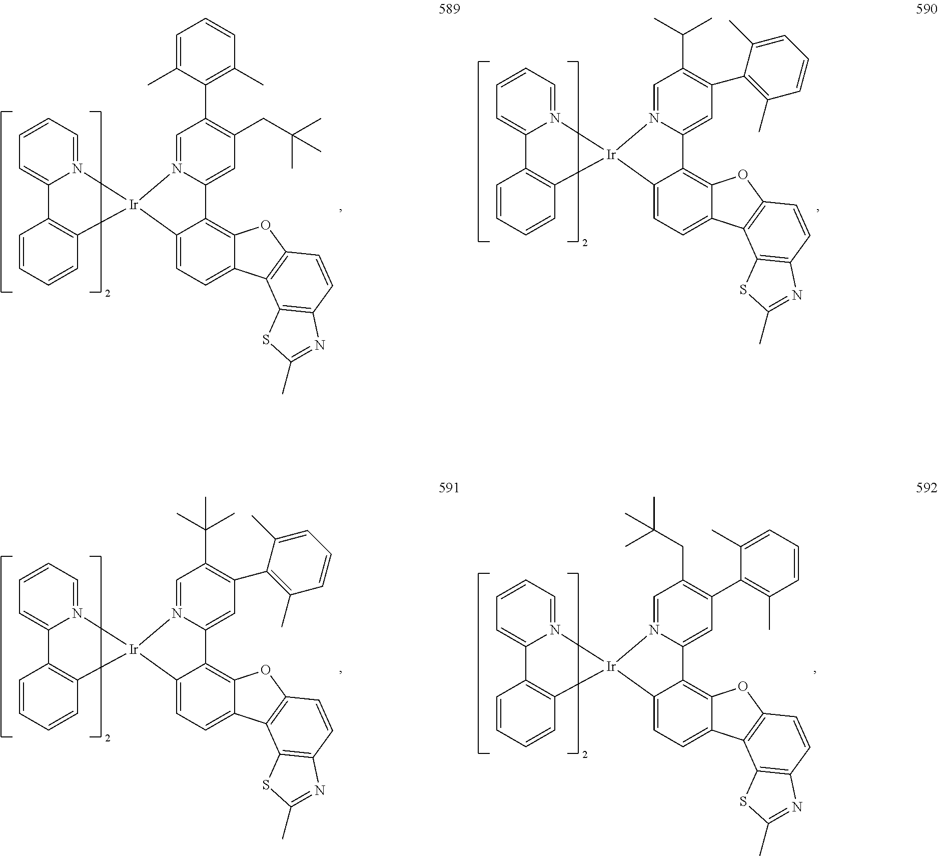

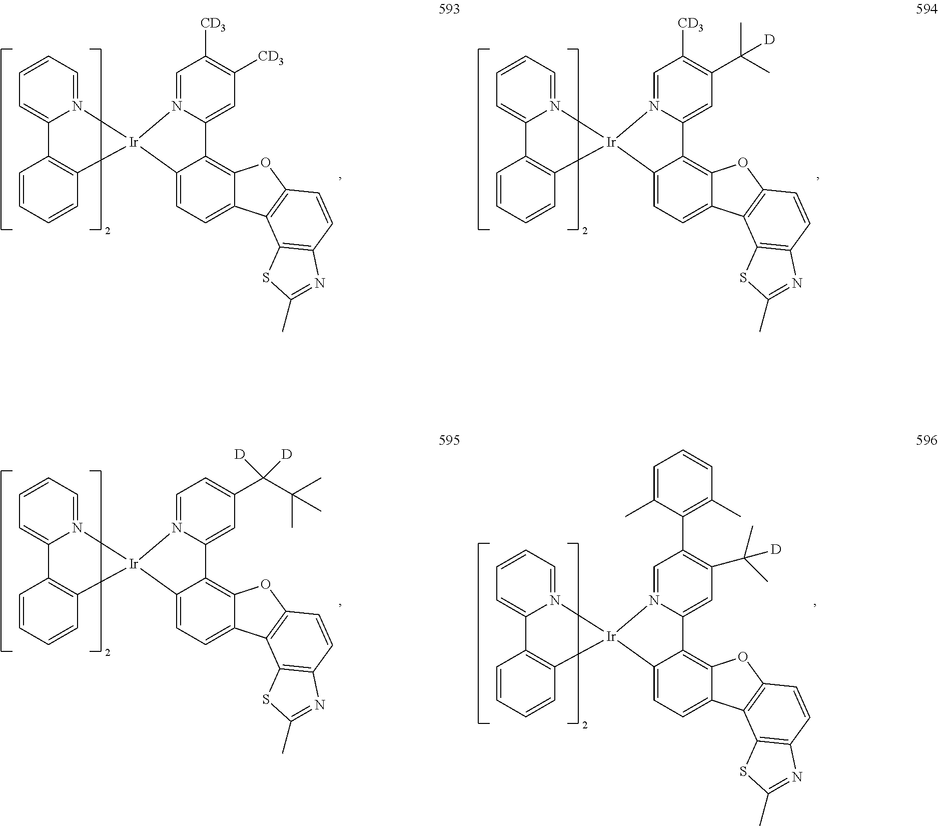

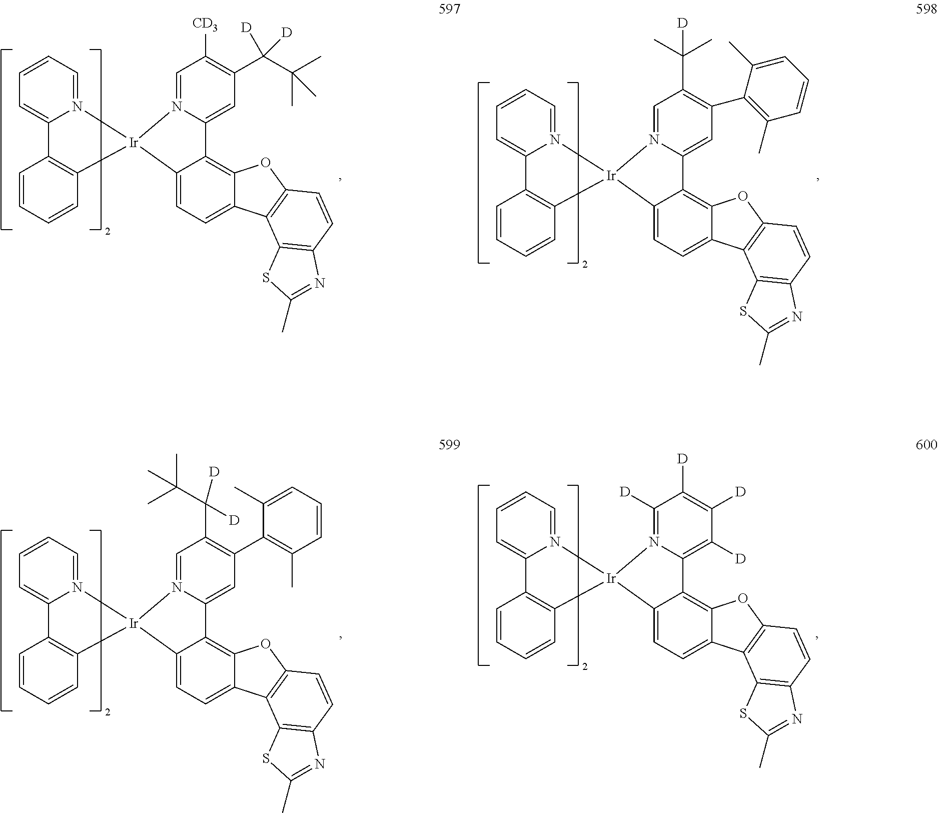

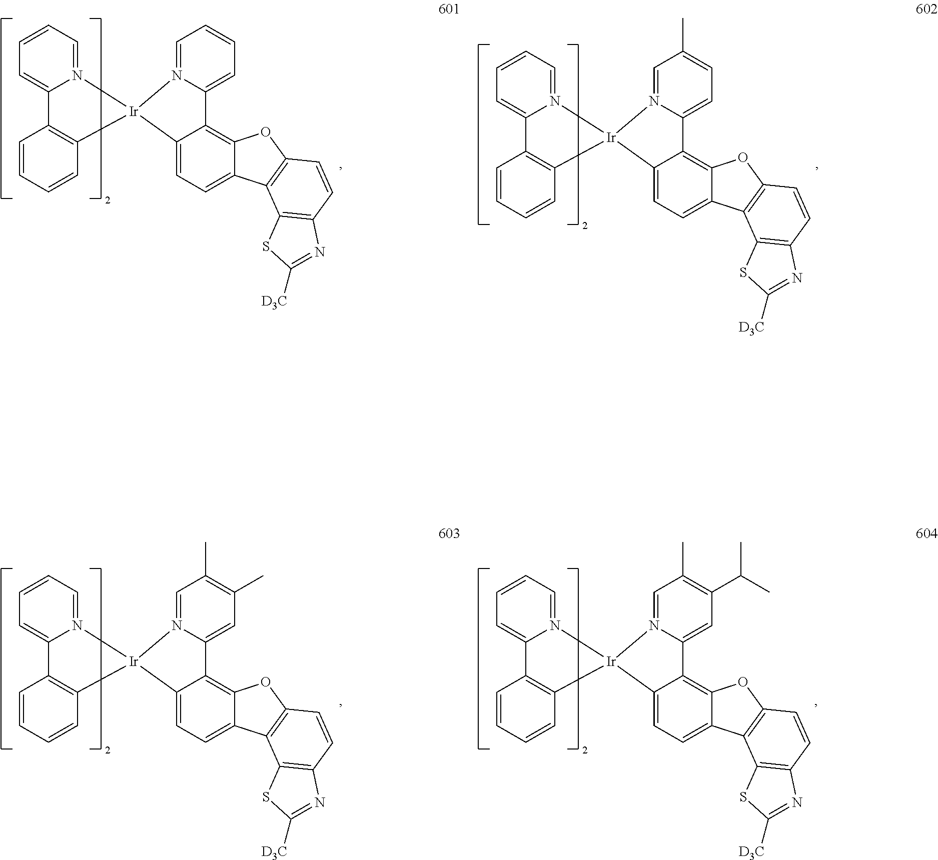

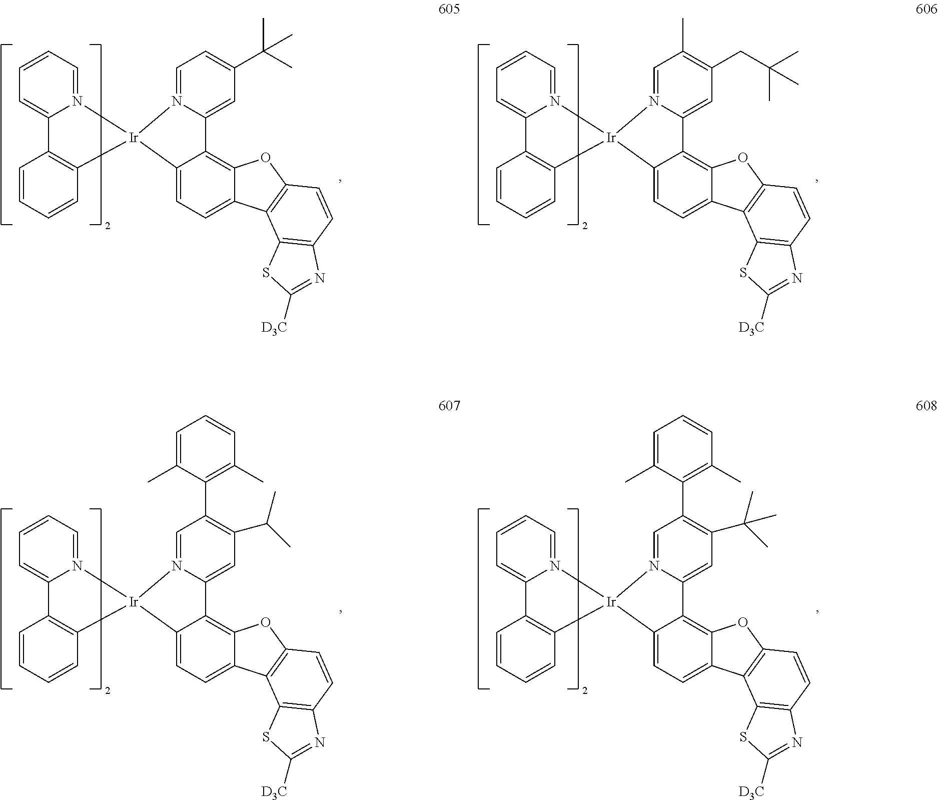

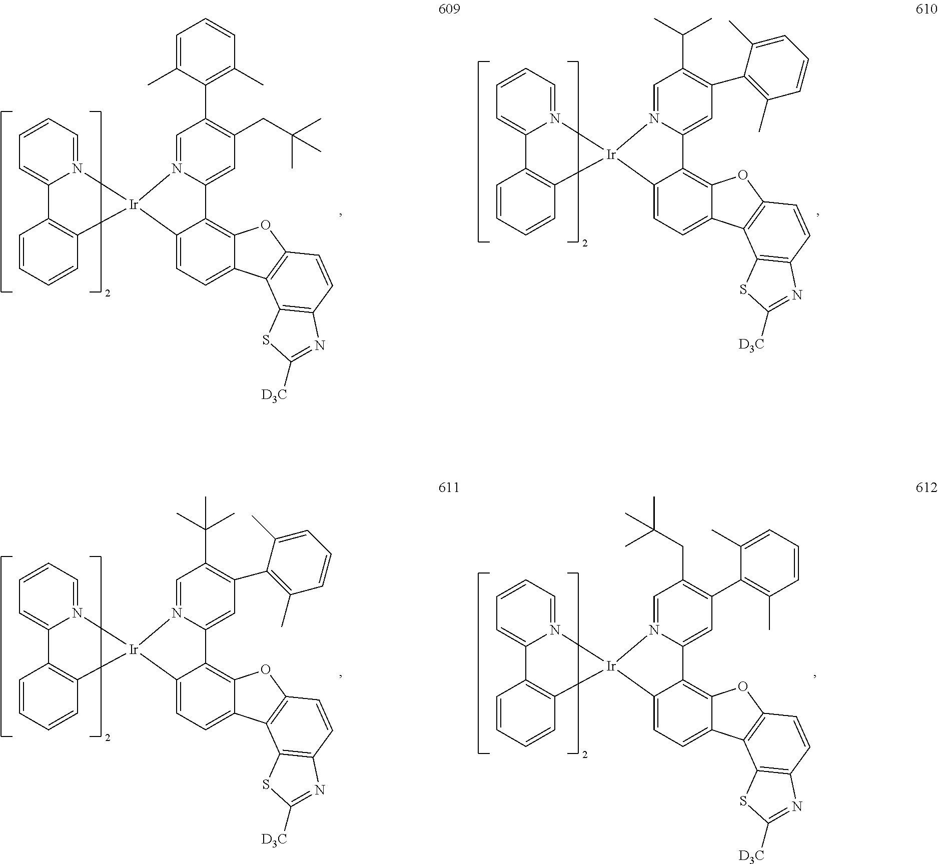

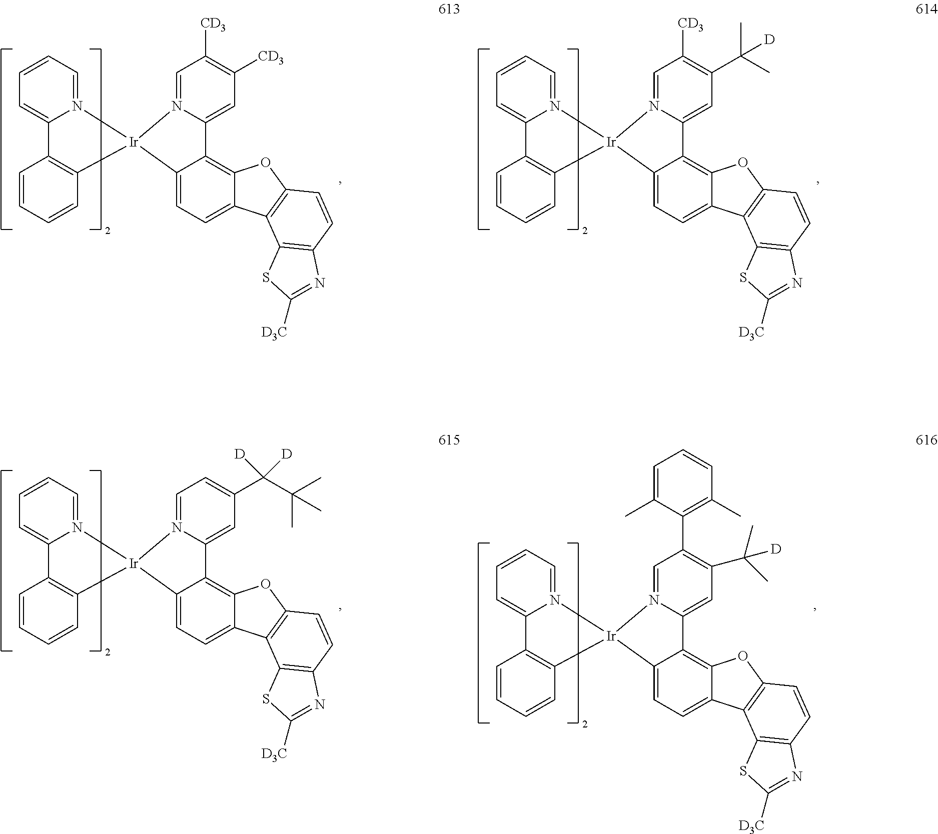

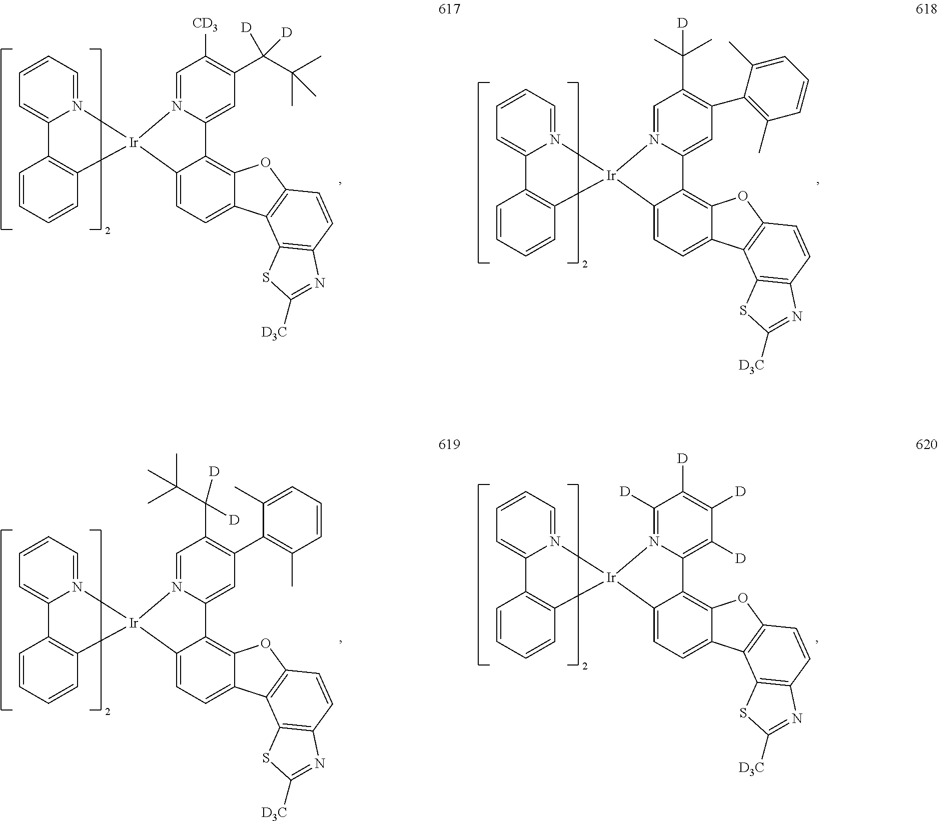

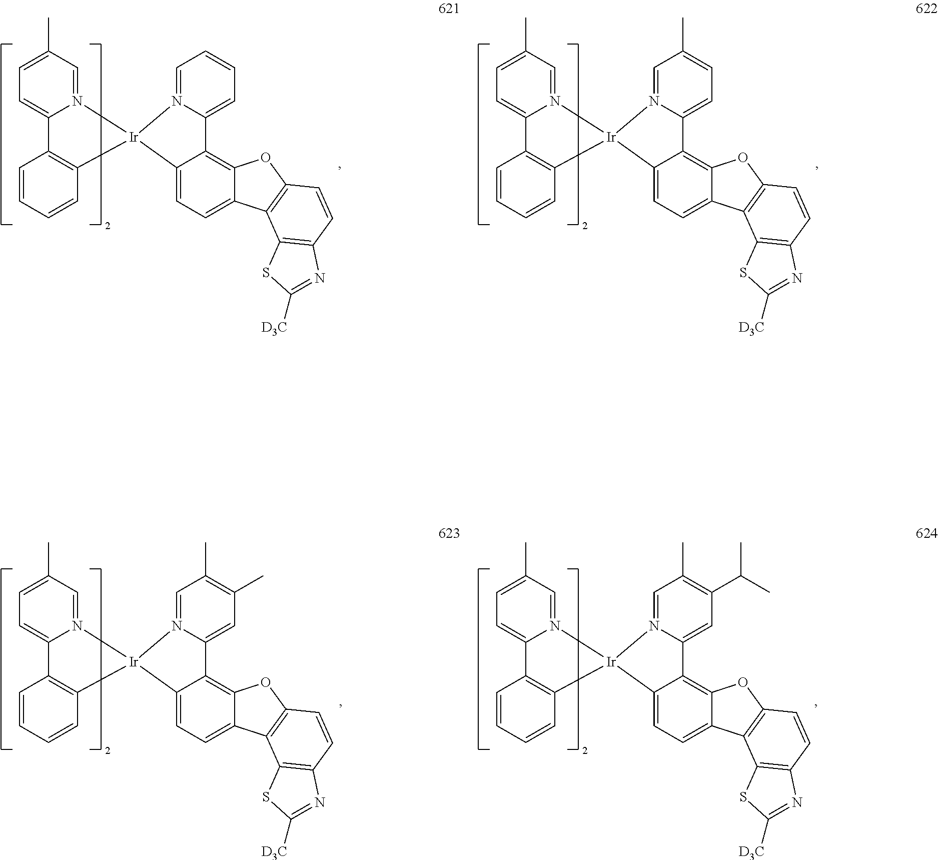

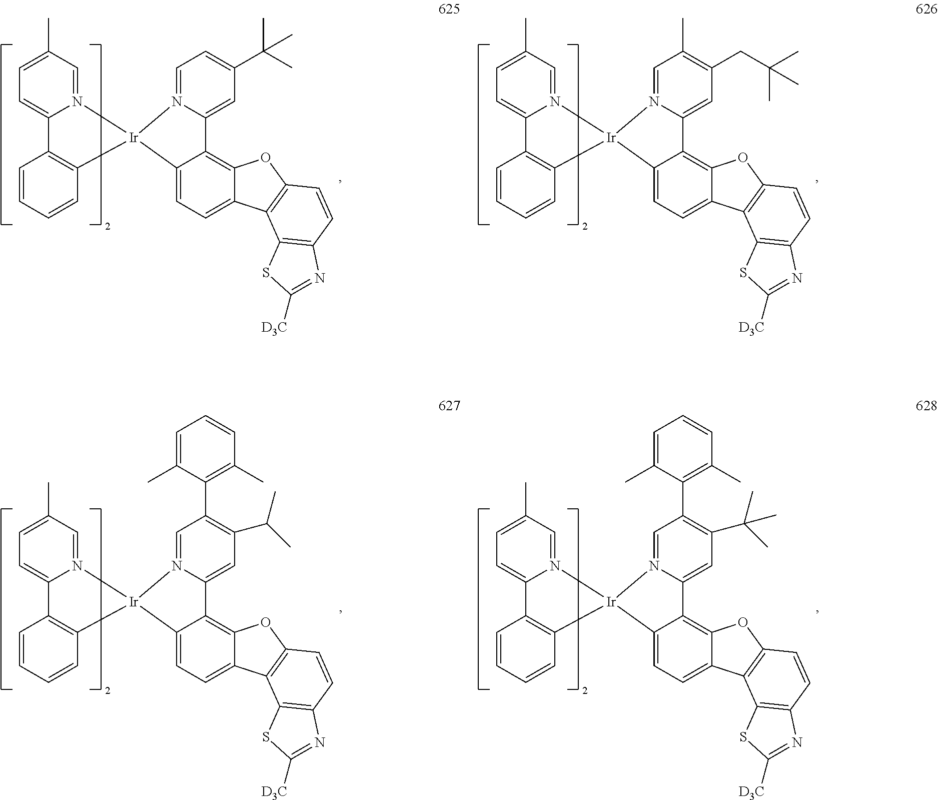

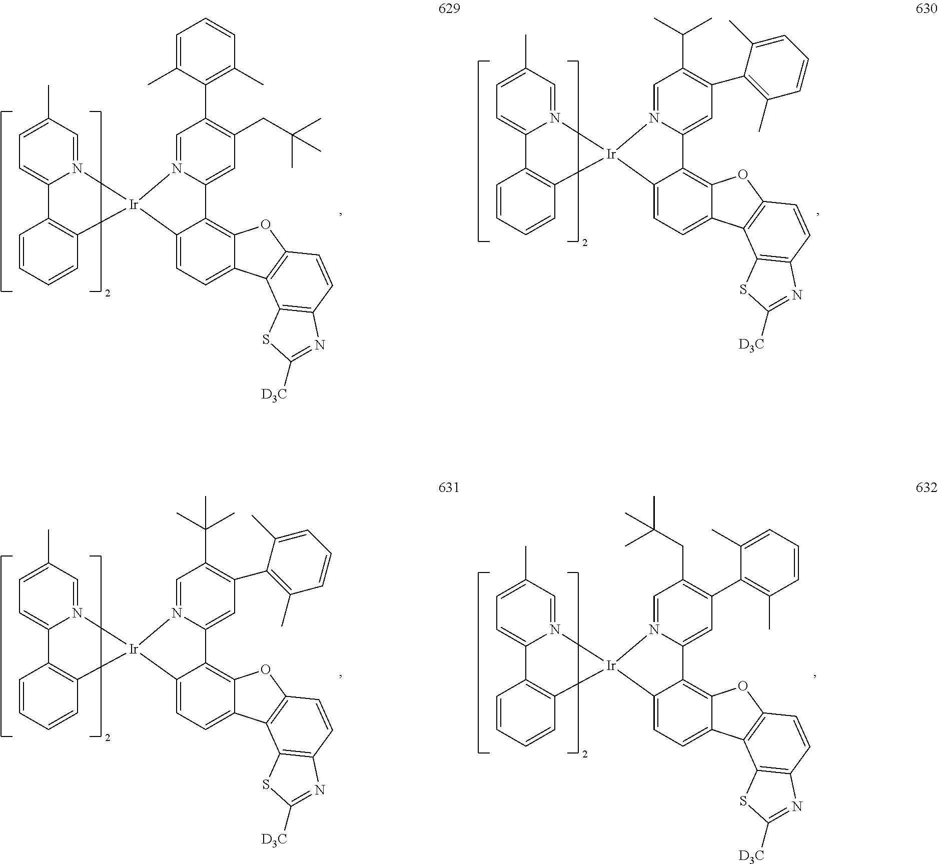

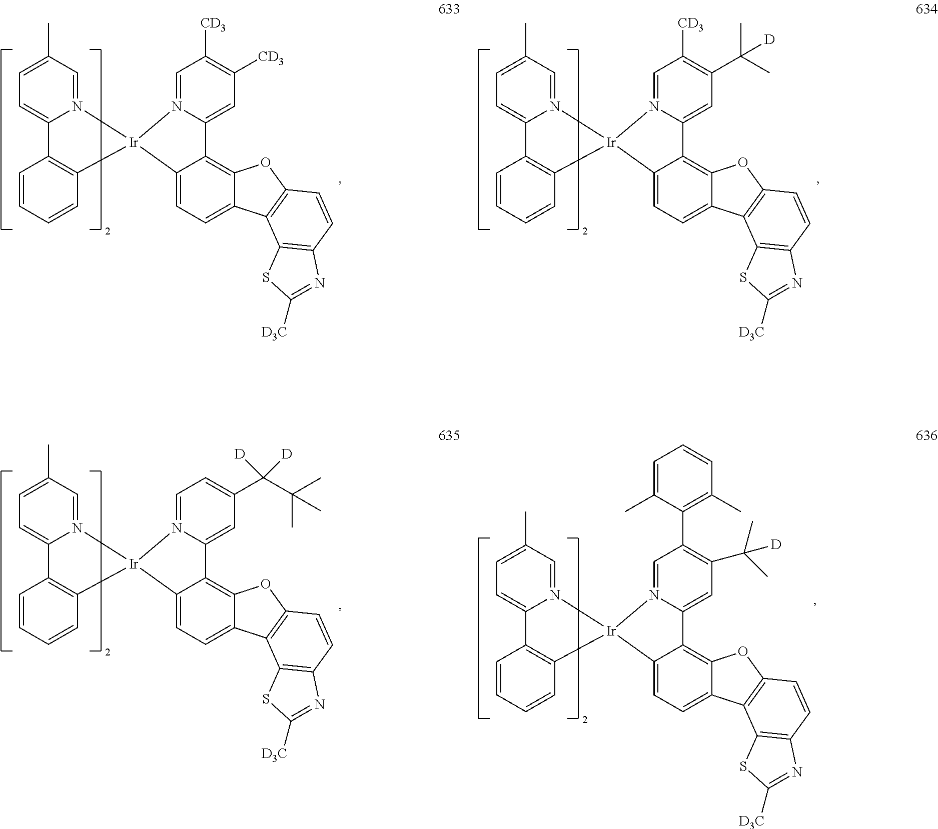

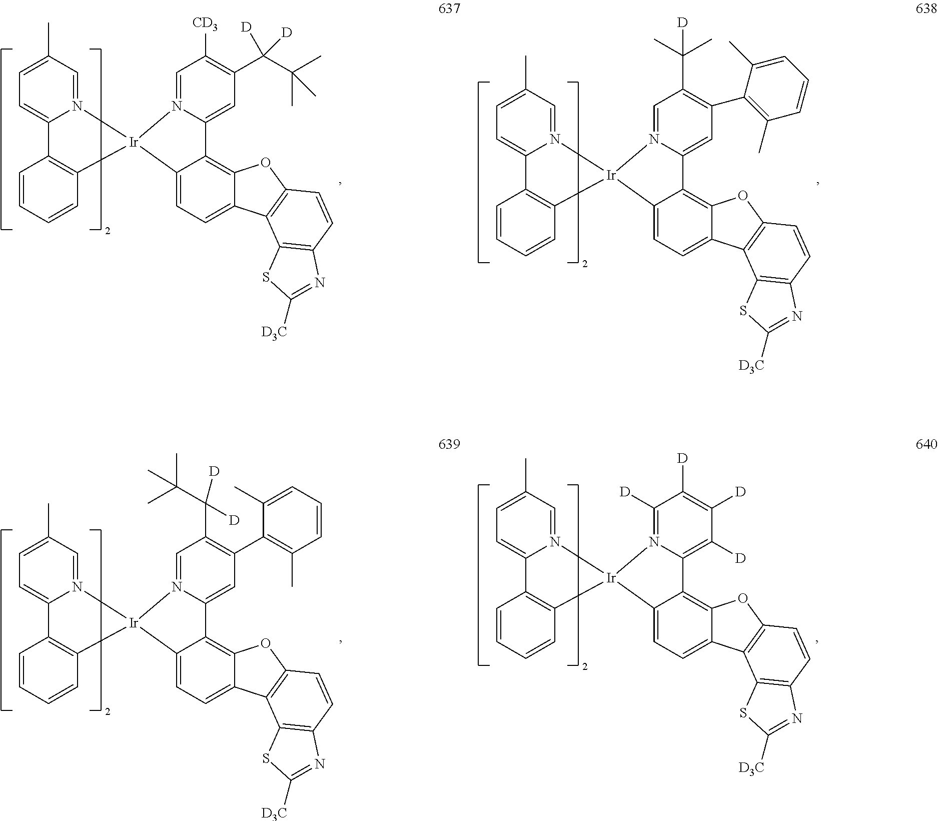

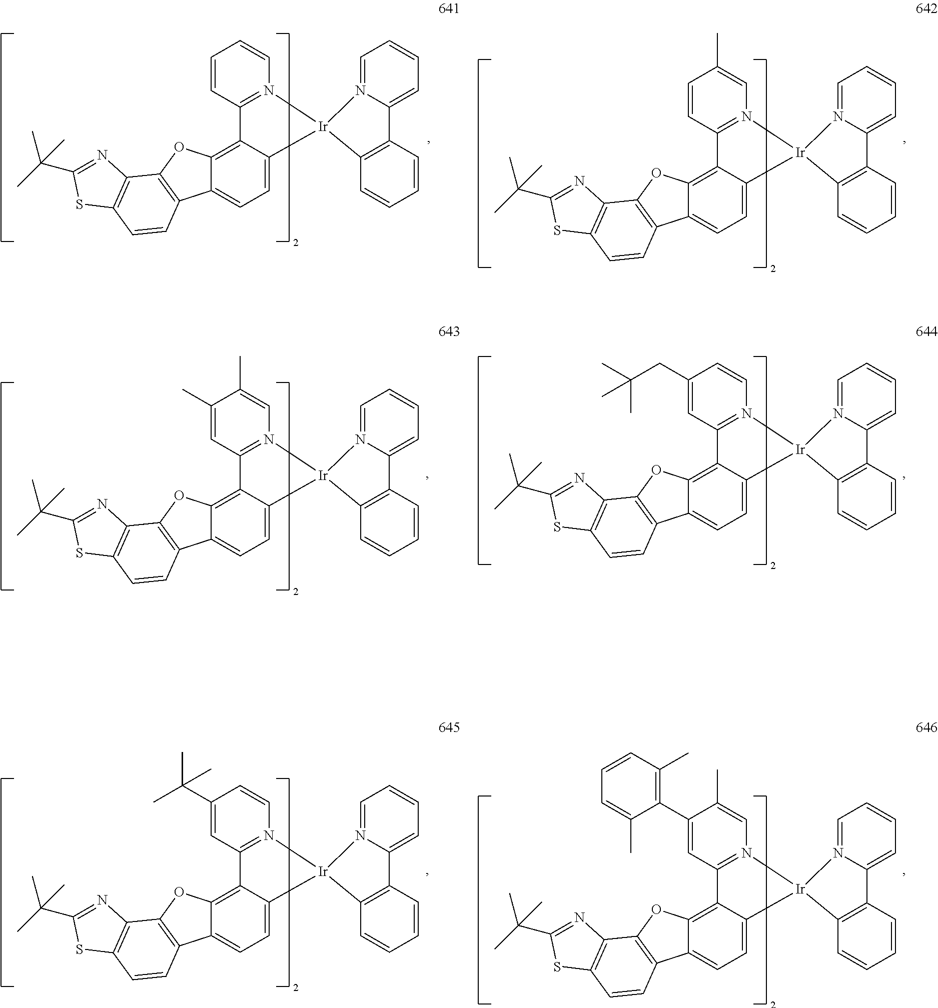

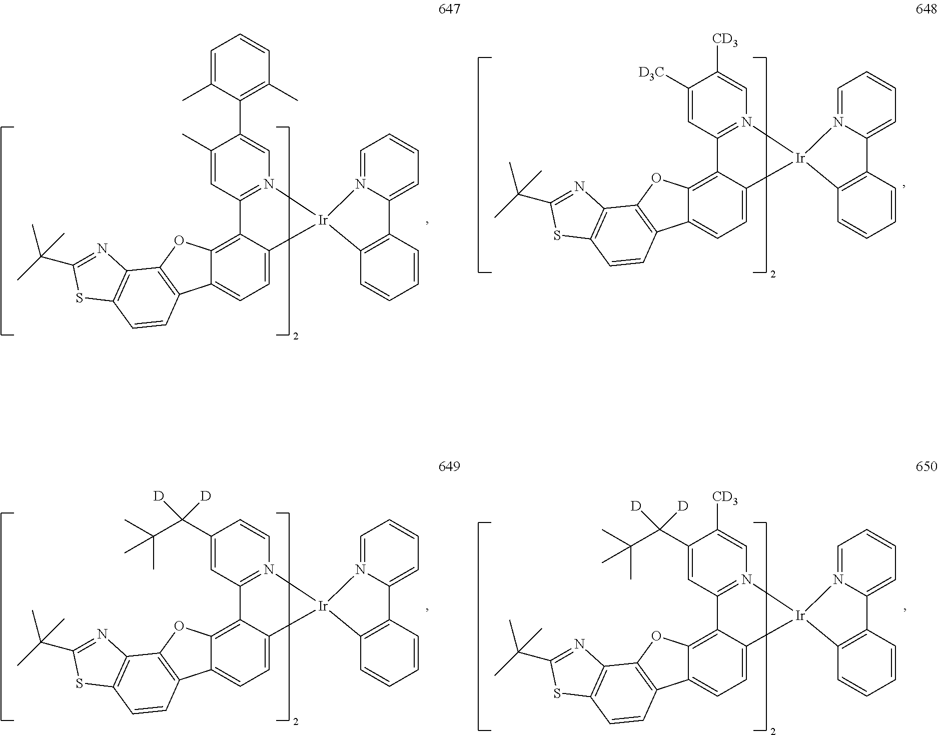

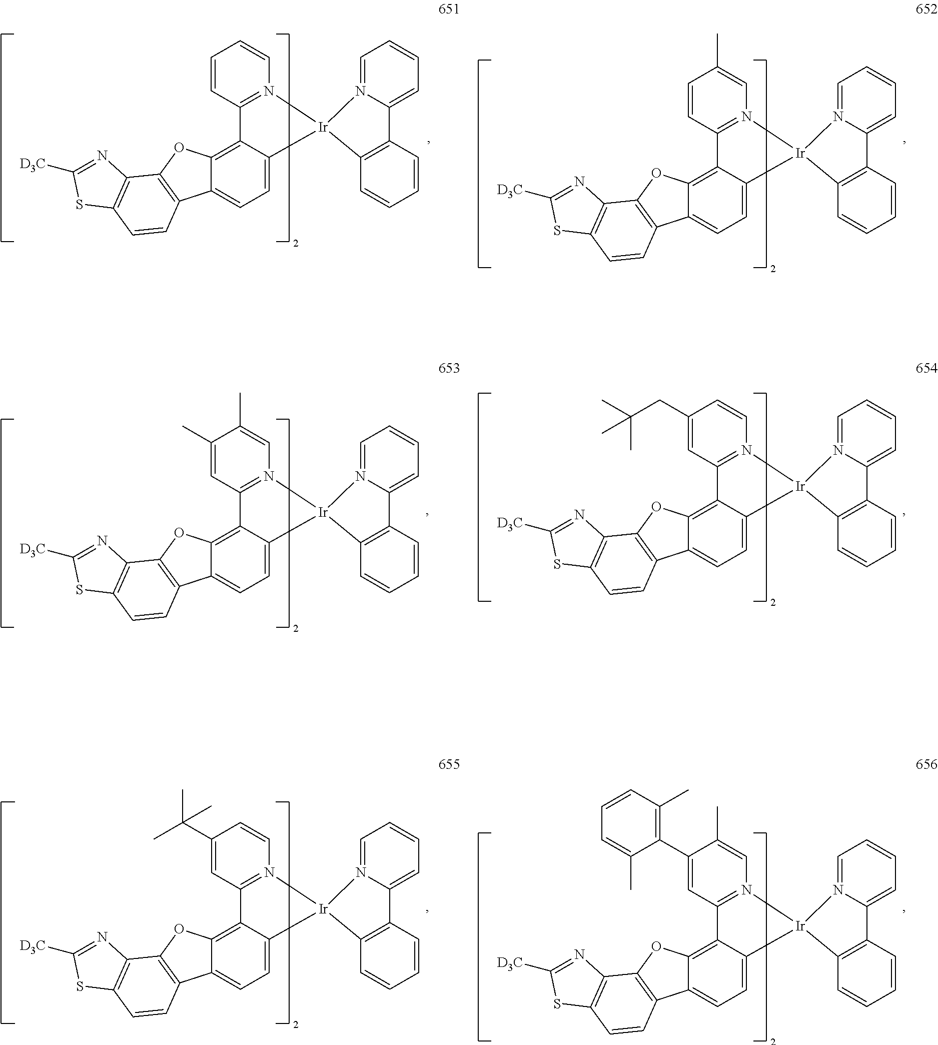

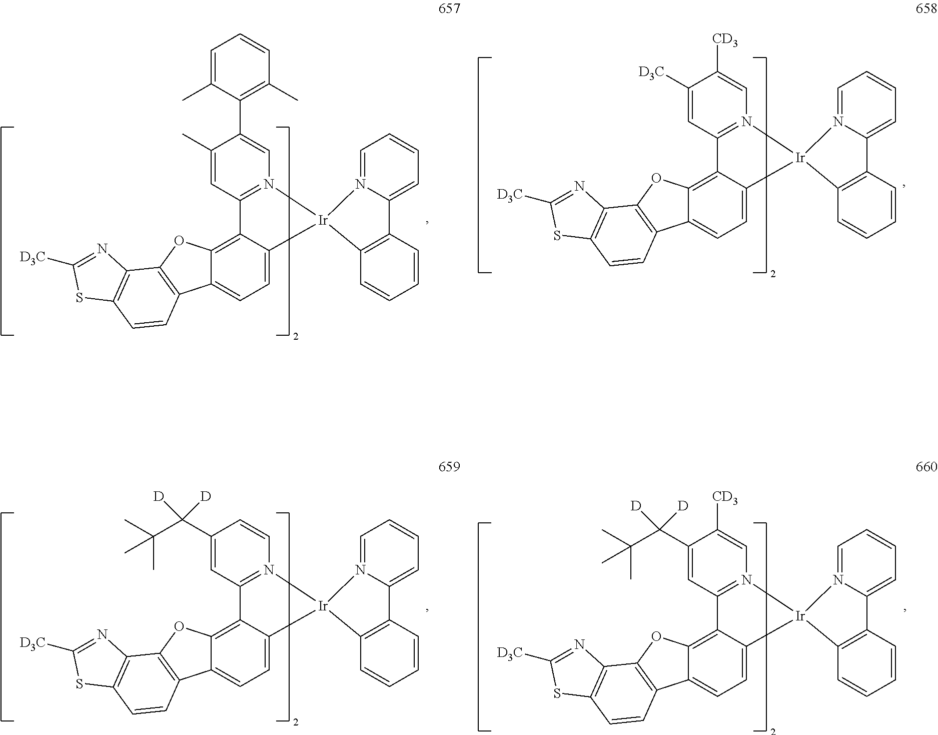

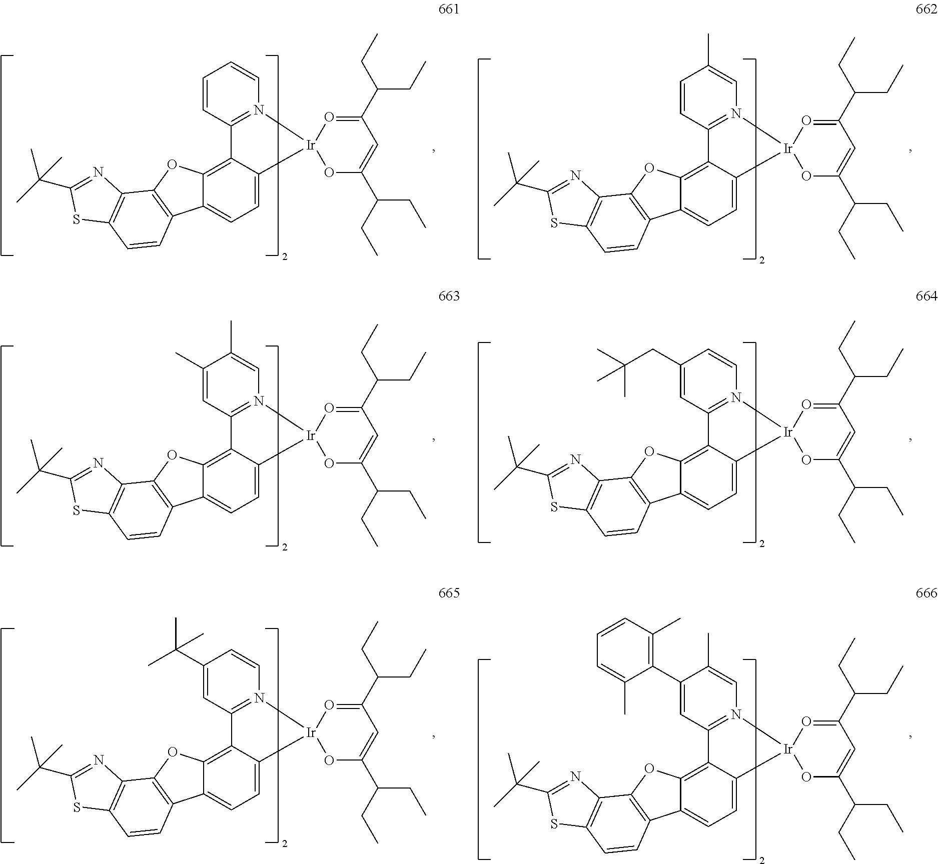

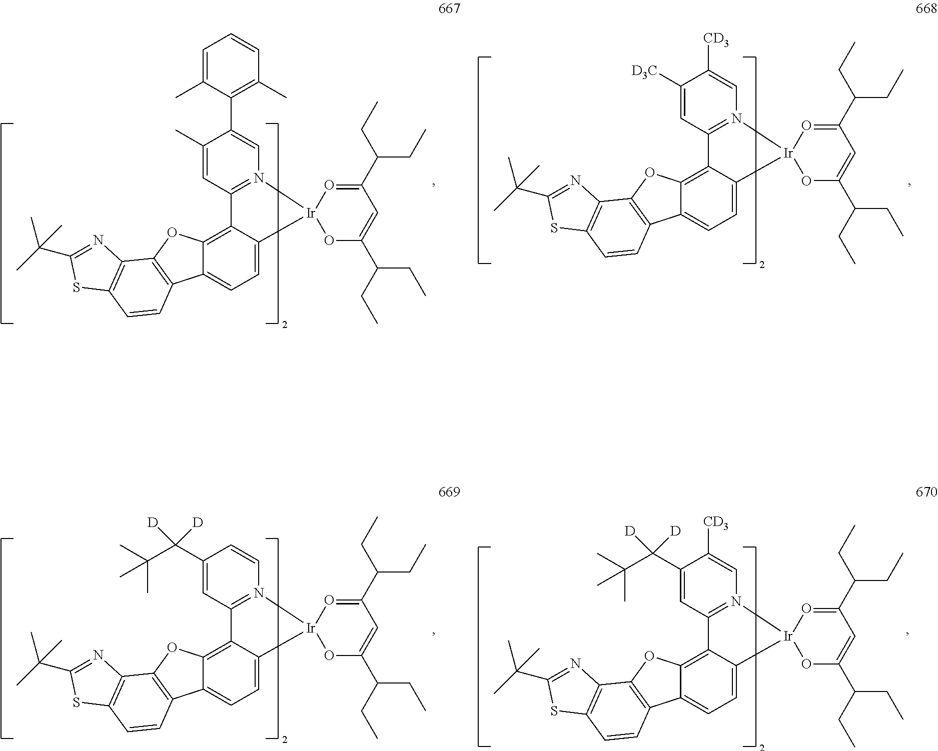

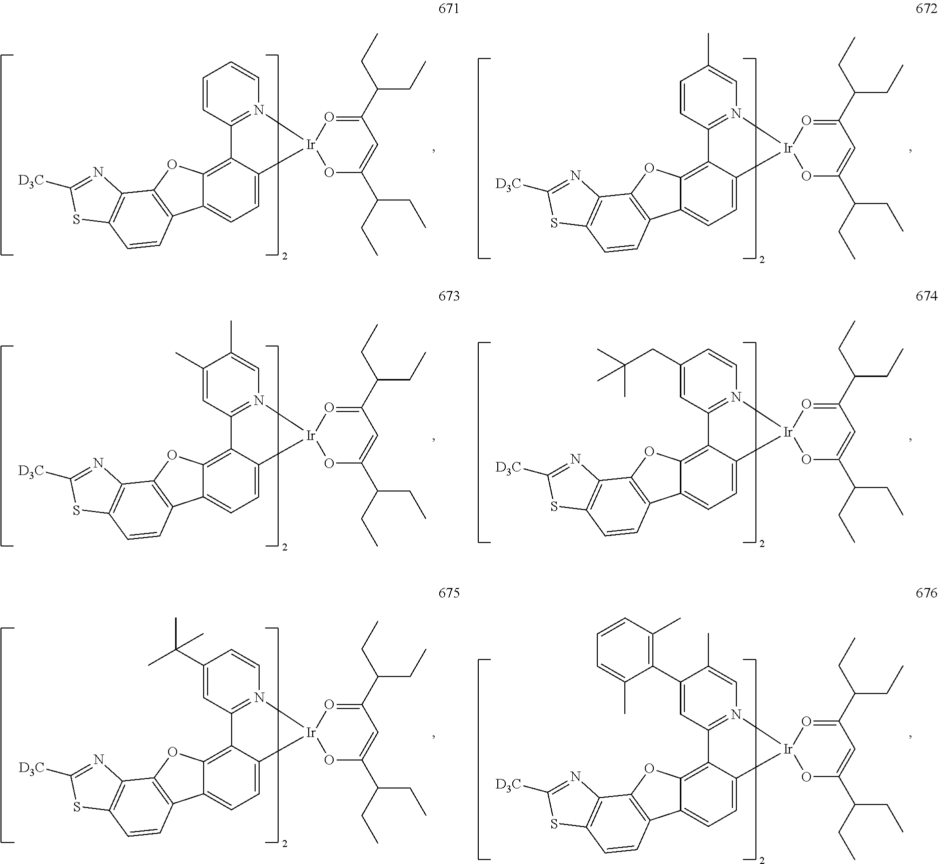

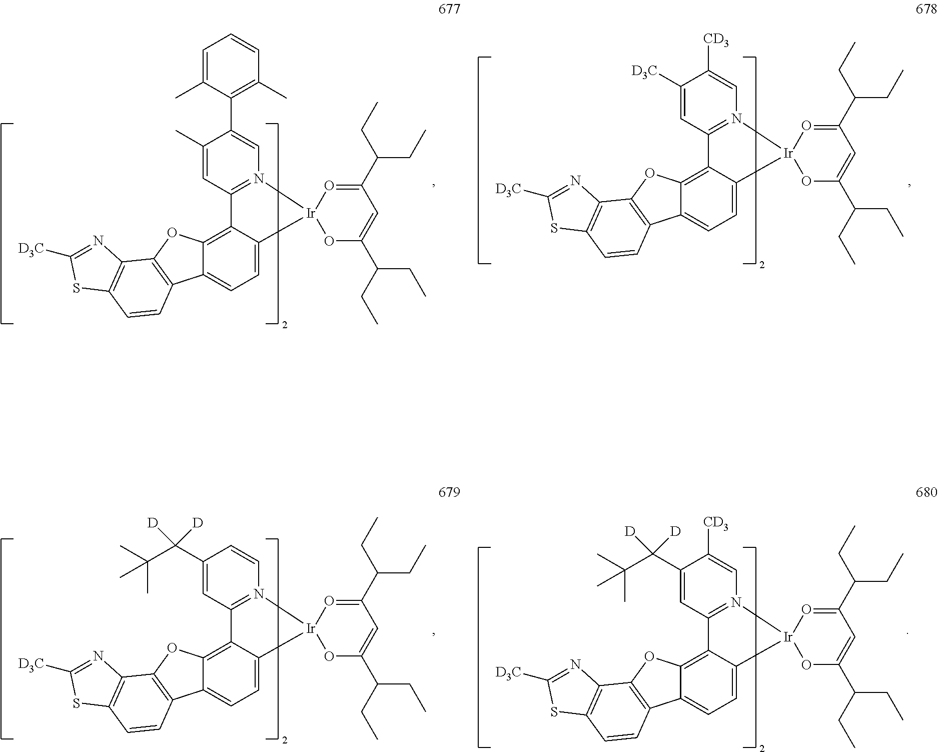

According to one implementation of the present disclosure, the organometallic compound represented by Chemical Formula 1 of the present disclosure may be used as a green phosphorescent dopant material.

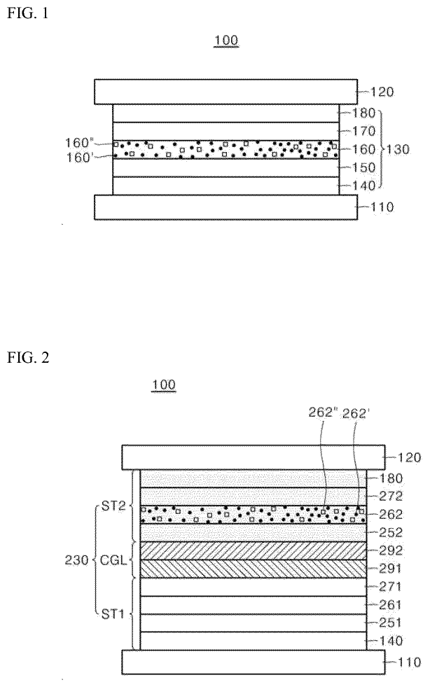

Referring to FIG. 1 according to one implementation of the present disclosure, an organic light-emitting diode 100 may be provided which includes a first electrode 110; a second electrode 120 facing the first electrode 110; and an organic layer 130 disposed between the first electrode 110 and the second electrode 120. The organic layer 130 may include a light-emitting layer 160, and the light-emitting layer 160 may include a host material 160″ and a dopant material 160′. The dopant 160 may be made of the organometallic compound represented by the Chemical Formula 1. In addition, in the organic light-emitting diode 100, the organic layer 130 disposed between the first electrode 110 and the second electrode 120 may be formed by sequentially stacking a hole injection layer 140 (HIL), a hole transport layer 150 (HTL), a light emission layer 160 (EML), an electron transport layer 170 (ETL) and an electron injection layer 180 (EIL) on the first electrode 110. The second electrode 120 may be formed on the electron injection layer 180, and a protective layer (not shown) may be formed thereon.

The first electrode 110 may act as a positive electrode, and may be made of ITO, IZO, tin-oxide, or zinc-oxide as a conductive material having a relatively large work function value. However, the present disclosure is not limited thereto.

The second electrode 120 may act as a negative electrode, and may include Al, Mg, Ca, or Ag as a conductive material having a relatively small work function value, or an alloy or combination thereof. However, the present disclosure is not limited thereto.

The hole injection layer 140 may be positioned between the first electrode 110 and the hole transport layer 150. The hole injection layer 140 may include a compound selected from a group consisting of MTDATA, CuPc, TCTA, NPB(NPD), HATCN, TDAPB, PEDOT/PSS, N-(biphenyl-4-yl)-9,9-dimethyl-N-(4-(9-phenyl-9H-carbazol-3-yl)phenyl)-9H-fluoren-2-amine, NPNPB (N,N′-diphenyl-N,N′-di[4-(N,N-diphenyl-amino)phenyl]benzidine), etc. Preferably, the hole injection layer 140 may include NPNPB. However, the present disclosure is not limited thereto.

The hole transport layer 150 may be positioned adjacent to the light-emitting layer and between the first electrode 110 and the light-emitting layer 160. A material of the hole transport layer 150 may include a compound selected from a group consisting of TPD, NPD, CBP, N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl)-4-amine, etc. However, the present disclosure is not limited thereto.

According to the present disclosure, the light-emitting layer 160 may be formed by doping the host material 160″ with the organometallic compound represented by the Chemical Formula 1 as the dopant 160′ in order to improve luminous efficiency of the diode 100. The organometallic compound represented by the Chemical Formula 1 may be used as a green or red light-emitting material, and preferably as a green phosphorescent material.

In one implementation of the present disclosure, a doping concentration of the dopant 160′ according to the present disclosure may be adjusted to be within a range of 1 to 30% by weight based on a total weight of the host material 160″. However, the disclosure is not limited thereto. For example, the doping concentration may be in a range of 2 to 20 wt %, for example, 3 to 15 wt %, for example, 5 to 10 wt %, for example, 3 to 8 wt %, for example, 2 to 7 wt %, for example, 5 to 7 wt %, or for example, 5 to 6 wt %.

The light-emitting layer 160 according to the present disclosure contains the host material 160′ which is known in the art and may achieve an effect of the present disclosure while the layer 160 contains the organometallic compound represented by the Chemical Formula 1 as the dopant 160″. For example, in accordance with the present disclosure, the host material 160′ may include ne host material selected from a group consisting of CBP (carbazole biphenyl), mCP (1,3-bis(carbazol-9-yl), and the like. However, the disclosure is not limited thereto.

Further, the electron transport layer 170 and the electron injection layer 180 may be sequentially stacked between the light-emitting layer 160 and the second electrode 120. A material of the electron transport layer 170 requires high electron mobility such that electrons may be stably supplied to the light-emitting layer under smooth electron transport.

For example, the material of the electron transport layer 170 may include a compound selected from a group consisting of Alq3 (tris(8-hydroxyquinolino)aluminum), Liq (8-hydroxyquinolinolatolithium), PBD (2-(4-biphenylyl)-5-(4-tert-butylphenyl)-1,3,4-oxadiazole), TAZ (3-(4-biphenyl)4-phenyl-5-tert-butylphenyl-1,2,4-triazole), spiro-PBD, BAlq (bis(2-methyl-8-quinolinolate)-4-(phenylphenolato)aluminium), SAlq, TPBi (2,2′,2-(1,3,5-benzinetriyl)-tris(1-phenyl-1-H-benzimidazole), oxadiazole, triazole, phenanthroline, benzoxazole, benzothiazole, and ZADN (2-[4-(9,10-Di-2-naphthalen2-yl-2-anthracen-2-yl)phenyl]-1-phenyl-1H-benzoimidazole). Preferably, the material of the electron transport layer 170 may include ZADN. However, the present disclosure is not limited thereto.

The electron injection layer 180 serves to facilitate electron injection. A material of the electron injection layer may include a compound selected from a group consisting of Alq3 (tris(8-hydroxyquinolino)aluminum), PBD, TAZ, spiro-PBD, BAlq, SAlq, etc. However, the present disclosure is not limited thereto. Alternatively, the electron injection layer 180 may be made of a metal compound. The metal compound may include, for example, one or more selected from a group consisting of Liq, LiF, NaF, KF, RbF, CsF, FrF, BcF₂, MgF₂, CaF₂, SrF₂, BaF₂ and RaF₂. However, the present disclosure is not limited thereto.

The organic light-emitting diode according to the present disclosure may be embodied as a white light-emitting diode having a tandem structure. The tandem organic light-emitting diode according to an illustrative embodiment of the present disclosure may be formed in a structure in which adjacent ones of two or more light-emitting stacks are connected to each other via a charge generation layer (CGL). The organic light-emitting diode may include at least two light-emitting stacks disposed on a substrate, wherein each of the at least two light-emitting stacks includes first and second electrodes facing each other, and the light-emitting layer disposed between the first and second electrodes to emit light in a specific wavelength band. The plurality of light-emitting stacks may emit light of the same color or different colors. In addition, one or more light-emitting layers may be included in one light-emitting stack, and the plurality of light-emitting layers may emit light of the same color or different colors.

In this case, the light-emitting layer included in at least one of the plurality of light-emitting stacks may contain the organometallic compound represented by the Chemical Formula 1 according to the present disclosure as the dopants. Adjacent ones of the plurality of light-emitting stacks in the tandem structure may be connected to each other via the charge generation layer CGL including an N-type charge generation layer and a P-type charge generation layer.

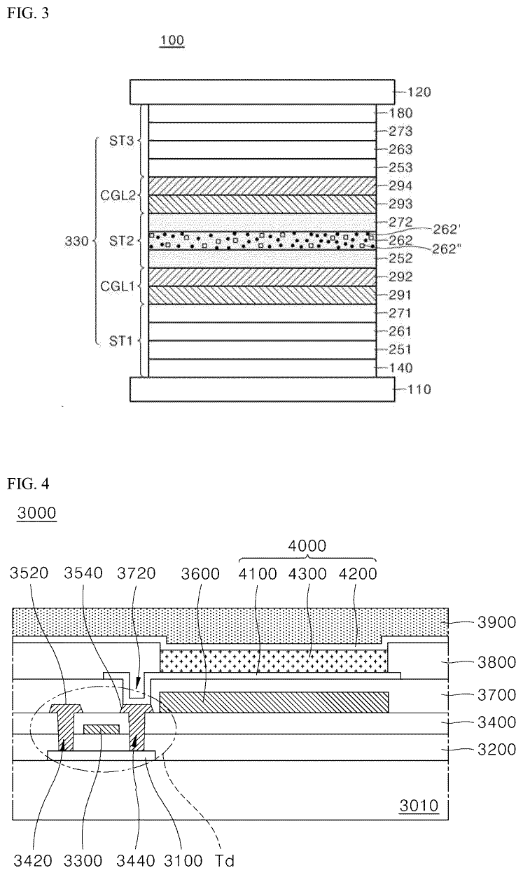

FIG. 2 and FIG. 3 are cross-sectional views schematically showing an organic light-emitting diode in a tandem structure having two light-emitting stacks and an organic light-emitting diode in a tandem structure having three light-emitting stacks, respectively, according to some implementations of the present disclosure.

As shown in FIG. 2, an organic light-emitting diode 100 according to the present disclosure include a first electrode 110 and a second electrode 120 facing each other, and an organic layer 230 positioned between the first electrode 110 and the second electrode 120. The organic layer 230 may be positioned between the first electrode 110 and the second electrode 120 and may include a first light-emitting stack ST1 including a first light-emitting layer 261, a second light-emitting stack ST2 positioned between the first light-emitting stack ST1 and the second electrode 120 and including a second light-emitting layer 262, and the charge generation layer CGL positioned between the first and second light-emitting stacks ST1 and ST2. The charge generation layer CGL may include an N-type charge generation layer 291 and a P-type charge generation layer 292. At least one of the first light-emitting layer 261 and the second light-emitting layer 262 may contain the organometallic compound represented by the Chemical Formula 1 according to the present disclosure as dopants 262′. For example, as shown in FIG. 2, the second light-emitting layer 262 of the second light-emitting stack ST2 may contain a host material 262″, and the dopants 262′ made of the organometallic compound represented by the Chemical Formula 1 doped into the host material. Although not shown in FIG. 2, each of the first and second light-emitting stacks ST1 and ST2 may further include, in addition to each of the first light-emitting layer 261 and the second light-emitting layer 262, an additional light-emitting layer. The descriptions as set forth above with respect to the hole transport layer 150 of FIG. 1 may be applied in the same or similar manner to each of the first hole transport layer 251 and the second hole transport layer 252 of FIG. 2. Moreover, the descriptions as set forth above with respect to the electron transport layer 170 of FIG. 1 may be applied in the same or similar manner to each of the first electron transport layer 271 and the second electron transport layer 272 of FIG. 2.

As shown in FIG. 3, the organic light-emitting diode 100 according to the present disclosure include the first electrode 110 and the second electrode 120 facing each other, and an organic layer 330 positioned between the first electrode 110 and the second electrode 120. The organic layer 330 may be positioned between the first electrode 110 and the second electrode 120 and may include the first light-emitting stack ST1 including the first light-emitting layer 261, the second light-emitting stack ST2 including the second light-emitting layer 262, a third light-emitting stack ST3 including a third light-emitting layer 263, a first charge generation layer CGL1 positioned between the first and second light-emitting stacks ST1 and ST2, and a second charge generation layer CGL2 positioned between the second and third light-emitting stacks ST2 and ST3. The first charge generation layer CGL1 may include a N-type charge generation layers 291 and a P-type charge generation layer 292. The second charge generation layer CGL2 may include a N-type charge generation layers 293 and a P-type charge generation layer 294. At least one of the first light-emitting layer 261, the second light-emitting layer 262, and the third light-emitting layer 263 may contain the organometallic compound represented by the Chemical Formula 1 according to the present disclosure as the dopants. For example, as shown in FIG. 3, the second light-emitting layer 262 of the second light-emitting stack ST2 may contain the host material 262″, and the dopants 262′ made of the organometallic compound represented by the Chemical Formula 1 doped into the host material. Although not shown in FIG. 3, each of the first, second and third light-emitting stacks ST1, ST2 and ST3 may further include an additional light-emitting layer, in addition to each of the first light-emitting layer 261, the second light-emitting layer 262 and the third light-emitting layer 263. The descriptions as set forth above with respect to the hole transport layer 150 of FIG. 1 may be applied in the same or similar manner to each of the first hole transport layer 251, the second hole transport layer 252, and the third hole transport layer 253 of FIG. 3. Moreover, the descriptions as set forth above with respect to the electron transport layer 170 of FIG. 1 may be applied in the same or similar manner to each of the first electron transport layer 271, the second electron transport layer 272, and the third electron transport layer 273 of FIG. 3.

Furthermore, an organic light-emitting diode according to an embodiment of the present disclosure may include a tandem structure in which four or more light-emitting stacks and three or more charge generating layers are disposed between the first electrode and the second electrode.

The organic light-emitting diode according to the present disclosure may be used as a light-emitting element of each of an organic light-emitting display device and a lighting device. In one implementation, FIG. 4 is a cross-sectional view schematically illustrating an organic light-emitting display device including the organic light-emitting diode according to some embodiments of the present disclosure as a light-emitting element thereof.

As shown in FIG. 4, an organic light-emitting display device 3000 includes a substrate 3010, an organic light-emitting diode 4000, and an encapsulation film 3900 covering the organic light-emitting diode 4000. A driving thin-film transistor Td as a driving element, and the organic light-emitting diode 4000 connected to the driving thin-film transistor Td are positioned on the substrate 3010.

Although not shown explicitly in FIG. 4, a gate line and a data line that intersect each other to define a pixel area, a power line extending parallel to and spaced from one of the gate line and the data line, a switching thin film transistor connected to the gate line and the data line, and a storage capacitor connected to one electrode of the thin film transistor and the power line are further formed on the substrate 3010.

The driving thin-film transistor Td is connected to the switching thin film transistor, and includes a semiconductor layer 3100, a gate electrode 3300, a source electrode 3520, and a drain electrode 3540.

The semiconductor layer 3100 may be formed on the substrate 3010 and may be made of an oxide semiconductor material or polycrystalline silicon. When the semiconductor layer 3100 is made of an oxide semiconductor material, a light-shielding pattern (not shown) may be formed under the semiconductor layer 3100. The light-shielding pattern prevents light from being incident into the semiconductor layer 3100 to prevent the semiconductor layer 3100 from being deteriorated due to the light. Alternatively, the semiconductor layer 3100 may be made of polycrystalline silicon. In this case, both edges of the semiconductor layer 3100 may be doped with impurities.

The gate insulating layer 3200 made of an insulating material is formed over an entirety of a surface of the substrate 3010 and on the semiconductor layer 3100. The gate insulating layer 3200 may be made of an inorganic insulating material such as silicon oxide or silicon nitride.

The gate electrode 3300 made of a conductive material such as a metal is formed on the gate insulating layer 3200 and corresponds to a center of the semiconductor layer 3100. The gate electrode 3300 is connected to the switching thin film transistor.

The interlayer insulating layer 3400 made of an insulating material is formed over the entirety of the surface of the substrate 3010 and on the gate electrode 3300. The interlayer insulating layer 3400 may be made of an inorganic insulating material such as silicon oxide or silicon nitride, or an organic insulating material such as benzocyclobutene or photo-acryl.

The interlayer insulating layer 3400 has first and second semiconductor layer contact holes 3420 and 3440 defined therein respectively exposing both opposing sides of the semiconductor layer 3100. The first and second semiconductor layer contact holes 3420 and 3440 are respectively positioned on both opposing sides of the gate electrode 3300 and are spaced apart from the gate electrode 3300.

The source electrode 3520 and the drain electrode 3540 made of a conductive material such as metal are formed on the interlayer insulating layer 3400. The source electrode 3520 and the drain electrode 3540 are positioned around the gate electrode 3300, and are spaced apart from each other, and respectively contact both opposing sides of the semiconductor layer 3100 via the first and second semiconductor layer contact holes 3420 and 3440, respectively. The source electrode 3520 is connected to a power line (not shown).

The semiconductor layer 3100, the gate electrode 3300, the source electrode 3520, and the drain electrode 3540 constitute the driving thin-film transistor Td. The driving thin-film transistor Td has a coplanar structure in which the gate electrode 3300, the source electrode 3520, and the drain electrode 3540 are positioned on top of the semiconductor layer 3100.

Alternatively, the driving thin-film transistor Td may have an inverted staggered structure in which the gate electrode is disposed under the semiconductor layer while the source electrode and the drain electrode are disposed above the semiconductor layer. In this case, the semiconductor layer may be made of amorphous silicon. In one example, the switching thin-film transistor (not shown) may have substantially the same structure as that of the driving thin-film transistor (Td).

In one example, the organic light-emitting display device 3000 may include a color filter 3600 absorbing the light generated from the electroluminescent element (light-emitting diode) 4000. For example, the color filter 3600 may absorb red (R), green (G), blue (B), and white (W) light. In this case, red, green, and blue color filter patterns that absorb light may be formed separately in different pixel areas. Each of these color filter patterns may be disposed to overlap each organic layer 4300 of the organic light-emitting diode 4000 to emit light of a wavelength band corresponding to each color filter. Adopting the color filter 3600 may allow the organic light-emitting display device 3000 to realize full-color.

For example, when the organic light-emitting display device 3000 is of a bottom emission type, the color filter 3600 absorbing light may be positioned on a portion of the interlayer insulating layer 3400 corresponding to the organic light-emitting diode 4000. In an optional embodiment, when the organic light-emitting display device 3000 is of a top emission type, the color filter may be positioned on top of the organic light-emitting diode 4000, that is, on top of a second electrode 4200. For example, the color filter 3600 may be formed to have a thickness of 2 to 5 μm.

In one example, a planarization layer 3700 having a drain contact hole 3720 defined therein exposing the drain electrode 3540 of the driving thin-film transistor Td is formed to cover the driving thin-film transistor Td.

On the planarization layer 3700, each first electrode 4100 connected to the drain electrode 3540 of the driving thin-film transistor Td via the drain contact hole 3720 is formed individually in each pixel area.

The first electrode 4100 may act as a positive electrode (anode), and may be made of a conductive material having a relatively large work function value. For example, the first electrode 4100 may be made of a transparent conductive material such as ITO, IZO or ZnO.

In one example, when the organic light-emitting display device 3000 is of a top-emission type, a reflective electrode or a reflective layer may be further formed under the first electrode 4100. For example, the reflective electrode or the reflective layer may be made of one of aluminum (Al), silver (Ag), nickel (Ni), and an aluminum-palladium-copper (APC) alloy.

A bank layer 3800 covering an edge of the first electrode 4100 is formed on the planarization layer 3700. The bank layer 3800 exposes a center of the first electrode 4100 corresponding to the pixel area.

An organic layer 4300 is formed on the first electrode 4100. If necessary, the organic light-emitting diode 4000 may have a tandem structure. Regarding the tandem structure, reference may be made to FIG. 2 to FIG. 4 which show some embodiments of the present disclosure, and the above descriptions thereof.

The second electrode 4200 is formed on the substrate 3010 on which the organic layer 4300 has been formed. The second electrode 4200 is disposed over the entirety of the surface of the display area and is made of a conductive material having a relatively small work function value and may be used as a negative electrode (a cathode). For example, the second electrode 4200 may be made of one of aluminum (Al), magnesium (Mg), and an aluminum-magnesium alloy (Al—Mg).

The first electrode 4100, the organic layer 4300, and the second electrode 4200 constitute the organic light-emitting diode 4000.

An encapsulation film 3900 is formed on the second electrode 4200 to prevent external moisture from penetrating into the organic light-emitting diode 4000. Although not shown explicitly in FIG. 4, the encapsulation film 3900 may have a triple-layer structure in which a first inorganic layer, an organic layer, and an inorganic layer are sequentially stacked. However, the present disclosure is not limited thereto.

Hereinafter, Synthesis Example and Present Example of the present disclosure will be described. However, following Examples are only examples of the present disclosure. The present disclosure is not limited thereto.

### Synthesis Example

### Preparation of Ligand A-2

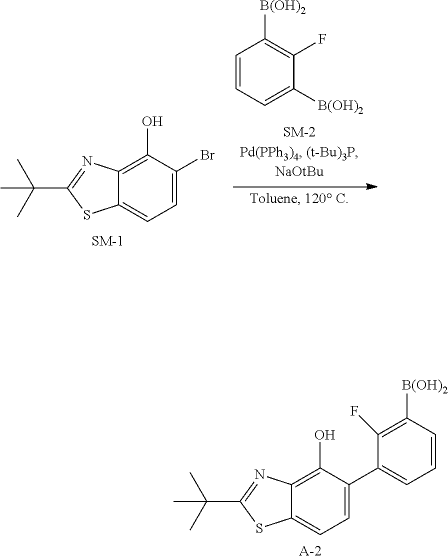

Under a nitrogen atmosphere and in a 250 mL round bottom flask, a compound SM-1 (5.70 g, 20 mmol), a compound SM-2 (3.67 g, 20 mmol), Pd(PPh₃)₄ (2.31 g, 2 mmol), P(t-Bu)₃ (0.81 g, 4 mmol), and NaOtBu (7.68 g, 80 mmol) were dissolved in 200 mL of toluene, followed by stirring while heating under reflux for 12 hours. After completion of the reaction, a temperature was lowered to room temperature, and then an organic layer was extracted therefrom with dichloromethane, and thoroughly washed with water. Water was removed therefrom with anhydrous magnesium sulfate, and a filtered solution was obtained therefrom and then was concentrated under reduced pressure, and then was subjected to separation with column chromatography using ethyl acetate and hexane to obtain a compound A-2 (5.59 g, 81%).

### Preparation of Ligand A-1

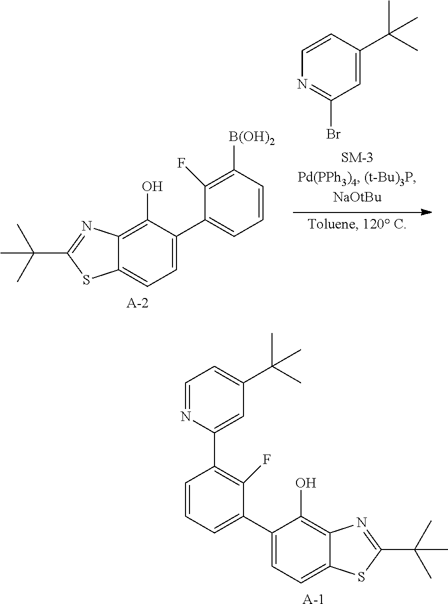

Under a nitrogen atmosphere and in a 250 mL round bottom flask, the compound A-2 (6.90 g, 20 mmol), a compound SM-3 (4.28 g, 20 mmol), Pd(PPh₃)₄ (2.31 g, 2 mmol), P(t-Bu)₃ (0.81 g, 4 mmol), NaOtBu (7.68 g, 80 mmol) were dissolved in 200 mL of toluene, followed by stirring while heating under reflux for 12 hours. After completion of the reaction, a temperature was lowered to room temperature, and then an organic layer was extracted therefrom with dichloromethane, and thoroughly washed with water. Water was removed therefrom with anhydrous magnesium sulfate, and a filtered solution was obtained therefrom and then was concentrated under reduced pressure, and then was subjected to separation with column chromatography using ethyl acetate and hexane to obtain a compound A-1 (7.13 g, 82%).

### Preparation of Ligand A

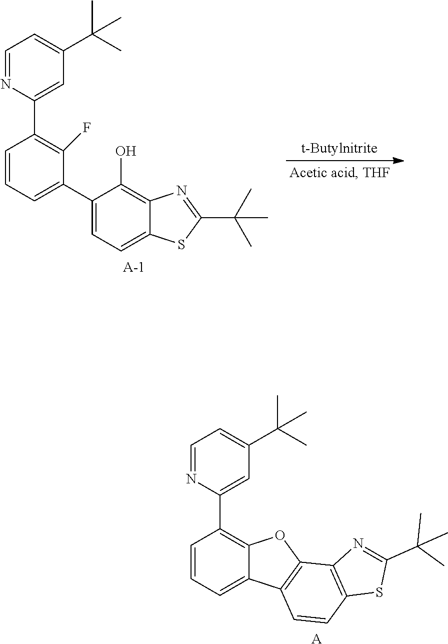

Under a nitrogen atmosphere and in a 250 mL round bottom flask, the compound A-1 (8.69 g, 20 mmol) was dissolved in 80 mL of acetic acid and 25 mL of THF, and then tert-butyl nitrite (5 mL, 38 mmol) was added dropwise thereto at 0° C., followed by stirring. After completion of the stirring at 0° C. for 4 hours, a temperature was raised to room temperature. Then, an organic layer was extracted therefrom with ethyl acetate and thoroughly washed with water. Water was removed therefrom with anhydrous magnesium sulfate, and a filtered solution was obtained therefrom and then was concentrated under reduced pressure, and then was subjected to separation with column chromatography using dichloromethane and hexane to obtain a compound A (6.05 g, 73%).

### Preparation of Ligand B-2

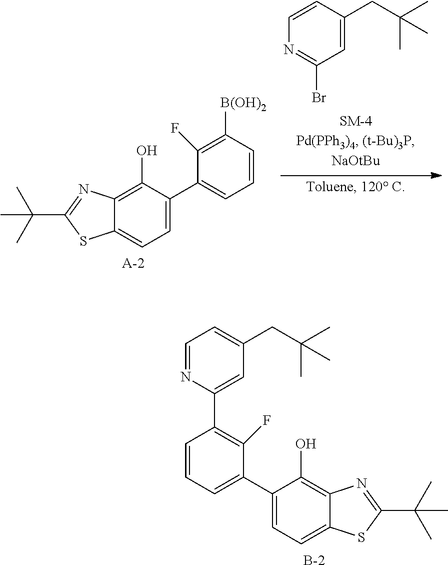

Under a nitrogen atmosphere and in a 250 mL round bottom flask, the compound A-2 (6.90 g, 20 mmol), a compound SM-4 (4.56 g, 20 mmol), Pd(PPh₃)₄ (2.31 g, 2 mmol), P(t-Bu)₃ (0.81 g, 4 mmol), and NaOtBu (7.68 g, 80 mmol) were dissolved in 200 mL of toluene, followed by stirring while heating under reflux for 12 hours. After completion of the reaction, a temperature was lowered to room temperature, and then an organic layer was extracted therefrom with dichloromethane, and thoroughly washed with water. Water was removed therefrom with anhydrous magnesium sulfate, and a filtered solution was obtained therefrom and then was concentrated under reduced pressure, and then was subjected to separation with column chromatography using ethyl acetate and hexane to obtain a compound B-2 (7.36 g, 82%).

### Preparation of Ligand B-1

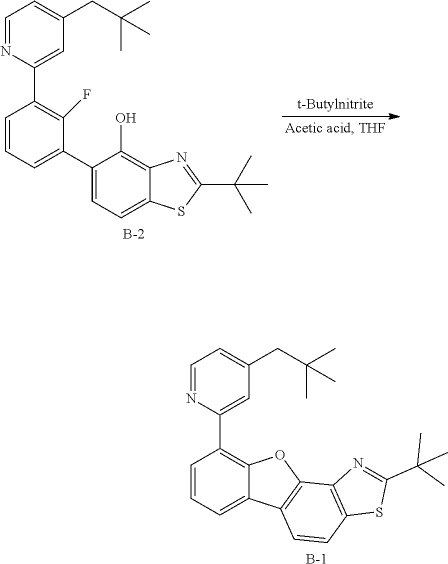

Under a nitrogen atmosphere and in a 250 mL round bottom flask, the compound B-2 (8.97 g, 20 mmol) was dissolved in 80 mL of acetic acid and 25 mL of THE, and then tert-butyl nitrite (5 mL, 38 mmol) was added dropwise thereto at 0° C., followed by stirring. After completion of the stirring at 0° C. for 4 hours, a temperature was raised to room temperature. Then, an organic layer was extracted therefrom with ethyl acetate and thoroughly washed with water. Water was removed therefrom with anhydrous magnesium sulfate, and a filtered solution was obtained therefrom and then was concentrated under reduced pressure, and then was subjected to separation with column chromatography using dichloromethane and hexane to obtain a compound B-1 (6.69 g, 78%).

### Preparation of Ligand B

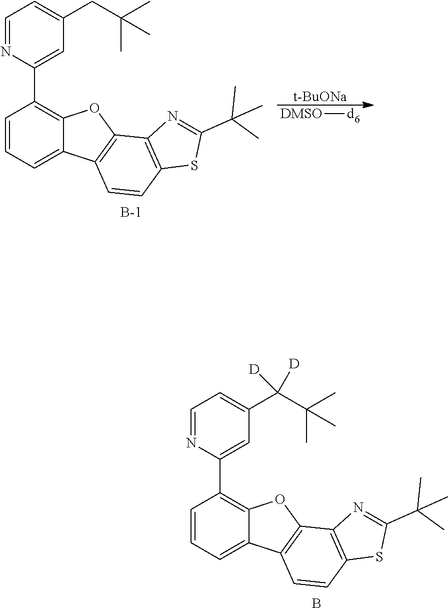

Under a nitrogen atmosphere and in a 250 mL round bottom flask, the compound B-1 (7.43 g, 20 mmol) and sodium tert-butoxide (4 mL, 40 mmol) were dissolved in DMSO-d₆ 100 mL, followed by stirring and heating at 135° C. for 48 hours. After completion of the reaction, a reaction vessel was cooled to room temperature. Then, an organic layer was extracted therefrom with ethyl acetate and thoroughly washed with water. Water was removed therefrom with anhydrous magnesium sulfate, and a filtered solution was obtained therefrom and then was concentrated under reduced pressure, and then was subjected to separation with column chromatography using dichloromethane and ethyl acetate to obtain a compound B (6.89 g, 80%).

### Preparation of Ligand C-3

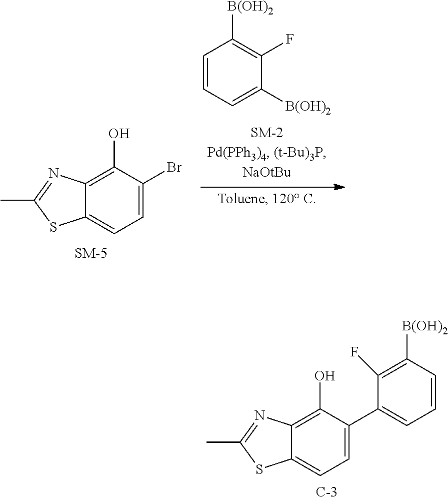

Under a nitrogen atmosphere and in a 250 mL round bottom flask, a compound SM-5 (4.88 g, 20 mmol), a compound SM-2 (3.67 g, 20 mmol), Pd(PPh₃)₄ (2.31 g, 2 mmol), P(t-Bu)₃ (0.81 g, 4 mmol), and NaOtBu (7.68 g, 80 mmol) were dissolved in 200 mL of toluene, followed by stirring while heating under reflux for 12 hours. After completion of the reaction, a temperature was lowered to room temperature, and then an organic layer was extracted therefrom with dichloromethane, and thoroughly washed with water. Water was removed therefrom with anhydrous magnesium sulfate, and a filtered solution was obtained therefrom and then was concentrated under reduced pressure, and then was subjected to separation with column chromatography using ethyl acetate and hexane to obtain a compound C-3 (4.85 g, 80%).

### Preparation of Ligand C-2

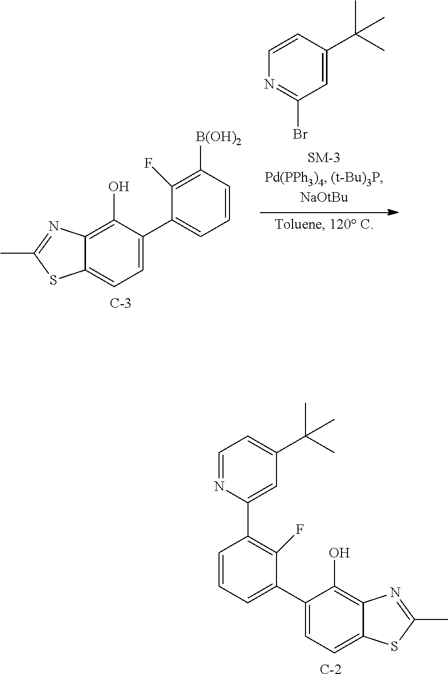

Under a nitrogen atmosphere and in a 250 mL round bottom flask, the compound C-3 (6.06 g, 20 mmol), the SM-3 (4.28 g, 20 mmol), Pd(PPh₃)₄ (2.31 g, 2 mmol), P(t-Bu)₃ (0.81 g, 4 mmol), and NaOtBu (7.68 g, 80 mmol) were dissolved in 200 mL of toluene, followed by stirring while heating under reflux for 12 hours. After completion of the reaction, a temperature was lowered to room temperature, and then an organic layer was extracted therefrom with dichloromethane, and thoroughly washed with water. Water was removed therefrom with anhydrous magnesium sulfate, and a filtered solution was obtained therefrom and then was concentrated under reduced pressure, and then was subjected to separation with column chromatography using ethyl acetate and hexane to obtain a compound C-2 (5.97 g, 76%).

### Preparation of Ligand C-1

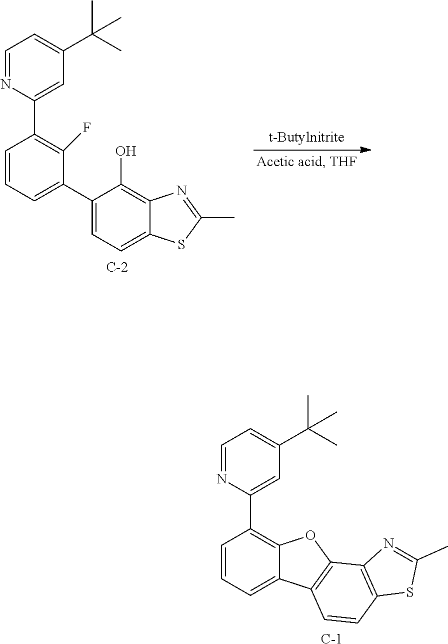

Under a nitrogen atmosphere and in a 250 mL round bottom flask, the compound C-2 (7.85 g, 20 mmol) was dissolved in 80 mL of acetic acid and 25 mL of THF, and then tert-butyl nitrite (5 mL, 38 mmol) was added dropwise thereto at 0° C., followed by stirring. After completion of the stirring at 0° C. for 4 hours, a temperature was raised to room temperature. Then, an organic layer was extracted therefrom with ethyl acetate and thoroughly washed with water. Water was removed therefrom with anhydrous magnesium sulfate, and a filtered solution was obtained therefrom and then was concentrated under reduced pressure, and then was subjected to separation with column chromatography using dichloromethane and hexane to obtain a compound C-1 (5.07 g, 68%).

### Preparation of Ligand C

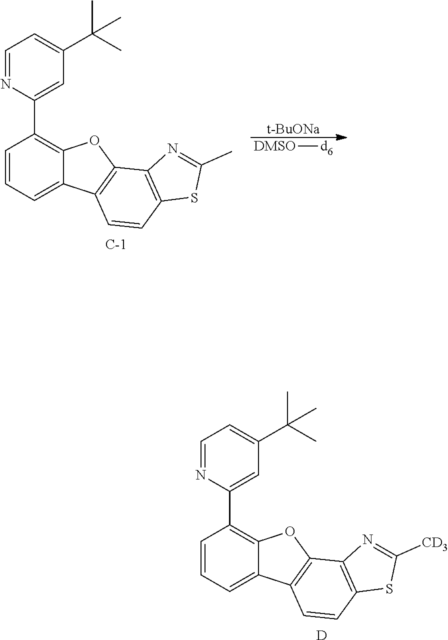

Under a nitrogen atmosphere and in a 250 mL round bottom flask, the compound C-1 (7.45 g, 20 mmol) and sodium tert-butoxide (4 mL, 40 mmol) were dissolved in DMSO-d₆ 100 mL, followed by stirring and heating at 135° C. for 48 hours. After completion of the reaction, a reaction vessel was cooled to room temperature. Then, an organic layer was extracted therefrom with ethyl acetate and thoroughly washed with water. Water was removed therefrom with anhydrous magnesium sulfate, and a filtered solution was obtained therefrom and then was concentrated under reduced pressure, and then was subjected to separation with column chromatography using dichloromethane and ethyl acetate to obtain a compound C (5.63 g, 75%).

### Preparation of Ligand D-2

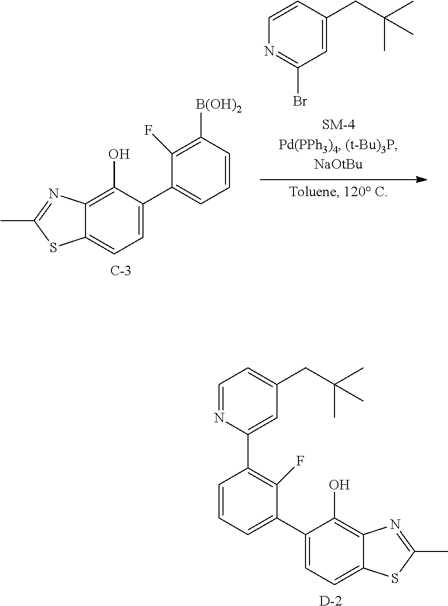

Under a nitrogen atmosphere and in a 250 mL round bottom flask, the compound C-3 (6.06 g, 20 mmol), the SM-4 (4.56 g, 20 mmol), Pd(PPh₃)₄ (2.31 g, 2 mmol), P(t-Bu)₃ (0.81 g, 4 mmol), and NaOtBu (7.68 g, 80 mmol) were dissolved in 200 mL of toluene, followed by stirring while heating under reflux for 12 hours. After completion of the reaction, a temperature was lowered to room temperature, and then an organic layer was extracted therefrom with dichloromethane, and thoroughly washed with water. Water was removed therefrom with anhydrous magnesium sulfate, and a filtered solution was obtained therefrom and then was concentrated under reduced pressure, and then was subjected to separation with column chromatography using ethyl acetate and hexane to obtain a compound D-2 (6.67 g, 82%).

### Preparation of Ligand D-1

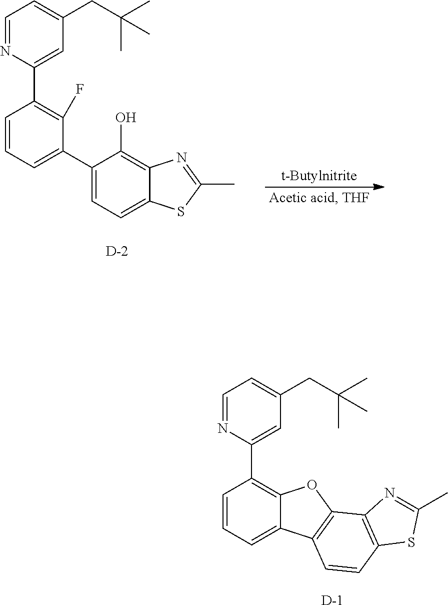

Under a nitrogen atmosphere and in a 250 mL round bottom flask, the compound D-2 (8.13 g, 20 mmol) was dissolved in 80 mL of acetic acid and 25 mL of THE, and then tert-butyl nitrite (5 mL, 38 mmol) was added dropwise thereto at 0° C., followed by stirring. After completion of the stirring at 0° C. for 4 hours, a temperature was raised to room temperature. Then, an organic layer was extracted therefrom with ethyl acetate and thoroughly washed with water. Water was removed therefrom with anhydrous magnesium sulfate, and a filtered solution was obtained therefrom and then was concentrated under reduced pressure, and then was subjected to separation with column chromatography using dichloromethane and hexane to obtain a compound D-1 (5.23 g, 71%).

### Preparation of Ligand D

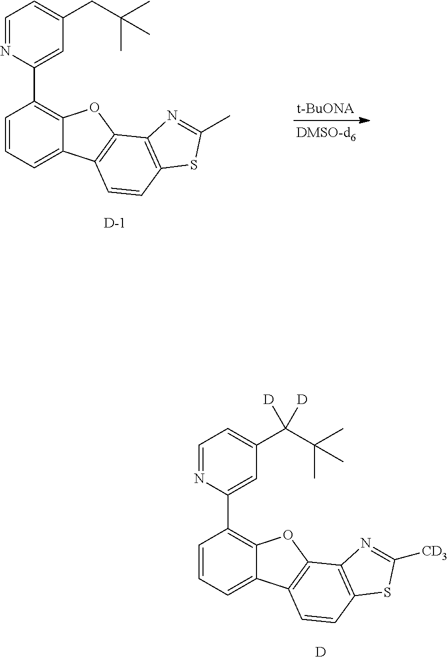

Under a nitrogen atmosphere and in a 250 mL round bottom flask, the compound D-1 (7.37 g, 20 mmol) and sodium tert-butoxide (4 mL, 40 mmol) were dissolved in DMSO-d₆ 100 mL, followed by stirring and heating at 135° C. for 48 hours. After completion of the reaction, a reaction vessel was cooled to room temperature. Then, an organic layer was extracted therefrom with ethyl acetate and thoroughly washed with water. Water was removed therefrom with anhydrous magnesium sulfate, and a filtered solution was obtained therefrom and then was concentrated under reduced pressure, and then was subjected to separation with column chromatography using dichloromethane and ethyl acetate to obtain a compound D (5.41 g, 72%).

### Preparation of Compound EE

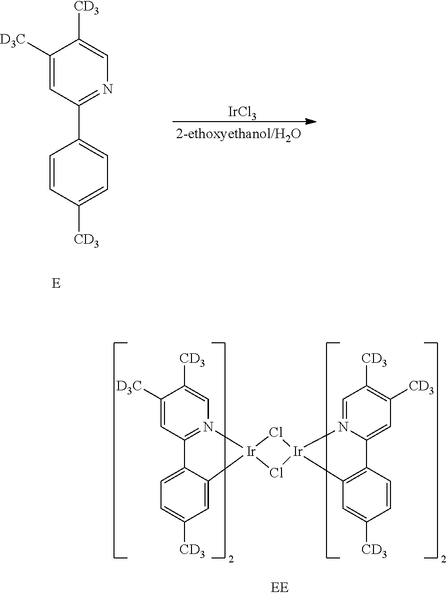

Under a nitrogen atmosphere and in a 250 mL round bottom flask, a compound E (4.13 g, 20 mmol) and IrCl₃ (2.39 g, 8.0 mmol) were dissolved in a mixed solvent (ethoxyethanol:distilled water=90 mL:30 mL), followed by stirring under reflux for 24 hours. After completion of the reaction, a temperature is lowered to room temperature, and a resulting solid is separated via filtration under reduced pressure. The solid filtered through the filter was thoroughly washed with water and cold methanol, and a filtration under reduced pressure was performed. The filtration and washing were repeated several times to obtain 8.78 g (86%) of a solid compound EE.

### Preparation of Compound E′

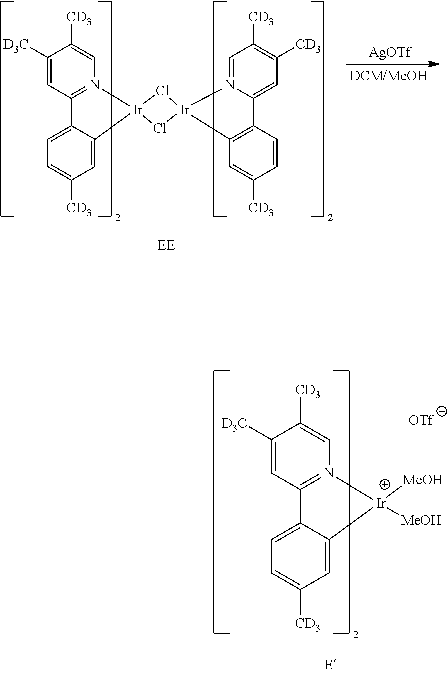

In a 250 mL round bottom flask, the compound EE (5.11 g, 4 mmol) and silver trifluoromethanesulfonate (AgOTf, 3.02 g, 12 mmol) were dissolved in dichloromethane, followed by stirring at room temperature for 24 hours. After completion of the reaction, a reaction product is filtered with Celite to remove solid precipitates therefrom. The filtrate obtained through the filter was subjected to distillation under reduced pressure to obtain 5.61 g (86%) of a solid compound E′.

### Preparation of Compound FF

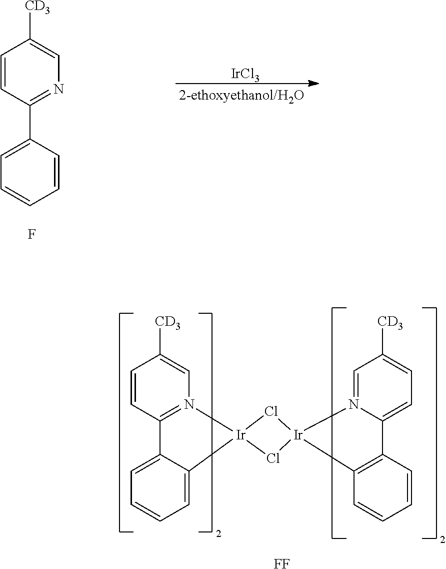

Under a nitrogen atmosphere and in a 250 mL round bottom flask, a compound F (3.45 g, 20 mmol), and IrCl₃ (2.39 g, 8.0 mmol) were dissolved in a mixed solvent (ethoxyethanol:distilled water=90 mL:30 mL), followed by stirring under reflux for 24 hours. After completion of the reaction, a temperature is lowered to room temperature, and a resulting solid is separated via filtration under reduced pressure. The solid filtered through the filter was thoroughly washed with water and cold methanol, and a filtration under reduced pressure was performed. The filtration and washing were repeated several times to obtain a solid compound FF 7.66 g (84%).

### Preparation of Compound F′

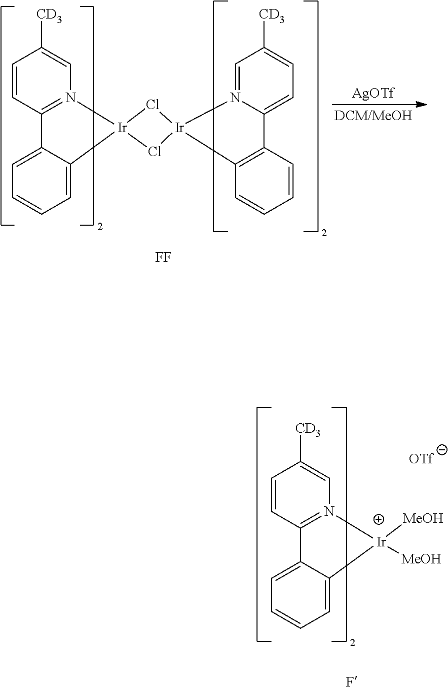

In a 250 mL round bottom flask, the compound FF (4.56 g, 4 mmol), and silver trifluoromethanesulfonate (AgOTf, 3.02 g, 12 mmol) were dissolved in dichloromethane, followed by stirring at room temperature for 24 hours. After completion of the reaction, a reaction product is filtered with Celite to remove solid precipitates therefrom. The filtrate obtained through the filter was subjected to distillation under reduced pressure to obtain a solid compound F′ 5.26 g (88%).

### Preparation of Compound AA

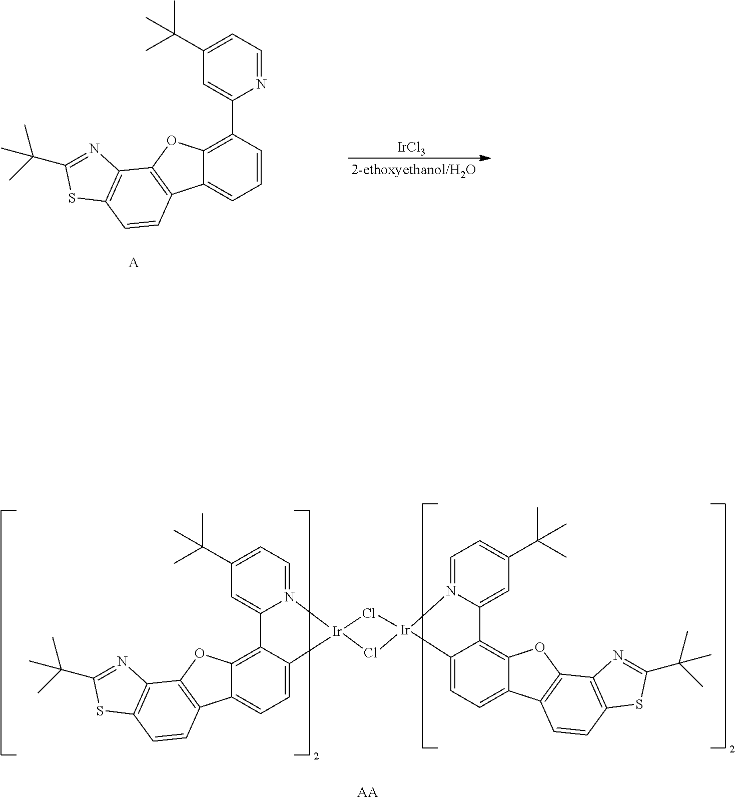

Under a nitrogen atmosphere and in a 250 mL round bottom flask, a compound A (7.47 g, 20 mmol), and IrCl₃ (2.39 g, 8.0 mmol) were dissolved in a mixed solvent (ethoxyethanol:distilled water=90 mL:30 mL), followed by stirring under reflux for 24 hours. After completion of the reaction, a temperature is lowered to room temperature, and a resulting solid is separated via filtration under reduced pressure. The solid filtered through the filter was thoroughly washed with water and cold methanol, and a filtration under reduced pressure was performed. The filtration and washing were repeated several times to obtain a solid compound AA 7.17 g (85%).

### Preparation of Compound A′

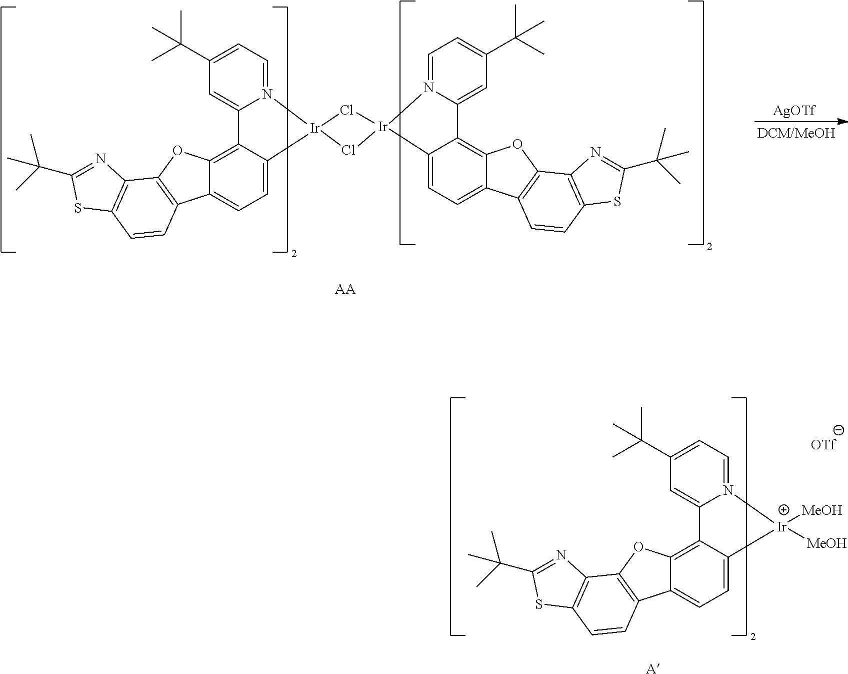

In a 250 mL round bottom flask, the compound AA (8.44 g, 4 mmol), and silver trifluoromethanesulfonate (AgOTf, 3.02 g, 12 mmol) were dissolved in dichloromethane, followed by stirring at room temperature for 24 hours. After completion of the reaction, a reaction product is filtered with Celite to remove solid precipitates therefrom. The filtrate obtained through the filter was subjected to distillation under reduced pressure to obtain a solid compound A′ 8.38 g (85%).

### Preparation of Compound BB

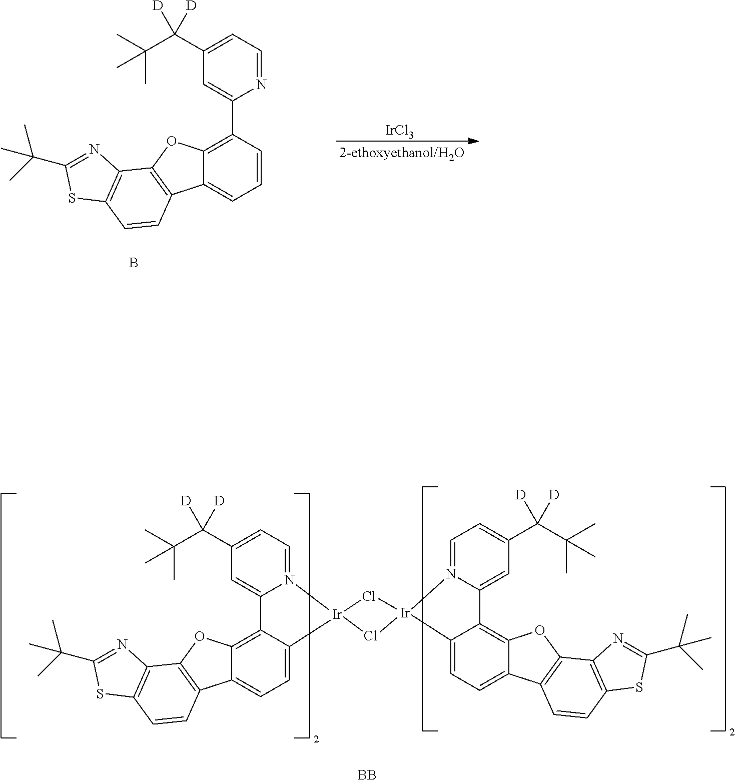

Under a nitrogen atmosphere and in a 250 mL round bottom flask, a compound B (8.61 g, 20 mmol), and IrCl₃ (2.39 g, 8.0 mmol) were dissolved in a mixed solvent (ethoxyethanol:distilled water=90 mL:30 mL), followed by stirring under reflux for 24 hours. After completion of the reaction, a temperature is lowered to room temperature, and a resulting solid is separated via filtration under reduced pressure. The solid filtered through the filter was thoroughly washed with water and cold methanol, and a filtration under reduced pressure was performed. The filtration and washing were repeated several times to obtain a solid compound BB 7.65 g (88%).

### Preparation of Compound B′

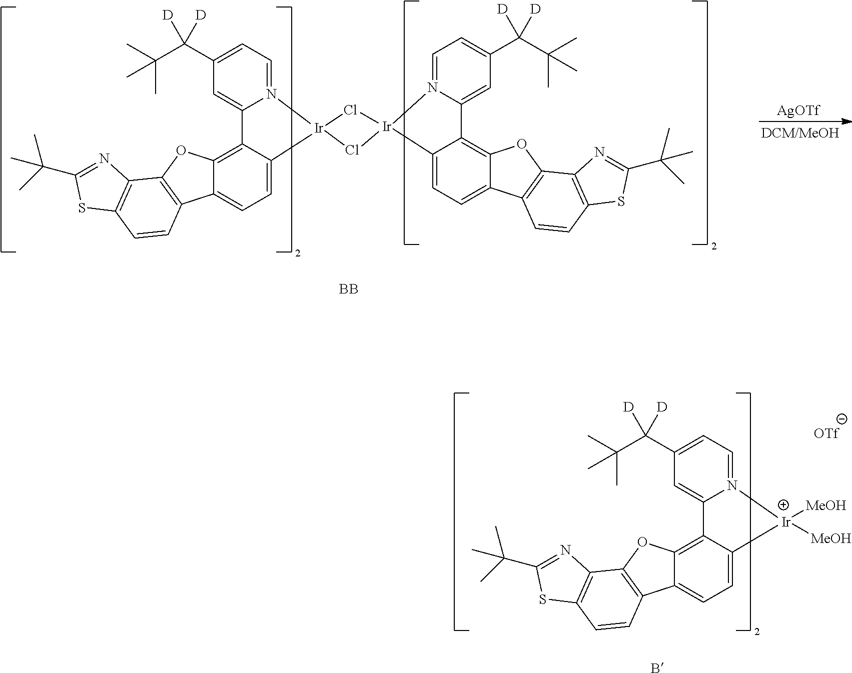

In a 250 mL round bottom flask, the compound BB (8.69 g, 4 mmol), and silver trifluoromethanesulfonate (AgOTf, 3.02 g, 12 mmol) were dissolved in dichloromethane, followed by stirring at room temperature for 24 hours. After completion of the reaction, a reaction product is filtered with Celite to remove solid precipitates therefrom. The filtrate obtained through the filter was subjected to distillation under reduced pressure to obtain a solid compound B′ 8.40 g (83%).

### Preparation of Compound CC

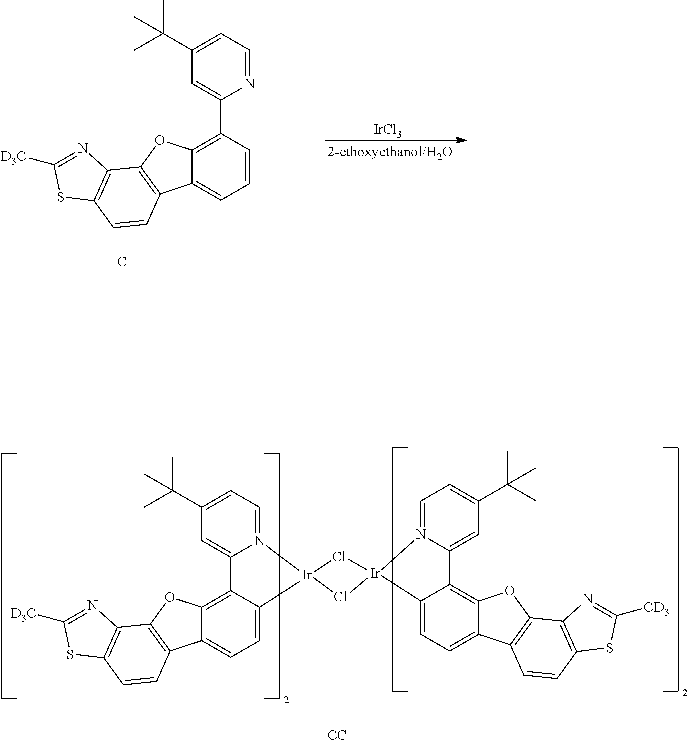

Under a nitrogen atmosphere and in a 250 mL round bottom flask, a compound C (7.45 g, 20 mmol), and IrCl₃ (2.39 g, 8.0 mmol) were dissolved in a mixed solvent (ethoxyethanol:distilled water=90 mL:30 mL), followed by stirring under reflux for 24 hours. After completion of the reaction, a temperature is lowered to room temperature, and a resulting solid is separated via filtration under reduced pressure. The solid filtered through the filter was thoroughly washed with water and cold methanol, and a filtration under reduced pressure was performed. The filtration and washing were repeated several times to obtain a solid compound CC 6.95 g (89%).

### Preparation of Compound C′

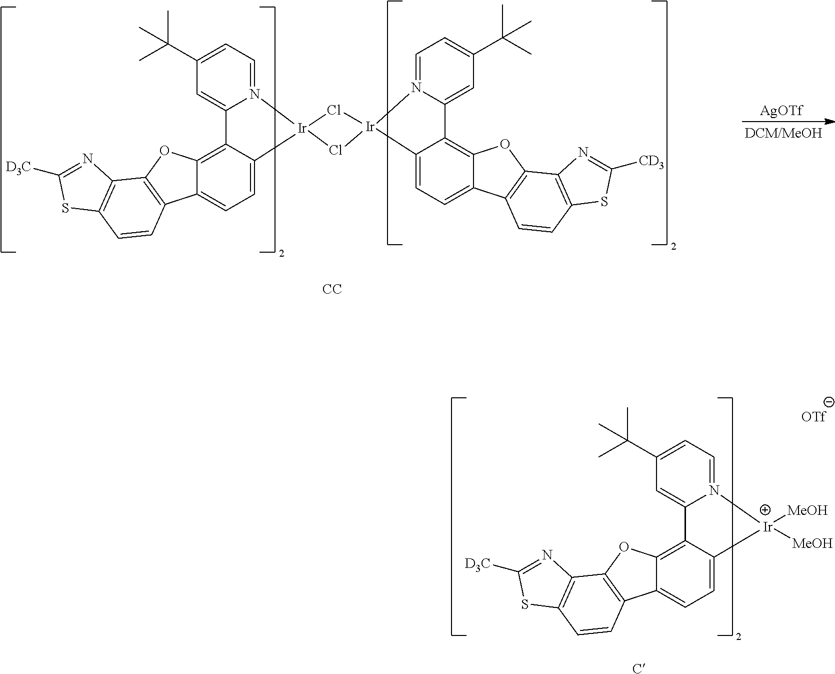

In a 250 mL round bottom flask, the compound CC (7.81 g, 4 mmol), and silver trifluoromethanesulfonate (AgOTf, 3.02 g, 12 mmol) were dissolved in dichloromethane, followed by stirring at room temperature for 24 hours. After completion of the reaction, a reaction product is filtered with Celite to remove solid precipitates therefrom. The filtrate obtained through the filter was subjected to distillation under reduced pressure to obtain a solid compound C′ 7.57 g (82%).

### Preparation of Compound DD

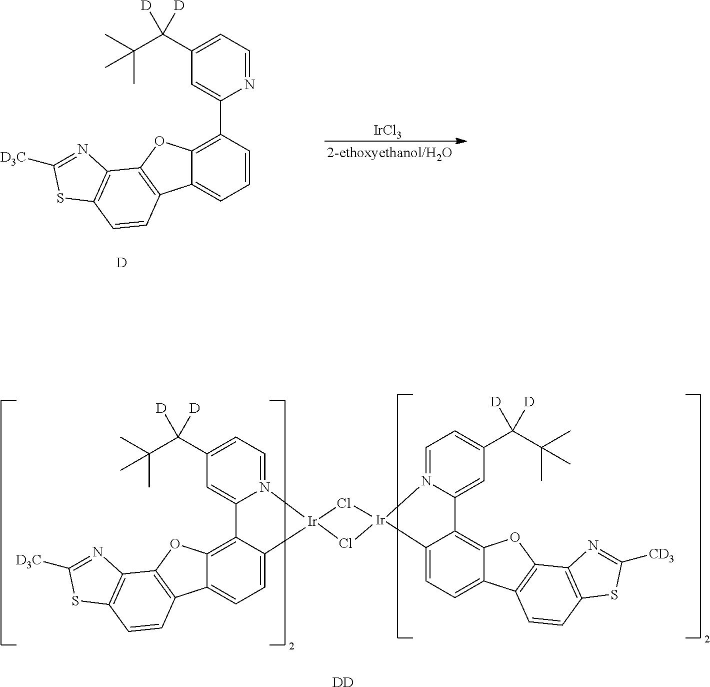

Under a nitrogen atmosphere and in a 250 mL round bottom flask, a compound D (7.37 g, 20 mmol), and IrCl₃ (2.39 g, 8.0 mmol) were dissolved in a mixed solvent (ethoxyethanol:distilled water=90 mL:30 mL), followed by stirring under reflux for 24 hours. After completion of the reaction, a temperature is lowered to room temperature, and a resulting solid is separated via filtration under reduced pressure. The solid filtered through the filter was thoroughly washed with water and cold methanol, and a filtration under reduced pressure was performed. The filtration and washing were repeated several times to obtain a solid compound DD 7.10 g (88%).

### Preparation of Compound D′

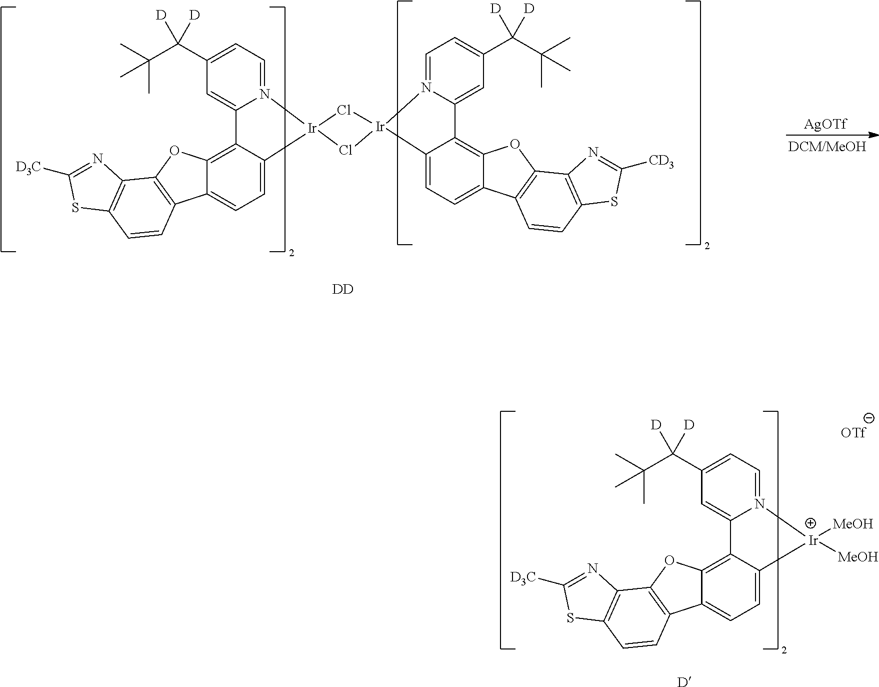

In a 250 mL round bottom flask, the compound DD (8.07 g, 4 mmol), and silver trifluoromethanesulfonate (AgOTf, 3.02 g, 12 mmol) were dissolved in dichloromethane, followed by stirring at room temperature for 24 hours. After completion of the reaction, a reaction product is filtered with Celite to remove solid precipitates therefrom. The filtrate obtained through the filter was subjected to distillation under reduced pressure to obtain a solid compound D′ 7.59 g (80%).

### Preparation of Iridium Compound 45

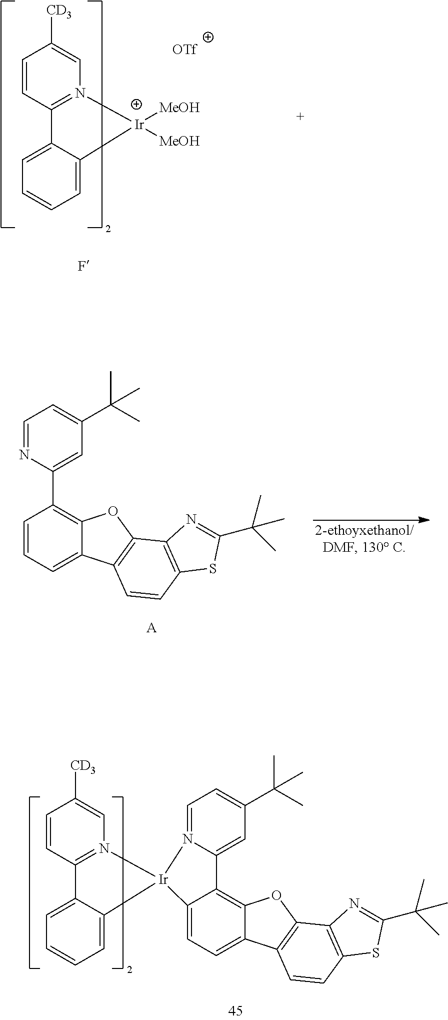

In a 150 mL round bottom flask and under a nitrogen atmosphere, an iridium precursor F′ (1.12 g, 1.5 mmol) and a ligand A (1.24 g, 3 mmol) were dissolved in 2-ethoxyethanol (50 mL) and DMF (50 mL), followed by stirring and heating 130° C. for 24 hours. When the reaction was completed, a temperature was lowered a to room temperature, and then, an organic layer was extracted therefrom using dichloromethane and distilled water. Then, anhydrous magnesium sulfate was added thereto to remove water therefrom. A filtrate is obtained therefrom via filtration, and was depressurized to obtain a crude product. Then, the crude product was purified by means of column chromatography under a condition of ethyl acetate:hexane=25:75 to obtain an iridium compound 45 (1.08 g, 76%).

### Preparation of Iridium Compound 55

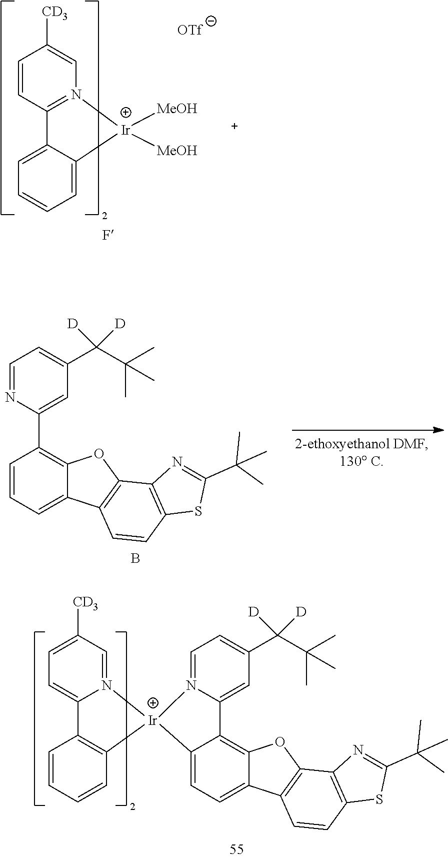

In a 150 mL round bottom flask and under a nitrogen atmosphere, an iridium precursor F′ (1.12 g, 1.5 mmol) and a ligand B (1.29 g, 3 mmol) were dissolved in 2-ethoxyethanol (50 mL) and DMF (50 mL), followed by stirring and heating 130° C. for 24 hours. When the reaction was completed, a temperature was lowered a to room temperature, and then, an organic layer was extracted therefrom using dichloromethane and distilled water. Then, anhydrous magnesium sulfate was added thereto to remove water therefrom. A filtrate is obtained therefrom via filtration, and was depressurized to obtain a crude product. Then, the crude product was purified by means of column chromatography under a condition of ethyl acetate:hexane=25:75 to obtain an iridium compound 55 (1.16 g, 80%).

### Preparation of Iridium Compound 105

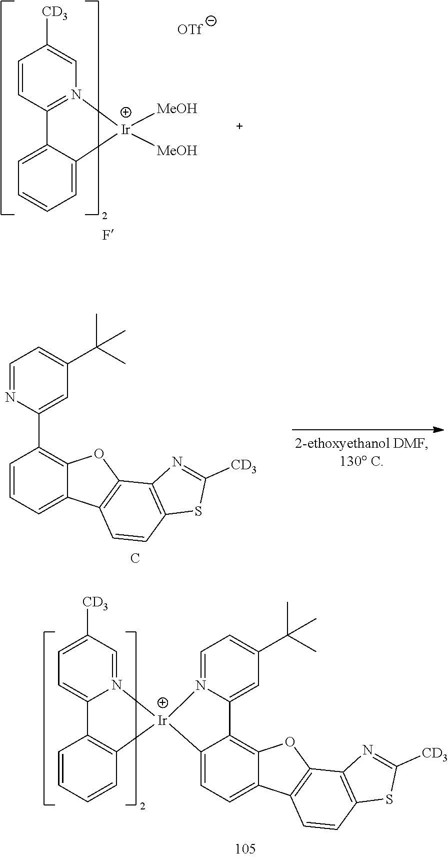

In a 150 mL round bottom flask and under a nitrogen atmosphere, an iridium precursor F′ (1.12 g, 1.5 mmol) and a ligand C (1.12 g, 3 mmol) were dissolved in 2-ethoxyethanol (50 mL) and DMF (50 mL), followed by stirring and heating 130° C. for 24 hours. When the reaction was completed, a temperature was lowered a to room temperature, and then, an organic layer was extracted therefrom using dichloromethane and distilled water. Then, anhydrous magnesium sulfate was added thereto to remove water therefrom. A filtrate is obtained therefrom via filtration, and was depressurized to obtain a crude product. Then, the crude product was purified by means of column chromatography under a condition of ethyl acetate:hexane=25:75 to obtain an iridium compound 105 (1.04 g, 76%).

### Preparation of Iridium Compound 115

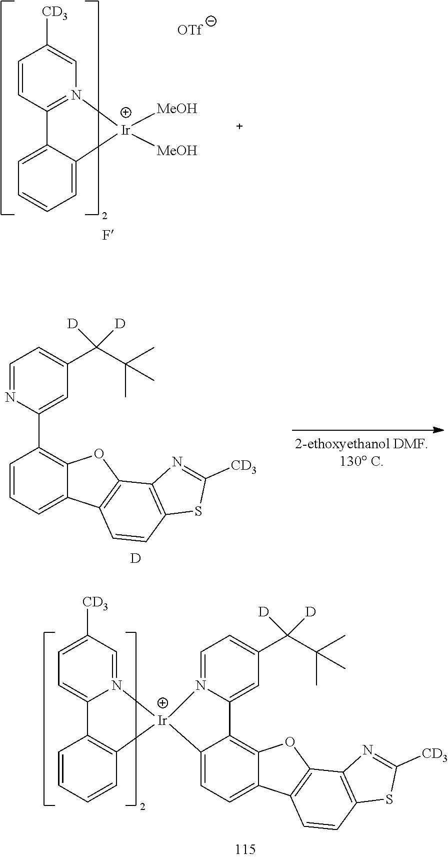

In a 150 mL round bottom flask and under a nitrogen atmosphere, an iridium precursor F′ (1.12 g, 1.5 mmol) and a ligand D (1.11 g, 3 mmol) were dissolved in 2-ethoxyethanol (50 mL) and DMF (50 mL), followed by stirring and heating 130° C. for 24 hours. When the reaction was completed, a temperature was lowered a to room temperature, and then, an organic layer was extracted therefrom using dichloromethane and distilled water. Then, anhydrous magnesium sulfate was added thereto to remove water therefrom. A filtrate is obtained therefrom via filtration, and was depressurized to obtain a crude product. Then, the crude product was purified by means of column chromatography under a condition of ethyl acetate:hexane=25:75 to obtain an iridium compound 115 (1.04 g, 75%).

### Preparation of Iridium Compound 385

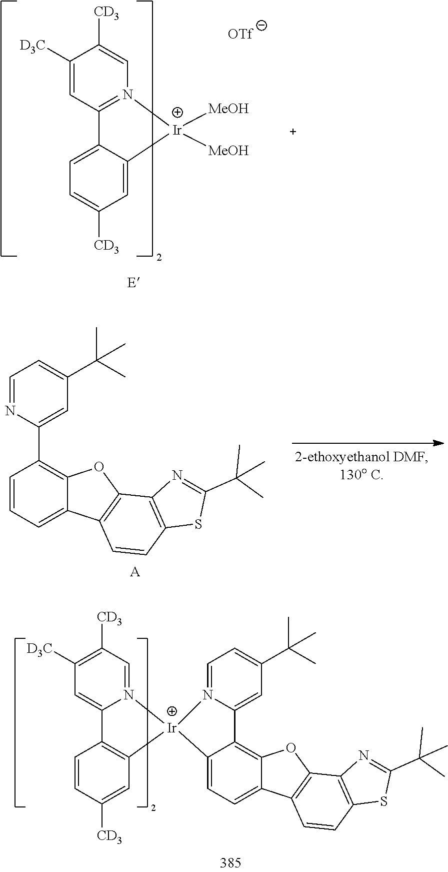

In a 150 mL round bottom flask and under a nitrogen atmosphere, an iridium precursor E′ (1.22 g, 1.5 mmol) and a ligand A (1.24 g, 3 mmol) were dissolved in 2-ethoxyethanol (50 mL) and DMF (50 mL), followed by stirring and heating 130° C. for 24 hours. When the reaction was completed, a temperature was lowered a to room temperature, and then, an organic layer was extracted therefrom using dichloromethane and distilled water. Then, anhydrous magnesium sulfate was added thereto to remove water therefrom. A filtrate is obtained therefrom via filtration, and was depressurized to obtain a crude product. Then, the crude product was purified by means of column chromatography under a condition of ethyl acetate:hexane=25:75 to obtain an iridium compound 385 (1.14 g, 75%).

### Preparation of Iridium Compound 395

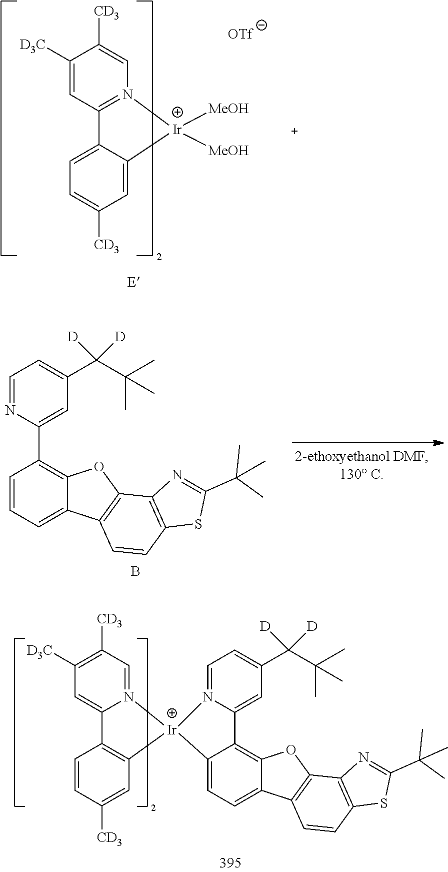

In a 150 mL round bottom flask and under a nitrogen atmosphere, an iridium precursor E′ (1.22 g, 1.5 mmol) and a ligand B (1.29 g, 3 mmol) were dissolved in 2-ethoxyethanol (50 mL) and DMF (50 mL), followed by stirring and heating 130° C. for 24 hours. When the reaction was completed, a temperature was lowered a to room temperature, and then, an organic layer was extracted therefrom using dichloromethane and distilled water. Then, anhydrous magnesium sulfate was added thereto to remove water therefrom. A filtrate is obtained therefrom via filtration, and was depressurized to obtain a crude product. Then, the crude product was purified by means of column chromatography under a condition of ethyl acetate:hexane=25:75 to obtain an iridium compound 395 (1.21 g, 78%).

### Preparation of Iridium Compound 445

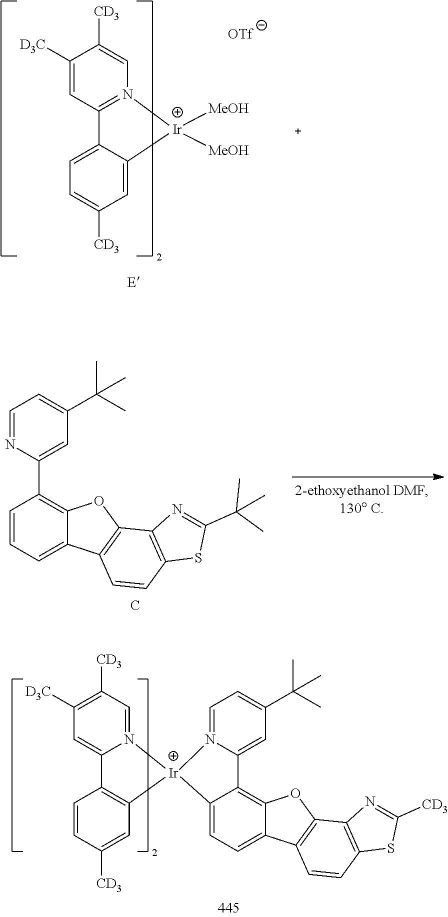

In a 150 mL round bottom flask and under a nitrogen atmosphere, an iridium precursor E′ (1.22 g, 1.5 mmol) and a ligand C (1.12 g, 3 mmol) were dissolved in 2-ethoxyethanol (50 mL) and DMF (50 mL), followed by stirring and heating 130° C. for 24 hours. When the reaction was completed, a temperature was lowered a to room temperature, and then, an organic layer was extracted therefrom using dichloromethane and distilled water. Then, anhydrous magnesium sulfate was added thereto to remove water therefrom. A filtrate is obtained therefrom via filtration, and was depressurized to obtain a crude product. Then, the crude product was purified by means of column chromatography under a condition of ethyl acetate:hexane=25:75 to obtain an iridium compound 445 (1.07 g, 73%).

### Preparation of Iridium Compound 455

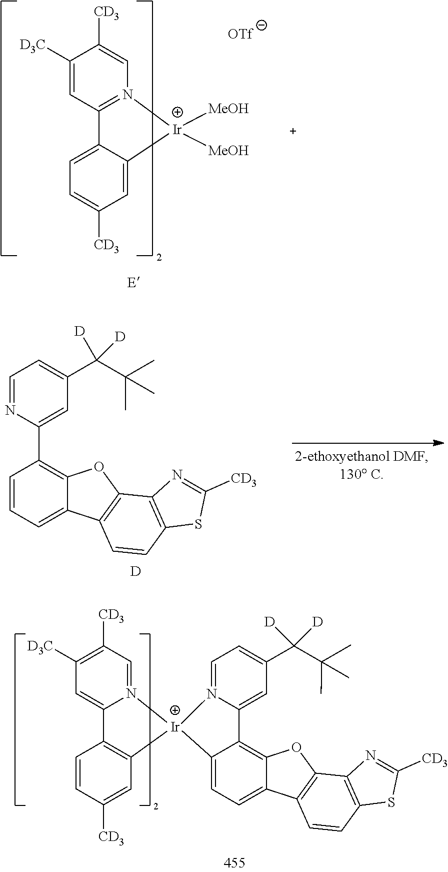

In a 150 mL round bottom flask and under a nitrogen atmosphere, an iridium precursor E′ (1.22 g, 1.5 mmol) and a ligand D (1.11 g, 3 mmol) were dissolved in 2-ethoxyethanol (50 mL) and DMF (50 mL), followed by stirring and heating 130° C. for 24 hours. When the reaction was completed, a temperature was lowered a to room temperature, and then, an organic layer was extracted therefrom using dichloromethane and distilled water. Then, anhydrous magnesium sulfate was added thereto to remove water therefrom. A filtrate is obtained therefrom via filtration, and was depressurized to obtain a crude product. Then, the crude product was purified by means of column chromatography under a condition of ethyl acetate:hexane=25:75 to obtain an iridium compound 455 (1.06 g, 71%).

### Preparation of Iridium Compound 645

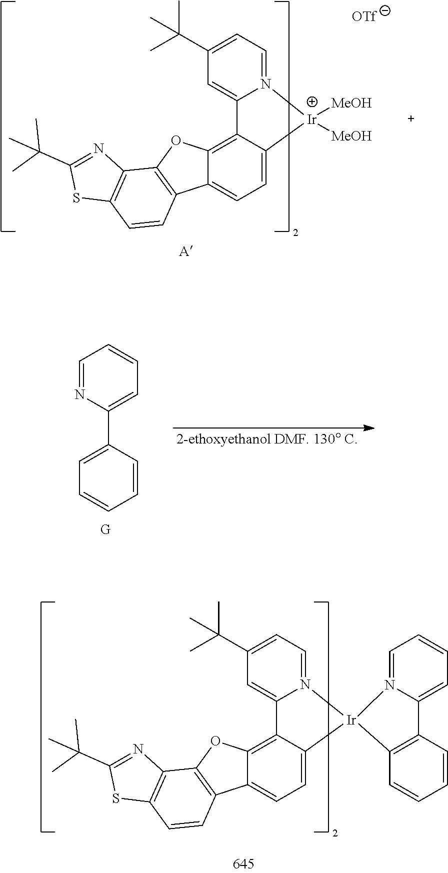

In a 150 mL round bottom flask and under a nitrogen atmosphere, an iridium precursor A′ (1.85 g, 1.5 mmol) and a ligand G (0.47 g, 3 mmol) were dissolved in 2-ethoxyethanol (50 mL) and DMF (50 mL), followed by stirring and heating 130° C. for 24 hours. When the reaction was completed, a temperature was lowered a to room temperature, and then, an organic layer was extracted therefrom using dichloromethane and distilled water. Then, anhydrous magnesium sulfate was added thereto to remove water therefrom. A filtrate is obtained therefrom via filtration, and was depressurized to obtain a crude product. Then, the crude product was purified by means of column chromatography under a condition of ethyl acetate:hexane=50:50 to obtain an iridium compound 645 (1.29 g, 73%).

### Preparation of Iridium Compound 649

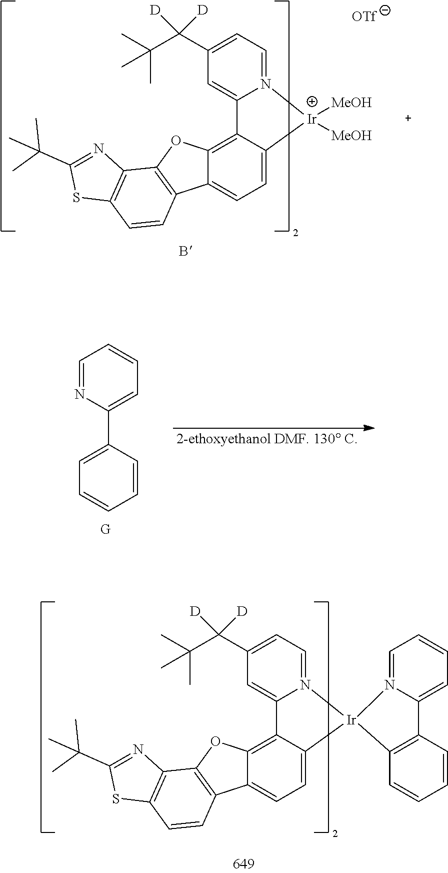

In a 150 mL round bottom flask and under a nitrogen atmosphere, an iridium precursor B′ (1.90 g, 1.5 mmol) and a ligand G (0.47 g, 3 mmol) were dissolved in 2-ethoxyethanol (50 mL) and DMF (50 mL), followed by stirring and heating 130° C. for 24 hours. When the reaction was completed, a temperature was lowered a to room temperature, and then, an organic layer was extracted therefrom using dichloromethane and distilled water. Then, anhydrous magnesium sulfate was added thereto to remove water therefrom. A filtrate is obtained therefrom via filtration, and was depressurized to obtain a crude product. Then, the crude product was purified by means of column chromatography under a condition of ethyl acetate:hexane=50:50 to obtain an iridium compound 649 (1.46 g, 81%).

### Preparation of Iridium Compound 655

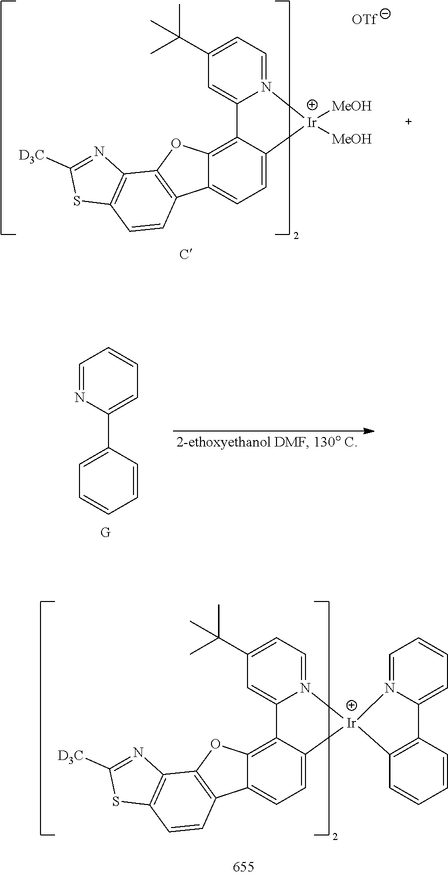

In a 150 mL round bottom flask and under a nitrogen atmosphere, an iridium precursor C′ (1.73 g, 1.5 mmol) and a ligand G (0.47 g, 3 mmol) were dissolved in 2-ethoxyethanol (50 mL) and DMF (50 mL), followed by stirring and heating 130° C. for 24 hours. When the reaction was completed, a temperature was lowered a to room temperature, and then, an organic layer was extracted therefrom using dichloromethane and distilled water. Then, anhydrous magnesium sulfate was added thereto to remove water therefrom. A filtrate is obtained therefrom via filtration, and was depressurized to obtain a crude product. Then, the crude product was purified by means of column chromatography under a condition of ethyl acetate:hexane=50:50 to obtain an iridium compound 655 (1.31 g, 80%).

### Preparation of Iridium Compound 659

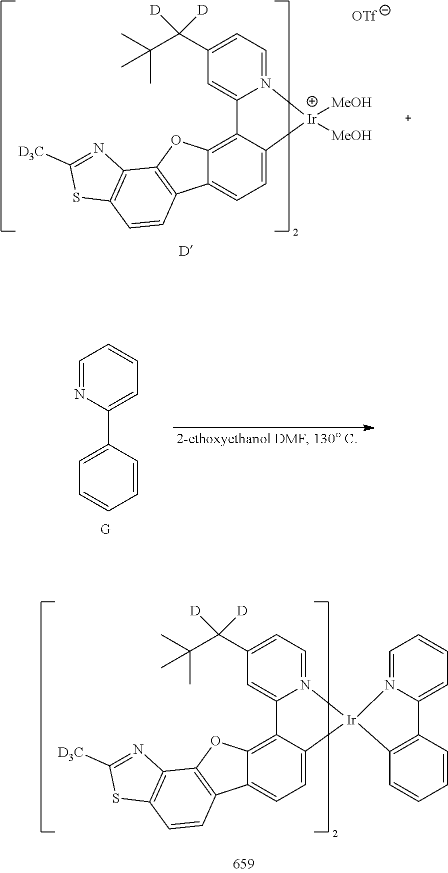

In a 150 mL round bottom flask and under a nitrogen atmosphere, an iridium precursor D′ (1.78 g, 1.5 mmol) and a ligand G (0.47 g, 3 mmol) were dissolved in 2-ethoxyethanol (50 mL) and DMF (50 mL), followed by stirring and heating 130° C. for 24 hours. When the reaction was completed, a temperature was lowered a to room temperature, and then, an organic layer was extracted therefrom using dichloromethane and distilled water. Then, anhydrous magnesium sulfate was added thereto to remove water therefrom. A filtrate is obtained therefrom via filtration, and was depressurized to obtain a crude product. Then, the crude product was purified by means of column chromatography under a condition of ethyl acetate:hexane=50:50 to obtain an iridium compound 659 (1.29 g, 76%).

### Preparation of Iridium Compound 665

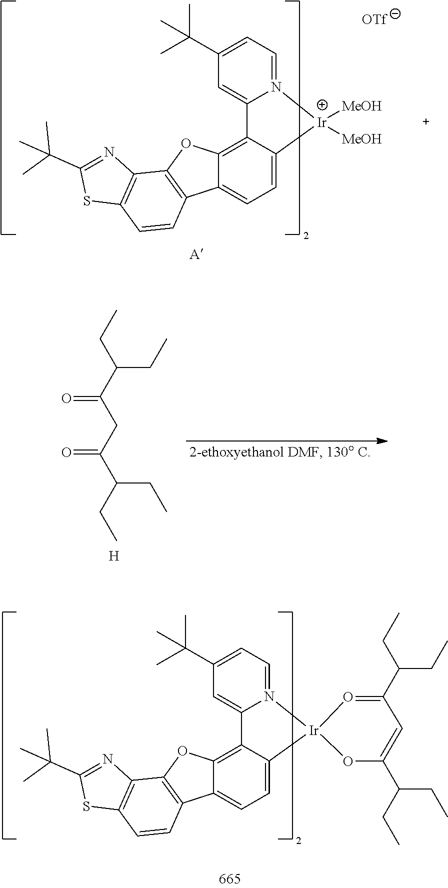

In a 150 mL round bottom flask and under a nitrogen atmosphere, an iridium precursor A′ (1.85 g, 1.5 mmol) and a ligand H (0.63 g, 3 mmol) were dissolved in 2-ethoxyethanol (50 mL) and DMF (50 mL), followed by stirring and heating 130° C. for 24 hours. When the reaction was completed, a temperature was lowered a to room temperature, and then, an organic layer was extracted therefrom using dichloromethane and distilled water. Then, anhydrous magnesium sulfate was added thereto to remove water therefrom. A filtrate is obtained therefrom via filtration, and was depressurized to obtain a crude product. Then, the crude product was purified by means of column chromatography under a condition of ethyl acetate:hexane=40:60 to obtain an iridium compound 665 (1.38 g, 75%).

### Preparation of Iridium Compound 669

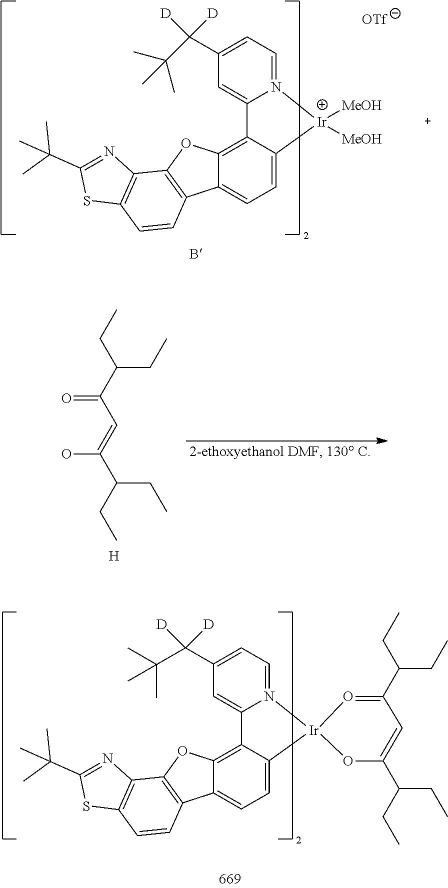

In a 150 mL round bottom flask and under a nitrogen atmosphere, an iridium precursor B′ (1.90 g, 1.5 mmol) and a ligand H (0.63 g, 3 mmol) were dissolved in 2-ethoxyethanol (50 mL) and DMF (50 mL), followed by stirring and heating 130° C. for 24 hours. When the reaction was completed, a temperature was lowered a to room temperature, and then, an organic layer was extracted therefrom using dichloromethane and distilled water. Then, anhydrous magnesium sulfate was added thereto to remove water therefrom. A filtrate is obtained therefrom via filtration, and was depressurized to obtain a crude product. Then, the crude product was purified by means of column chromatography under a condition of ethyl acetate:hexane=40:60 to obtain an iridium compound 669 (1.46 g, 77%).

### Preparation of Iridium Compound 675

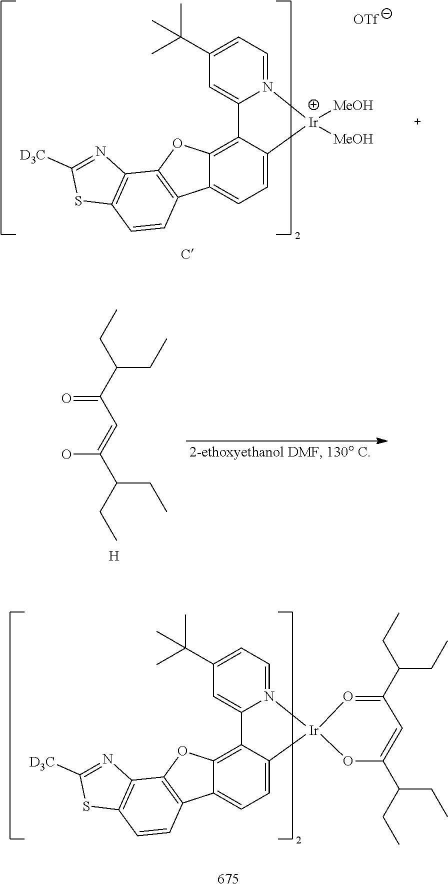

In a 150 mL round bottom flask and under a nitrogen atmosphere, an iridium precursor C′ (1.73 g, 1.5 mmol) and a ligand H (0.63 g, 3 mmol) were dissolved in 2-ethoxyethanol (50 mL) and DMF (50 mL), followed by stirring and heating 130° C. for 24 hours. When the reaction was completed, a temperature was lowered a to room temperature, and then, an organic layer was extracted therefrom using dichloromethane and distilled water. Then, anhydrous magnesium sulfate was added thereto to remove water therefrom. A filtrate is obtained therefrom via filtration, and was depressurized to obtain a crude product. Then, the crude product was purified by means of column chromatography under a condition of ethyl acetate:hexane=40:60 to obtain an iridium compound 675 (1.23 g, 71%).

### Preparation of Iridium Compound 679

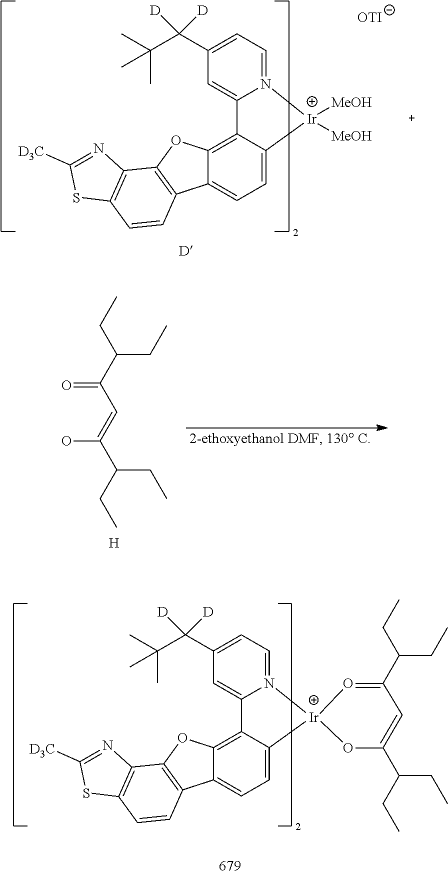

In a 150 mL round bottom flask and under a nitrogen atmosphere, an iridium precursor D′ (1.78 g, 1.5 mmol) and a ligand H (0.63 g, 3 mmol) were dissolved in 2-ethoxyethanol (50 mL) and DMF (50 mL), followed by stirring and heating 130° C. for 24 hours. When the reaction was completed, a temperature was lowered a to room temperature, and then, an organic layer was extracted therefrom using dichloromethane and distilled water. Then, anhydrous magnesium sulfate was added thereto to remove water therefrom. A filtrate is obtained therefrom via filtration, and was depressurized to obtain a crude product. Then, the crude product was purified by means of column chromatography under a condition of ethyl acetate:hexane=40:60 to obtain an iridium compound 679 (1.30 g, 73%).

### EXAMPLES

### Present Example 1

A glass substrate having a thin film of ITO (indium tin oxide) having a thickness of 1,000 Å coated thereon was washed, followed by ultrasonic cleaning with a solvent such as isopropyl alcohol, acetone, or methanol. Then, the glass substrate was dried. Thus, an ITO transparent electrode was formed. HI-1 as a hole injection material was deposited on the ITO transparent electrode in a thermal vacuum deposition manner. Thus, a hole injection layer having a thickness of 60 nm was formed. Then, NPB as a hole transport material was deposited on the hole injection layer in a thermal vacuum deposition manner. Thus, a hole transport layer having a thickness of 80 nm was formed. Then, CBP as a host material of a light-emitting layer was deposited on the hole transport layer in a thermal vacuum deposition manner. The compound 45 as a dopant was doped into the host material at a doping concentration of 5%. Thus, the light-emitting layer of a thickness of 30 nm was formed. ET-1:Liq (1:1) (30 nm) as materials for an electron transport layer and an electron injection layer, respectively, were deposited on the light-emitting layer. Then, 100 nm thick aluminum was deposited thereon to form a negative electrode. In this way, an organic light-emitting diode was manufactured. The materials used in Present Example 1 are as follows.

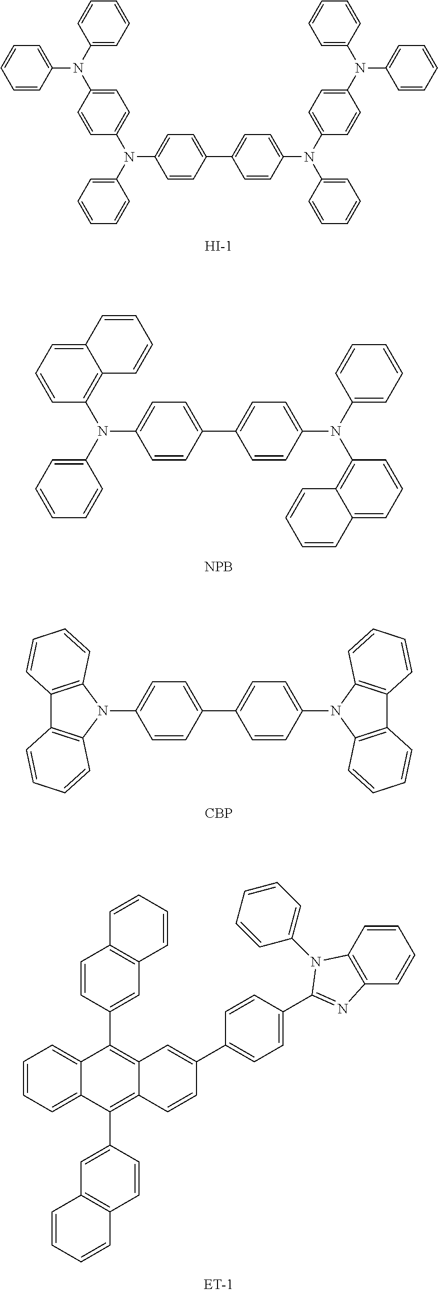

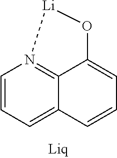

HI-1 is NPNPB, and ET-1 is ZADN.

### Present Examples 2 to 16

An organic light-emitting diode of each of Present Examples 2 to 16 was manufactured in the same manner as in Present Example 1, except that each of compounds as indicated in following Tables 1 and 2 was used instead of the compound 45 in Present Example 1.

### Comparative Examples 1 to 4

An organic light-emitting diode of each of Comparative Examples 1 to 4 was manufactured in the same manner as in Present Example 1, except that each of following compounds Ref-1 to Ref-4 as compounds as indicated in the following Tables 1 and 2 was used instead of the compound 45 in Present Example 1:

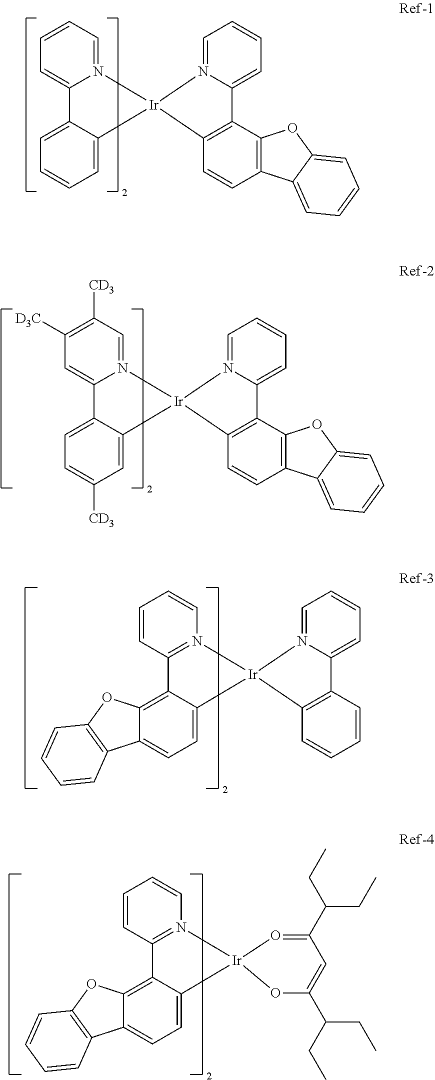

### Experimental Example

The organic light-emitting diode as manufactured in each of Present Examples 1 to 16 and Comparative Examples 1 to 4 was connected to an external power source, and characteristics of the organic light-emitting diode were evaluated at room temperature using a current source and a photometer.

Specifically, operation voltage (V), maximum light-emission quantum efficiency (%), external quantum efficiency (EQE; %, relative value), and lifetime characteristics (LT95; %, relative value) were measured at a current density of 10 mA/cm², and were calculated as relative values to those of Comparative Example 1, and the results are shown in a following Table 1.

LT95 lifetime refers to a time it takes for the display element to lose 5% of its initial brightness. LT95 is the customer specification to most difficult to meet. Whether or not image burn-in occurs on the display may be determined based on the LT95.

TABLE 1

| | | | Maximum light- | | |
|---|---|---|---|---|---|
| | | Operation | emission quantum | EQE | LT95 |
| | | voltage | efficiency | (%, relative | (%, relative |
| | Dopant | (V) | (%, relative value) | value) | value) |
| Comparative | Ref-1 | 4.25 | 100 | 100 | 100 |
| Example 1 | | | | | |
| Comparative | Ref-2 | 4.26 | 101 | 102 | 108 |
| Example 2 | | | | | |
| Present | Compound 45 | 4.22 | 113 | 112 | 125 |
| Example 1 | | | | | |
| Present | Compound 55 | 4.21 | 114 | 115 | 128 |
| Example 2 | | | | | |
| Present | Compound 105 | 4.22 | 112 | 114 | 129 |
| Example 3 | | | | | |
| Present | Compound 115 | 4.21 | 110 | 112 | 130 |
| Example 4 | | | | | |
| Present | Compound 385 | 4.23 | 114 | 114 | 124 |
| Example 5 | | | | | |
| Present | Compound 395 | 4.24 | 115 | 116 | 125 |
| Example 6 | | | | | |
| Present | Compound 445 | 4.22 | 117 | 118 | 127 |
| Example 7 | | | | | |
| Present | Compound 455 | 4.23 | 118 | 118 | 129 |
| Example 8 | | | | | |

TABLE 2

| | | | Maximum light- | | |
|---|---|---|---|---|---|
| | | Operation | emission quantum | EQE | LT95 |
| | | voltage | efficiency | (%, relative | (%, relative |
| | Dopant | (V) | (%, relative value) | value) | value) |
| Comparative | Ref-3 | 4.32 | 94 | 90 | 101 |
| Example 3 | | | | | |
| Comparative | Ref-4 | 4.31 | 95 | 92 | 100 |
| Example 4 | | | | | |
| Present | Compound 645 | 4.23 | 116 | 112 | 126 |
| Example 9 | | | | | |
| Present | Compound 649 | 4.21 | 115 | 113 | 128 |
| Example 10 | | | | | |
| Present | Compound 655 | 4.22 | 116 | 114 | 126 |
| Example 11 | | | | | |
| Present | Compound 659 | 4.22 | 117 | 115 | 127 |
| Example 12 | | | | | |
| Present | Compound 665 | 4.23 | 118 | 115 | 126 |
| Example 13 | | | | | |
| Present | Compound 669 | 4.24 | 116 | 114 | 124 |
| Example 14 | | | | | |
| Present | Compound 675 | 4.23 | 115 | 113 | 126 |
| Example 15 | | | | | |
| Present | Compound 679 | 4.24 | 114 | 112 | 124 |
| Example 16 | | | | | |

Each of the compounds of Present Examples of the present disclosure is different from each of Ref-1 to Ref-4 as the dopant compound of the light-emitting layer of each of Comparative Examples 1 to 4 of the present disclosure in that each of Ref-1 to Ref-4 has a structure in which the thiazole group does not bind to the dibenzofuran group moiety of the main ligand.

As may be identified from the results of Tables 1 and 2, the organic light-emitting diode of each of Present Examples 1 to 16 of the present disclosure in which the organometallic compound of a structure in which the aralkyl group moiety binds to the pyridine is used as a dopant in the light-emitting layer has lowered operation voltage, and improved maximum light-emission quantum efficiency, external quantum efficiency (EQE) and lifetime (LT95) compared to those in the organic light-emitting diode of each of Comparative Examples 1 to 4.

Although the embodiments of the present disclosure have been described in more detail with reference to the accompanying drawings, the present disclosure is not necessarily limited to these embodiments, and may be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects.

What is claimed is:

1. An organometallic compound represented by a following Chemical Formula 1:
Ir(L_{A})ₘ(L_{B})ₙ [Chemical Formula 1]
wherein in the Chemical Formula 1,
L_{A} and L_{B} are represented by a following Chemical Formula 2 and a following Chemical Formula 3, respectively,
m is an integer from 1 to 3, n is an integer from 0 to 2, a sum of m and n is 3, 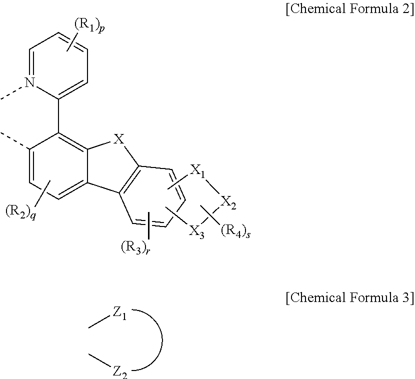
wherein in the Chemical Formula 2,
each of X, X₁, X₂ and X₃ independently represents one selected from a group consisting of carbon (C), oxygen (O), nitrogen (N) and sulfur (S),
each of R₁, R₂, R₃ and R₄ independently represents one selected from a group consisting of deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acid, ester, nitrile, isonitrile, sulfanyl, sulfinyl, sulfonyl, phosphino, and combinations thereof,
p is an integer from 0 to 4, each of q and r is independently an integer from 0 to 2, s is an integer from 0 to 3,
when p is 2 or larger, two adjacent to each other of a plurality of R₁s may bind to each other to form a fused ring structure,
when q is 2, two adjacent to each other of a plurality of R₂s may bind to each other to form a fused ring structure,
when r is 2, two adjacent to each other of a plurality of R₃s may bind to each other to form a fused ring structure,
when s is 2, two adjacent to each other of a plurality of R₄s may bind to each other to form a fused ring structure,
the Chemical Formula 3 is a bidendate ligand.

2. The organometallic compound of claim 1, wherein X is oxygen (O).

3. The organometallic compound of claim 1, wherein one of X₁ and X₃ is nitrogen (N), and the other of X₁ and X₃ other than nitrogen (N) is sulfur (S).

4. The organometallic compound of claim 1, wherein the Chemical Formula 2 has a structure represented by one selected from a group consisting of following Chemical Formula 2-1, Chemical Formula 2-2 and Chemical Formula 2-3: 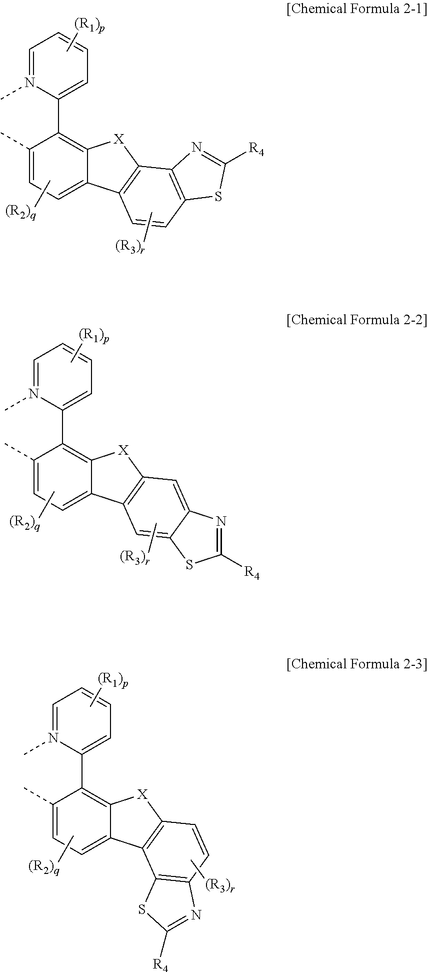
wherein in the Chemical Formulas 2-1 to 2-3, each of R₁ and R₄ represents one selected from a group consisting of deuterium, halogen, a C1 to C10 linear alkyl group, a C1 to C10 branched alkyl group, a C7 to C30 aralkyl group, and a C6 to C30 aryl group,
wherein at least one hydrogen of each of the C1 to C10 linear alkyl group, the C1 to C10 branched alkyl group, the C7 to C30 aralkyl group, or the C6 to C30 aryl group selected as R₁ or R₄ may be substituted with deuterium.

5. The organometallic compound of claim 4, wherein R₄ represents one selected from a group consisting of deuterium, a C1 to C10 linear alkyl group, and a C1 to C10 branched alkyl group,
wherein at least one hydrogen of each of the C1 to C10 linear alkyl group, or the C1 to C10 branched alkyl group selected as R₄ may be substituted with deuterium.

6. The organometallic compound of claim 1, wherein each of q and r is independently an integer of 0.

7. The organometallic compound of claim 1, wherein the Chemical Formula 3 has a structure represented by one selected from a group consisting of following Chemical Formula 3-1 and Chemical Formula 3-2: 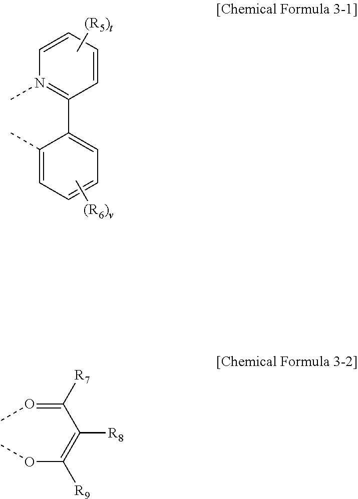
wherein in the Chemical Formula 3-1, each of R₅ and R₆ independently represents one selected from a group consisting of deuterium, a C1 to C5 linear alkyl group, and a C1 to C5 branched alkyl group,
wherein at least one hydrogen of each of the C1 to C5 linear alkyl group or the C1 to C5 branched alkyl group selected as R₅ or R₆ may be substituted with at least one selected from deuterium and a halogen element,
wherein each of t and v is independently an integer from 0 to 4,
wherein when t is 2 or greater, two functional groups adjacent to each other among a plurality of R₅s may bind to each other to form a fused ring structure,
wherein when v is 2 or greater, two functional groups adjacent to each other among a plurality of Res may bind to each other to form a fused ring structure,
wherein in the Chemical Formula 3-2, each of R₇, R₈, and R₉ independently represents one selected from a group consisting of hydrogen, deuterium, a C1 to C5 linear alkyl group, and a C1 to C5 branched alkyl group,
wherein at least one hydrogen of each of the C1 to C5 linear alkyl group or the C1 to C5 branched alkyl group selected as R₇, R₈ or R₉ may be substituted with at least one selected from deuterium and a halogen element,
wherein two functional groups adjacent to each other among R₇, R₈ and R₉ may bind to each other to form a fused ring structure.

8. The organometallic compound of claim 1, wherein m is 1, and n is 2.

9. The organometallic compound of claim 1, wherein m is 2, and n is 1.

10. The organometallic compound of claim 1, wherein m is 3, and n is 0.

11. The organometallic compound of claim 1, wherein the compound represented by the Chemical Formula 1 is one selected from a group consisting of following compounds 1 to 680:

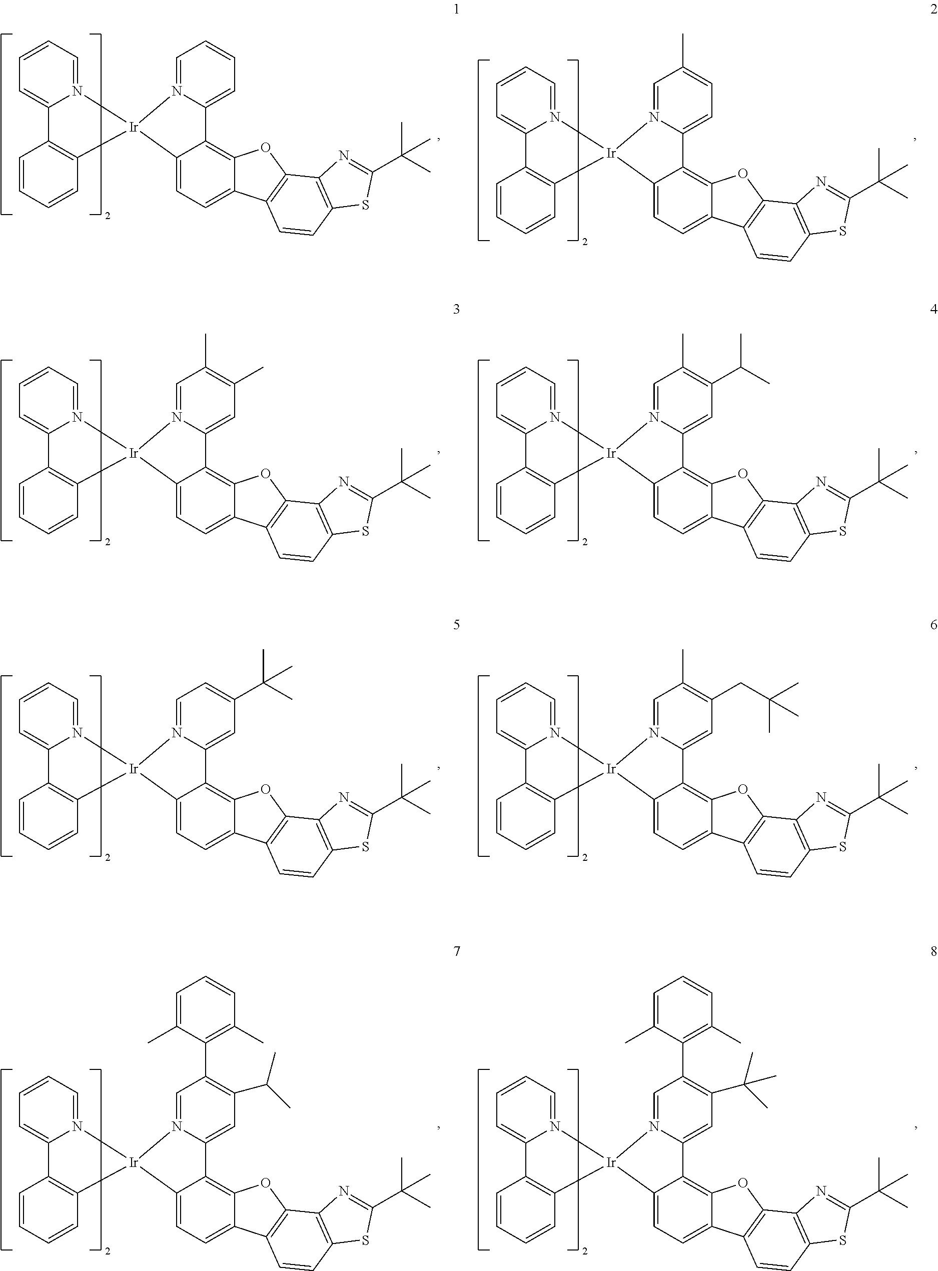

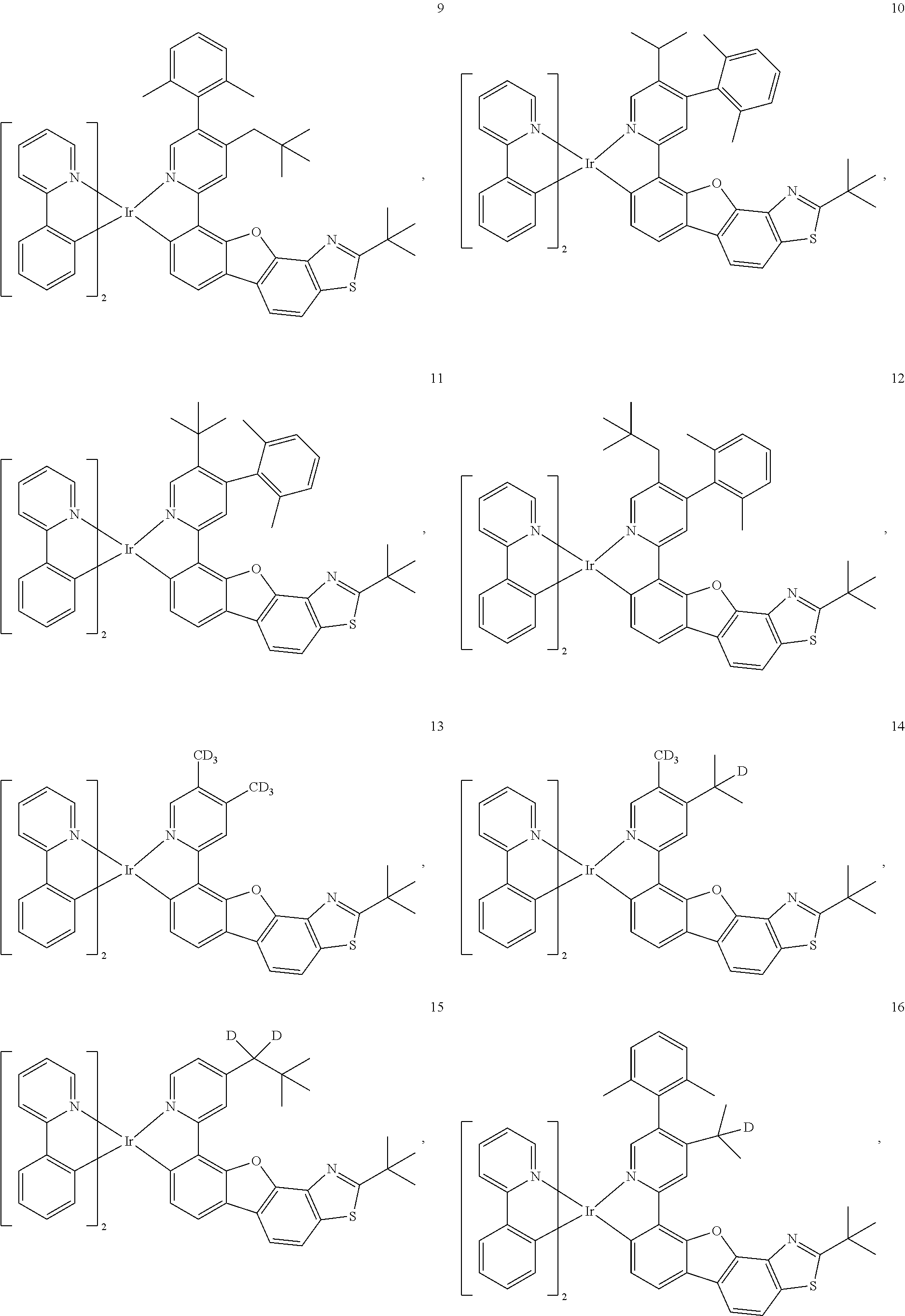

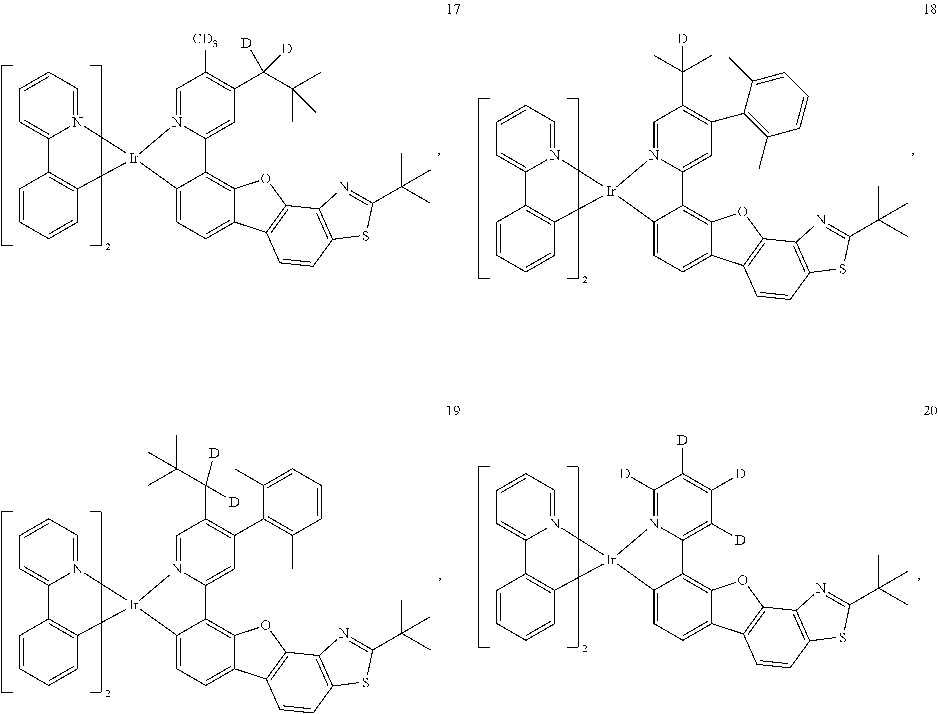

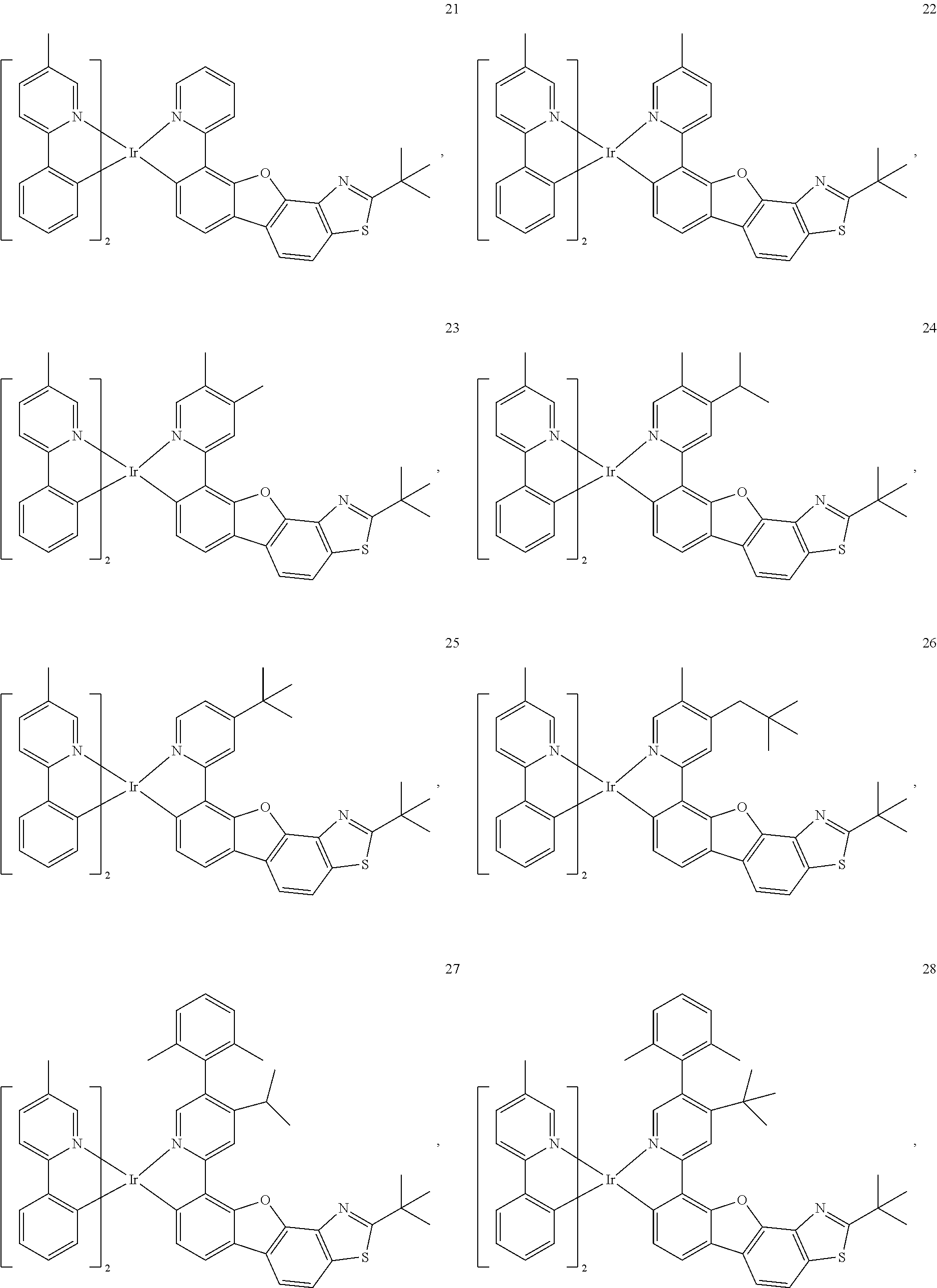

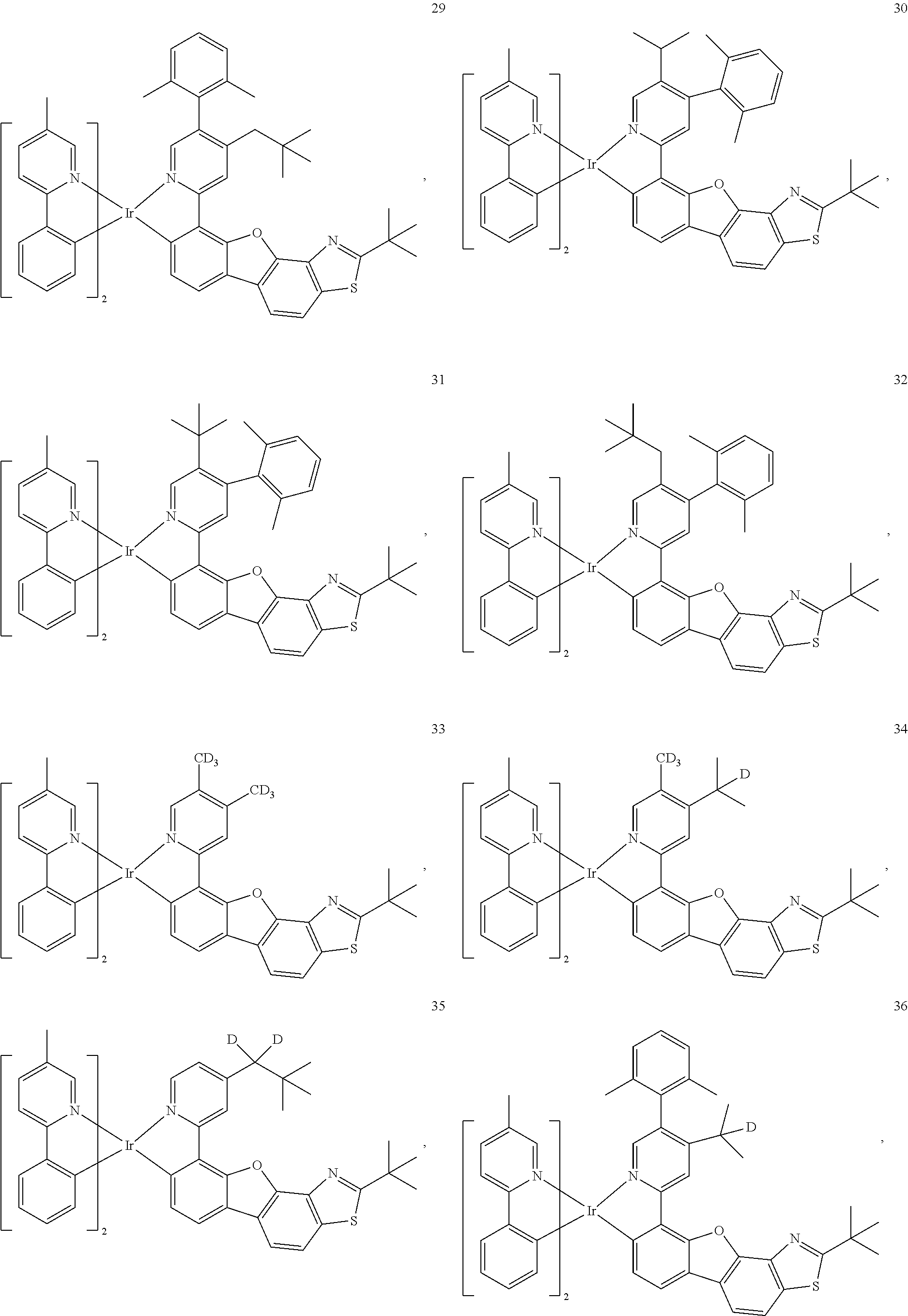

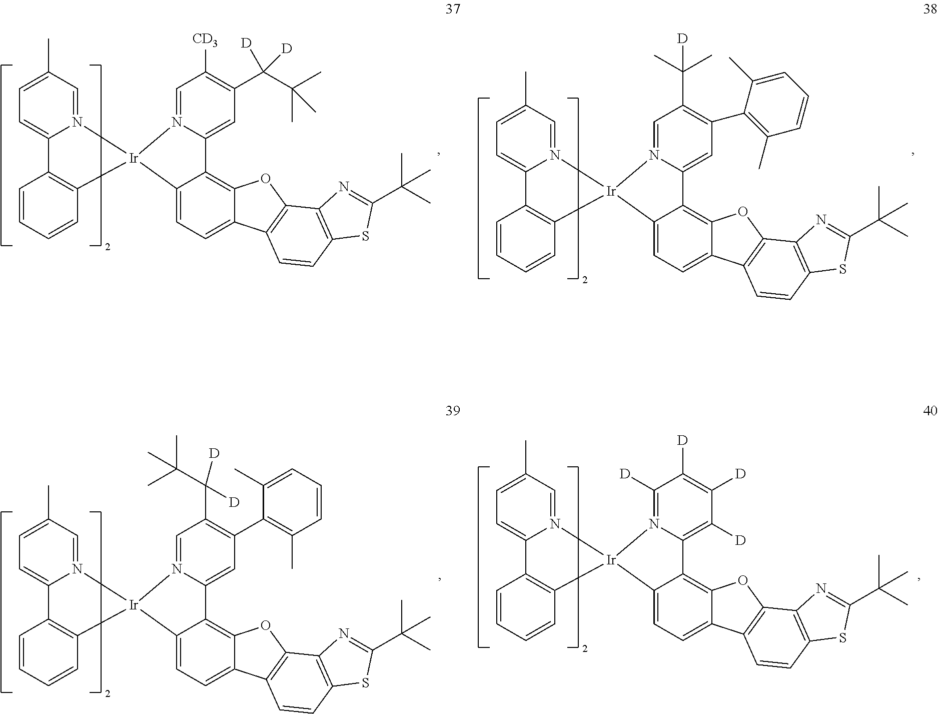

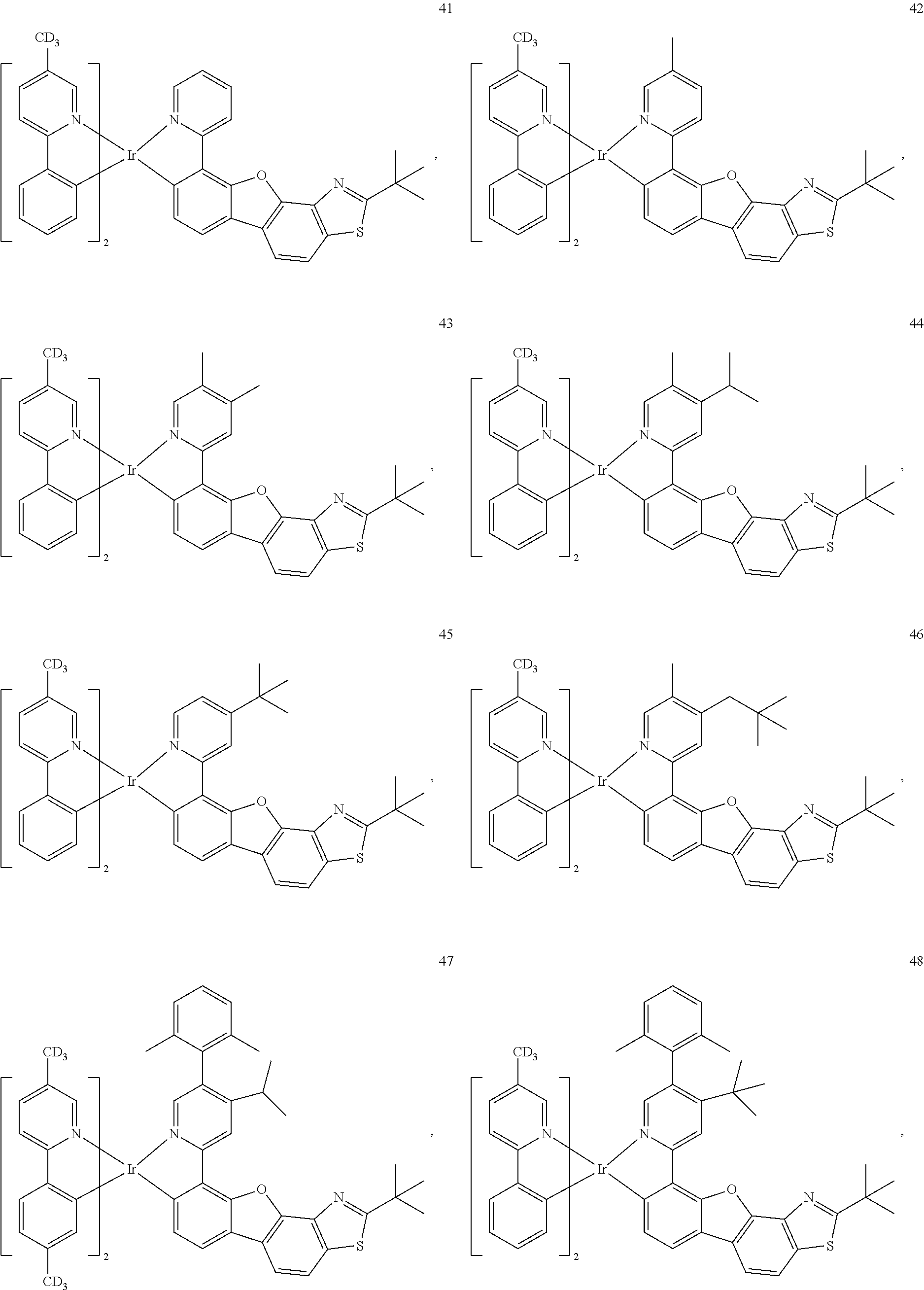

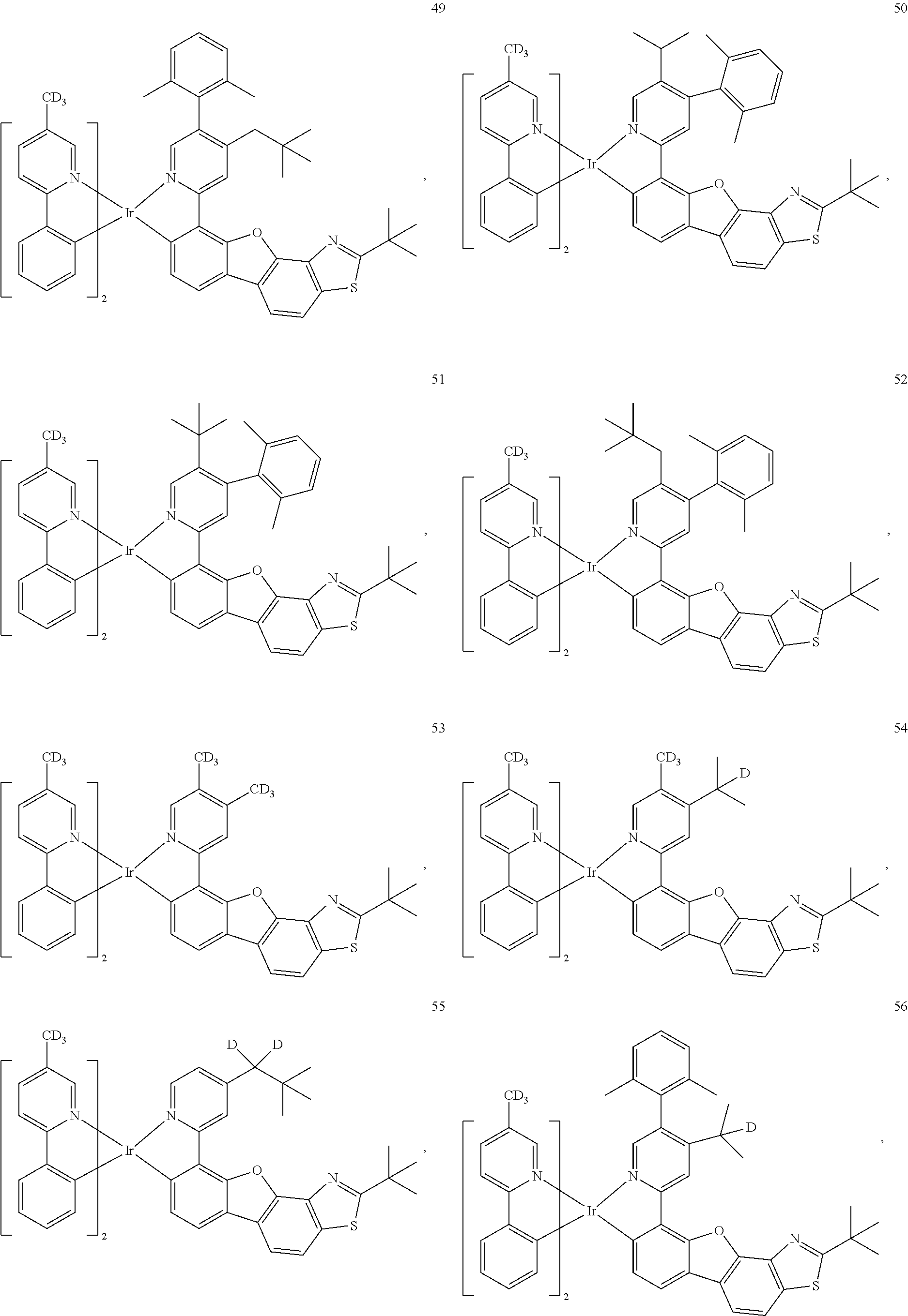

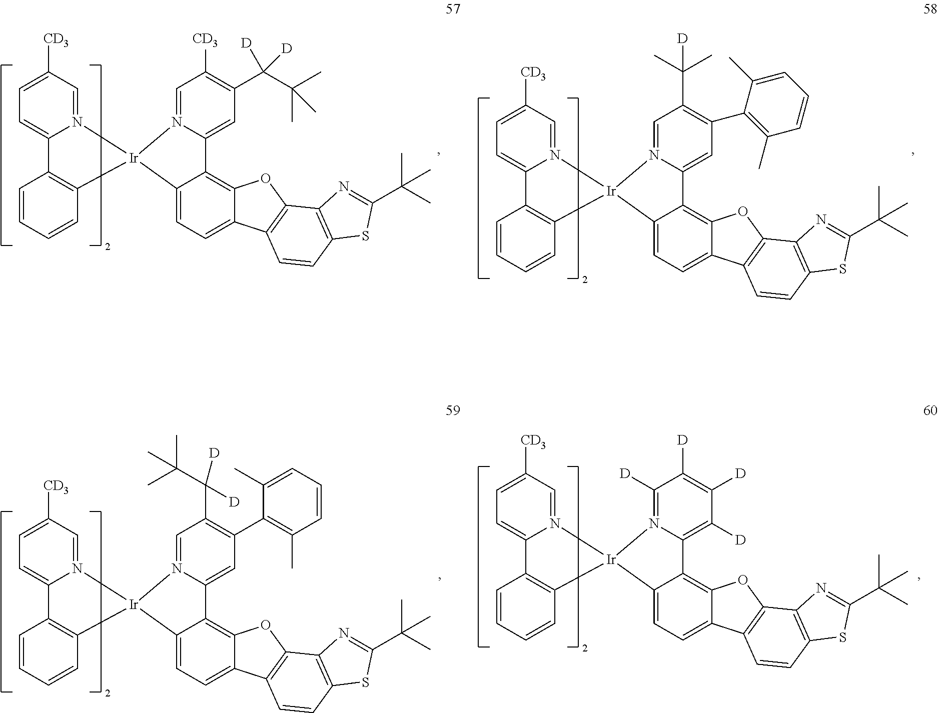

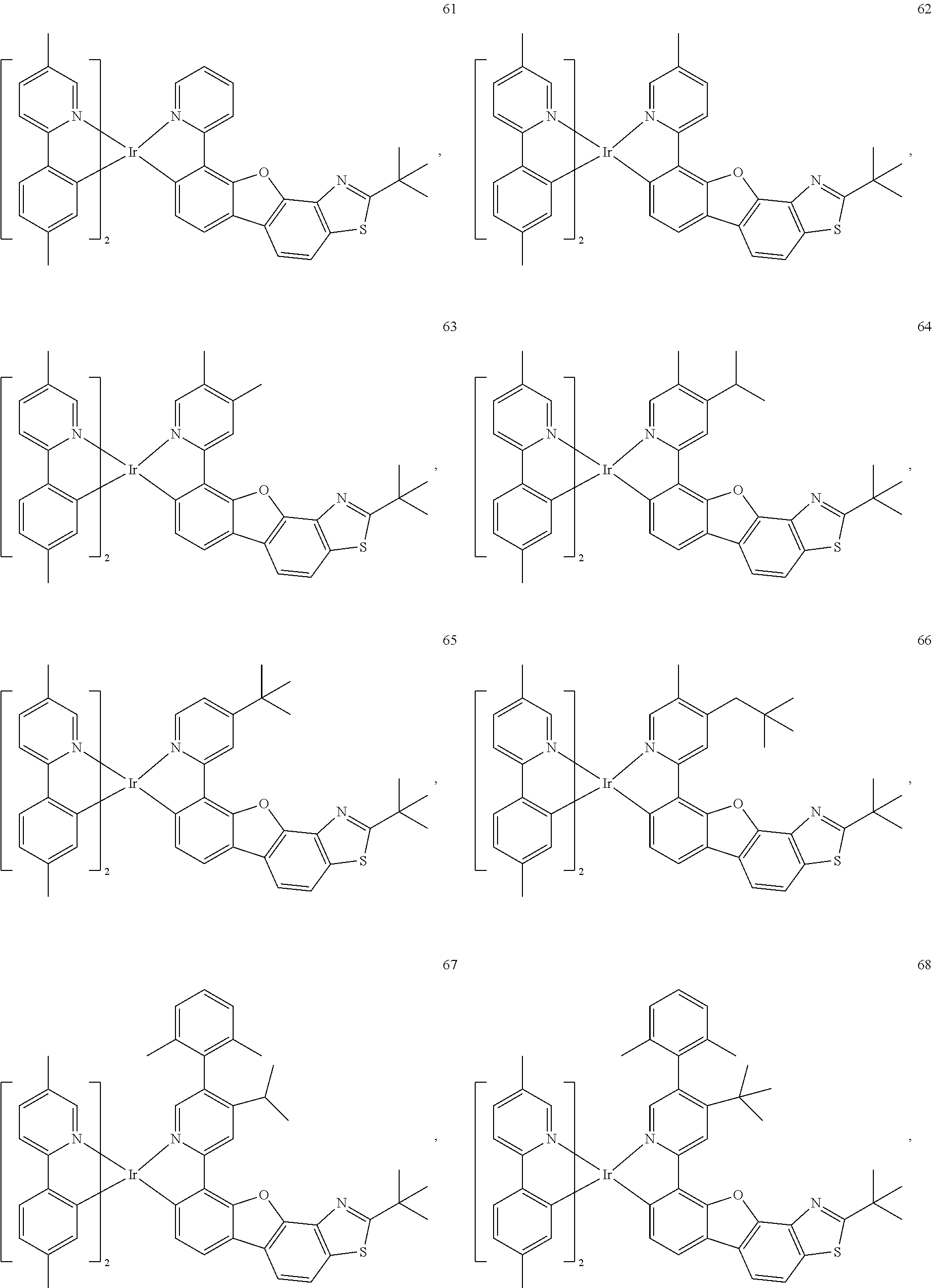

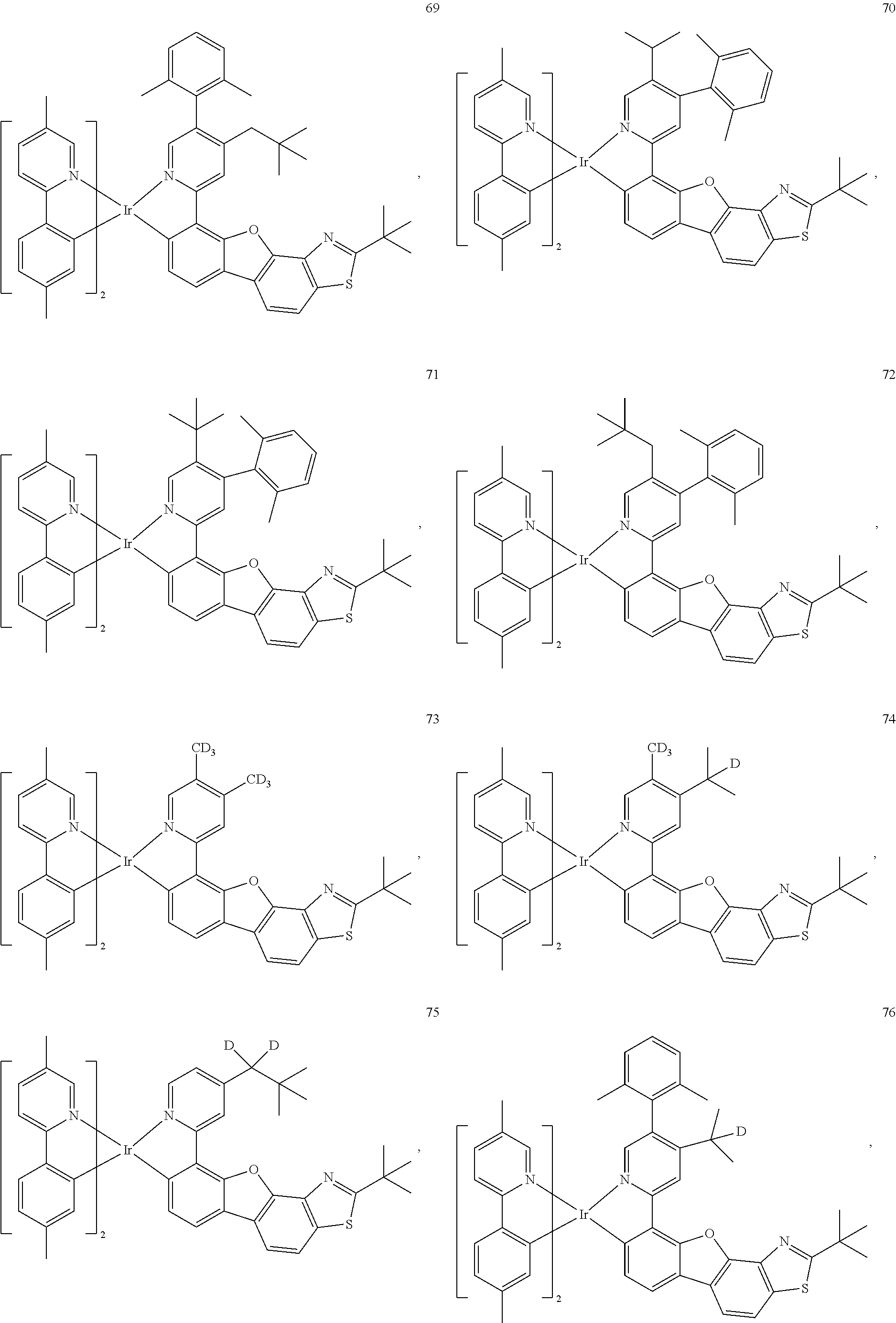

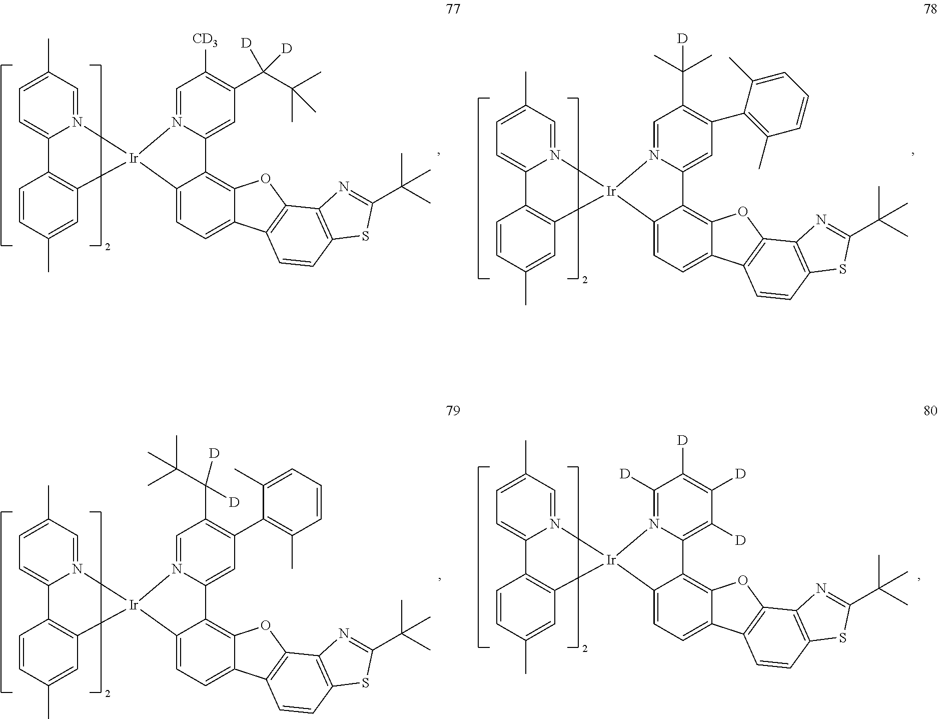

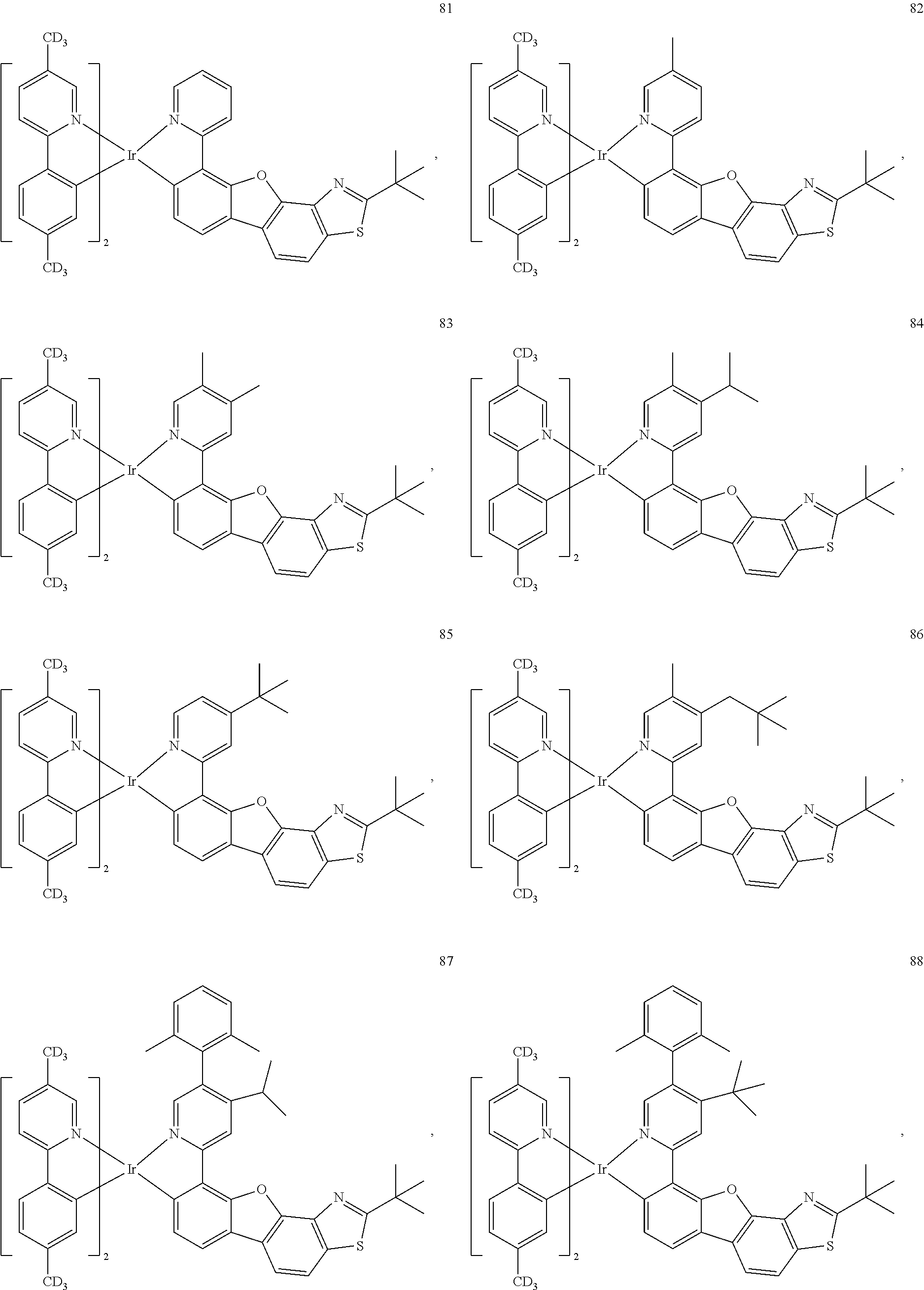

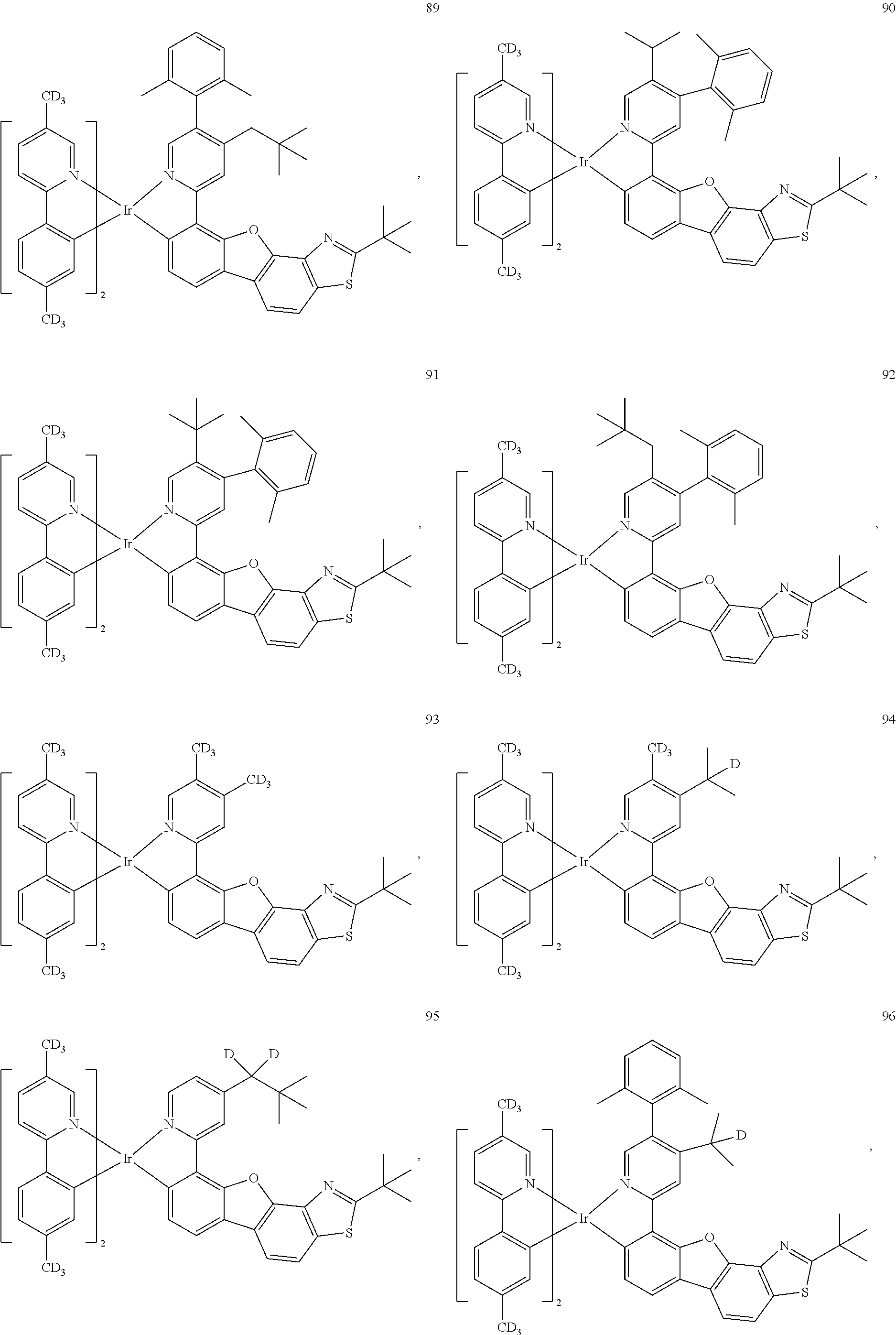

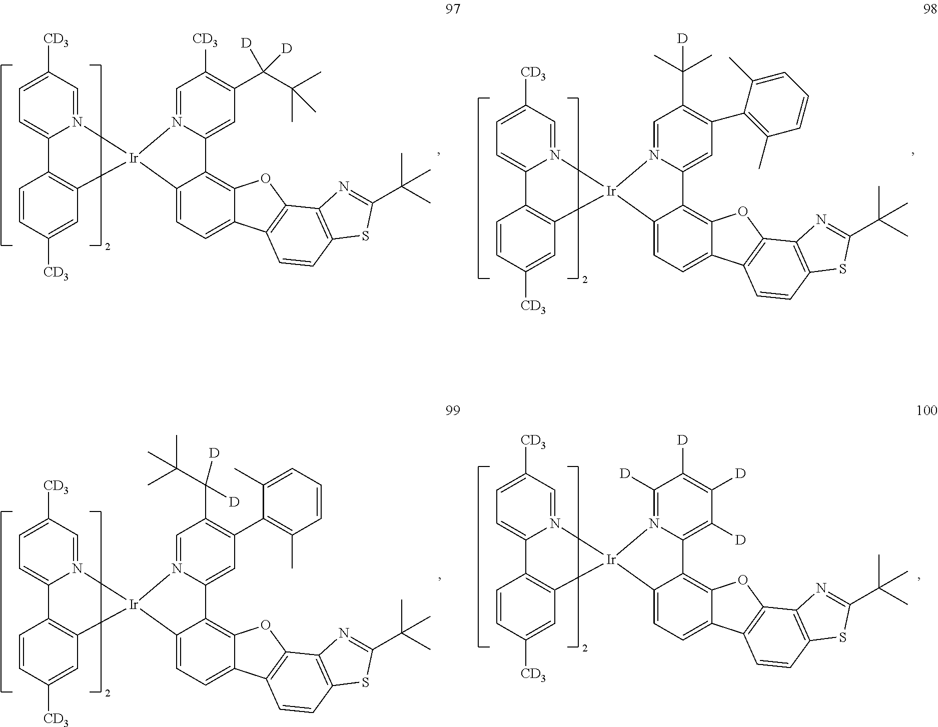

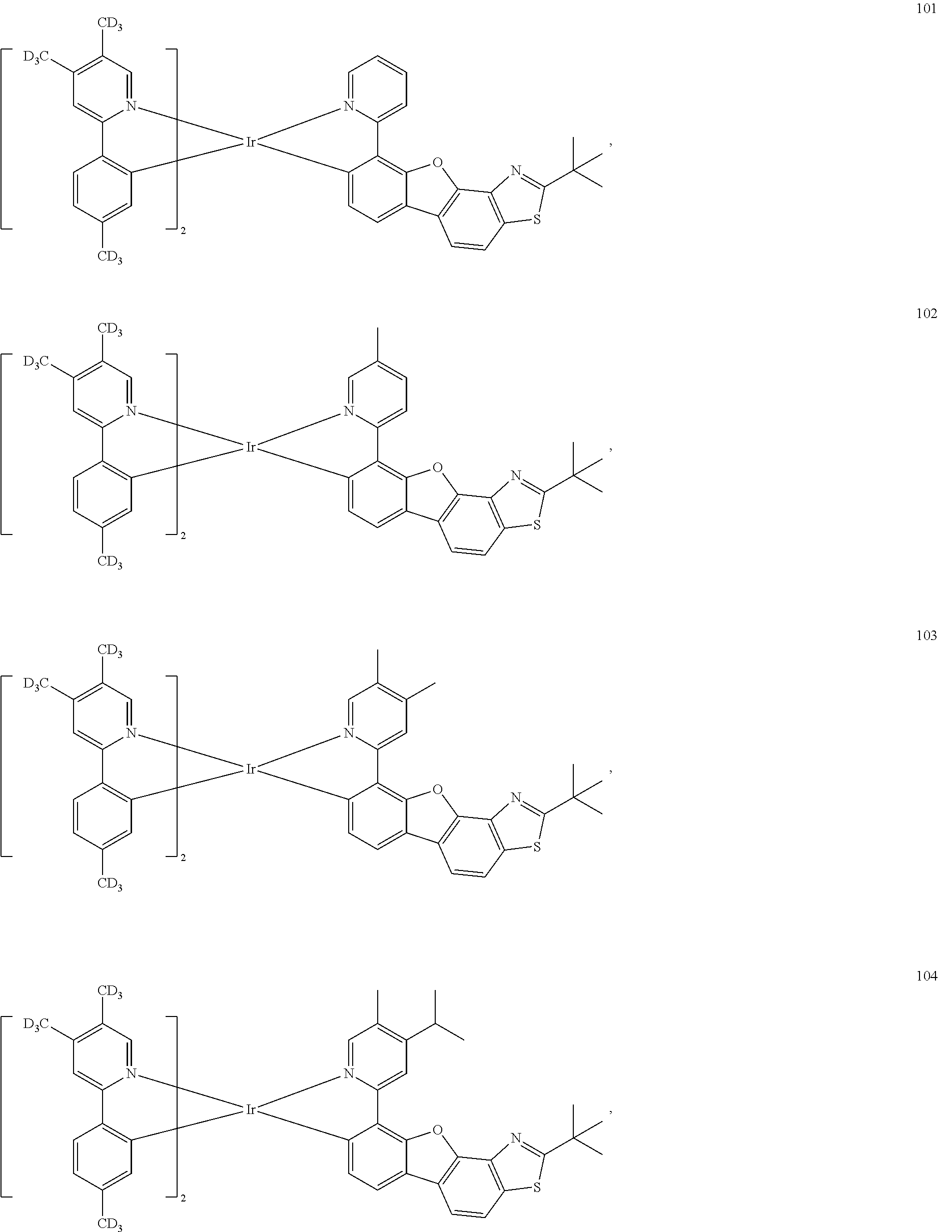

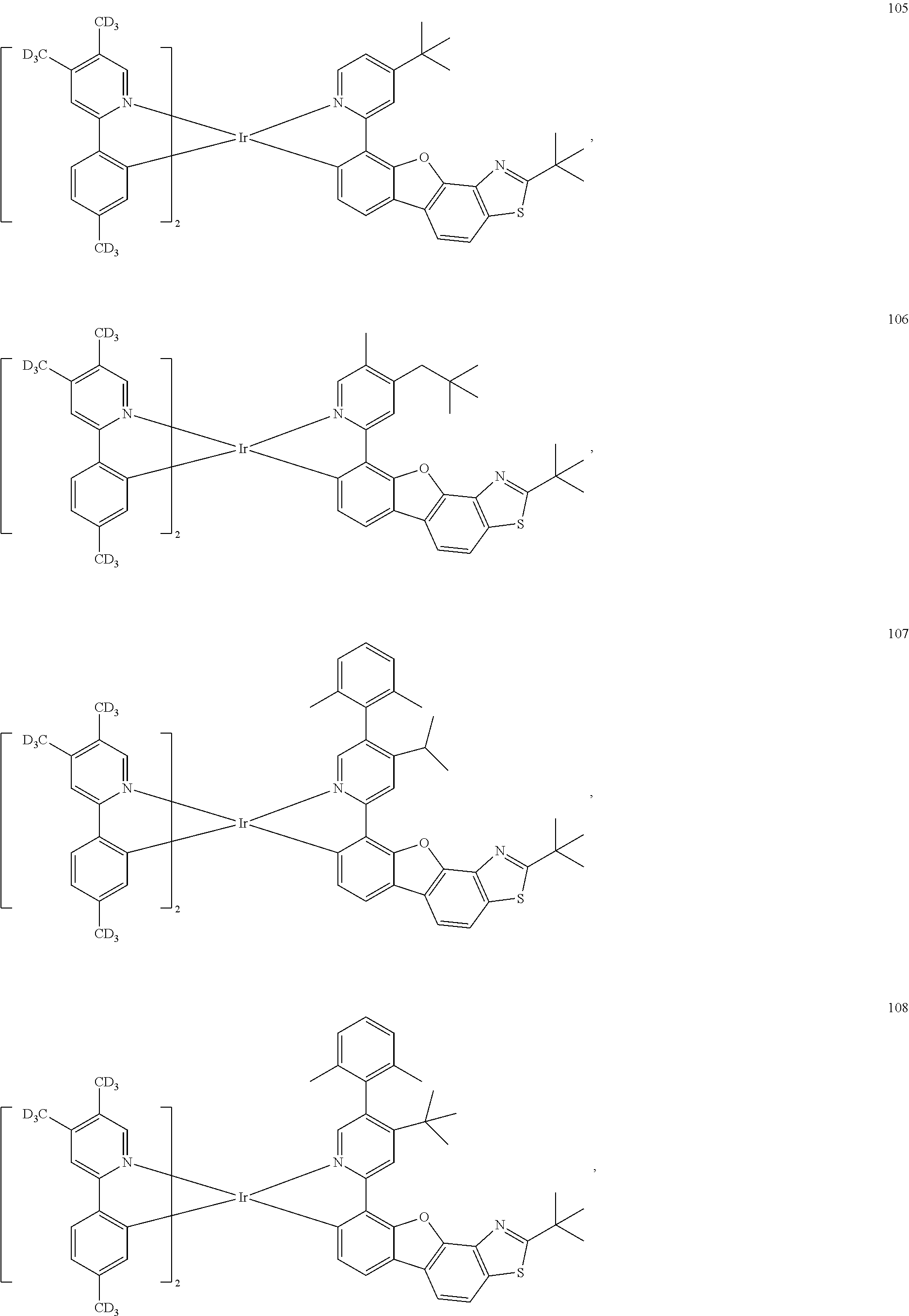

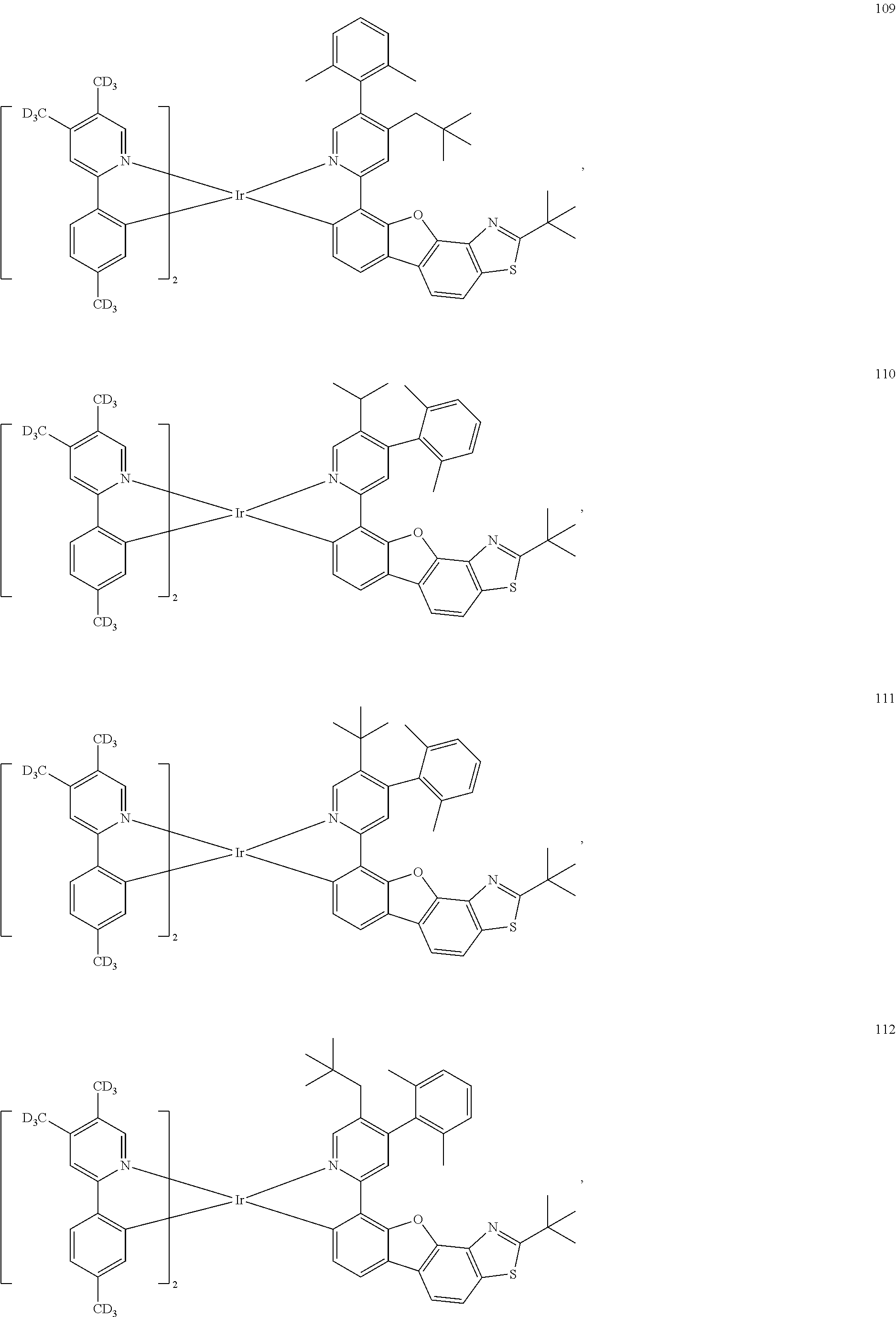

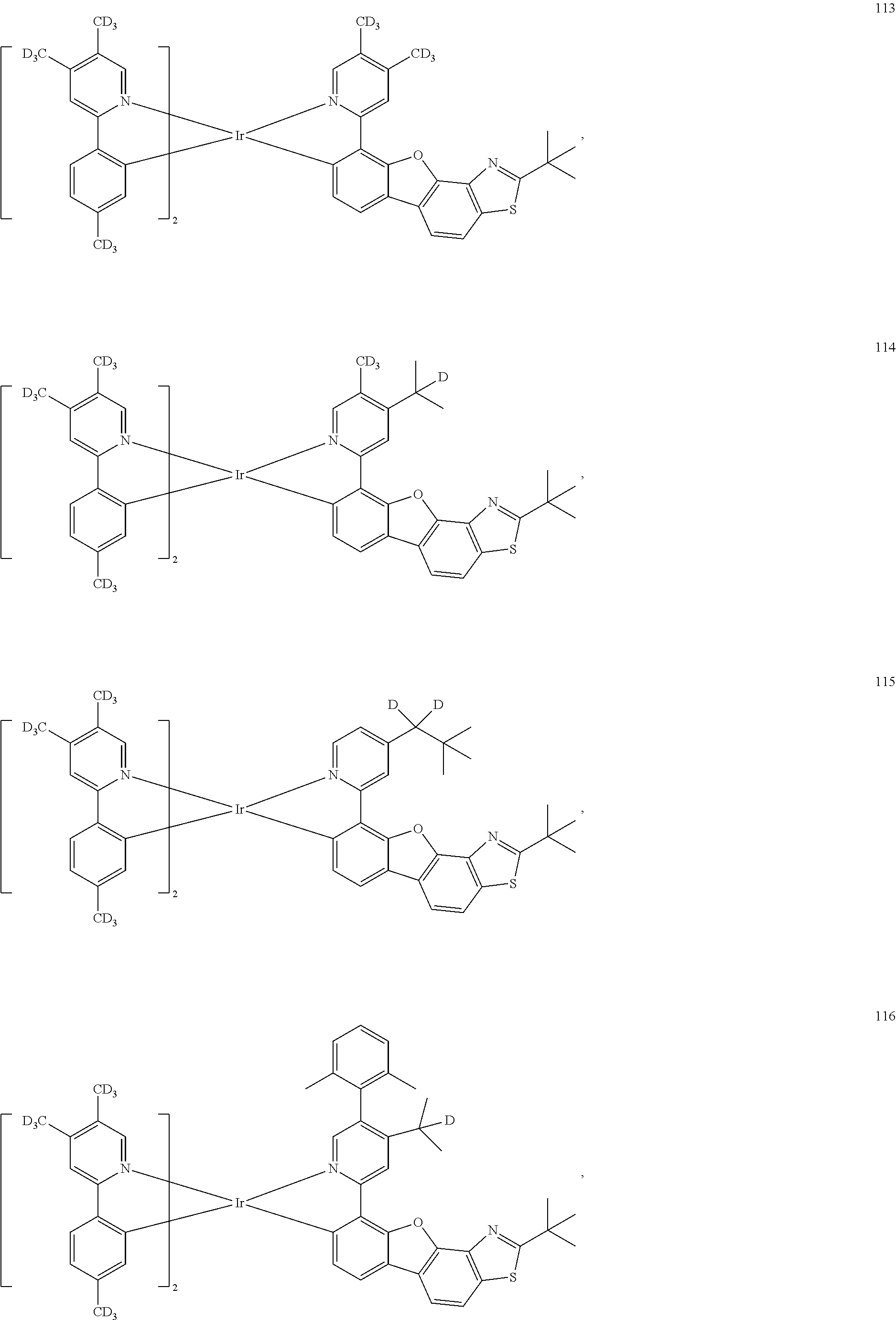

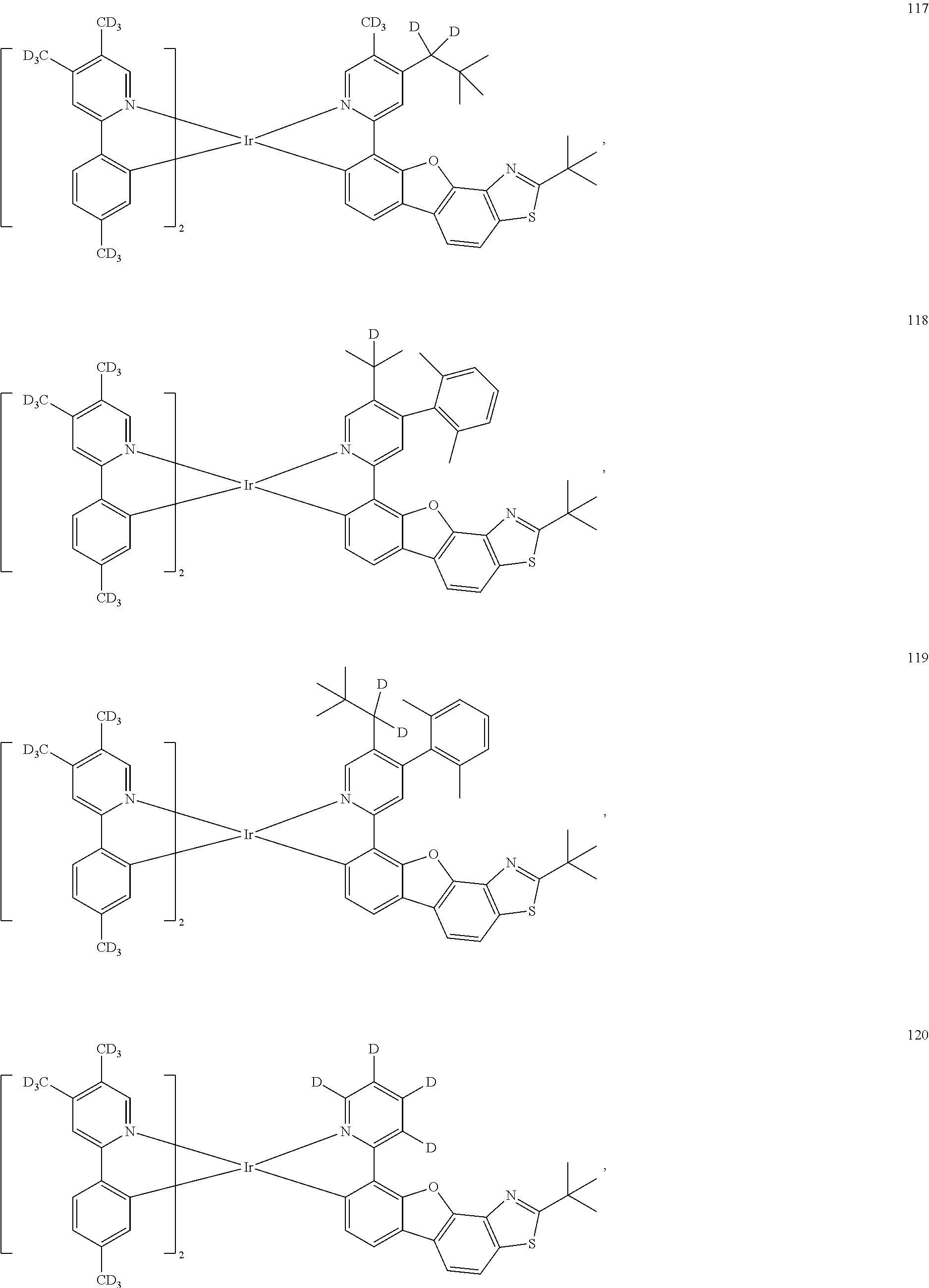

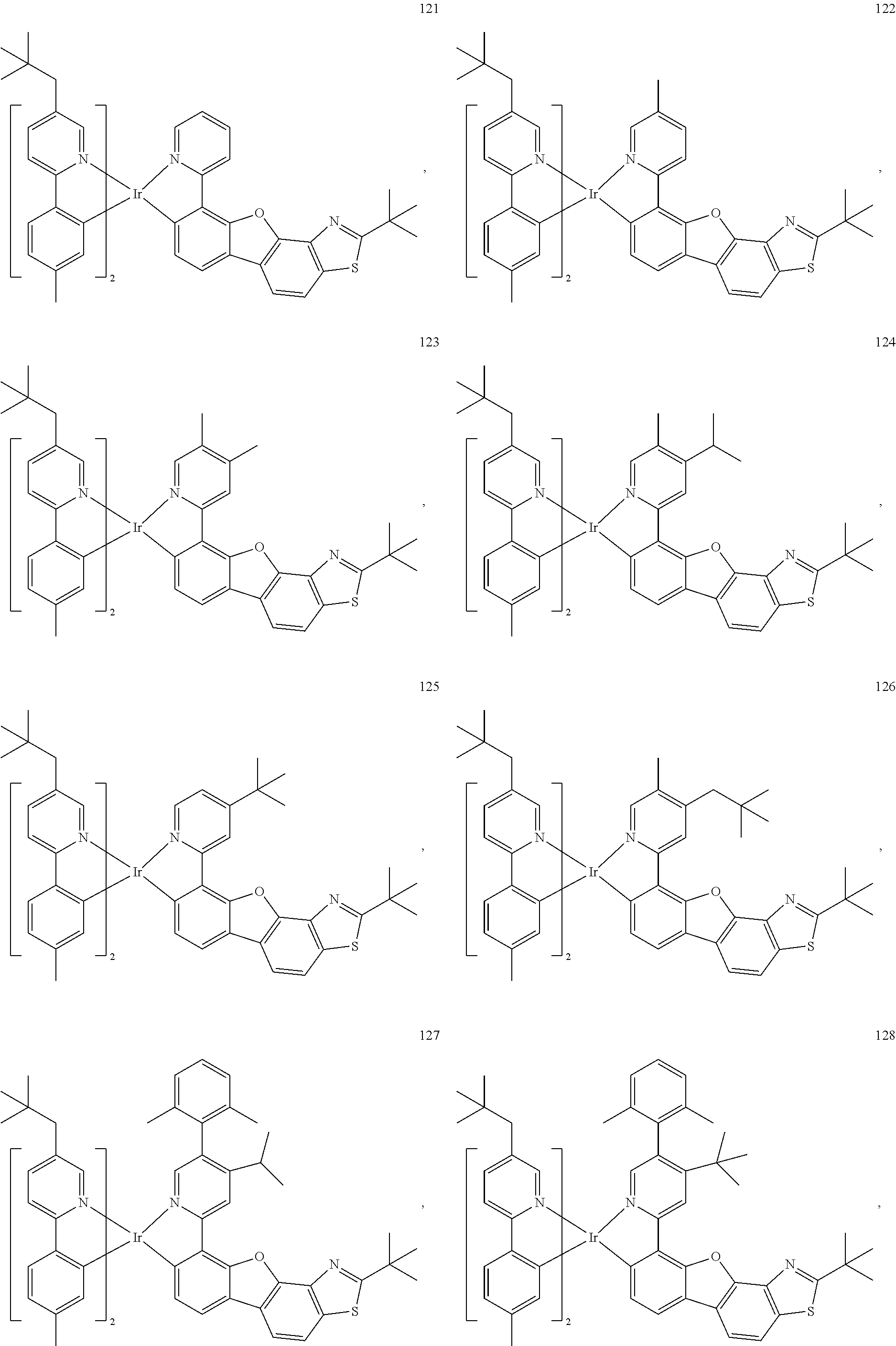

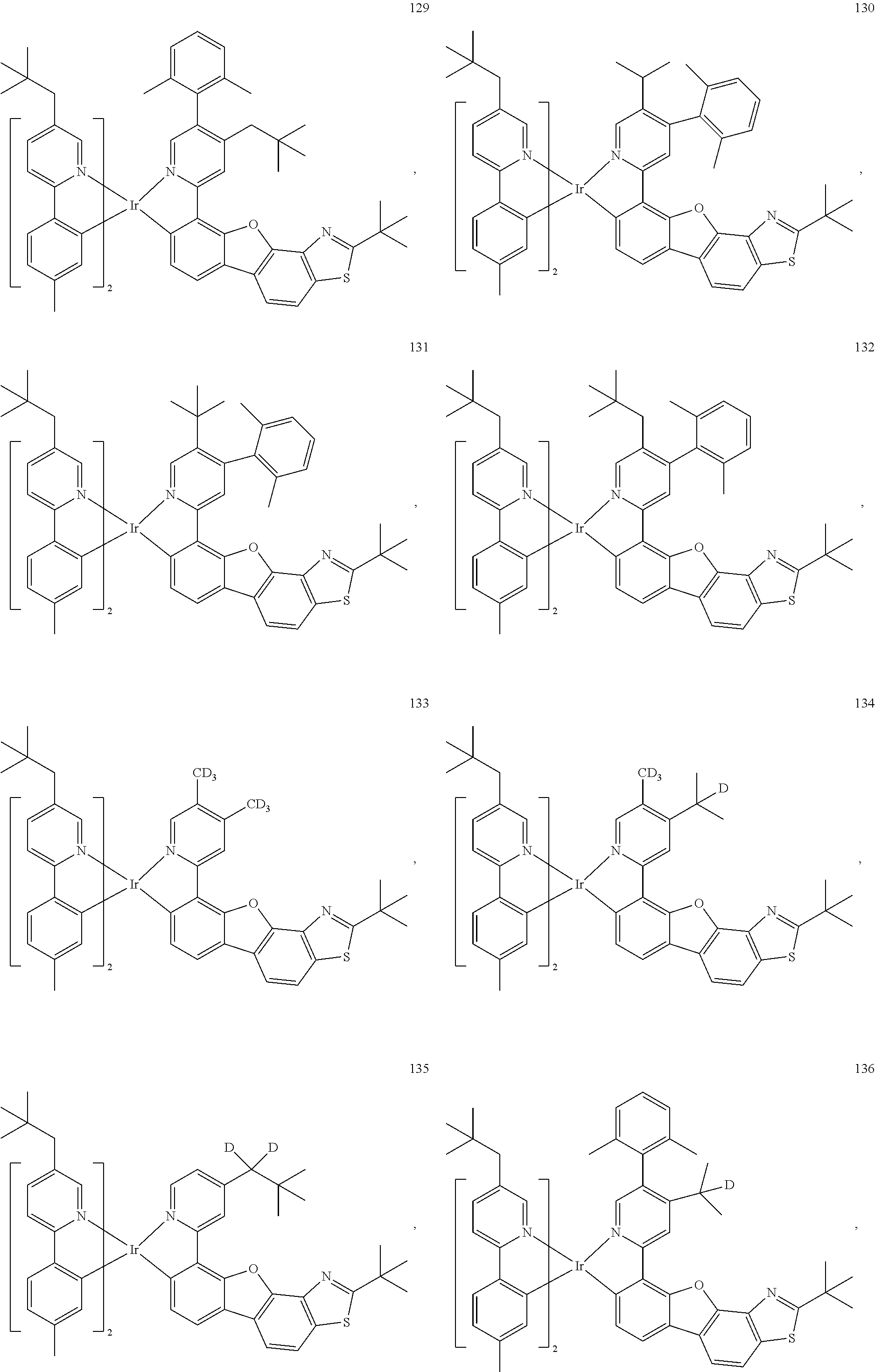

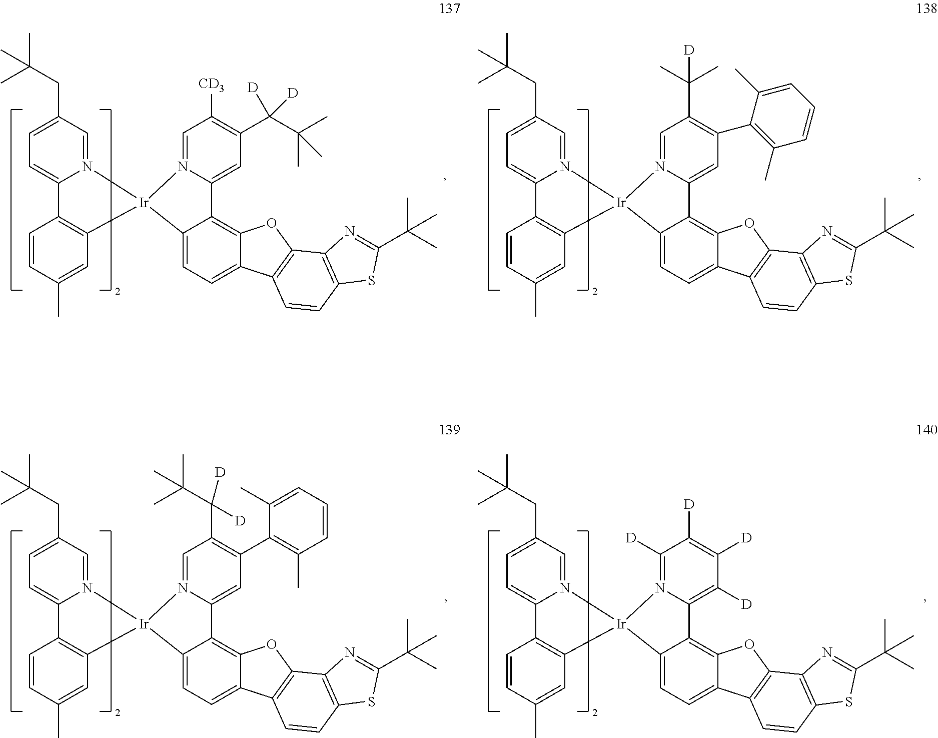

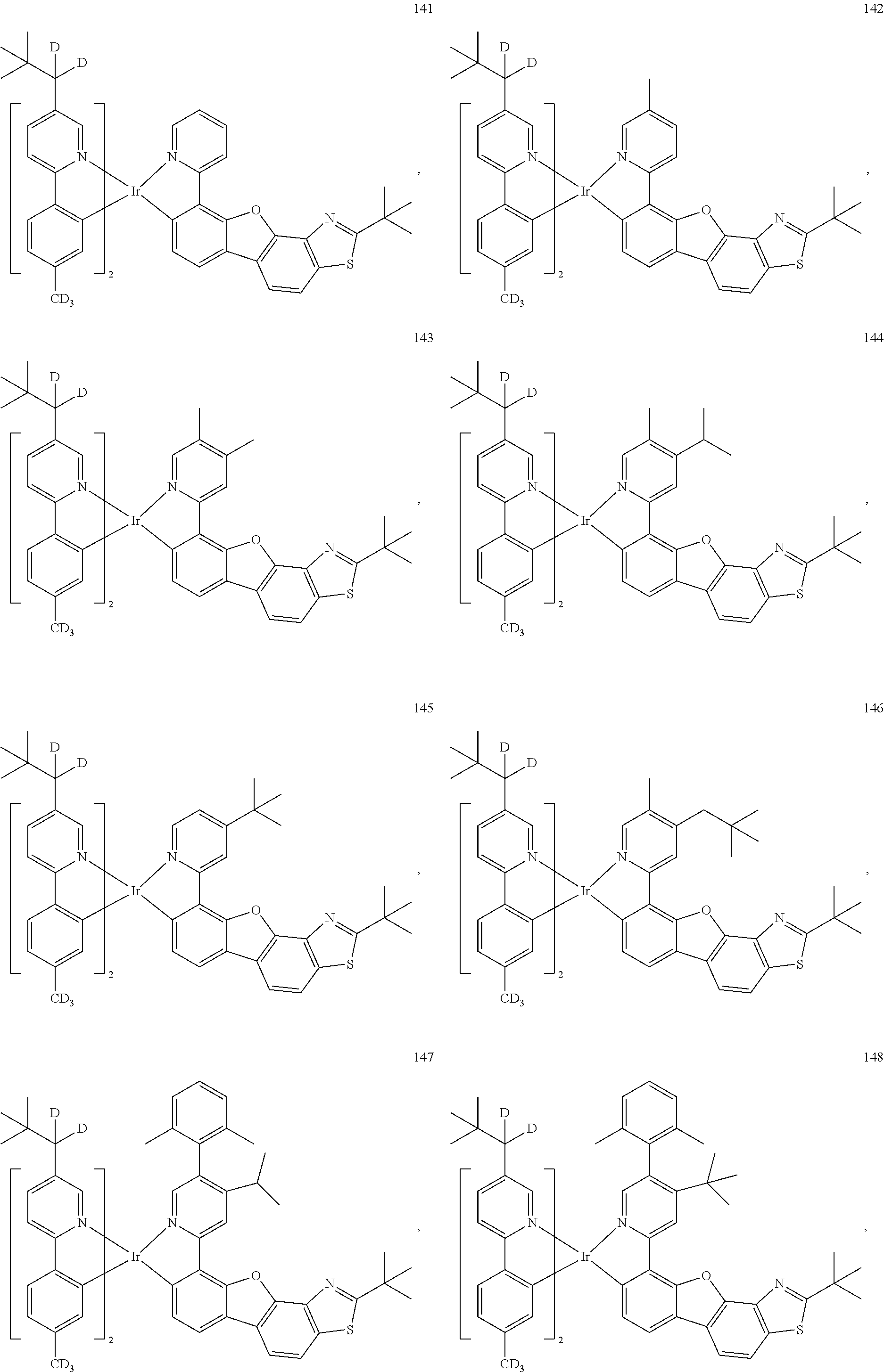

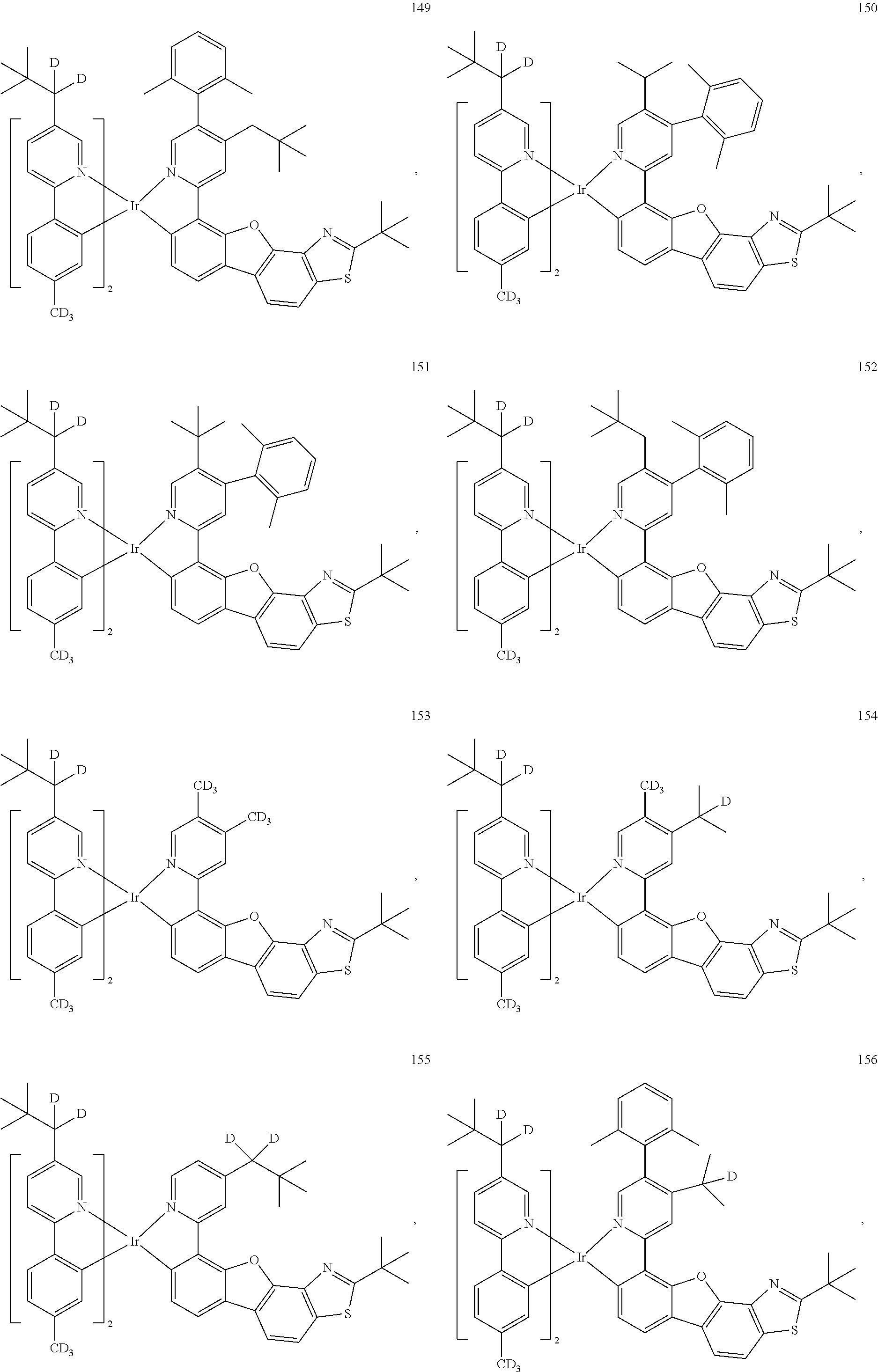

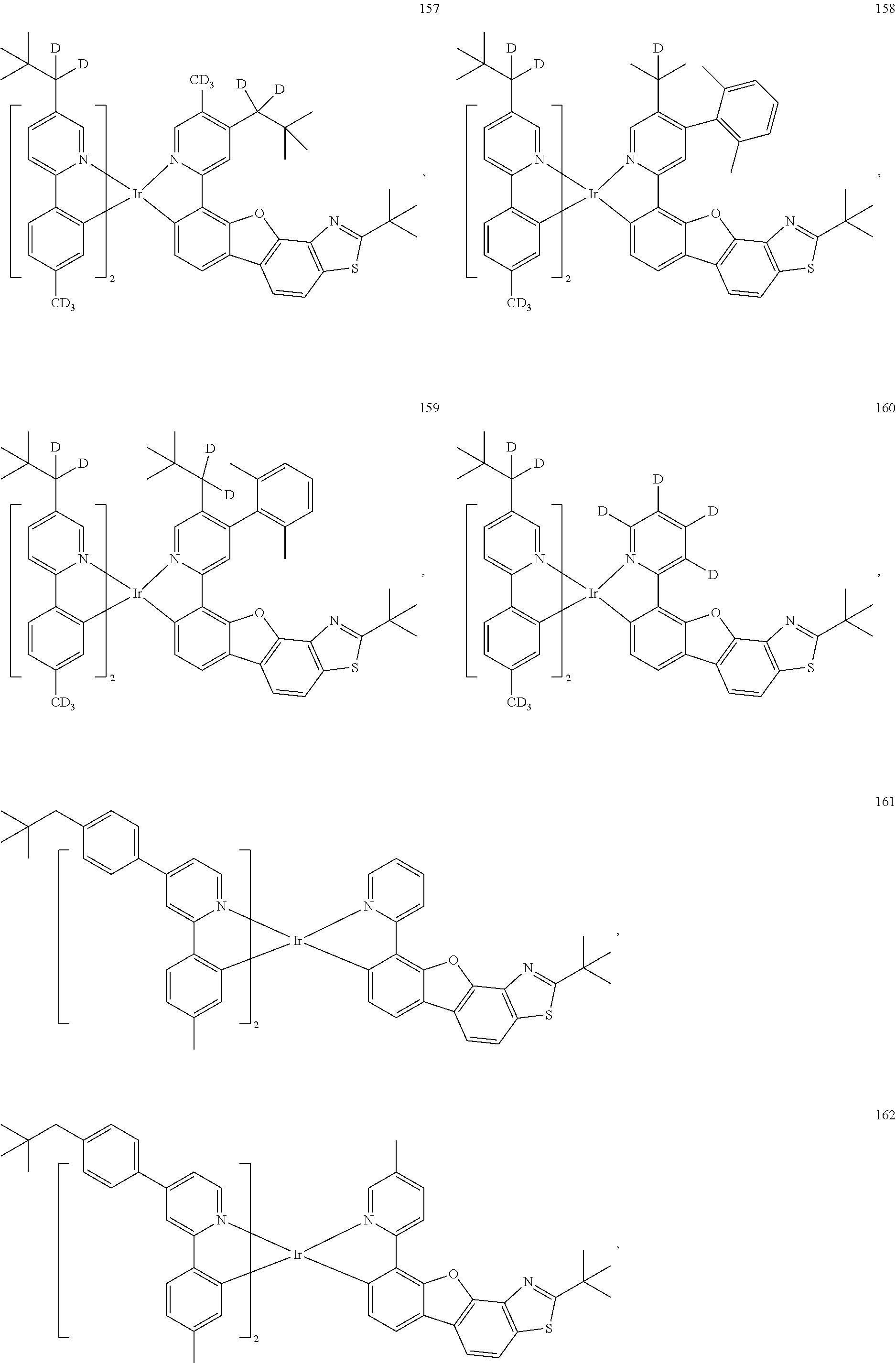

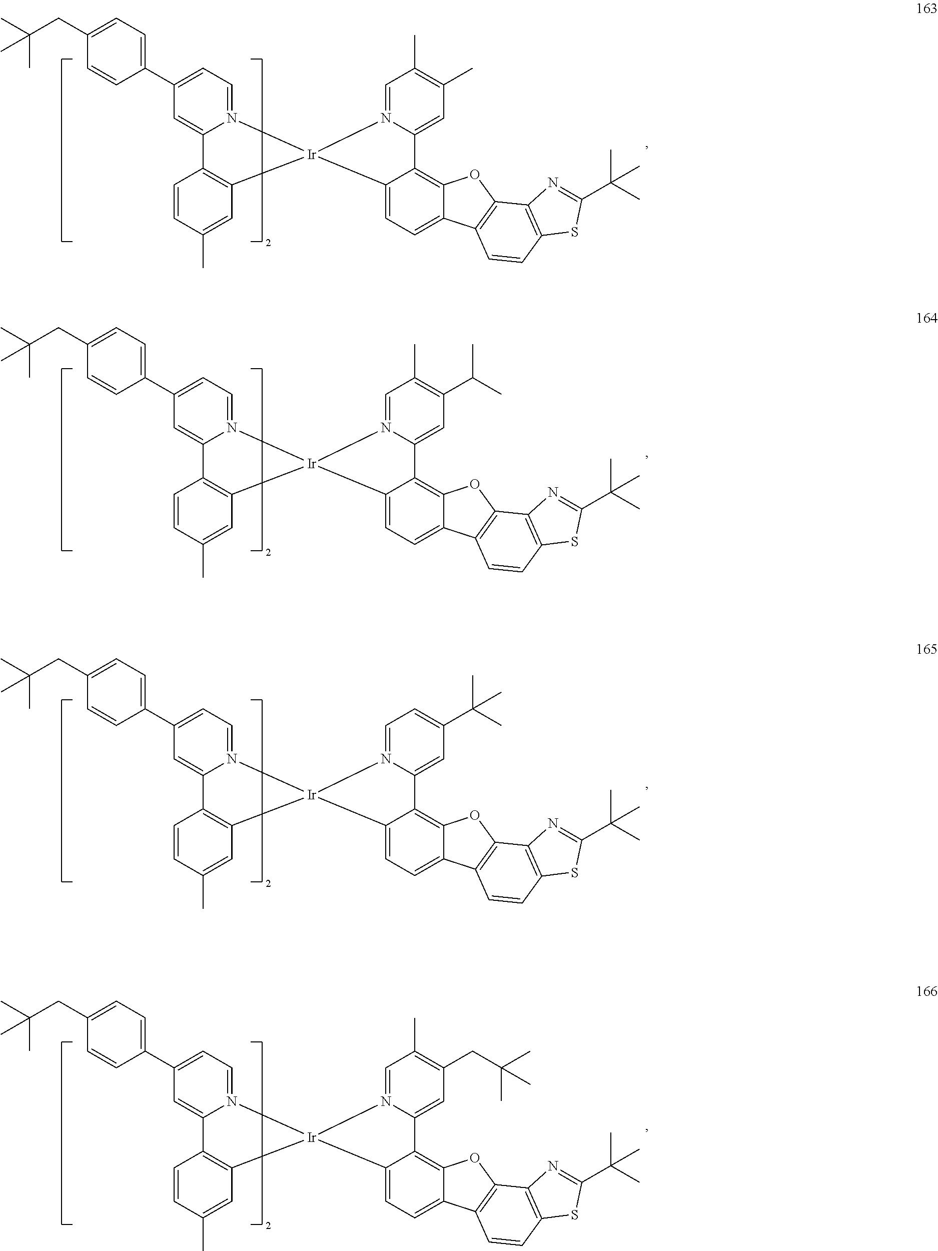

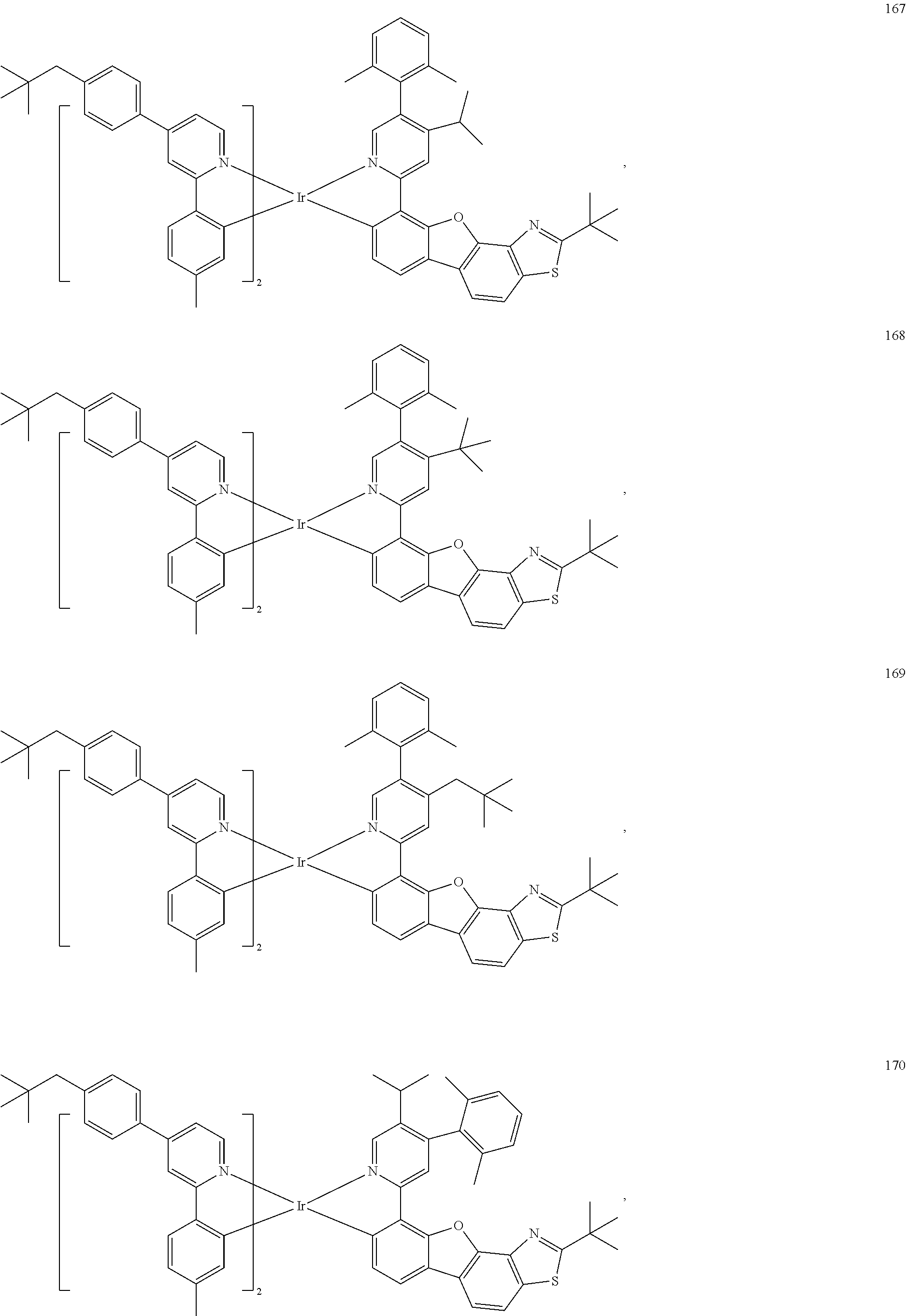

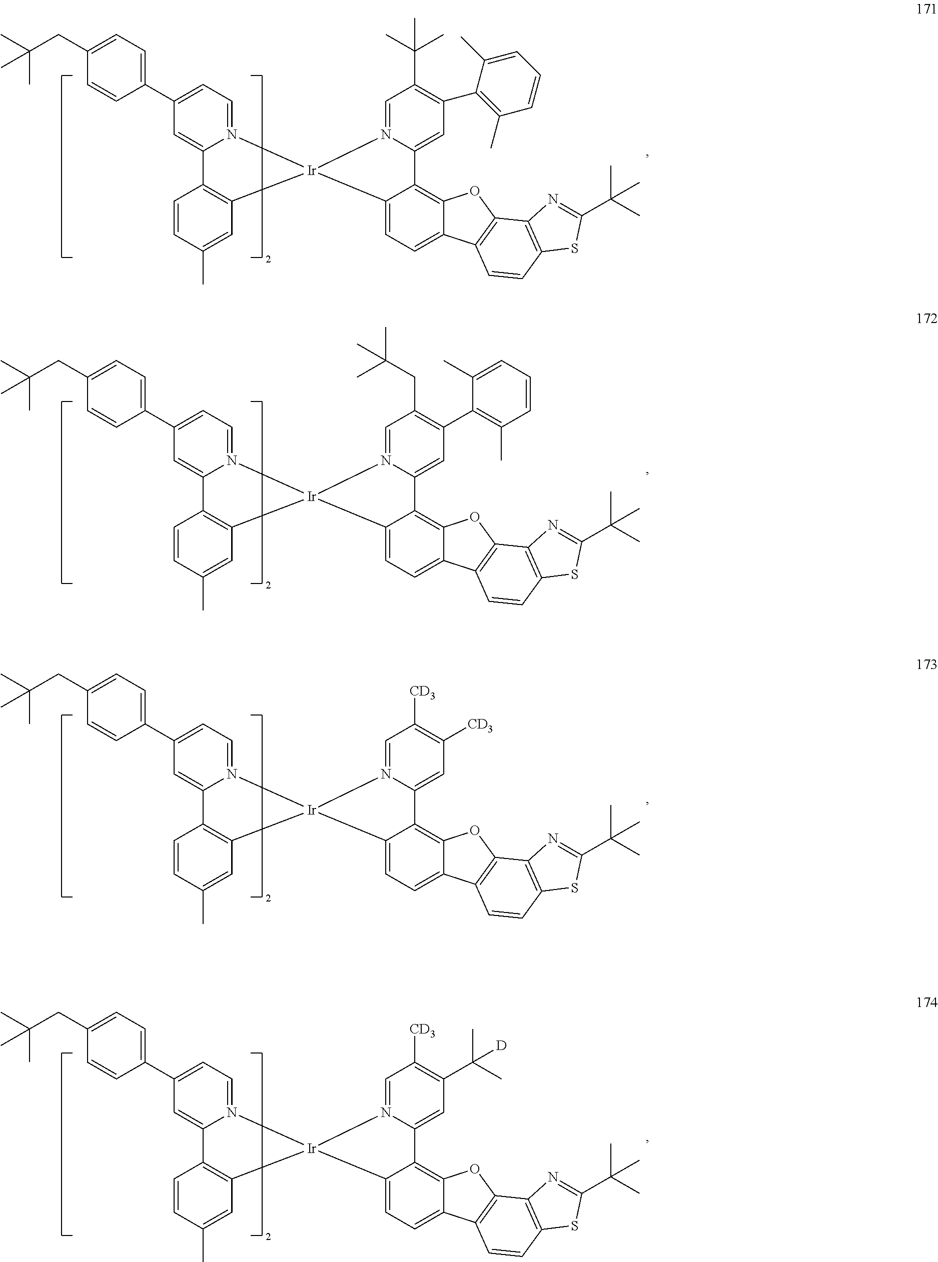

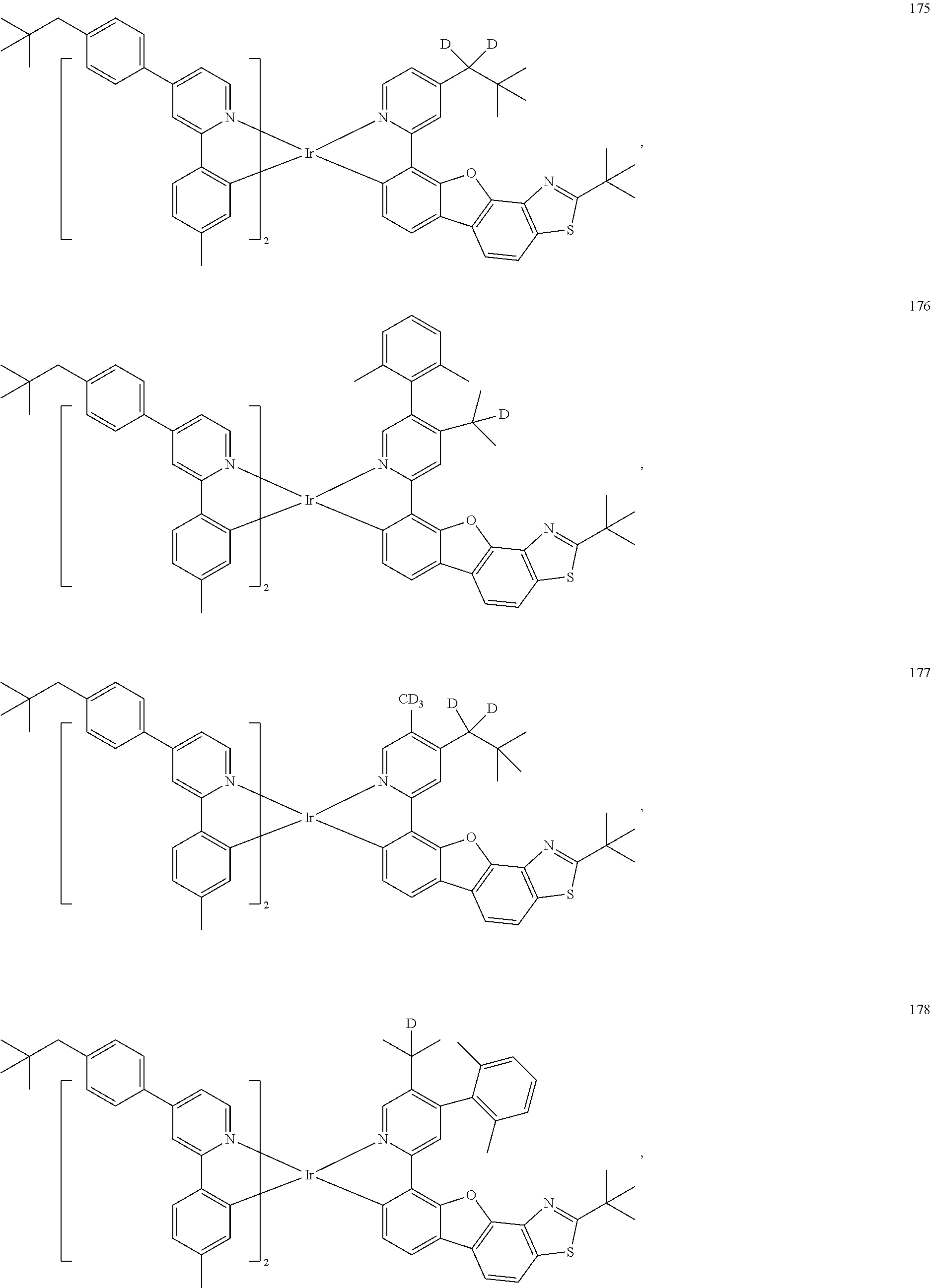

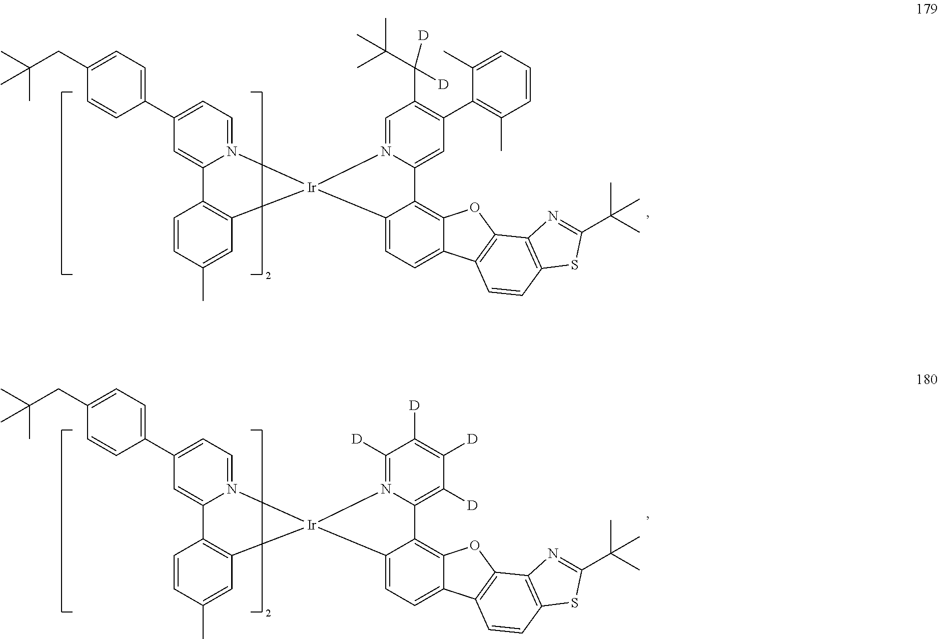

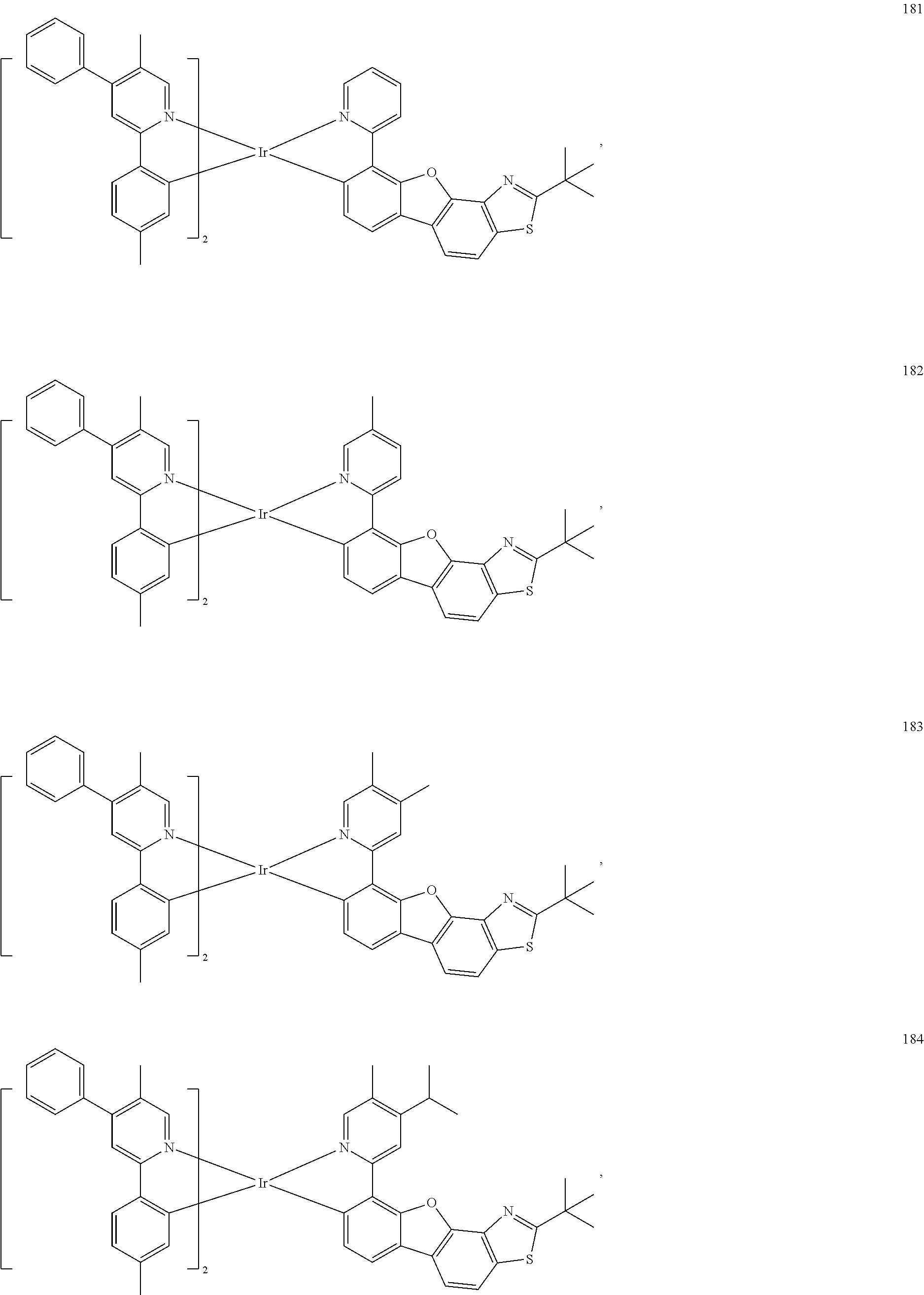

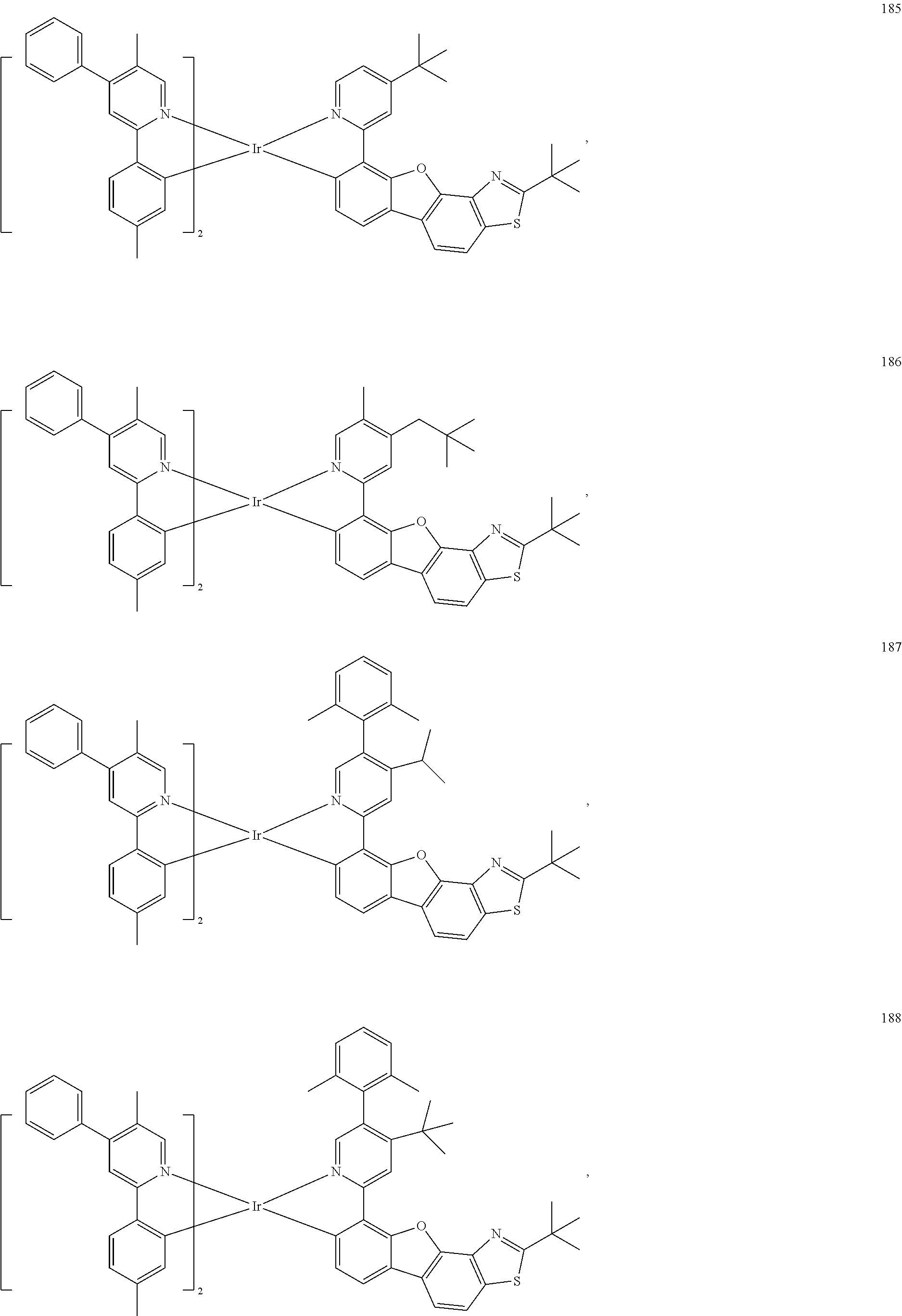

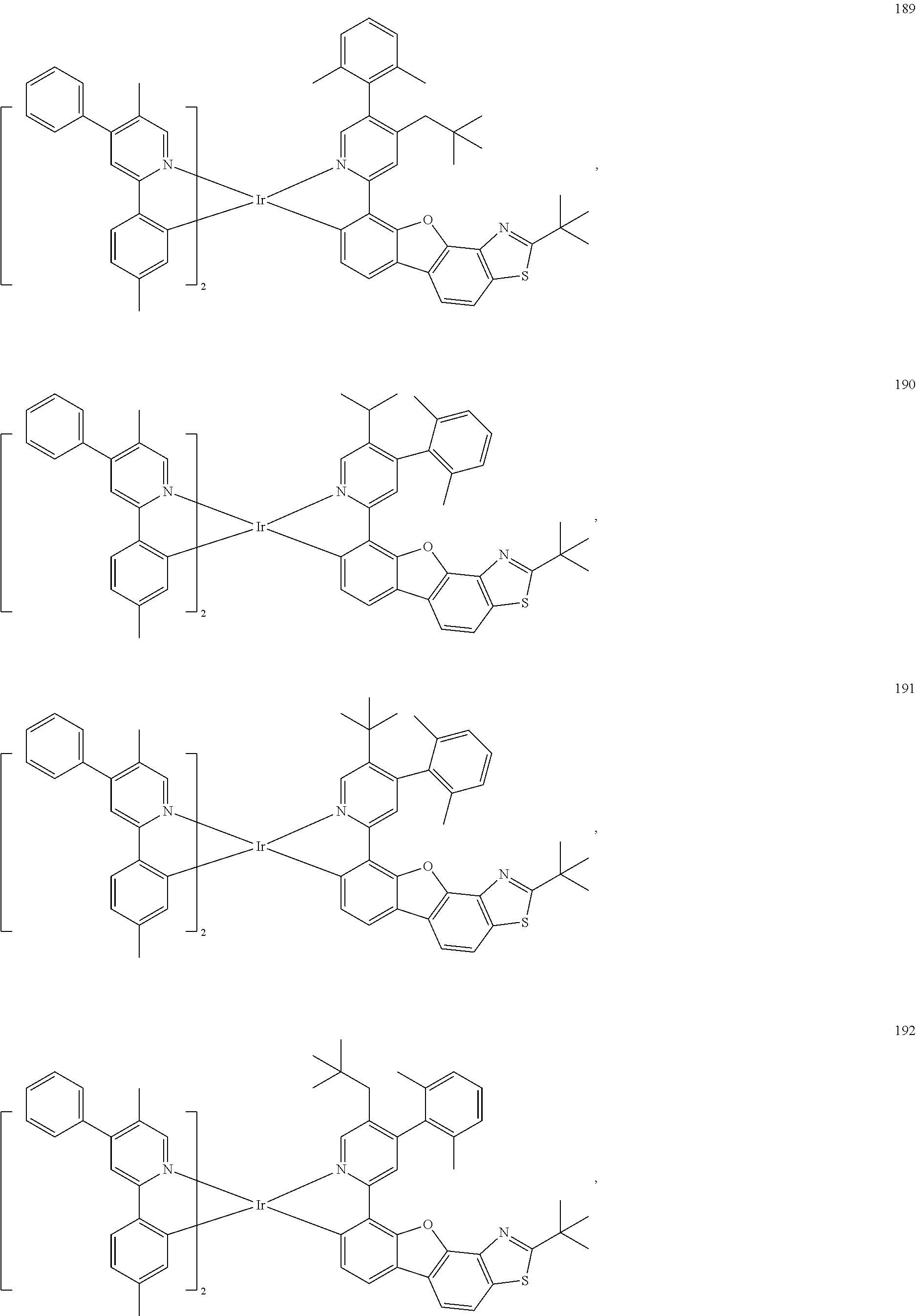

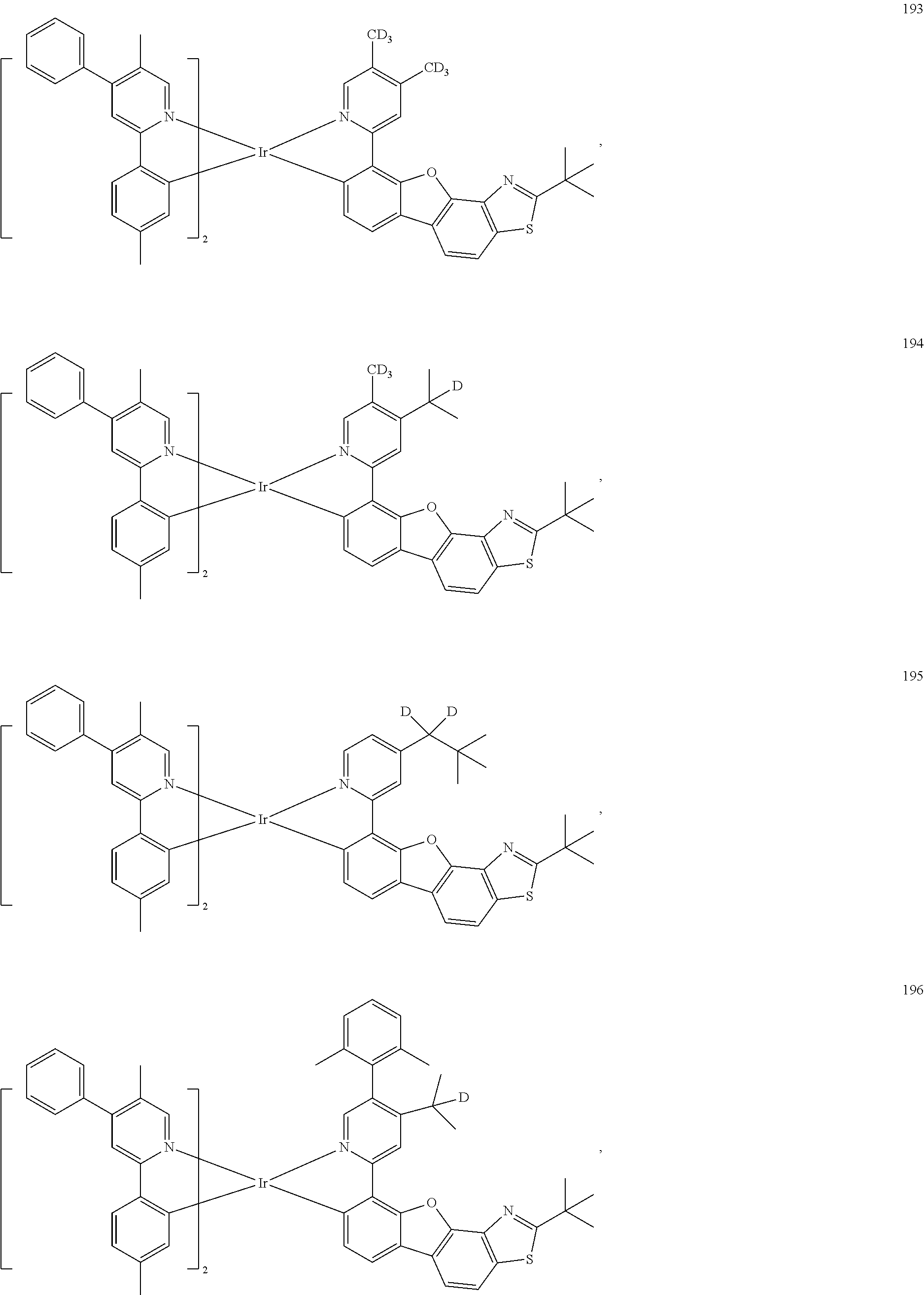

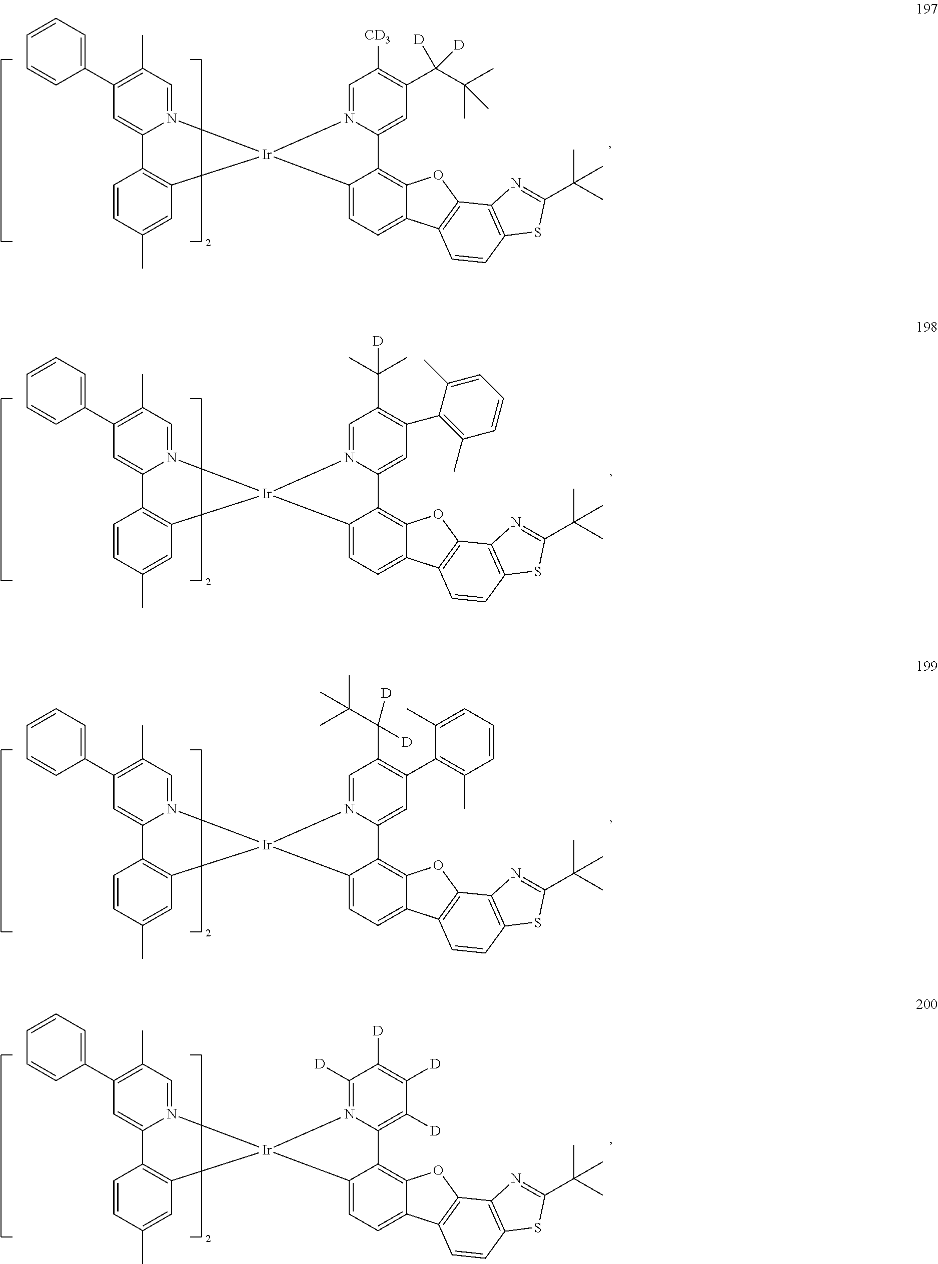

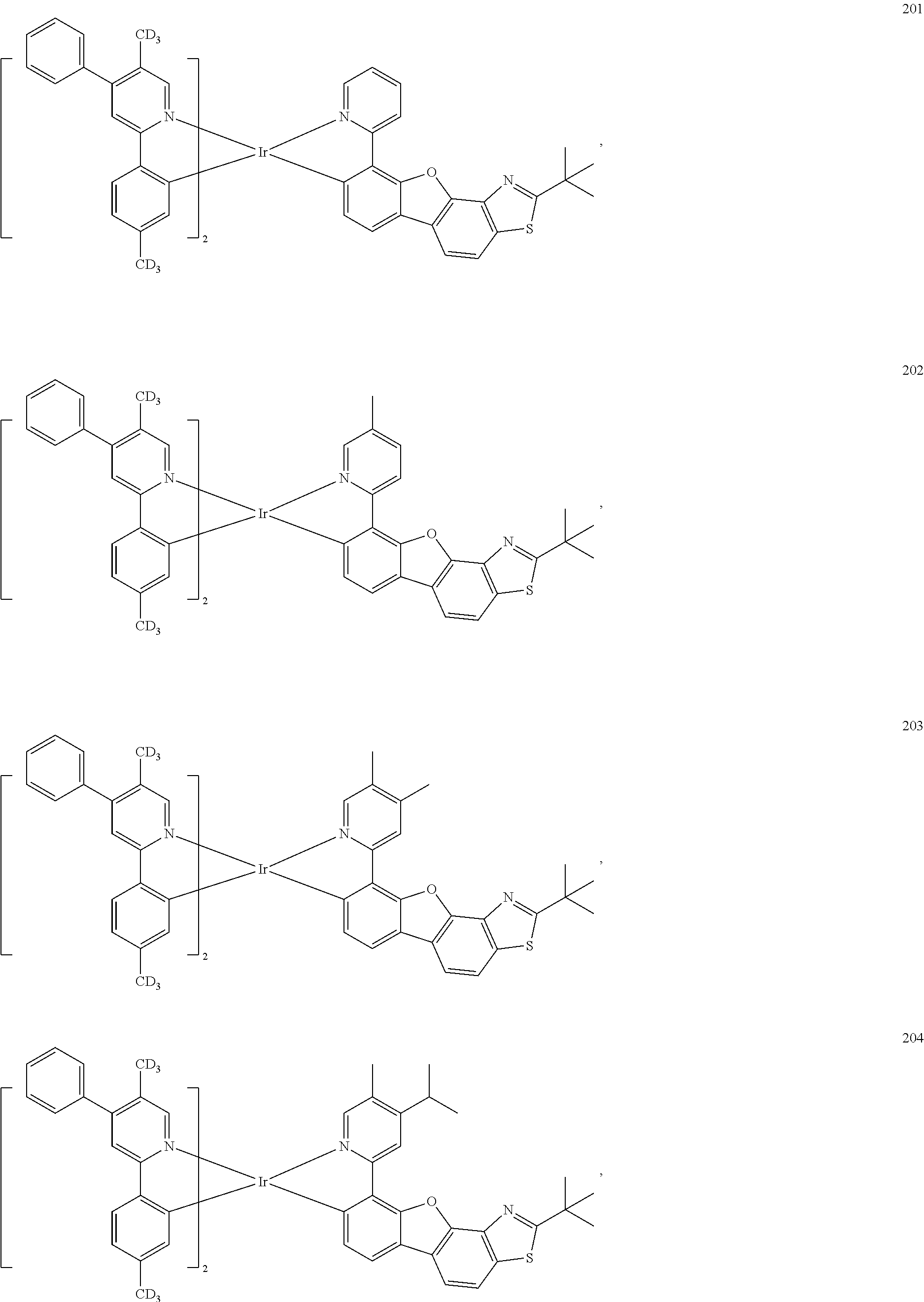

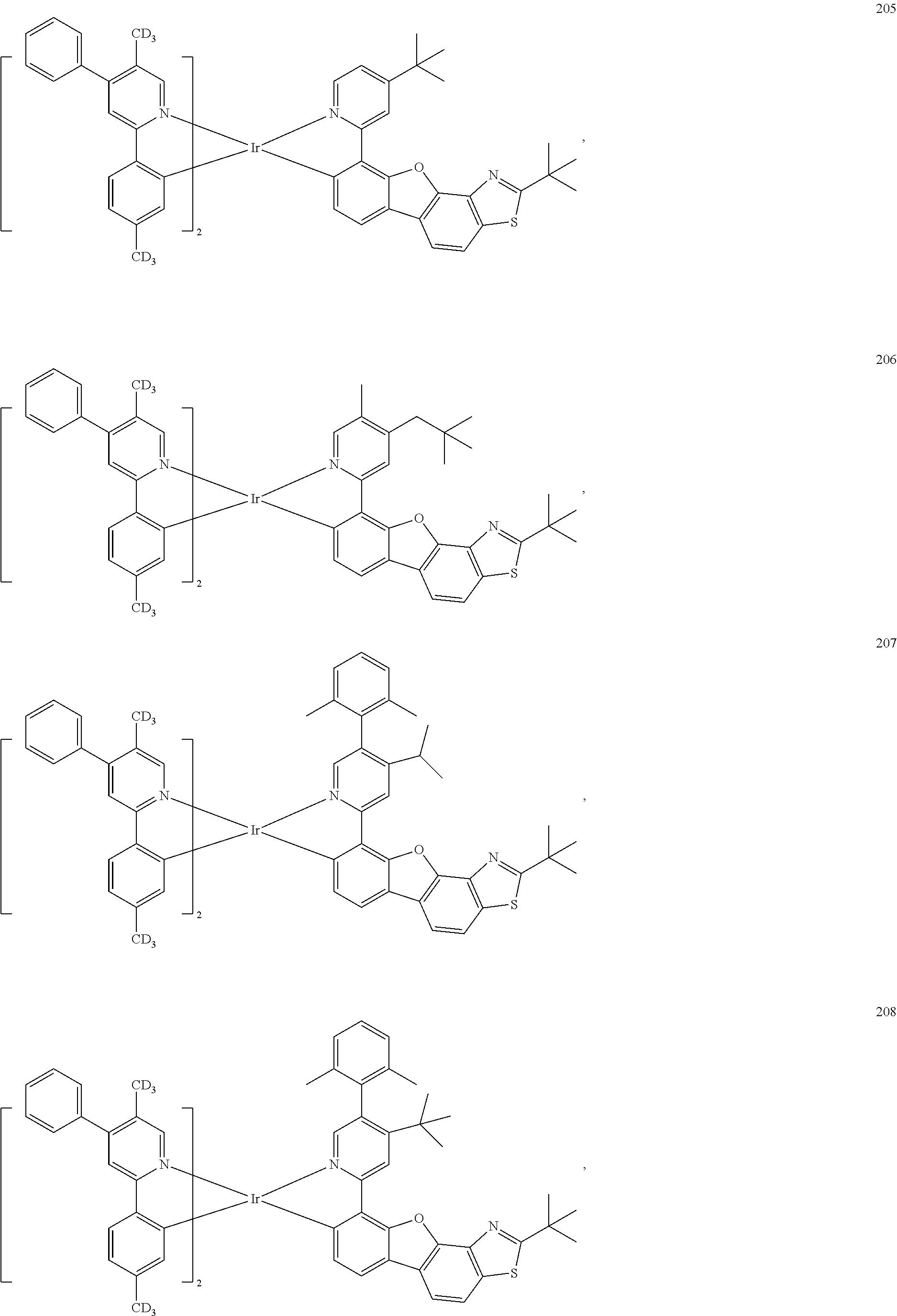

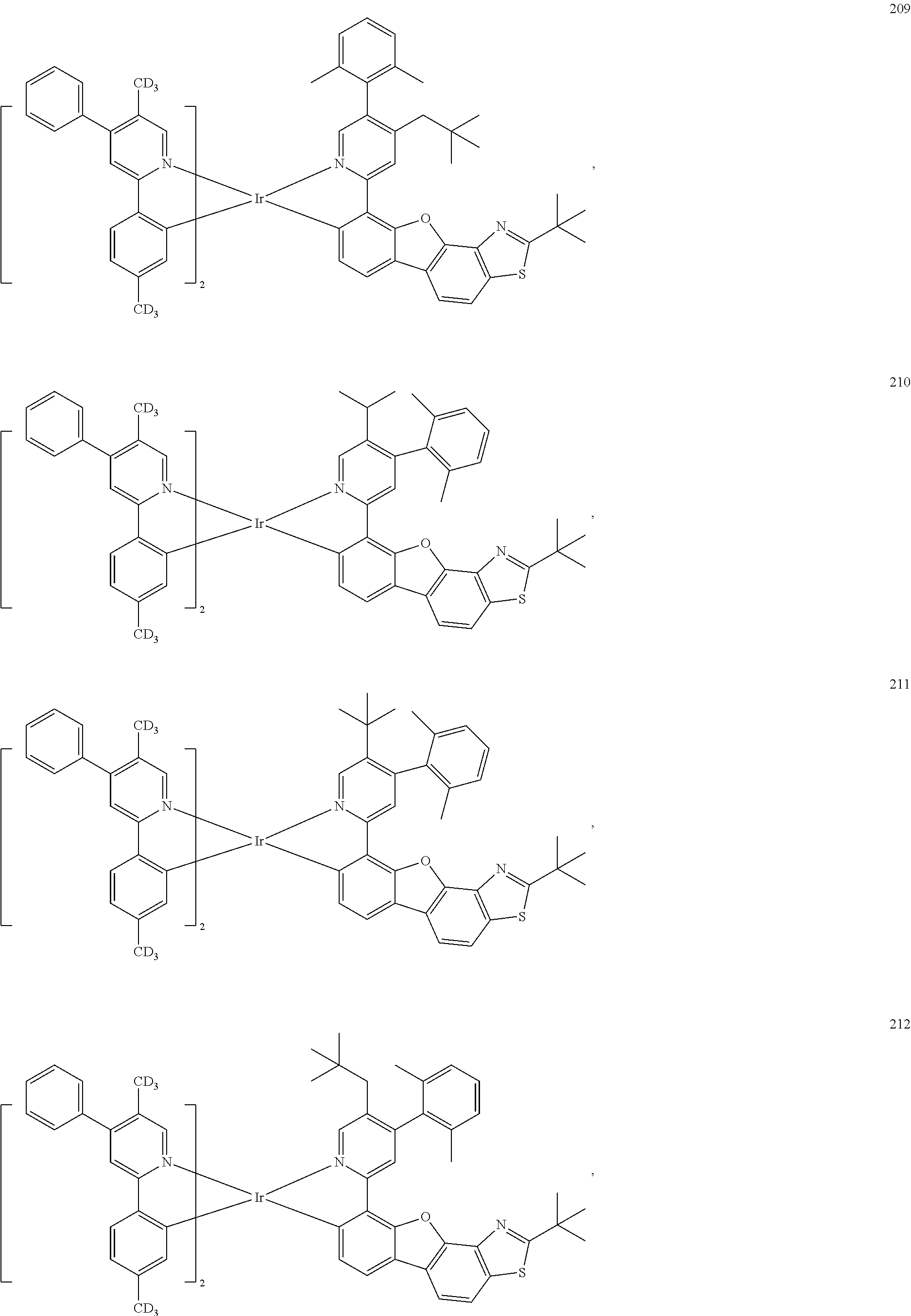

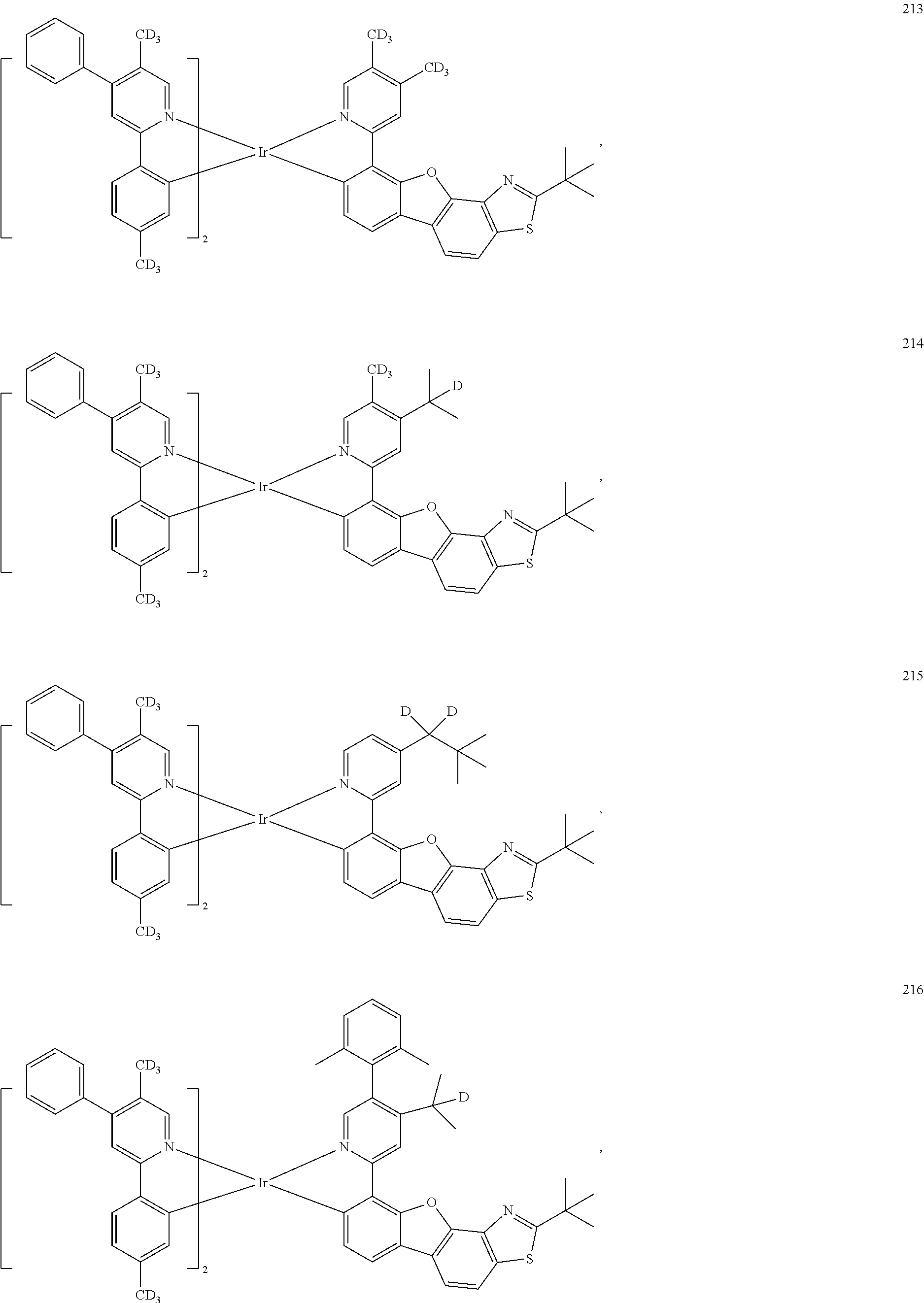

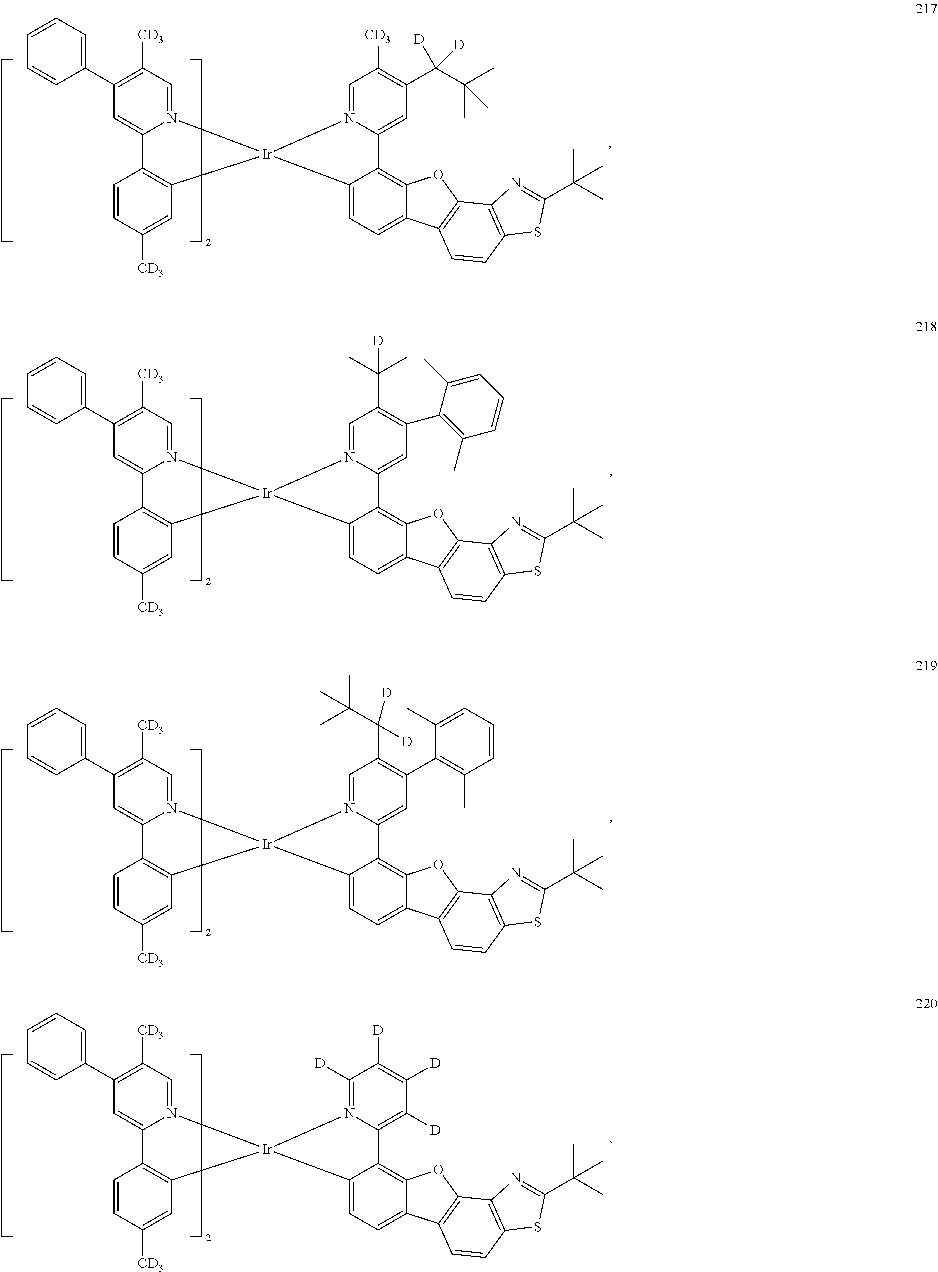

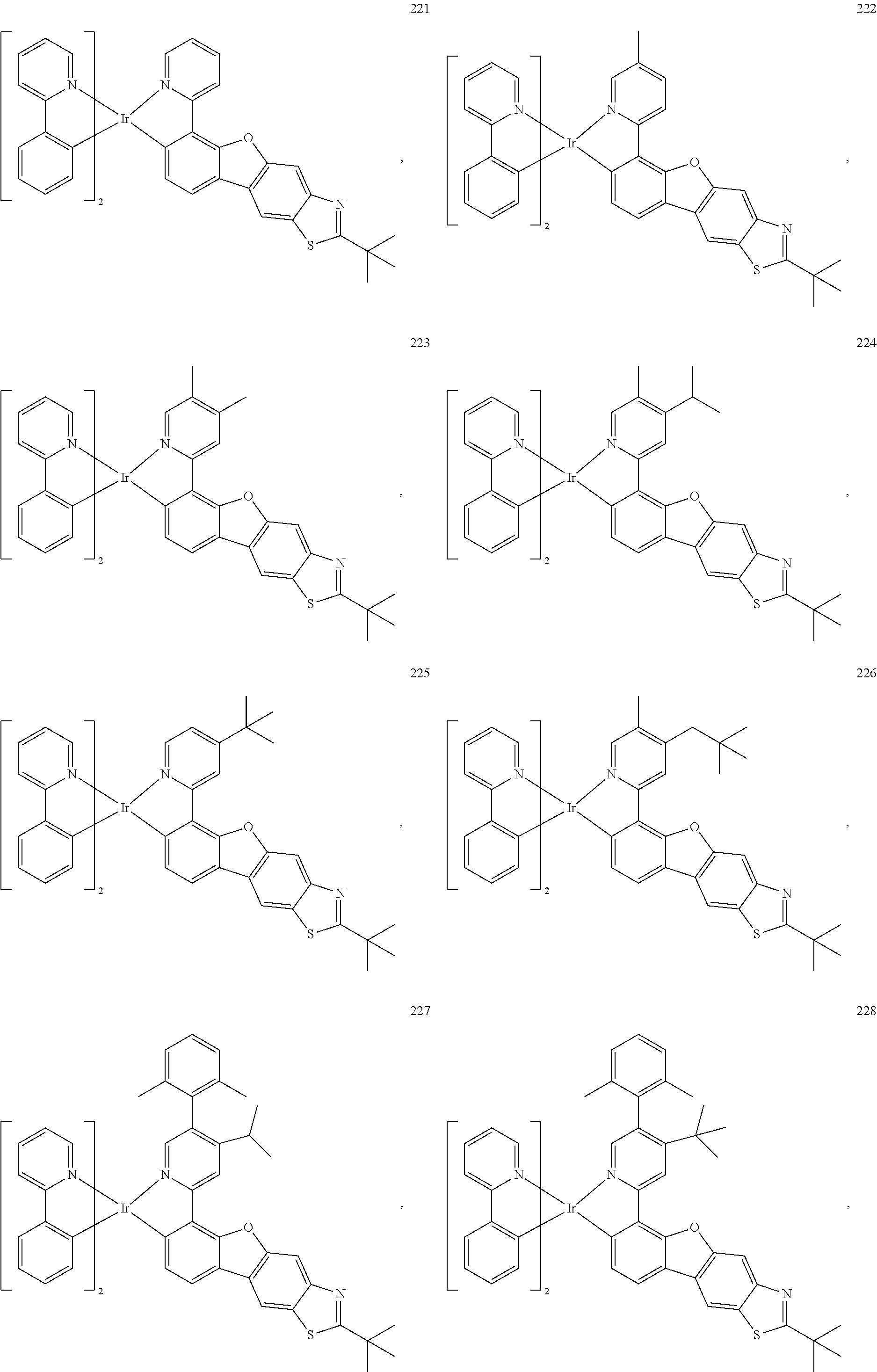

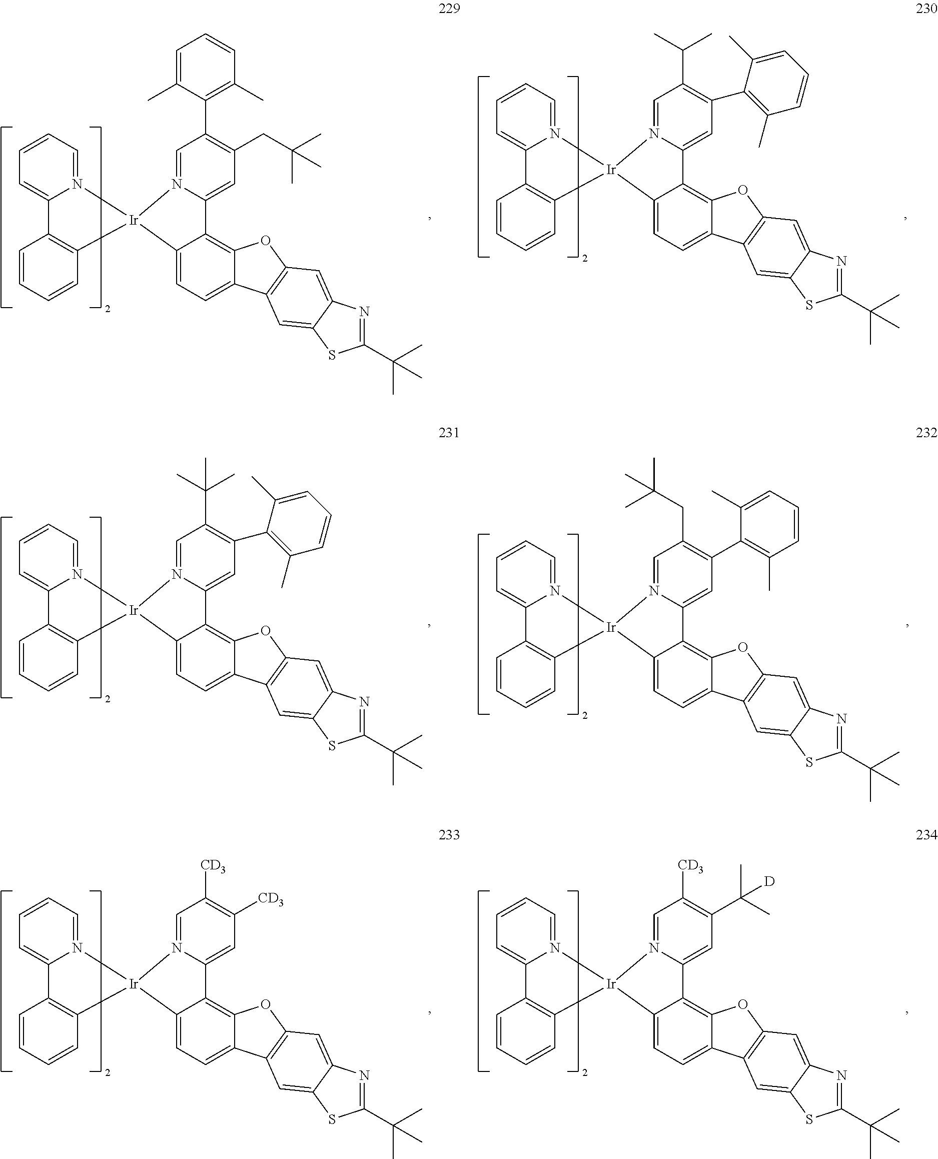

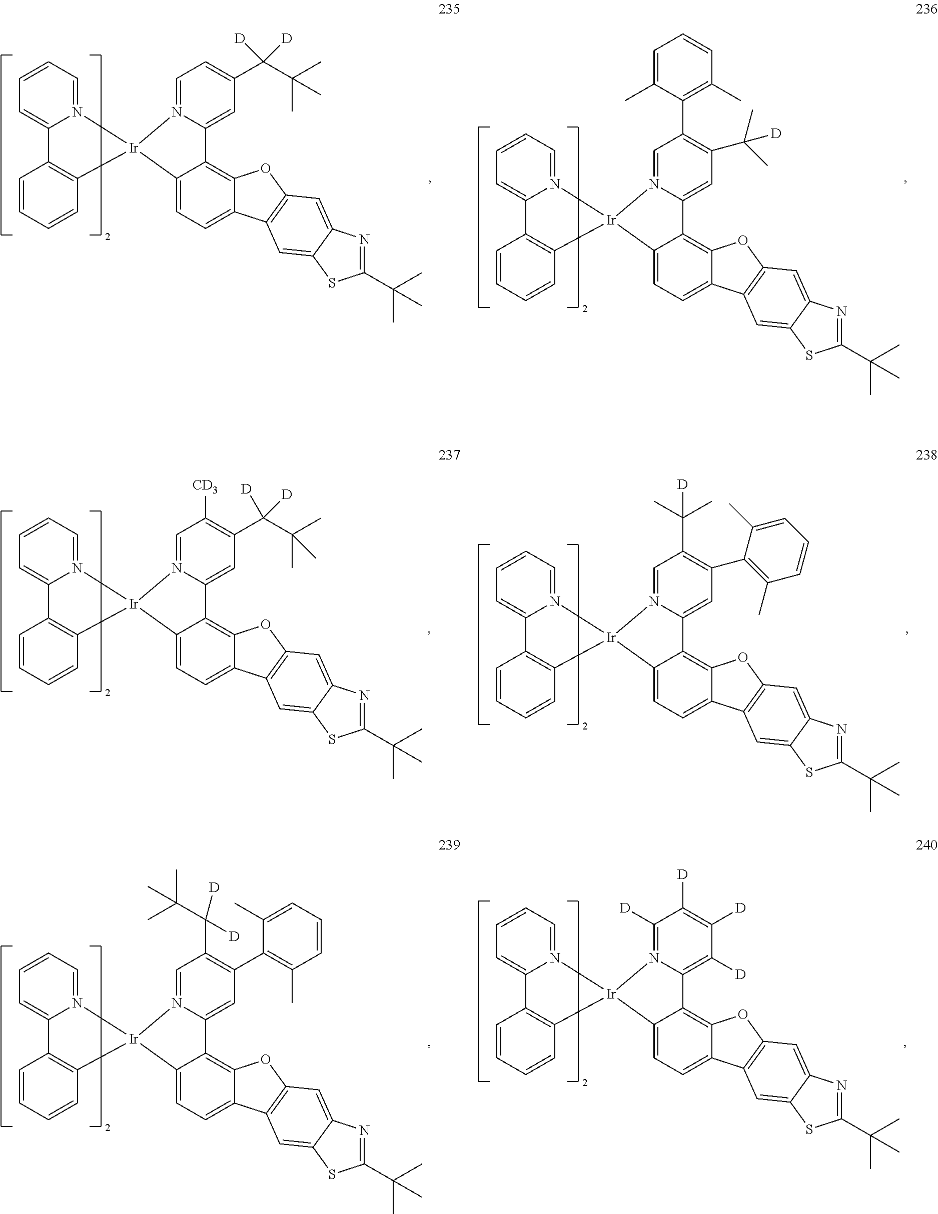

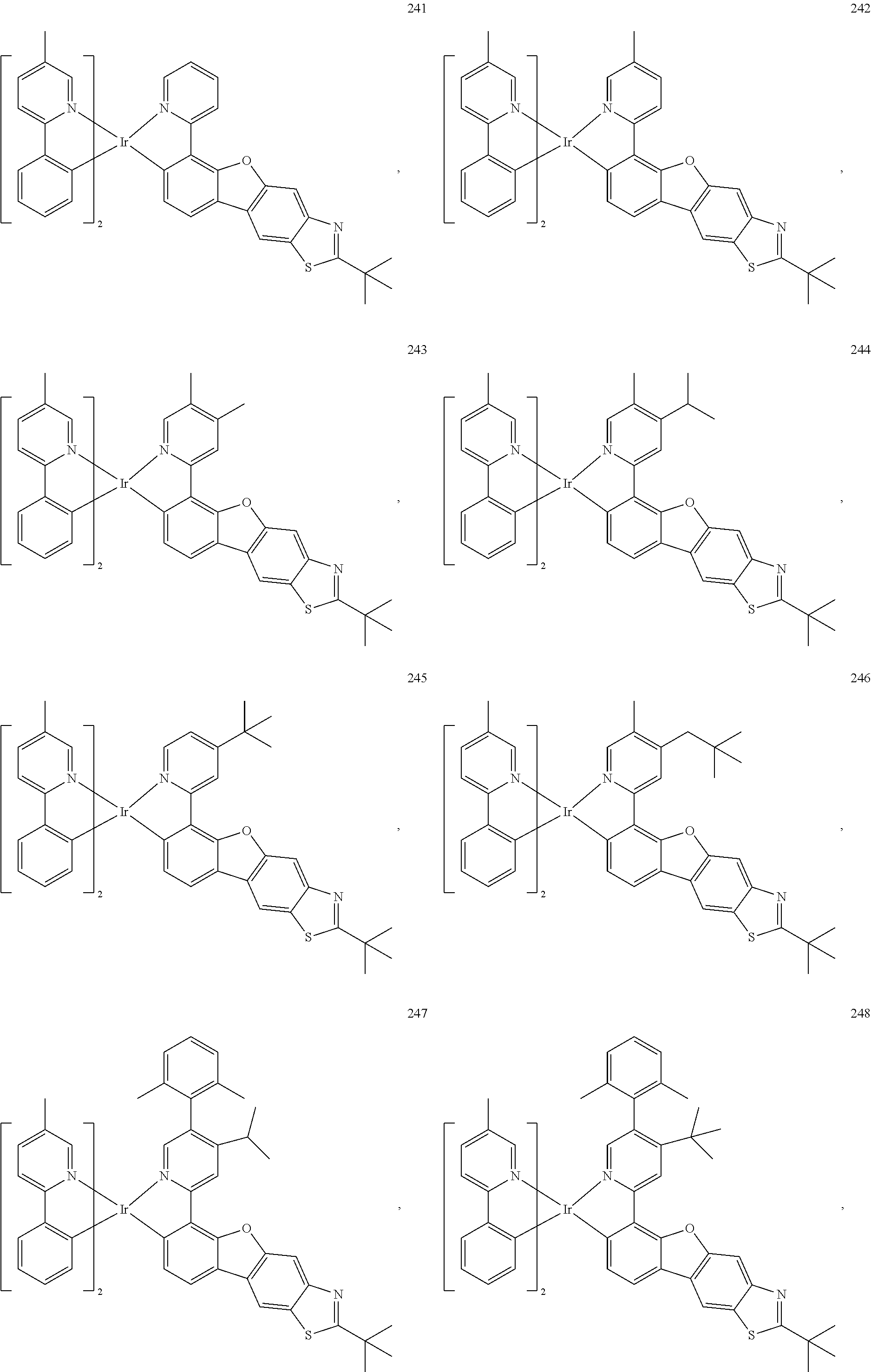

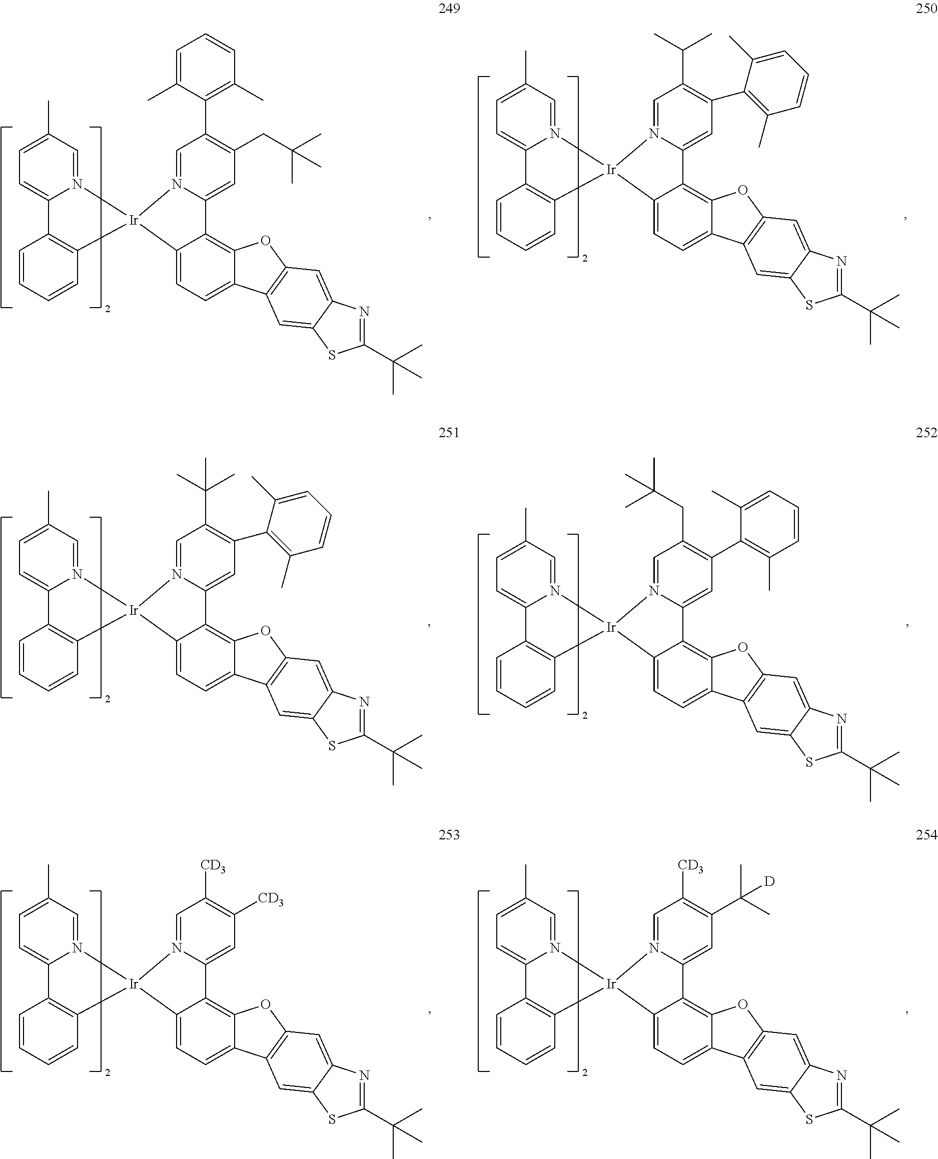

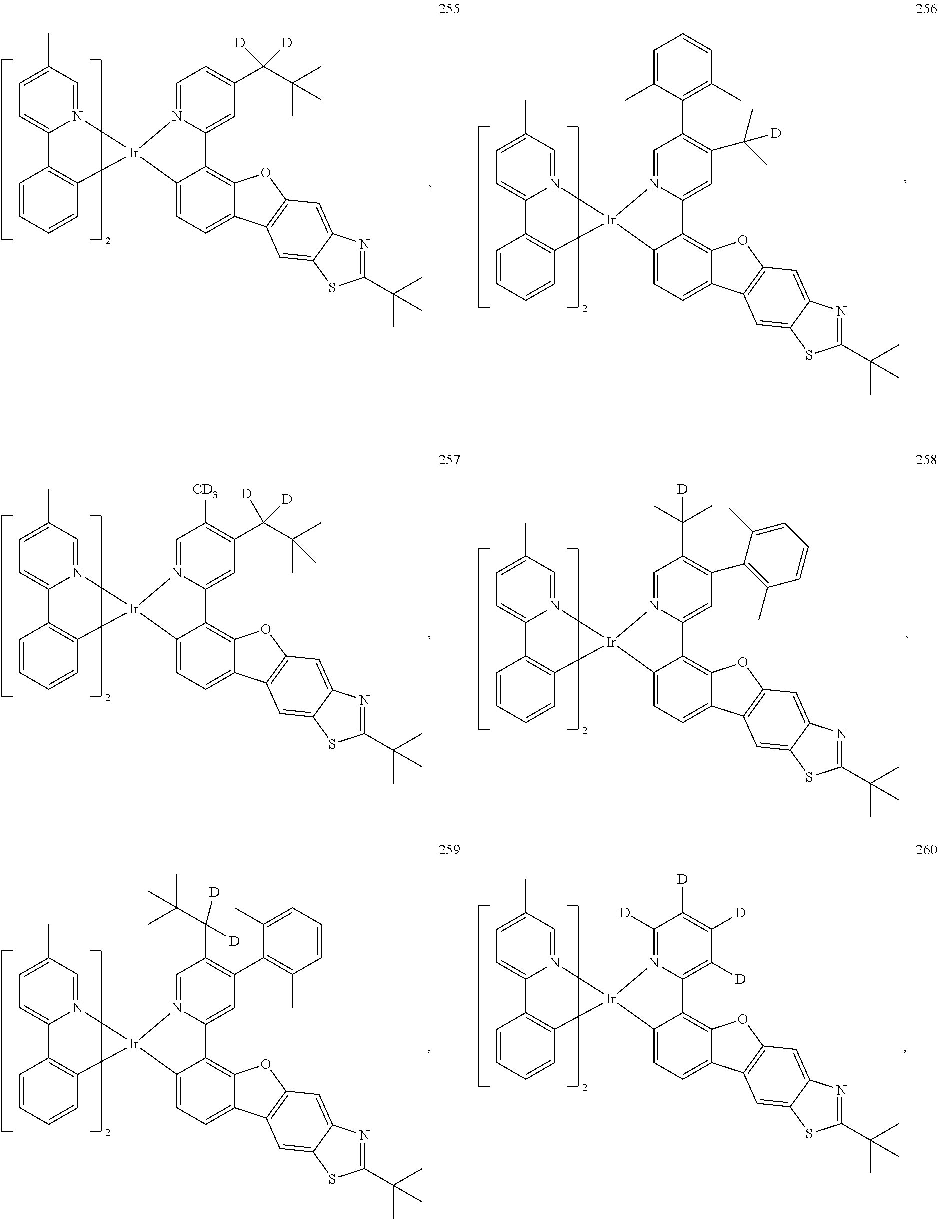

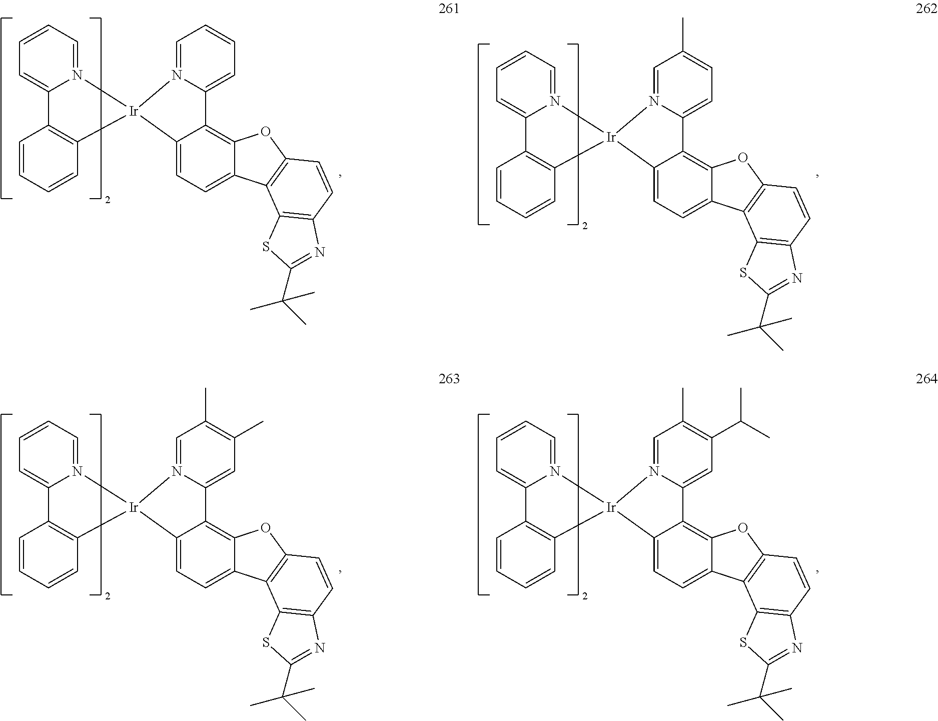

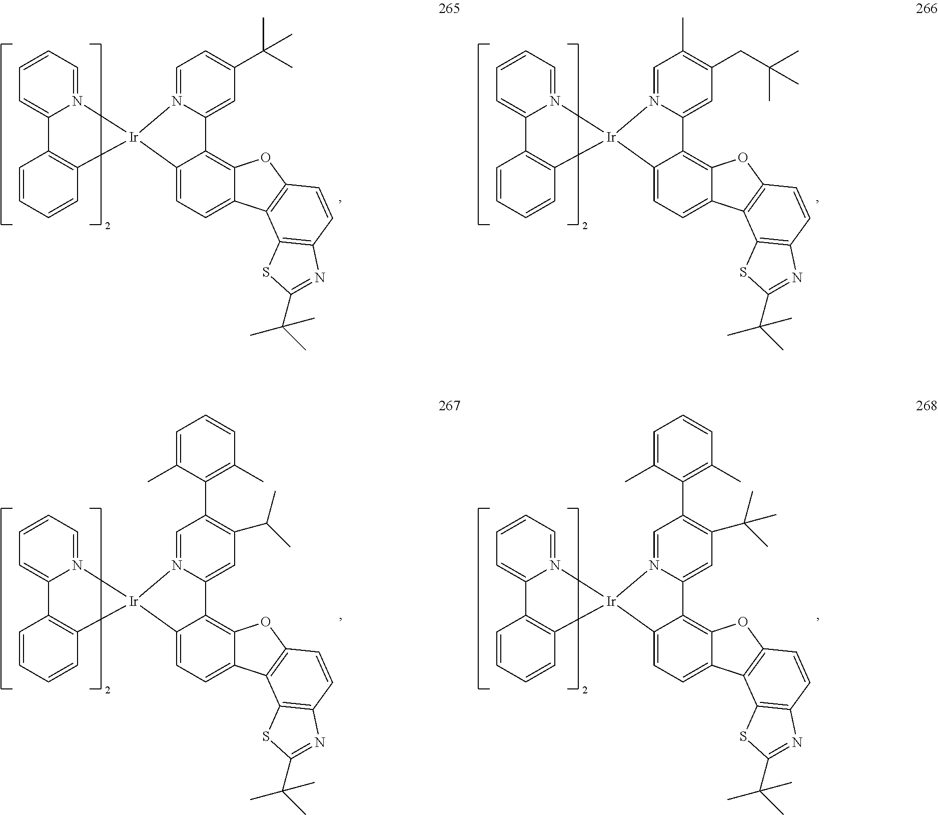

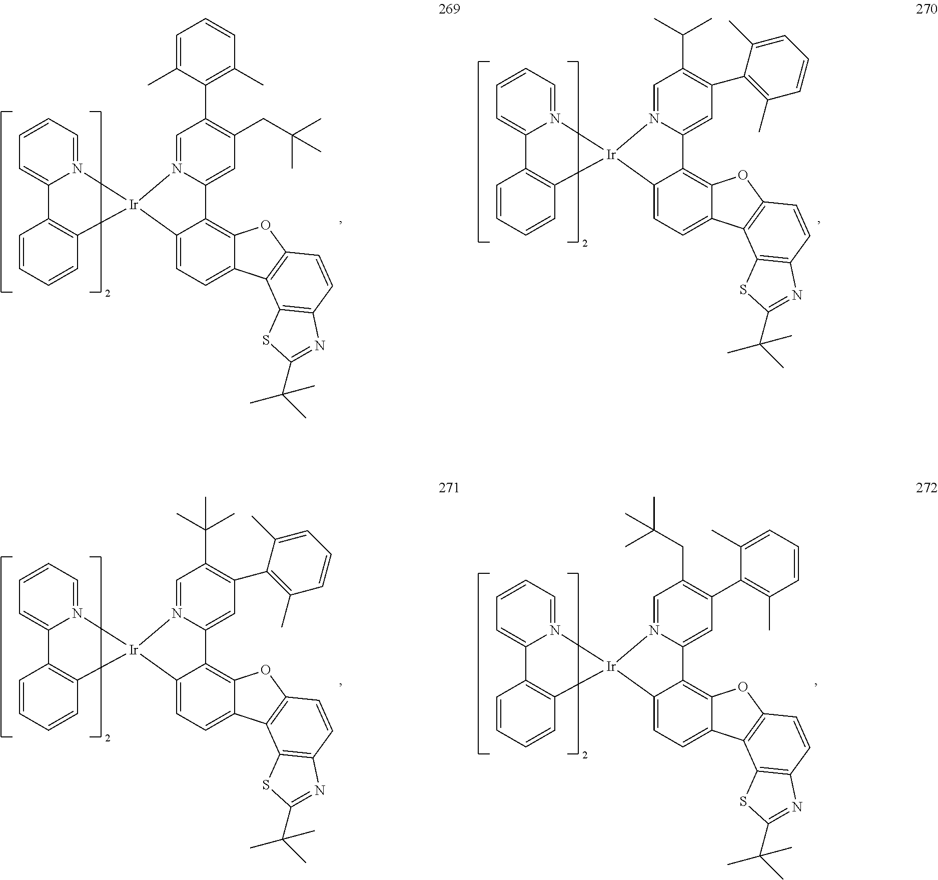

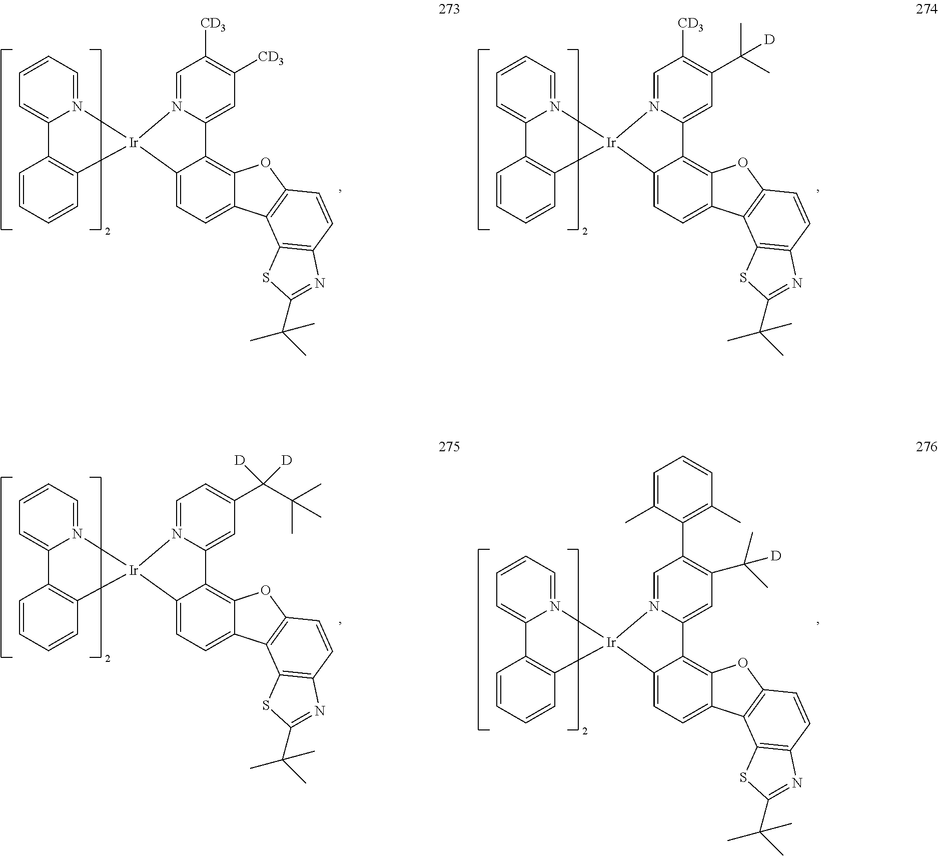

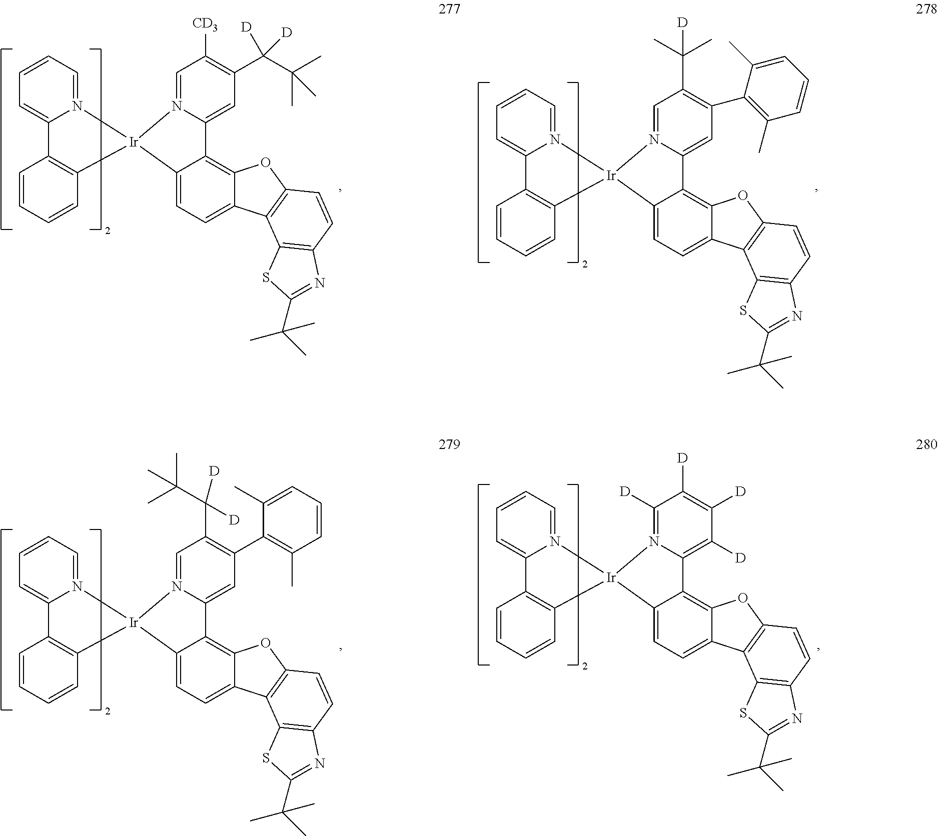

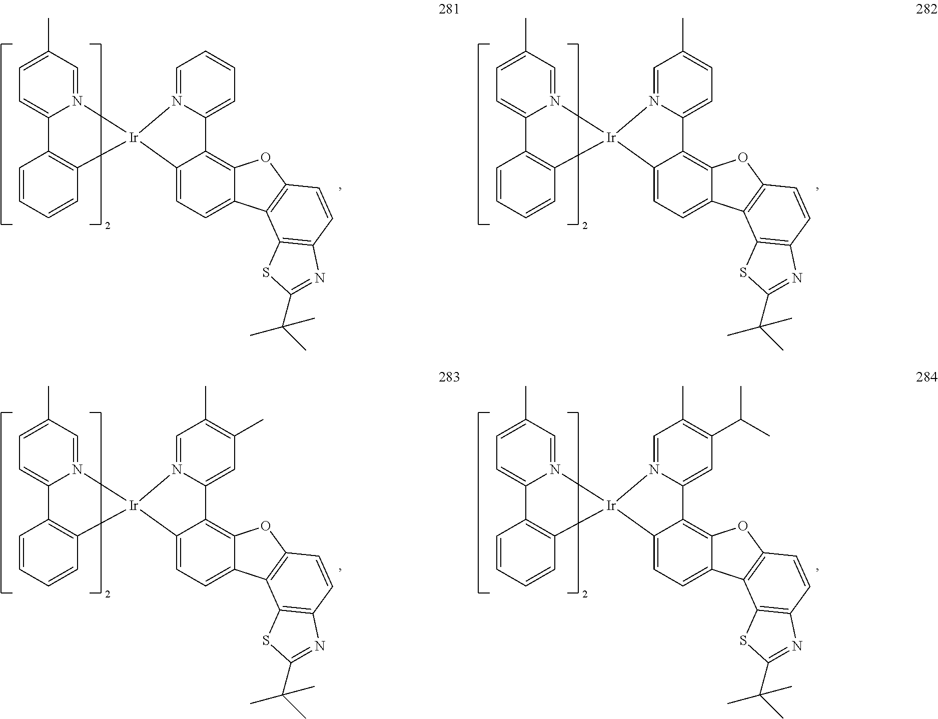

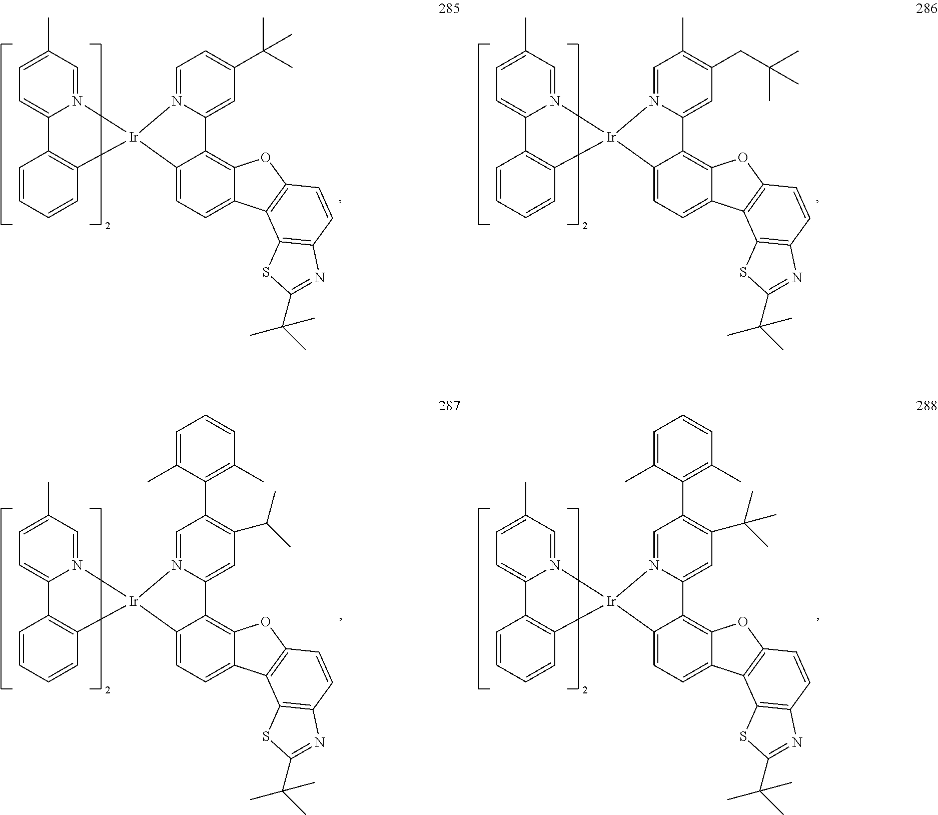

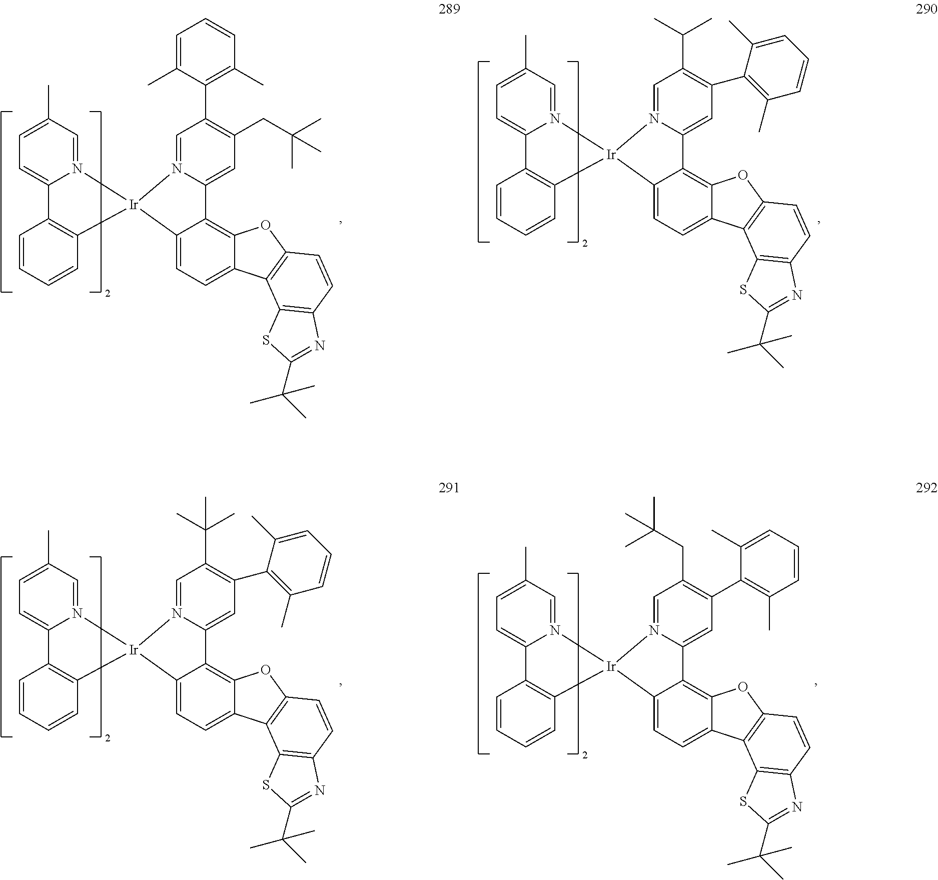

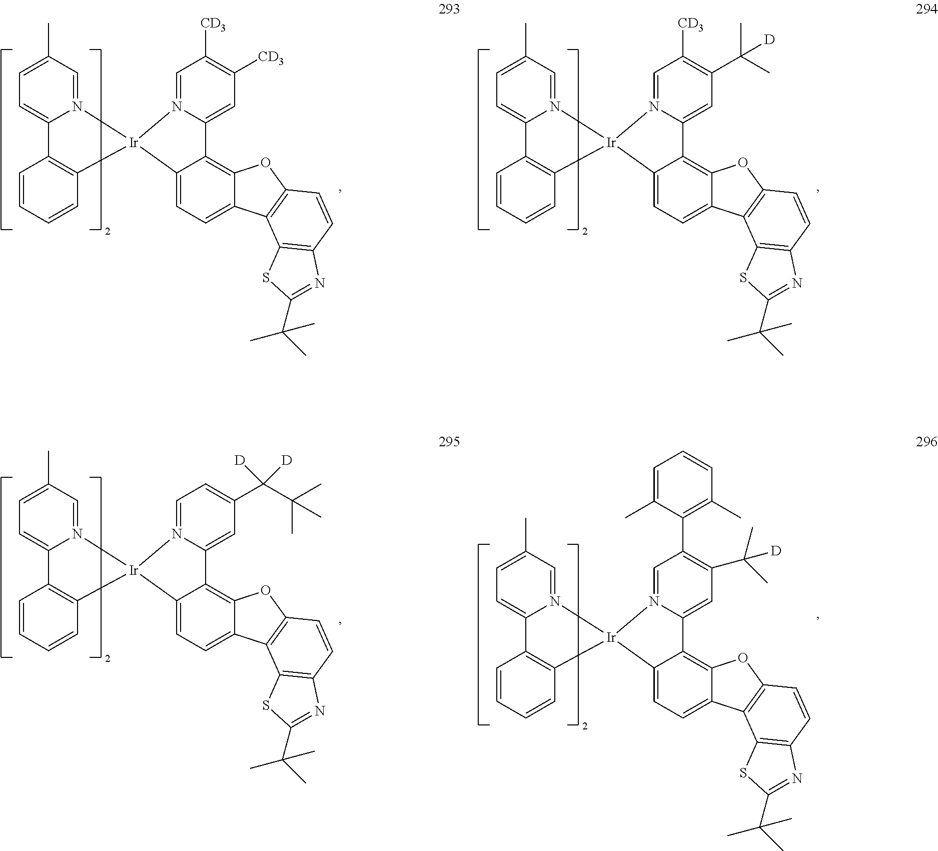

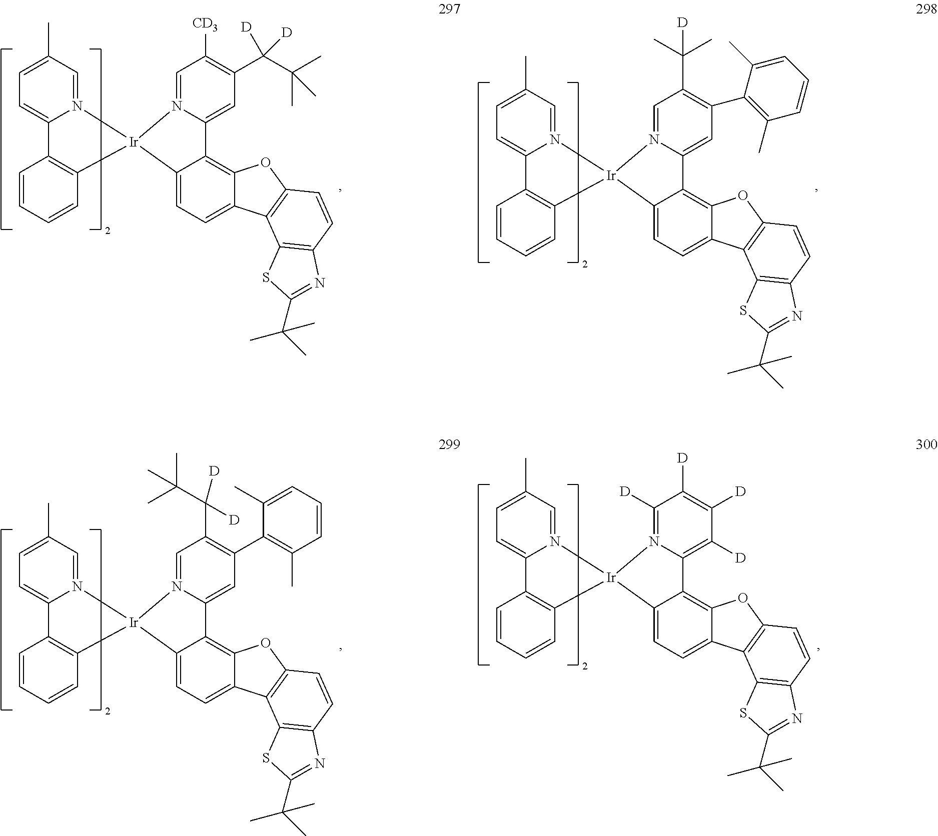

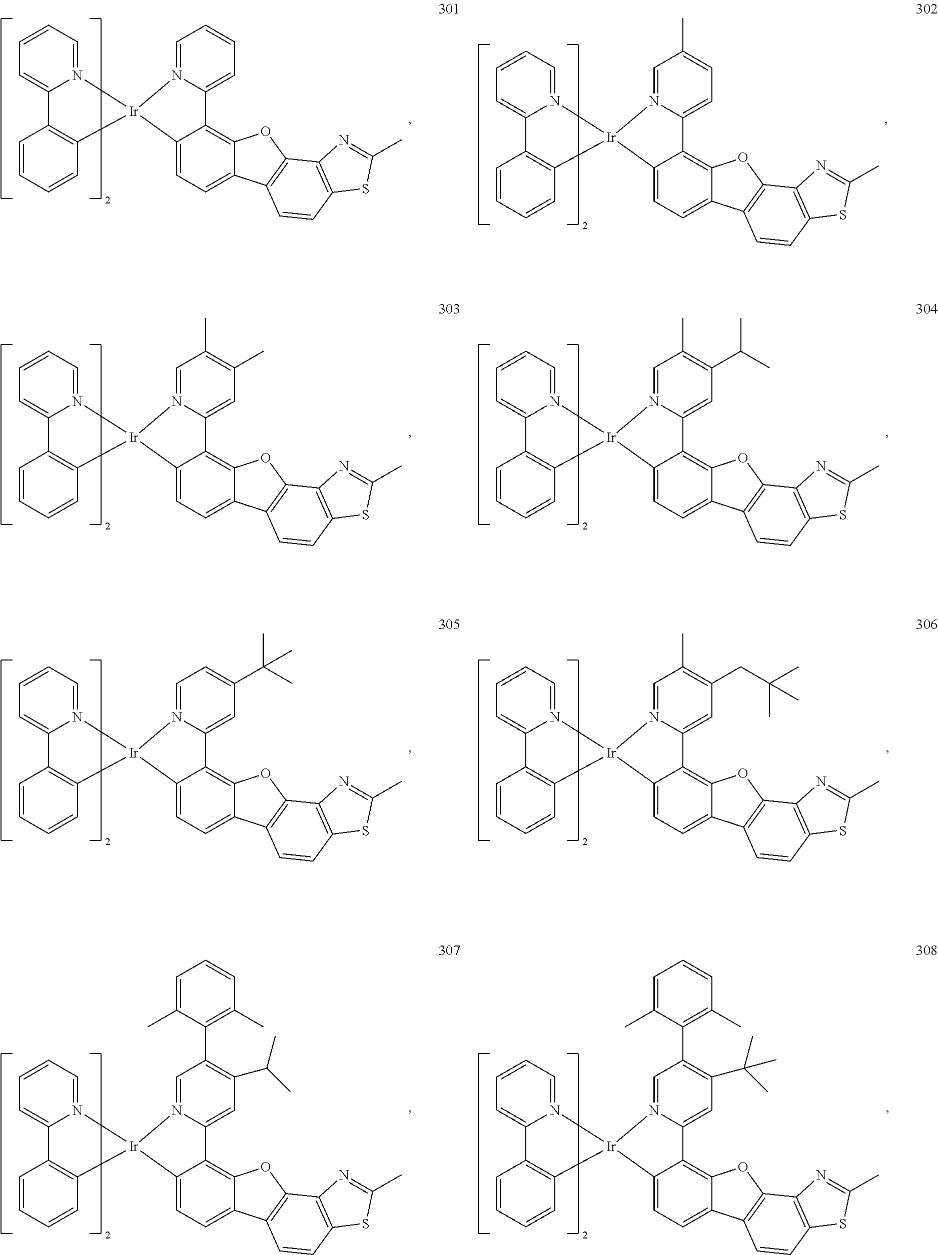

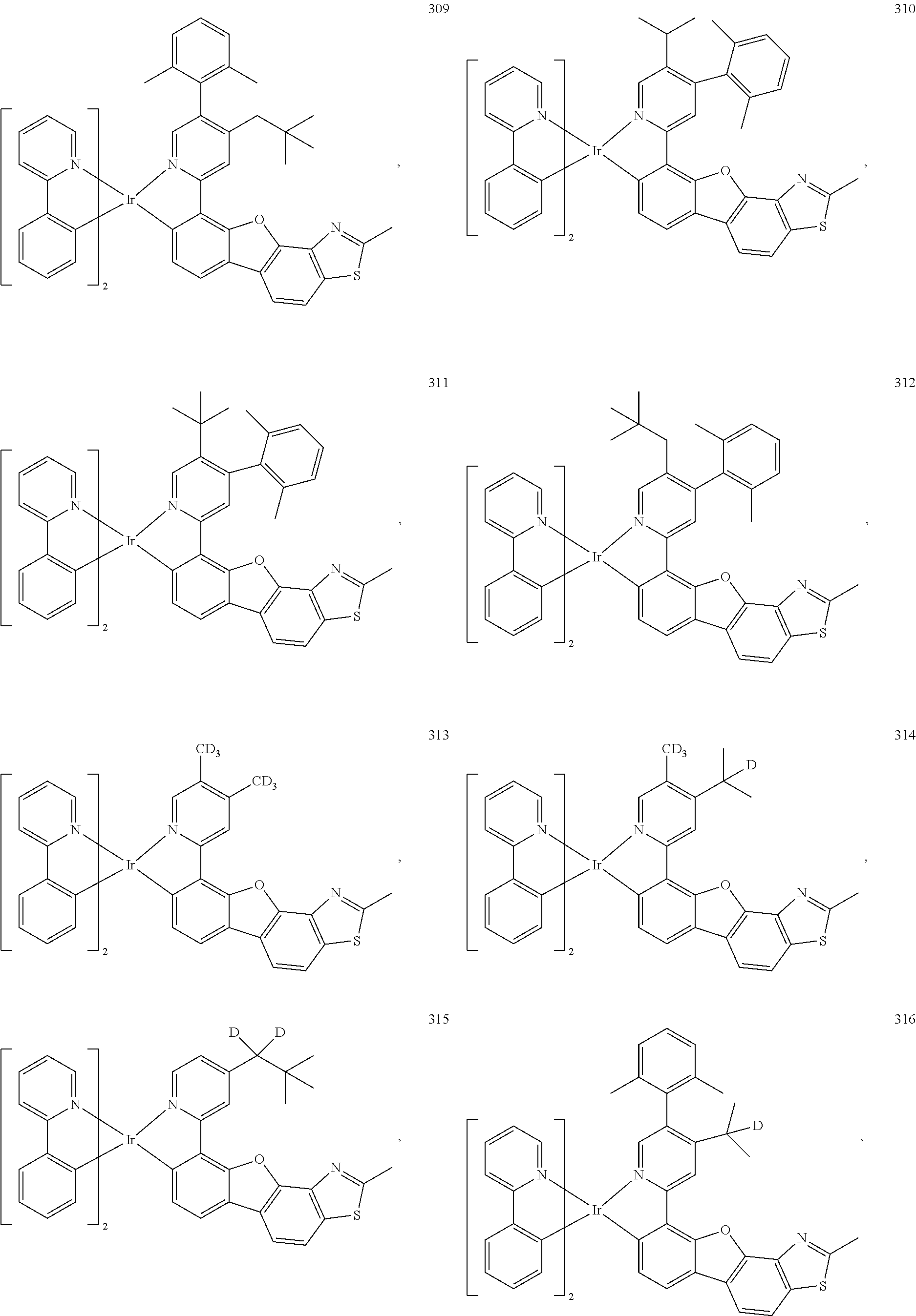

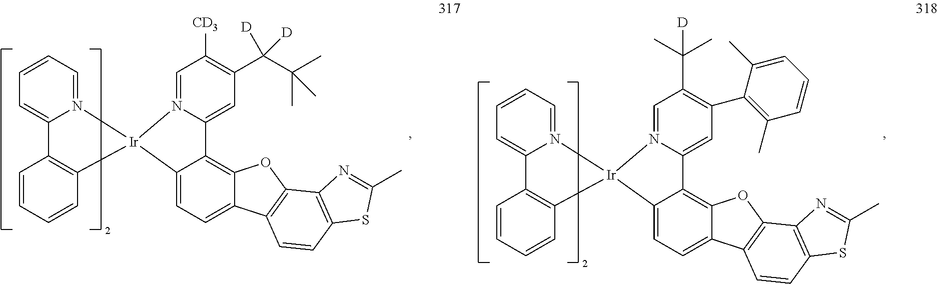

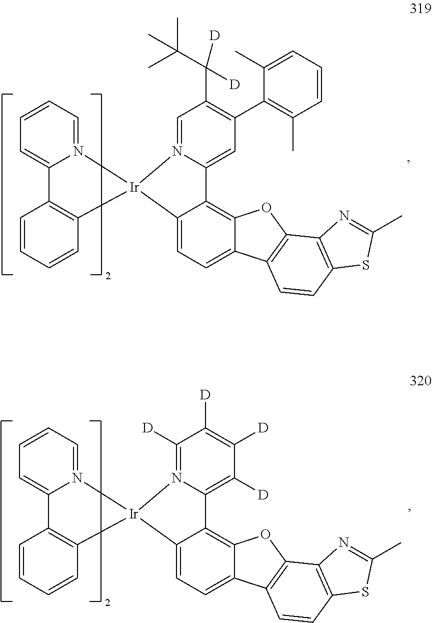

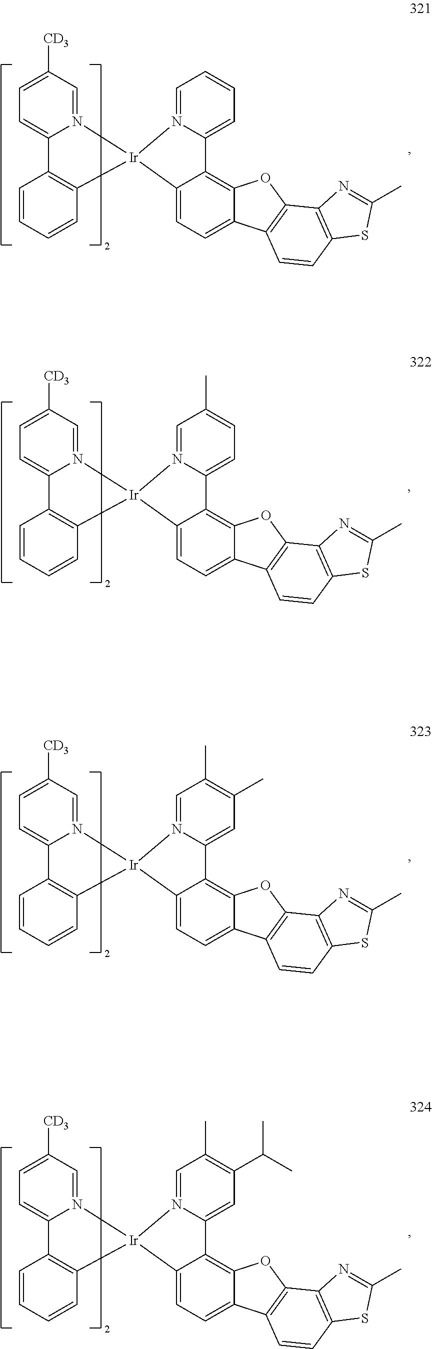

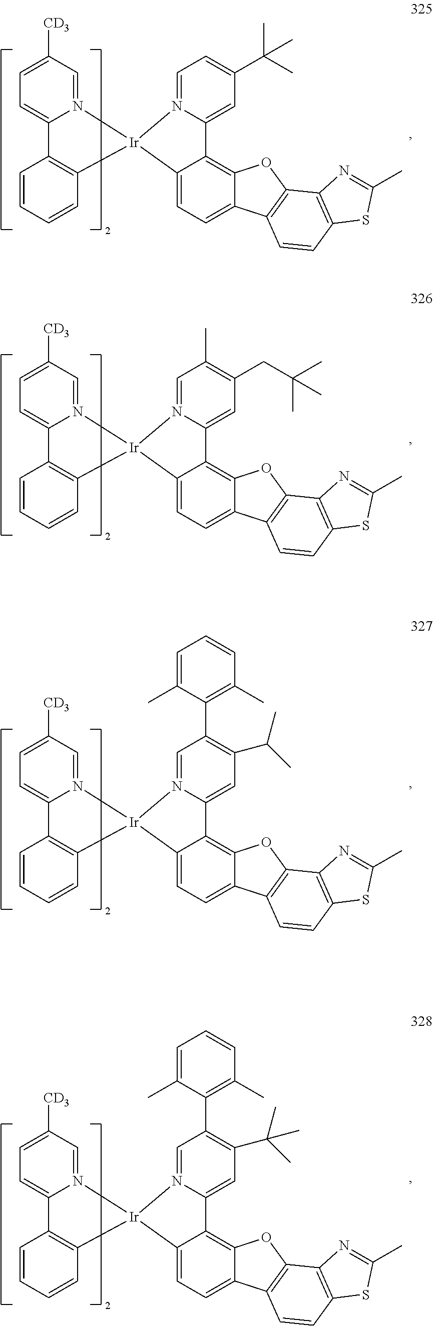

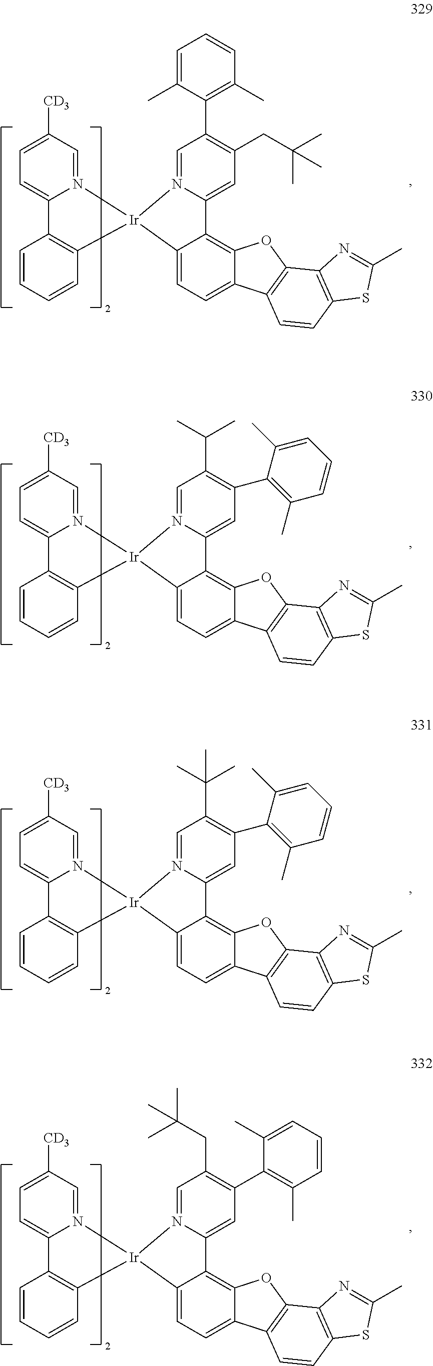

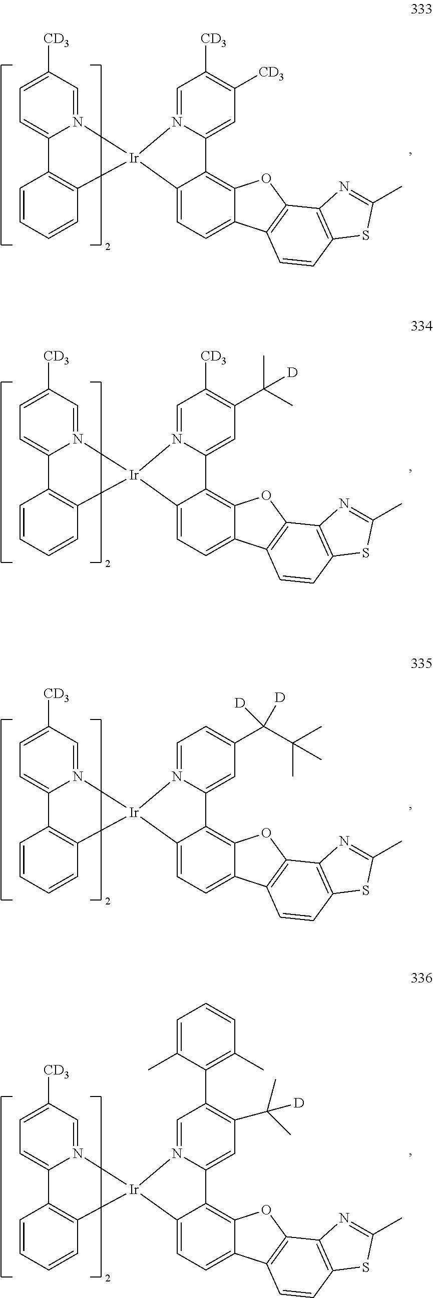

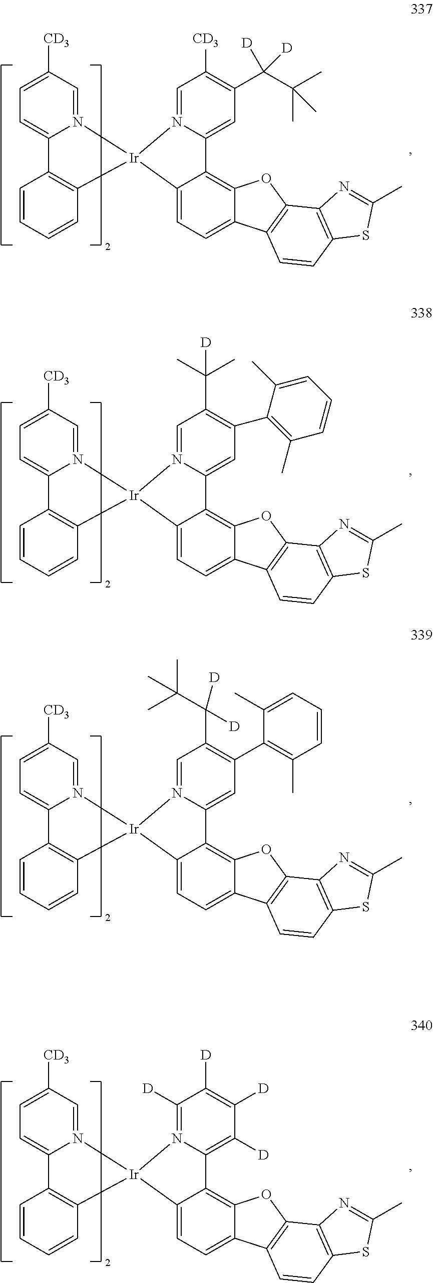

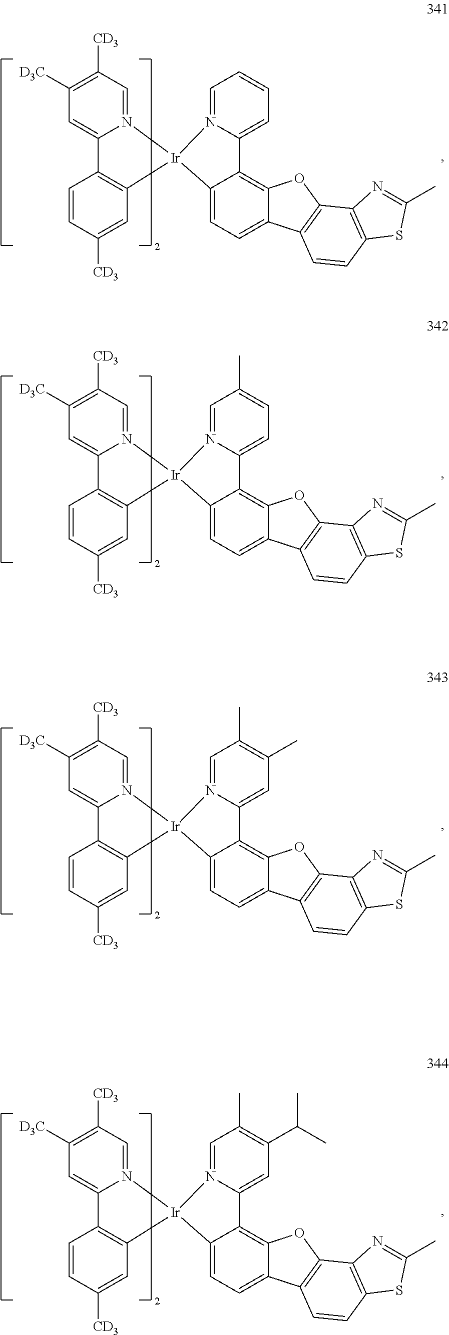

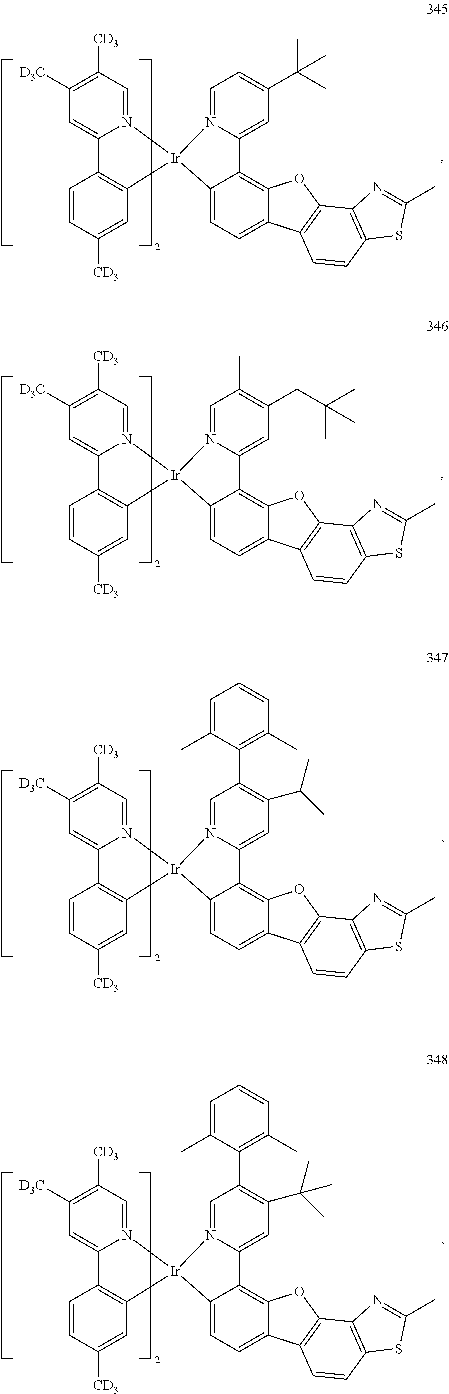

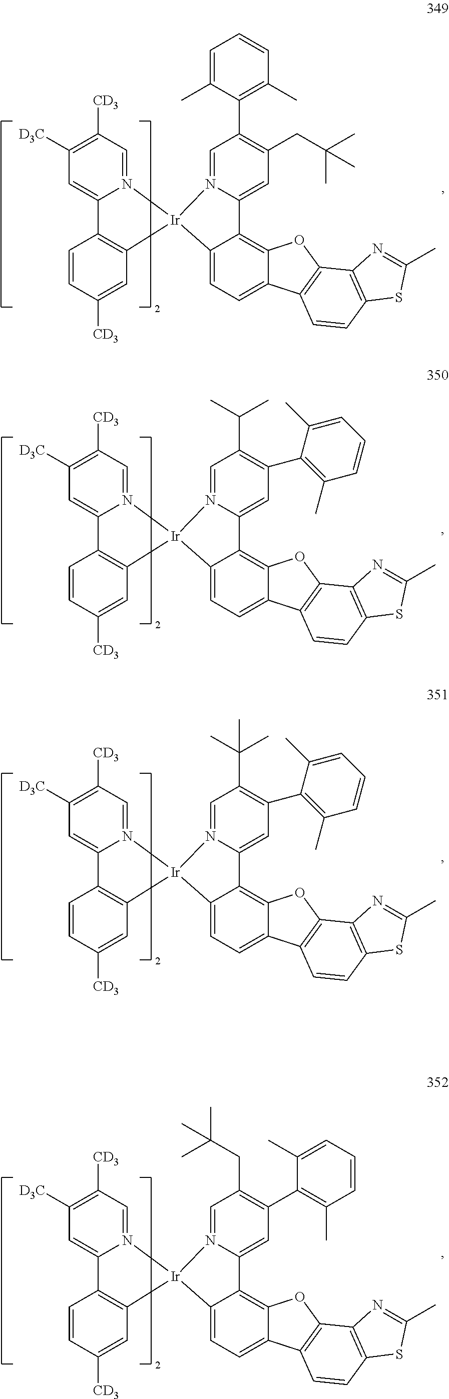

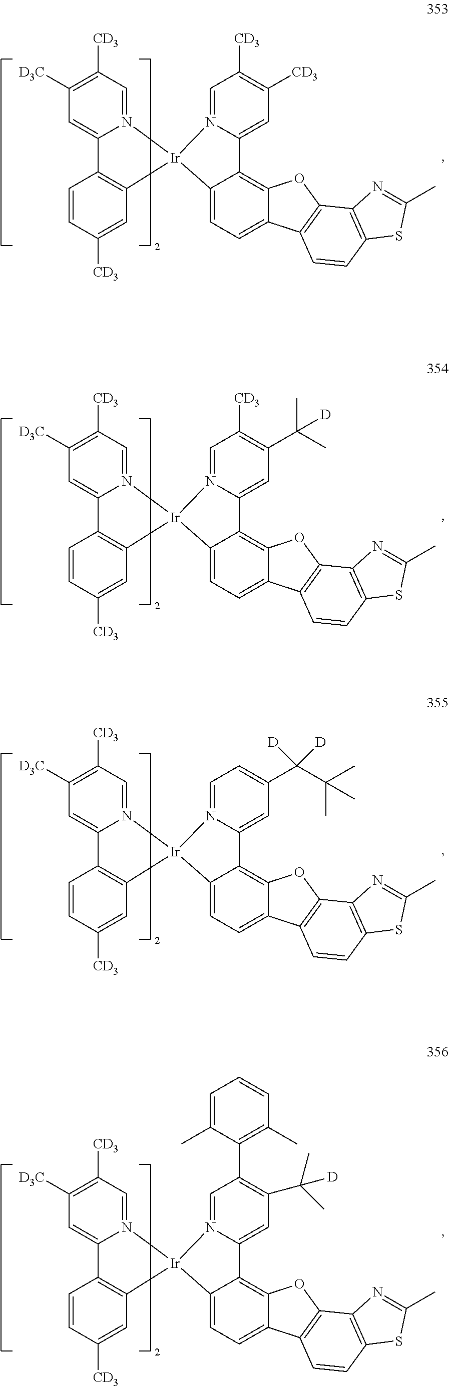

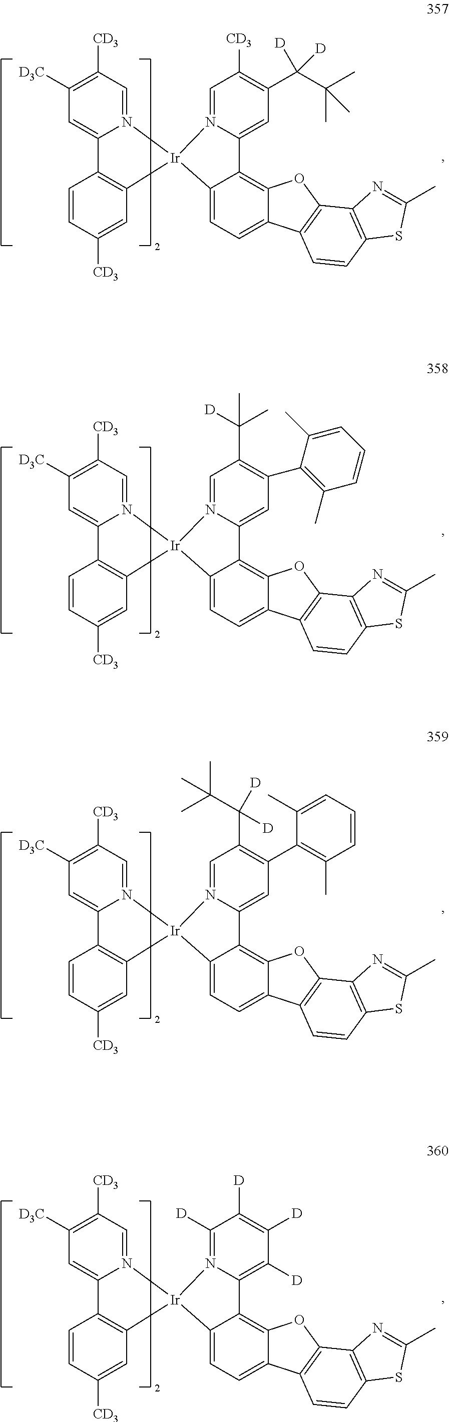

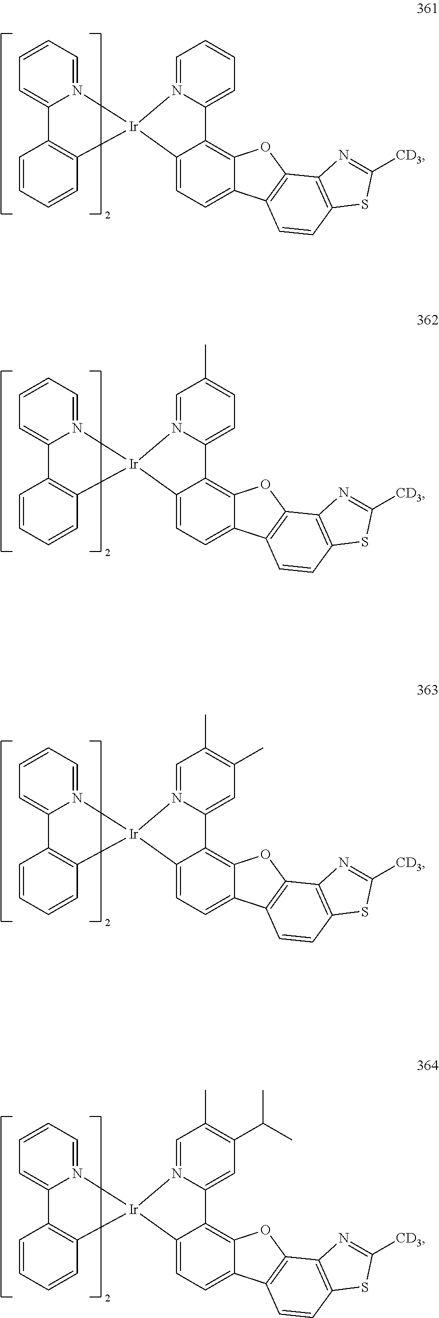

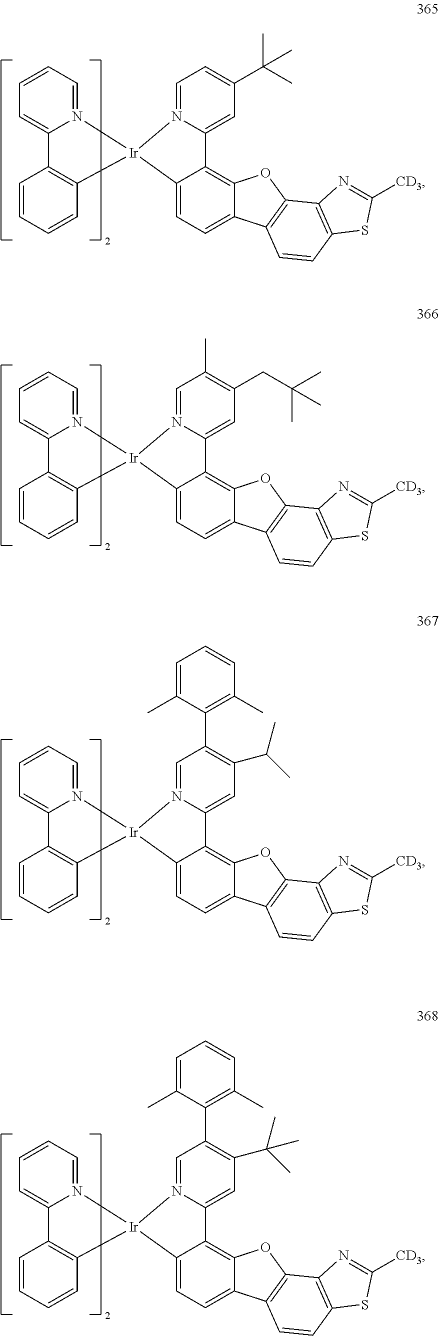

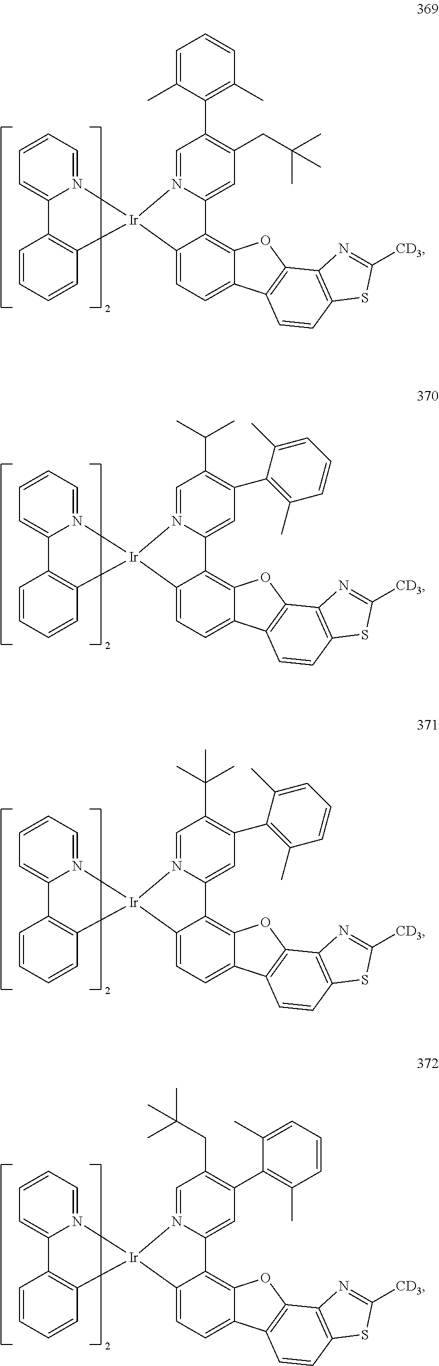

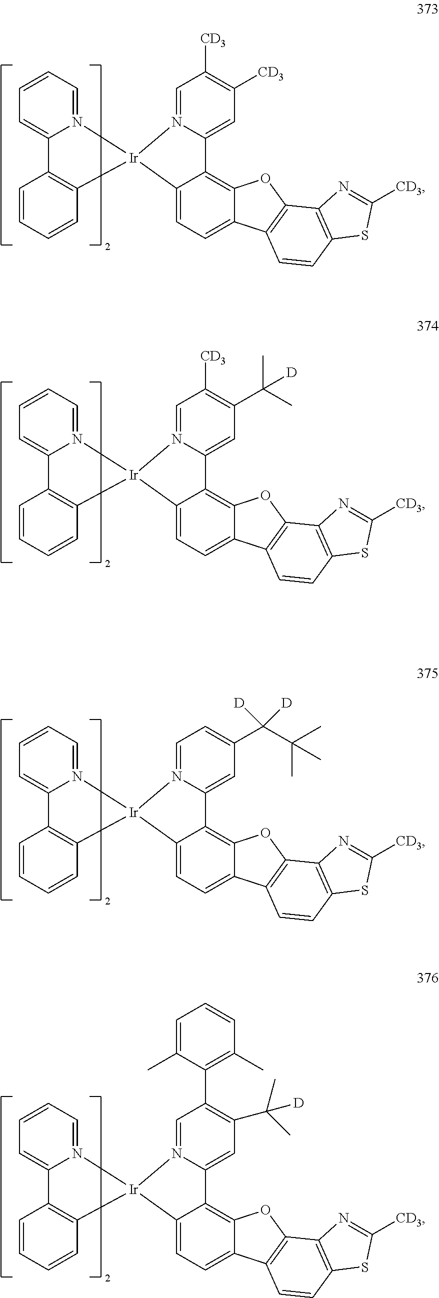

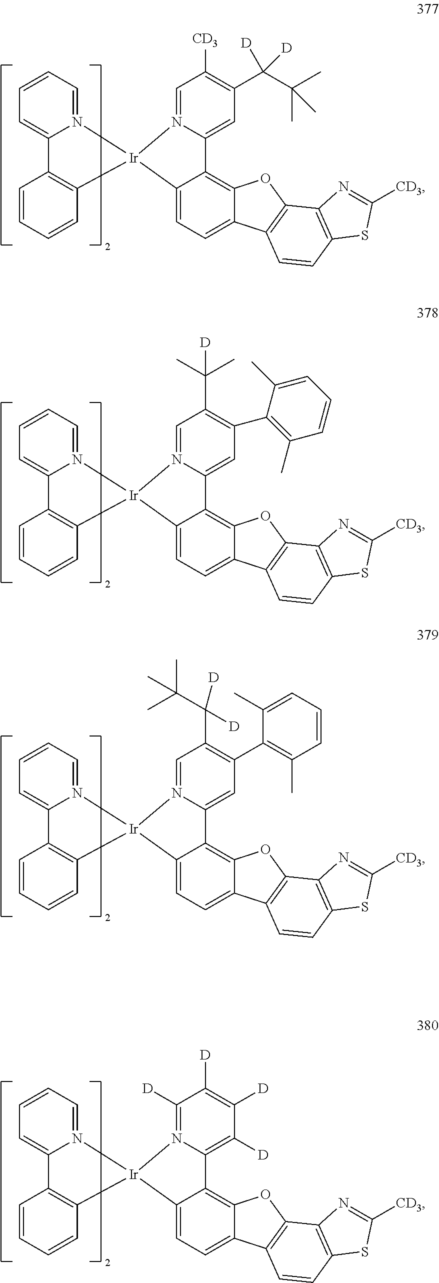

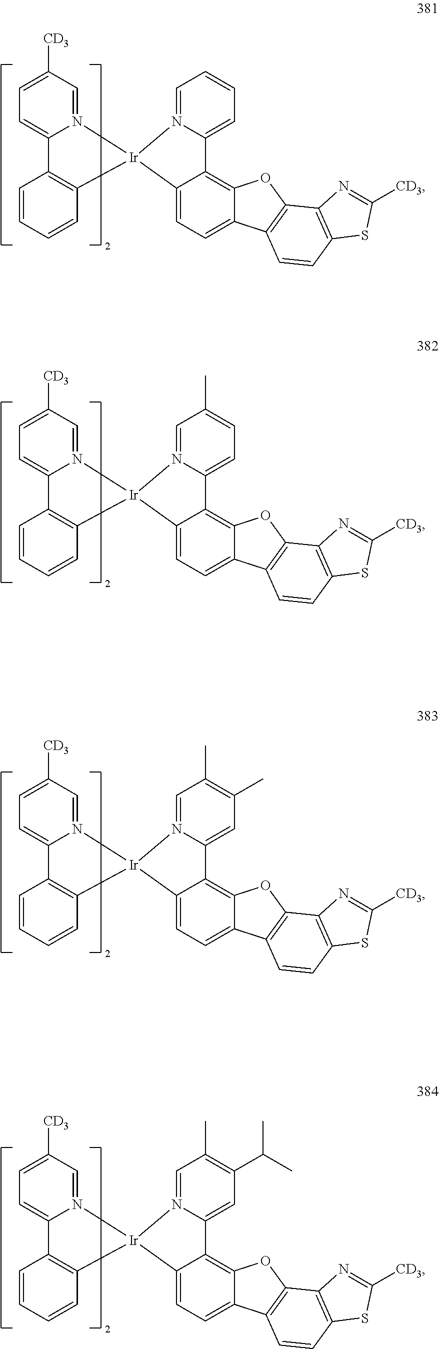

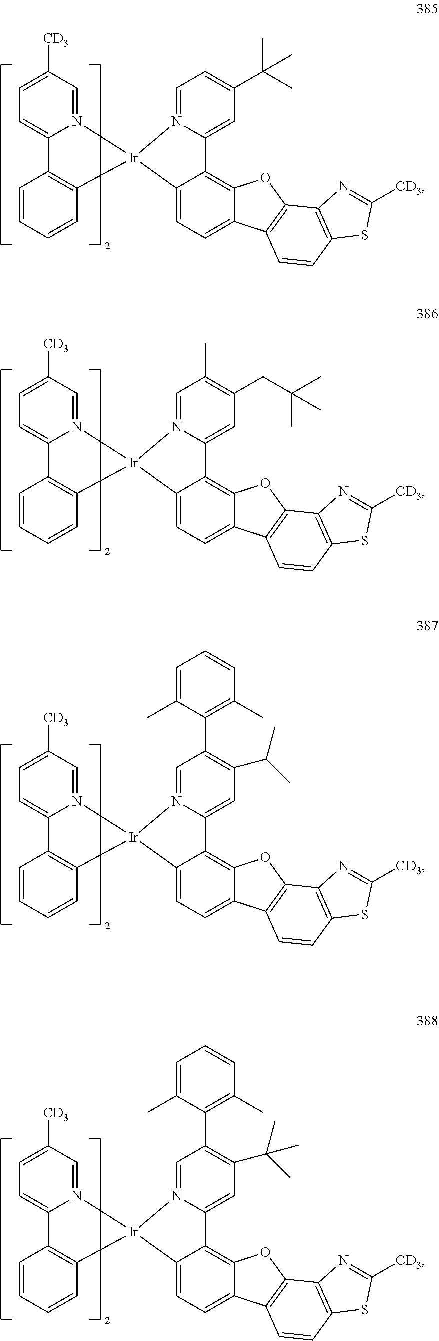

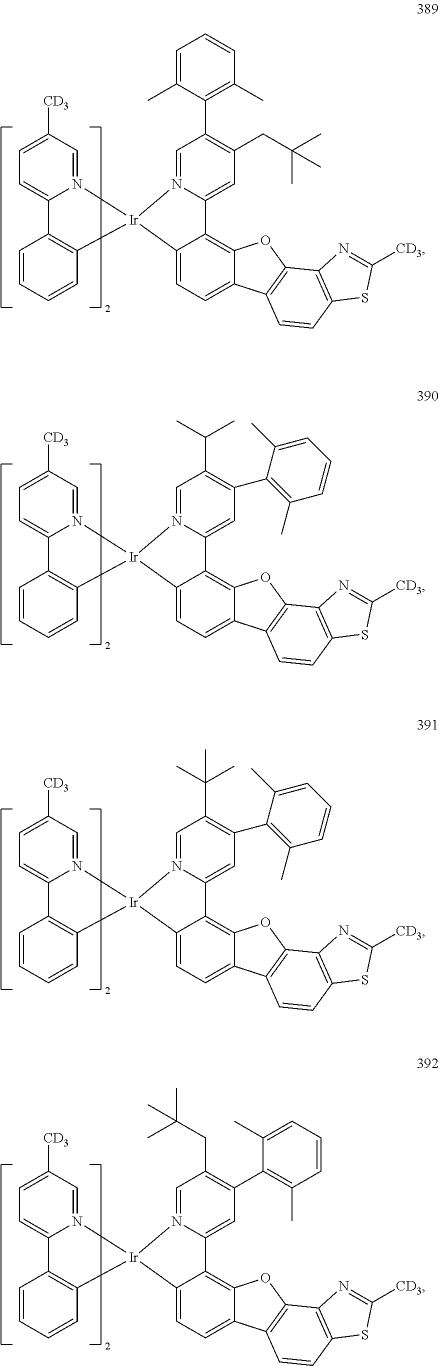

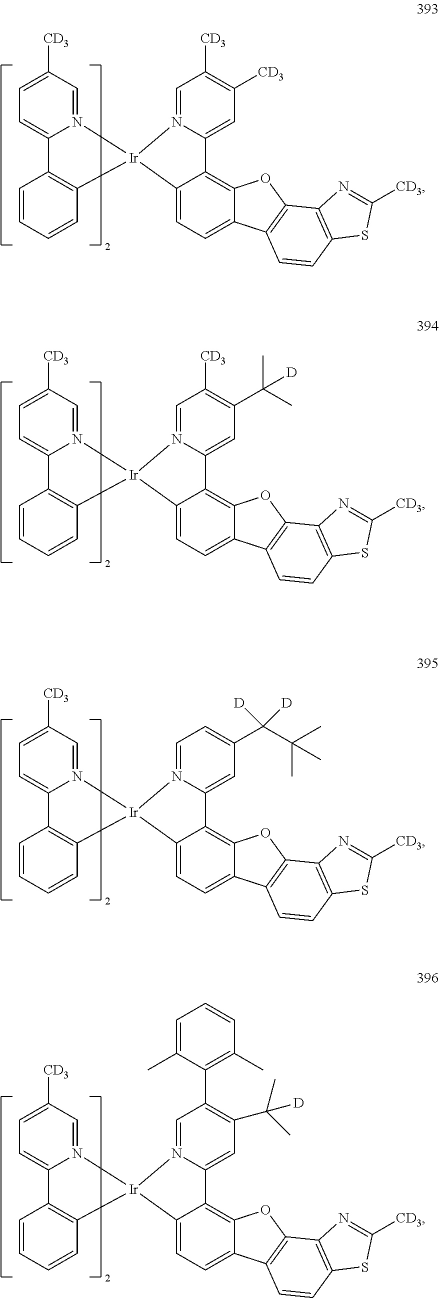

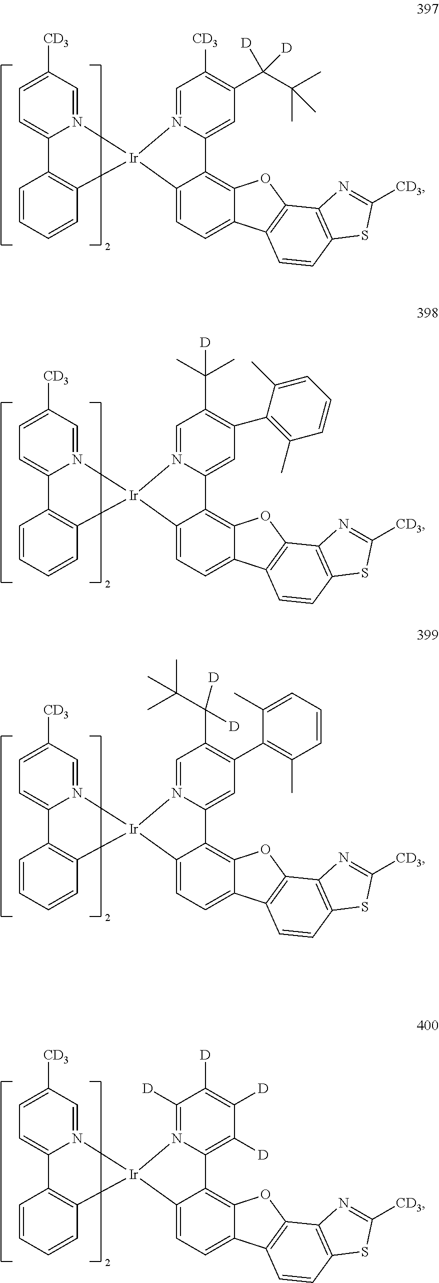

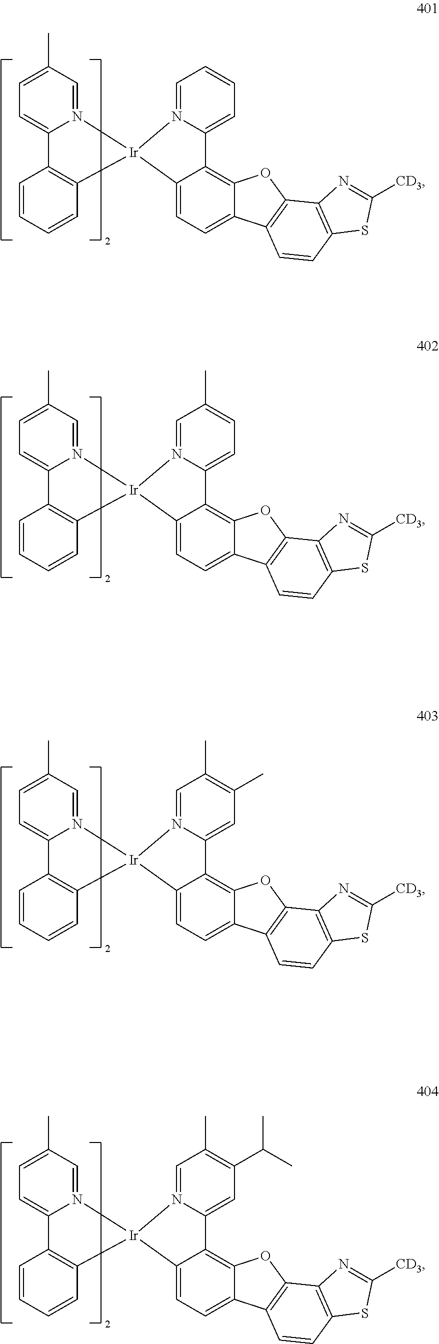

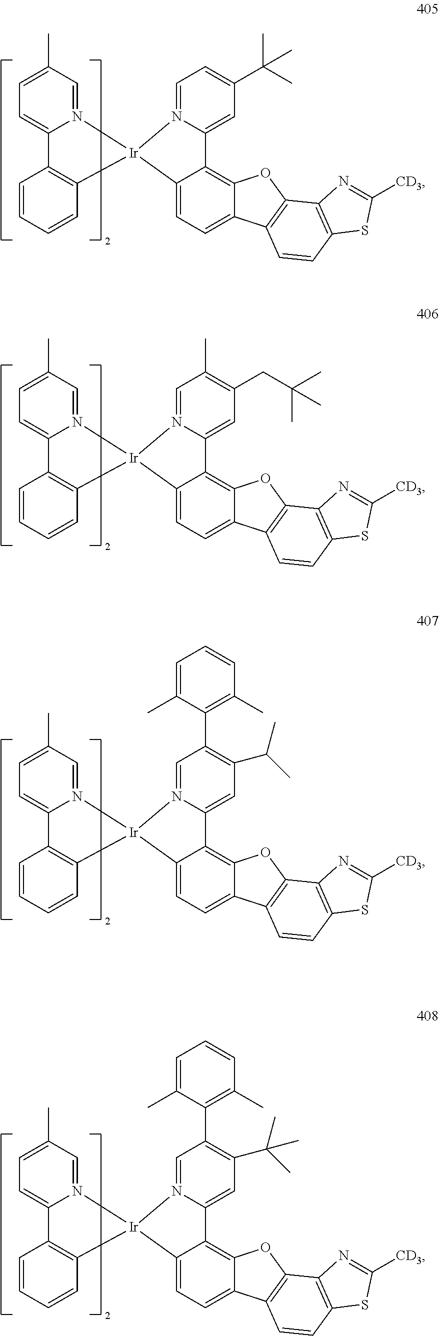

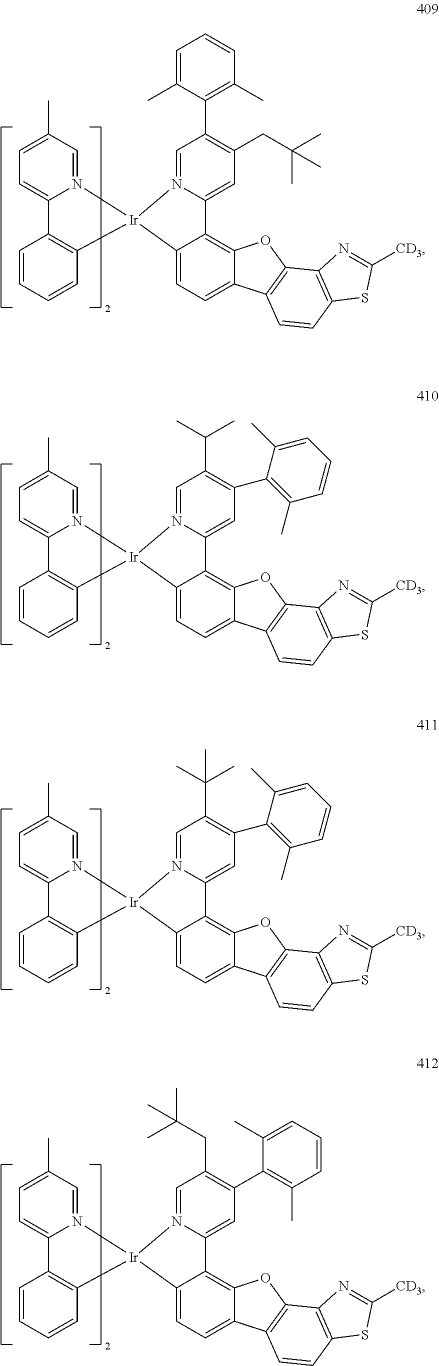

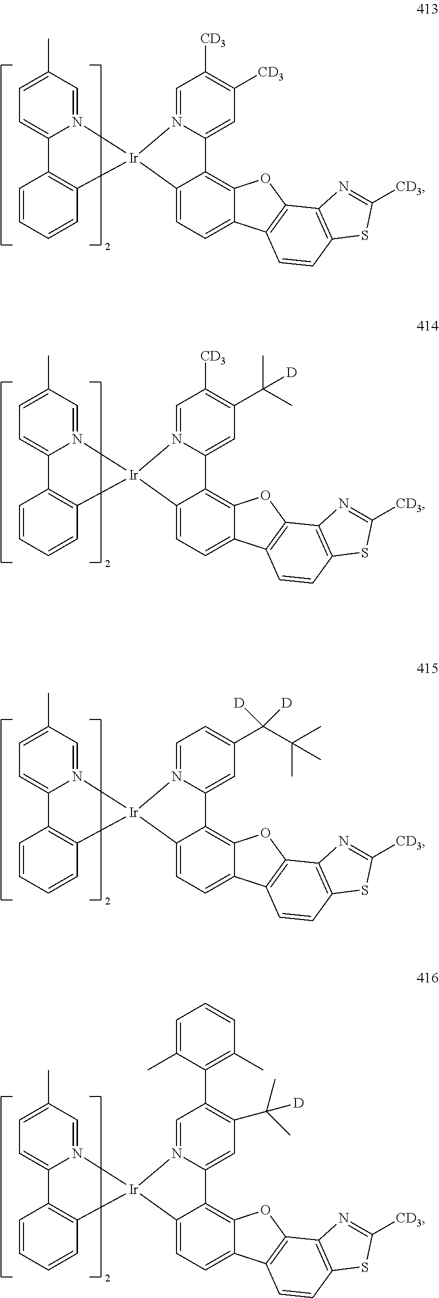

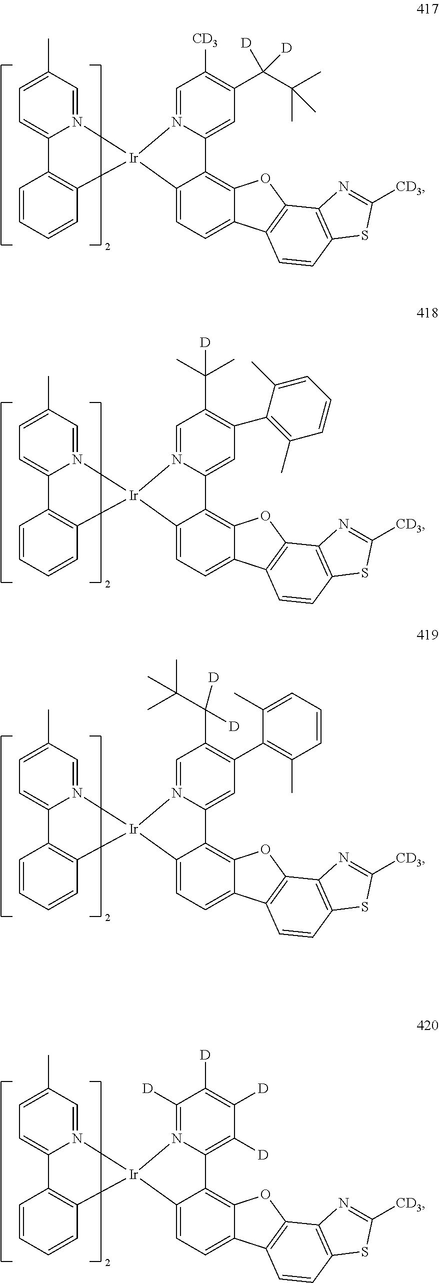

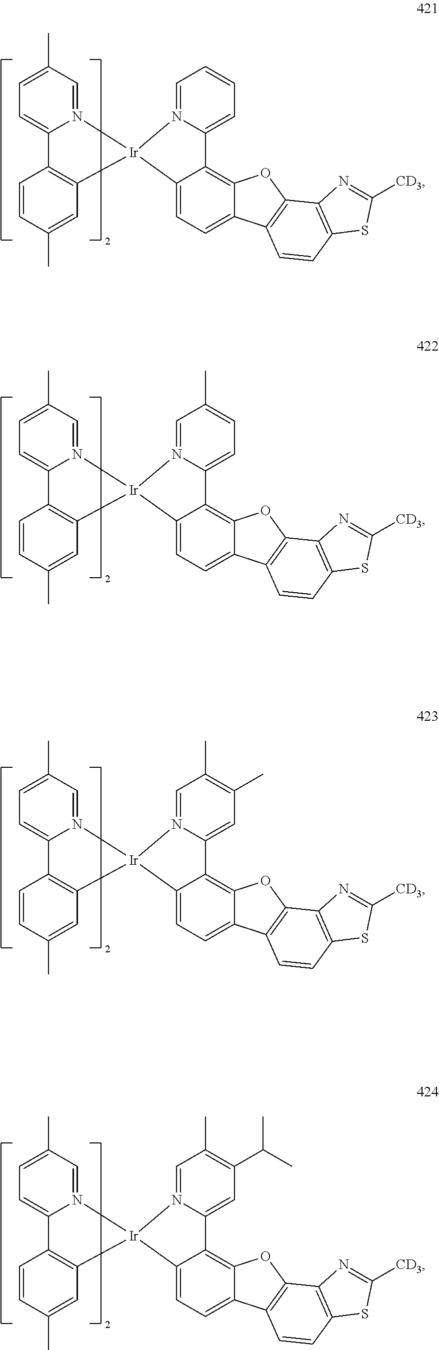

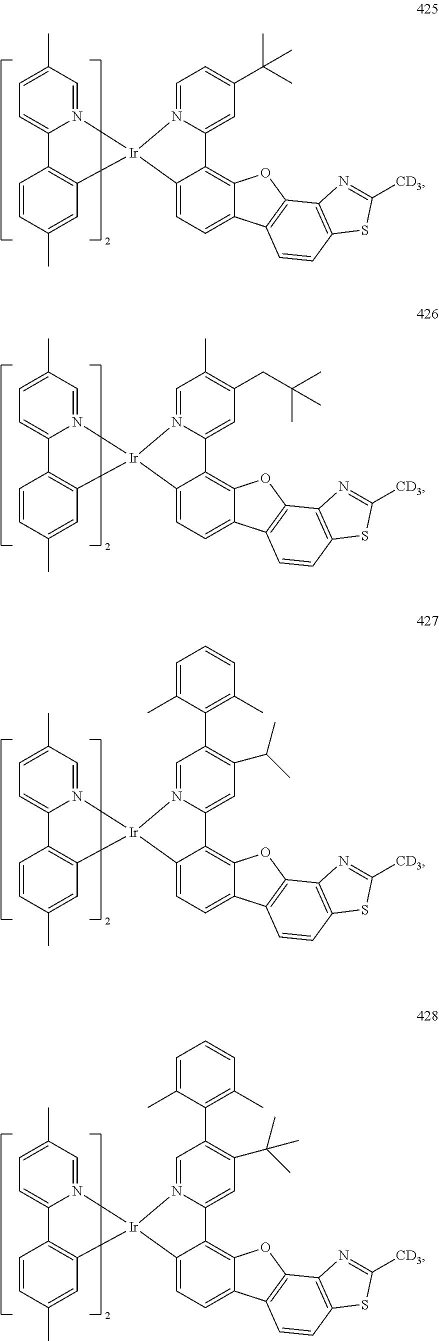

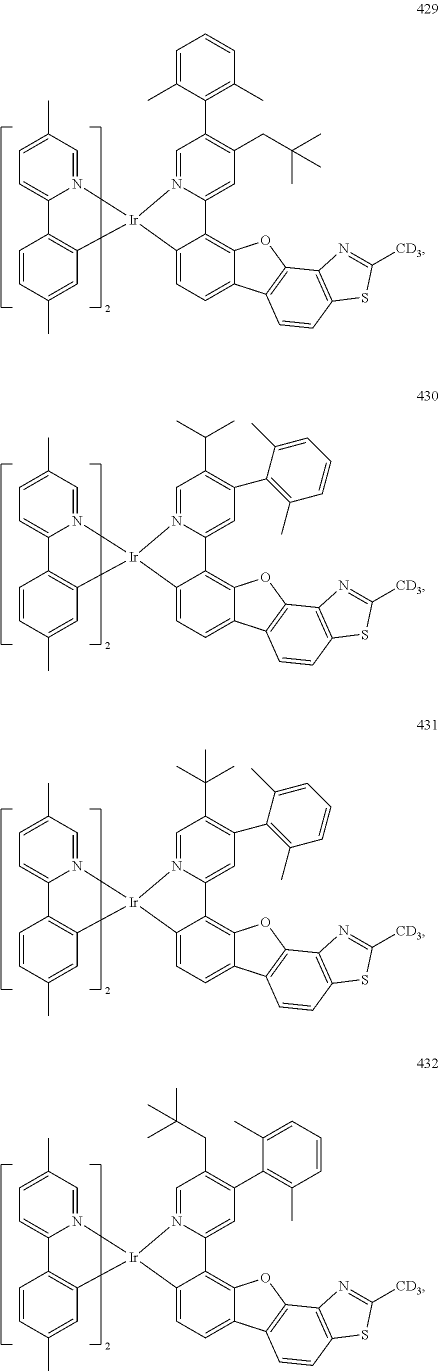

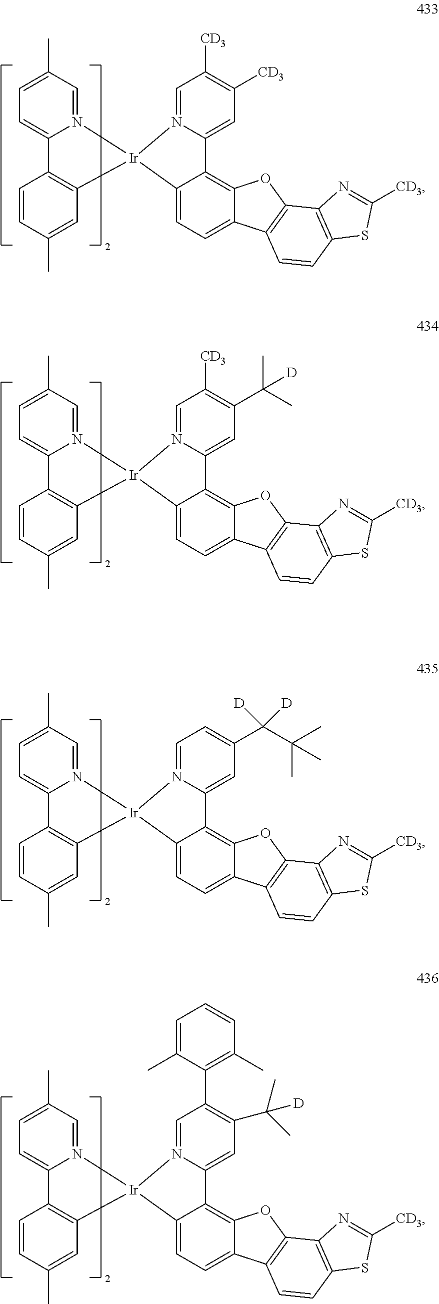

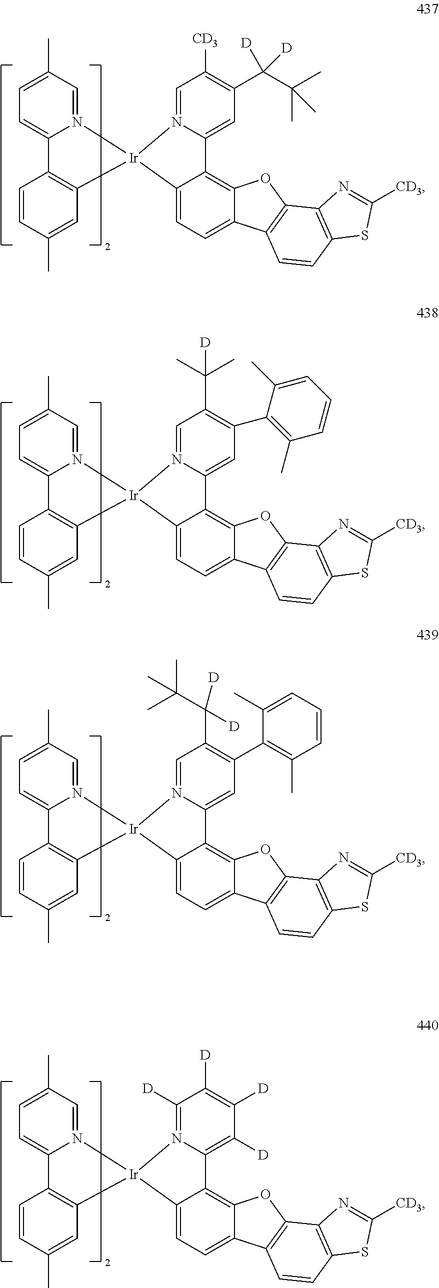

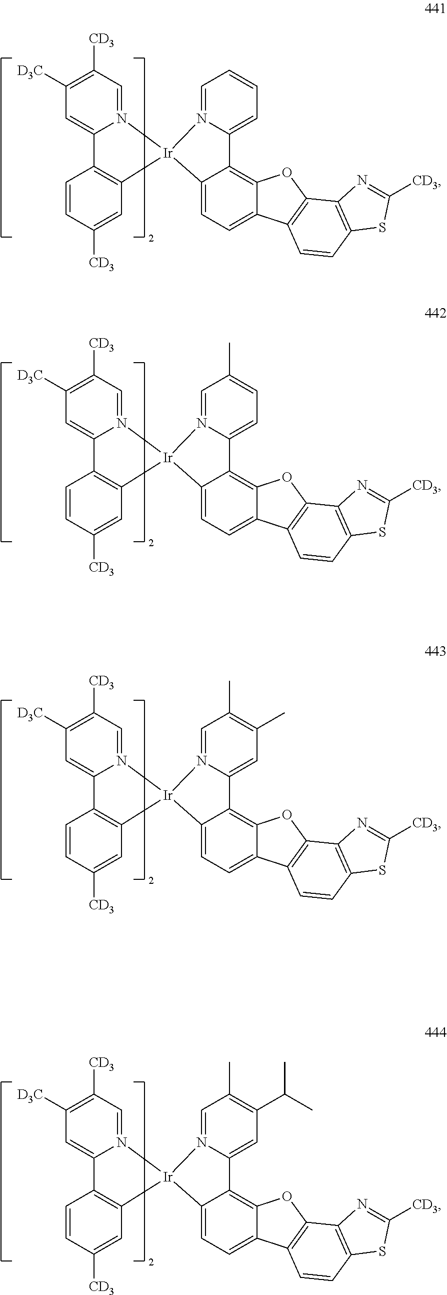

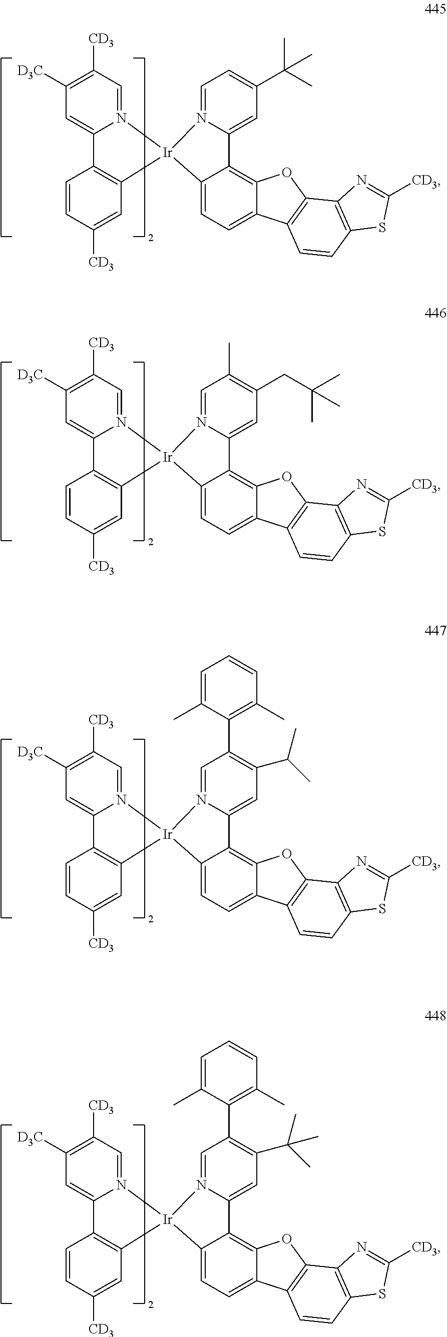

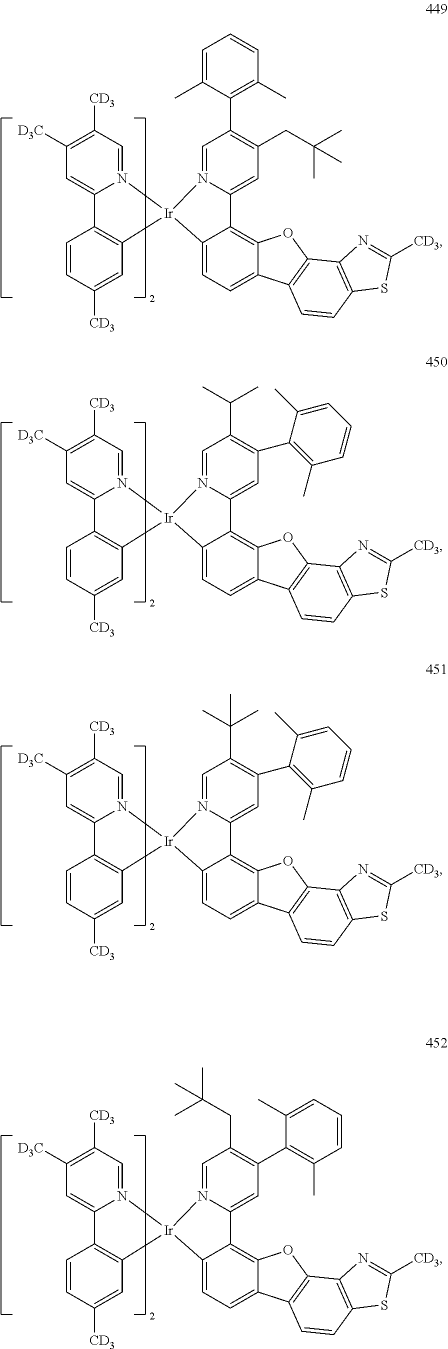

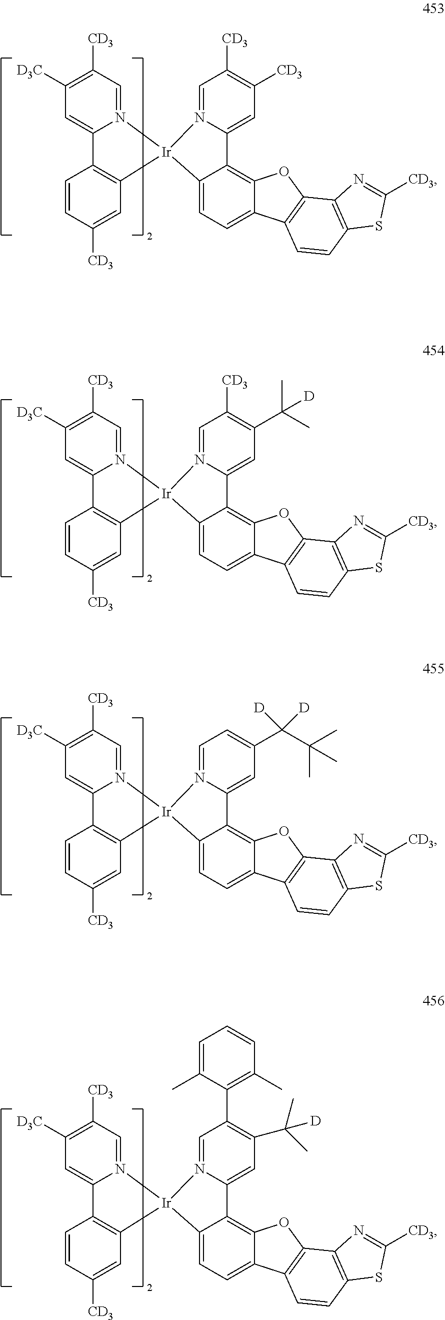

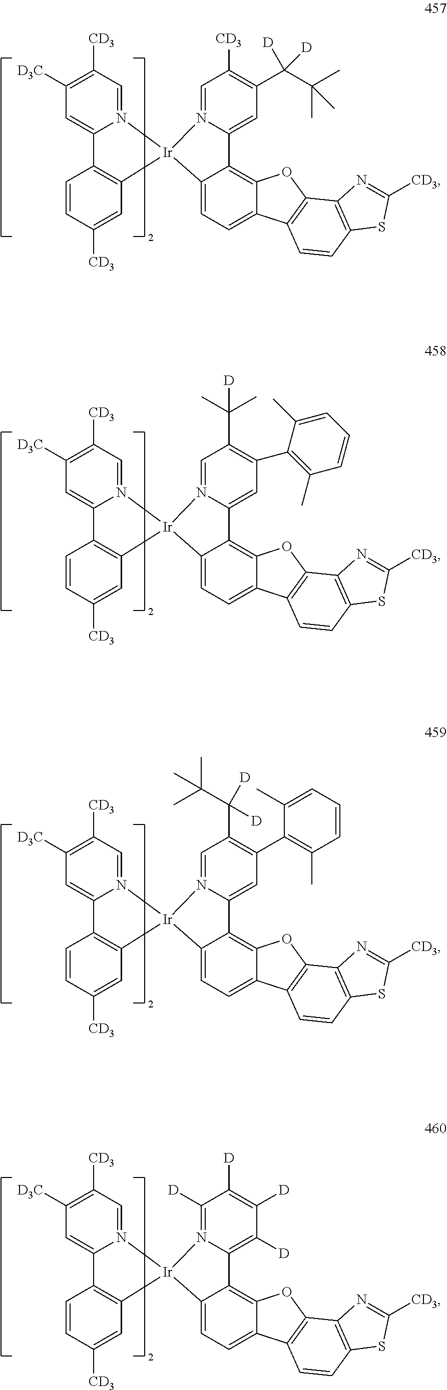

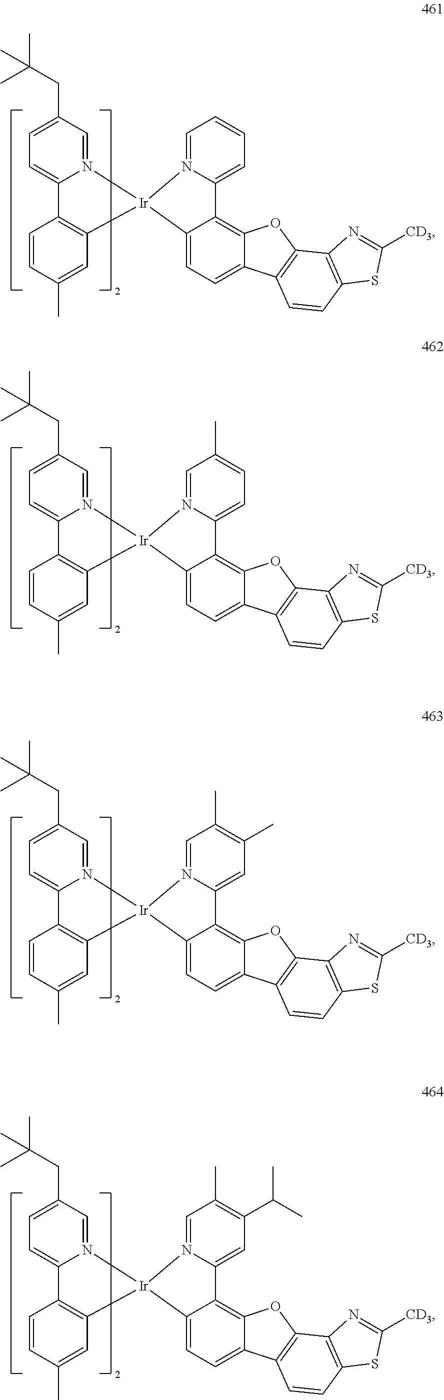

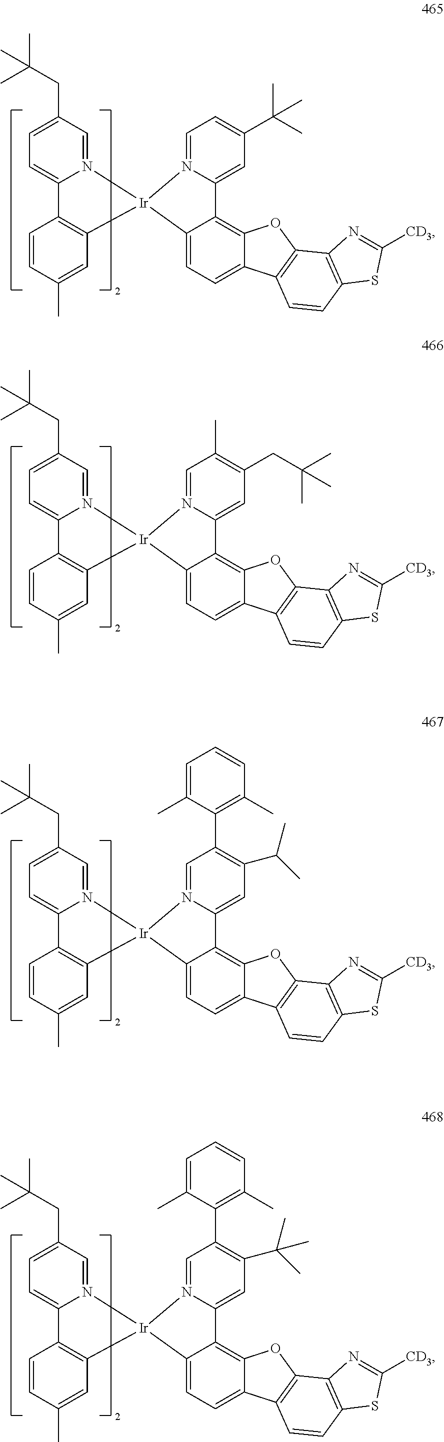

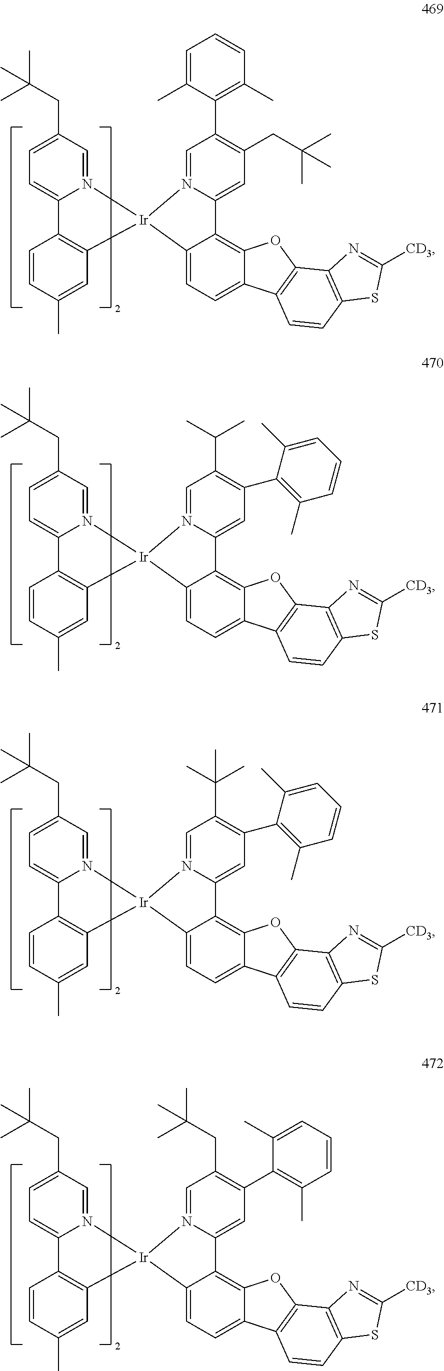

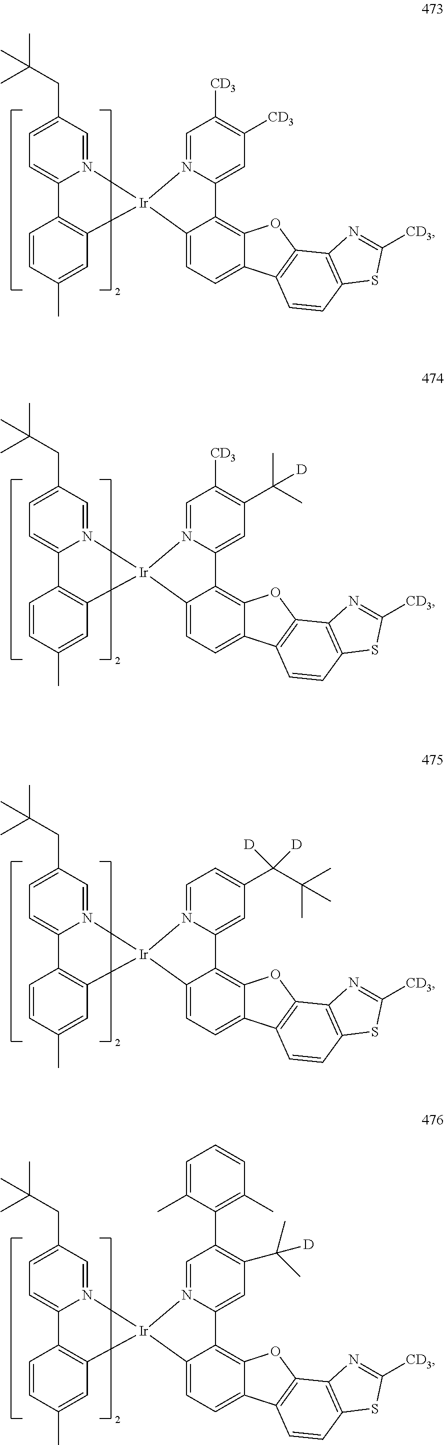

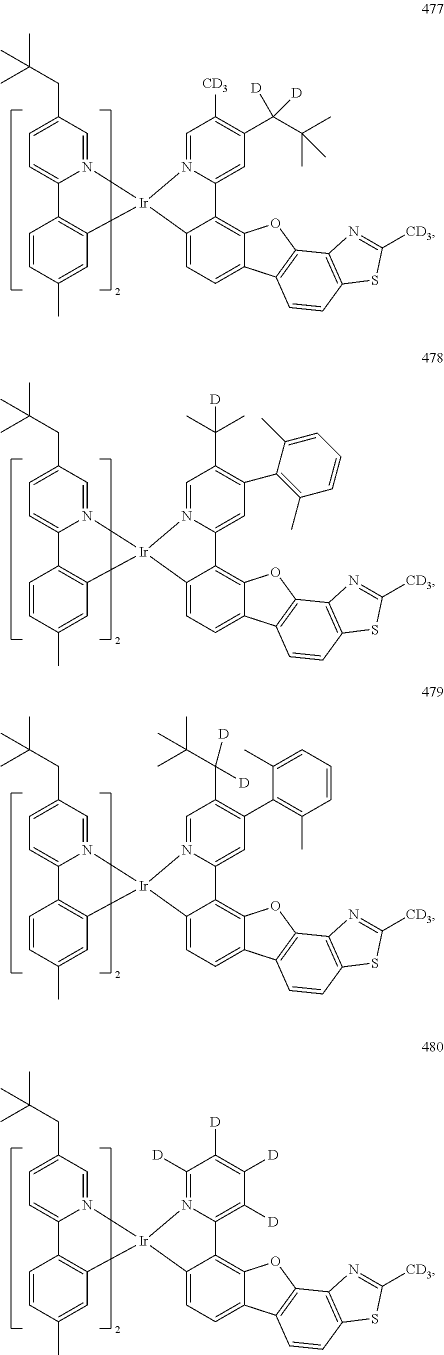

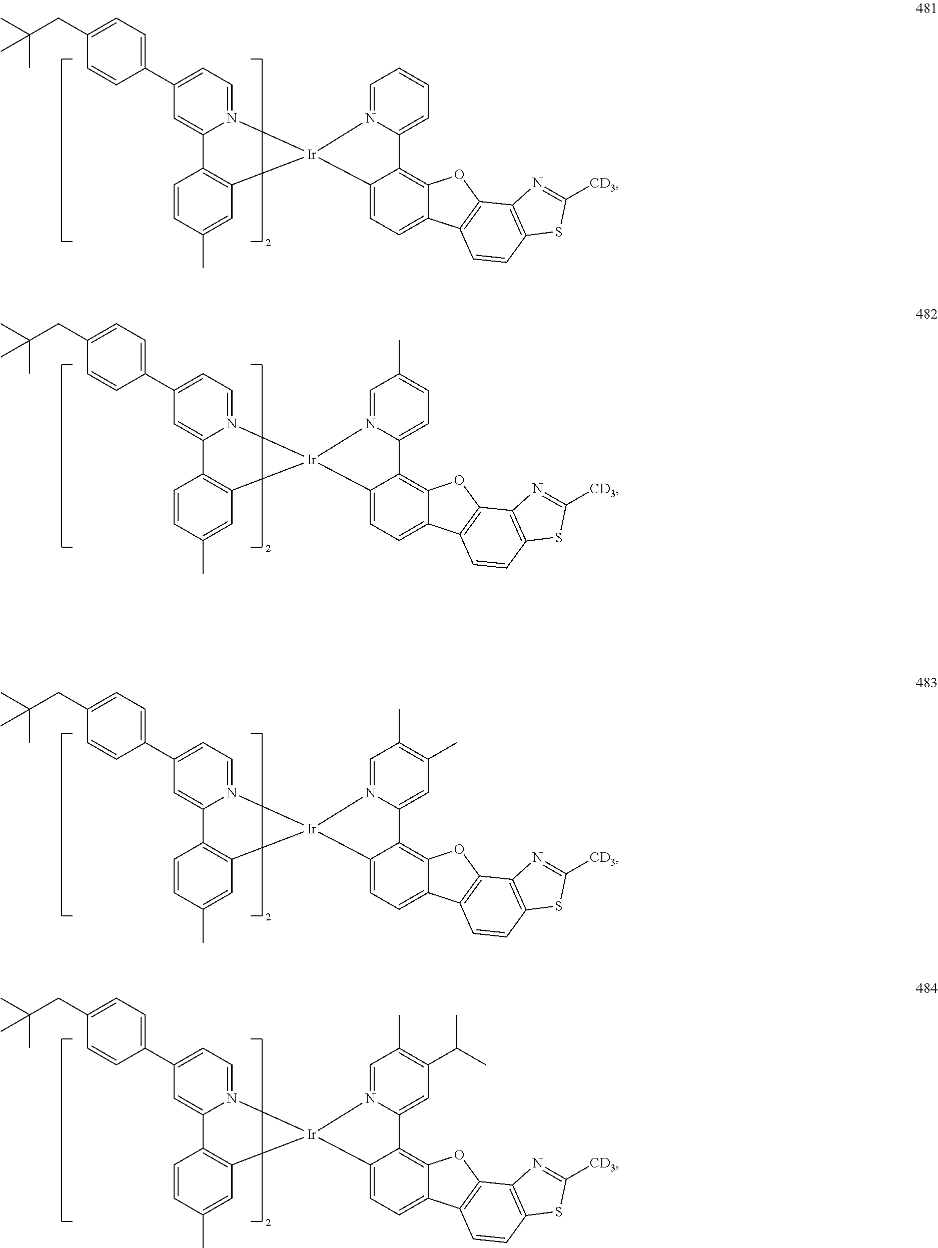

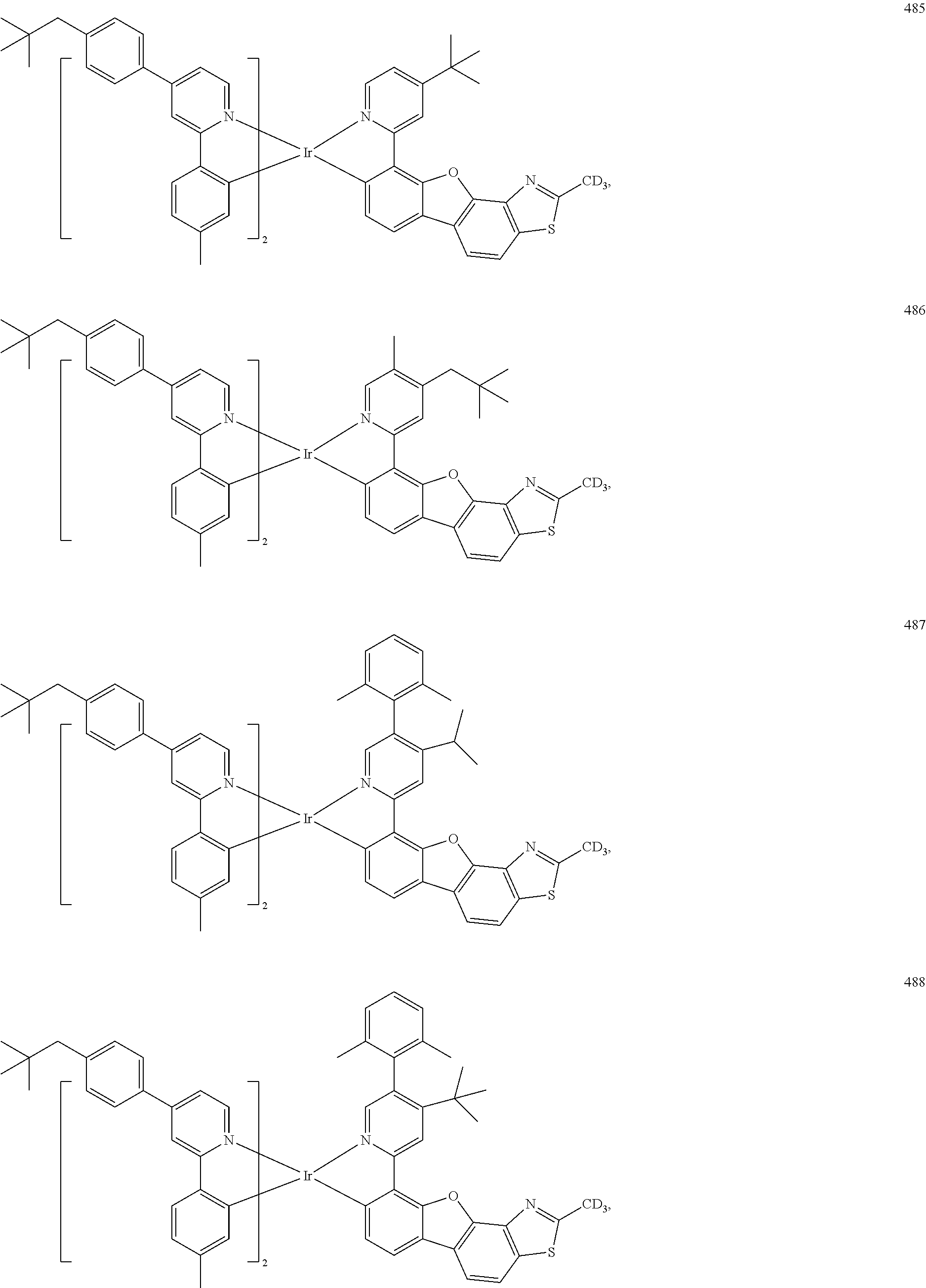

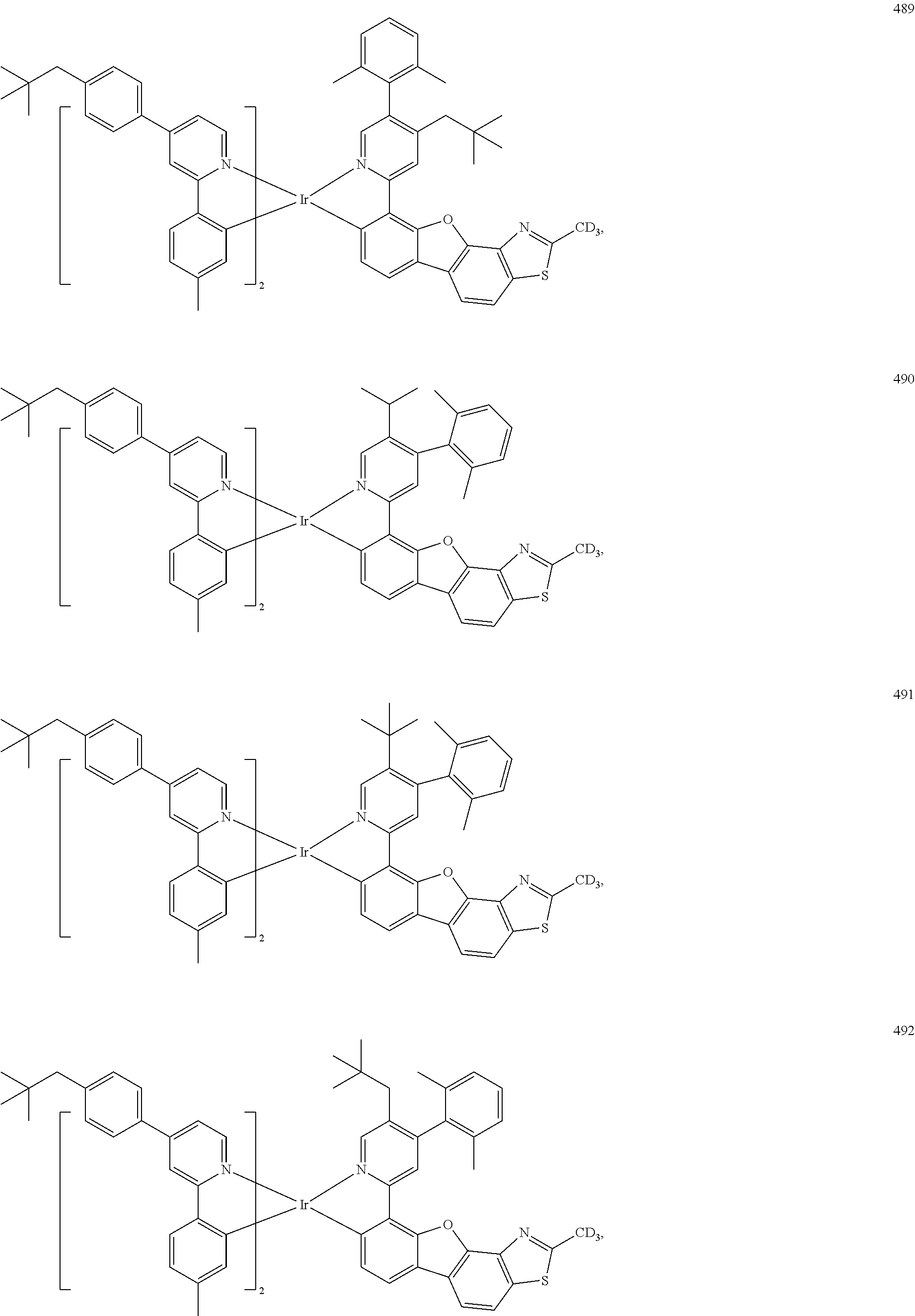

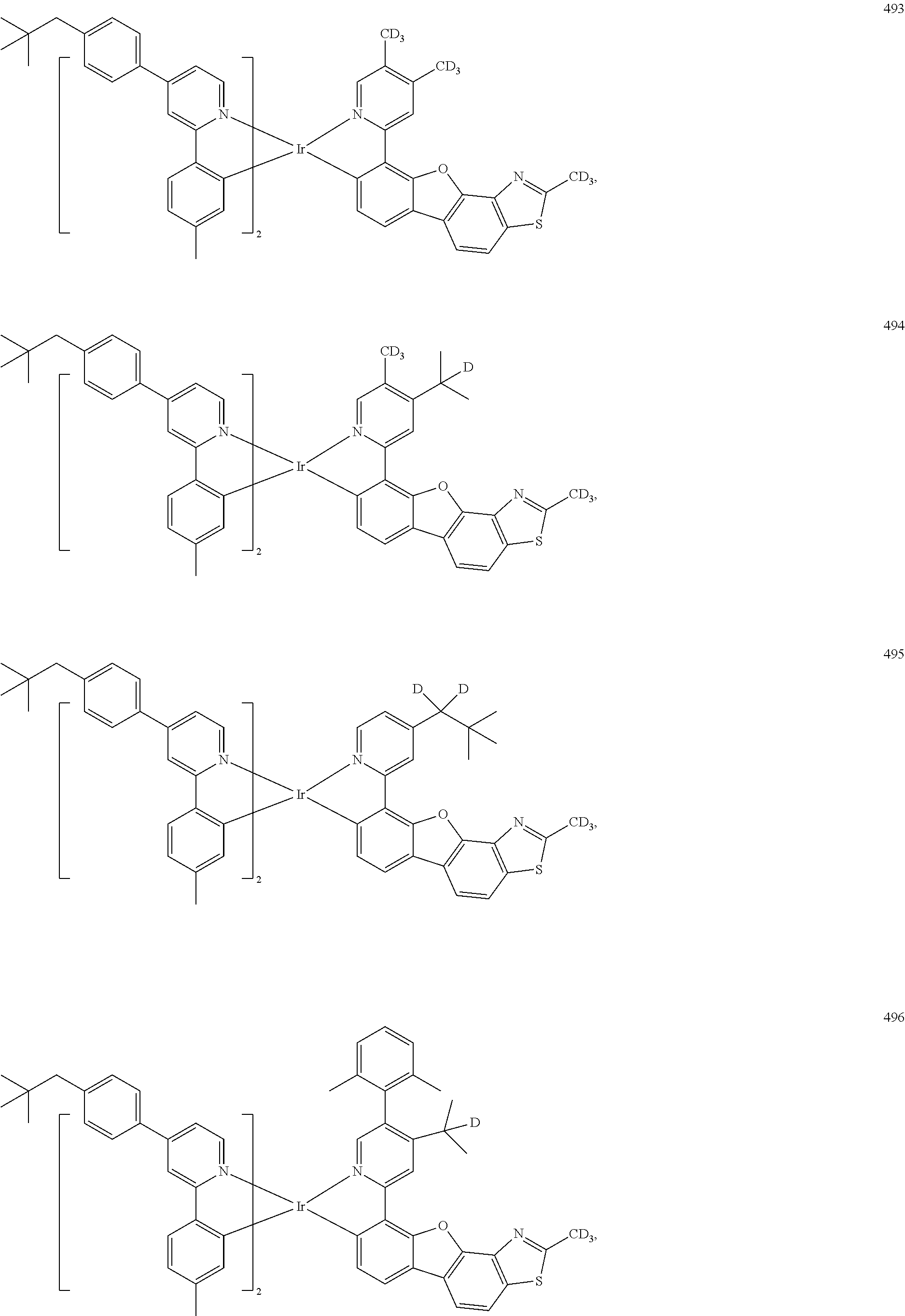

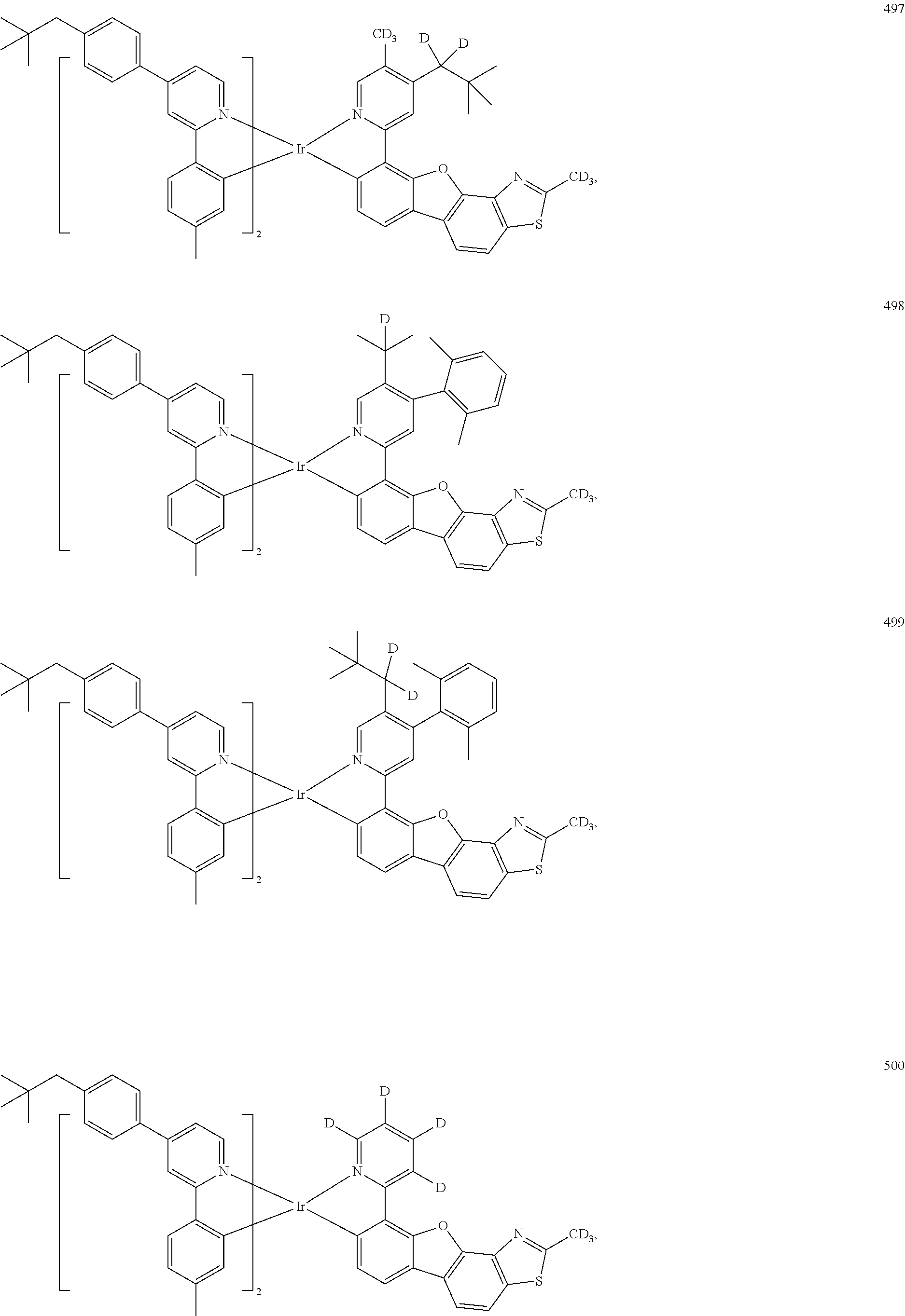

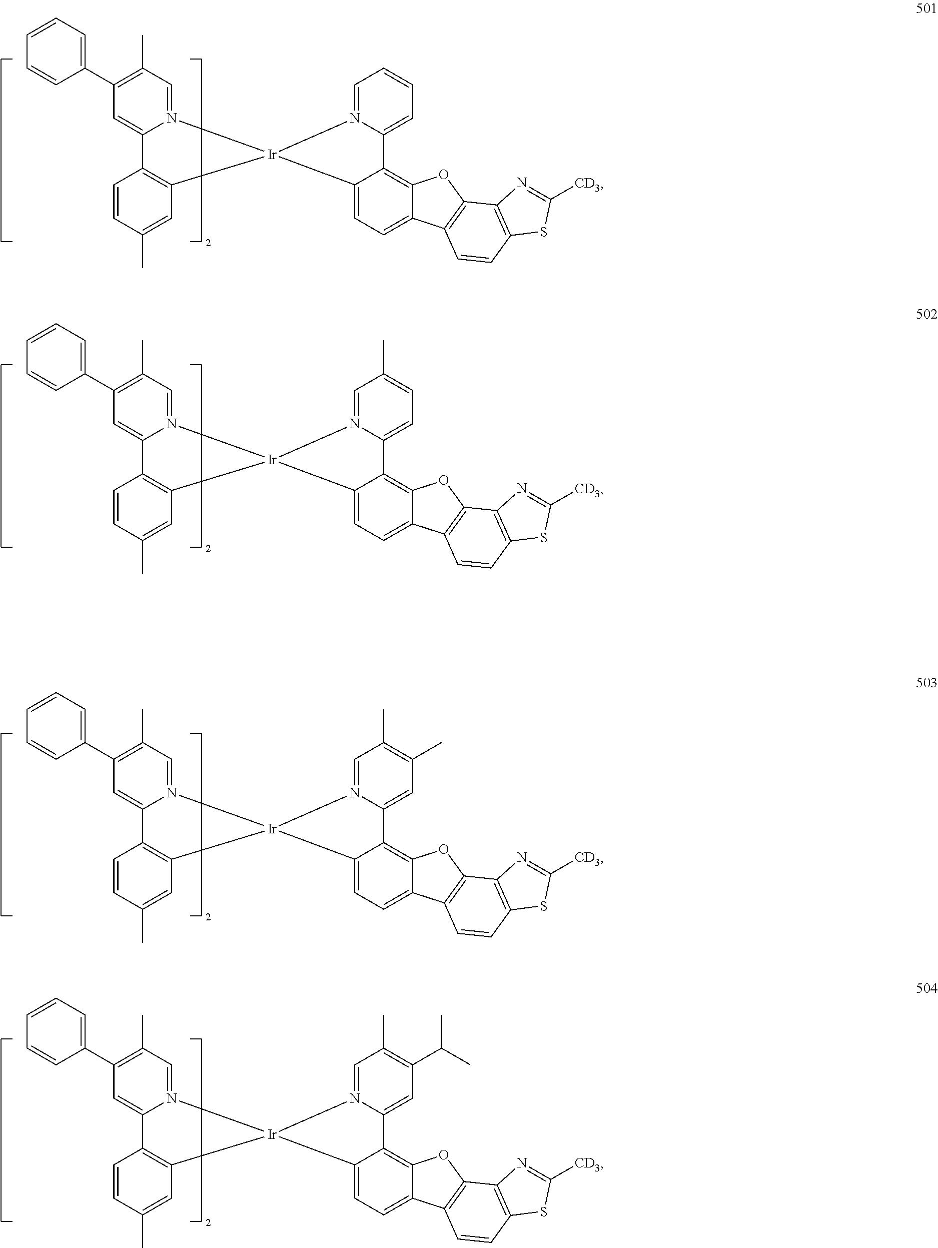

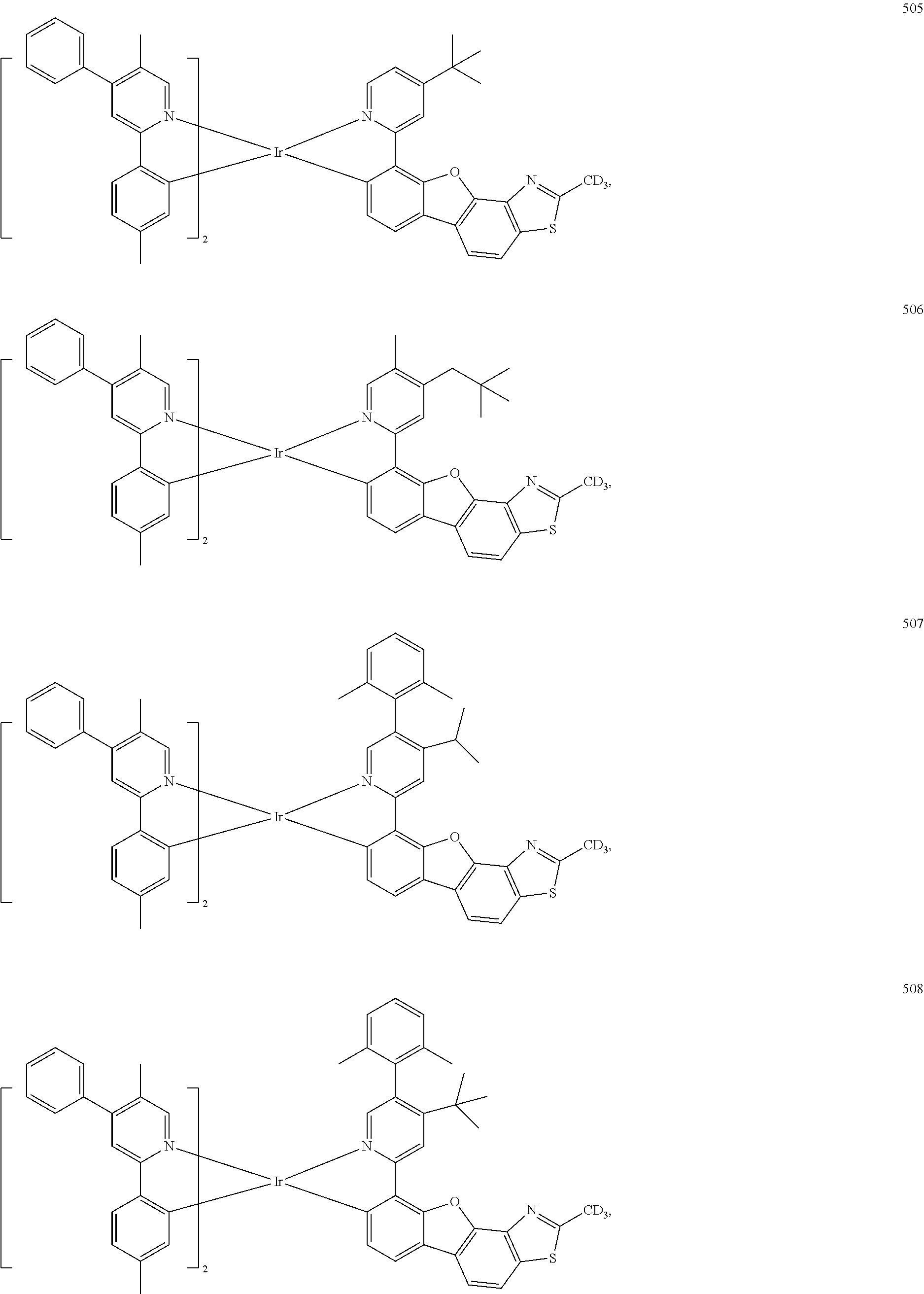

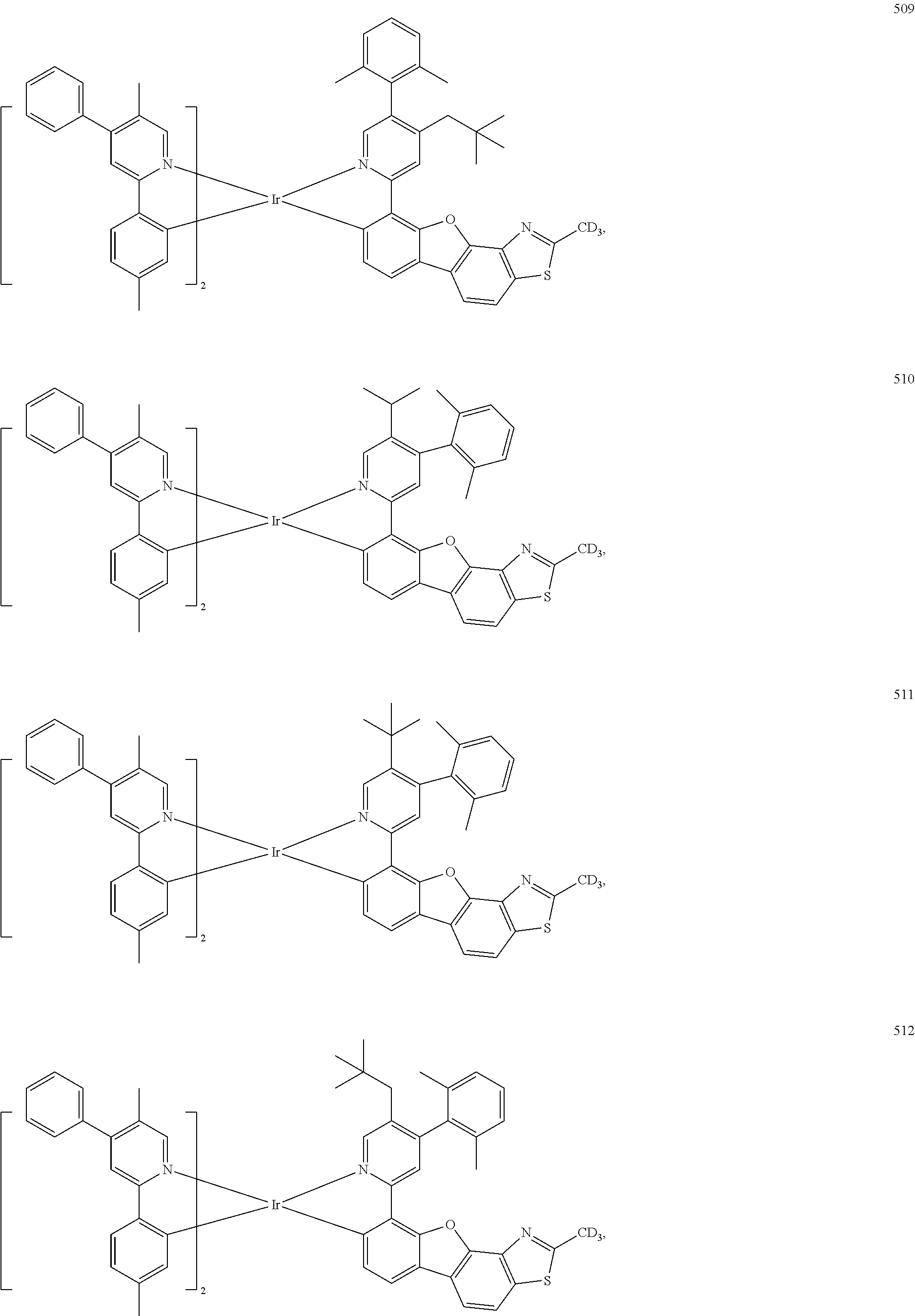

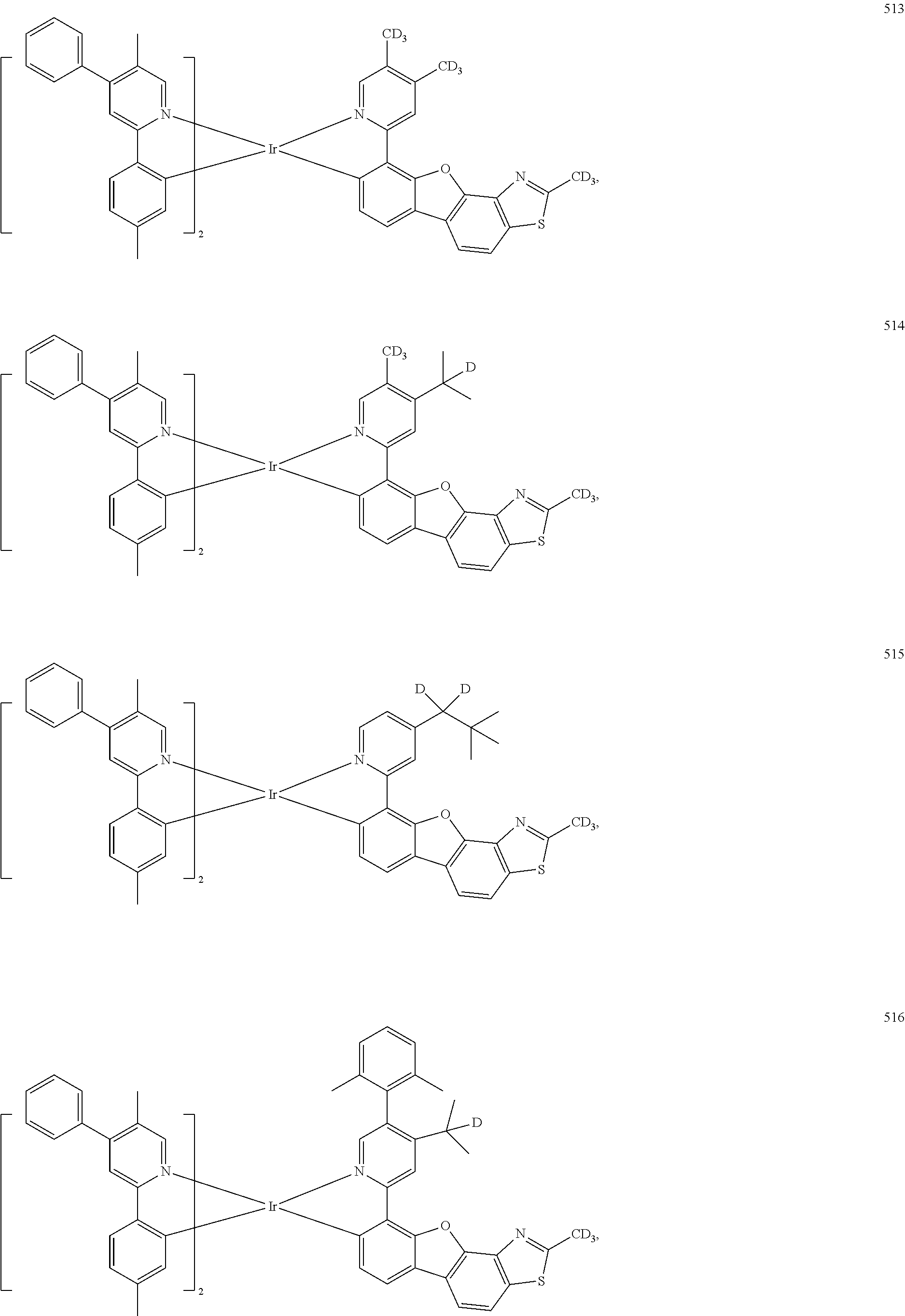

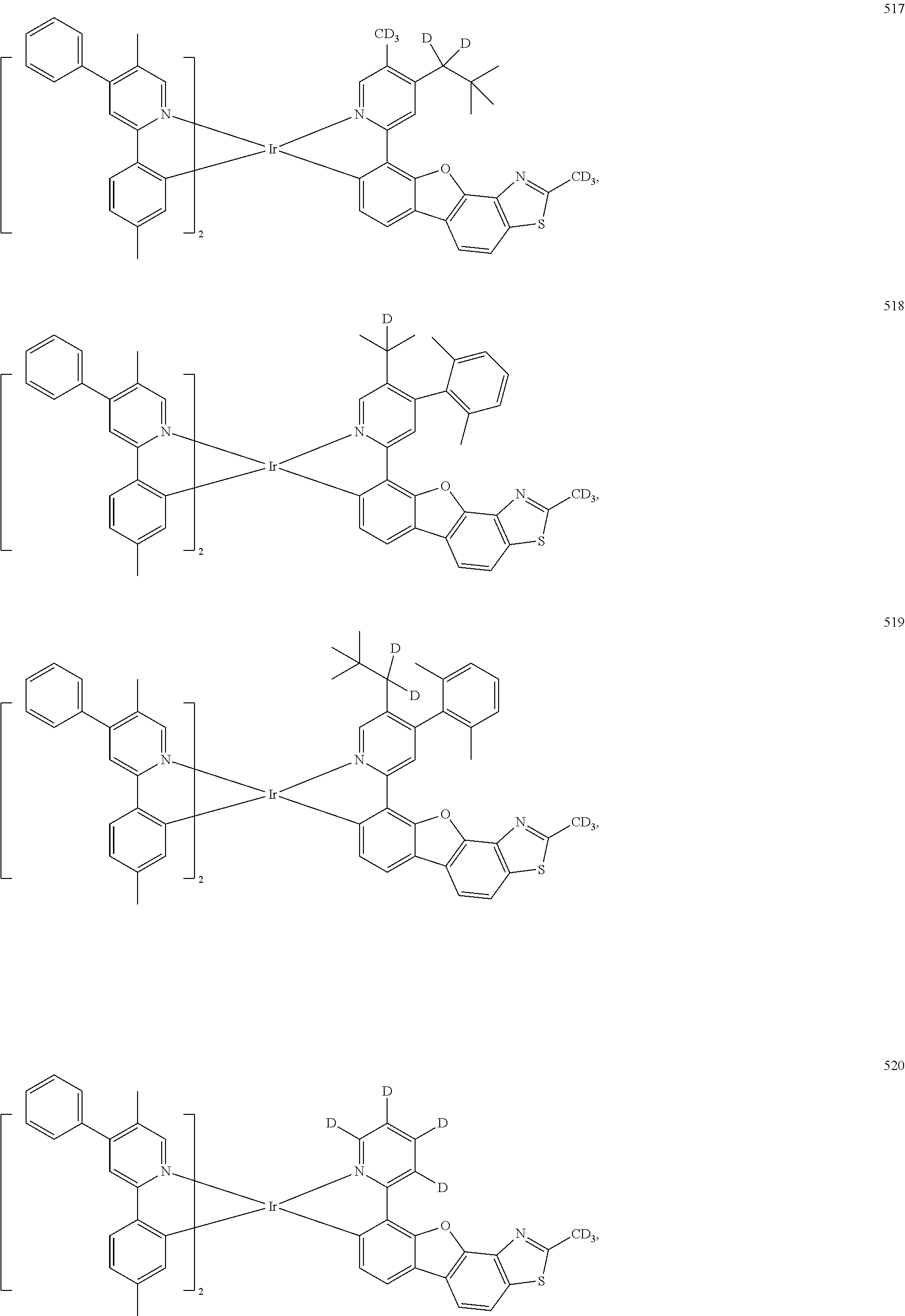

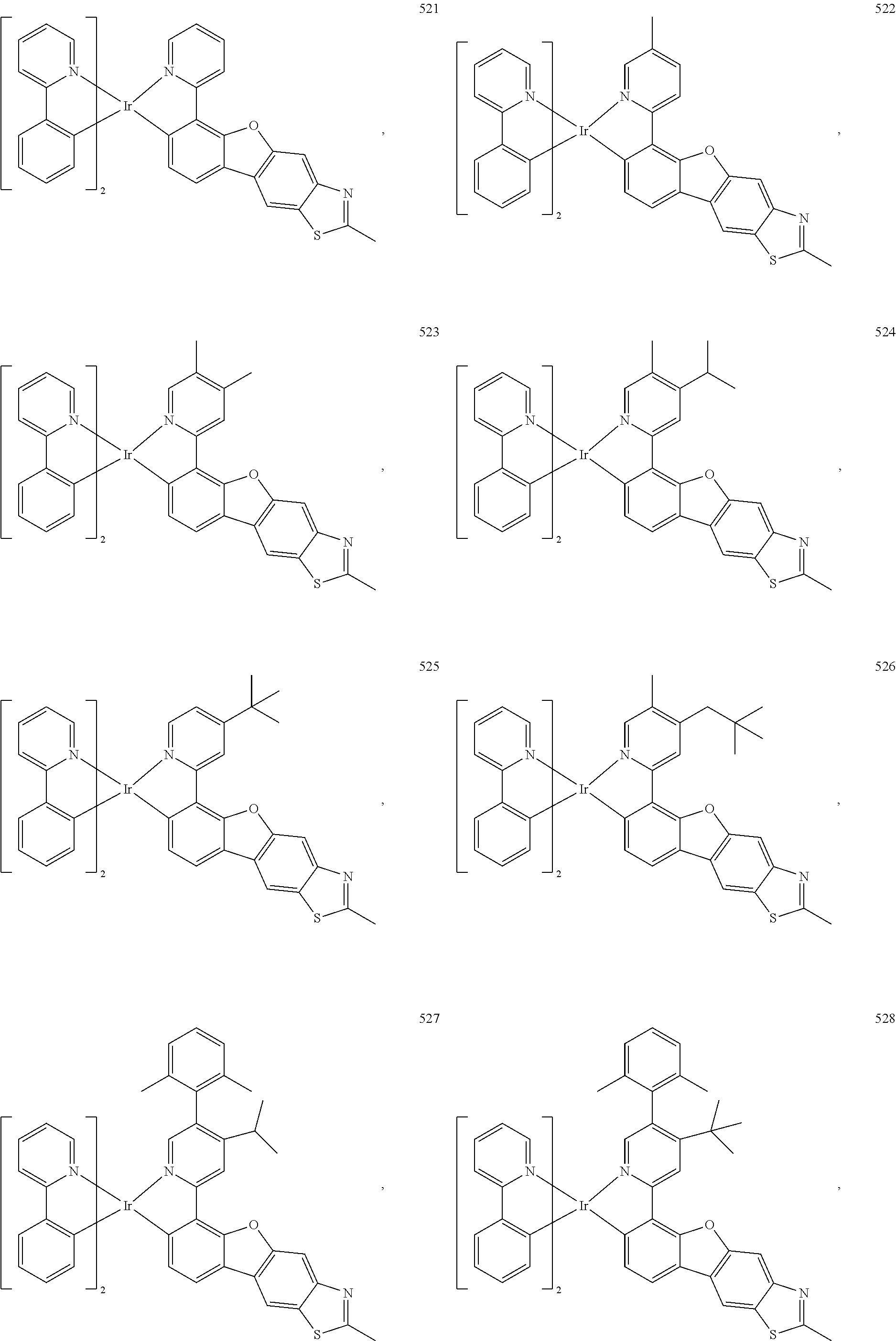

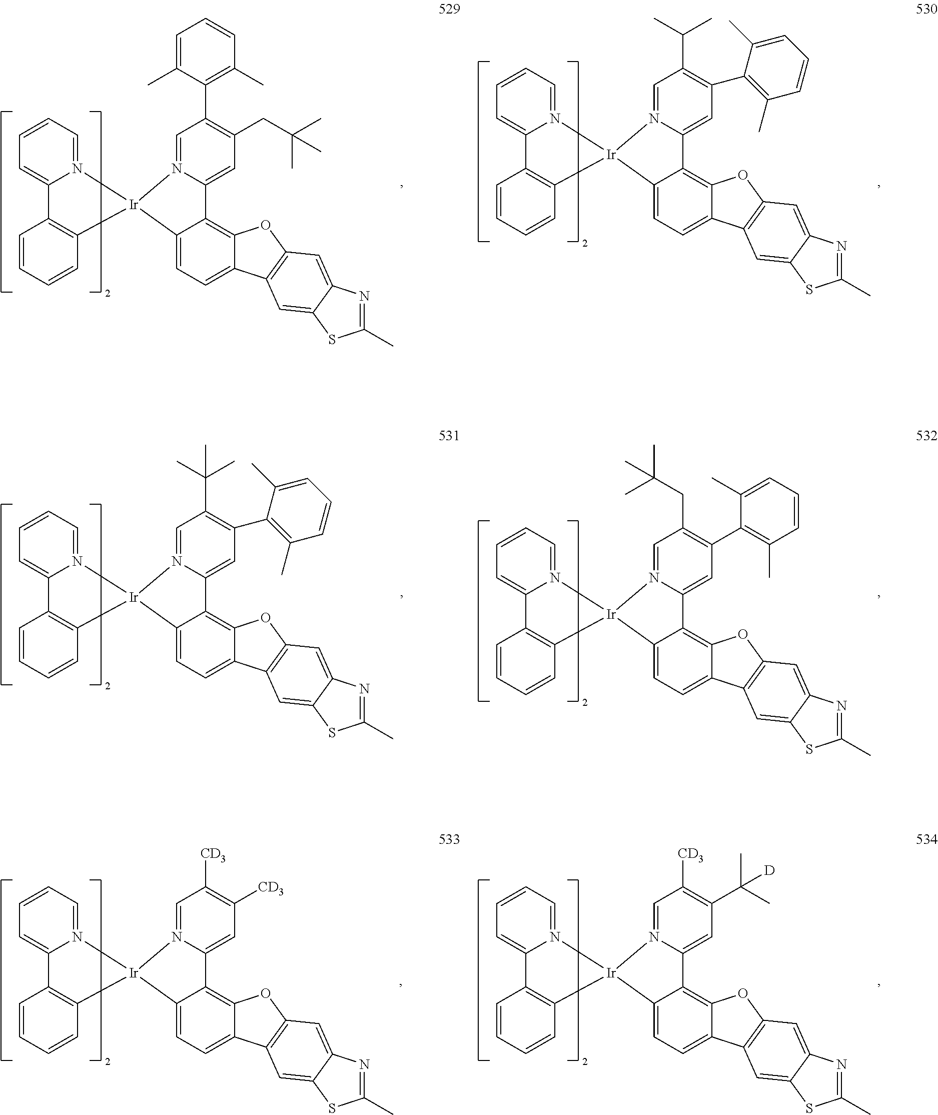

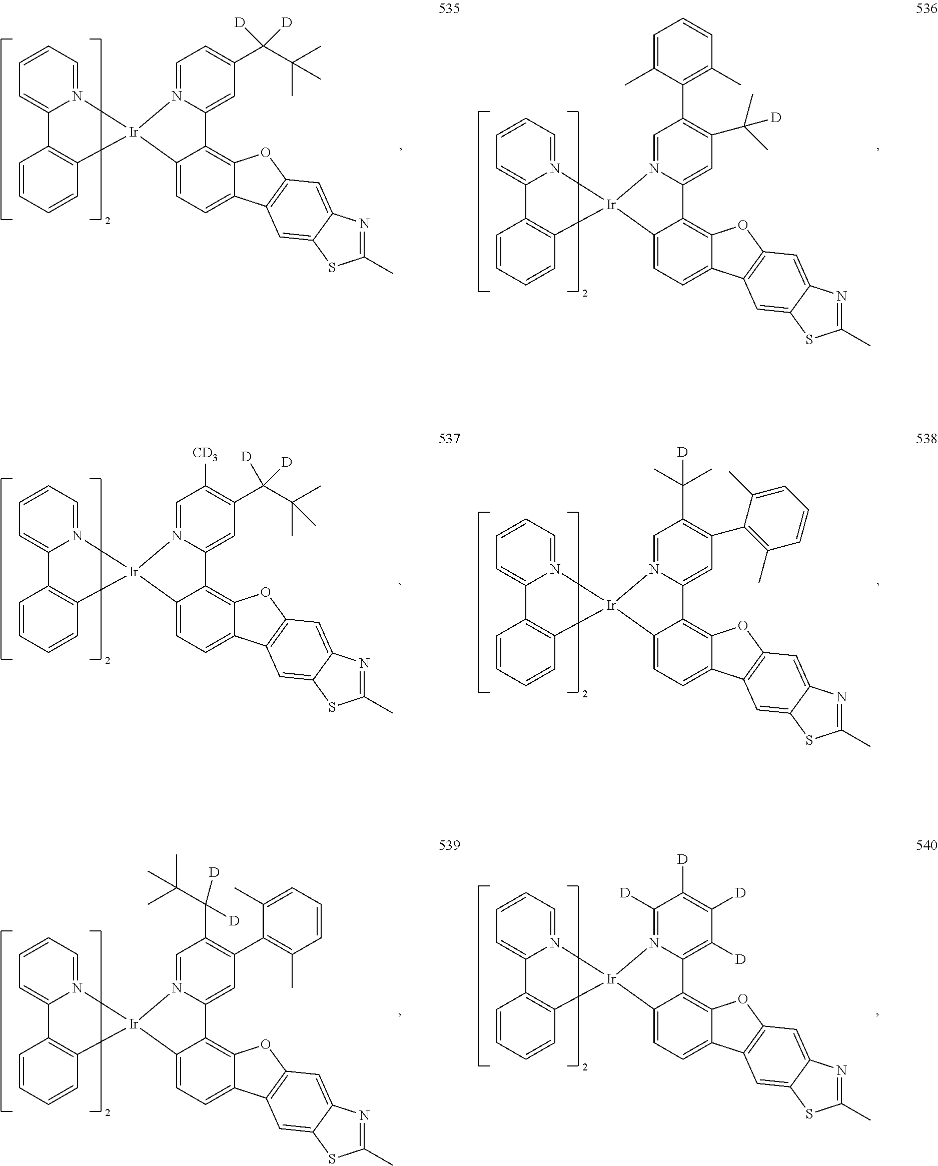

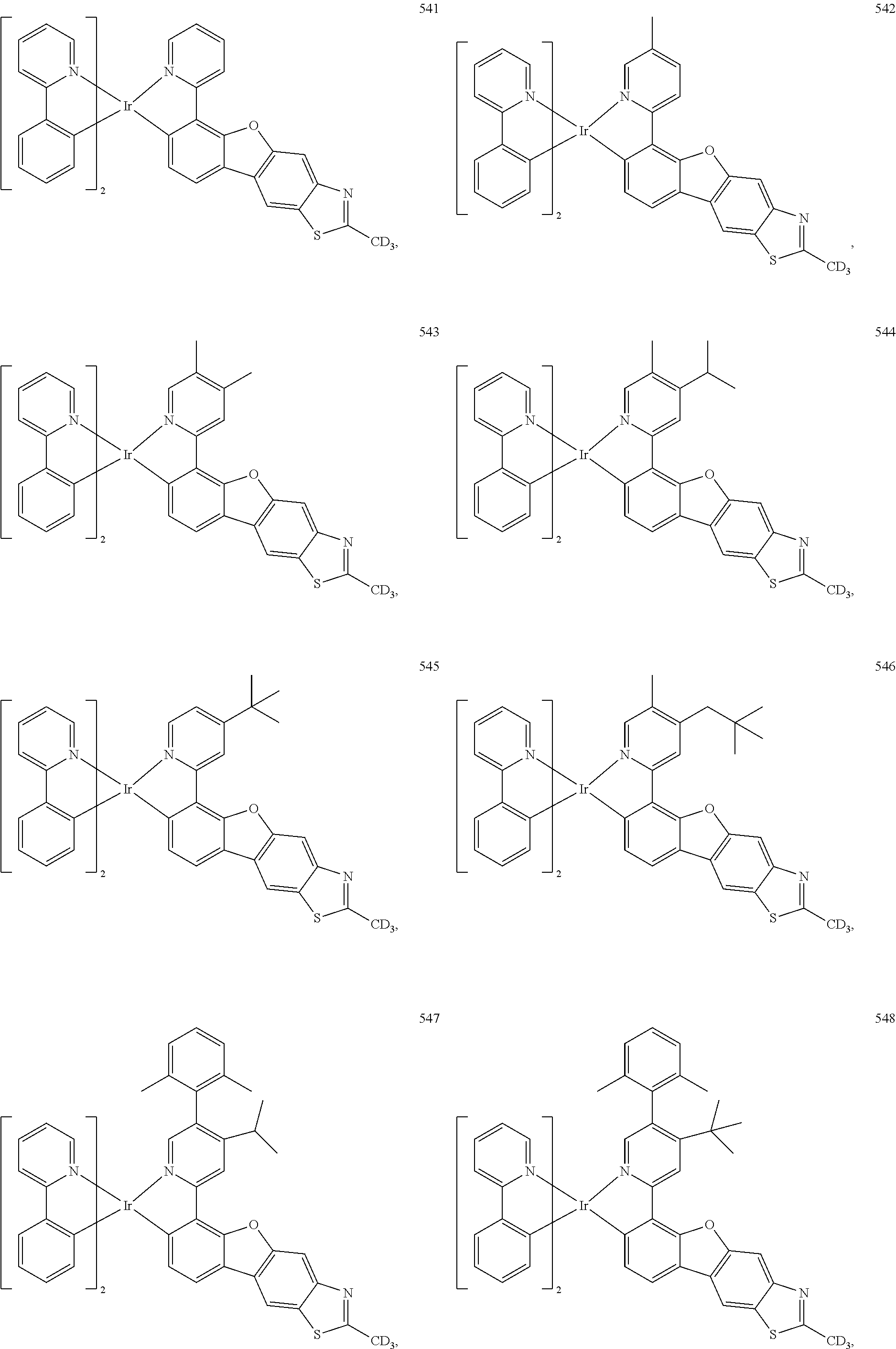

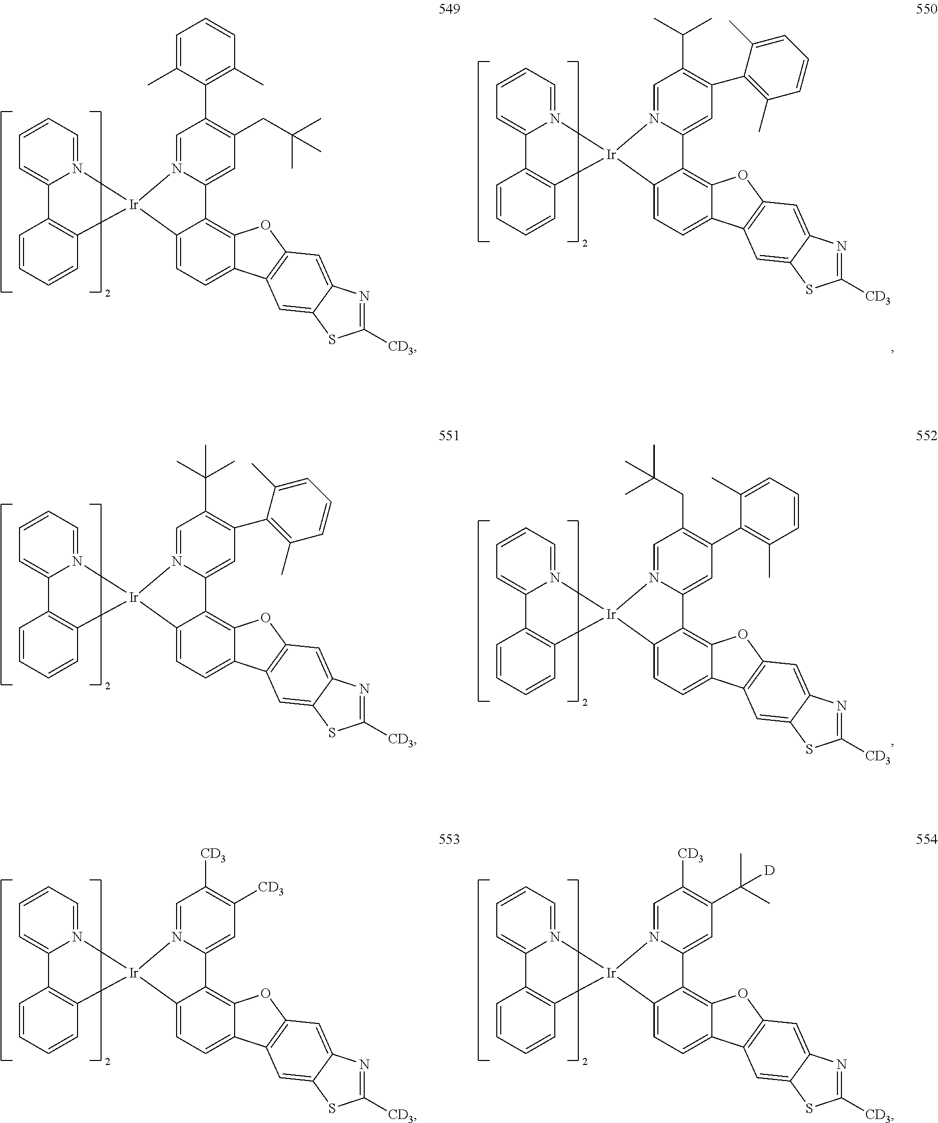

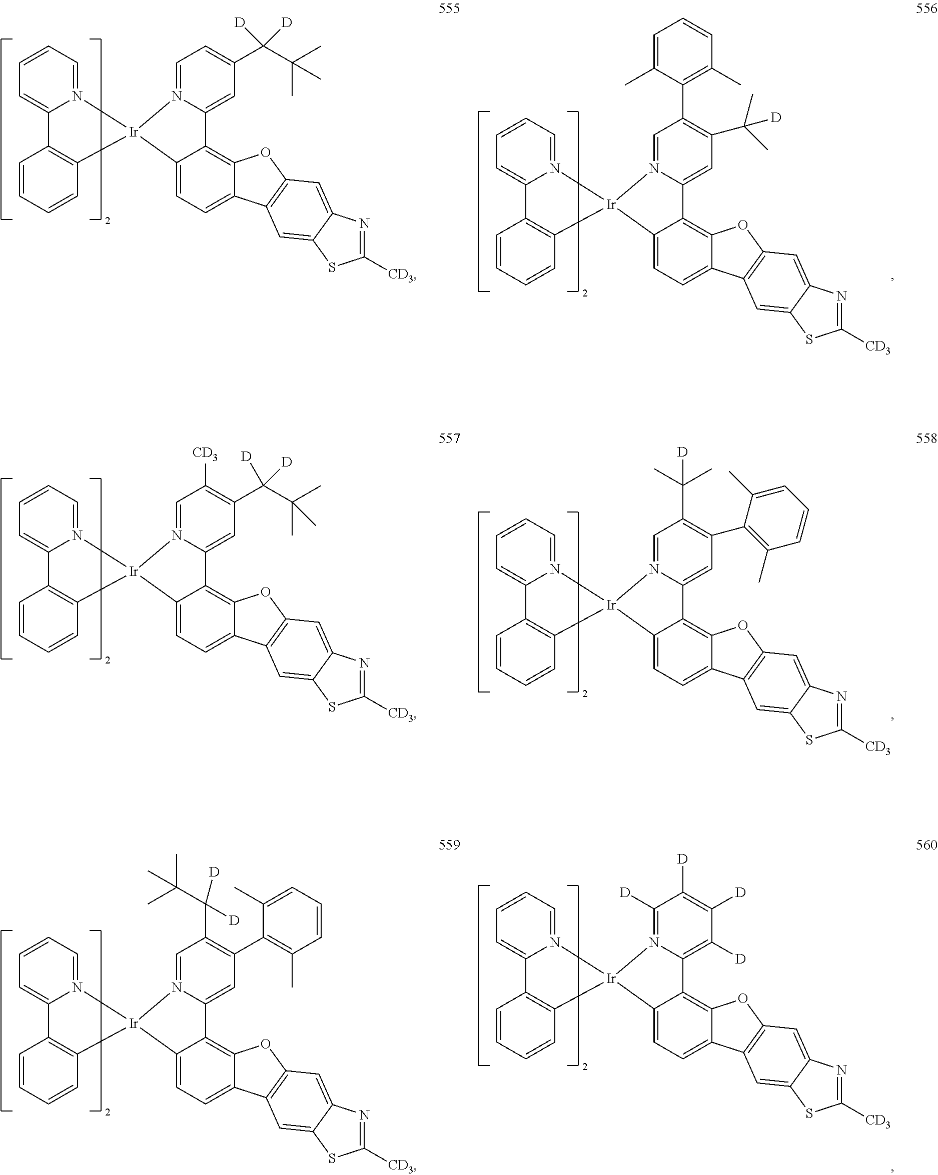

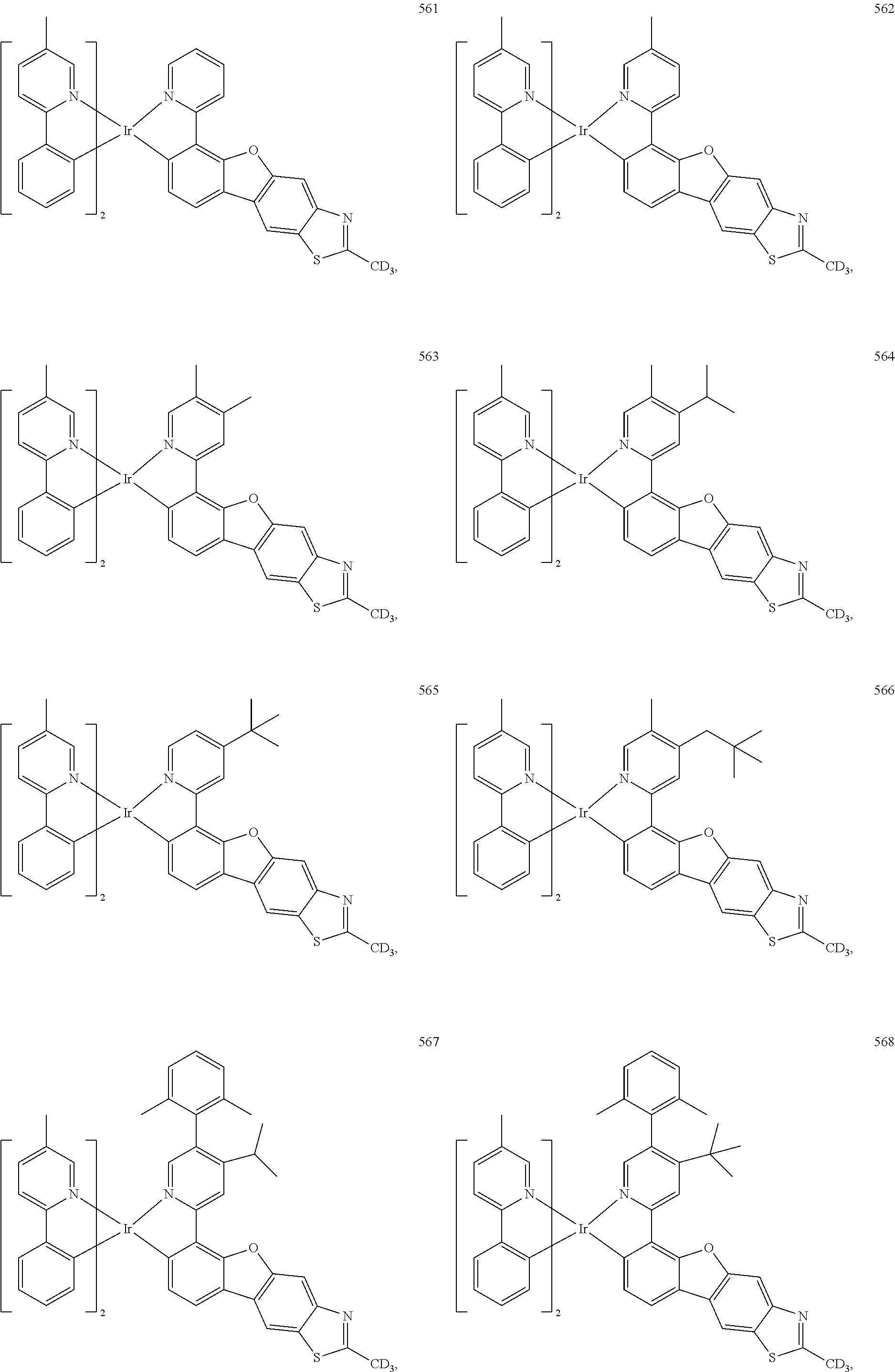

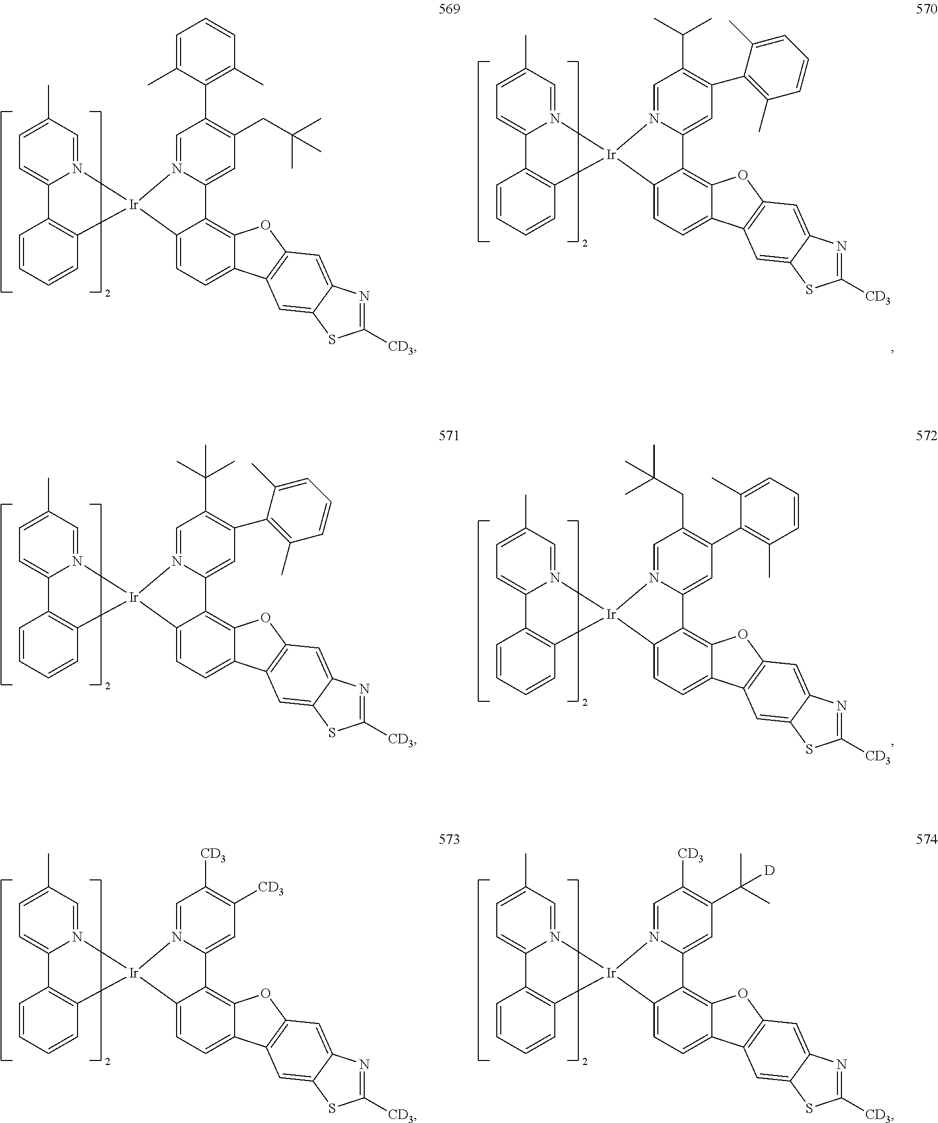

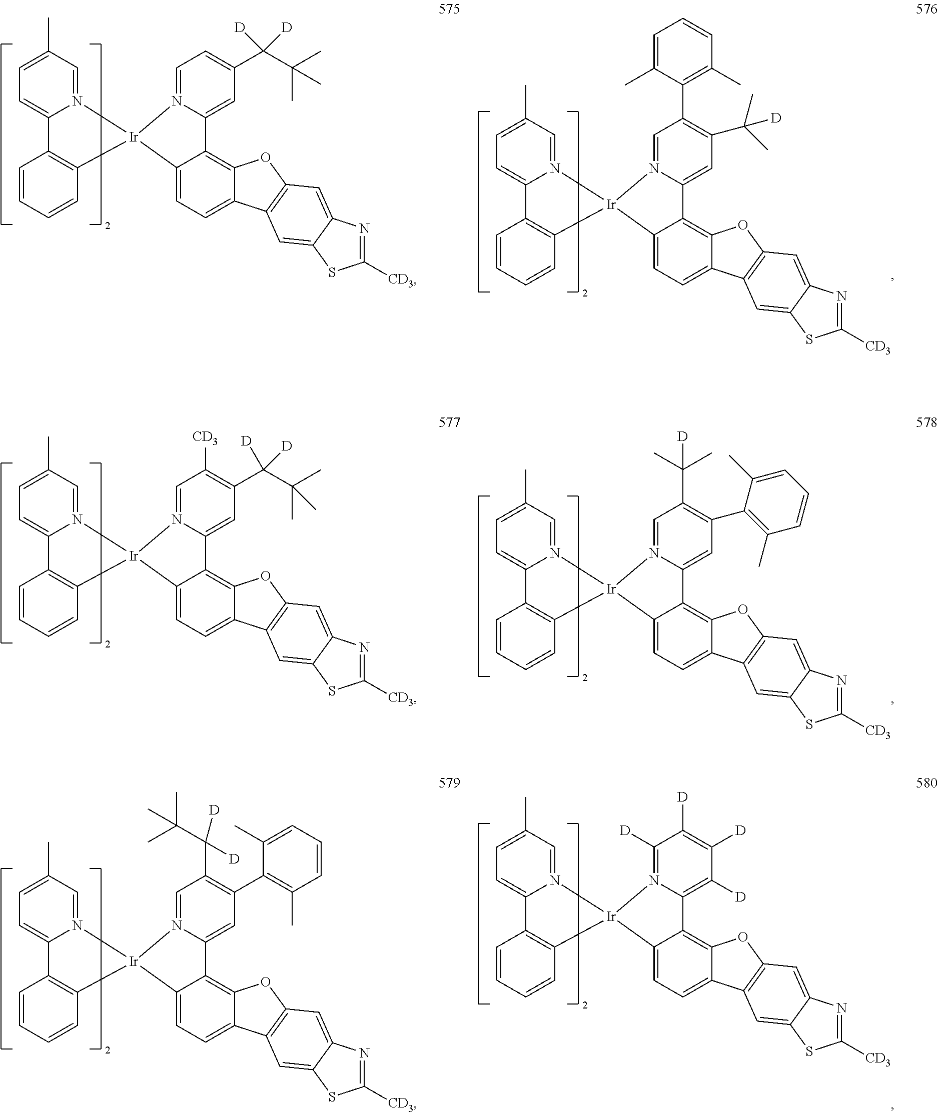

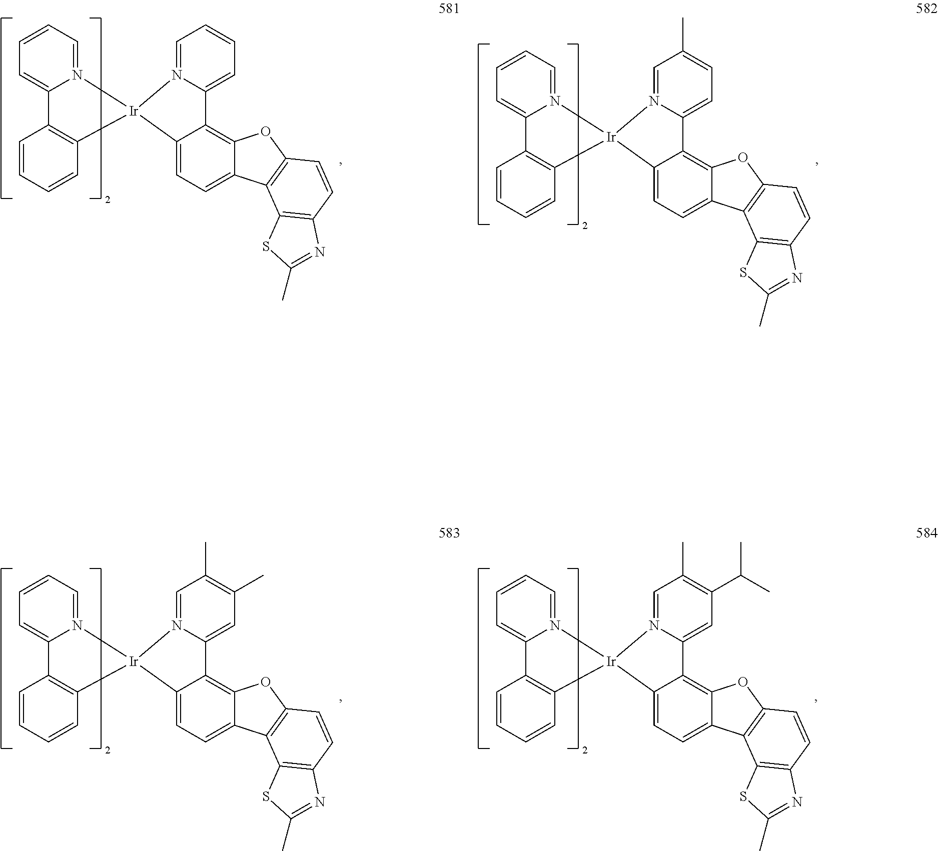

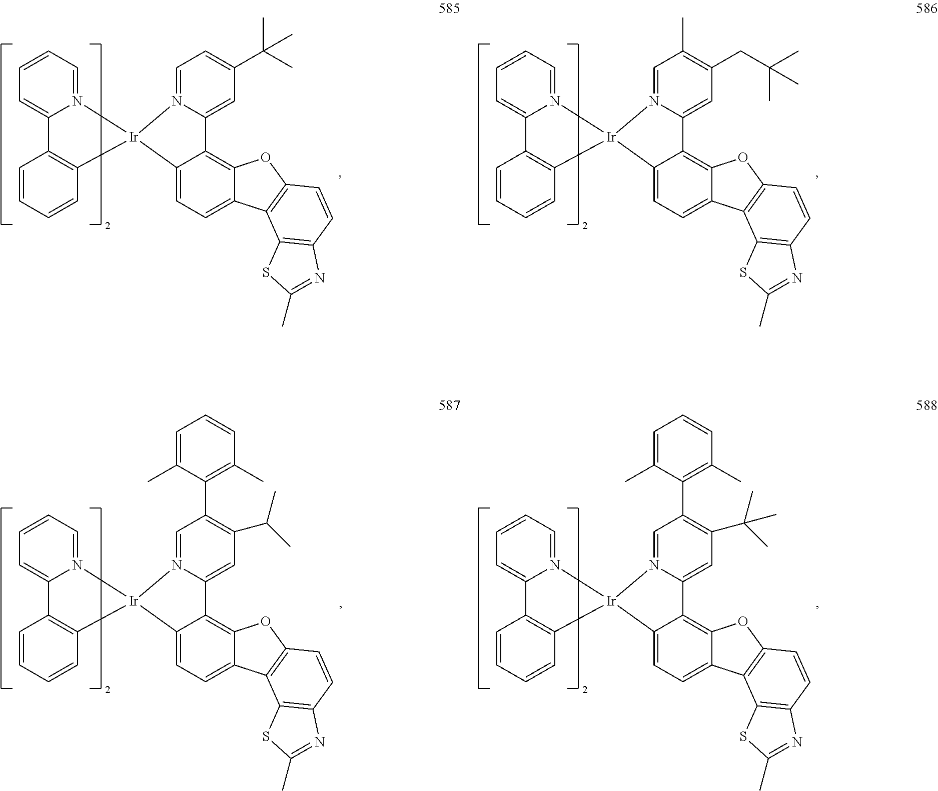

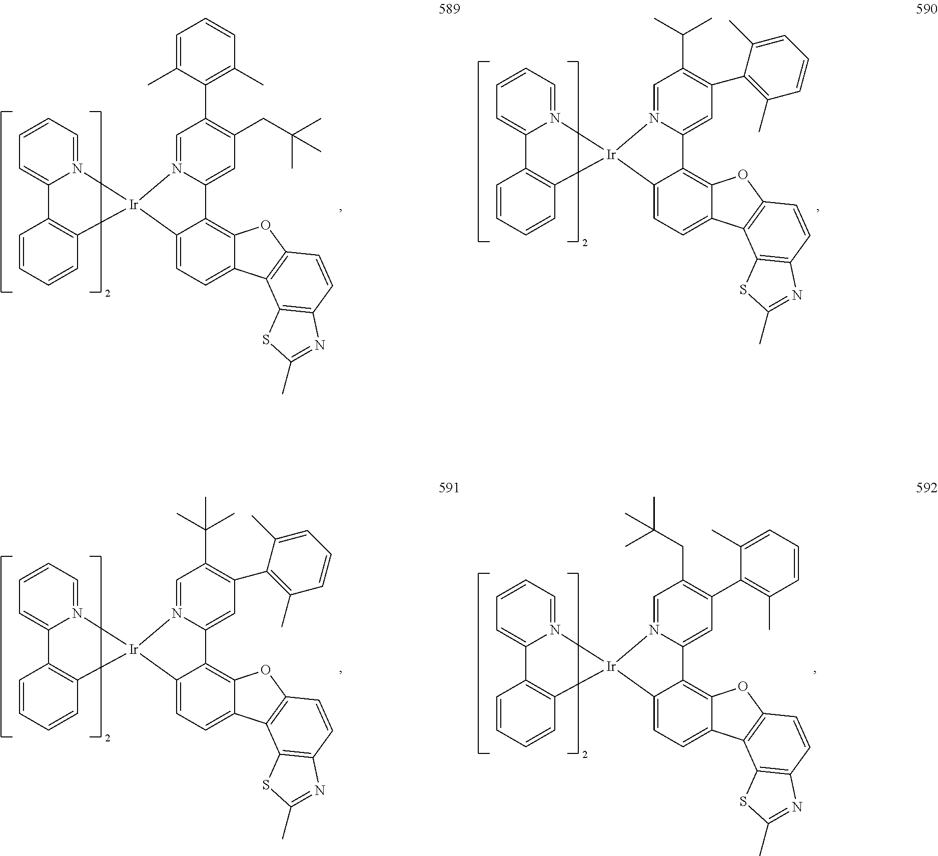

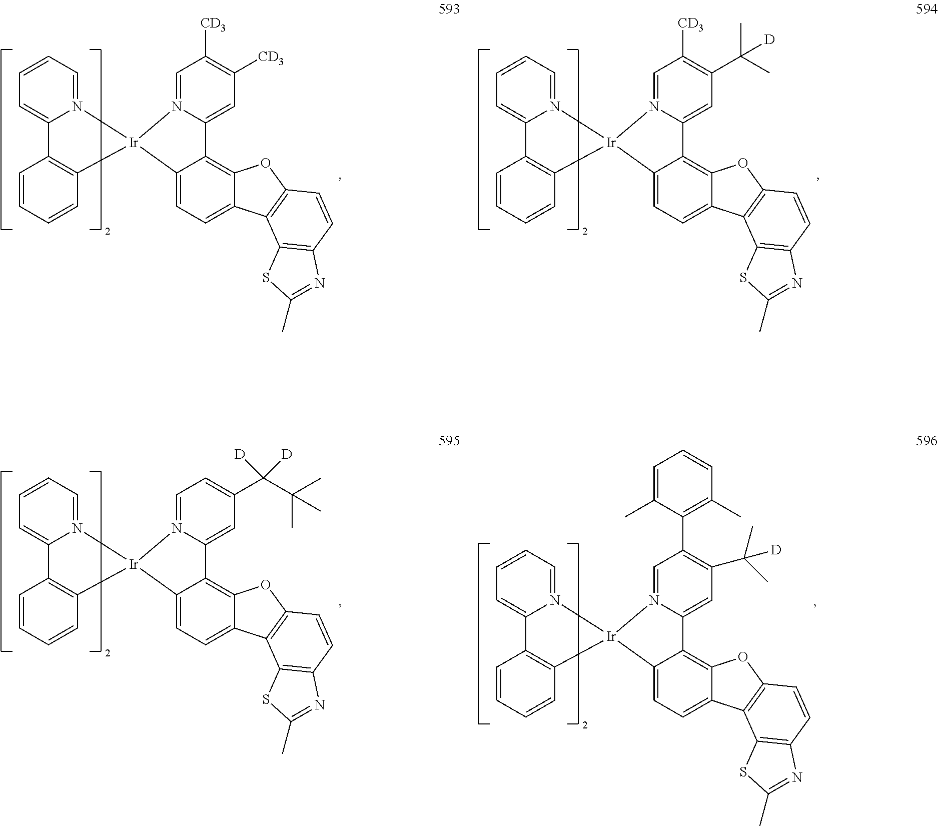

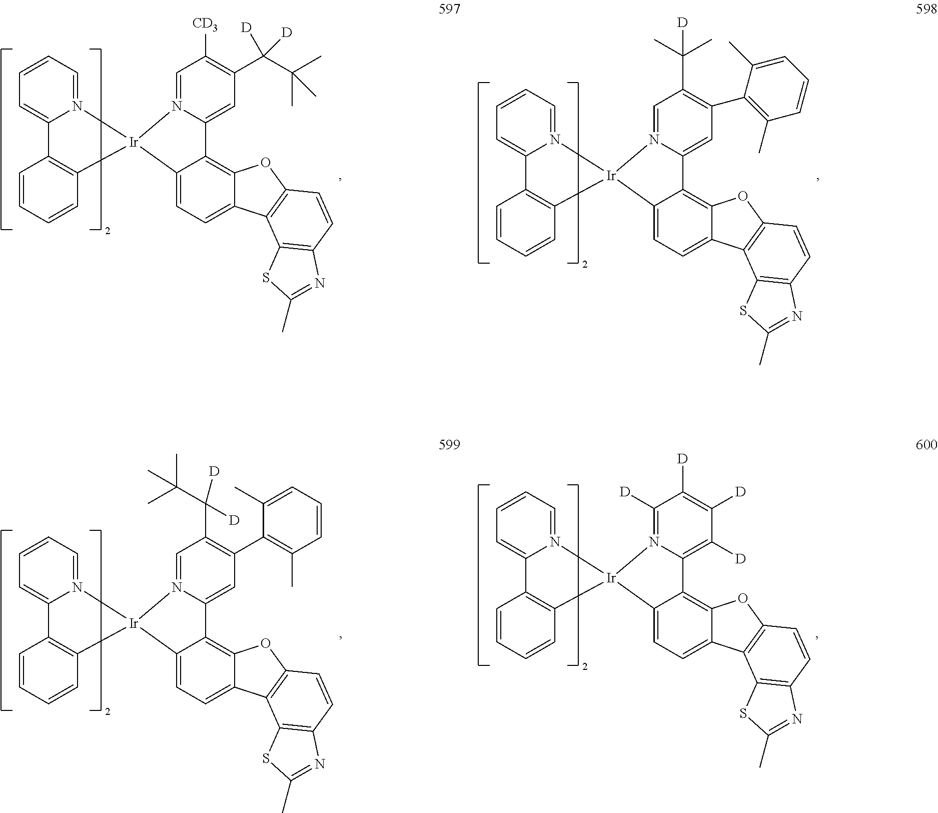

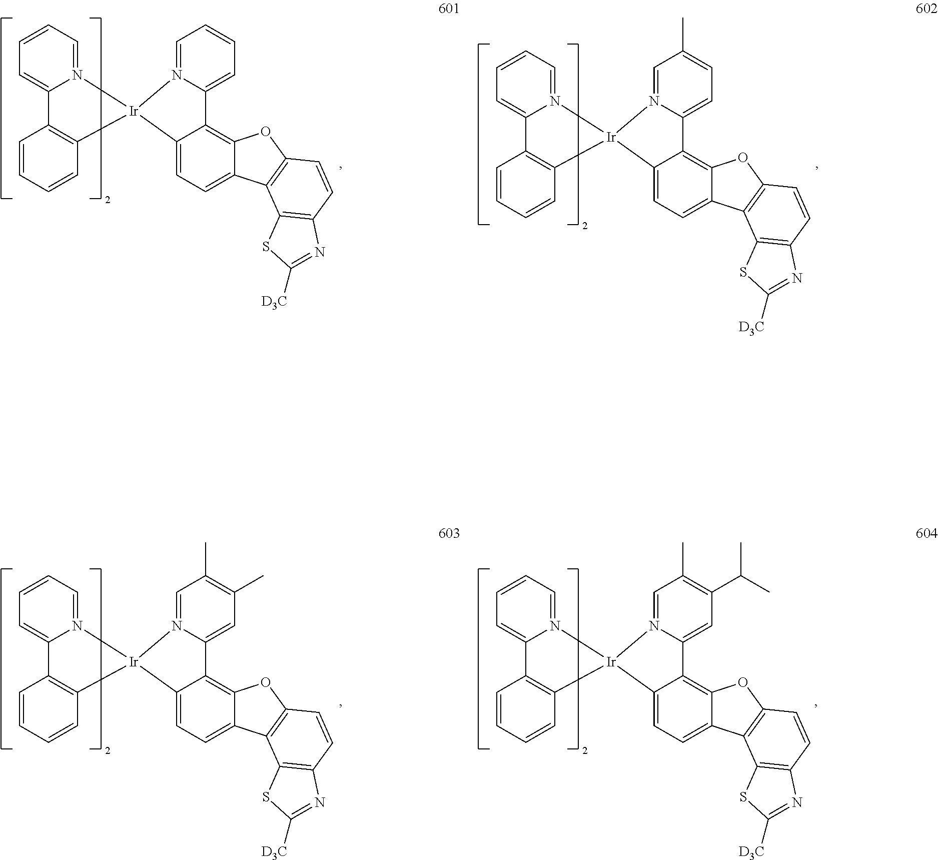

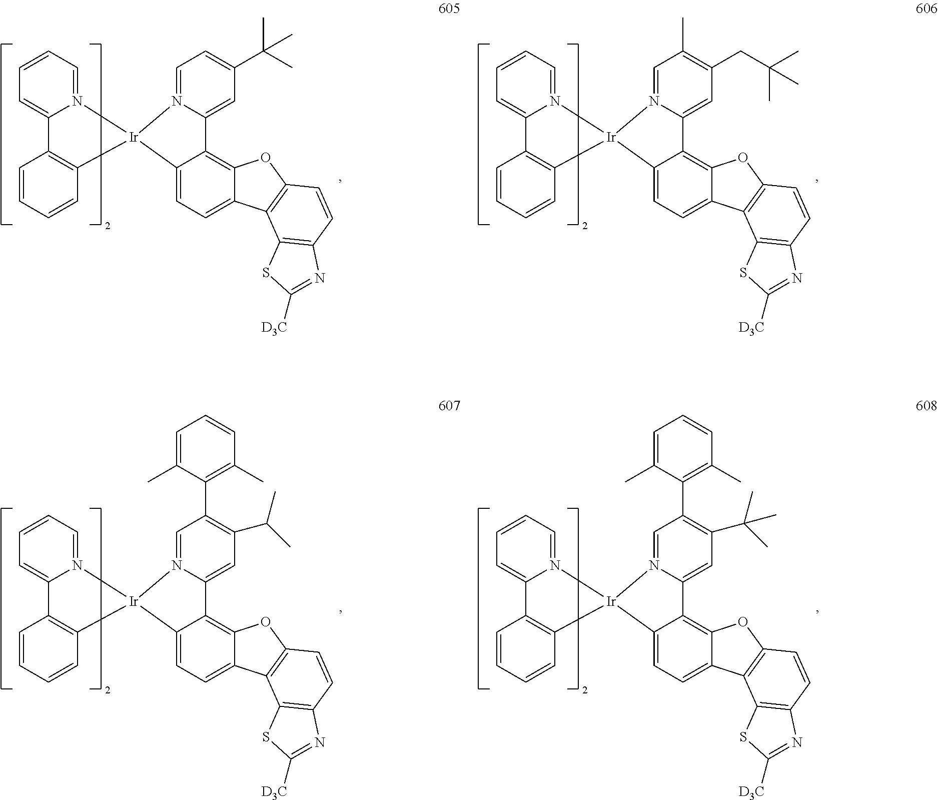

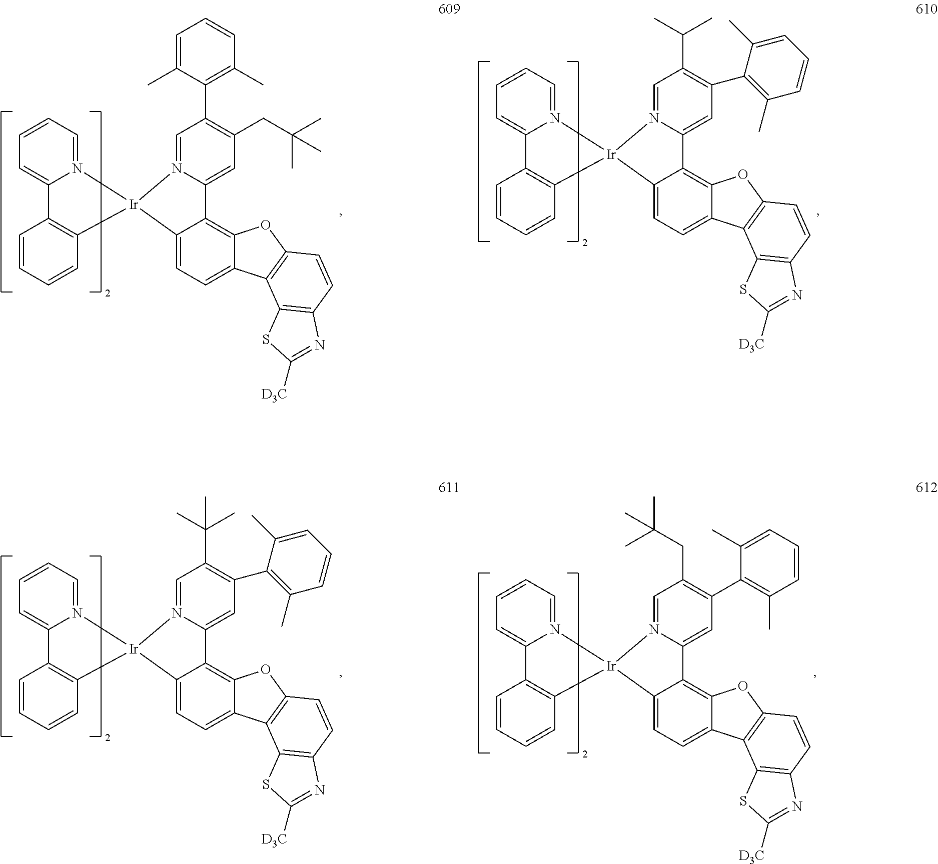

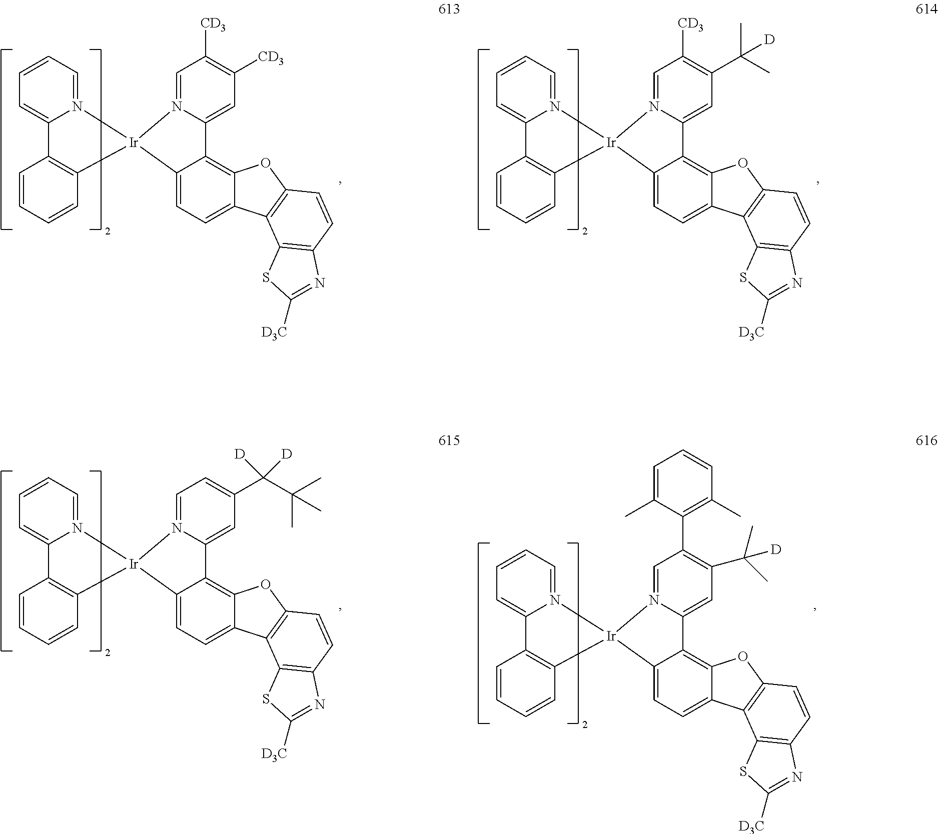

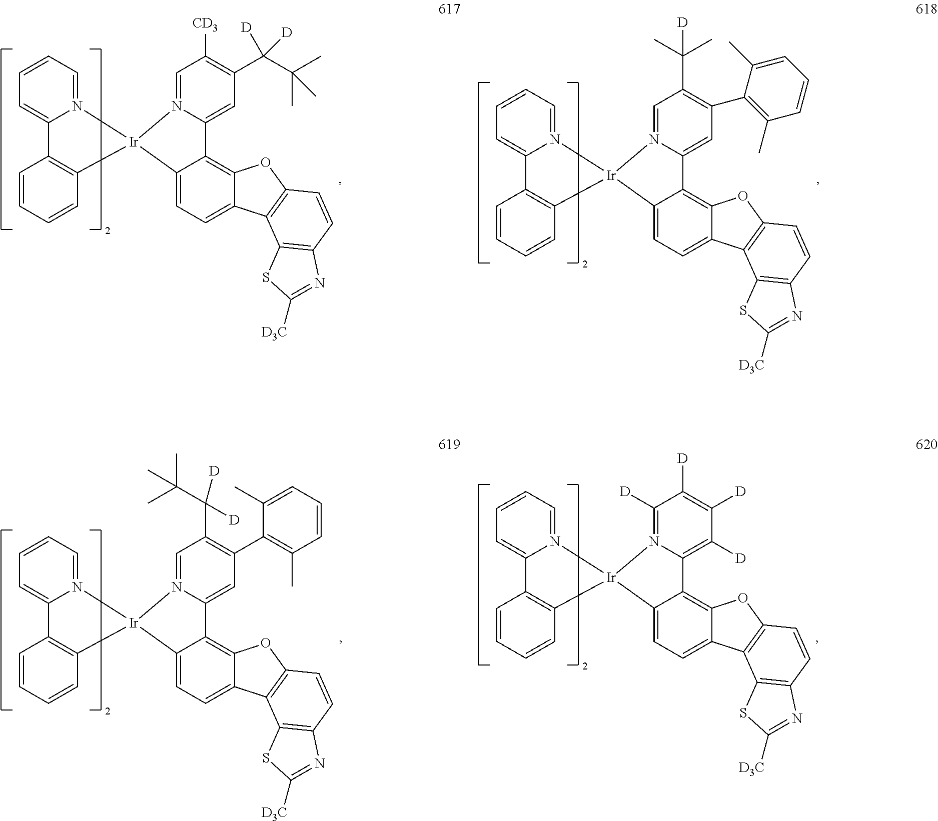

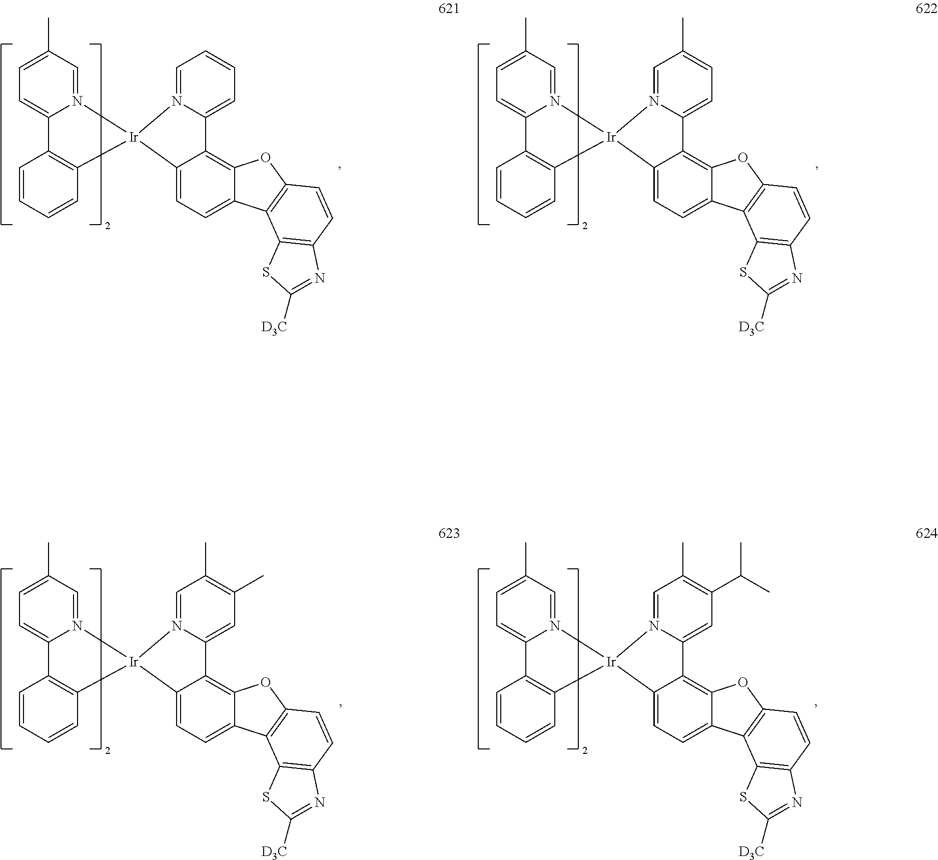

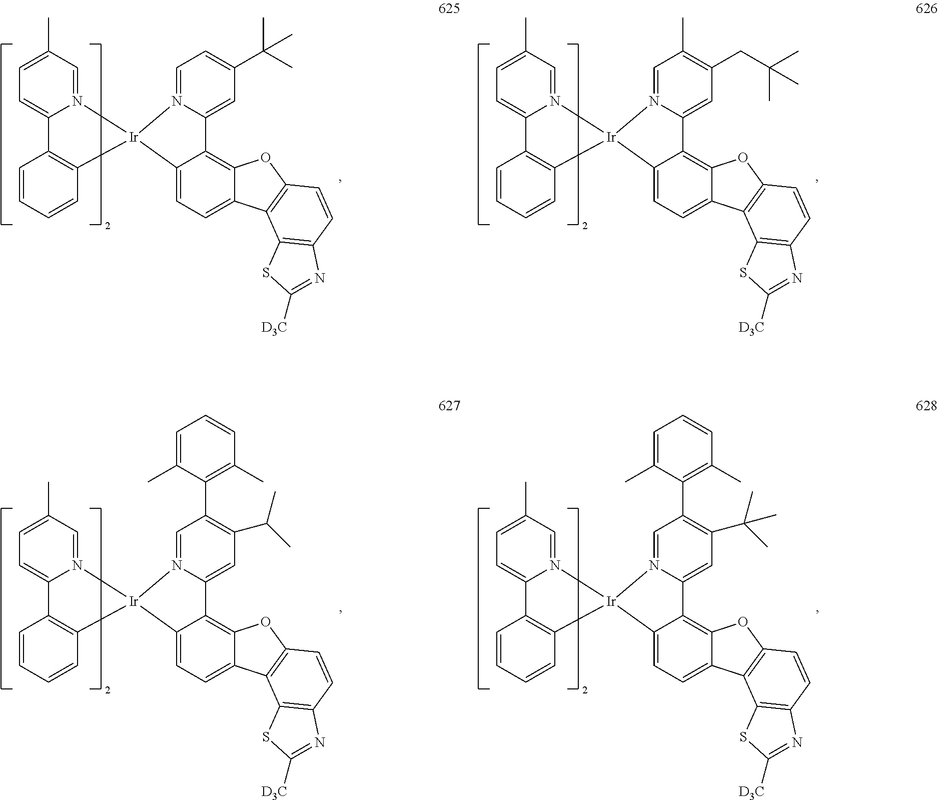

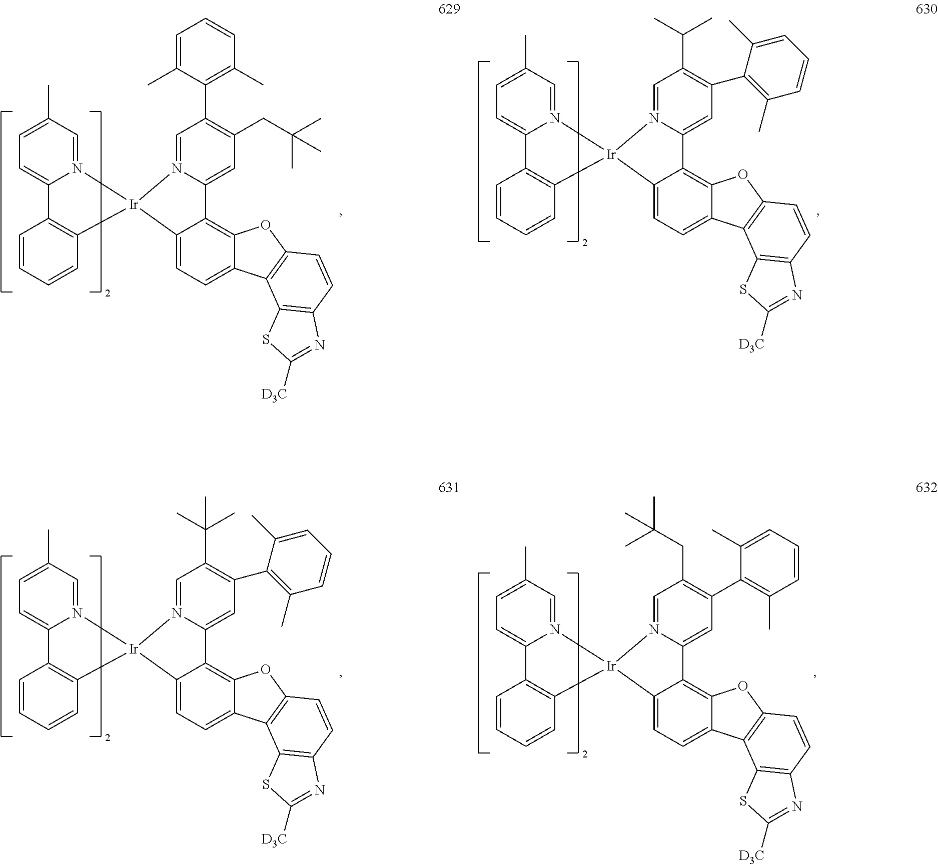

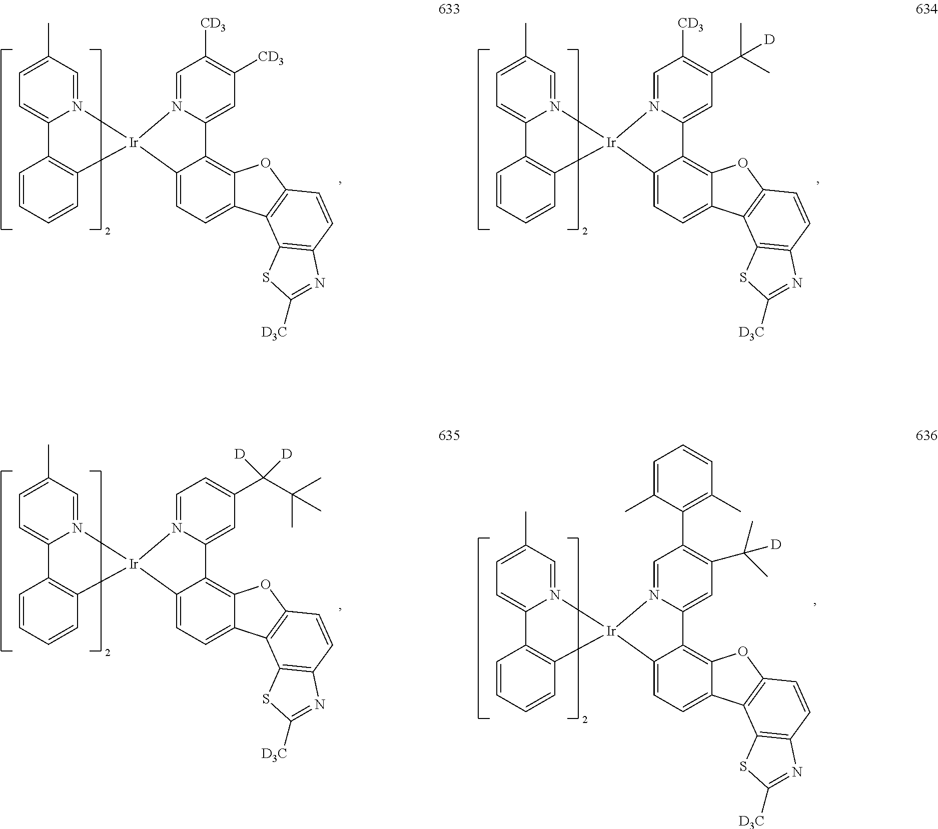

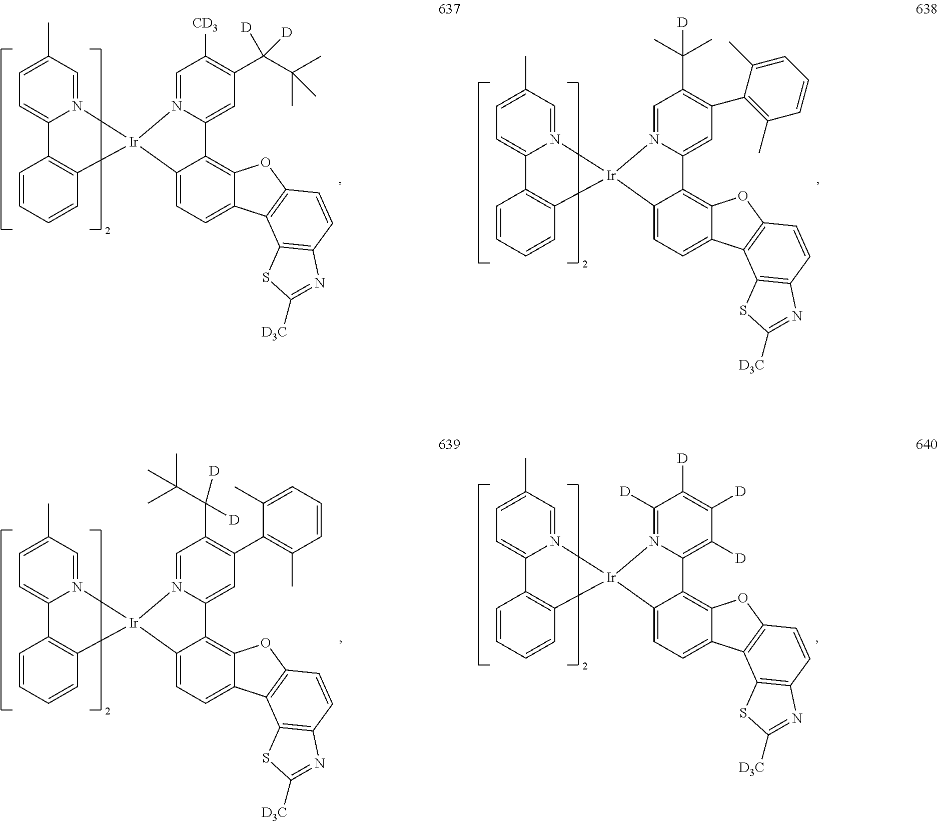

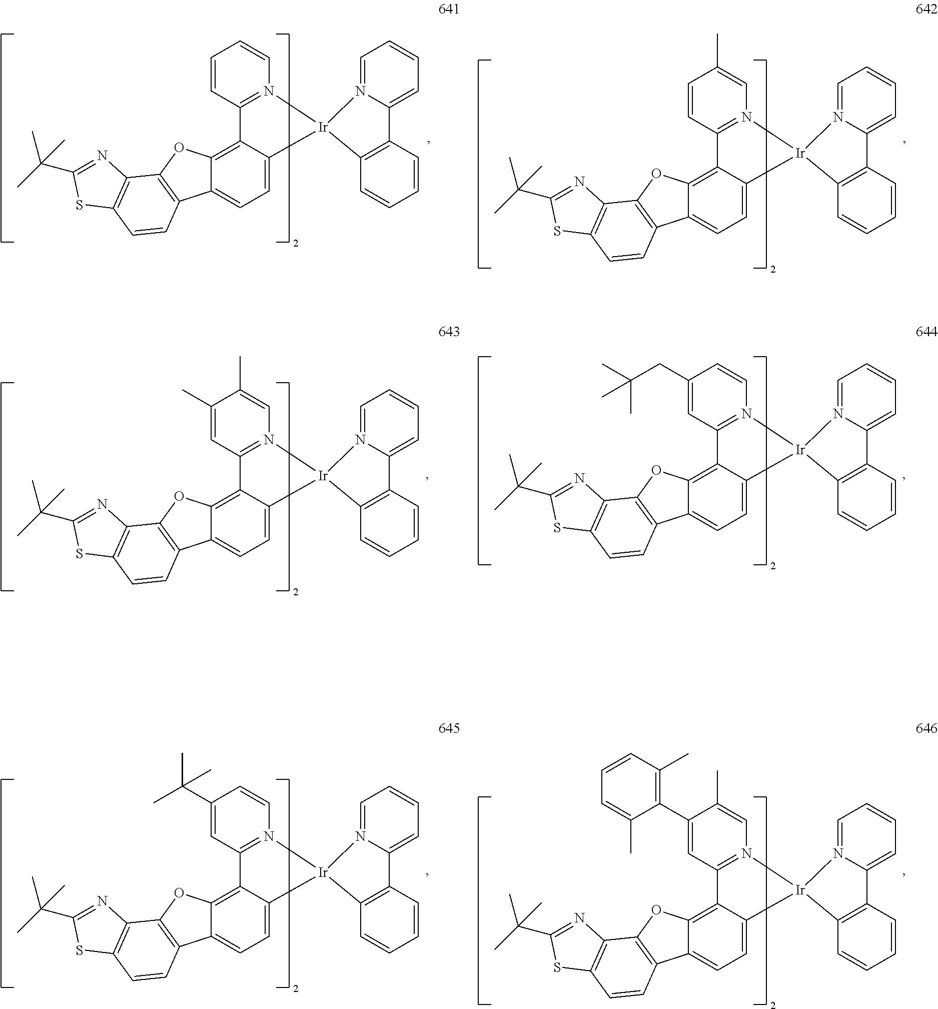

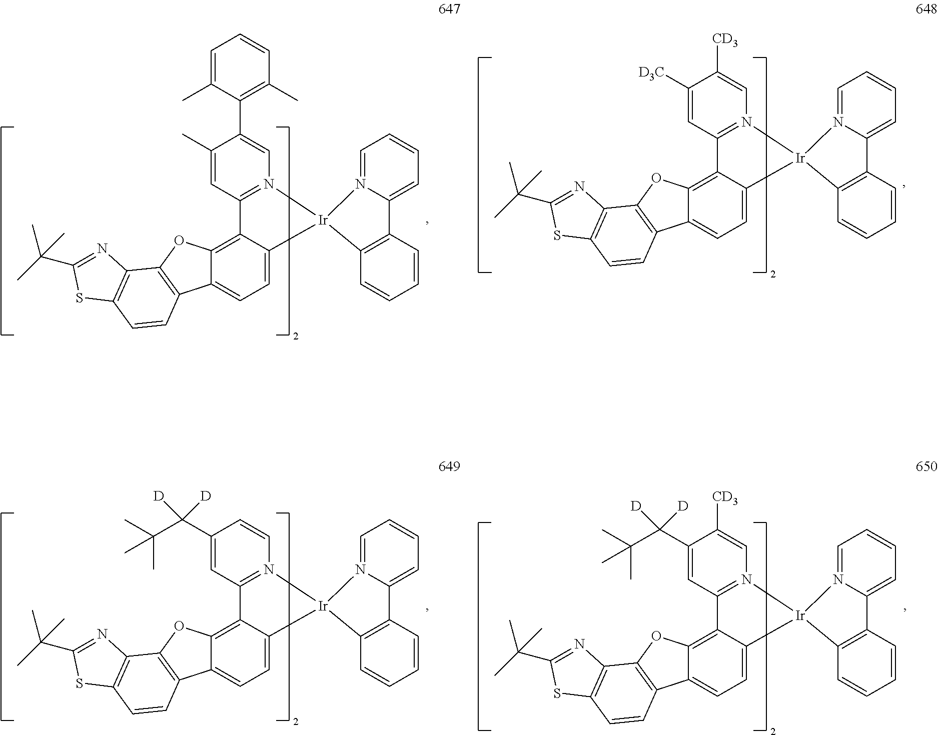

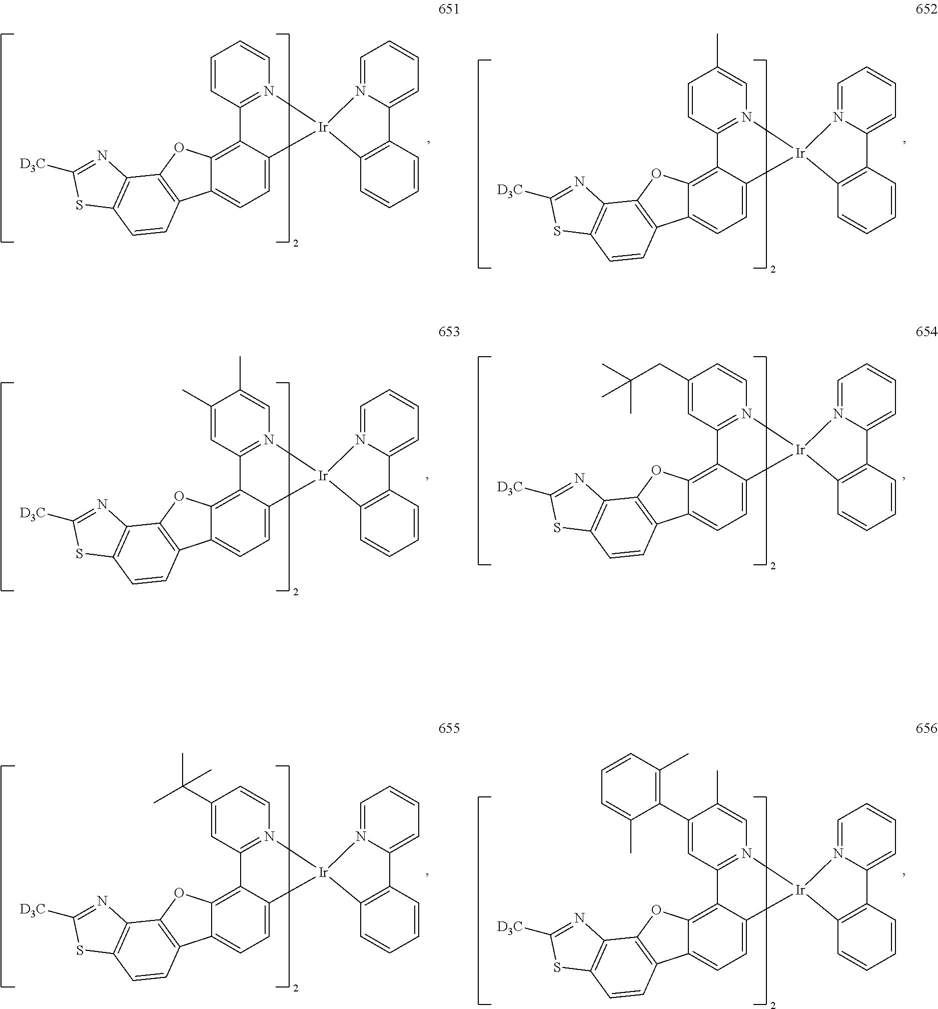

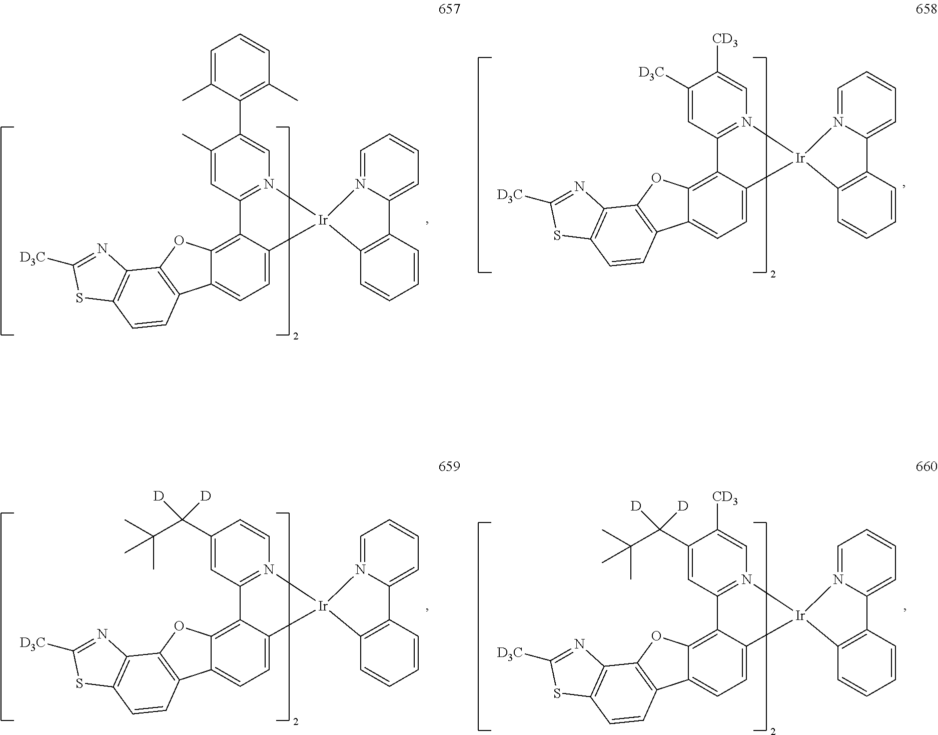

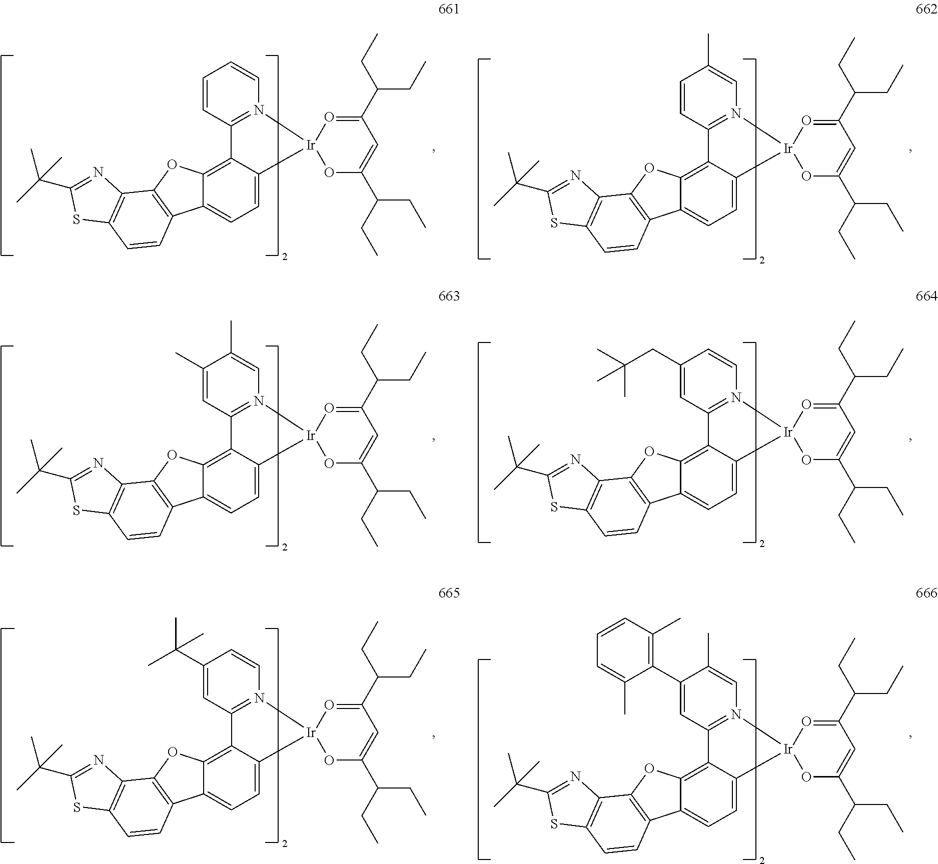

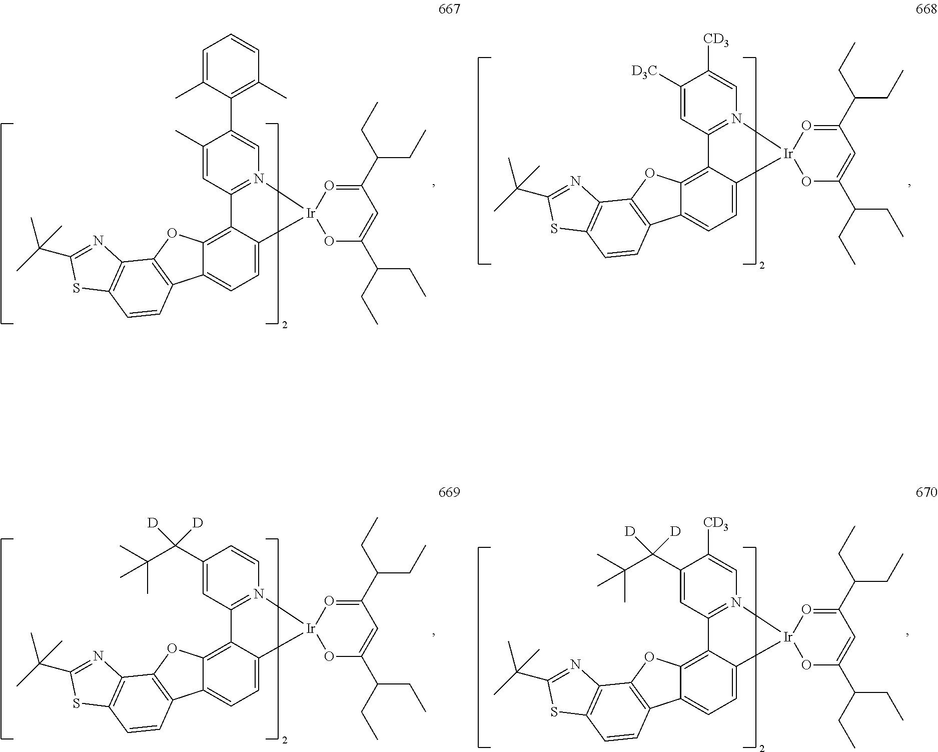

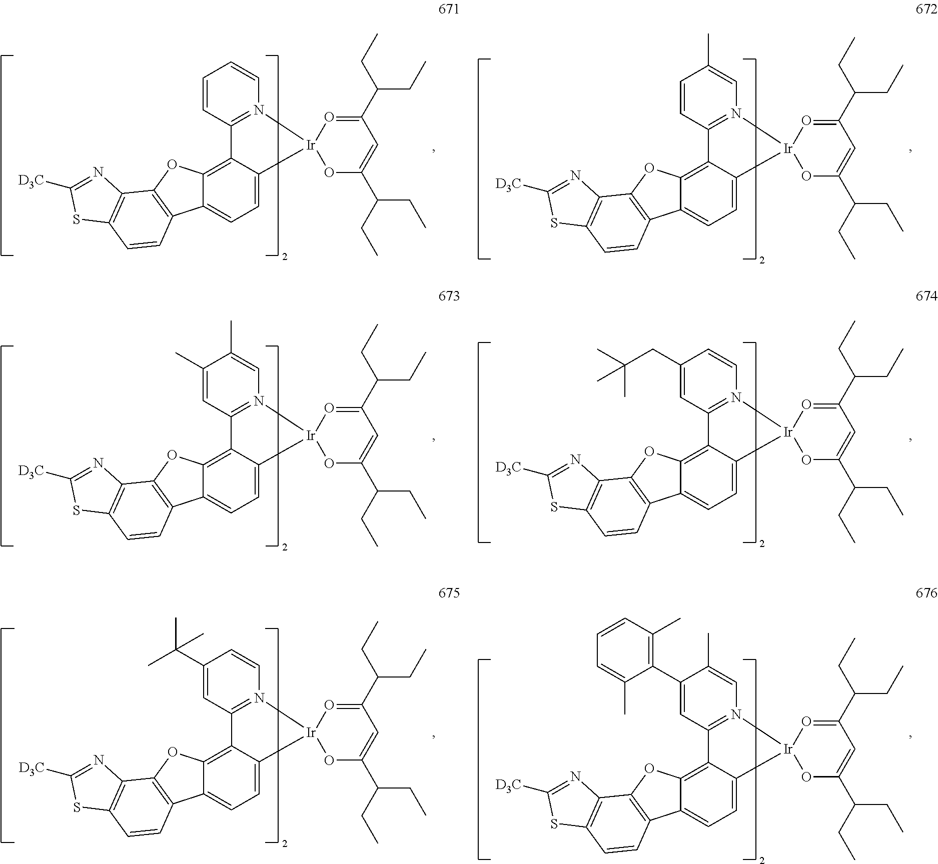

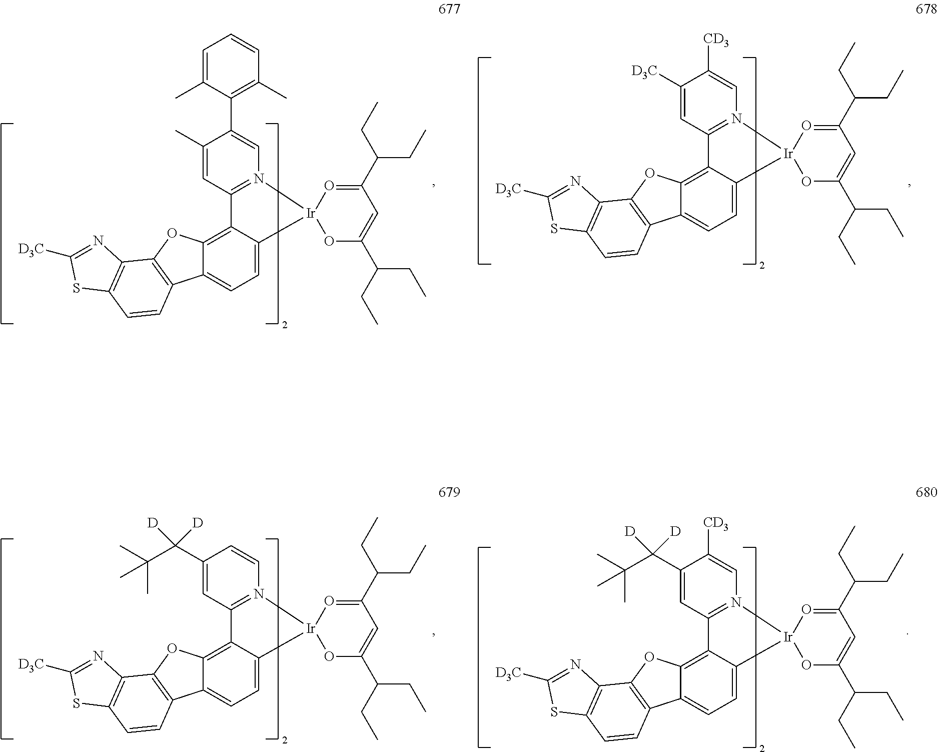

12. The organometallic compound of claim 1, wherein the compound represented by the Chemical Formula 1 is used as a green phosphorescent material.

13. An organic light-emitting diode comprising:
a first electrode;
a second electrode facing the first electrode; and
an organic layer disposed between the first electrode and the second electrode,
wherein the organic layer includes a light-emitting layer,
wherein the light-emitting layer contains the organometallic compound according to claim 1.

14. The organic light-emitting diode of claim 13, wherein the compound represented by the Chemical Formula 1 is used as a green phosphorescent material of the light-emitting layer.

15. The organic light-emitting diode of claim 13, wherein the organic layer further includes at least one selected from a group consisting of a hole injection layer, a hole transport layer, an electron transport layer and an electron injection layer.

16. An organic light-emitting display device comprising:
a substrate;
a driving element positioned on the substrate; and
an organic light-emitting diode disposed on the substrate and connected to the driving element, wherein the organic light-emitting diode includes the organic light-emitting diode according to claim 13.
